(19) United States
(12) Patent Application Publication
(10) Pub. No.: US 2026/0332070 A1
(43) Pub. Date: Oct. 22, 2026

(54) IMPROVED OPTICAL WAVEGUIDE COMPRISING A SELF-ADJUSTING SENSOR ELEMENT HAVING NV CENTRES AND A SMALL MEAURING VOLUME, METHOD FOR MANUFACTURING SAID OPTICAL WAVEGUIDE, AND APPLICATIONS THEREOF

(71) Applicant: QUANTUM TECHNOLOGIES GmbH, Leipzig (DE)

(72) Inventors: Lutz LANGGUTH, Leipzig (DE); Robert Staacke, Leipzig (DE); Dominik RAJSP, Leipzig (DE); Romy MÜLLER, Leipzig (DE)

(73) Assignee: QUANTUM TECHNOLOGIES GmbH, Leipzig (DE)

(21) Appl. No.: 19/105,782

(22) PCT Filed: Aug. 23, 2023
(86) PCT No.: PCT/DE2023/100614

§ 371 Date: Feb. 21, 2025

(30) Foreign Application Priority Data
Aug. 24, 2022 (DE) 10 2022 005 018.8
Sep. 6, 2022 (DE) 10 2022 122 507.0
Nov. 26, 2022 (DE) 10 2022 131 306.9
Jan. 16, 2023 (DE) 10 2023 100 857.9
May 7, 2023 (DE) 10 2023 111 859.5
Jun. 19, 2023 (DE) 10 2023 115 907.0
Aug. 11, 2023 (DE) 10 2023 121 634.1

(51) Int. Cl. H02P 6/16; G01R 33/26; H02K 11/22

(52) U.S. Cl. CPC H02P 6/16; G01R 33/26; H02K 11/22

(57) ABSTRACT

An optical waveguide (LWL) includes a sensor element (SE) that includes a substrate material (TM). Diamonds (DM) are embedded in the substrate material (TM). One or more diamonds (DM) include NV-centers (NVZ) and/or other paramagnetic centers. The NV centers (NVZ) of the sensor element (SE) and/or the other paramagnetic centers of the sensor element (SE) emit at least one fluorescence radiation (FL) upon exposure to pump radiation (LB). The substrate material (TM) is a radiation cured substrate material (TM). The substrate material (TM) is transparent to radiation with a pump radiation wavelength (pmp) of the pump radiation (LB). The substrate material (TM) is substantially transparent to radiation having a fluorescence wavelength (fl) of the fluorescence radiation (LB) of the NV centers (NVZ) and/or the other paramagnetic centers.

### CROSS REFERENCE TO RELATED APPLICATIONS

This Application is a National Phase of, and claims priority to, International Application Number PCT/DE2023/100614, filed Aug. 23, 2023, and entitled IMPROVED OPTICAL WAVEGUIDE COMPRISING A SELF-ADJUSTING SENSOR ELEMENT HAVING NV CENTRES AND A SMALL MEASURING VOLUME, METHOD FOR MANUFACTURING SAID OPTICAL WAVEGUIDE, AND APPLICATIONS THEREOF; which claims priority to German patent applications DE 10 2022 005018.8 dated Aug. 24, 2022, DE 10 2023 100 857.9 dated Jan. 16, 2023, DE 10 2023 111 859.5 dated May 7, 2023, DE 10 2022 122 507.0 dated Sep. 6, 2022, DE 10 2023 115 907.0 dated Jun. 19, 2023 DE 10 2023 121 634.1 dated Aug. 11, 2023 and DE 10 2022 131 306.9 dated Nov. 26, 2022, the entire disclosures of each of which are incorporated herein by reference.

### TECHNICAL FIELD

The present invention relates to optical sensor technology and, more specifically, to devices and methods for highly spatially resolved magnetic field measurements using optical waveguides with embedded sensor elements. The invention further relates to applications of such sensor elements in electric motor commutation and material property detection.

### BACKGROUND

Devices for measuring magnetic fields with high spatial resolution are used in various applications, including electric motor commutation and material property detection on workpiece surfaces. One approach to magnetic field sensing involves optical waveguides coupled with sensor elements that contain nitrogen-vacancy (NV) centers in diamonds or other paramagnetic centers. These NV centers emit fluorescence radiation when exposed to pump radiation, allowing for detection and measurement of magnetic fields.

However, the precise alignment of the sensor element with respect to the optical waveguide remains a challenge. Existing solutions often require manual alignment steps, which increase production complexity and reduce consistency. Additionally, embedding NV centers or other paramagnetic centers into a stable substrate material while maintaining optical transparency to both pump radiation and fluorescence emissions is difficult.

There is a need for an improved optical waveguide sensor that enables self-alignment of the sensor element, ensures high manufacturing consistency, and allows for efficient series production with high process capability indices (Cpk values).

### PRIOR ART

A system is known from DE 10 2020 129 367 A1 in which it is intended to position the evaluation electronics of a similar system directly on the stator. During the development of the proposal presented here in this document, it was recognized that the technical teaching of DE 10 2020 129 367 A1 is susceptible to EMC interference and causes a problem with galvanic isolation and temperature stress.

Methods for producing NV centers are known from DE 10 2020 109 477 A1.

DE 10 2019 120 076 A1, DE 11 2020 003 569 A5, DE 11 2020 004 650 A5, DE 10 2021 101 565 A1, DE 10 2021 132 782 A1 and EP 3 874 343 A2 already contain known conduction-free devices for detecting magnetic fields.

From the paper Ilya Fescenko, Andrey Jarmola, Igor Savukov, Pauli Kehayias, Janis Smits, Joshua Damron, Nathaniel Ristoff, Nazanin Mosavian and Victor M. Acosta “Diamond magnetometer enhanced by ferrite flux concentrators”, Phys. Rev. Research 2, 023394, 24 Jun. 2020, DOI: https://doi.org/10.1103/PhysRevResearch.2.023394 the use of a dichroitic mirror for the separation of pump radiation and fluorescence radiation is known.

From the paper Georgios Chatzidrosos, Joseph Shaji Rebeirro, Huijie Zheng, Muhib Omar, Andreas Brenneis, Felix M. Stürner, Tino Fuchs, Thomas Buck, Robert Rölver, Tim Schneemann, Peter Blümler, Dmitry Budker, Arne Wickenbrock, “Fiberized Diamond-Based Vector Magnetometers” Front. Photon., 20 Aug. 2021, Sec. Quantum Optics, Volume 2-2021|https://doi.org/10.3389/fphot.2021.732748 and from the paper Yuji Hatano, Jaewon Shin, Daisuke Nishitani, Haruki Iwatsuka, Yuta Masuyama, Hiroki Sugiyama, Makoto Ishii, Shinobu Onoda, Takeshi Ohshima, Keigo Arai, Takayuki Iwasaki, Mutsuko Hatano, “Simultaneous thermometry and magnetometry using a fiber-coupled quantum diamond sensor” Appl. Phys. Lett. 118, 034001 (2021) https://doi.org/10.1063/5.0031502 The transfer of pump radiation to excite NV centers of a single crystal by means of optical waveguides is known.

The website https://de.wikipedia.org/wiki/Lichtwellenleiter provides more information about optical waveguides.

All these writings do not solve the problem of how the sensor element of the optical waveguide should be designed to comprise a stability that is suitable for the thermal requirements, for example for use in a motor or a sensor head. In prior art methods, the diamonds are bonded to the end of an optical waveguide fiber. This fabrication step typically requires careful alignment of the diamonds to achieve good coupling. Also, all diamonds with NV centers should be equally exposed to pump radiation of the pump radiation wavelength λₚₘₚ during fabrication. Diamonds that are not sufficiently exposed do not show the full contrast with regard to the dependence of the intensity of the fluorescence radiation of their paramagnetic centers, in this case the NV centers, on an ambient magnetic field.

An essential problem is to achieve a good Cₚₖ value for the properties of the optical waveguide equipped with NV centers at one of its ends. In quantum sensor systems using microwaves and/or radio waves, waveguides such as microstrip lines, slotted lines, trip-plate waveguides, differential microstrip lines and differential trip-plate waveguides and even more complex stripline systems are generally used. The waveguide region, in which the NV centers and/or paramagnetic centers of crystals and/or diamonds of a sensor element interact with such a waveguide, exhibits a deviating permittivity when exposed to a defined pump radiation, which can also have the intensity value 0, due to a deviating permittivitys of the substrate material of the sensor element in which these crystals and/or diamonds are embedded, and, due to the deviating permittivitys of these crystals and/or these diamonds, has a different characteristic impedance than the rest of the waveguide that is not covered by the sensor element. An essential problem here is achieving a good Cₚₖ value for the characteristic impedance of the section of the waveguide that is covered by the sensor element. Only such good Cₚₖ values ultimately enable series production with reliable, high-quality results and yields.

The aforementioned fonts do not solve this problem. Also, placing NV centers in the right way requires highly qualified personnel, which is expensive and not always available.

A recurring problem is the detection of cracks and other defects in the surfaces of ferromagnetic workpieces. Corresponding measurement methods are known in the state of the art. However, these have insufficient spatial resolution to detect small cracks.

The document presented here provides only brief key points on the principle of non-destructive material testing with regard to the state of the art.

For the measurement of workpieces by means of magnetic field measurement, the use of Hall sensors/coils for measuring stray magnetic fields/eddy current fields poses the problem that these measuring methods comprise a large measuring volume at a limited distance from the workpiece and a large measuring cross-section. The corresponding devices are not diamagnetic and therefore change the measurement object, the magnetic field.

The method and device presented here are intended to remedy this.

A sensor comprising a magnetic is known from WO 2022 096 891 A1. According to the technical teaching of WO 2022 096 891 A1, the magnet is arranged such that it applies an inhomogeneous magnetic field to a certain volume. The sensor of WO 2022 096 891 A1 further comprises a magnetometer with an active element for detecting the magnetic field in a volume comprising the determined volume.

A detection system for orthogonal cracks based on NV color center detection technology is known from CN 1 14 994 006 A. The detection system of CN 1 14 994 006 A comprises an excitation end, a collection end and a magnetization detection front end. The technical teaching of CN 1 14 994 006 A uses the excitation end to generate excitation light, wherein the excitation light acts on the front end of the magnetization sensor. The front end of the magnetizing sensor comprises a magnetizing portion and a detecting portion, wherein the magnetizing portion is used for magnetizing a ferromagnetic object to be detected. The magnetizing portion of the device of CN 1 14 994 006 A comprises a magnetizing interval. When a crack on the ferromagnetic object to be detected is positioned in the magnetization interval, the device of CN 1 14 994 006 A can generate a magnetic stray field at the crack. The detection part of the device of CN 1 14 994 006 A generates a voltage fluorescence under the effect of the excitation light and the magnetic stray field. The detection part of the device of CN 1 14 994 006 A is used to receive the voltage fluorescence and to analyze and process the voltage fluorescence. The magnetization part of CN 1 14 994 006 A comprises two groups of electromagnets. The magnetization directions of the two groups of electromagnets of the device of CN 1 14 994 006 A are orthogonal to each other. The sensor part of the device of CN 1 14 994 006 A comprises an optical sensor fiber, an end part of the optical sensor fiber is a detection end, and diamond-shaped NV colorant particles attached to the fiber core are arranged on the end surface of the detection end.

A method for the fabrication of a fiber optic quantum probe with controllable diamond particle doping is known from CN 1 12 146 782 A. The method of CN 1 12 146 782 A comprises the following steps:
Step 1) Mixing the solution with an aqueous nano-diamond particle solution containing NV color centers;
Step 2) dissolving the prepared solution doped with the nano-diamond particles containing the NV color centers with ultrasound by a sol-gel method, sealing and allowing the solution to stand, and completely hydrolyzing the solution to form sol-gel; and
3) uniformly applying the sol-gel prepared in step 2) to the end face of the optical fiber, holding the optical fiber by a stepping motor, contacting the end face of the optical fiber with the sol-gel, pulling the end face of the optical fiber at a certain speed after a period of time to form a hemispherical gel film having a certain thickness and a certain curvature, and curing to obtain the fabricated quantum probe of the optical fiber. According to the technical teaching of CN 1 12 146 782 A, the doping concentration of the nanodiamond particles containing NV color centers can be controlled. According to the technical teaching of CN 1 12 146 782 A, the nanodiamond particles are uniformly mixed. CN 1 12 146 782 A states that the manufacturing process of the probe is simple, its repeatability is high, and that mass production can be realized.

A device for detecting the stray flow in a pipeline is known from CN 1 14 720 553 A. The device of CN 1 14 720 553 A is based on an optical fiber coupling a diamond nitrogen vacancy color center.

These writings also do not solve the problem of the necessary self-alignment of the material of the sensor element with the crystals comprising the paramagnetic centers and/or NV centers with respect to the optical waveguide.

### SUMMARY

The disclosure is directed to a device for the highly spatially resolved measurement of magnetic fields by means of an optical waveguide with a sensor element that is self-adjusting relative to the optical waveguide with respect to a target placement. As applications, the document presented here discloses a use of the device for commutation of an electric motor and a sensor head for detecting material properties on the surface of a workpiece. The sensor element comprises a multiplicity of diamonds comprising NV centers or other paramagnetic centers. This multiplicity of diamonds comprises a different orientation to each other. In the application case of a sensor head, this multiplicity of diamonds thus comprises a different spatial orientation of the diamonds in relation to the sensor head housing.

The disclosure relates to an optical waveguide (LWL) with a sensor element (SE), wherein the sensor element (SE) comprises a substrate material (TM) and wherein a multiplicity of diamonds (DM) are embedded in the substrate material (TM) and wherein one or more or all diamonds (DM) of these diamonds (DM) comprise NV-centers (NVZ) and/or other paramagnetic centers and wherein the NV centers (NVZ) of the sensor element (SE) and/or the other paramagnetic centers of the sensor element (SE) emit at least one fluorescence radiation (FL) upon exposure to pump radiation (LB). The optical waveguide is characterized in that the substrate material (TM) is a radiation cured substrate material (TM). This enables self-adjusting series production with a high Cₚₖ value. For the functionality of the devices constructed with it, it is necessary that the substrate material (TM) is essentially transparent to radiation with a pump radiation wavelength (λₚₘₚ) of the pump radiation (LB) with which the NV centers (NVZ) and/or the other paramagnetic centers are pumped, is essentially transparent, and in that the substrate material (TM) is essentially transparent to radiation having a fluorescence wavelength (λ_{fl}) of the fluorescence radiation (LB) of the NV centers (NVZ) and/or the other paramagnetic centers.

A method according to the disclosure for the series production of such an advantageous optical waveguide (LWL) with a high Cₚₖ value comprises the steps a) deployment (140) of an optical waveguide (LWL),

wherein the optical waveguide (LWL) comprises a first end and a second end; B) deploying (145) a liquid substrate material (TM) curable by means of electromagnetic radiation of a curing wavelength (λ_{H}), wherein a multiplicity of diamonds (DM) and/or crystals are embedded in the substrate material (TM), and wherein one or more or all diamonds (DM) of these diamonds (DM) and/or crystals comprise NV centers (NVZ) and/or other paramagnetic centers, and wherein the NV centers (NVZ) of the substrate material (TM) comprise a multiplicity of diamonds (DM) and/or crystals centers (NVZ) of the substrate material (TM) and/or the other paramagnetic centers of the substrate material (TM) emit at least one fluorescence radiation (FL) upon exposure to pump radiation (LB) of a pump radiation wavelength (λₚₘₚ); c) wetting (150) the first end of the optical waveguide (LWL), in particular to a wetting length LB or in a wetting region, with the substrate material (TM) comprising the multiplicity of embedded diamonds (DM) and/or crystals; d) irradiating (155) the substrate material (TM) in the region of the first end (ELWL1) of the optical waveguide (LWL) with electromagnetic curing radiation, the wavelength of this electromagnetic radiation, the curing wavelength (λ_{H}), being selected such that the substrate material (TM) at the first end (ELWL1) of the optical waveguide (LWL) at least partially cures in the irradiated area and at least partially transforms into a solid; e) removing (160) the uncured substrate material (TM), in particular by means of a solvent, the remaining film of the substrate material (TM) at the first end of the optical waveguide (LWL) forming the sensor element (SE). A further embodiment of the method according to the disclosure comprises a concretization of the exposure (155) of the substrate material (TM) in the region of the first end (ELWL1) of the optical waveguide (LWL) in the form of an injection (155) of electromagnetic curing radiation into the second end of the optical waveguide (LWL), the wavelength of this electromagnetic radiation, the curing wavelength (λ_{H}), being selected such that the substrate material (TM) at the first end of the optical waveguide (LWL) cures and transforms into a solid. This has the advantage that the hardening of the substrate material (TM) at the first end (ELWL1) of the optical waveguide (LWL) to form a sensor element (SE) is self-adjusting and only takes place in the region of the light emission from the optical waveguide (LWL).

It has been shown that it is advantageous for subsequent cleaning if, in a further embodiment of the method according to the disclosure, the substrate material (TM) only partially cures during exposure to the curing radiation of the curing wavelength (λ_{H}).

For curing according to the method described above, relatively high photon energies are generally advantageous depending on the substrate material (TM). In a further embodiment, the method according to the disclosure therefore provides that the radiation of the curing radiation fed in at the second end of the optical waveguide for curing is UV radiation with a curing wavelength (λ_{H}) in the wavelength range from 1 nm to 400 nm.

To improve the self-alignment of the sensor element (SE) with respect to the optical waveguide (LWL), it is advantageous according to the disclosure if the optical waveguide (LWL) provided has, at least at the first end of the optical waveguide (LWL), an optical waveguide core (LWLC), inter alia for this purpose and/or at least at the first end of the optical waveguide (LWL) is coated with a light-impermeable layer which comprises one or more light-permeable openings, the so-called clearances, and wherein these structures of the optical waveguide (LWL), the optical waveguide core (LWLC) and/or the clearances limiting the light emission of the curing radiation with the curing wavelength (λ_{H}) at the first end (ELWL1) of the optical waveguide (LWL) to one or more emission areas, and wherein the method in the substrate material (TM) during curing by feeding the curing radiation with the curing wavelength (λ_{H}) at the second end (ELWL2) of the optical waveguide (LWL) one or more functional elements (LWLL) and/or one or more sensor elements (SE) at the first end (ELWL1) of the optical waveguide (LWL) in the region of the one or more emission areas, and wherein the one or more optical functional elements (LWLL) thus formed by the method and/or the one or more sensor elements (SE) thus formed by the method are configured by the method in such a way such that the one or more optical functional elements (LWLL) thus formed by the method and/or the one or more sensor elements (SE) thus formed by the method
with the optical waveguide core (LWLC) at the first end (ELWL1) of the optical waveguide (LWL) and/or
with the one or more clearances at the first end (ELWL1) of the optical waveguide (LWL),
in particular self-adjusted by the method, interact optically,
if optical radiation, in particular pump radiation (LB) with the pump radiation wavelength (□pmp), is fed in at the second end (ELWL2) of the optical waveguide (LWL) and/or
if NV centers (NVZ) within the substrate material (TM) and/or other paramagnetic centers within the substrate material (TM) emit fluorescence radiation (FL) at the first end (ELWL1) of the optical waveguide (LWL).

According to the disclosure, it has been recognized that it is useful for some application examples if the optical waveguide (LWL) provided in the method is coated with one or more waveguides (1380, 1880, 2380, 6880, 6980) which comprise clearances in particular. These enable the self-alignment of the sensor elements with respect to these clearances and thus with respect to the waveguide in the manufacturing process according to the disclosure.

Corresponding to the optical waveguide according to the disclosure is a method of using this advantageous waveguide with very good Cₚₖ values of the measured values which such optical waveguides provide in sensor systems. The method proposed according to the disclosure for determining a physical quantity comprises a) the deployment of an advantageous optical waveguide (LWL) according to the disclosure as described above, wherein the optical waveguide (LWL) provided is coated with one or more waveguides (1380, 1880, 2380, 6880, 6980) comprising clearances, and wherein one or more sensor elements (SE) are located in the clearances of the one or more waveguides or on the waveguide and/or in the vicinity of the waveguide (1380, 1880, 2380, 6880, 6980), and b) feeding a microwave signal (μW) into one or more of the waveguides (1380, 1880, 2380, 6880, 6980) and feeding a pump radiation (LB) with the pump radiation wavelength (λₚₘₚ) into the optical waveguide (LWL), in particular at the second end (ELWL2) of the optical waveguide (LWL), or exposing the sensor element (SE) of the optical waveguide (LWL) to a pump radiation (LB) with the pump radiation wavelength (λₚₘₚ), and c) detecting an intensity value of the fluorescence radiation (FL) of the NV centers (NVZ) of the sensor element (SE) and/or of the other paramagnetic centers of the sensor element (SE) and the d) determining at least one measured value for a physical quantity from this intensity value and possibly further values.

Another method of use according to the disclosure comprises a) the deployment of an advantageous optical waveguide (LWL) according to the disclosure and b) the injection of a pump radiation (LB) with the pump radiation wavelength (λₚₘₚ) into the optical waveguide (LWL), in particular at the second end (ELWL2) of the optical waveguide (LWL), or exposing the sensor element (SE) of the optical waveguide (LWL) to a pump radiation (LB) with the pump radiation wavelength (λₚₘₚ) and c) detecting an intensity value of the fluorescence radiation (FL) of the NV centers (NVZ) of the sensor element (SE) and/or of the other paramagnetic centers of the sensor element (SE) and d) detecting at least one measured value for a physical quantity from this intensity value and, if appropriate, further values. further values.

In the course of working out the disclosure, it was realized that the disclosure can be used to improve a magnetic field camera according to the disclosure. The magnetic field camera comprises a sensor element layer (5) as a sensor element (SE), wherein the sensor element (SE) comprises a substrate material (TM) and wherein a multiplicity of diamonds (DM) are embedded in the substrate material (TM) and
wherein one or more or all diamonds (DM) of said diamonds (DM) comprise NV centers (NVZ) and/or other paramagnetic centers and wherein the NV centers (NVZ) of the sensor element (SE) and/or the other paramagnetic centers of the sensor element (SE) emit at least one fluorescence radiation (FL) upon exposure to pump radiation (LB). Preferably, the substrate material (TM) is a radiation cured substrate material (TM), which enables fabrication with good Cₚₖ values. In order to function properly, it is necessary that the substrate material (TM) is substantially transparent to radiation with a pump radiation wavelength (λₚₘₚ) of the pump radiation (LB) with which the NV centers (NVZ) and/or the other paramagnetic centers are pumped, is essentially transparent and that the substrate material (TM) is essentially transparent to radiation having a fluorescence wavelength (λ_{fl}) of the fluorescence radiation (LB) of the NV centers (NVZ) and that the magnetic field camera is a fluorescence camera, in particular a light sensor array (1) and an optical system (7), for spatially resolved recording of a fluorescence picture of the fluorescence radiation (FL) of the NV centers (NVZ) and/or the other paramagnetic centers with at least 2×2 pixels.

According to the disclosure, in a special embodiment, the magnetic field camera is configured to generate a fluorescence picture and to output the fluorescence picture. The magnetic field camera comprises a memory. In this embodiment, the magnetic field camera is configured to store or temporarily store the fluorescence picture in this memory and/or to keep it available and/or to output it from the memory and/or to transfer it from the memory to a higher-level computer system.

In a further embodiment, the magnetic field camera is configured to execute a computer-implemented artificial intelligence program in order to generate and/or output digitized and/or binary measured values and/or classifications from the recorded fluorescence pictures of the magnetic field camera, in particular from fluorescence pictures in the memory of the magnetic field camera, and/or to store them in a memory of the magnetic field camera and to keep them available in the memory of the magnetic field camera and/or to output them and/or to transmit them to a higher-level computer system.

In a further embodiment, the magnetic field camera comprises a memory in which the program code of the computer-implemented artificial intelligence program is stored at least temporarily, and

wherein a computer system of the magnetic field camera retrieves and executes the program code from this memory upon execution of the computer-implemented artificial intelligence program.

An advantageous computer program product corresponds to this, wherein the computer program product comprises at least one storage medium and wherein the information of the program code of the computer-implemented artificial intelligence program is at least temporarily stored in the storage medium in compressed and/or non-compressed and/or encrypted or non-encrypted form, and wherein the storage medium of the computer program product is configured to become part of the memory of the magnetic field camera in which the program code of the computer-implemented artificial intelligence program is at least temporarily stored, or to transfer at least part of its content to the memory of the magnetic field camera in which the program code of the computer-implemented artificial intelligence program is at least temporarily stored.

Another embodiment according to the disclosure relates to a motor control unit for a motor, wherein the motor and/or the control of the motor comprises an optical waveguide according to the disclosure and/or wherein the control of the motor comprises a magnetic field camera according to the disclosure and/or wherein the control of the motor is configured to use a computer program product according to the disclosure.

Associated therewith is a method according to the disclosure for commutation of a motor with the steps a) of detecting the points in time of the zero crossings of the phase current of a motor phase of the motor by means of a method according to the disclosure and/or b) of detecting the points in time of the zero crossings of the absolute value of the magnetic flux density within the air gap (LS) of the motor by means of a method according to the disclosure, the sensor element (SE) being arranged in the air gap (LS) of the motor and/or in the stray field of the magnetic field in the air gap (LS) of the motor, and c) controlling the commutation of the phase voltages of the phase connections of the motor phase windings as a function of the points in time of the zero crossings.

The high quality of the optical waveguides (LWL9 according to the disclosure enables the series production of high quality light waveguide production quantities, wherein the light waveguide production quantity comprises a plurality of light waveguides (LWL) and wherein the light waveguide (LWL) of the plurality of light waveguides (LWL) is provided with a sensor element (SE) and wherein the sensor element (SE) comprises a substrate material (TM) and wherein a multiplicity of diamonds (DM) and/or crystals are embedded in the substrate material (TM) and wherein one or more or all diamonds (DM) of these diamonds (DM) and/or one or more crystals of these crystals comprise NV-centers (NVZ) and/or other paramagnetic centers, and wherein the NV centers (NVZ) of the sensor element (SE) and/or the other paramagnetic centers of the sensor element (SE) emit at least one fluorescence radiation (FL) via the optical waveguide (LWL) upon exposure to pump radiation (LB) of a pump radiation wavelength (λₚₘₚ) of a predetermined pump radiation intensity. The light waveguide production quantity according to the disclosure is characterized in in that said light waveguide production quantity of said light waveguide (LWL) comprises 10 or more light waveguides (LWL), and in that the tolerance window of the intensity of the fluorescence radiation (FL) of said light waveguide (LWL), which is decisive here, comprises a pump radiation wavelength (λₚₘₚ) of a predetermined pump radiation intensity (LB) via the light waveguide (LWL). via the light waveguide (LWL) is 10% of the mean value of the measured intensities of the fluorescence radiation (FL) of the various light waveguides of the light waveguide production quantity upon said exposure of the sensor element (SE) to pump radiation (LB) of the pump radiation wavelength (λₚₘₚ) of the predetermined pump radiation intensity, wherein the exposure is the irradiation for the measurement of the respective optical waveguide (LWL) via the respective optical waveguide (LWL) and in the Cₚₖ value of these measured intensities of the fluorescence radiation (FL) of the various optical waveguides (LWL) of the light waveguide production quantity during said exposure of the sensor element (SE) to pump radiation (LB) of the pump radiation wavelength (λₚₘₚ) of the predetermined pump radiation intensity with respect to said relevant tolerance window has a Cₚₖ value higher than Cₚₖ=0.8 and/or better higher than Cₚₖ=1.0 and/or better higher than Cₚₖ=1.2 and/or better higher than Cₚₖ=1.4 and/or better higher than Cₚₖ=1.66. These high Cₚₖ values are essential for successful series production.

In an analogous manner, the present document describes a high quality waveguide production quantity according to the disclosure, wherein the waveguide production quantity comprises a plurality of waveguides (1380, 1880, 2380, 6880, 6980) and wherein each waveguide (1380, 1880, 2380, 6880, 6980, 6980) of the waveguides (1380, 1880, 2380, 6880, 6980) is provided with a sensor element (SE) and wherein the respective sensor element (SE) comprises a substrate material (TM) and wherein a multiplicity of diamonds (DM) and/or crystals are embedded in the respective substrate material (TM); and wherein one or more or all diamonds (DM) of said diamonds (DM) and/or one or more crystals of said crystals comprise NV centers (NVZ) and/or other paramagnetic centers, and wherein the NV centers (NVZ) of the sensor element (SE) and/or the other paramagnetic centers of the sensor element (SE) emit at least one fluorescence radiation (FL) upon exposure to pump radiation (LB) of a pump radiation wavelength (λₚₘₚ) of a predetermined pump radiation intensity. The waveguide production quantity according to the disclosure is characterized in that said waveguide production quantity of said waveguides (1380, 1880, 2380, 6880, 6980) comprises 10 or more waveguides (1380, 1880, 2380, 6880, 6980), and in that the tolerance window of the intensity of the fluorescence radiation (FL) of said waveguides (1380, 1880, 2380, 6880, 6980) relevant here, upon exposure to pump radiation (LB) of a pump radiation wavelength (λₚₘₚ) of a predetermined pump radiation intensity via an optical waveguide (LWL) or via a light transmission path which is the same for each waveguide, comprises 10% of the mean value of the measured intensities of the fluorescence radiation (FL) of the various waveguides (1380, 1880, 2380, 6880, 6980), 1880, 2380, 6880, 6980) of the waveguide production quantity during said exposure of the sensor element (SE) to pump radiation (LB) of the pump radiation wavelength (λₚₘₚ) of the predetermined pump radiation intensity, the exposure for the measurement of the respective waveguide being carried out via the optical waveguide (LWL) for each waveguide or via the same light transmission path for each waveguide; and that the C (pk) value of these measured intensities of the fluorescence radiation (FL) of the different waveguides of the waveguide production quantity during said exposure of the sensor element (SE) to pump radiation (LB) of the pump radiation wavelength (λₚₘₚ) of the predetermined pump radiation intensity with respect to said relevant tolerance window has a Cₚₖ value higher than Cₚₖ=0.8 and/or better higher than Cₚₖ=1.0 and/or better higher than Cₚₖ=1.2 and/or better higher than Cₚₖ=1.4 and/or better higher than Cₚₖ=1.66. These high Cₚₖ values are essential for successful series production.

### Task

The proposal is therefore based on the task of finding a solution to the above problems;
a) the necessary thermal and galvanic separation;
b) the alignment of the crystals to the core of the optical fiber or optical waveguide; and
c) a suitable method for the fabrication of a suitable optical waveguide with a high Cₚₖ value in series production;
   to specify.

This task is solved by the independent claims. Further embodiments are the subject of subclaims.

Four exemplary applications of the proposed optical waveguide LWL) with a self-adjusting sensor element SE are:
the measurement of a magnetic field by means of a sensor head (first application example);
the measurement of a magnetic field in a motor (second application example);
use in a magnetic field camera as sensor layer 5 (third application example); and/or
use in a waveguide, in particular together with a magnetic field camera (fourth application example) for measuring physical quantities, such as unknown signal frequencies ωₙₖ and/or absolute values of magnetic flux densities and/or current values of electric currents in lines (B 1330) and/or temperatures and/or voltages and/or indirectly determinable quantities such as pressures and/or mechanical stresses and/or spatial coordinates and/or velocities and/or accelerations and/or gravitational accelerations and/or rotational velocities and/or angular positions and/or rotational accelerations and/or sound signals and/or ultrasonic signals and/or spectra.

However, the uses of the proposed optical waveguide LWL) with a self-adjusting sensor element SE are not limited to these application examples.

For the purposes of the present disclosure, an optical waveguide LWL is typically a dielectric waveguide of any shape. The optical waveguide LWL) may comprise one or more dielectric layers. In particular, the optical waveguide LWL) may comprise an optical waveguide core LWLC) as one such dielectric layer. Preferably, several dielectric layers of an optical waveguide LWL comprise different refractive indices and/or dielectric material constants ε of their material, so that reflection occurs at the interfaces between these dielectric layers of the respective optical waveguide LWL.

In the following, the document presented here describes the application of the proposed optical waveguide LWL) with a self-aligning sensor element SE in various application examples.

In particular, the present document describes as a first application example the use of the proposed optical waveguide LWL) in a sensor head SK.

In particular, the present document describes, as a second application example, the use of the proposed optical waveguide LWL) in an electric motor, in particular for controlling the commutation of this motor. Since a four-quadrant operation of the motor is to be included, the use of this motor as a generator of electrical energy is included in the term motor in the sense of the document presented here.

For such and other applications of the proposed optical waveguide with a self-aligning sensor element SE with similar measurement tasks, the document presented here proposes an optical waveguide LWL) with a self-aligning sensor element SE and a method for its fabrication.

The sensor element SE comprises a substrate material TM in which a multiplicity of diamonds DM are embedded. One or more or all diamonds DM of these diamonds DM comprise one or more NV centers NVZ and/or one or more other paramagnetic centers. The NV centers NVZ of the sensor element SE and/or the other paramagnetic centers of the sensor element SE emit at least one fluorescence radiation FL upon exposure to pump radiation LB. The special feature of the optical waveguide proposed in the document presented here is that the substrate material TM is a substrate material TM cured by means of electromagnetic radiation and that, after curing, the substrate material TM is essentially transparent to radiation with a pump radiation wavelength λₚₘₚ of the pump radiation LB with which the NV centers NVZ and/or the other paramagnetic centers are pumped. Essentially means that the losses that undoubtedly occur are still so small that the functionality of the application in question is still ensured. In the same way, the substrate material TM should be essentially transparent for radiation with a fluorescence wavelength λ_{fl} of the fluorescence radiation LB of the NV centers. Essentially means again that the losses that undoubtedly occur are still so small that the functionality of the application in question is still given. By curing a previously liquid carrier medium TM, the production of such an optical waveguide LWL) is particularly easy and process-reliable with a high Cₚₖ value.

As a first exemplary application, the paper presented here proposes a device for detecting the magnetic flux density B in the vicinity of a disturbance of a ferromagnetic surface.

As a second exemplary application example, the paper presented here proposes a device for detecting the magnetic flux density B in an air gap LS and/or in the stray field BSTR of the air gap LS of a motor.

In a sensor head of the proposed type according to the first application example, the task is solved according to the proposal in that:
the sensor head uses NV-rich diamond dust as a magnetic field sensor and
permanent magnets or coils (AC or DC magnetic fields) of the sensor head generate a magnetic test field that penetrates the surface of the workpiece, and
the diamond material of the diamond stub forms the sensor element at one fiber end of an optical waveguide and
the sensor head enables purely optical measurement of the magnetic field and thus the magnetic properties of the workpiece surface via the optical waveguide.

In a motor of the proposed type according to the second application example, the motor comprises a housing (GHR, GH).

Furthermore, the devices of the application examples of the technical teaching presented here, in this case the motor and the sensor head SK, each comprise a sensor element SE with a carrier medium TM. Preferably, a multiplicity of diamonds DM are embedded in the carrier medium TM. Preferably, the substrate material TM comprises glass and/or a cured plastic and/or another optical transparent material. The substrate material TM fixes the diamonds DM and prevents repositioning of the diamonds DM. Preferably, after solidification in the manufacturing process, the substrate material TM is transparent to electromagnetic radiation with the pump radiation wavelength λ(LB) of the pump radiation LB for the paramagnetic centers and/or NV centers NVZ in the diamonds DM in order to enable pumping of these paramagnetic centers and/or NV centers. Preferably, after solidification in the manufacturing process, the substrate material TM is transparent to electromagnetic radiation with the fluorescence wavelength λ_{fl} of the fluorescence radiation FL of the paramagnetic centers and/or the NV centers NVZ in the diamonds DM in the diamonds DM. One or more or all of the diamonds DM of these diamonds DM typically comprise paramagnetic centers and/or NV centers NVZ.

In the first application example, the magnetic flux density B acts on the paramagnetic centers and/or NV centers NVZ of the sensor element SE. In the second application example, the motor according to the proposal preferably comprises a rotor and a stator. An air gap LS separates the rotor from the stator. The rotor is mounted to rotate about an axis AX relative to the stator. The magnetic flux density B in the air gap LS and/or in the stray field BSTR of the air gap LS of the motor on the paramagnetic centers and/or NV centers NVZ. Typically, an increasing absolute value of the magnetic flux density B causes a reduction in the intensity of the fluorescence radiation FL.

In the first application example, the sensor head SK preferably has an optical waveguide LWL) for the access of pump radiation LB from a pump radiation source PL to the sensor element SE.

In the second application example, the housing GH of the motor preferably has a first opening OF for the access of pump radiation LB from a pump radiation source PL to the sensor element SE.

When using NV centers in diamond as paramagnetic centers of the sensor element SE, the pump radiation LB preferably comprises a pump radiation wavelength λₚₘₚ in a wavelength range of 400 nm to 700 nm and/or better 450 nm to 650 nm and/or better 500 nm to 550 nm and/or better 515 nm to 540 nm. A wavelength of 532 nm is clearly preferred as the pump radiation wavelength λₚₘₚ. In the case of NV centers in diamond or in diamonds, a laser diode of the type PLT5 520B from Osram, for example, is suitable as pump radiation source PL1 with 520 nm pump radiation wavelength λ₍ₚₘₚ₎. The NV centers NVZ of the sensor element SE typically emit fluorescence radiation FL with a typical fluorescence wavelength λ_{fl} of approx. 637 nm for NV centers when exposed to pump radiation LB of the pump radiation wavelength λₚₘₚ described above. Other wavelengths can be achieved by plasmonic coupling with metallic nano crystals in the substrate material TM. The optical properties of paramagnetic centers in the sensor element SE, in this case the NV centers NVZ, can be modified by combining the nano-diamonds or diamonds DM or crystals in the substrate material TM with metallic nanoparticles.

In the first application example, a second optical waveguide LWL) preferably transports the fluorescence radiation FL from the sensor element SE to a photo detector PD.

In the second application example, the housing GH of the motor preferably comprises a second opening OF for the exit fluorescence radiation FL of the sensor element SE towards a photo detector PD.

The proposed device also preferably comprises a partial device, in particular a dichroitic mirror F1, to separate the fluorescence radiation FL from the pump radiation LB, so that essentially only fluorescence radiation FL and, if possible, no pump radiation LB falls on the photo detector PD in the. This partial device in the form of a filter F1 or dichroitic mirror allows the passage of radiation with the fluorescence wavelength λ_{fl} of the fluorescence radiation FL—e.g. 637 nm for NV centers NVZ with a phonon sideband of 637 nm to 850 nm—in the direction of the photo detector PD, while it does not allow the passage of radiation with the pump radiation wavelength λₚₘₚ of the pump radiation wavelength LB of the pump radiation source PL and thus the modulated pump radiation LB or guides it so that it does not hit or influence the photo detector PD. The photo detector PD converts the intensity signal of the fluorescence radiation FL into a receiver output signal S0.

In the first application example, the device evaluates the receiver output signal S0 to obtain information on the distortion of the magnetic field B of a permanent magnet PM by cracks RI and/or recesses in the surface of a ferromagnetic material FM. In the first application example, the proposed device then has the advantage that the magnetic field of the cracks RI and/or recesses in the surface of a ferromagnetic material FM is not disturbed by feed lines as, for example, in magnetic field measurement with Hall sensors. Furthermore, the sensor element SE is completely diamagnetic. Due to the galvanic isolation, it is very unlikely that the magnetic fields and/or interference fields will affect the evaluation electronics of the sensor system via the sensor element SE and the optical waveguide LWL). This means that the system can also be used in high-voltage systems with device parts that are driven by very high voltages. Systems from the state of the art do not demonstrate this.

In the second application example, the device evaluates the receiver output signal S0 to obtain information about the position of the magnetic field B in the motor or to obtain information comprising this information about the position of the magnetic field B in the motor. The proposed device in the second application example has the advantage that the magnetic field of the motor is not disturbed by feed lines, such as in the case of magnetic field measurement with Hall sensors. Furthermore, the sensor element is completely diamagnetic. Due to the galvanic isolation, it is very unlikely that the motor fields will the evaluation electronics of the sensor system via the sensor element and the optical waveguide (LWL). This means that the system can also be used in high-voltage systems with motors that are driven by very high voltages. The system is also suitable for generators in power stations. Systems from the state of the art do not demonstrate this. For example, a system is known from DE 10 2020 129 367 A1 in which it is intended to position the evaluation electronics directly on the stator. during the development of the proposal presented here in this document, it was recognized that the technical teaching of DE 10 2020 129 367 A1 is susceptible to EMC interference and causes a problem with galvanic isolation and temperature stress. The proposal presented here does not have these problems.

In a first variant in the second application example, paramagnetic centers and/or NV centers NVZ of the sensor element SE are preferably located not only in the stray field of the air gap, but in the air gap LS of the motor itself. This enables a better signal and more precise measured values with less interference.

In a second variant of the device according to the proposal, the diamonds DM in the substrate material TM are oriented essentially differently from one another, each with an essentially different orientation. This has the essential and quite massive manufacturing advantage that an alignment of the diamonds DM is no longer necessary and that the manufacturing process for the fabrication of the sensor element SE can, for example, use diamond powder with a very large number of very small diamonds DM. A sensor element SE with such a disordered multiplicity of diamonds DM has the advantage that the measurement of the magnetic flux density B is isotropic. This means that the sensor element SE only detects the absolute value of the magnetic flux density B, but not the direction.

In the first application example, this has the advantage that it is no longer necessary to align the sensor element SE and the optical waveguide LWL and the sensor head SK.

In the second application example, this has the advantage that it is no longer necessary to align the sensor element SE and the optical waveguide LWL) in the motor.

The assembly of such a sensor element SE can be carried out by auxiliary personnel or low-precision mechanical devices, which in the first application example only have to insert the sensor element SE with the optical waveguide LWL, for example, into the channel KN of the sensor head SK and which in the second application example only have to insert the sensor element SE with the optical waveguide LWL, for example, into an opening OF provided for this purpose on the motor.

This reduces the manufacturing costs for devices that use the proposed optical waveguide LWL), such as the sensor head SK in the first application example and the motor in the second application example. In order to achieve spatial isotropy, it is therefore advantageous if the orientation of the diamonds DM is stochastically essentially uniformly distributed.

In the course of developing the technical teaching of this document, the applicant has recognized that it is also advantageous, in accordance with the preceding explanations, if in the first application example the sensor element SE is located in the stray field BSTR of the magnetic field of the permanent magnet PM. Instead of a permanent magnet, other field excitations are conceivable. For the purposes of the document presented here, these are comprised by the description “permanent magnet PM”.

In the course of developing the technical teaching of this document, the applicant has recognized that it is also advantageous, in accordance with the preceding explanations, if in the second application example the sensor element SE is located in the air gap LS or in the stray field BSTR of the air gap LS of the motor.

In order to minimize the number of optical waveguides LWL and to keep the modifications to the device using the proposed optical waveguide LWL, here exemplified by the sensor head SK or the motor, to a minimum, it is advantageous to use a single optical waveguide LWL for the supply of the pump radiation LB from the pump radiation source PL to the sensor element SE and for the return of the fluorescence radiation FL from the sensor element SE to the photo detector PD.

In the case of a single optical waveguide LWL, only a single channel KN is necessary for mounting the optical waveguide LWL in the first application example of the sensor head SK, so that the first channel KN is then identical to the second channel KN. The following text then refers to such a channel KN as a common channel KN.

In the case of a single optical waveguide LWL, only a single opening OF is necessary for mounting the optical waveguide LWL in the second application example of the motor, so that the first opening OF is then identical to the second opening OF. The following text then refers to such an opening OF as a common opening OF.

Thus, the device according to the proposal, here exemplified by the sensor head SK and the motor, preferably comprises a sensor element SE with a multiplicity of diamonds DM with paramagnetic centers and/or NV centers NVZ in a substrate material TM and a first optical waveguide LWL, to which the sensor element SE is attached, wherein the optical waveguide LWL transports the pump radiation LB of the pump radiation source PL to the sensor element SE, so that the pump radiation LB exposes the sensor element SE and the paramagnetic centers and/or NV centers NVZ emit fluorescence radiation FL, which the optical waveguide LWL detects and transports back in the direction of the photo detector PD.

In the first application example of the sensor head SK, the optical waveguide LWL) can be inserted parallel to the contact surface AF of the sensor head SK, with the sensor element SE then preferably being located in the stray field of the cracks RI and/or recesses in the surface of a ferromagnetic material FM. However, the optical waveguide LWL) can also be inserted into the sensor head SK perpendicular to the contact surface AF of the sensor head SK by means of a vertical channel and advanced in the vicinity of the contact surface AF, so that the sensor element SE then detects the magnetic flux density B in the stray field of the cracks RI and/or recesses in the surface of the ferromagnetic material FM. The sensor element SE can also be advanced to the immediate vicinity of the contact surface AF of the sensor head SK, but the problem then arises that the probability of damage during measurement operation of the sensor head SK increases due to movement along the contact surface AF of the sensor head SK.

In the second application example of the motor, the optical waveguide LWL) can be inserted parallel to the axis AX of the motor, in which case the sensor element SE is preferably located in the stray field of the air gap LS. However, the optical waveguide LWL) can also be inserted perpendicular to the axis of rotation AX by means of a hole in the laminated core of the stator between the grooves in which the rods of the stator coils SL are inserted and advanced up to the air gap, so that the sensor element SE then detects the magnetic flux density B in a stator coil SL. The sensor element SE can also be advanced as far as the air gap, but then the problem arises that the probability of damage during operation of the motor increases due to movement or vibration of moving components of the motor or different thermal expansion coefficients.

If the fluorescence radiation FL is to be fed back from the sensor element SE to the photo detector PD separately from the pump radiation LB being fed to the sensor element SE, in this case the device according to the proposal, in this case for example the sensor head SK or the motor, preferably comprises a second optical waveguide LWL), which detects the fluorescence radiation FL of the sensor element SE and transports the fluorescence radiation FL in the direction of the photo detector PD.

As explained above, however, the first optical waveguide LWL is preferably identical to the second optical waveguide LWL. In the following, the document presented here refers to such an optical waveguide LWL as common optical waveguide LWL. Such a common optical waveguide LWL saves calibration effort and reduces assembly complexity and saves material and is therefore advantageous. In particular, the necessary modifications to the device according to the proposal, here exemplarily to the sensor head SK or m motor, are themselves reduced.

The first optical waveguide LWL) comprises a first end and a second end.

The second optical waveguide LWL also comprises a first end and a second end. The common optical waveguide LWL also comprises a first end and a second end.

The present document now proposes to attach the sensor element SE to the first end of the first optical waveguide LWL and/or to the first end of the second optical waveguide LWL and/or to the first end of the common optical waveguide LWL in order to stabilize the optical coupling between the optical waveguide LWL and the sensor element SE.

If the first end of the first and/or the second or the common optical waveguide LWL) is now encased by the substrate material TM of the sensor element SE, this results in particularly good stabilization of this optical coupling.

Preferably, a first end surface EF1 of the first end of the first and/or the second or if the common optical waveguide LWL forms a first planar end surface EF1. Preferably, a first end surface EF1 of the first end of the first and/or the second or the common optical waveguide LWL forms a first planar end surface EF1 perpendicular to the centerline ML of the optical waveguide LWL. The centerline ML typically corresponds to the optical axis of the optical waveguide LWL). The optical waveguide LWL) may also comprise a shape. Such a flat first end surface EF1 enables improved decoupling of the electromagnetic pump radiation LB from the optical waveguide LWL and improved optical coupling of the fluorescence radiation FL into the optical waveguide LWL. Preferably, the distance of one or preferably more diamonds DM from this first planar end face EF1 is smaller than the pump radiation wavelength λₚₘₚ and/or better than ½ of the pump radiation wavelength λₚₘₚ, and/or better than ¼ of the pump radiation wavelength λₚₘₚ, and/or better than ⅛ of the pump radiation wavelength λₚₘₚ, and/or better than 1/10 of the pump radiation wavelength pmp, and/or better than 1/20 of the pump radiation wavelength λₚₘₚ, and/or better than 1/50 of the pump radiation wavelength λₚₘₚ, and/or better than 1/100 of the pump radiation wavelength λₚₘₚ, and/or better than 1/200 of the pump radiation wavelength λₚₘₚ, and/or better than 1/500 of the pump radiation wavelength λₚₘₚ, and/or better than 1/1000 of the pump radiation wavelength λₚₘ

The center line ML, which is an imaginary auxiliary construction to clarify the facts, pierces the first end face EF1 at a center point MP of the first end face EF1. In the case of an elongated optical waveguide LWL with an optical waveguide core LWLC, for example a glass fiber and/or a gradient glass fiber and/or a single-mode glass fiber, the thickness dl of the substrate material TM is preferably thicker at this midpoint MP than the thickness dr at other points of the first end face EF1 of the first end of the first and/or the second or the common optical waveguide LWL. This has the advantage that light is reflected back into the optical waveguide LWL) through the substrate material TM/air interface and that the efficiency and effectiveness then increase. This requirement can be met particularly easily by a self-adjusting sensor element SE. A manufacturing method for such a sensor element SE, as disclosed in the document presented here, typically fulfills this requirement in a particularly simple and cost-effective manner. In the case of an elongated optical waveguide LWL with an optical waveguide core LWLC), for example an optical fiber and/or a graded glass fiber and/or a step index or graded index fiber and/or a single mode glass fiber and/or an optical waveguide based on a photonic crystal, the fulfillment of this requirement ensures that, firstly, the pump radiation LB is optimally coupled out of the optical waveguide core LWLC of the optical waveguide LWL into the substrate material TM of the sensor element SE and thus into the crystals embedded in the substrate material TM, in particular the diamonds DM, in particular the diamond nano crystals, which preferably comprise the paramagnetic centers and/or NV centers,

Preferably, therefore, the substrate material TM forms a lens LWLL at the first end ELWL1 of a fibrous and/or cylindrical and elongated optical waveguide LWL. The diameter DLWLL of the lens LWLL is typically smaller than the diameter DLWL of such a fibrous and/or cylindrical and elongated optical waveguide LWL. However, the diameter DLWLL of the lens LWLL can also be as large as the diameter DLWL of such a fibrous and/or cylindrical and elongated optical waveguide LWL, which, however, is not optimal according to the experience gained during the elaboration of the technical teaching of the present document.

Preferably, the first optical waveguide LWL) is completely or partially encased by a mechanical sheath MH in the region of the application device, for example in the region of the sensor head SK and/or inside the sensor head SK in the case of the first application example and in the region of the motor and/or inside the motor in the case of the second application example. The mechanical sheath MH can have the purpose of mechanically protecting the first optical waveguide LWL) and/or shielding it from ambient light and/or shielding it from external magnetic and/or electromagnetic fields. The mechanical sheath MH can enclose the sensor element SE. This is advantageous in particular if the variable to be detected is generated within the mechanical sheath, for example in a micro-fluidic functional element.

Preferably, the second optical waveguide LWL) is also completely or partially sheathed by a second mechanical sheath MH in the region in the area of the application device, for example here in the region of the sensor head SK and/or inside the sensor head SK in the case of the first application example and in the region of the motor and/or inside the motor in the case of the second application example. The second mechanical sheath MH may have the purpose of mechanically protecting the second optical waveguide LWL) and/or shielding it from ambient light and/or shielding it from external magnetic and/or electromagnetic fields.

Preferably, the common optical waveguide LWL) in the region in the area of the application device, i.e. here for example in the case of the first application example in the region of the sensor head SK and/or within sensor head SK and in the case of the second application example in the region of the motor and/or within the motor, is completely or partially encased in the same way by a mechanical sheath MH.

The mechanical sheath MH typically supports the respective optical waveguide LWL) mechanically. The mechanical sheath MH typically supports and protects the respective optical waveguide LWL) against the harsh conditions inside and outside the application device, i.e. here in the first application example of the sensor head SK and in the second application example of the motor.

In thermally and/or chemically stressful environments within the application device, for example within the sensor head SK in the first application example and within the motor in the second example, the mechanical sheath MH should generally meet special requirements with regard to thermal and chemical stability against heat and operating fluids. The mechanical sheath MH is therefore preferably made of glass or ceramic or the like. Very preferably, the mechanical sheath comprises a mechanically flexible material, for example a fabric, for example a glass fabric.

The mechanical sheath MH therefore preferably has a ceramic material or another non-magnetizable and/or electrically non-conductive material and/or a material that is stable at temperatures above 100° C. and/or a material that is stable at temperatures above 140° C. and/or a material that is stable at temperatures above 170° C. and/or a material that is stable at temperatures above 200° C. and/or a material that is stable at temperatures above 250° C. or comprises these or consists of these in extreme cases. As a result, the respective application devices, here for example the sensor head in the first application example and the motor in the second application example, can also be used at high external and/or internal temperatures. In the case of the first application example of a sensor head SK, for example, this can relate to a high temperature of the ferromagnetic material FM. The mechanical sheath MH can therefore be made of a ceramic material or of another non-magnetizable and/or electrically non-conductive material and/or of a material that is stable at temperatures above 100° C. and/or of a material that is stable at temperatures above 140° C. and/or of a material that is stable at temperatures above 170° C. and/or of a material that is stable at temperatures above 200° C. and/or of a material that is stable at temperatures above 250° C.

Preferably, the mechanical sheath MH is at least in sections a tube or pipe or a capillary or a cannula, into which the respective optical waveguide LWL) can be inserted, for example. This simplifies the production of the system consisting of optical waveguide LWL), sensor element SE and mechanical sheath MH. The inner diameter Dro of such a tube or such a capillary or such a cannula is preferably only slightly larger than the diameter of the optical waveguide lens LWLL and the diameter DLWL of the optical waveguide LWL.

In order to minimize the access of extraneous light to the sensor element SE during operation, it is useful if the first gap between the edge of the access channel of the first optical waveguide LWL in the application device, in the first application example of a sensor head SK of the channel KN and in the second application example of a motor of the first opening OF, and the first optical waveguide LWL is completely or partially sealed with an optically opaque filling compound FM.

For the same reason, it is useful if the second gap between the edge of the access channel of the second optical waveguide LWL) in the application device, in the first application example of a sensor head SK of the channel KN and in the second application example of a motor of the first opening OF, and the second optical waveguide LWL is completely or partially sealed with an optically non-transparent filling compound FM and/or if the common gap between the edge of the access channel of the common optical waveguide LWL in the application device, in the first application example of a sensor head SK of the channel KN and in the second application example of a motor of the first opening OF, and the common optical waveguide LWL is completely or partially sealed with an optically essentially non-transparent filling compound FM. The common filling compound FM can fasten the respective optical waveguide to the housing of the application device, in the first application example of the sensor head SK and in the second application example of the motor.

Preferably, the device is configured to determine the temporal value profile of the intensity of the fluorescence radiation FL, in particular in the form of a receiver output signal S0. Furthermore, the device is preferably configured to determine the time characteristic of the amplitude value of the time characteristic of the intensity of the fluorescence radiation FL from the time characteristic of the intensity of the fluorescence radiation FL, in particular from the receiver output signal S0 and in particular by means of a lock-in amplifier LIV or a functionally equivalent subdevice.

Finally, the device is preferably configured to carry out a display or other signaling as a function of the determined temporal course of the amplitude value of the temporal value course of the intensity of the fluorescence radiation FL, in order to enable higher-level systems and/or a user to intervene as a function of such a display or signaling.

In the case of the second application example of a motor, the device is preferably configured to control the electrical supply of coils of the motor, in particular of stator coils SL of the motor and/or the electrical supply of rotor coils of the motor, and in particular by means of a half-bridge control CTRH in interaction with half-bridges HB, as a function of the determined time characteristic of the amplitude value of the time characteristic of the intensity of the fluorescence radiation FL. This makes it possible to detect the magnetic field in the motor and control the motor without modifying the magnetic field of the motor with cables etc. and without problems with galvanic isolation.

In the case of the second application example of a motor, the motor typically comprises n motor phases (MPH_{U}, MPH_{V}, MPH_{W}) with n as a positive integer greater than 2. In the examples in the figures, the exemplary motor comprises n=3 motor phases. The device energizes each of these motor phases (MPH_{U}, MPH_{V}, MPH_{W}) by means of half-bridges HB with a respective associated motor phase current (I_{MPHU}, I_{MPHV}, I_{MPHW}). Typically, the half-bridge control CTRH modulates the half-bridges HB with a respective pulse-modulated control signal, which it generates individually for each motor phase. These motor phase currents (I_{MPHU}, I_{MPHV}, I_{MPHW}) are typically periodic, at least in terms of time, with a period T. Preferably, a current angle (φ_{MPHU}, φ_{MPHV}, φ_{MPHW}) is assigned to each of the motor phase currents (I_{MPHU}, I_{MPHV}, I_{(MPH)(W)}). The motor phase currents can always be arranged in the form of a sequence of motor phase currents (I_{MPHU}, I_{MPHV}, I_{MPHW}) in such a way that the current angle of a preceding motor phase current differs from the current angle of the following motor phase current by 2π/n. This means that each motor phase current is assigned a motor phase current vector whose orientation corresponds to the current angle of the motor phase current and whose length corresponds to the absolute value of the motor phase current.

Preferably, the device according to the proposal is configured, in particular by means of a high-pass filter or a functionally equivalent filter, to determine an alternating component and/or a direct component of the temporal course of the amplitude value of the temporal value course of the intensity of the fluorescence radiation FL from the temporal course of the amplitude value of the temporal value course of the intensity of the fluorescence radiation FL.

For example, in the second application example of a motor, only this alternating component and in particular its zero crossings enable the commutation of the current supply of the motor to be controlled by means of a half-bridge based on the intensity of the fluorescence radiation of the sensor element SE with the NV centers NVZ.

Preferably, the application device in the second application example of a motor is configured to determine, in particular by means of a second low pass TP2, a low-frequency DC component in the temporal course of the amplitude value of the temporal value course of the intensity of the fluorescence radiation FL. This DC component can be used by the device to monitor the sensor element SE and the optical path and detect deviations from expected values. For this purpose, the device compares the value of the DC component with an expected value interval. If the value of the DC component is outside the expected value interval, the device preferably indicates a fault and triggers appropriate measures. One such measure can be, for example, that the half-bridge control CTRH transmits a signal via an external data bus EXTDB to a higher-level computer system, which then initiates everything else.

Preferably, the application device comprises, in the second application example of a motor, the half-bridge control CTRH, a computer core with a non-volatile memory, a typically volatile read/write memory, a reset circuit, a clock generator with a clock system, which in the second application example of a motor is used to supply the half-bridge control with an operating clock, a data bus interface to external data bus EXTDB, an internal data bus for the data connection of these components and a power supply and, if necessary, other usual processor components. In the second application example, the exemplary application device preferably comprises, for example, an interface for controlling the half-bridges for controlling the motor. Preferably, the power supply also supplies the other device components with electrical energy from a positive and a negative supply voltage line. Preferably, the power supply also deploys the reference potential line GND.

Preferably, the computer core of the application device executes an application program whose program code is located in one of these memories of the application device. This application program can emulate parts of the signal processing components described herein. For example, this application program may emulate the high pass filters and/or low pass filters and/or synchronous demodulators and/or functionally equivalent implementations thereof described herein.

Preferably, the device is configured to separate this low-frequency DC component in the time characteristic of the amplitude value of the time characteristic of the intensity of the fluorescence radiation FL from the time characteristic of the amplitude value of the time characteristic of the intensity of the fluorescence radiation FL and thus to determine the alternating component of the time characteristic of the amplitude value of the time characteristic of the intensity of the fluorescence radiation FL. In the case of the second application example of a motor, the application device can in this way provide a signal that is suitable for controlling the commutation of the half-bridges in the exemplary application device in the second application example of a motor.

An exemplary application of the proposed optical waveguide LWL) of the first application example of a sensor head SK is the measurement of a magnetic field of a ferromagnetic material FM.

Preferably, in the case of the second application example of a motor, the application device is therefore configured to detect a zero crossing of the alternating component of the time characteristic of the amplitude value of the time characteristic of the intensity of the fluorescence radiation FL. The detection of the zero crossing has the advantage that fluctuations in the amplitude of the signal etc. are insignificant for the zero crossing. Such a signal is therefore more suitable for controlling the commutation of a motor.

Furthermore, in the case of the second application example of a motor, the application device is preferably configured to carry out a commutation of the electrical supply of coils of the motor, in particular of stator coils SL of the motor, and/or the electrical supply of rotor coils of the motor, and in particular by means of a half-bridge control CTRH in cooperation with half-bridges HB, in a temporal relationship with the determined zero crossing of the alternating component of the temporal course of the amplitude value of the temporal value course of the intensity of the fluorescence radiation FL.

Finally, in the case of the second application example of a motor, the application device is preferably configured for this purpose;
1. to determine one or more voltage values of one or more motor phase voltages (V_{MPHU}, V_{MPHV}, V_{MPHW}) of one or more motor phases (MPH_{U}, MPH_{V}, MPH_{W}) of the motor phases MPH against one or more motor phases (MPH_{U}, MPH_{V}, MPH_{W}) of the motor phases MPH which are different from this motor phase and/or against a reference potential GND, and
2. to determine one or more current values of one or more motor phase currents (I_{MPHU}, I_{MPHV}, I_{MPHW}) of one or more motor phases (MPH_{U}, MPH_{V}, MPH_{W}) of the motor phases MPH and/or
3. one or more sum current values of one or more sum currents of several motor phase currents (I_{MPHU}, I_{MPHV}, I_{MPHW}) of several motor phases (MPH_{U}, MPH_{V}, MPH_{W}) of the motor phases MPH, in particular a neutral point current from a neutral point of coils of the motor to a reference node or a reference potential node GND,
   to determine.

As a result, in the case of the second application example of a motor, the application device is preferably configured to determine information about the zero crossing of the alternating component of the time characteristic of the amplitude value of the time value characteristic of the intensity of the fluorescence radiation FL as a first control parameter on the one hand.

Furthermore, in the case of the second application example of a motor, the application device is preferably configured for this purpose;
1. with the one voltage value of a motor phase voltage of the motor phase voltages (V_{MPHU}, V_{MPHV}, V_{MPHW}) of a motor phase of the motor phases (MPH_{U}, MPH_{V}, MPH_{W}) and/or
2. with several voltage values of the several voltage values of motor phase voltages (V_{MPHU}, V_{MPHV}, V_{MPHW}) of several motor phases (MPH_{U}, MPH_{V}, MPH_{W}) and/or
3. with the one current value of a motor phase current of the motor phase currents (I_{MPHU}, I_{MPHV}, I_{MPHW}) of a motor phase of the motor phases (MPH_{U}, MPH_{V}, MPH_{W}) and/or
4. with several current values of the current values of several motor phase currents of the motor phase currents (I_{MPHU}, I_{MPHV}, I_{MPHW}) of several motor phases of the motor phases (MPH_{U}, MPH_{V}, MPH_{W}) and/or
5. with the one sum current value of a sum current of several motor phase currents of the motor phase currents (I_{MPHU}, I_{MPHV}, I_{MPHW}) of several motor phases of the motor phases (MPH_{U}, MPH_{V}, MPH_{W}) and/or
6. with several sum current values of several sum currents of several sum currents of several motor phase currents of several motor phase currents (I_{MPHU}, I_{MPHV}, I_{MPHW}) of several motor phases of the motor phases (MPH_{U}, MPH_{V}, MPH_{W}) as the second control parameter on the other hand with the first control parameter.

In the case of the second application example of a motor, the application device is preferably configured to change the point in time of the commutation of the current supply to coils of the motor, in particular to stator coils SL and/or in particular to rotor coils of the motor, as a function of the first control parameter and of such a second control parameter.

Preferably, in the case of the second application example of a motor, the application device is also configured to use the first control parameter and the second control parameter to infer a position of the magnetic field with the flux density B in the air gap (LS) of the motor relative to one or more motor phase current vectors of the motor phase currents (I_{MPHU}, I_{MPHV}, I_{MPHW}) and to determine a spatial angular value of the angle between the position of the sensor element as reference position on the one hand and the direction of one or more motor phase current vectors of the motor phase currents (I_{MPHU}, I_{MPHV}, I_{MPHW}) at the point in time of the zero crossing of the alternating component of the temporal course of the amplitude value of the temporal value course of the intensity of the fluorescence radiation FL on the other hand.

In addition, sensor fusion makes sense here.

Preferably, in the case of the second example application of a motor, proposed application device comprises a position sensor POS. Preferably, the device is configured to determine position information POSS by means of this position sensor POS and to combine information about the zero crossing of the alternating component of the time characteristic of the amplitude value of the time value characteristic of the intensity of the fluorescence radiation FL as a first control parameter on the one hand with the position information as a second control parameter on the other hand. In this case, the application device of the second application example of a motor is preferably configured to determine the point in time of the commutation of the current supply of coils of the motor, in particular of stator coils SL and/or in particular of rotor coils, as a function of the first control parameter and of such a second control parameter in order, in particular, to infer the position of the magnetic field B in the air gap (LS) relative to one or more motor phase current vectors of the motor phase currents (I_{MPHU}, I_{MPHV}, I_{MPHW}).

In another variant, the application device of the second application example of a motor is preferably configured to use the first control parameter and the second control parameter to infer a position of the magnetic field with the flux density B in the air gap LS of the motor relative to the position of the rotor (GHR, PM, RMK). In another variant, the application device of the second application example of a motor is thus preferably configured to then determine a spatial angular value of the angle between the position of the sensor element as reference position on the one hand and the spatial position of the rotor at the point in time of the zero crossing of the alternating component of the temporal course of the amplitude value of the temporal value course of the intensity of the fluorescence radiation FL on the other hand.

However, the applications of the technical teaching presented here are not limited to this. The document presented here an optical waveguide LWL) with the sensor element SE for such and other applications with similar measurement tasks. The sensor element SE comprises a substrate material TM in which a multiplicity of diamonds DM are embedded. One or more or all diamonds DM of these diamonds DM comprise one or more NV centers NVZ and/or one or more other paramagnetic centers. The NV centers NVZ of the sensor element SE and/or the other paramagnetic centers of the sensor element SE emit at least one fluorescence radiation FL upon exposure to pump radiation LB.

The special feature of the optical waveguide LWL proposed in the document presented here is that the substrate material TM is preferably a substrate material TM cured by means of electromagnetic radiation and that, after curing, the substrate material TM is essentially transparent to radiation with a pump radiation wavelength λ_{TM} of the pump radiation LB with which the NV centers NVZ and/or the other paramagnetic centers are pumped. Essentially means that the losses that undoubtedly occur are still so small that the functionality of the device of the application in question is still given. In the same way, the substrate material TM should be essentially transparent for radiation with a fluorescence wavelength λ_{FL} of the fluorescence radiation LB of the NV centers NVZ or paramagnetic centers. Essentially means again that the losses that undoubtedly occur are still so small that the functionality of the device of the application in question is still given.

As a first application example, the document presented here proposes a device for detecting the magnetic flux density B in a channel KN of a sensor head SK and/or in the stray field BSTR of a permanent magnet PM of the sensor head SK. The sensor head SK of the first application example preferably comprises a sensor element SE with a carrier medium TM.

According to the technical teaching of the document presented here, a multiplicity of diamonds or nano-diamonds DM and/or crystals are preferably embedded in the carrier medium TM of a sensor element SE according to the proposal. Preferably, the substrate material TM comprises glass and/or a cured plastic. The substrate material TM fixes the diamonds DM and/or crystals relative to the first end ELWL1 of the optical waveguide LWL and prevents repositioning of the diamonds DM and/or crystals. Preferably, after solidification in the manufacturing process, the substrate material TM is essentially transparent for radiation with the pump radiation wavelength λₚₘₚ of the pump radiation LB and for radiation with the fluorescence wavelength λ_{fl} of the fluorescence radiation FL of the NV centers NVZ or paramagnetic centers in the diamonds DM or nano-diamonds and/or crystals. One or more or all of the diamonds or nano-diamonds DM and/or crystals of these diamonds or nano-diamonds DM and/or crystals typically comprise NV centers NVZ and/or paramagnetic centers.

In an exemplary variant of the application device of the first application example of a sensor head SK, the magnetic flux density B in the stray field BSTR of the magnetic field of the exemplary permanent magnet PM on the NV centers NVZ or the paramagnetic centers in the sensor element SE of the sensor head SK.

Typically, the magnetic flux density B, which penetrates the substrate material TM of the sensor head with the paramagnetic centers and/or NV centers NVZ, causes a reduction in the intensity of the fluorescence radiation FL of the NV centers NVZ and/or paramagnetic centers in the sensor element SE.

In an exemplary variant of the application device of the first application example of a sensor head SK, the sensor head housing GH preferably has a first channel KN for supplying pump radiation LB from the pump radiation source PL to the sensor element SE via an optical waveguide LWL) or via a similar optical system.

In an exemplary variant of the application device of the second application example of a motor, the housing GH of the motor preferably has a first opening OF for the supply of pump radiation LB from the pump radiation source PL to the sensor element SE via an optical waveguide LWL) or via a similar optical system.

In the case of NV centers in dimant as paramagnetic centers within the substrate material TM of the sensor element SE, the pump radiation LB preferably comprises a pump radiation wavelength λₚₘₚ in a wavelength range of 400 nm to 700 nm and/or better 450 nm to 650 nm and/or better 500 nm to 550 nm and/or better 515 nm to 540 nm. A wavelength of 532 nm is clearly preferred as the pump radiation wavelength λₚₘₚ. In the case of NV centers in diamond or in diamonds as paramagnetic centers within the substrate material TM of the sensor element SE, a laser diode of the type PLT5 520B from Osram, for example, is suitable as a pump radiation source PL with 520 nm pump radiation wavelength λ₍ₚₘₚ₎. The NV centers NVZ of the sensor element SE then typically emit fluorescence radiation FL with a typical fluorescence wavelength λ_{fl} of approx. 637 nm for NV centers NVZ when exposed to pump radiation LB of the pump radiation wavelength λₚₘₚ described above.

Other wavelengths can be achieved by plasmonic coupling with additional metallic nano crystals embedded in the substrate material TM. The optical properties of the NV centers NVZ or paramagnetic centers in the sensor element SE can be modified by combining the nano-diamonds or diamonds DM in the substrate material TM of the sensor element SE with metallic nanoparticles.

In an exemplary variant of the application device of the first application example of a sensor head SK, the sensor head housing GH preferably comprises a second channel KN for the exit fluorescence radiation FL of the sensor element SE towards a photo detector PD.

In an exemplary variant of the application device of the second application example of a motor, the housing GH of the motor preferably comprises a second channel KN for the emission of fluorescence radiation FL of the sensor element SE towards a photo detector PD.

The proposed device also preferably comprises a partial device, in particular a dichroitic mirror F1 and/or a filter F1, to separate the fluorescence radiation FL from the pump radiation LB, so that essentially only fluorescence radiation FL and preferably no pump radiation LB is incident on the photo detector PD. This partial device in the form of a filter F1 or dichroitic mirror preferably allows the passage of radiation with the fluorescence wavelength λ_{fl} of the fluorescence radiation FL—e.g. 637 nm for NV centers NVZ with a phonon sideband of 637 nm to 850 nm for NV centers NVZ—in the direction of the photo detector PD, while it does not allow the passage of radiation with the pump radiation wavelength λₚₘₚ of the pump radiation source PL (LB) and thus the modulated pump radiation LB or guides it so that it does not hit or influence the photo detector PD. The photo detector PD converts the intensity signal of the fluorescence radiation FL into a receiver output signal S0. The device evaluates the receiver output signal S0,

In the case of the application device of the first application example of a sensor head SK, the application device can evaluate the receiver output signal S0 to obtain information about the values of magnetic material parameters of the material at the surface OF of a workpiece and/or to obtain information comprising this information. Preferably, the material of the workpiece in the vicinity of the surface OF comprises a ferromagnetic material FMM.

In the case of the application device of the second application example of a motor, the application device may evaluate the receiver output signal S0 to obtain information about the rotor position and/or the actual position of the magnetic field in the air gap LS of the motor and/or the state of the motor and/or its driving device and/or its mechanical load (i.e. the applied torque) and/or obtain information comprising this information.

The proposed device has the advantage that the magnetic field in the application device, i.e. in the first application example the magnetic field of the permanent magnet PM and the ferromagnetic material FM of the workpiece and in the second application example the magnetic field in the air gap LS of the motor, is not disturbed by supply lines as, for example, in the magnetic field measurement with Hall sensors.

Furthermore, the sensor element SE is completely diamagnetic. A feedback effect of fields within the application device and/or from the environment of the application device on the evaluation electronics of the sensor system via the sensor element SE and the sensor head SK and the optical waveguide LWL) is very unlikely due to the galvanic isolation.

In the case of an application device of the first application example of a sensor head SK, a feedback effect of fields within the sensor head SK and/or from the environment of the sensor head SK—for example the workpiece—on the evaluation electronics of the sensor system via the sensor element SE and the sensor head SK and the optical waveguide LWL) is very unlikely due to the galvanic isolation.

In the case of an application device of the second application example of a motor, feedback from fields within the motor and/or from the environment of the motor—for example from rotor or stator voltages and currents—to the evaluation electronics of the sensor system via the sensor element SE and the sensor head SK and the optical waveguide LWL) is very unlikely due to the galvanic isolation.

This means that the system can also be used in application devices in high-voltage subassemblies that are at a very high electrical potential.

For example, in an application device of the first application example of a sensor head SK, the system can also be used in high-voltage systems with workpieces that are at very high electrical potential.

For example, in an application device of the second application example of a motor, the system can also be used in high-voltage systems motor components that are at very high electrical potential.

These are essential advantages of a proposed sensor element SE. The small size that can be achieved with simultaneous positioning precision is particularly advantageous.

It is also conceivable that the application device, e.g. the sensor head SK or the motor, and/or the environment of the application device, e.g. the workpiece or the environment of the motor, are very hot or very cold compared to the operating conditions of semiconductors. A temperature range of 0° C. to 80° C. is possible. With the appropriate design of the sensor head, the optical waveguide LWL), the mechanical sheath MH, the substrate material TM and the material of the sensor head housing GH, temperatures of up to 700° C. and up to absolute zero are conceivable for the workpiece and the ferromagnetic material FM. Prior art systems do not demonstrate this

Preferably, NV centers NVZ or the paramagnetic centers of the sensor element SE are not located in the stray field BSTR of the permanent magnet PM in the first application example of a sensor head SK and not in the stray field BSTR of the air gap LS in the second application example of a motor.

Preferably, the diamonds or nano-diamonds DM and/or crystals in the substrate material TM are oriented essentially differently from one another with an essentially different orientation in each case. This has the manufacturing advantage that an alignment of the diamonds or nano-diamonds DM and/or crystals is no longer necessary and that the manufacturing process for the fabrication of the sensor element SE can use, for example, diamond powder and/or crystal powder with a very large number of very small diamonds or nano-diamonds DM and/or crystals.

A sensor element SE with such a disordered multiplicity of diamonds or nano-diamonds DM and/or such a disordered multiplicity of crystals has the advantage that the measurement of the magnetic flux density B is isotropic.

This means that the sensor element SE only detects the absolute value of the magnetic flux density B, but not the direction. This has the advantage that it is no longer necessary to align the sensor element SE and the optical waveguide LWL) in the sensor head SK. The assembly of such a sensor element SE can be carried out by assistants or less precise mechanical devices, which only have to insert the sensor element SE with the optical waveguide LWL) into a channel KN provided for this purpose in the sensor head housing GH and fasten it there, for example by means of bonding or screwing. This drastically reduces the manufacturing costs for such a sensor head SK. The Cpk value of a series production based on such a manufacturing process increases dramatically, which enables correspondingly low cost items. In order to achieve spatial isotropy, it is therefore advantageous if the orientation of the diamonds or nano-diamonds DM and/or crystals is stochastically distributed essentially uniformly in the sensor element SE.

In the course of developing the technical teaching of this document, the applicant has recognized that it can also be advantageous, in accordance with the preceding explanations, if the sensor element SE is nevertheless located in the stray field BSTR of the permanent magnet PM in certain special cases in the first application example of a sensor head SK and in the second application example of a motor in the stray field BSTR of the air gap LS.

In order to minimize the number of optical waveguides LWL and to keep the modifications to the application device, here in the first application example on the sensor head SK and in the second application example of a motor on the motor, to a minimum, it is advantageous to use a single optical waveguide LWL for the supply of the pump radiation LB from the pump radiation source PL to the sensor element SE and for the return of the fluorescence radiation FL from the sensor element SE to the photo detector PD.

In this case, only a single channel KN or only a single opening OF in the application device, here in the first application example in the sensor head SK and in the second application example of a motor in the motor, is necessary for mounting the optical waveguide LWL) in the housing GH of the application device, here in the first application example in the sensor head housing GH and in the second application example in the housing GH of the motor, so that the first channel KN is then identical to the second channel KN or the first opening OF and the second opening OF are identical. The following text then designates such a channel KN as a common channel KN and such an opening OF as a common opening OF.

Thus, the application device according to the proposal, in the first application example the sensor head SK according to the proposal and in the second application example the motor, comprises a sensor element SE with a multiplicity of diamonds or nano-diamonds DM and/or crystals with NV centers NVZ and/or other paramagnetic centers in a substrate material TM and a first optical waveguide LWL to which the sensor element SE is attached. The optical waveguide LWL transports the pump radiation LB of the pump radiation source PL to the sensor element SE, so that the pump radiation LB exposes the sensor element SE and the NV centers NVZ or the paramagnetic centers of the sensor element SE emit fluorescence radiation FL. The optical waveguide LWL) detects this fluorescence radiation FL transports the fluorescence radiation FL back towards the photo detector PD.

In the application device of the first application example of a sensor head SK, the optical waveguide LWL) can be inserted parallel or perpendicular to the axis AX of the permanent magnet PM in the sensor head SK, whereby the sensor element SE is then preferably located in the stray field BSTR of the permanent magnet PM.

In the application device of the second application example of a motor, the optical waveguide LWL) can be inserted parallel or perpendicular to the axis AX of the motor in the air gap LS of the motor, whereby the sensor element SE is then preferably located in the stray field BSTR in the air gap LS of the motor.

If the fluorescence radiation FL is to be fed back from the sensor element SE to the photo detector PD separately from the pump radiation LB being fed to the sensor element SE, in this case the application device, in the first application example of a sensor head SK the sensor head SK in the second application example of a motor the motor, preferably comprises a second optical waveguide LWL), which detects the fluorescence radiation FL of the sensor element SE and transports the fluorescence radiation FL in the direction of the photo detector PD.

As explained above, however, the first optical waveguide LWL is preferably identical to the second optical waveguide LWL. In the following, the document presented here refers to such an optical waveguide LWL as a common optical waveguide LWL. Such a common optical waveguide LWL saves calibration effort and reduces assembly complexity and saves material and is therefore advantageous.

In particular, a common optical waveguide LWL) reduces the necessary modifications to the application device, in the first application example of a sensor head SK to the sensor head SK in the second application example of a motor to the motor.

The first optical waveguide LWL comprises a first end ELWL1 and a second end ELWL2. The second optical waveguide LWL also comprises a first end ELWL1 and a second end ELWL2). The common optical waveguide LWL also a first end ELWL1 and a second end ELWL2.

The present document now proposes to attach the sensor element SE to the first end ELWL1 of the first optical waveguide LWL and/or the second optical waveguide LWL or the common optical waveguide LWL in order to stabilize the optical coupling between the optical waveguide LWL and the sensor element SE.

An optical waveguide LWL) within the meaning of this document may comprise the shape of a cylinder, in particular an elongated cylinder such as that of an optical fiber, or a polyhedron or a parallelepiped or a cuboid or a prism or any other geometric shape.

In the sense of the document presented here, the first end ELWL1 of an optical waveguide LWL comprises an end surface EF, which is a partial surface of the outer surface of the optical waveguide LWL, from which the pump radiation LB emerges into the substrate material TM of the sensor element SE and/or into which the fluorescence radiation FL of the paramagnetic centers and/or NV centers NVZ of the diamonds or nano-diamonds and/or crystals of the substrate material TM enters the optical waveguide LWL.

In the sense of the document presented here, the second end ELWL2 of an optical waveguide LWL comprises an end surface EF, which is a partial surface of the outer surface of the optical waveguide LWL, into which the pump radiation LB enters the optical waveguide LWL and/or from which the fluorescence radiation FL of the paramagnetic centers and/or NV centers NVZ of the diamonds or nano-diamonds and/or crystals of the substrate material TM emerges again from the optical waveguide LWL.

The second end ELWL2 of an optical waveguide LWL and the first end ELWL1 of an optical waveguide LWL do not necessarily comprise end faces EF aligned plane-parallel to each other. Optical functional elements of the optical waveguide LWL can redirect the light appropriately within the optical waveguide LWL.

Such optical functional elements may comprise reflective outer surfaces of the optical waveguide and/or micro-optical functional elements such as microlenses and/or holographic structures, in particular reflective holographic structures and/or diffusers and/or digital optical functional elements such as Fresnel lenses, etc. Preferably, these optical and micro-optical functional elements are located on partial surfaces of the optical waveguide LWL).

If, for example, the first end ELWL1 of the first and/or the second or the common optical waveguide LWL) is encased by the substrate material TM of the sensor element SE, this results in particularly good stabilization of this optical coupling.

Preferably, in the case of an elongated optical waveguide, the end surface EF of the first end ELWL1 of the first and/or the second or the common optical waveguide LWL forms a planar end surface EF perpendicular to the centerline ML of the optical waveguide LWL. The centerline ML typically corresponds to the optical axis of the optical waveguide LWL).

Such a flat end surface EF in the case of an elongated optical waveguide enables improved decoupling of the electromagnetic pump radiation LB from the optical waveguide LWL and improved optical coupling of the fluorescence radiation FL into the optical waveguide LWL. Preferably, the distance of one or preferably more diamonds or λ nano-diamonds DM and/or one or more crystals in the substrate material TM of the sensor element SE from this planar end face EF is smaller than the pump radiation wavelength λₚₘₚ and/or better than ½ of the pump radiation wavelength λₚₘₚ, and/or better than ¼ of the pump radiation wavelength λₚₘₚ, and/or better than ⅛ of the ₚᵤₘₚ radiation wavelength λ(pmp), and/or better than 1/10 of the _{pump radiation wavelength (pmp)}, and/or better than 1/20 of the pump radiation wavelength λₚₘₚ, better than 1/50 of the pump radiation wavelength λₚₘₚ, and/or better than 1/100 of the pump radiation wavelength λₚₘₚ, and/or better than 1/200 of the pump radiation wavelength λₚₘₚ, and/or better than 1/500 of the pump radiation wavelength λₚₘₚ, and/or better than 1/1000 of the pump radiation wavelength λₚₘₚ.

In the case of an elongated optical waveguide LWL, the center line ML, which is an imaginary auxiliary construction for clarifying the facts, pierces the end face EF at a center point MP of the end face EF. The thickness dₗ of the substrate material TM is preferably thicker at this center point MP than the thickness dᵣ at other points of the end face EF of the first end of the first and/or the second or the common optical waveguide LWL) in the case of an elongated optical waveguide LWL. This has the advantage that, in the case of an elongated optical waveguide LWL, light is reflected back into the optical waveguide LWL through the substrate material TM/air interface and that the efficiency and effectiveness then increase.

Preferably, therefore, in the case of an elongated optical waveguide LWL, the substrate material TM forms a lens LWLL at the first end ELWL1 of the optical waveguide LWL. The diameter D_{LWLL} of the lens LWLL is typically smaller than the diameter D_{LWL} of the optical waveguide LWL in the case of an elongated optical waveguide LWL. However, the diameter D_{LWLL} of the lens LWLL can also be as large as the diameter D_{LWL} of the optical waveguide LWL in the case of an elongated optical waveguide LWL, but this is not optimal according to the experience gained during the elaboration of the technical teaching of this document.

Preferably, in the case of an elongated first optical waveguide LWL, the first optical waveguide LWL is completely or partially sheathed by a mechanical sheath MH in the region of the sensor head SK and/or within the sensor head SK. Preferably, in the case of an elongated second optical waveguide LWL, the second optical waveguide LWL in the region of the application device, in the case of the first application example of the sensor head SK and in the case of the second application example of the motor, and/or within the application device is also completely or partially sheathed by a mechanical sheath MH.

Preferably, the common optical waveguide LWL) in the region of the application device, in the case of the first application example of the sensor head SK and in the case of the second application example of the motor, and/or within the application device is completely or partially encased in the same way by a mechanical sheath MH. The mechanical sheath MH supports and protects the respective optical waveguide LWL) against the harsh conditions of the respective measurement situation.

The mechanical sheath MH within the application device, in the case of the first application example of the sensor head SK and in the case of the second application example of the motor, must meet the respective special requirements with regard to thermal and chemical stability against heat and operating fluids. The mechanical sheath MH is therefore preferably made of glass fabric or ceramic or plastic or the like in the case of an elongated, fiber-shaped optical waveguide.

The mechanical sheath MH therefore preferably has a ceramic material or another non-magnetizable and/or electrically non-conductive material and/or a material that is stable at temperatures above 100° C. and/or a material that is stable at temperatures above 140° C. and/or a material that is stable at temperatures above 170° C. and/or a material that is stable at temperatures above 200° C. and/or a material that is stable at temperatures above 250° C., or comprises these or consists of these in extreme cases. The mechanical sheath MH can thus be made of a ceramic material or of another non-magnetizable and/or electrically non-conductive material and/or of a material stable at temperatures above 100° C. and/or of a material stable at temperatures above 140° C. and/or of a material stable at temperatures above 170° C. and/or of a material stable at temperatures above 200° C. and/or of a material stable at temperatures above 250° C. or comprise the same.

In the case of a fiber-shaped optical waveguide LWL, the mechanical sheath MH is preferably a tube or pipe or a capillary or a cannula or a hose, at least in sections, into which the respective optical waveguide LWL is inserted. This simplifies the production of the system consisting of optical waveguide LWL, sensor element SE and mechanical sheath MH. The inner diameter Dro of such a tube or such a capillary or such a cannula or such a hose is preferably only a little larger than the diameter of the optical waveguide lens LWLL and the diameter DLWL of the optical waveguide LWL.

In order minimize the access of extraneous light to the sensor element SE during operation, it is useful if the first gap between the edge of the first channel KN or the edge of the first opening OF and the first optical waveguide LWL in the case of a fiber-shaped first optical waveguide LWL is closed completely or partially or in sections with an optically non-transparent filling compound. For the same reason, it is useful if the second gap between the edge of the second channel KN or the edge of the second opening OF and the second optical waveguide LWL in the case of a fiber-shaped second optical waveguide LWL is completely or partially sealed or partially sealed in sections with an optically non-transparent filling compound and/or if the common gap between the edge of the common channel KN or the edge of the common opening OF and the edge of the second opening OF is completely or partially sealed or partially sealed in sections with an optically non-transparent filling compound and/or if the common gap between the edge of the common channel KN or the edge of the common opening OF and the edge of the second opening OF is completely or partially sealed or partially sealed in sections with an optically non-transparent filling compound and/or if the common gap between the edge of the common channel KN or the edge of the common opening OF and the edge of the second opening OF is completely or partially sealed with an optically non-transparent filling compound, the edge of the common opening OF and the common optical waveguide LWL in the case of a fiber-shaped common optical waveguide LWL is completely or partially or partially closed with an optical, essentially non-transparent filling compound. The common filling compound can fasten the respective optical waveguide LWL in the respective channel KN and/or the respective opening OF of the housing of the application device, in the first application example of the sensor head housing GH and in the second application example of the housing GH of the motor.

Preferably, the device is configured to determine the temporal value profile of the intensity of the fluorescence radiation FL, in particular in the form of a receiver output signal S0. Furthermore, the device is preferably configured to determine the time characteristic of the amplitude value of the time characteristic of the intensity of the fluorescence radiation FL from the time characteristic of the intensity of the fluorescence radiation FL, in particular from the receiver output signal S0 and in particular by means of a lock-in amplifier LIV or a functionally equivalent subdevice.

Here, the sensor element SE preferably comprises a substrate material TM in which a multiplicity of diamonds or nano-diamonds DM and/or crystals are embedded. One or more or all diamonds or nano-diamonds DM of these diamonds DM and/or one or more crystals of these crystals comprise one or more NV centers NVZ and/or one or more other paramagnetic centers. The NV centers NVZ of the sensor element SE and/or the other paramagnetic centers of the sensor element SE emit at least one fluorescence radiation FL upon exposure to pump radiation LB.

The special feature of the optical waveguide LWL proposed in the document presented here is that the substrate material TM is preferably a substrate material TM cured by means of electromagnetic radiation and that, after curing, the substrate material TM is essentially transparent to radiation with a pump radiation wavelength λ_{TM} of the pump radiation LB with which the NV centers NVZ and/or the other paramagnetic centers are pumped. Essentially means that the losses that undoubtedly occur are still so small that the functionality of the application in question is still ensured. In the same way, the substrate material TM should be essentially transparent for radiation with a fluorescence wavelength λ_{fl} of the fluorescence radiation LB of the NV centers or the paramagnetic centers. Essentially means that the losses that undoubtedly occur are still so small that the functionality of the application in question is still ensured. By curing a previously liquid carrier medium TM, the production of such an optical waveguide LWL) is particularly easy and process-reliable with a high Cₚₖ value.

In one variant of the optical waveguide, the diamonds or nano-diamonds DM and/or crystals in the substrate material TM are oriented essentially differently with respect to one another, each with an essentially different orientation. This has the advantage that the sensor element behaves isotropically and shows no preferred direction. The mixture of different diamond crystals homogenizes the measurement results and improves the Cₚₖ value.

For the same reason, it is advantageous if the orientation of the diamonds or nano-diamonds DM and/or crystals is essentially stochastically uniformly distributed in the substrate material TM.

Preferably, the optical waveguide LWL is configured or intended to transport pump radiation LB from the pump radiation source PL to the sensor element SE, so that the pump radiation LB exposes the sensor element SE to radiation of the pump radiation wavelength λ₍ₚₘₚ₎.

The optical waveguide LWL) is preferably also configured or intended to fluorescence radiation FL from the sensor element SE and to transport the fluorescence radiation FL in the direction of a photo detector PD.

The proposed optical waveguide LWL again preferably comprises a first end ELWL1 and a second end ELWL2. The substrate material TM preferably forms the sensor element SE and attaches this sensor element SE to the first end ELWL1 of the optical waveguide LWL.

In the case of an elongated, in particular fiber-shaped optical waveguide LWL, the substrate material TM of the sensor element SE preferably encases the first end ELWL1 of the optical waveguide LWL. This improves the mechanical connection between the optical waveguide LWL) and the sensor element SE.

Preferably, in the case of an elongated, in particular fiber-shaped optical waveguide LWL, an end surface EF of the first end ELWL1) of the optical waveguide LWL forms a flat end surface EF perpendicular to the center line ML of the optical waveguide LWL. This improves the coupling of electromagnetic radiation from the core LWLC) of the optical waveguide LWL into the sensor element SE and vice versa.

In the case of an elongated, in particular fiber-shaped optical waveguide LWL, the imaginary virtual center line ML of the optical waveguide LWL pierces the end face EF of the optical waveguide LWL at the first end ELWL1 of the optical waveguide LWL at a midpoint MP of the end face EF of the optical waveguide LWL. Preferably, the thickness dₗ of the substrate material TM at this center point MP is thicker than the thickness dᵣ at other points of the end face EF of the first end ELWL1 of the optical waveguide LWL. As a result, an optical functional element is formed at the first end ELWL1) of the optical waveguide LWL. This improves the coupling of electromagnetic radiation from the core LWLC) of the optical waveguide LWL into the sensor element SE and vice versa.

Preferably, therefore, the substrate material TM at the first end ELWL1 of the optical waveguide LWL forms a lens LWLL in the case of an elongated, in particular fiber-shaped optical waveguide LWL, the diameter D_{LWLL} of which is preferably smaller than the diameter D_{LWL} of the optical waveguide LWL or as large as the diameter D_{LWL} of the optical waveguide LWL. This reduces the measuring volume of the sensor element and thus increases the spatial resolution of magnetic measurements. Thus, in the first application example of a sensor head SK, the method presented here can then detect particularly small cracks RI in the surface OF of the material of the workpiece by means of the proposed device.

Preferably, in the case of an elongated, in particular fiber-shaped first optical waveguide LWL, the first optical waveguide LWL is completely or partially sheathed by a first mechanical sheath MH. Preferably, the mechanical sheath MH comprises a ceramic material or another non-magnetizable and/or electrically non-conductive material and/or a material that is stable at temperatures above 100° C. and/or a material that is stable at temperatures above 140° C. and/or a material that is stable at temperatures above 170° C. and/or a material that is stable at temperatures above 200° C. and/or a material that is stable at temperatures above 250° C. or comprises such a material. This protects the sensor element SE and the optical waveguide LWL) from damage. Preferably, the mechanical sheath MH is made of a ceramic material or of another non-magnetizable and/or electrically non-conductive material and/or of a material that is stable at temperatures above 100° C. and/or of a material that is stable at temperatures above 140° C. and/or of a material that is stable at temperatures above 170° C. and/or of a material that is stable at temperatures above 200° C. and/or of a material that is stable at temperatures above 250° C.

For better processing and assembly, in the case of an elongated, in particular fiber-shaped optical waveguide (LWL), the mechanical sheath MH preferably comprises at least in sections a tube or pipe or a capillary or a cannula or a hose, in particular a fabric hose.

The fluorescence radiation of the NV centers NVZ and/or the other paramagnetic centers in the diamonds or the nano-diamonds DM and/or the crystals of the substrate material TM and, in particular, the fluorescence wavelength λ_{fl} of their fluorescence radiation FL can, for example, be modified by means of plasmonic coupling by metallic nanoparticles which are also added to the substrate material TM. In this case, for example, the substrate material TM can comprise metallic nanoparticles with a diameter of less than 200 nm and/or less than 100 nm and/or less than 50 nm and/or less than 20 nm and/or less than 10 nm and/or less than 5 nm, which are later embedded in the solidified substrate material TM. This improves the applicability in special applications.

The metallic nanoparticles then typically interact plasmonically with diamonds or nano-diamonds DM and/or crystals in the substrate material TM and thus influence the fluorescence radiation FL of these diamonds DM and/or crystals.

These metallic nanoparticles typically have gold and/or platinum and/or palladium and/or graphite and/or graphene and/or chromium and/or silicon and/or germanium and/or tin and/or sulfur and/or selenium and/or tellurium and/or magnesium and/or calcium and/or strontium and/or barium and/or titanium and/or zirconium and/or hafnium and/or chromium and/or molybdenum and/or tungsten and/or iron and/or ruthenium and/or osmium and/or nickel and/or tin and/or cadmium and/or mercury and/or cerium and/or neodymium and/or samarium and/or gadolinium and/or dysprosium and/or erbium and/or ytterbium and/or thorium and/or proactinium and/or uranium and/or plutonium. Whereby the former are particularly preferred.

The atoms of the metal of the nanoparticles comprise one or more elements of the periodic table. Each of these elements occurs in different isotopes in nature with a respective natural isotope mixing ratio. Each isotope of an element comprises a natural proportion corresponding to the natural isotope mixing ratio of this element. With regard to these proportions and the values, the document presented here refers to the German patent application DE 10 2020 125 178 A1 of the applicant. These isotopes each comprise a magnetic nuclear moment u or not, depending on the isotope. Preferably, the metallic nanoparticles have an increased proportion in the isotope mixing ratio for at least one element comprised by the metallic nanoparticles compared to the natural proportion of the isotope mixing ratio for at least one of the following isotopes: ¹²C, ¹⁴C, ²⁸Si, ³⁰Si, ⁷⁰Ge, ⁷²Ge, ⁷⁴Ge, ⁷⁶Ge, ¹¹²Zn, ¹¹⁴Zn, ¹¹⁶Zn, ¹¹⁸Zn, ¹²⁰Zn, ¹²²Zn, ¹²⁴Zn, ¹⁶O, ¹⁸O, ³²S, ³⁴S, ³⁶S, ⁷⁴Se, ⁷⁶Se, ⁷⁸Se, ⁸⁰Se, ⁸²Se, ¹²⁰Te, ¹²²Te, ¹²⁴Te, ¹²⁶Te, ¹²⁸Te, ¹³⁰Te, ²⁴Mg, ²⁶Mg, ⁴⁰Ca, ⁴²Ca, ⁴⁴Ca, ⁴⁶Ca, ⁴⁸Ca, ⁸⁴Sr, ⁸⁶Sr, ⁸⁸Sr, ¹³⁰Ba, ¹³²Ba, ¹³⁴Ba, ¹³⁶Ba, ¹³⁸Ba, ⁴⁶Ti, ⁴⁸Ti, ⁵⁰Ti, ⁹⁰Zr, ⁹⁰Zr, ⁹²Zr, ⁹⁴Zr, ⁹⁶Zr, ¹⁷⁴Hf, ¹⁷⁶Hf, ¹⁷⁸Hf, ⁵⁰Cr, ⁵²Cr, ⁵³Cr, ⁹²Mo, ⁹⁴Mo, ⁹⁶Mo, ⁹⁸Mo, ¹⁰⁰Mo, ¹⁸⁰W, ¹⁸²W, ¹⁸⁴W, ¹⁸⁶W, ⁵⁴Fe, ⁵⁶Fe, ⁵⁸Fe, ⁹⁶Ru, ⁹⁸Ru, ¹⁰⁰Ru, ¹⁰²Ru, ¹⁰⁴Ru, ¹⁸⁴Os, ¹⁸⁶Os, ¹⁸⁸Os, ¹⁹⁰Os, ¹⁹²Os, ⁵⁸Ni, ⁶⁰Ni, ⁶²Ni, ⁶⁴Ni, ¹⁰²Pd, ¹⁰²Pd, ¹⁰⁴Pd, ¹⁰⁶Pd, ¹⁰⁸Pd, ¹¹⁰Pd, ¹⁹⁰Pt, ¹⁹²Pt, ¹⁹⁴Pt, ¹⁹⁶Pt, ¹⁹⁸Pt, ⁶⁴Zn, ⁶⁶Zn, ⁶⁸Zn, ⁷⁰Zn, ¹⁰⁶Cd, ¹⁰⁸Cd, ¹¹⁰Cd, ¹¹²Cd, ¹¹⁴Cd, ¹¹⁶Cd, ¹⁹⁶Hg, ¹⁹⁸Hg, ²⁰⁰Hg, ²⁰²Hg, ²⁰⁴Hg, ¹³⁶Ce, ¹³⁸Ce, ¹⁴⁰Ce, ¹⁴²Ce, ¹⁴²Nd, ¹⁴⁴Nd, ¹⁴⁶Nd, ¹⁴⁸Nd, ¹⁵⁰Nd, ¹⁴⁴Sm, ¹⁴⁶Sm, ¹⁴⁸Sm, ¹⁵⁰Sm, ¹⁵²Sm, ¹⁵⁴Sm, ¹⁵²Gd, ¹⁵⁴Gd, ¹⁵⁶Gd, ¹⁵⁸Gd, ¹⁶⁰Gd, ¹⁵⁶Dy, ¹⁵⁸Dy, ¹⁶⁰Dy, ¹⁶²Dy, ¹⁶⁴Dy, ¹⁶²Er, ¹⁶⁴Er, ¹⁶⁶Er, ¹⁶⁸Er, ¹⁷⁰Er, ¹⁶⁸Yb, ¹⁷⁰Yb, ¹⁷²Yb, ¹⁷⁴Yb, ¹⁷⁶Yb, ²³²Th, ²³⁴Pa, ²³⁴U, ²³⁸U, ²⁴⁴Pu.

The optical waveguide LWL) may comprise an optical waveguide core LWLC). In the substrate material TM, the substrate material TM preferably forms an optical functional element at the first end ELWL1 of the optical waveguide LWL. This again improves said optical coupling between optical waveguide LWL and substrate material TM. The optical functional element then interacts optically with the optical waveguide core LWLC) of the optical waveguide LWL at the first end ELWL1 of the optical waveguide LWL.

Preferably, the optical functional element comprises an optical fiber lens LWLL, in particular in the form of a thickening of the substrate material TM in the region of the optical functional element.

Now, the essential feature of the present document is that it also describes and discloses a method for the fabrication of an optical waveguide LWL) as previously described and used. The proposed method comprises the steps of:
deployment 140 of an optical waveguide LWL, wherein the optical waveguide LWL comprises a first end ELWL1 and a second end ELWL2 wherein the optical waveguide LWL is transparent for electromagnetic radiation of the pump radiation wavelength λₚₘₚ of the pump radiation LB and/or for electromagnetic radiation of the fluorescence radiation wavelength λ_{fl} of the fluorescence radiation LB and for electromagnetic radiation of a curing wavelength λ_{H} of the substrate material TM of the sensor element SE;
deployment 142 of a liquid substrate material TM which is curable by means of electromagnetic radiation of a curing wavelength λ_{H}, wherein a multiplicity of diamonds DM, preferably nano-diamonds, and/or crystals are embedded in the substrate material TM and wherein one or more or all diamonds DM of these diamonds DM and/or one or more crystals of these crystals have NV centers NVC and/or other paramagnetic centers and wherein the NV centers NVC and/or other paramagnetic centers are embedded in the substrate material TM, and/or crystals are embedded in the substrate material TM and wherein one or more or all diamonds DM of these diamonds DM and/or one or more crystals of these crystals comprise NV centers NVZ and/or other paramagnetic centers and wherein the NV centers NVZ of the diamonds DM and/or crystals of the substrate material TM and/or the other paramagnetic centers of the diamonds DM and/or crystals of the substrate material TM emit at least one fluorescence radiation FL upon exposure to pump radiation LB;
wetting 145 of the first end of the optical waveguide TM, in particular to a wetting length LDM, with the substrate material TM comprising the multiplicity of embedded diamonds DM and/or crystals;
if necessary, pre-baking 147 (pre-bake) of the sensor element SE by means of a preceding temperature treatment.
injecting 150 electromagnetic radiation into the second end of the optical waveguide LWL, the wavelength of this electromagnetic radiation, the curing wavelength λ_{H}, being selected such that the substrate material TM at the second end of the optical waveguide LWL hardens and transforms into a solid.
removal 160 of the uncured substrate material TM, in particular by means of a solvent, the remaining film of the substrate material TM forming the sensor element SE at the first end of the optical waveguide LWL.
if necessary, post-baking 165 (post-bake) of the sensor element SE by subsequent temperature treatment.

Typically, the substrate material TM only partially hardens, which enables the formation of the optical functional elements.

The electromagnetic radiation with the curing wavelength λ_{H} comprises a penetration depth into the substrate material TM, so that the substrate material TM cures only up to a thickness dₗ of the substrate material and thus forms the optical functional element, which was first recognized as a surprising and advantageous procedure during the elaboration of the technical teaching of this paper.

The radiation fed into the second end ELWL2 of the optical waveguide LWL for curing is preferably UV radiation. A radiation for curing with a curing wavelength λ_{H} between 320-380 nm is particularly preferred.

In certain applications, nanoparticles with a diameter smaller than 200 nm and/or smaller than 100 nm and/or smaller than 50 nm and/or smaller than 20 nm and/or smaller than 10 nm and/or smaller than 5 nm can be added to the substrate material TM before deployment, so that these are embedded in the substrate material TM after curing. Preferably, these are metallic nanoparticles.

Such metallic nanoparticles interact with diamonds or nano-diamonds DM and/or crystals in the substrate material TM and can, for example, influence the fluorescence radiation FL of these diamonds or nano-diamonds DM and/or crystals.

The metallic nanoparticles comprise, for example, gold and/or platinum and/or palladium and/or graphite and/or graphene and/or chromium and/or silicon and/or germanium and/or tin and/or sulfur and/or selenium and/or tellurium and/or magnesium and/or calcium and/or strontium and/or barium and/or titanium and/or zirconium and/or hafnium and/or chromium and/or molybdenum and/or tungsten and/or iron and/or ruthenium and/or osmium and/or nickel and/or tin and/or cadmium and/or mercury and/or cerium and/or neodymium and/or samarium and/or gadolinium and/or dysprosium and/or erbium and/or ytterbium and/or thorium and/or proactinium and/or uranium and/or plutonium and/or mixtures thereof.

The atoms of the metal of the nanoparticles naturally comprised one or more elements of the periodic table of elements. Each of these elements occurs in different isotopes in nature with a respective natural isotope mixing ratio. Each isotope has a natural proportion in nature corresponding to the natural isotope mixing ratio. These isotopes may comprise a magnetic nuclear moment u or not, depending on the isotope. For at least one element comprising the metallic nanoparticles, the metallic nanoparticles have an increased proportion in the isotope mixing ratio compared to the natural proportion of the isotope mixing ratio for at least one of the following isotopes: ¹²C, ¹⁴C, ²⁸Si, ³⁰Si, ⁷⁰Ge, ⁷²Ge, ⁷⁴Ge, ⁷⁶Ge, ¹¹²Zn, ¹¹⁴Zn, ¹¹⁶Zn, ¹¹⁸Zn, ¹²⁰Zn, ¹²²Zn, ¹²⁴Zn, ¹⁶O, ¹⁸O, ³²S, ³⁴S, ³⁶S, ⁷⁴Se, ⁷⁶Se, ⁷⁸Se, ⁸⁰Se, ⁸²Se, ¹²⁰Te, ¹²²Te, ¹²⁴Te, ¹²⁶Te, ¹²⁸Te, ¹³⁰Te, ²⁴Mg, ²⁶Mg, ⁴⁰Ca, ⁴²Ca, ⁴⁴Ca, ⁴⁶Ca, ⁴⁸Ca, ⁸⁴Sr, ⁸⁶Sr, ⁸⁸Sr, ¹³⁰Ba, ¹³²Ba, ¹³⁴Ba, ¹³⁶Ba, ¹³⁸Ba, ⁴⁶Ti, ⁴⁸Ti, ⁵⁰Ti, ⁹⁰Zr, ⁹⁰Zr, ⁹²Zr, ⁹⁴Zr, ⁹⁶Zr, ¹⁷⁴Hf, ¹⁷⁶Hf, ¹⁷⁸Hf, ⁵⁰Cr, ⁵²Cr, ⁵³Cr, ⁹²Mo, ⁹⁴Mo, ⁹⁶Mo, ⁹⁸Mo, ¹⁰⁰Mo, ¹⁸⁰W, ¹⁸²W, ¹⁸⁴W, ¹⁸⁶W, ⁵⁴Fe, ⁵⁶Fe, ⁵⁸Fe, ⁹⁶Ru, ⁹⁸Ru, ¹⁰⁰Ru, ¹⁰²Ru, ¹⁰⁴Ru, ¹⁸⁴Os. ¹⁸⁶Os, ¹⁸⁸Os, ¹⁹⁰Os, ¹⁹²Os, ⁵⁸Ni, ⁶⁰Ni, ⁶²Ni, ⁶⁴Ni, ¹⁰²Pd, ¹⁰²Pd, ¹⁰⁴Pd, ¹⁰⁶Pd, ¹⁰⁸Pd, ¹¹⁰Pd, ¹⁹⁰Pt, ¹⁹²Pt, ¹⁹⁴Pt, ¹⁹⁶Pt, ¹⁹⁸Pt, ⁶⁴Zn, ⁶⁶Zn, ⁶⁸Zn, ⁷⁰Zn, ¹⁰⁶Cd, ¹⁰⁸Cd, ¹¹⁰Cd, ¹¹²Cd, ¹¹⁴Cd, ¹¹⁶Cd, ¹⁹⁶Hg, ¹⁹⁸Hg, ²⁰⁰Hg, ²⁰²Hg, ²⁰⁴Hg, ¹³⁶Ce, ¹³⁸Ce, ¹⁴⁰Ce, ¹⁴²Ce, ¹⁴²Nd, ¹⁴⁴Nd, ¹⁴⁶Nd, ¹⁴⁸Nd, ¹⁵⁰Nd, ¹⁴⁴Sm, ¹⁴⁶Sm, ¹⁴⁸Sm, ¹⁵⁰Sm, ¹⁵²Sm, ¹⁵⁴Sm, ¹⁵²Gd, ¹⁵⁴Gd, ¹⁵⁶Gd, ¹⁵⁸Gd, ¹⁶⁰Gd, ¹⁵⁶Dy, ¹⁵⁸Dy, ¹⁶⁰Dy, ¹⁶²Dy, ¹⁶⁴Dy, ¹⁶²Er, ¹⁶⁴Er, ¹⁶⁶Er, ¹⁶⁸Er, ¹⁷⁰Er, ¹⁶⁸Yb, ¹⁷⁰Yb, ¹⁷²Yb, ¹⁷⁴Yb, ¹⁷⁶Yb, ²³²Th, ²³⁴Pa, ²³⁴U, ²³⁸U, ²⁴⁴Pu. For the purposes of this document, “increased” means that the proportion in the isotope mixing ratio of the above isotopes is increased by 50% or more.

The optical waveguide LWL) preferably comprises an optical waveguide core LWLC) in the case of a fibrous and/or elongated optical waveguide. The proposed method preferably forms an optical functional element LWLL at the first end ELWL1 of the optical waveguide LWL during curing with radiation of the curing wavelength λ_{H}, wherein the radiation of the curing wavelength λ_{H} is fed in via the second end ELWL2 of the optical waveguide LWL and supplied to the substrate material TM.

The optical functional element LWL thus formed can then interact optically with the optical waveguide core LWLC at the first end ELWL1 of the optical waveguide LWL when optical radiation, in particular pump radiation LB with the pump radiation wavelength λ₍ₚₘₚ₎, is fed in at the second end ELWL2 of the optical waveguide LWL.

The optical functional element then comprises an optical fiber lens (LWLL), in particular in the form of a thickening of the substrate material TM.

The document presented herein proposes as substrate material TM, for example, a clear, colorless, liquid photopolymer, such as Norland optical adhesive 61. Further information is available at the point in time of filing the document presented here at https://www.norlandprod.com/adhesives/noa%2061.html.

Norland Optical Adhesive 61 (“NOA 61”) is a clear, colorless, liquid photopolymer that cures under ultraviolet light. As it is a single component system with 100% solids, it offers many advantages for bonding applications where the adhesive may be exposed to UV light. The use of NOA 61 eliminates the need for premixing, drying or curing by heat, as is common with other adhesive systems. The curing time is short and depends on the thickness applied and the available UV light energy. It is particularly useful if the carrier medium meets TM Federal Specification MIL-A-3920 for optical adhesives. NOA 61 complies with Federal Specification MIL-A-3920 for optical adhesives. The substrate material TM should produce the best possible optical bond to glass surfaces, metals, glass fibers and glass-filled plastics. NOA61 fulfills this requirement. The use of a substrate material TM that is recommended for the bonding of lenses, prisms and mirrors for military, aerospace and commercial optics as well as for the termination and splicing of glass fibers is particularly advantageous. NOA61 fulfills these requirements.

The substrate material TM is also said to be characterized by excellent clarity, low shrinkage and light flexibility. These properties are important to enable the user to manufacture high quality sensor elements SE and achieve long-term performance under varying aggressive environmental conditions.

NOA 61 cures with ultraviolet light, as desired for the substrate material TM, with maximum absorption in the region of 320-380 nanometers for the curing wavelength λ_{H} and maximum sensitivity at 365 nm. The recommended energy for complete curing is 3 joules/cm² at these wavelengths. Curing is not inhibited by oxygen, so all areas in contact with air will cure to a non-tacky state when exposed to ultraviolet light.

In most optical applications, curing takes place in two steps. First, there is a short, uniform exposure, known as pre-bake. The curing time is long enough to solidify the joint and allow it to be moved without disturbing the alignment. This is followed by a longer cure under UV light to achieve complete cross-linking and solvent resistance of the adhesive. Curing can be accomplished in 10 seconds with a 100 watt mercury lamp at 6″. If a longer time is required for alignment, it can be extended to several minutes with a very low intensity light source. Final curing can be achieved in 5 to 10 minutes with the 100 watt mercury lamp.

Pre-baking allows the user to quickly align and fix the optical waveguide LWL) if required and minimizes the number of holding devices required. After pre-fixing, excess adhesive can be wiped off with a cloth moistened with alcohol or acetone as an example solvent. The optical waveguides (LWL) should be inspected at this point in time and rejects separated in methylene chloride. The coated region of the sensor elements SE must be soaked in the solvent and will normally dissolve overnight. The time required to dissolve the substrate material TM depends on the extent of curing and the size of the coating.

After curing, NOA 61 comprises very good adhesion and solvent resistance, but it has not yet reached its optimum adhesion to glass. This is achieved by ageing over a period of about 1 week, during which a chemical bond is formed between the glass and the adhesive. This optimum adhesion can also be achieved by ageing at 50° C. for 12 hours in a temperature cabinet.

NOA 61 can withstand temperatures from −15° C. to 60° C. before ageing when used to coat optical waveguide (LWL). After ageing, it can withstand temperatures from −150° C. to 125° C. As a coating on the surface of the optical waveguide, NOA 61 can withstand 260° C. for three hours and during reflow soldering. This means that the sensor element SE can be used for measuring the magnetic flux density B up to these temperatures. The document presented here therefore proposes the use of a proposed optical waveguide LWL) at temperatures above 100° C. and/or even above 110° C. and/or even above 120° C. and/or even above 130° C. and/or even above 140° C. and/or even above 150° C. and/or even above 160° C. and/or even above 170° C. and/or even above 180° C. and/or even above 190° C. and/or even above 200° C. and/or even above 210° C. and/or even above 220° C. and/or even above 230° C. and/or even above 240° C. and/or even above 250° C. and/or even above 260° C. NOA 61 is not suitable for higher temperatures. Other materials make sense here.

Typical properties of a carrier medium are a solids content of more than 80%, a viscosity at 25° C. of more than 250 cps, a refractive index of the cured substrate material TM of more than 1.2, an elongation at break of less than 50% or more than 25% depending on the application, a modulus of elasticity of less than (psi) 200,000, a tensile strength of more than (psi) 3,000 and a hardness of more than Shore D 60.

Typical properties of NOA 61 as an exemplary carrier medium are a solids content of 100%, a viscosity at 25° C. of 300 cps, a refractive index of the cured polymer of 1.56, an elongation at break of 38%, a modulus of elasticity of (psi) 150,000, a tensile strength of (psi) 3,000 and a hardness of Shore D 85.

### Advantage

The technical solution proposed in this document is characterized by the following advantages:
the sensor element SE is electrically isolated from the evaluation electronics of the respective application circuit;
the sensor element SE is thermally separated from the evaluation electronics of the respective application circuit;
the sensor element SE and its cable (LWL) are diamagnetic and do not influence the measurement;
the application devices (e.g. sensor head SK and motor) are not susceptible to electrostatic interference;
the sensor element SE can comprise a small measuring volume (fiber core diameter 9 μm to 1000 μm);
the thickness of the material of the substrate material TM with the diamonds DM and/or nano-diamonds and/or crystals with the paramagnetic centers and/or NV centers at the first end of the optical waveguide is variable;
the possible measuring frequency ranges from DC (0 Hz) to the MHz region same sensor for DC/AC field excitation; and
diamagnetic measuring head (sensor does not influence measurement)

Such a device, as described in the above description, makes it possible in the second application example of a motor to detect the magnetic field in the air gap of a motor without disturbing this magnetic field, without causing EMC problems and without causing problems with non-existent galvanic isolation. The installation space of such a solution is extremely small. The solution is robust against thermal and chemical requirements. It also works, for example, at 100° K and possibly down to 0° K.

### Third Application Example Magnetic Field Camera

The basic idea of the third application example described in this document is to detect the fluorescent light of a magnetic field-sensitive fluorescent layer as sensor element SE by means of an optical fluorescent light camera as a spatially resolving photo detector PD. The document presented here proposes to use diamond crystals as the fluorescent layer, preferably diamond nanocrystals in a substrate material as the material of the fluorescent layer. Instead of diamond crystals, other crystals that emit fluorescence radiation upon exposure to pump radiation can also be used alternatively or additionally. Unless expressly described otherwise, the reader may read along other crystals with functionally equivalent fluorescence features when diamonds are mentioned, and may read along other paramagnetic centers of functionally equivalent fluorescence features when NV centers are mentioned. In a particularly preferred embodiment, the diamond nanocrystals are HDNV diamonds. In this context, the document presented here refers to the prior art document cited above. (E.G. EN 10 2021 132 780 A1)

In connection with the proposed magnetic field camera, the present document proposes, as a third embodiment, exposure of the NV centers in the nano-diamonds of the fluorescent layer of the fluorescent layer to pump radiation having a pump radiation wavelength. This exposure of the nano-diamonds of the fluorescence layer to pump radiation excites the NV centers of the nano-diamonds of the fluorescence layer to emit fluorescence radiation with a fluorescence wavelength. Preferably, the substrate material in which the nano-diamonds are embedded is transparent for radiation of the pump radiation wavelength and for radiation of the fluorescence wavelength. The magnetic flux density B of the magnetic field to be measured penetrates the fluorescence layer. Typically, the penetration of the fluorescence layer by the magnetic flux density B is not homogeneous, but depends on the magnetizable bodies and the distribution of magnetic substances etc. in the vicinity of the fluorescence layer. Preferably, the orientation of the nano-diamonds is stochastically uniformly distributed, so that the fluorescence radiation of the NV centers of the nano-diamonds of the fluorescence layer does not depend on the direction of the magnetic flux density B, but only on the absolute value of the magnetic flux density B.

Typically, therefore, the fluorescence radiation intensity of the fluorescence radiation of the NV centers of the fluorescence layer depends on the location-dependent absolute value of the magnetic flux density at the location of the respective NV center in the fluorescence layer.

A fluorescence camera of the proposed magnetic field camera as a third embodiment detects the location-dependent intensity of the fluorescence radiation of the NV centers in a layer with paramagnetic centers in a multiplicity of crystals. For this purpose, the fluorescence camera preferably comprises a two-dimensional array of light sensors of a light sensor array that are sensitive to the electromagnetic radiation of the fluorescence wavelength. For example, the two-dimensional array of light sensors of the light sensor array of the fluorescence camera may comprise a CCD sensor array or a CMOS array or a SPAD array. If necessary, an evaluation circuit provides the light sensors with the required operating voltage. Typically, the light sensors generate a photocurrent and/or a photocharge, which is typically proportional to the received light intensity or at least depends on the respective received light intensity. The evaluation circuit detects the value of this photocurrent or photocharge and uses it to determine, pixel by pixel, a measured value for the intensity of the fluorescence radiation at the location of the fluorescence layer of the sensor layer, which the imaging optics of the fluorescence camera images onto the respective pixel. The fluorescence layer comprises crystals with paramagnetic centers that fluoresce depending on the magnetic flux density B and the intensity of the pump radiation with which they are exposed. In this way, the fluorescence camera can determine the value of the magnetic flux density per pixel of the photo detector array, which corresponds to a region of the fluorescence layer assigned to this pixel.

The disclosure uses the combination of diamond dust and UV Adhesive and the know-how from measurements of magnetic fields by fiber-coupled measurement of the fluorescence of NV-rich diamond powder. The document presented here refers in this context to the unpublished German patent application DE 10 2022 122 505.4.

NV-containing diamond dust (any size, but should preferably be in the region of 100 nm-2 μm particles) applied to a substrate material in combination with an optically transparent (500 nm-850 nm) composite material (e.g. UV Adhesive or other optically transparent materials such as glass, glass pastes, epoxy etc.) is used as the sensor element. There are no restrictions on the surface size and shape (e.g. curved or flexible surfaces are possible). The thickness of the sensor layer is significantly smaller than the surface expansion (typically a few 10 μm). In addition, the substrate material can be mirrored to improve excitation and detection and to block possible scattered light from outside the sensor. For this purpose, metals (e.g. Au, Ti, Al, Ag) can be applied to the substrate material or dielectric reflective coatings can be used. The substrate material can be ceramic, (hardened) glass or metal, for example. In order to get as close as possible to a test piece with the sensor element, the substrate material should be as thin as possible. To ensure the stability of the substrate material in conjunction with the diamond material, a further (thicker) optically transparent substrate material can be applied to the diamond material.

The document presented here a sensor layer for these and other applications with similar measurement tasks. Preferably, the sensor layer comprises a substrate material in which a multiplicity of diamonds or other crystals comprising paramagnetic centers are embedded. One or more or all diamonds of these diamonds or one or more or all crystals of these crystals comprise one or more NV centers and/or one or more other paramagnetic centers. The NV centers of the sensor layer and/or the other paramagnetic centers of the sensor layer emit at least one fluorescence radiation upon exposure to pump radiation. The special feature of the sensor layer proposed in the document presented here is that the substrate material can, for example, be a substrate material cured by means of electromagnetic radiation and that, after curing, the substrate material is essentially transparent to radiation with a pump radiation wavelength λₚₘₚ of the pump radiation with which the NV centers NVZ and/or the other paramagnetic centers are pumped. Essentially means that the losses that undoubtedly occur are still so small that the functionality of the application in question is still ensured. In the same way, the substrate material should be essentially transparent for radiation with a fluorescence wavelength λ_{fl} of the fluorescence radiation of the NV centers. Essentially means that the losses that undoubtedly occur are still so small that the functionality of the application in question is still ensured. By curing a previously liquid carrier medium, the production of such a sensor layer is particularly easy and process-reliable with a high Cₚₖ value.

In one variant of the sensor layer, the diamonds or crystals in the substrate material of the sensor layer are oriented essentially differently to one another, each with an essentially different orientation. This has the advantage that the sensor layer behaves isotropically and shows no preferred direction. The mixture of different diamond crystals or crystals can homogenize the measurement results and improve the Cₚₖ value.

The diamond material of the sensor layer of the proposed magnetic field camera is preferably, if it contains NV centers, excited with green light. This can be done, for example, by using one or more LEDs as a light source. To improve the targeted excitation of the diamond material, lenses can be used to focus/align the excitation in the proposed magnetic field camera. The fluorescence radiation is then measured spatially resolved with a light sensor array of the proposed magnetic field camera. For optimal detection, the fluorescence emission of the fluorescence radiation can be imaged onto the light sensor array with an objective/lens (fluorescence camera). Alternatively, the diamond material can also be applied directly to a light sensor array using optical filters-however, the measuring range then only corresponds to the size of the sensor array. To improve the contrast, a short pass filter can be used in front of the LED, i.e. the light source, and/or a long pass filter in front of the light sensor array of the proposed magnetic field camera, whereby the cut-off wavelength of the short pass filter of the proposed magnetic field camera should be smaller than that of the long pass filter of the proposed magnetic field camera. The long pass filter typically allows electromagnetic radiation with a wavelength in the technically relevant wavelength range for the application in question greater than the cut-off wavelength of the long pass filter to pass. The short pass filter of the proposed magnetic field camera allows electromagnetic radiation with a wavelength in the technically relevant wavelength range for the application in question smaller than the cut-off wavelength of the short pass filter to pass. Preferably, the proposed device comprises a monochrome light sensor array without RGB filter and without infrared filter as the light sensor array of the proposed magnetic field camera.

Now, the essential aspect of the present document is that it also describes and discloses a method for the fabrication of a sensor layer as previously described. The proposed method comprises the steps of:
deployment of a first substrate material 9;
Coating the surface of the upper side of the first substrate material 9 with a reflective coating 10;
deployment of a liquid, second liquid substrate material curable by means of electromagnetic radiation of a curing wavelength λ_{H}, wherein a multiplicity of diamonds, preferably nano-diamonds, or crystals, preferably nano-crystals, are embedded in the second liquid substrate material and wherein one or more or all diamonds of these diamonds or crystals have NV centers and/or other paramagnetic centers and wherein the NV centers of the diamonds or crystals of the second liquid substrate material and/or the other paramagnetic centers of the diamonds or crystals have NV centers and/or other paramagnetic centers. crystals comprise NV centers and/or other paramagnetic centers and wherein the NV centers of the diamonds or crystals of the second, liquid substrate material and/or the other paramagnetic centers of the diamonds or crystals of the second, liquid substrate material emit at least one fluorescence radiation upon exposure to pump radiation;
wetting the surface of the reflective coating 10 with the second, liquid substrate material comprising the multiplicity of embedded diamonds or embedded crystals;
exposure of the surface of the reflective coating 10 and the layer of the second liquid substrate material to electromagnetic radiation, the wavelength of this electromagnetic radiation, the curing wavelength λ_{H}, being selected such that the second liquid substrate material cures and transforms into a solid. A layer 11 with crystals with paramagnetic centers is formed. Preferably, this layer comprises a multiplicity of nano crystals, which are preferably oriented in a completely random, uniformly distributed manner, and whose density is preferably not essentially dependent on the position in the layer. Preferably, the crystals are diamonds. Preferably, the paramagnetic centers are NV centers. Preferably, the diamond material is NV-rich diamond dust in an optically transparent composite material which is essentially transparent to electromagnetic radiation with pump radiation wavelength λₚₘₚ and to electromagnetic radiation with fluorescence radiation wavelength λ_{fl}; and
removal of the uncured, liquid, second substrate material, in particular by means of a solvent, the remaining film of the second substrate material on the surface of the reflective coating 10, after optional coating with a further substrate material 12, together with the other components (9, 10, 11, 12) forming the sensor layer 5.

Typically, the second, liquid substrate material only partially hardens, which enables the formation of the optical functional elements.

The electromagnetic radiation with the curing wavelength λ_{H} comprises a penetration depth into the second, liquid substrate material, so that the second substrate material cures only up to a certain thickness of the substrate material and thus forms the optical functional elements, which was first recognized as a surprising and advantageous procedure during the elaboration of the technical teaching of this paper.

The radiation used to cure the second liquid substrate material is preferably UV radiation. Particularly preferred is radiation for curing with a curing wavelength λ_{H} between 320-380 nm.

In certain applications, nanoparticles with a diameter of less than 200 nm and/or less than 100 nm and/or less than 50 nm and/or less than 20 nm and/or less than 10 nm and/or less than 5 nm can be added to the second, liquid substrate material before deployment, so that these are embedded in the substrate material after curing. For example, these can be metallic nanoparticles.

Such metallic nanoparticles interact with diamonds in the second substrate material of the sensor layer 9 and can, for example, influence the fluorescence radiation of these diamonds DM.

The optional metallic nanoparticles can be, for example, gold and/or platinum and/or palladium and/or graphite and/or graphene and/or chromium and/or silicon and/or germanium and/or tin and/or sulfur and/or selenium and/or tellurium and/or magnesium and/or calcium and/or strontium and/or barium and/or titanium and/or zirconium and/or hafnium and/or chromium and/or molybdenum and/or tungsten and/or iron and/or ruthenium and/or osmium and/or nickel and/or tin and/or cadmium and/or mercury and/or cerium and/or neodymium and/or samarium and/or gadolinium and/or dysprosium and/or erbium and/or ytterbium and/or thorium and/or proactinium and/or uranium and/or plutonium and/or mixtures thereof.

The atoms of the metal of the nanoparticles naturally comprised one or more elements of the periodic table of elements. Each of these elements occurs in different isotopes in nature with a respective natural isotope mixing ratio. Each isotope has a natural proportion in nature corresponding to the natural isotope mixing ratio. These isotopes may comprise a magnetic nuclear moment u or not, depending on the isotope. The metallic nanoparticles preferably have an increased proportion in the isotope mixing ratio for at least one element comprised by the metallic nanoparticles compared to the natural proportion of the isotope mixing ratio for at least one of the following isotopes: ¹²C, ¹⁴C, ²⁸Si, ³⁰Si, ⁷⁰Ge, ⁷²Ge, ⁷⁴Ge, ⁷⁶Ge, ¹¹²Zn, ¹¹⁴Zn, ¹¹⁶Zn, ¹¹⁸Zn, ¹²⁰Zn, ¹²²Zn, ¹²⁴Zn, ¹⁶O, ¹⁸O, ³²S, ³⁴S, ³⁶S, ⁷⁴Se, ⁷⁶Se, ⁷⁸Se, ⁸⁰Se, ⁸²Se, ¹²⁰Te, ¹²²Te, ¹²⁴Te, ¹²⁶Te, ¹²⁸Te, ¹³⁰Te, ²⁴Mg, ²⁶Mg, ⁴⁰Ca, ⁴²Ca, ⁴⁴Ca, ⁴⁶Ca, ⁴⁸Ca, ⁸⁴Sr, ⁸⁶Sr, ⁸⁸Sr, ¹³⁰Ba, ¹³²Ba, ¹³⁴Ba, ¹³⁶Ba, ¹³⁸Ba, ⁴⁶Ti, ⁴⁸Ti, ⁵⁰Ti, ⁹⁰Zr, ⁹⁰Zr, ⁹²Zr, ⁹⁴Zr, ⁹⁶Zr, ¹⁷⁴Hf, ¹⁷⁶Hf, ¹⁷⁸Hf, ⁵⁰Cr, ⁵²Cr, ⁵³Cr, ⁹²Mo, ⁹⁴Mo, ⁹⁶Mo, ⁹⁸Mo, ¹⁰⁰Mo, ¹⁸⁰W, ¹⁸²W, ¹⁸⁴W, ¹⁸⁶W, ⁵⁴Fe, ⁵⁶Fe, ⁵⁸Fe, ⁹⁶Ru, ⁹⁸Ru, ¹⁰⁰Ru, ¹⁰²Ru, ¹⁰⁴Ru, ¹⁸⁴Os. ¹⁸⁶Os, ¹⁸⁸Os, ¹⁹⁰Os, ¹⁹²Os, ⁵⁸Ni, ⁶⁰Ni, ⁶²Ni, ⁶⁴Ni, ¹⁰²Pd, ¹⁰²Pd, ¹⁰⁴Pd, ¹⁰⁶Pd, ¹⁰⁸Pd, ¹¹⁰Pd, ¹⁹⁰Pt, ¹⁹²Pt, ¹⁹⁴Pt, ¹⁹⁶Pt, ¹⁹⁸Pt, ⁶⁴Zn, ⁶⁶Zn, ⁶⁸Zn, ⁷⁰Zn, ¹⁰⁶Cd, ¹⁰⁸Cd, ¹¹⁰Cd, ¹¹²Cd, ¹¹⁴Cd, ¹¹⁶Cd, ¹⁹⁶Hg, ¹⁹⁸Hg, ²⁰⁰Hg, ²⁰²Hg, ²⁰⁴Hg, ¹³⁶Ce, ¹³⁸Ce, ¹⁴⁰Ce, ¹⁴²Ce, ¹⁴²Nd, ¹⁴⁴Nd, ¹⁴⁶Nd, ¹⁴⁸Nd, ¹⁵⁰Nd, ¹⁴⁴Sm, ¹⁴⁶Sm, ¹⁴⁸Sm, ¹⁵⁰Sm, ¹⁵²Sm, ¹⁵⁴Sm, ¹⁵²Gd, ¹⁵⁴Gd, ¹⁵⁶Gd, ¹⁵⁸Gd, ¹⁶⁰Gd, ¹⁵⁶Dy, ¹⁵⁸Dy, ¹⁶⁰Dy, ¹⁶²Dy, ¹⁶⁴Dy, ¹⁶²Er, ¹⁶⁴Er, ¹⁶⁶Er, ¹⁶⁸Er, ¹⁷⁰Er, ¹⁶⁸Yb, ¹⁷⁰Yb, ¹⁷²Yb, ¹⁷⁴Yb, ¹⁷⁶Yb, ²³²Th, ²³⁴Pa, ²³⁴U, ²³⁸U, ²⁴⁴Pu. For the purposes of this document, “increased” means that the proportion in the isotope mixing ratio of the above isotopes is increased by 50% or more.

The value of the output signal of each sensor pixel, i.e. each light sensor of the light sensor array of the proposed magnetic field camera, then reflects the magnetic field strength at the location of the diamond material volume imaged on the respective sensor pixel, i.e., the respective light sensor of the light sensor array. Thus, the spatial resolution of the proposed magnetic field camera is only limited by the imaging optics and the resolution of the light sensor array, i.e. the sensor resolution. Such a device can thus realize several megapixel resolution.

The evaluation electronics can calculate out fluctuations caused by the excitation light or inhomogeneities in the diamond material by using values from a previously performed reference measurement of a reference sample. The excitation, detection and the optically accessible side of the diamond material are preferably located in an optically closed housing in order to suppress the influence of external light.

For larger sensor areas, the working distance and focus of the fluorescence camera of the proposed magnetic field camera can be adjusted accordingly. Devices that use several fluorescence cameras to increase the spatial resolution with a larger sensor area are conceivable. The evaluation electronics can then process the majority of images from this plurality of fluorescence cameras into one image.

A demonstrator has already proven its suitability for spatially resolved measurement of magnetic fields during testing of the proposal.

### Summary of the Third Implementation Proposal (Magnetic Field Camera)

The present document proposes a magnetic field camera head 21 comprising a sensor layer 5, a light source 2 for pump radiation 13 and a fluorescence camera comprising a light sensor array 1 of light sensors. The sensor layer 5 preferably comprises paramagnetic centers. These paramagnetic centers emit fluorescence radiation 14 upon exposure to pump radiation 13. The intensity of the emitted fluorescence radiation 14 depends on the intensity of the pump radiation 13 and the intensity of the magnetic flux density B at the respective location of the respective paramagnetic center in the sensor layer 5. The fluorescence camera of the proposed magnetic field camera detects and deploys a fluorescence picture of the emission intensity distribution for the fluorescence radiation emission of the fluorescence radiation 14 from the sensor layer 5.

The magnetic field camera head 21 may comprise auxiliary magnets 19.

The sensor layer 5 preferably comprises diamonds with NV centers as paramagnetic centers and/or NV centers NVZ and/or other crystals with paramagnetic centers.

Furthermore, the present document proposes a magnetic field camera with such a magnetic field camera head 21 and with a computer system 28 for operating the magnetic field camera head 21, wherein the computer system 28 is preferably configured to generate a magnetic flux density magnitude image from a fluorescence picture of the magnetic field camera head 21 and/or to generate a one-dimensional course of the fluorescence intensity or the magnetic flux density magnitude along a line through the fluorescence picture.

Furthermore, the present document proposes the use of the above-described magnetic field camera and/or the above-described magnetic field camera head 21 for investigating the magnetic field of magnetized objects and/or for investigating the structure of magnetized objects and/or for investigating the current density distribution in objects through which an electric current flows.

In this third application example, the technical teaching presented here makes image formats for magnetic field cameras possible that were previously not feasible.

In the following, the document presented here lists some of these image formats that become possible by means of the magnetic field camera presented here with a suitable choice of the crystal size of the crystals and nano crystals 66 and/or diamonds and/or nano diamonds and a suitable choice of the number of pixels of the light sensor array 1 of the proposed magnetic field camera.

Preferably, the detection area of a light sensor (pixel) of the light sensor array 1 of the proposed magnetic field camera on the surface of the layer 11 should be larger than twice the mean diameter of the crystals and/or nano crystals 66. The Nyquist theorem is then generally fulfilled. Preferably, the detection area of a light sensor (pixel) of the light sensor array 1 of the proposed magnetic field camera on the surface of the layer 11 should be larger than 5 times, better 10 times, better 20 times, better 50 times the mean diameter of the crystals and/or nano crystals 66 or diamonds and/or nano-diamonds. This enables a stochastic uniform distribution of the orientation of several crystals and/or nano crystals or diamonds and/or nano-diamonds whose fluorescence radiation is detected by this light sensor (pixel) of the light sensor array 1 of the proposed magnetic field camera.

Magnetic Field Camera with Areal Pump Radiation Source

The document presented here describes, among other things, an areal pump radiation source PL for the exposure of paramagnetic centers to pump radiation 13 with a pump radiation wavelength λₚₘₚ, wherein the areal pump radiation source PL comprises one or more primary pump radiation sources, in particular in the form of LEDs 44. The one or more primary pump radiation sources are preferably configured to emit pump radiation 13 with the pump radiation wavelength λ₍ₚₘₚ₎.

Preferably, the planar pump radiation source comprises a first optical functional element, in particular a glass plate 46 and/or a planar optical waveguide and/or an optical system. For the purposes of the present document, the first optical functional element is an optical waveguide LWL). The first optical functional element typically comprises a first surface 67. Preferably, the first optical functional element distributes the pump radiation 13 with the pump radiation wavelength λₚₘₚ emitted by the primary pump radiation sources over an area.

Typically, the first optical functional element is thus configured so that this pump radiation 13, which is distributed over an area, emerges over an area from a first surface of the first optical functional element of the areal pump radiation source.

This areal pump radiation source enables the layer 11 to be illuminated by means of LEDs 44 instead of laser diodes as primary pump radiation sources. This is essentially more cost-effective than illumination by means of lasers. However, when the document presented here refers to LEDs 44, this includes lasers as possible primary pump radiation sources.

In another embodiment, the one or more primary pump radiation sources of the areal pump radiation source thus comprise one or more LEDs 44 as primary pump radiation sources of the pump radiation 13. This enables good and, above all, more homogeneous illumination of the layer 11 with pump radiation 13.
In another embodiment, the first optical functional element comprises one or more of the following optical functional elements: a glass plate 46;
an areal optical waveguide;
a plurality of optical waveguides which are functionally equivalent to a planar optical waveguide;
a micro-optical system with at least one photonic crystal which is configured to distribute the pump radiation 13 with the pump radiation wavelength λₚₘₚ over an area;
a micro-optical system with at least one micro-optical mirror which is configured to distribute the pump radiation 13 with the pump radiation wavelength λₚₘₚ over an area; and/or
another optical system configured to distribute the pump radiation 13 with the pump radiation wavelength λₚₘₚ over an area.

This first optical functional element thus enables the planar distribution of the pump radiation 13 for exposure of the layer 11 to pump radiation 13.

In another embodiment, the areal pump radiation source of the proposed magnetic field camera exposes an areal layer 11 with areally distributed crystals and/or nano crystals 66 and/or diamonds with paramagnetic centers and/or NV centers with pump radiation 13 of the pump radiation wavelength λ₍ₚₘₚ₎. This first optical functional element thus enables the areal distribution of the pump radiation 13 for exposure of the layer 11 with pump radiation 13.

In another embodiment, the planar pump radiation source comprises the layer 11 and irradiates the layer 11 via the first surface 67. In this other embodiment, the layer 11 is directly or indirectly mechanically connected to the first surface 67 of the first optical functional element, in this case the glass plate 46. Preferably, the layer 11 completely or partially covers the first surface 67 of the first optical functional element, in this case the glass plate 46.

This enables a very simple construction of an areal fluorescence radiation source as a combination of the layer 11 with the areal pump radiation source, whereby the areal pump radiation source exposes the layer 11 with pump radiation 13 over an area and then the paramagnetic centers in the layer 11 emit fluorescence radiation 14 over an area depending on the magnetic flux density at the location of the respective paramagnetic center in the layer 11. This thus results in an areal fluorescence radiation source in which the intensity of the fluorescence radiation 14 emitted locally at a point on the radiating surface of the areal fluorescence radiation source depends on the magnetic flux density at this point on the radiating surface of the areal fluorescence radiation source.

In another embodiment, the layer 11 emits locally different fluorescence radiation 14 with a fluorescence radiation wavelength λ_{FL} depending on the value of the local absolute value of the magnetic flux density in the layer 11. This also results in a planar fluorescence radiation source in which the intensity of the fluorescence radiation 14 emitted locally at a point on the radiating surface of the planar fluorescence radiation source depends on the magnetic flux density at this point on the radiating surface of the planar fluorescence radiation source.

In another embodiment, the planar pump radiation source comprises a further optical functional element which separates electromagnetic radiation with the pump radiation wavelength λₚₘₚ from electromagnetic radiation with the fluorescence radiation wavelength λ_{fl}. This thus results in an areal fluorescence radiation source in which the intensity of the fluorescence radiation 14 emitted locally at a point on the radiation surface of the areal fluorescence radiation source depends on the magnetic flux density at this point on the radiation surface of the areal fluorescence radiation source and which does not emit any pump radiation, which increases the contrast.

In another embodiment, the further optical functional element comprises one or more of the following optical functional elements:
a dichroic reflecting layer 47; and/or
an optical filter (long pass) 6.

This enables a very simple design of the separation device for the separation of electromagnetic radiation with pump radiation wavelength λₚₘₚ from electromagnetic radiation with fluorescence radiation wavelength λFL.

In another embodiment, the further optical functional element separates the pump radiation 13 with the pump radiation wavelength λₚₘₚ from the fluorescence radiation 14 with the fluorescence radiation wavelength λ_{fl}. This thus results in an areal fluorescence radiation source in which the intensity of the fluorescence radiation 14 emitted locally at a point on the radiating surface of the areal fluorescence radiation source depends on the magnetic flux density at this point on the radiating surface of the areal fluorescence radiation source and which does not emit any pump radiation, which increases the contrast.

### Manufacturing Process for the Areal Pump Radiation Source

The present document further provides a method for fabrication of an areal pump radiation source (44, 46). The method begins with the deployment of one or more primary pump radiation sources. Thereby, the one or more primary pump radiation sources emit pump radiation 13 with the pump radiation wavelength λₚₘₚ. A further step comprises the deployment of a first optical functional element, for example a glass plate 46. Typically, the first optical functional element comprises a first surface 67. Preferably, the first optical functional element distributes the pump radiation 13 with the pump radiation wavelength pmp emitted by the primary pump radiation sources over an area. The first optical functional element is thus configured so that this pump radiation 13, which is distributed over an area, emerges over an area from the first surface 67 of the first optical functional element of the pump radiation source. A further step of the method is typically a mechanical connection of the primary pump radiation sources to the first optical functional element. Here, for example, a printed circuit board (PCB) 43 can establish the mechanical connection by means of soldering and/or bonding. After the mechanical connection, the primary pump radiation sources are preferably configured to emit pump radiation 13 with the pump radiation wavelength λₚₘₚ upon electrical activation, for example by current supply, and to feed it into the first optical functional element, in particular via an edge of the first optical functional element and/or a side surface of the first optical functional element. The first optical functional element is preferably configured so that the pump radiation 13 propagates over an area within the first optical functional element in a light surface. The first optical functional element preferably emits pump radiation 13 with the pump radiation wavelength λₚₘₚ via the first surface 67 of the first optical functional element perpendicular to the aforementioned light surface of the pump radiation 13 within the first optical functional element pump radiation (13) with the pump radiation wavelength λ₍ₚₘₚ₎.

In another embodiment, the method for the fabrication of a sensor layer 5 comprises as a step the deployment of a first optical functional element, in particular a glass plate (46) and/or a planar optical waveguide and/or an optical system. Furthermore, the method in this embodiment preferably comprises the deployment of a liquid second substrate material that is curable by means of electromagnetic radiation of a curing wavelength λ_{H}. Preferably, a multiplicity of diamonds, preferably nano-diamonds, or crystals 66, preferably nano crystals 66, are embedded in the second, liquid substrate material. Preferably, one or more or all of these diamonds or crystals 66 and/or nano crystals 66 comprise NV centers and/or other paramagnetic centers. Preferably, the NV centers of the diamonds or crystals 66 and/or nano crystals 66 of the second, liquid substrate material and/or the other paramagnetic centers of the diamonds or crystals 66 and/or nano crystals 66 of the second, liquid substrate material emit at least one fluorescence radiation 14 upon exposure to pump radiation 13. In this embodiment, the method presented herein for the fabrication of a planar pump radiation source (44, 46) preferably comprises the step of wetting and coating the first surface 67 of the first optical functional element, in particular the glass plate 46 and/or the planar optical waveguide and/or the optical system, with the second, liquid substrate material, which preferably comprises the multiplicity of embedded diamonds or embedded crystals 66 and/or nano crystals 66. The method presented herein for the fabrication of a planar pump radiation source (44, 46) preferably comprises as a further step the exposure of the first surface 67 of the first optical functional element, in particular the glass plate (46) and/or the planar optical waveguide and/or the optical system, and/or the layer of the second liquid substrate material with electromagnetic radiation, the wavelength of this electromagnetic radiation, the curing wavelength λH, being selected such that the second liquid substrate material cures and transforms into a solid, in particular in the form of the layer 11. Preferably, curing radiation is fed in as electromagnetic radiation with the curing wavelength λ_{H} at the points of the first optical functional elements—for example the glass plate 46—at which the primary pump radiation sources—for example the LEDs 44—are to feed the pump radiation 13 later. As a result, the layer is cured in a self-aligning manner on the first surface 67 of the first optical functional element—for example the glass plate 46—and thus manufactured.

In another embodiment of the method of fabrication of a sensor layer 5, the layer 11 comprises a multiplicity of crystals 66 and/or nano crystals 66 having paramagnetic centers.

In another embodiment of the method for the fabrication of a sensor layer 5, the crystals 66 and/or nano crystals 66 in the layer 11 are oriented in a completely random and substantially uniformly distributed manner, and/or the density of crystals 66 and/or nano crystals 66 in the layer 11 is preferably essentially not dependent on the position in the layer 11.

In another embodiment of the method for the fabrication of a sensor layer 5, the crystals 66 and/or nano crystals 66 comprise diamonds. Preferably, in this embodiment, the crystals 66 and/or nano crystals 66 comprise paramagnetic centers. Preferably, in this embodiment, the crystals 66 and/or nano crystals 66 comprise diamonds with NV centers.

In another embodiment of the method for the fabrication of a sensor layer 5, the layer 11 is an optically transparent composite material which is essentially transparent for electromagnetic radiation with pump radiation wavelength λₚₘₚ and for electromagnetic radiation with fluorescence radiation wavelength λ_{fl}.

In another embodiment of the method for the fabrication of a sensor layer 5, the method comprises a further step of removing the uncured liquid second substrate material, in particular by means of a solvent, wherein the remaining film of the second substrate material on the first surface 67 of the first optical functional element, in particular the glass plate 46, forms the layer 11.

In another embodiment of the method for the fabrication of a sensor layer 5, the method comprises a further step of coating the layer 11 with a reflective coating 10.

In another embodiment of the method for the fabrication of a sensor layer 5, the method comprises a further step of coating the layer 11 and/or the reflective coating 10 with a further substrate material 12.

In another embodiment of the method for the fabrication of a sensor layer 5, the method comprises a further step of using the layer 11 together with other components (9, 10, 12) as the sensor layer 5 of a sensor head 21.

In another embodiment of the method for fabricating a sensor layer 5, the method comprises a further step of fabricating a diffuser or a diffuser layer 69 on the first surface 67 of the first optical functional element over the entire surface or in certain areas.

### Fabrication of the Sensor Layer 5 on a Substrate Material 9

In another embodiment of the method for fabricating a sensor layer 5 in a housing 8, the method for fabricating a sensor layer 5 comprises as a first step the deployment of a first substrate material 9. A further step of this method for fabricating a sensor layer 5 in a housing 8 comprises the coating of the surface of the upper side of the first substrate material 9 with a reflective coating 10. The method also comprises the deployment of a liquid second substrate material which is curable by means of electromagnetic radiation of a curing wavelength λ_{H}. Preferably, a multiplicity of diamonds, preferably nano-diamonds, or crystals 66, preferably nano crystals 66, are embedded in the second, liquid substrate material. Preferably, one or more or all of these diamonds or crystals 66 and/or nano crystals 66 comprise NV centers and/or other paramagnetic centers. In this case, the NV centers of the diamonds or crystals 66 and/or nano crystals 66 of the second, liquid substrate material and/or the other paramagnetic centers of the diamonds or crystals 66 and/or nano crystals 66 of the second, liquid substrate material emit at least one fluorescence radiation 14 upon exposure to pump radiation 13. Preferably, the method comprises wetting the surface of the reflective coating 10 with the second, liquid substrate material comprising the multiplicity of embedded diamonds or embedded crystals 66 and/or nano crystals 66. Preferably, the method comprises exposing the surface of the reflective coating 10 and the layer of the second liquid substrate material to electromagnetic radiation. Preferably, the wavelength of this electromagnetic radiation, the curing wavelength λ_{H}, is selected such that the second liquid substrate material cures and transforms into a solid. Typically, a layer 11 comprising crystals 66 and/or nano crystals 66 with paramagnetic centers is formed. Preferably, this layer 11 comprises a multiplicity of nano crystals 66, which are preferably oriented in a completely random, uniformly distributed manner, and whose density is preferably essentially not dependent on the position in the layer 11. Preferably, the crystals are diamonds. Preferably, the paramagnetic centers are NV centers. Preferably, said diamond material is NV-rich diamond dust of crystals 66 and/or nano crystals 66 in an optically transparent composite material which is essentially transparent to electromagnetic radiation with pump radiation wavelength λₚₘₚ and to electromagnetic radiation with fluorescence radiation wavelength λ_{fl}. The proposed method preferably comprises removing the uncured, liquid, second substrate material, in particular by means of a solvent, the remaining film of the second substrate material on the surface of the reflective coating 10 after optional coating with a further substrate material 12 together with the other components (9, 10, 11, 12) forming the sensor layer 5.

### Use of an Area Pump Radiation Source (46, 44)

The present document further describes a method of using a sheet-like pump radiation source (46, 44). Steps of the method include providing the sheet-like pump radiation source (46, 44) and deploying a sheet-like layer 11, wherein the sheet-like layer 11 comprises a multiplicity of crystals 66 and/or nano crystals 66 comprising paramagnetic centers. The method preferably comprises exposing the planar layer 11 to pump radiation 13 from a pump radiation source (2, 44), wherein the pump radiation 13 comprises a pump radiation wavelength λₚₘₚ. Paramagnetic centers of crystals 66 and/or nano crystals 66 of the planar layer 11 emit fluorescence radiation 14 during this exposure by the pump radiation 13 of the planar pump radiation source (46, 44). The method further preferably comprises separating the fluorescence radiation 14 from the pump radiation 13 by means of a separating agent (6, 47). Typically, optical filters (long pass) 6 and/or dichroic reflecting optional layers 47 may constitute such separation means (6, 47). The method also comprises detecting the fluorescence radiation 14 by means of a detecting means 15, 1. Typically, the light sensors of the light sensor array 1 and/or the evaluation electronics 15 of the fluorescence camera can represent such detecting means 15, 1.

In a further embodiment of the method of using an areal pump radiation source (46, 44), the method comprises imaging the distribution of the local intensity of the areal emission of the fluorescence radiation 14 by means of imaging optics 7 onto a light sensor array 1;

In a further embodiment of the method for using an areal pump radiation source (46, 44), the method comprises detecting measured values from light sensors of the light sensor array 1 and processing these measured values in evaluation electronics 15 and preferably forming a fluorescence picture from such measured values.

In a further embodiment of the method for using an areal pump radiation source (46, 44), the method comprises compressing the detected measured values of light sensors of the light sensor array 1 and processing these measured values in evaluation electronics 15, in particular to form a compressed fluorescence picture. For example, the sensor head 21 can generate formats of lossless image compression methods such as GIF, RAW, BMP, PNG. For example, the sensor head 21 can generate formats of lossy image compression methods such as JPEG.

In a further embodiment of the method of using an areal pump radiation source (46, 44), the method comprises transferring a fluorescence picture and/or a compressed fluorescence picture to a higher-level computer system 28.

In a further embodiment of the method of using an area pump radiation source (46, 44), the method comprises decompressing the received compressed fluorescence picture to a transferred fluorescence picture in the higher-level computer system 28 and/or using the received fluorescence picture to a transferred fluorescence picture in the higher-level computer system 28.

In a further embodiment of the method of using an areal pump radiation source (46, 44), the method comprises determining an image of the one-dimensional and/or two-dimensional and/or three-dimensional distribution of the magnetic flux density as a function of one or more transferred or detected fluorescence pictures. Preferably, a higher-level computer system 28 performs this determination.

In a further embodiment of the method of using an areal pump radiation source (46, 44), the method comprises displaying an image of the one-dimensional and/or two-dimensional and/or three-dimensional distribution of magnetic flux density and/or one or more transferred or captured fluorescence pictures and/or images calculated therefrom on a display 32 or other medium for displaying images.

In a further embodiment of the method for using an areal pump radiation source (46, 44), the method comprises generating a video sequence from a plurality of an image of the one-dimensional and/or two-dimensional and/or three-dimensional distribution of the magnetic flux density and/or from one or more transferred or detected fluorescence pictures and/or from images calculated therefrom. The evaluation electronics 15 and/or the higher-level computer system 28 can perform this video sequence generation.

In a further embodiment of the method for using an areal pump radiation source (46, 44), the method comprises compressing the video sequence into a compressed video sequence. In this regard, the evaluation electronics 15 and/or the higher-level computer system 28 may perform this compression. Preferably, these use one of the following compression methods: AVC, HEVC, MPEG. Preferably, the evaluation electronics 15 of the sensor head 21 creates the video sequence and compresses it by means of a compression method and then transfers the compressed video sequence via the data bus 29 to the higher-level computer system 28 for operating the sensor head 21.

In a further embodiment of the method of using an areal pump radiation source (46, 44), the method comprises displaying the video sequence on a display 32 or other medium for displaying video sequences.

### Sensor Head

The document presented here also proposes a sensor head 21 with a sensor layer 5 and a light source (2, 44) for pump radiation 13 and a fluorescence camera with a light sensor array 1 of light sensors. Here too, the sensor layer 5 preferably comprises paramagnetic centers that emit fluorescence radiation (14) upon exposure to pump radiation 13. The intensity of the fluorescence radiation 14 depends on the intensity of the pump radiation 13 and the intensity of the magnetic flux density at the respective location of the respective paramagnetic center. According to the proposal, the fluorescence camera detects a fluorescence picture of the emission intensity distribution for the emission of the fluorescence radiation 14 from the sensor layer 5 and deploys the fluorescence picture.

In a further embodiment of the sensor head 21, the sensor head comprises auxiliary magnets 19.

In a further embodiment of the sensor head 21, the sensor layer 5 comprises diamonds with NV centers as paramagnetic centers.

### Magnetic Field Camera

The present document proposes a magnetic field camera comprising one of the magnetic field camera heads 21 described above. The magnetic field camera comprises a computer system 28 for operating the magnetic field camera head 21, wherein the computer system 28 preferably operates from a fluorescence picture of the magnetic field camera head 21 and/or from an image calculated therefrom.
a magnetic flux density magnitude image and/or
an image of the one-dimensional and/or two-dimensional and/or three-dimensional distribution of the magnetic flux density and/or
a data set with values of a one-dimensional course of the fluorescence intensity or the magnetic flux density along a line through the fluorescence picture and/or the picture calculated from it generated.

### Use of a Magnetic Field Camera

The document presented here proposes to use one of the magnetic field cameras discussed above to study the magnetic field of magnetized objects.

The document presented here proposes to use one of the magnetic field cameras discussed above to study the structure of magnetized objects.

The document presented here proposes to use one of the magnetic field cameras discussed above to investigate the material composition of magnetized objects.

The document presented here proposes to use one of the magnetic field cameras discussed above to investigate the current density distribution in objects through which an electric current flows.

### Resolution

Preferably, the fluorescence camera provides an image with more than 19000 pixels after decompression.

Possible image formats for the magnetic field camera are, for example, depending on the light sensor array format of light sensor array 1 (source: https://de.wikipedia.org/wiki/Bildauf1%C3%B6sung)

| Abbreviation | Name | x | | y | x y: | DAR | PAR | x-y |
|---|---|---|---|---|---|---|---|---|
| QQVGA | Quarter | 160 | × | 120 | 4 3: | 4 3: | 1 1: | 19.200 |
| | QVGA | | | | | | | |
| | [2][3] | | | | | | | |
| GB | Game | 160 | × | 144 | 4 3: | 4 3: | 1 1: | 23.040 |
| | Boy[4] | | | | | | | |
| GBC | Game Boy | 160 | × | 144 | 4 3: | 4 3: | 1 1: | 23.040 |
| | Color [5] | | | | | | | |
| Palm | Palm Low | 160 | × | 160 | 1 1: | 1 1: | 1 1: | 25.600 |
| LoRes | Resolution | | | | | | | |
| GBA | Game Boy | 240 | × | 160 | 3 2: | 3 2: | 1 1: | 38.400 |
| | Advance [6] | | | | | | | |
| ⅛ VGA | ⅛ VGA | 240 | × | 180 | 4 3: | 4 3: | 1 1: | 43.200 |
| ZXS | ZX | 256 | × | 192 | 4 3: | 4 3: | 1 1: | 49.152 |
| | Spectrum | | | | | | | |
| NDS | Nintendo | 256 | × | 192 | 4 3: | 4 3: | 1 1: | 49.152 |
| | DS[7] | | | | | | | |
| 3DS | Nintendo | 400 | × | 240 | 5 3: | 5 3: | 1 1: | 96.000 |
| | 3DS | | | | | | | |
| | resolution | | | | | | | |
| | per eye[8] | | | | | | | |
| CGA | Color | 320 | × | 200 | 8 5: | 4 3: | 0.833 | 64.000 |
| | Graphics | | | | | | | |
| | Adapter[3] | | | | | | | |
| QVGA | Quarter | 320 | × | 240 | 4 3: | 4 3: | 1 1: | 76.800 |
| | VGA[3] | 360 | × | 240 | 3 2: | 3 2: | 1 1: | 86.400 |
| | | 384 | × | 240 | 8 5: | 4 3: | 0.833 | 92.160 |
| Palm | Palm High | 320 | × | 320 | 1 1: | 1 1: | 1 1: | 102.400 |
| HiRes | Resolution | | | | | | | |
| QSVGA | Quarter | 400 | × | 300 | 4 3: | 4 3: | 1 1: | 120.000 |
| | SVGA | | | | | | | |
| WQVGA | Wide QVGA | 432 | × | 240 | 9 5: | 9 5: | 1 1: | 103.680 |
| | | 480 | × | 160 | 3:1 | 3 | 1 1: | 76.800 |
| PSP | PlayStation | 480 | × | 272 | 16 9: | 16 9: | 1.007 | 130.560 |
| | Portable[9] | | | | | | | |
| HVGA | Half | 480 | × | 320 | 3 2: | 3 2: | 1 1: | 153.600 |
| | VGA[2] | | | | | | | |
| PSION | | 640 | × | 240 | 8:3 | 8:3 | 1 1: | 153.600 |
| Series 5 | | 480 | × | 360 | 4 3: | 4 3: | 1 1: | 172.800 |
| EGA | Enhanced | 640 | × | 350 | 64:35 | 4 3: | 0.729 | 224.000 |
| | Graphics | | | | | | | |
| | Adapter [3] | | | | | | | |
| QHD | Quarter HD | 640 | × | 360 | 16 9: | 16 9: | 1 1: | 230.400 |
| HSVGA | Half SVGA | 600 | × | 400 | 3 2: | 3 2: | 1 1: | 240.000 |
| VGA | Video | 640 | × | 480 | 4 3: | 4 3: | 1 1: | 307.200 |
| | Graphics | | | | | | | |
| | Array[2] | | | | | | | |
| HGC | Hercules | 720 | × | 348 | 60:29 | 4 3: | 0.644 | 250.560 |
| | Graphics | | | | | | | |
| | Card | | | | | | | |
| MDA | Monochrome | 720 | × | 350 | 72:35 | 4 3: | 0.648 | 252.000 |
| | display | | | | | | | |
| | adapter | | | | | | | |
| Apple | | 720 | × | 364 | ≈2:1 | 4 3: | 0.674 | 262.080 |
| Lisa | | | | | | | | |
| WVGA, WGA | Wide VGA | 720 | × | 400 | 9 5: | 9 5: | 1 1: | 288.000 |
| | | 720 | × | 480 | 3 2: | 3 2: | 1 1: | 345.600 |
| | | 720 | × | 540 | 4 3: | 4 3: | 1 1: | 388.800 |
| WVGA, | Wide VGA | 800 | × | 480 | 5 3: | 5 3: | 1 1: | 384.000 |
| WGA | | | | | | | | |
| WVGA, | Wide VGA | 848 | × | 480 | ≈16:9 | 16 9: | 1.006 | 407.040 |
| WGA | | | | | | | | |
| WVGA, | Wide VGA | 852 | × | 480 | ≈16:9 | 16 9: | 1.001 | 408.960 |
| WGA | | | | | | | | |
| WVGA, | Wide VGA | 858 | × | 484 | ≈16:9 | 16 9: | 1.002 | 415.272 |
| WGA | | | | | | | | |
| WVGA, | Wide VGA | 864 | × | 480 | 9 5: | 9 5: | 1 1: | 414.720 |
| WGA | | | | | | | | |
| PAL-D | PAL | 768 | × | 576 | 4 3: | 4 3: | 1 1: | 442.368 |
| | Digital[3] | | | | | | | |
| SVGA | Super | 800 | × | 600 | 4 3: | 4 3: | 1 1: | 480.000 |
| | VGA[3][2] | | | | | | | |
| HXGA | Half | 832 | × | 624 | 4 3: | 4 3: | 1 1: | 519.168 |
| | Megapixel | | | | | | | |
| | (Apple) | | | | | | | |
| qHD, QHD | Quarter HD | 960 | × | 540 | 16 9: | 16 9: | 1 1: | 518.400 |
| | | 960 | × | 540 | 16 9: | 16 9: | 1 1: | 518.400 |
| PS Vita | PlayStation | 964 | × | 544 | 16 9: | 16 9: | 1 1: | 524.416 |
| | Vita | 964 | × | 544 | ≈16:9 | 16 9: | 1 1: | 524.416 |
| DVGA | Double | 960 | × | 640 | 3 2: | 3 2: | 1 1: | 614.400 |
| | VGA | 960 | × | 720 | 4 3: | 4 3: | 1 1: | 691.200 |
| WXGA | Wide XGA | 1024 | × | 576 | 16 9: | 16 9: | 1 1: | 589.824 |
| WSVGA | Wide SVGA | 1024 | × | 600 | ≈17:10 | 16 9: | 1.041 | 614.400 |
| | [3] | | | | | | | |
| WSVGA | Wide SVGA | 1072 | × | 600 | ≈16:9 | 16 9: | 0.995 | 643.200 |
| EVGA | Extended | 1024 | × | 768 | 4 3: | 4 3: | 1 1: | 786.432 |
| | VGA | | | | | | | |
| XGA | Extended | 1024 | × | 768 | 4 3: | 4 3: | 1 1: | 786.432 |
| | Graphics | | | | | | | |
| | Array[2][3] | | | | | | | |
| XGA | XGA+[3] | 1152 | × | 864 | 4 3: | 4 3: | 1 1: | 995.328 |
| HD720, | High | 1280 | × | 720 | 16 9: | 16 9: | 1 1: | 921.600 |
| 720p | Definition, | | | | | | | |
| | “HD | | | | | | | |
| | ready”[3] | | | | | | | |
| WXGA | Wide XGA | 1280 | × | 768 | 5 3: | 5 3: | 1 1: | 983.040 |
| | (Bright | | | | | | | |
| | View) | | | | | | | |
| DSVGA | Double | 1200 | × | 800 | 3 2: | 32 | 1 1: | 960.000 |
| | SVGA | | | | | | | |
| WXGA | Wide | 1280 | × | 800 | 8 5: | 8 5: | 1 1: | 1.024.000 |
| | XGA[3] | | | | | | | |
| OLPC | One laptop | 1200 | × | 900 | 4 3: | 4 3: | 1 1: | 1.080.000 |
| | per child | | | | | | | |
| SXVGA, | Super | 1280 | × | 960 | 4 3: | 4 3: | 1 1: | 1.228.800 |
| QVGA | Extended | | | | | | | |
| | VGA, Quad | | | | | | | |
| | VGA | | | | | | | |
| SXGA | Super | 1280 | × | 1024 | 5 4: | 5 4: | 1 1: | 1.310.720 |
| | XGA[2][3] | | | | | | | |
| WXGA | Wide XGA | 1360 | × | 768 | ≈16:9 | 16 9: | 1.003 | 1.044.480 |
| WXGA | Wide XGA | 1366 | × | 768 | ≈16:9 | 16 9: | 0.999 | 1.049.088 |
| WXGA | Wide XGA | 1376 | × | 768 | ≈16:9 | 16 9: | 0.992 | 1.056.768 |
| WXGA+ | WXGA | 1400 | × | 900 | 14 9: | 14 9: | 1 1: | 1.260.000 |
| | Plus[3] | | | | | | | |
| WXGA+ | WXGA Plus | 1440 | × | 900 | 8 5: | 8 5: | 1 1: | 1.296.000 |
| (Apple) | | 1440 | × | 960 | 3 2: | 3 2: | 1 1: | 1.382.400 |
| SXGA+ | SXGA | 1400 | × | 1050 | 4 3: | 4 3: | 1 1: | 1.470.000 |
| | Plus[3] | | | | | | | |
| UWXGA | Ultra Wide | 1600 | × | 768 | 25:12 | 2.083 | 1 1: | 1.228.800 |
| | XGA | | | | | | | |
| WSXGA | Wide | 1600 | × | 900 | 16 9: | 16 9: | 1 1: | 1.440.000 |
| | SXGA[3] | | | | | | | |
| WSXGA | Wide | 1600 | × | 1024 | 25: 16 | 25: 16 | 1 1: | 1.638.400 |
| | SXGA[3] | | | | | | | |
| UXGA | Ultra | 1600 | × | 1200 | 4 3: | 4 3: | 1 1: | 1.920.000 |
| | XGA[2][3] | | | | | | | |
| WSXGA+ | Wide | 1680 | × | 1050 | 8 5: | 85 | 1 1: | 1.764.000 |
| | SXGA+[3] | | | | | | | |
| FHD, | High | 1920 | × | 1080 | 16 9: | 16 9: | 1 1: | 2.073.600 |
| HD1080, | Definition, | | | | | | | |
| 1080p | “Full HD | | | | | | | |
| WUXGA | Wide | 1920 | × | 1200 | 8 5: | 8 5: | 1 1: | 2.304.000 |
| | UXGA[3] | | | | | | | |
| 2K-DCI | 2K-Digital | 2048 | × | 1080 | 256: 135 | 256: 135 | 1 1: | |
| | Cinema | | | | | | | |
| | Initiatives | | | | | | | |
| QWXGA | Quad | 2048 | × | 1152 | 16 9: | 16 9: | 1 1: | 2.359.296 |
| | WXGA | | | | | | | |
| TXGA | Tesselar | 1920 | × | 1400 | 48:35 | 1.371 | 1 1: | 2.688.000 |
| | GA | 1920 | × | 1440 | 4 3: | 4 3: | 1 1: | 2.764.800 |
| SUXGA | Super | 2048 | × | 1536 | 4 3: | 4 3: | 1 1: | 3.145.728 |
| | UXGA | | | | | | | |
| QXGA | Quad | 2048 | × | 1536 | 4 3: | 4 3: | 1 1: | 3.145.728 |
| | XGA[2][3] | | | | | | | |
| FHD+ | Full HD+ | 2160 | × | 1080 | 18:9 | 18:9 | 1 1: | 2.332.800 |
| FHD+ | Full HD+ | 2340 | × | 1080 | 2.10 1: | 2.10 1: | 1 1: | 2.527.200 |
| UWFHD | Ultra Wide | 2560 | × | 1080 | 21 9: | 21 9: | 1 1: | 2.764.800 |
| | FHD | | | | | | | |
| WQHD, | Wide QHD | 2560 | × | 1440 | 16 9: | 16 9: | 1 1: | 3.686.400 |
| 1440p | (QHD),[3] | | | | | | | |
| | “2K”[10] | | | | | | | |
| WQXGA | Wide | 2560 | × | 1600 | 8 5: | 8 5: | 1 1: | 4.096.000 |
| | QXGA[3] | | | | | | | |
| QSXGA | Quad | 2560 | × | 2048 | 5 4: | 5 4: | 1 1: | 5.242.880 |
| | SXGA[3] | | | | | | | |
| QHD+ | Quad High | 3200 | × | 1800 | 16 9: | 16 9: | 1 1: | 5.760.000 |
| | Definition | | | | | | | |
| | Plus | | | | | | | |
| QSXGA+ | Quad | 2800 | × | 2100 | 4 3: | 4 3: | 1 1: | 5.880.000 |
| | SXGA+ | | | | | | | |
| DFHD | Double Full | 3840 | × | 1080 | 3 2:9 | 3 2:9 | 1 1: | 4.147.200 |
| | HD | | | | | | | |
| 2K+ | Quad HD+ | 2880 | × | 1440 | 18:9 | 18:9 | 1 1: | 4.147.200 |
| 2K+ | Quad HD+ | 2960 | × | 1440 | 18, 5:9/ | 18, 5:9/ | 1 1: | 4.262.400 |
| | | | | | 19:9 | 19:9 | | |
| DWUXGA | Double | 3840 | × | 1200 | 3 2:10 | 3 2: 10 | 1 1: | 4.608.000 |
| | WUXGA | | | | | | | |
| WQSXGA | Wide | 3200 | × | 2048 | 25: 16 | 25: 16 | 1 1: | 6.553.600 |
| | QSXGA | | | | | | | |
| QUXGA | Quad | 3200 | × | 2400 | 4 3: | 4 3: | 1 1: | 7.680.000 |
| | UXGA[2] | | | | | | | |
| HSVGA | Hex SVGA | 3200 | × | 2400 | 4 3: | 4 3: | 1 1: | 7.680.000 |
| UWQHD, | Ultra Wide | 3440 | × | 1440 | 21 9: | 4 3: 18 | 1 1: | 4.953.600 |
| 1440p | QHD (QHD) | | | | | | | |
| QHD | Quad High | 3440 | × | 1440 | 21 9: | 4 3:18 | 1 1: | 4.953.600 |
| 1440p | Definition | | | | | | | |
| UWQXGA | Ultra Wide | 3840 | × | 1600 | 2.35 1: | 2.35 1: | 1 1: | 6.144.000 |
| | QXGA | | | | | | | |
| QHD+ | Quad High | 3840 | × | 1600 | 2.35 1: | 2.35 1: | 1 1: | 6.144.000 |
| 1600p | Definition | | | | | | | |
| UW4k | Plus (Ultra | | | | | | | |
| | Wide 4K) | | | | | | | |
| UHD | Ultra High | 3840 | × | 2160 | 16 9: | 16 9: | 1 1: | 8.294.400 |
| 4K, | Definition | | | | | | | |
| 2160p | “4K”[3] | | | | | | | |
| QWUXGA | Quad | 3840 | × | 2400 | 8 5: | 8 5: | 1 1: | 9.216.000 |
| | WUXGA | | | | | | | |
| WQUXGA | Wide | 3840 | × | 2400 | 8 5: | 85: | 1 1: | 9.216.000 |
| | QUXGA | | | | | | | |
| 4K-DCI, | 4K-Digital | 4096 | × | 2160 | 256: 135 | 256: 135 | 1 1: | 8.847.360 |
| 4K2K | Cinema | | | | | | | |
| | Initiatives, | | | | | | | |
| | High | | | | | | | |
| | Definition, | | | | | | | |
| | “4K2K”[3] | | | | | | | |
| Apple | | 4096 | × | 2304 | 16 9: | 16 9: | 11 | 9.437.184 |
| iMac | | | | | | | | |
| Retina | | | | | | | | |
| 4K | | | | | | | | |
| HXGA | Hex XGA | 4096 | × | 3072 | 4 3: | 4 3: | 1 1: | 12.582.912 |
| DQHD | Double | 5120 | × | 1440 | 3 2:9 | 3 2:9 | 1 1: | 7.372.800 |
| | QHD | | | | | | | |
| WUHD | Wide UHD, | 5120 | × | 2160 | 21 9: | 21 9: | 1 1: | 11.059.200 |
| | “5K2K”[3] | | | | | | | |
| UHD+ | Ultra High | 5120 | × | 2880 | 16 9: | 16 9: | 1 1: | 14.745.600 |
| | Definition | | | | | | | |
| | Plus, | | | | | | | |
| | “5K”[3] | | | | | | | |
| WHXGA | Wide HXGA | 5120 | × | 3200 | 8 5: | 8 5: | 1 1: | 16.384.000 |
| Apple | | 6016 | × | 3384 | 16 9: | 16 9: | 1 1: | 20.358.144 |
| Pro | | | | | | | | |
| Display | | | | | | | | |
| XDR | | | | | | | | |
| HSXGA | Hex SXGA | 5120 | × | 4096 | 5 4: | 5 4: | 1 1: | 20.971.520 |
| WHSXGA | Wide | 6400 | × | 4096 | 25: 16 | 25: 16 | 1 1: | 26.214.400 |
| | HSXGA | | | | | | | |
| HUXGA | Hex UXGA | 6400 | × | 4800 | 4 3: | 4 3: | 1 1: | 30.720.000 |
| FUHD, | Full UHD, | 7680 | × | 4320 | 16 9: | 16 9: | 1 1: | 33.177.600 |
| 4320p | 8K[3] | | | | | | | |
| WHUXGA | Wide | 7680 | × | 4800 | 8 5: | 85: | 1 1: | 36.864.000 |
| | HUXGA | | | | | | | |
| 8K-DCI | 8K-Digital | 8192 | × | 4320 | 256: 135 | 256: 135 | 1 1: | 35.389.440 |
| | Cinema | | | | | | | |
| | Initiatives | | | | | | | |
| QUHD, | Quad UHD, | 15360 | × | 8640 | 16 9: | 16 9: | 1 1: | 132.710.400 |
| 8640p | “16K”[3] | | | | | | | |

The following video formats, for example, can be considered for transferring the video sequences from the sensor head 21 to a higher-level computer system 28:

Some video formats: (Source: https://de.wikipedia.org/wiki/Bildauf1%C3%B6sung)

| | Tech- | | | Aspect | |
|---|---|---|---|---|---|
| Format | nology | Width | Height | ratio | pixel |
| VHS | analog | 320 | 240 | 4:3 | 76,800 (0.08 MP) |
| Hi8 | analog | 533 | 400 | 4:3 | 213,200 (0.21 MP) |
| S-VHS | analog | 533 | 400 | 4:3 | 213,200 (0.21 MP) |
| LD | analog | 640 | 480 | 4:3 | 307,200 (0.30 MP) |
| VCD (PAL) | digital | 352 | 288 | 4:3 | 101,376 (0.10 MP) |
| SVCD (PAL) | digital | 480 | 576 | 4:3 | 276,480 (0.28 MP) |
| DVB (PAL), | digital | 720 | 576 | 4:3 or | 414,720 (0.41 MP) |
| DVD-Video | | | | 16:9 | |
| (PAL) | | | | | |
| HDTV | digital | 1280 | 720 | 16:9 | 921,600 (0.92 MP) |
| (“720 p”) | | | | | |
| FullHD | digital | 1920 | 1080 | 16:9 | 2,073,600 (2.07 MP) |
| (1080 p) | | | | | |
| WUXGA | digital | 1920 | 1200 | 16:10 | 2,304,000 (2.30 MP) |
| HD-MAC/ | analog/ | 2048 | 1152 | 16:9 | 2,359,296 (2.36 MP) |
| QWXGA | digital | | | | |
| 2K | digital | 2048 | 1536 | 4:3 | 3,145,728 (3.15 MP) |
| UHDV-1 | digital | 3840 | 2160 | 16:9 | 8,294,400 (8.30 MP) |
| (“2160 p”) | | | | | |
| 4K | digital | 4096 | 3072 | 4:3 | 12,582,912 (12.58 |
| | | | | | MP) |
| UHDV-2 | digital | 7680 | 4320 | 16:9 | 33,177,600 (33.20 |
| | | | | | MP) |
| UHXGA | digital | 7680 | 4800 | 16:10 | 36,864,000 (36.90 |
| | | | | | MP) |

Preferably, a video format used by the magnetic field camera for the transfer of video sequences comprises more than 70000 pixels per frame after decompression.

Preferably, the sensor head 21 transfers the video sequences to the higher-level computer system 28 at a frame rate of more than 5 fps, better more than 10 fps, better more than 20 fps, better more than 50 fps, better more than 100 fps. (fps=frames per second=frames per second)

### Advantages of the Magnetic Field Camera

The proposed disclosure presented here is freely scalable and offers a significantly better spatial resolution than current solutions.

The advantages over current technology are:
the freely selectable sensor surface of the sensor layer 5 on the underside 24 of the magnetic field camera head 21 also enables the measurement of curved and flexible surfaces;
the magnetic field camera head 21 offers an increased spatial resolution up to a maximum of the particle size of the nano-diamonds with the NV centers in the sensor layer 5. This size can be ~100 nm, for example!;
the magnetic field camera head 21 offers increased time resolution due to the high possible image transmission rate;
the magnetic field camera head 21 provides increased galvanic isolation. The sensor layer 5 is preferably made of a dielectric, insulating material and thus typically does not influence the magnetic field to be measured; and
the sensor layer 5 of the magnetic field camera head 21 is typically insensitive to electromagnetic interference and radiation and does not itself emit electromagnetic waves in the radio or microwave range. It is therefore superior to other quantum sensors.

### Fourth Example of a Spectrometer

### Proposal

The document presented here proposes a high-frequency spectrum analyzer for the spectral analysis of an external signal (S_{ωnk}) as a fourth embodiment example. However, the principles of the device presented here go beyond this. Therefore, the document presented here also describes other devices, methods and applications based on these principles.

The proposed high frequency spectrum analyzer typically comprises one or more sensor elements (SE, 5). Preferably, the high frequency spectrum analyzer comprises a magnetic field generating device (L_{c}), which may be electrically controlled and/or may be realized by a permanent magnet (PM) and/or by a gradient afflicted permanent magnet (GPM). Preferably, these generate an additional magnetic field whose flux density (Bad) depends on the position within a sensor element (SE) and/or along a waveguide (1380, 1880, 2380, 6830, 6980). The radio frequency spectrum analyzer therefore preferably comprises a waveguide (1380, 1880, 2380, 6830, 6980) having a longitudinal extension with a waveguide extension coordinate (x) along this longitudinal extension. The points on the waveguide (1380, 1880, 2380, 6830, 6980) along the longitudinal extension of the waveguide (1380, 1880, 2380, 6830, 6980) then typically correlate with a unique waveguide extension coordinate (x). The sensor elements (SE, 5) are preferably placed above the waveguide (1380, 1880, 2380, 6830, 6980) along the transport direction for electromagnetic radiation along the waveguide (1380, 1880, 2380, 6830, 6980). The sensor elements (SE, 5) preferably comprise a multiplicity of crystals and/or diamond nano crystals (ND). The crystals and/or diamond nano crystals (ND) typically comprise paramagnetic centers, preferably NV centers in diamond as diamond nano crystals (ND). The paramagnetic centers typically emit fluorescence radiation (FL) with a fluorescence radiation wavelength (λ_{fl}) upon exposure to pump radiation (LB) of a pump radiation wavelength (λₚₘₚ). The intensity (Iᵢₛₜ(x), Iᵢₛₜ(y)) of the emission of the fluorescence radiation (FL) typically depends on the frequency of the microwave signal (μW) and the total flux density (B_{Σ}) at the location of the respective paramagnetic center within the sensor elements (SE, 5). The radio frequency spectrum analyzer feeds the external signal (S_{ωnk}) or a microwave mixing signal (μW_MX_I) mixed with the external signal (S_{ω nk}) and then typically filtered signal, the filtered, mixed microwave mixing signal, into the waveguide (1380, 1880, 2380, 6830, 6980) as a microwave signal (μW) for analysis. The waveguides (1380, 1880, 2380, 6830, 6980) can be various planar waveguides in particular. This microwave signal (μW) then typically interacts with the paramagnetic centers in the sensor elements (SE, 5). The magnetic field generating device (L_{c}) then floods the sensor elements (SE, 5) with a magnetic field with an additional magnetic flux density (B_{ad}(x), B_{ad}(y)). Preferably, the sensor element (SE) is an extended sensor element layer (5), the areal fluorescence radiation (FL) of which is detected spatially resolved by a magnetic field camera, which is preferably part of the high-frequency spectrum analyzer, by means of a light sensor array (1) of photo detectors (PD). This additional magnetic flux density (B_{ad}(x), B_{ad}(y)) then contributes to the respective total flux density (Bg) at the respective position (x, y) of the respective paramagnetic center in the sensor element (SE) or in the sensor element layer (5) at the associated waveguide extension coordinate (x, y). The high-frequency spectrum analyzer preferably comprises means for detecting the measured value curve of the intensity curve (Iᵢₛₜ(x), Iᵢₛₜ(y)) of the emission of the fluorescence radiation (FL) along the waveguide (1380, 1880, 2380, 6830, 6980). Such a means may comprise, for example, device parts of a magnetic field camera. The high-frequency spectrum analyzer is preferably configured to determine the intensity curve (Iᵢₛₜ(x), Iᵢₛₜ(y)) of the emission of the fluorescence radiation (FL) along the waveguide (1380, 1880, 2380, 6830, 6980) to infer a high-frequency spectrum (Kₛ(ω_{μW}), K_{w}(ω_{μW})) of the external signal (S_{ω nk}). The advantage of such a device is that the course of the fluorescence intensity of the intensity Iᵢₛₜ(x), Iᵢₛₜ(y) of the fluorescence radiation (FL) along the sensor element (SE, 5) along the waveguide in a magnetic field with a gradient along the waveguide, in particular of a gradient afflicted permanent magnet (GPM), can be converted extremely quickly into a spectrum K (ω_{μW}) of the external signal (S_{ω nk}) by means of a simple transformation after detecting by a magnetic field camera and/or a multiplicity of photo detectors (PD).

In a particular embodiment, the radio frequency spectrum analyzer comprises a first waveguide (6980_I) and a second waveguide (6980_II) as waveguides (1380, 1880, 2380, 6830, 6980), wherein the first waveguide (6980_I) is different from the second waveguide (6980_II). In this embodiment, the radio frequency spectrum analyzer generates a first microwave signal (μW_I) by mixing the external signal (S_{ω nk}) with a first internal microwave signal (μW_G_I) at a first internal microwave frequency (ω_{μW_I}). In this embodiment, the radio frequency spectrum analyzer generates a second microwave signal (μW_II) by mixing the external signal (S_{ω nk}) with a second internal microwave signal (μW_G_II) with a second internal microwave frequency (ω_{μw_II}). Preferably, the radio frequency spectrum analyzer then feeds the first microwave signal (μW_I) into the first waveguide (6980_I). Preferably, the radio frequency spectrum analyzer feeds the second microwave signal (μW_II) into the second waveguide (6980_II). Preferably, the high-frequency spectrum analyzer comprises means of detecting the measured value curve of the intensity curves (Iᵢₛₜ(x), Iᵢₛₜ(y)) of the emission of the fluorescence radiation (FL) along the waveguide coordinate (x) of the first waveguide (6980_I) and along the waveguide coordinate (y) of the second waveguide (6980_II). In this embodiment, the high-frequency spectrum analyzer is then preferably configured to calculate the intensity curves (Iᵢₛₜ(x), Iᵢₛₜ(y)) of the emission of the fluorescence radiation (FL) along the waveguide coordinate (x) of the first waveguide (6980_I) and along the waveguide coordinate (y) of the second waveguide (6980_II) to infer one or more high-frequency spectra (Kₛ(ω_{μW}), K_{w}(ω_{μW})) of the external signal (S_{ωnk}). The advantage of such a construction is that different vertical lines in the diagram in FIG. 2 can be scanned simultaneously and therefore more quickly. This makes it possible to determine the position (30) of the V-formation from the lower resonance edge (522) and the upper resonance edge (525) (see FIG. 51b) more precisely and very quickly.

A microwave signal to be characterized (S_{ω nk}) is guided, for example, in a planar waveguide whose surface is covered with NV powder and preferably also subjected to a static magnetic field distribution. Microwave radiation of a certain frequency leads to an attenuation of the fluorescence intensities at positions of certain magnetic field strengths, whereby the microwave spectrum can be reconstructed by evaluating the fluorescence intensity distribution.

This enables an optical broadband single-shot spectrum analyzer for microwave radiation in the frequency range from approx. 0.1 to 100 GHz.

The unknown microwave signal (S ωₙₖ) is fed into a microwave component, for example a waveguide (e.g. a planar PCB), which carries the microwave signal (μW) of the microwaves (e.g. coplanar waveguide). A microwave component can also be an interconnection of several microwave components. Such a microwave component may also be able to spectrally separate the unknown microwave signal and/or couple it to resonators (e.g. ring resonators). The microwave component is preferably designed in such a way that evanescent microwave fields are present on the surface. This surface is coated with the NV diamond powder. This can be done, for example, by a mixture of NV diamond powder with diamond nano crystals (ND) powder or another crystal powder with other paramagnetic centers and UV-curable substrate material TM). After applying this colloidal mixture to a microwave component, the UV-curable adhesive (substrate material TM) is preferably cured by means of UV radiation (curing radiation 4910). Other adhesives (substrate materials TM) with other curing methods are conceivable. The curing process creates the actual sensor element (SE).

Furthermore, permanent magnets (PM, GPM) or electromagnets (magnetic field generation means L_{c}) generate an additional magnetic field distribution (B_{ad}) in the NV diamond powder of the sensor element (SE), which is preferably perpendicular to the magnetic field (B_{μW}) of the microwave field.

In addition, the NV diamond powder is excited by a suitable light source (e.g. green LED) as a pump radiation source to emit fluorescence radiation (FL). A photodetector array (1) and/or a camera measure the distribution of the fluorescence radiation's intensity Iᵢₛₜ(t) across the waveguide.

Microwave radiation of a certain microwave frequency (ω_{μW}) causes a characteristic fluorescence intensity attenuation of the intensity Iᵢₛₜ(t) of the fluorescence radiation of the NV centers in the diamond crystals of the NV diamond powder. This fluorescence intensity attenuation typically depends on the strength of the static magnetic field at the NV centers or paramagnetic centers associated with the respective photo detector of the respective measurement pixel.

By measuring the fluorescence radiation distribution intensity Iᵢₛₜ(t) of the NV centers in the diamond crystals of the NV diamond powder with a camera (or another sensor or photodetector array) and knowing the distribution of the static magnetic field (in particular after prior calibration of the measuring device), the spectral components of the microwave signal (S_{ω nk}) can be reconstructed.

A first essential advantage of using NV diamond powder, which comprises many small, disordered diamond crystals (diamond nano crystals ND) with NV centers, over the use of single crystal diamond is mainly the simplicity of production, which no longer requires alignment of a single crystal diamond with respect to a magnetic field. Such a colloidal mixture (KL) of NV diamond crystals and an Adhesive as substrate material (TM) can be easily handled by spin-coating, dispensing or printing and is therefore batch-capable, which massively reduces the manufacturing costs for these sensor systems and results in CMOS compatibility and CMOS fab capability.

What is new is the idea of placing such a mixture on a waveguide (1380, 1880, 2380, 6830, 6980), and in particular in a self-aligned manner. The colloidal mixture (KL) is therefore easily deposited on a printed circuit board (PCB) or a wafer of micro integrated semiconductor circuits which may comprise said waveguides (1380, 1880, 2380, 6830, 6980).

The spectrometer presented here can therefore be micro-integrated.

The NV powder layer comprising diamond nano crystals (ND) with NV centers and/or paramagnetic centers and/or comprising crystals with paramagnetic centers is preferably thin and thus interacts well with the evanescent components of the microwave fields guided in the PCB.

Preferably, the thickness D_{SE} of the sensor element SE and/or the sensor element layer 5 is thinner than the width of the smallest structures of the respective waveguide in order to ensure good resolution.

By mixing the NV diamond powder with diamond nano crystals (ND) with NV centers and/or paramagnetic centers and/or crystals with paramagnetic centers with an adhesive as substrate material, the NV powder can be applied specifically to regions of the PCB and/or the wafer in which the evanescent microwave field of the microwave signal (μW) comprises a high amplitude and suitable orientation.

In contrast to single-crystal diamonds, no alignment of NV diamond crystals is necessary in the technical teaching presented in this document, since all spatial directions in the NV powder are statistically equally distributed as alignment directions of the NV center axes.

Compared to other spectrum analyzers, a device according to the technical teaching presented here can cover a very wide frequency range with the measurement technology presented here. The measuring range is given by the maximum applied static magnetic field (28 GHz/Tesla). This results in a measuring range of approx. 0-70 Ghz for a magnetic field distribution of 0 T to 2.5 T, for example. The biggest advantage, however, is that when using a magnetic field camera, the entire measuring range can be measured with a “single shot” by means of individual frames of a magnetic field camera. A tuning of a microwave frequency, such as for a heterodyne measurement, is not necessary with the measurement technique presented here.

During the preparation of the document presented here, it was furthermore recognized that the device is also suitable for the high-precision measurement of unknown external magnetic flux densities (Bₑₓₜ).

The device can therefore PARALLEL determine an unknown microwave frequency (ωₙₖ) and an unknown magnetic flux density (Bₑₓₜ).

Due to the large parallelism of the measurements, the multiplicity of measured values can be used for a significant error reduction. The technical teaching presented here therefore enables broadband, fast and highly accurate measurements of magnetic flux densities (Bₑₓₜ) and/or microwave frequencies (ω_{μW}).

This results in the following areas of application for the technical teaching presented here, for example:

Magnetocardiography (MKG): The sensor systems presented here can be used, for example, for detecting and recording magnetic fields generated by the heart of a human or animal. Magnetocardiography enables a non-invasive examination of heart activity and can be used to diagnose heart disease.

Magnetoencephalography (MEG): The sensor systems presented here can be used, for example, to measure the magnetic fields generated by the electrical activity of a person's or animal's brain. Magnetoencephalography enables high-resolution imaging of brain activity and can be used in neuroscience and clinical diagnostics.

Neurointerfaces: The sensor systems presented here can be used, for example, to measure the magnetic fields generated by the electrical activity of the brain of humans or animals, whereby the measured values detected can then be used directly or indirectly to control computers and/or computer systems and/or quantum computers, which in turn can control actuators or fill databases with data.

Biomagnetics: The sensor systems presented here can be used, for example, in the research and measurement of magnetic fields generated by biological organisms. This comprises studies on magnetoreception in animals, investigations into brain function and activity, but also the detection of cancer using magnetic markers in medical imaging.

Material characterization: The sensor systems presented here can be used, for example, to characterize the magnetic properties of materials. This comprises the measurement of magnetic susceptibility, critical magnetic fields and magnetization curves, which provide important information about the material properties. This includes the detection and visualization of material defects such as cracks, voids and inhomogeneities.

Geophysical exploration: The sensor systems presented here can be used in geophysics, for example, to measure magnetic fields and map geological structures. This comprises the search for mineral resources, the investigation of the earth's crust and research into the earth's magnetic field.

Quantum informatics and quantum computing: The sensor systems presented here can be used, for example, in some approaches for the realization of quantum bits (qubits) in quantum computers. They enable the measurement and control of quantum states and are likely to be useful for the development of scalable quantum computers.

Detection of weak magnetic signals: Due to their high sensitivity, the sensor systems presented here can be used in various applications to detect weak magnetic signals, for example. This comprises the investigation of material defects, non-destructive testing, magnetic resonance imaging (MRI) and the detection of biomagnetic signals.

Current measurement: The sensor systems presented here can be used, for example, for non-invasive measurement of current levels in electrical systems. They can be used in power electronics, electric vehicles, solar modules, power components (IGBTs, thyristors, diodes, etc.) and other applications to monitor the current flow.

Speed and position control: The sensor systems presented here can be used, for example, to detect the speed and position of rotating and/or translationally moving components such as motors, fans and gears. They enable precise regulation and control of the relevant movement.

Automotive applications: The sensor systems presented here can be used in various applications in the automotive industry, for example. These include detecting the crankshaft position, camshaft signal, wheel speed, steering angle and other parameters for engine control, the anti-lock braking system (ABS), traction control and other safety-relevant systems.

Magnetic field measurement: The sensor systems presented here can be used, for example, to measure and monitor magnetic fields. This can be done in regions such as magnetic sensor technology, material characterization, geophysics, robotics and other scientific and industrial applications.

Security and alarm systems: The sensor systems presented here can be used in security systems, for example, to monitor the opening or closing of doors, windows and other access points. They can also be used in alarm systems to detect intruders or to monitor movements.

Power supply and energy efficiency: The sensor systems presented here can be used, for example, in power supply systems to monitor energy consumption and optimize energy efficiency. They can be used in smart grids, electric vehicle charging systems and other applications to enable accurate measurement and control.

Electronics and communication: The sensor systems presented here can be used in electronics and communication technology, for example, to detect and reduce magnetic interference. They can also be used in non-contact switches, locking systems, joysticks and other electronic devices and for troubleshooting in electronic circuits and microelectronic circuits.

Industrial automation: The sensor systems presented here can be used in industrial automation, for example, to detect positions, angles, angular velocities, angular accelerations, speeds, accelerations and movements. They enable precise control of machines and processes.

### Carrier Substrate

In order to be able to realize such a high frequency spectrum analyzer, the document presented here proposes a carrier substrate (1360), in particular for such a high frequency spectrum analyzer and/or for devices for determining magnetic flux densities. The carrier substrate (1360) typically comprises a surface having one or more waveguides (1380, 1880, 2380, 6830, 6980). According to a proposal, the carrier substrate (1360) comprises a sensor element (SE) for detecting the component of a total flux density (B_{Σ}) parallel and/or perpendicular to the surface of the carrier substrate (1360) and parallel and/or perpendicular to the direction of the waveguides (1380, 1880, 2380, 6830, 6980), wherein the component of the total flux density (B_{Σ}) depends on the size and position of the sensor element (SE) relative to the structures of the waveguide. According to a proposal, the sensor element (SE) comprises a multiplicity of crystals and/or diamond nano crystals (ND), wherein the crystals, if present, and diamond nano crystals (ND), if present, comprise paramagnetic centers, in particular and preferably NV centers in diamond as diamond nano crystals (ND). The preferred diamond nano crystals (ND) with NV centers and/or paramagnetic centers are preferably present as diamond powder prior to processing. The sensor element (SE) preferably comprises a substrate material (TM) in which the crystals and/or diamond nano crystals (ND) are typically embedded. In principle, the vector of the magnetic flux density of a microwave signal (μW) in the microwave line (1380, 1880, 2380, 6830, 6980) and the axis of the NV centers or paramagnetic centers in the crystals and/or diamond nano crystals (ND) of the sensor element (SE) must be perpendicular to each other. In contrast, the axis of the external magnetic field must typically be parallel to the NV center axis or the axis of the paramagnetic centers in order to show a reduction in the intensity Iᵢₛₜ(t) of the fluorescence radiation (FL) of the paramagnetic centers or NV centers at resonance between the microwave signal (μW) and the NV center or the paramagnetic center. In order to be used as intended, the substrate material (TM) is preferably essentially transparent to electromagnetic radiation (pump radiation LB) of a pump radiation wavelength (λₚₘₚ) and essentially transparent to electromagnetic radiation (fluorescence radiation FL) of a fluorescence radiation wavelength (λ_{fl}). Typically, paramagnetic centers of the crystals and/or the diamond nano crystals (ND) emit fluorescence radiation (FL) of a fluorescence wavelength (λ_{fl}) when exposed to pump radiation (LB) of the pump radiation wavelength (λₚₘₚ). Preferably, the sensor element (SE) now comprises a width (d_{SE}). According to the proposal, this now results in different positionings for the sensor element (SE, 5) relative to a waveguide (1380, 1880, 2380, 6830, 6980):

Firstly, corresponding to a sensor element position A of the sensor element (SE):

When the sensor element (SE, 5) is positioned in accordance with a sensor element position A of the sensor element (SE), the waveguide (1380, 2380, 6830, 6980) comprises only one signal line (1330) or a differential signal line (6830) comprising two signal lines (6810, 6820). When the sensor element (SE, 5) is positioned in accordance with a sensor element position A of the sensor element (SE), the respective sensor element (SE) is located on the respective signal line (1330, 6810, 6820) and is preferably permanently connected to the respective signal line (1330, 6810, 6820). The respective signal line (1330, 6810, 6820) in question typically comprises a respective width (dₛ). According to the proposal, the respective width (d_{SE}) of the respective sensor element (SE) is preferably smaller than the respective width (dₛ) of the respective signal line (1330, 6810, 6820) in some application cases.

Secondly, corresponding to a sensor element position B of the sensor element (SE):

When the sensor element (SE, 5) is positioned according to a sensor element position B of the sensor element (SE), the waveguide (1880, 2380, 6830, 6980) comprises a non-conductive insulation gap (1840, 2340, 2350, 6840). When the sensor element (SE, 5) is positioned according to a sensor element position B of the sensor element (SE), the respective sensor element (SE) is preferably located in the respective non-conductive insulation gap (1840, 2340, 2350, 6840) and the respective sensor element (SE) is preferably firmly connected to the surface of the respective non-conductive insulation gap (1840, 2340, 2350, 6840). Typically, the respective non-conductive insulation gap (1840, 2340, 2350, 6840) comprises a respective width (d_{IS1}, d_{IS2}, d_{SL}). Preferably, the respective width (d_{SE}) of the respective sensor element (SE) is smaller than the respective width (d_{IS1}, d_{IS2}, d_{SL}) of the respective non-conductive insulation gap (1840, 2340, 2350, 6840).

Thirdly, corresponding to a sensor element position C of the sensor element (SE):

When the sensor element (SE, 5) is positioned according to a sensor element position C of the sensor element (SE), the waveguide (1380, 6830) comprises a signal line (1330, 6810, 6820) and an electrically essentially non-conductive insulation area (1340, 1350). When the sensor element (SE, 5) is positioned in accordance with a sensor element position C of the sensor element (SE), the respective sensor element (SE) is preferably located on the respective electrically essentially non-conductive insulation area (1340, 1350) and is preferably firmly connected to the respective electrically essentially non-conductive insulation area (1340, 1350). The respective signal line (1330, 6810, 6820) comprises a respective width (dₛ), wherein preferably the respective width (d_{SE}) of the respective sensor element (SE) is smaller than the respective width (dₛ) of the respective signal line (1330, 6810, 6820) and wherein preferably the maximum distance of a part of the respective sensor element (SE) from the respective nearest edge of the respective signal line (1330, 6810, 6820) is less than twice the respective width (dₛ) of the respective signal line (1330, 6810, 6820).

Fourth, corresponding to a sensor element position D of the sensor element (SE):

When the sensor element (SE, 5) is positioned according to a sensor element position D of the sensor element (SE), the waveguide (1880, 2380, 6980) comprises a non-conductive insulation gap (1840, 2340, 2350, 6840) and an electrically conductive signal ground plane (1310, 1320). When the sensor element (SE, 5) is positioned in accordance with a sensor element position D of the sensor element (SE), the respective sensor element (SE) is located on the respective electrically conductive signal ground plane (1310, 1320) and is preferably firmly connected to the respective electrically conductive signal ground plane (1310, 1320). Preferably, the respective non-conductive insulation gap (1840, 2340, 2350, 6840) comprises a respective width (d_{IS1}, d_{IS2}, d_{SL}), wherein preferably the respective width (d_{SE}) of the sensor element (SE) is smaller than the respective width (d_{IS1}, d_{IS2}, d_{SL}) of the respective non-conductive insulation gap (1840, 2340, 2350, 6840) and wherein preferably the maximum distance of a part of the respective sensor element (SE) from the respective nearest edge of the respective non-conductive insulation gap (1840, 2340, 2350, 6840) is smaller than twice the respective width (d_{IS1}, d_{IS2}, d_{SL}) of the respective non-conductive insulation gap (1840, 2340, 2350, 6840).

In a further embodiment of the carrier substrate (1360), the substrate material (TM) comprises a radiation cured substrate material (TM). In a further embodiment of the carrier substrate (1360), the substrate material (TM) comprises a UV radiation cured substrate material (TM).

Carrier Substrate Set with High Cₚₖ Value

The manufacturing techniques described in the present document, in particular self-aligning techniques, enable the manufacturing of sensor elements (SE) with a high Cₚₖ value. Preferably, the Cₚₖ value is determined using an arbitrary carrier substrate set as a sample, wherein the carrier substrate set comprises a plurality of carrier substrates (1360). Preferably, the carrier substrate set comprises a plurality of at least 10 and/or more preferably at least 20 and/or more preferably at least 50 and/or more preferably at least 100 carrier substrates (1360). In order to be able to determine a meaningful Cₚₖ value, the carrier substrates (1360) of the carrier substrate set should be constructed in essentially the same way (be identical in construction). Typically, each of the carrier substrates (1360) of the carrier substrate set comprises at least one waveguide (1380, 1880, 2380, 6830, 6980). Furthermore, the at least one waveguide (1380, 1880, 2380, 6830, 6980) of each respective carrier substrate (1360) of the carrier substrate set typically has at least one of the structural elements:
a signal conductor (1330) with a width (dS) and/or
an essentially electrically non-conductive left-hand insulation gap (2340) with a width (dIS1) and/or
an essentially electrically non-conductive right-hand insulation gap (2350) with a width (dIS2) and/or
a slot (1840) with a width (dSL) and/or
a left signal conductor (6810) with a width (dS) and/or
a right signal conductor (6820) with a width (dS) and/or
an electrically insulating gap (6840) with a width (dSL)
   as the respective structural element. Thus, each of the respective carrier substrates (1360) of the carrier substrate set comprises at least one respective sensor element (SE) of the respective carrier substrate (1360) of the carrier substrate set having a respective diameter (dSE) and its respective center of the respective sensor element (SE) of the respective carrier substrate (1360) of the carrier substrate set. The respective sensor element (SE) of the respective carrier substrate (1360) of the carrier substrate set is typically located on or in the at least one respective structural element of the at least one respective waveguide (1380, 1880, 2380, 6830, 6980) of the respective carrier substrate (1360). This respective structural element of the respective carrier substrate (1360) of the carrier substrate set comprises in each case the said respective width and a respective center of this respective structural element of the respective carrier substrate (1360) at half its respective width. The respective center of the at least one respective sensor element of the respective carrier substrate (1360) of the carrier substrate set is typically offset from the respective center of this respective structural element of the respective carrier substrate (1360) by a respective offset due to the manufacturing process. The Cₚₖ value determined from these respective offsets of the respective carrier substrates (1360) as respective dispersions and the mean width of the respective width of the at least one respective structural element of the respective carrier substrates (1360) as a tolerance interval for the offset of the respective sensor elements (SE) with respect to the respective structural element for the entirety of the carrier substrates (1360) of this carrier substrate set is, when using the manufacturing techniques presented here, self-adjusting production techniques presented here, if the methods are applied correctly, is better than 1.66 and thus suitable for production in automotive supply chains.

The respective structural elements of the respective carrier substrates (1360) of the carrier substrate set measured to determine the C (pk) value of the carrier substrate set are preferably the same respective structural elements for all respective carrier substrates of the carrier substrates (1360) of the carrier substrate set. The respective sensor elements (SE) of the respective carrier substrates (1360) of the carrier substrate set measured to determine the Cₚₖ value of the carrier substrate set are preferably the same respective sensor elements (SE) for all respective carrier substrates of the carrier substrates (1360) of the carrier substrate set.

For the purposes of the present document, a structural element can also be composed of several of the structural elements presented here lying next to one another on the respective carrier substrates (1360).

Of course, a Cₚₖ value can also be formed from the widths of the respective sensor elements (SE) of the respective carrier substrates (1360) of the carrier substrate set and the average widths of the structural elements of the respective carrier substrates (1360) of the carrier substrate set as a tolerance measure, which can also be greater than 1.66 due to the manufacturing processes disclosed herein. Such carrier substrate sets are therefore part of the disclosure and potential claim of the present document. General Sensor Systems

As already indicated, the system of the radio frequency spectrum analyzer can also be used as a general sensor system. Such a general sensor system typically comprises a control device (CTR) for setting a magnetic flux density (B_{Σ}, B_{ad}) as a first measurement parameter within a first measurement parameter interval and for setting a microwave frequency (ω_{μW}) of a microwave signal (μW) as a second measurement parameter within a second measurement parameter interval. The general sensor system preferably further comprises a sensor element (SE, 5) with a multiplicity of crystals and/or diamond nano crystals (ND), wherein the multiplicity of crystals and/or diamond nano crystals (ND) are embedded in a substrate material (TM) of the sensor element (SE) and are typically oriented essentially differently. The multiplicity of crystals and/or diamond nano crystals (ND) preferably comprises paramagnetic centers, in particular NV centers in diamond as diamond nano crystals (ND). Preferably, the sensor system comprises a pump radiation source in the form of a light source (LED), wherein the pump radiation source is preferably configured to irradiate the paramagnetic centers of the multiplicity of crystals and/or the diamond nano crystals (ND) of the sensor element (SE, 5) with pump radiation (LB) of a pump radiation wavelength (λₚₘₚ). The paramagnetic centers of the multiplicity of crystals and/or diamond nano crystals (ND) of the sensor element (SE, 5) emit fluorescence radiation (FL) with a fluorescence radiation wavelength (λ_{fl}) upon exposure to the pump radiation (LB) of the pump radiation wavelength (λₚₘₚ). Preferably, the sensor system (SE) is configured to parameterize its device parts for measuring a set measurement point from a first value of the first measurement parameter and a second value of the second measurement parameter. The sensor element (SE) is preferably configured to serve to determine a sensor element measured value for this set measuring point, the sensor element measured value corresponding to the fluorescence intensity value of the intensity Iᵢₛₜ(t) of the fluorescence radiation (FL) and/or an attenuation of the intensity Iᵢₛₜ(t) of the fluorescence radiation (FL) and or depending on these. The sensor element measurement value typically depends on the first measurement parameter and the second measurement parameter. Typically, the sensor element measured value in an X-Y plane with the first measured value as X-coordinate and the second measured value as Y-coordinate forms a V-formation of a lower resonance edge (522) and an upper resonance edge (525). (See FIG. 2) The V-formation (522, 525) comprises a peak (530) of the V-formation, which may also lie in the region that can no longer be measured and can therefore only be inferred indirectly. Preferably, the control device (CTR) is configured to use a computer-implemented method to determine, in particular, the next measurement point with as few iterations as possible, wherein the next measurement point preferably comprises a next first measurement parameter and a next second measurement parameter.

In a further embodiment of the sensor system, the control device (CTR) therefore preferably applies one or more of the following computer-implemented methods as a computer-implemented method:
a computer-implemented machine learning method;
a computer-implemented method for applying computer-implemented optimization algorithms;
a computer-implemented machine learning method using a method of computer-implemented Bayesian optimization;
a computer-implemented method of computer-implemented random forest regression;
a computer-implemented method of computer-implemented Gaussian process regression;
a computer-implemented method using a computer-implemented neural network model;
a computer-implemented method of computer-implemented gradient-based optimization;
a computer-implemented method of computer-implemented gradient descent;
a computer-implemented method of computer-implemented stochastic gradient descent;
a computer-implemented method of computer-implemented simulated annealing;
a computer-implemented method of computer-implemented particle swarm optimization;
a computer-implemented method using computer-implemented genetic algorithms a computer-implemented method using a computer-implemented method of Bayesian optimization; and/or
a computer-implemented method of the computer-implemented Nelder-Mead algorithm.

As already indicated, the system of the radio frequency spectrum analyzer can also be used as a general sensor system in another embodiment. Such a general sensor system comprises, for example, a control device (CTR) for setting a magnetic flux density (B_{Σ}, B_{ad}) as a first measurement parameter within a first measurement parameter interval and for setting a microwave frequency (ω_{μW}) of a microwave signal (μW) as a second measurement parameter within a second measurement parameter interval. The general sensor system preferably again comprises a sensor element (SE, 5) with a multiplicity of crystals and/or diamond nano crystals (ND), wherein the multiplicity of crystals and/or diamond nano crystals (ND) are preferably embedded in a substrate material (TM) of the sensor element (SE) and wherein preferably the multiplicity of crystals and/or diamond nano crystals (ND) are essentially oriented differently. Preferably, the multiplicity of crystals and/or diamond nano crystals (ND) comprises paramagnetic centers, in particular NV centers. Preferably, the general sensor system typically comprises a pump radiation source in the form of a light source (LED), wherein the pump radiation source is preferably configured to irradiate the paramagnetic centers of the multiplicity of crystals and/or diamond nano crystals (ND) of the sensor element (SE, 5) with pump radiation (LB) of the pump radiation wavelength (λₚₘₚ), and wherein the paramagnetic centers of the multiplicity of crystals and/or diamond nano crystals (ND) of the sensor element (SE, 5) emit fluorescence radiation (FL) with a fluorescence radiation wavelength (λ_{fl}) upon exposure to the pump radiation (LB) of the pump radiation wavelength (λₚₘₚ). Preferably, the general sensor system is configured to parameterize its device parts for measuring a set measurement point from a first value of the first measurement parameter and a second value of the second measurement parameter. Typically, the control device (CTR) is capable of setting a first measurement parameter within a first measurement parameter interval and setting a second measurement parameter within a second measurement parameter interval. The sensor element (SE) is then preferably configured to serve to determine a sensor element measured value for this set measuring point. Preferably, the sensor element measured value corresponds to the fluorescence intensity value of the intensity Iᵢₛₜ(t) of the fluorescence radiation (FL) and/or an attenuation of the intensity Iᵢₛₜ(t) of the fluorescence radiation (FL) and/or depends on these. Typically, the sensor element measured value depends at least on the first measurement parameter and the second measurement parameter. The first measurement parameter can be, for example, the total magnetic flux density (B_{Σ}) or the additional magnetic flux density (B_{ad}), which contributes to the total magnetic flux density (Bg). When measuring in this way with different measurement points from a first measurement parameter value of the first measurement parameter and a second measurement parameter value of the second measurement parameter, the sensor element measurement values detected via the X-Y surface of these two measurement parameters form a V-formation in this X-Y plane with the first measurement value as the X coordinate and the second measurement value as the Y coordinate. A lower resonance edge (522) and an upper resonance edge (525) form this V-formation. (See FIG. 51b). An essential idea of the document presented here is to recognize the position of this V-formation by pattern recognition and to derive measured values from it, since the size, orientation and structure are essentially already determined at the atomic level and only the position of the tip (530) of this V-formation depends on the microwave frequency (ω_{μW}) and the total magnetic flux density (B_{Σ}) or the additional magnetic flux density (B_{ad}), which contributes to the total magnetic flux density (Bg). This V-formation thus comprises the said peak (530) of the V-formation, which can also lie outside the measurable region and whose position is particularly characteristic of the position of the V-formation. Typically, the sensor element (SE) provides the sensor element measurement value as a function of the set first measurement parameter and the set second measurement parameter. The control device (CTR) is typically configured to use a computer-implemented method of determining the next measurement point comprising the next first measurement parameter and the next second measurement parameter. For this purpose, the sensor system preferably comprises a system for determining the position of a V-formation in the X-Y plane, the position being defined by the X-coordinate of the first measurement parameter and the Y-coordinate of the second measurement parameter. The sensor system may also comprise a system for determining the position (530) of the tip of the V-formation in the X-Y plane, this position also being defined by the associated X-coordinate of the first measurement parameter and the associated Y-coordinate of the second measurement parameter. Preferably, the sensor system comprises a memory device (RAM, NVM) for keeping the thus determined position of the V-formation in the X-Y plane and/or for keeping available the determined position (530) of the tip of the V-formation and/or functionally equivalent information for use by a higher-level system. For this purpose, the sensor system preferably comprises a user interface for setting parameters, such as the measurement parameter intervals and/or for retrieving the results of the position (530) of the tip of the V-formation in the X-Y plane from the first measurement parameter as X coordinate and the second measurement parameter as Y coordinate. According to the proposal, this user interface can also be addressed, operated and queried by a device, for example a higher-level computer system. The user interface can therefore also be a machine-machine interface. The user interface can be a web page generated by the control device (CTR).

As already indicated, the system of the radio frequency spectrum analyzer can also be used as a general sensor system in another third embodiment. Such a general sensor system preferably comprises, for example, a control device (CTR), wherein the general sensor system preferably comprises a control device (CTR) for setting a magnetic flux density (B_{Σ}, B_{ad}) as a first measurement parameter within a first measurement parameter interval and for setting a microwave frequency (ω_{μW}) of a microwave signal (μW) as a second measurement parameter within a second measurement parameter interval. Again, the general sensor system preferably comprises a sensor element (SE, 5) with a multiplicity of crystals and/or diamond nano crystals (ND), which are typically embedded in a substrate material (TM) of the sensor element (SE). The multiplicity of crystals and/or diamond nano crystals (ND) are preferably essentially differently oriented. Crystals and/or diamond nano crystals (ND) of the crystals and/or diamond nano crystals (ND) preferably comprise paramagnetic centers, in particular NV centers in diamond. The general sensor system again preferably comprises a pump radiation source in the form of a light source (LED), which can expose the paramagnetic centers of the multiplicity of crystals and/or diamond nano crystals (ND) of the sensor element (SE, 5) to pump radiation (LB) of a pump radiation wavelength (λₚₘₚ). As before, when exposed to the pump radiation (LB) of a pump radiation wavelength (λₚₘₚ), the paramagnetic centers of the multiplicity of crystals and/or diamond nano crystals (ND) of the sensor element (SE, 5) again typically emit fluorescence radiation (FL) of a fluorescence radiation wavelength (λ_{fl}). Preferably, the general sensor system is configured to parameterize its device parts for measuring a set measurement point from a first value of the first measurement parameter and a second value of the second measurement parameter, for example by means of its control device (CTR). Therefore, the control device (CTR) is preferably able to set a first measurement parameter within a first measurement parameter interval and to set a second measurement parameter within a second measurement parameter interval. The sensor element (SE) is typically configured to serve to determine a sensor element measured value for this set measuring point. The sensor element measured value typically corresponds to and/or depends on the fluorescence intensity value of the intensity Iᵢₛₜ(t) of the fluorescence radiation (FL) and/or an attenuation of the intensity Iᵢₛₜ(t) of the fluorescence radiation (FL). This sensor element measurement value typically depends on the first measurement parameter and the second measurement parameter. Typically, the sensor element measured value in an X-Y plane with the first measured value as X-coordinate and the second measured value as Y-coordinate forms a V-formation comprising a lower resonance edge (522) and an upper resonance edge (525). Here, the V-formation generally comprises a peak (530) of the V-formation, which may also lie outside the measurement range. Furthermore, the general sensor system of this embodiment preferably comprises the sensor element (SE) for determining a sensor element measurement value for a set measurement point based on the first measurement parameter and the second measurement parameter. Preferably, the general sensor system uses a virtual, memory-based, three-dimensional Cartesian coordinate system for entering the measured values of the sensor element (SE) into a database in the memory (RAM, NVM) of the sensor system, wherein preferably the x-coordinate on the x-axis is determined by the first measurement parameter and the y-coordinate on the y-axis is determined by the second measurement parameter and the z-coordinate on the z-axis is determined by the measured value of the sensor element (SE). Furthermore, the sensor system in this embodiment preferably comprises a position detection unit which is known and which uses the information that the maxima of the absolute value of the gradient of the measured value of the sensor element according to the x-coordinate and the y-coordinate result in a V-formation on the X-Y-plane, wherein it is typically the task of the sensor system to determine and output the position of the lower peak (530) of this V-formation (522, 525).

In a further embodiment of the preceding three embodiments of the sensor system, the control device (CTR) is preferably configured to determine the next measuring point for the next measurement of a sensor element measured value as a function of one or more already existing measured value data sets, wherein such a measured value data set typically comprises a measuring point and a sensor element measured value. This enables rapid convergence of the measured values in order to identify the true position of the V-formation and, in particular, the position of the tip (530) of the V-formation from the lower resonance edge (522) and the upper resonance edge (525) and, if necessary, to derive further measured values for the magnetic flux density B and/or the microwave frequency from this.

In a further embodiment of the four preceding embodiments of the sensor system, the control device (CTR) is preferably configured to apply the computer-implemented method for determining the next measurement point from a next first measurement parameter and a next second measurement parameter in order to determine the position of the V-formation in the X-Y plane and to calculate the position (30) of the tip of the V-formation in the X-Y plane or functionally equivalent information and to keep it available for use by a higher-level system.

In a further embodiment of the five preceding embodiments of the sensor system, the control device (CTR) is preferably configured to use the computer-implemented method to determine the position of the V-formation in the X-Y plane from the first measurement parameter as the X-coordinate and the second measurement parameter as the Y-coordinate or a functionally equivalent positional information of the V-formation and/or a functionally equivalent positional information of a feature of the V-formation by means of iteration.

In a further embodiment of the six preceding embodiments of the sensor system, the control device (CTR) is preferably configured to carry out the computer-implemented method such that the control device (CTR) determines the position indication of the V-formation and/or a functionally equivalent position indication of a feature of the V-formation with as few iterations as possible by means of the computer-implemented method.

In a further embodiment of the seven preceding embodiments of the sensor system, the control device (CTR) is preferably configured to use the computer-implemented method for determining the position of the tip (30) of the V-formation in the X-Y plane from the first measurement parameter as the X coordinate and the second measurement parameter as the Y coordinate or functionally equivalent information.

In a further embodiment of the eight preceding embodiments of the sensor system, the control device (CTR) is preferably configured to keep the thus determined position indication of the V-formation and/or a functionally equivalent position indication of a feature of the V-formation and/or the position of the tip (30) of the V-formation available for use by a higher-level system (e.g. 28).

In a further embodiment of the nine preceding embodiments of the sensor system, the control device (CTR) is preferably configured to use the computer-implemented method in combination with the sensor element (SE) to determine the position (30) of the tip of the V-formation and/or functionally equivalent information based on the first measurement parameters and the second measurement parameters.

In a further embodiment of the ten preceding embodiments of the sensor system, the control device (CTR) is preferably configured to keep the position (30) of the tip of the V-formation and/or the function-equivalent information available for use by a higher-level system (e.g. 28). This enables, for example, a sensor fusion of this information with data from other sensors, for example in a higher-level system, and the detection of incorrect values by the higher-level system.

In a further embodiment of the sensor system, the program code and/or the program data of the computer-implemented method are stored on a memory-based medium (RAM, NVM). In particular, it is conceivable that this storage medium (RAM, NVM) can be exchanged in order to be able to quickly adapt the sensor system to new conditions.

Preferably, the control device (CTR) and the memory-based medium (RAM, NVM) are configured to execute this program code of the computer-implemented method by means of a processor of the control device (CTR). The memory-based medium (RAM, NVM) may comprise a computer program product, a hard disk, a flash memory or another non-volatile storage medium (NVM).

As already indicated, the system of the radio frequency spectrum analyzer can also be used as a general sensor system in another twelfth embodiment. Here, the sensor system comprises a storage medium (RAM, NVM) which stores the current values of the first measurement parameter, the second measurement parameter and the sensor element measurement value in order to perform one of the computer-implemented methods, in particular iteratively. In this embodiment, the control device (CTR) may in particular be configured to perform a convergence criterion check in the case of an iterative method in order to determine whether the calculation of the position of the lower tip (30) of the V-formation in the X-Y plane and/or the calculation of function-equivalent information has converged, and to terminate the iterations of the computer-implemented method accordingly.

As already indicated, the system of the radio frequency spectrum analyzer can also be used as a general sensor system in another thirteenth embodiment. In this case, the control device (CTR) preferably comprises an error correction and compensation unit configured to detect and correct errors in the measurements of the sensor element (SE) in order to ensure a more precise determination of the position of the lower peak (30) of the V-formation and/or functionally equivalent information.

As already indicated, the system of the radio frequency spectrum analyzer can also be used as a general sensor system in another twelfth embodiment. Here, the control device (CTR) is preferably configured to apply one of the computer-implemented methods by generating a set of measurement points in the X-Y plane representing an initial estimate of the position (30) of the peak of the V-formation and/or function-equivalent information, and subsequently evaluating the measurement points based on the sensor element reading and selecting the best measurement points for the next iteration.

As already indicated, the system of the radio frequency spectrum analyzer can also be used as a general sensor system in another thirteenth embodiment. Here, the sensor system comprises the control device (CTR) with a processor and a memory (RAM, NVM), wherein the memory (RAM, NVM) contains the program code for the computer-implemented method. In this embodiment, the control device (CTR) is preferably configured to retrieve and execute the program code from the memory (RAM, NVM) by means of its processor. Preferably, the memory (RAM, NVM) is configured to store further information about the V-formation, such as the size or shape, in order to enable a comprise characterization of the V-formation.

Finally, the document presented here describes a method for the fabrication of a monolithically integrated sensor system. The proposed method comprises the steps:
1. deployment of a semiconductor substrate (1360), the semiconductor substrate (1360) comprising one or more microelectronic circuits and a metallization stack with electrical lines, any necessary through hole contacts, contacts, pads and insulation layers etc. on one of its surfaces. It is particularly important in this case that the semiconductor substrate (1360) comprises a waveguide (1380, 1880, 2380, 6830, 6980) on this surface;
2. a further step is the coating of this surface of the semiconductor substrate (1360) in the region of the waveguide (1380, 1880, 2380, 6830, 6980) over the entire area or partially with a colloidal varnish (KL) of the collodial mixture to form a local colloidal varnish layer, wherein the colloidal varnish (KL) comprises a substrate material (TM) and crystals and/or diamond nano crystals (ND), all or parts of which comprise paramagnetic centers, in particular NV centers in diamond, which in turn, on exposure to pump radiation (LB) with a pump radiation wavelength (λₚₘₚ) fluorescence radiation (FL) with a fluorescence radiation wavelength (λ_{fl});
3. this is followed by the structuring of the local colloidal coating layer. This structuring can basically take place in two ways as a positive process or a negative process. A further step involves carrying out at least one of these two subsequent structuring processes:
   3.1. Negative method with the steps:
      3.1.1.locally limited exposure of the local colloidal varnish layer of the colloidal varnish (KL) to electromagnetic curing radiation (4910) of a curing wavelength (λ_{H}), so that the substrate material (TM) of the local colloidal varnish layer of the colloidal varnish (KL) is cured. The cured substrate material (TM) is preferably essentially transparent to electromagnetic radiation of the pump radiation wavelength (λₚₘₚ) and essentially transparent to electromagnetic radiation of the fluorescence radiation wavelength (λ_{fl});
      3.1.2. Removing the regions of the local colloidal varnish layer of a colloidal varnish (KL) whose substrate material (TM) has not cured in order to form one or more sensor elements (SE).
   3.2. positive method with the steps:
      3.2.1. pre-bake the local colloidal varnish layer;
      3.2.2. locally limited exposure of the pre-cured local colloidal varnish layer of the colloidal varnish (KL) to electromagnetic exposure radiation (4910) of an exposure wavelength (λ_{B}), so that the substrate material (TM) of the local colloidal varnish layer of the colloidal varnish (KL) becomes attackable,
      3.2.3. removal of the regions of the exposed and thus vulnerable local colloidal varnish layer of the colloidal varnish (KL), for example by means of a solvent or a developer,
      3.2.4. curing the non-removed regions of the unexposed local colloidal varnish layer of the one colloidal varnish (KL) to form one or more sensor elements (SE), wherein the then cured substrate material (TM) is essentially transparent to electromagnetic radiation of the pump radiation wavelength (λₚₘₚ) and wherein the then cured substrate material (TM) is essentially transparent to electromagnetic radiation of the fluorescence radiation wavelength (λ_{fl}).

Preferably, the microelectronic circuits on the semiconductor substrate (1360) comprise one or more device elements of the sensor system and/or one or more sensor channels and/or a control device (CTR) and/or one or more memories (RAM; NVM), and/or one or more magnetic field generation means (L_{c}) and/or one or more signal sources (μWG, G1, G2, LDRV) and/or one or more pattern recognition devices (MEV) and/or one or more micro-optical device elements (LWL1, LWL2) and/or one or more micro-fluidic and/or one or more micro-mechanical functional elements.

Here is an incomplete list of exemplary simple circuit blocks that are typically found in such mixed-signal circuits of CMOS technology and whose integration into the semiconductor substrate (1360) is conceivable:

Amplifiers: Amplifiers are used to amplify and/or filter and/or mixer and/or add electrical signals, etc., either in analog or digital form. Examples are operational amplifiers (op-amps) and differential amplifiers.

Comparators: Comparators compare two input signals and generate an output signal that indicates whether one signal is greater or less than the other. They are often used in threshold detectors and analog-to-digital converters.

Filters: Filters make it possible to amplify or suppress certain frequencies of a signal or to recognize certain signal structures. Examples include low pass filters, high pass filters, band pass filters and notch filters, Kalman filters, optimum filters, matched filters, etc.

Analog-to-digital converter (ADC): ADCs convert analog signals into digital values. They are essential for the digital processing of analog signals and are used in many applications, e.g. in sound recording, sensor technology and communication.

Digital-to-analog converter (DAC): DACs convert digital values into analog signals. They are used to transfer digital information into a continuous analog form, B in audio amplifiers and communication systems.

Oscillators: Oscillators generate periodic signals that are required in many applications such as clock generators, timers and clock synchronization.

Multiplexer: Multiplexers enable the selection and forwarding of a specific input signal from a group of signals to an output. They are often used to switch between different data sources or addresses. They can also be digital multiplexers and/or analog multiplexers.

Shift registers: Shift registers are sequential circuits capable of storing a series of data bits and shifting them in series or parallel. They are used in many applications such as memory expansion, data shifting and signal processing.

Phase detectors: Phase detectors are used to measure the phase difference between two signals. They are important in phase-locked loops (PLL) and frequency synthesizers.

Voltage references: Voltage references generate precise and stable reference voltages that are used as reference voltages in many circuits, for example in ADCs, DACs and control circuits.

Phase-locked loops (PLL): PLLs are used to achieve precise phase and frequency synchronization between different signals. They are used in communication systems, clock generators and frequency synthesizers.

Clock generators: Clock generators produce precise and stable clock pulses that are used to synchronize circuits and for time multiplexing. They play a crucial role in digital circuits and communication systems.

Switching regulators: Switching regulators are electronic circuits that can efficiently convert or regulate voltage or current. They are used in power supplies, battery chargers and energy-efficient systems.

Comparator-based analog-to-digital converters (Flash ADC): Flash ADCs are fast analog-to-digital converters that use the comparator circuit principle to quantize the input signal. They are widely used in applications with high sampling rates and fast signals.

Current sources and mirror circuits: Current sources and mirror circuits are used to generate and mirror stable current references. They are important in analog circuits such as amplifiers and differential amplifiers.

Operational amplifier circuits: Operational amplifiers (op-amps) are used in many analog circuits to perform amplification, filtering, gain and other functions. They are a fundamental building block in analog signal processing.

Threshold detectors: Threshold detectors compare an input signal with a defined threshold value and output a digital signal based on this comparison. They are used in data recognition, signal processing and communication.

Integrators and differentiators: Integrators and differentiators are circuits that enable the integration and differentiation of analog signals. They are used in many applications such as filter design, audio processing and control technology.

Voltage follower: Voltage followers (buffers) are amplifier circuits with an amplification of about 1, which serve to isolate the output signal and reduce the current requirement of other circuits.

Analog switches: Analog switches make it possible to control analog signals and switch between different circuit paths. They are used in analog multiplexers,

Buffer amplifiers: Buffer amplifiers are used to adjust the impedance between different circuit areas and minimize signal losses. They are often used to connect signal sources with different impedances.

Switching control circuits (regulators): Switching control circuits are feedback circuits that are used to maintain a stable output voltage or a stable output current. They are used in power supplies and control circuits.

Schmitt triggers: Schmitt triggers are comparator circuits with hysteresis that are used to generate a stable digital output signal that reacts sensitively to changes in the input signal. They are used in threshold detectors, circuits with noise and signal processing circuits.

Clock synchronization circuits: Clock synchronization circuits are used to synchronize different clock sources with each other or to generate clock phase shifts. They are important in communication systems and synchronous digital circuits.

Clock distributors: Clock distributors enable the distribution of a clock pulse to several circuit parts. They are used to control and synchronize several synchronized circuits.

Digital logic circuits: Digital logic circuits such as AND gates, OR gates, NAND gates and NOR gates are used to perform logical operations on digital signals. They are basic building blocks in digital circuits and processors.

Threshold converter circuits: Threshold converters are used to convert analog signals into digital signals by comparing the signal amplitude with a specified threshold value. They are used in signal processing and communication technology.

Band gap references: Bandgap references are precise voltage references that are insensitive to supply voltage fluctuations. They are used to deploy stable reference voltages in analog circuits.

Power amplification circuits: Power amplifier circuits are used to deliver high power in a circuit, B. for audio amplifiers, amplifiers in wireless communication systems and power converters.

Reset circuits: These reset the micro integrated circuit in the event of a restart or loss of operating voltage and similar faults.

Phase shifters: Phase shifters are circuits that can change the phase position of a signal. They are used in phase control loops, communication systems and oscillators.

Test controller (JATG): Test controllers (JATG) are important for the production test of the microelectronic circuits on the semiconductor substrate (1360). Preferably it is a JATG test controller (JATG). This is described in the document IEEE Standard for Test Access Port and Boundary-Scan Architecture, IEEE Std 1149.1-2013 (Revision of IEEE Std 1149.1-2001).

In addition, the document presented here comprises the standards:
IEEE Standard for Reduced-Pin and Enhanced-Functionality Test Access Port and Boundary-Scan Architecture IEEE Std 1149.7-2009;
IEEE Supplement to Standard Test Access Port and Boundary-Scan Architecture (1149.1) IEEE Std 1149.1b-1994;
IEEE Standard for Reduced-Pin and Enhanced-Functionality Test Access Port and Boundary-Scan Architecture, IEEE Std 1149.7-2022 (Revision of IEEE Std 1149.7-2009); and
IEEE Standard for Access and Control of Instrumentation Embedded within a Semiconductor Device, IEEE Std 1687-2014for information purposes. Access to the test controller (JATG) is preferably via the JATG test bus (TB).

The functionality of a JATG test interface from the prior art is not explained here. The document presented here refers to the texts as examples:
https://de.wikipedia.org/wiki/Joint_Test_Action_Group
https://www.corelis.com/education/tutorials/boundary-scan/

It is a further idea of the present document that the proposed microelectronic circuit comprises a test interface, preferably a JATG test interface according to one of the IEEE JATG test standards, and comprises a test controller, preferably an IEEE 1149 JATG test controller (JATG), which can control or read out at least one of the following functional elements of the sensor system via a data register (DR) and/or an instruction register (IR) of the JATG test controller (JATG):

A light source (LED) for exposure of one or more paramagnetic centers to pump radiation (LB) of a pump radiation wavelength (λₚₘₚ) and/or

one or more paramagnetic centers, in particular one or more NV centers, by exposure to pump radiation (LB) of a pump radiation wavelength (λₚₘₚ) of a light source (LED) which can be controlled by a data register (DR) and/or instruction register (IR) of the test controller (JTAG), in particular of the IEEE 1149 JATG test controller (JTAG), and/or

one or more paramagnetic centers, in particular one or more NV centers, by means of detecting the fluorescence radiation (FL) of this one paramagnetic center or these several paramagnetic centers, in particular this one NV center or these several NV centers, by means of one or more photo detectors (PD) whose receiver output signals (S0) are converted by one or more circuit parts of the microelectronic circuit, so that the test controller (JTAG), in particular the IEEE 1149 JATG test controller (JTAG), can detect one or more values, in particular by means of a data register (DR) of the JATG test controller (JATG), which depend on the fluorescence radiation (FL) of the one or more paramagnetic centers, in particular of the one or more NV centers and/or

a data interface via which the test controller (JTAG), in particular the IEEE 1149 JATG test controller (JTAG), can output one or more detected values which depend on the fluorescence radiation (FL) of one or more paramagnetic centers, in particular the one or more NV centers.

This allows a production test to be carried out during micro-integration of the sensor system based on paramagnetic centers and/or NV centers. The micro-integration can be carried out monolithically or as a microsystem.

Circuit System with Multiple Correlator

In a further embodiment, the sensor system comprises a control device (CTR), a first signal generator (G1), a light source (LED), a second signal generator (G2), a photo detector (PD), a sensor element (SE) with crystals and/or diamond nano crystals (ND) with paramagnetic centers and/or NV centers in diamond, a waveguide (1380, 1880, 2380, 6830, 6980) and a microwave signal source (μWG). The first signal generator (G1) generates an LED modulation signal (S5w). The second signal generator (G2) generates a microwave modulation signal (S5m). The light source (LED) generates a pump radiation (LB) and exposes the paramagnetic centers and/or NV centers in diamond to the modulated pump radiation (LB) in a modulated manner depending on the LED modulation signal. The microwave signal source (μWG) generates a microwave signal (μW) and feeds the modulated microwave signal (μW) into the waveguide (1380, 1880, 2380, 6830, 6980) as a function of the microwave modulation signal (S5m). The waveguide (1380, 1880, 2380, 6830, 6980) exposes the paramagnetic centers and/or NV centers in diamond to the modulated microwave signal (μW). Depending on the modulated microwave signal (μW) and depending on the pump radiation (LB), paramagnetic centers and/or NV centers in diamond emit fluorescence radiation (FL). The photo detector (PD) detects the fluorescence radiation (FL) emitted by the paramagnetic centers and/or NV centers in diamond and, depending on this, forms a receiver output signal (S0). A multiple correlator (LIV) or a functionally equivalent device correlates the receiver output signal (S0), or a signal derived from it with the LED modulation signal (S5w) and the microwave modulation signal (S5m), in particular by hardware-assisted formation of an L3 product, to form a one- or multi-dimensional filter output signal (S4). The sensor system uses the filter output signal (S4) and/or a signal derived from it as a measurement result or keeps it available or outputs it to a higher-level system.

### Vector Sensor Element Channel

A vectorial sensor element channel can thus be defined, which essentially comprises parts of a sensor system. Preferably, the vectorial sensor element channel comprises a first signal generator (G1) configured to generate an LED modulation signal (S5w). Alternatively, the vectorial sensor element channel may comprise a first vectorial signal generator (G1) which comprises a plurality of signal generators (G1_1, G1_2, G1_3, G1_4, G1_5) as first signal generator components and which is configured to generate generating a vectorial LED modulation signal (S5w) with a plurality of LED modulation signals (S5w_1, S5w_2, S5w_3, S5w_4, S5w_5) as LED modulation signal components. The vectorial sensor element channel can comprise a transmission signal (S5) or a vectorial transmission signal (S5) comprising several transmission signals (S5_1, S5_2, S5_3, S5_4, S5_5) as transmission signal components. The vectorial sensor element channel preferably comprises a light source driver (LDRV), which is configured to generate the transmission signal (S5) for a light source (LED) as a function of the LED modulation signal (S5w) and preferably to supply the light source (LED) at least temporarily with electrical energy, or wherein the vectorial sensor element channel comprises a vectorial light source driver (LDRV), which comprises a plurality of light source drivers (LDRV_1, LDRV_2, LDRV_3, LDRV_4, LDRV_5) and which is configured to generate the transmission signal components (S5_1, S5_2, S5_3, S5_4, S5_5) of the vectorial transmission signal (S5) for a vectorial light source (LED) as a function of the vectorial LED modulation signal (S5w) and/or of the LED modulation signal (S5w) and to generate the respective light source components (LED_1, LED_2, LED_3, LED_4, LED_5) of the vectorial light source (LED) at least temporarily with electrical energy. The vectorial sensor element channel preferably comprises a light source (LED) that is configured to generate pump radiation (LB) as a function of the transmission signal (S5). Typically, the transmission signal (S5) switches the light source (LED) temporarily and/or partially on and temporarily and/or partially off. The vectorial sensor element channel may comprise a vectorial light source (LED) comprising a plurality of light sources (LED_1, LED_2, LED_3, LED_4, LED_5) as light source components, which are preferably configured to generate the vectorial pump radiation (LB) comprising a plurality of pump radiation components (LB_1, LB_2, LB_3, LB_4, LB_5), which in each case generates one of these light source components (LED_1, LED_2, LED_3, LED_4, LED_5), in respective dependence on the respective transmission signal components (S5_1, S5_2, S5_3, S5_4, S5_5) of the vectorial transmission signal (S5). In doing so, the respective transmission signal components (S5_1, S5_2, S5_3, S5_4, S5_5) of the vectorial transmission signal (S5) then preferably temporarily and/or partially switch on and temporarily and/or partially switch off the respective light source components (LED_1, LED_2, LED_3, LED_4, LED_5) of the vectorial light source (LED) assigned to them. The vectorial sensor element channel typically comprises a first vectorial optical system comprising a first optical functional element (LWL) or a vectorial first optical functional element comprising a plurality of first optical functional elements (LWL_1, LWL_2, LWL_3, LWL_4, LWL_5) as first optical functional element components. The first vectorial optical system is preferably configured to detect the pump radiation (LB) of the light source (LED) or to detect the vectorial pump radiation (LB) of the vectorial light source (LED) in a vectorial manner, wherein preferably each optical functional component (LWL_1, LWL_2, LWL_3, LWL_4, LWL_5) separately detects one or more respective pump radiation components (LB_1, LB_2, LB_3, LB_4, LB_5) of the vectorial pump radiation (LB). Furthermore, the first vectorial optical system is preferably configured to transport the detected pump radiation (LB) to the sensor element (SE) or to transport the respectively detected pump radiation components (LB_1, LB_2, LB_3, LB_4, LB_5) of the pump radiation (LB) to one or more associated sensor element components (e.g. 1410, 1420, 1430) of the vectorial sensor element (SE). Preferably, the vectorial sensor element (SE) comprises at least two sensor element components (e.g. 1410, 1420, 1430). Preferably, the first vectorial optical system is configured to couple out the pump radiation (LB) from the first optical functional element (LWL) or to couple out the respective pump radiation component (LB_1, LB_2, LB_3, LB_4, LB_5) of the vectorial pump radiation (LB) in each case from the respective first optical functional element component (LWL_1, LWL_2, LWL_3, LWL_4, LWL_5) of the first vectorial optical functional element (LWL). Furthermore, the first vectorial optical system is preferably configured to irradiate the sensor element (SE) with this pump radiation (LB) or to irradiate one or more sensor element components (e.g. 1410, 1420, 1430) of the vectorial sensor element (SE) with exactly one or more respective pump radiation components (LB_1, LB_2, LB_3, LB_4, LB_5) of the vectorial pump radiation (LB). Preferably exactly one respective pump radiation component (LB_1, LB_2, LB_3, LB_4, LB_5) of the vectorial pump radiation (LB) irradiates exactly one respective light source component (LED_1, LED_2, LED_3, LED_4, LED_5) of the vectorial light source (LED) preferably exactly one respective sensor element component (e.g. 1410, 1420, 1430) of the vectorial sensor element (SE). In one variant, the first vectorial optical system preferably comprises a first vectorial optical waveguide (LWL), which preferably comprises a plurality of first optical waveguides (LWL_1, LWL_2, LWL_3, LWL_4, LWL_5) as first optical waveguide components, for this exposure of the vectorial sensor element (SE) as such a vectorial first optical functional element. The vectorial sensor element channel preferably comprises a second vectorial optical system comprising a second optical functional element (LWL) or a vectorial second optical functional element (LWL) comprising a plurality of second optical functional elements (LWL_1, LWL_2, LWL_3, LWL_4, LWL_5) as second optical functional element components. The second vectorial optical system is preferably configured to detect the fluorescence radiation (FL) of the sensor element (SE) or the sensor elements (SE) by means of the second optical functional element (LWL) or to detect the respective fluorescence radiation components (FL_!, FL_2, FL3, FL_4, FL_5) of the vectorial fluorescence radiation (FL) of one or more of the respective sensor element components (e.g. 1410, 1420, 1430) of the vectorial sensor element (SE). Preferably, exactly one of its respective second optical functional element components (LWL_1, LWL_2, LWL_3, LWL_4, LWL_5) of its vectorial second optical functional element (LWL) detects exactly one respective fluorescence radiation component (FL_1, FL_2, FL3, FL_4, FL_5) of the vectorial fluorescence radiation (FL) of one or more of the respective sensor element components (e.g. 1410, 1420, 1430) of the vectorial sensor element (SE).B. 1410, 1420, 1430) of the vectorial sensor element (SE). The fluorescence radiation (FL) of the NV centers and/or the paramagnetic centers of the sensor element (SE) comprises a single fluorescence radiation component or the vectorial fluorescence radiation (FL) comprises the respective fluorescence radiations (FL1, FL_2, FL_3, FL_4, FL_5) of the NV centers and/or the paramagnetic centers of the respective sensor element components (e. g., B. 1410, 1420, 1430) of the vectorial sensor element (SE) as respective fluorescence radiation components (FL_1, FL_2, FL_3, FL_4, FL_5). Preferably, the second vectorial optical system is configured to transport fluorescence radiation (FL) from the NV centers and/or the paramagnetic centers of the sensor element (SE) to the photo detector (PD) or to transport the respective fluorescence radiation components (FL_1, FL_2, FL_3, FL_4, FL_5) of the vectorial fluorescence radiation (FL) preferably separately from one another to respective photo detector components (PD_1, PD_2, PD_3, PD_4, PD_5) of a vectorial photo detector (PD). Preferably, the vectorial photo detector (PD) comprises several photo detectors (PD_1, PD_2, PD_3, PD_4, PD_5) as respective photo detector components of the vectorial photo detector (PD). Preferably, the second vectorial optical system is configured to couple out the fluorescence radiation (FL) from the second functional optical element or to couple out the respective fluorescence radiation components (FL_1, FL_2, FL_3, FL_4, FL_5) of the vectorial fluorescence radiation (FL) from the respective second optical functional component (LWL_1, LWL_2, LWL_3, LWL_4, LWL_5) of the second vectorial optical functional component (LWL). Furthermore, the second vectorial optical system is preferably configured to expose the photo detector (PD) to the coupled-out fluorescence radiation (FL) or to couple the respective photo detector component (PD_1, PD_2, PD_3, PD_4, PD_5) of the vectorial photo detector (PD) with one, in particular, respective fluorescence radiation component (FL_1, FL_2, FL_3, FL_4, FL_5) of the vectorial fluorescence radiation (FL). The second vectorial optical system preferably irradiates exactly one respective photodetector component (PD_1, PD_2, PD_3, PD_4, PD_5) of the vectorial photodetector (PD) with exactly one respective fluorescence radiation component (FL_1, FL_2, FL_3, FL_4, FL_5) of the vectorial fluorescence radiation (FL). The second vectorial optical system preferably comprises further optical functional elements, in particular one or more dichroitic mirrors (F1) and/or one or more optical filters (also designated by the function-related reference sign F1) in the beam path, which ensure that essentially no pump radiation (LB, LB_1, LB_2, LB_3, LB_4, LB_5) from these or other pump radiation sources (LED, LED_1, LED_2, LED_3, LED_4, LED_5) reaches the photo detector (PD) or the respective photo detector component (PD_1, PD_2, PD_3, PD_4, PD_5) of the photo detector components (PD_1, PD_2, PD_3, PD_4, PD_5) of the vectorial photo detector (PD). Preferably, the second vectorial optical system comprises in particular a second optical waveguide (LWL) as such a second optical functional element or in particular a second vectorial optical waveguide (LWL) with several optical waveguides (LWL_1, LWL_2, LWL_3, LWL_4, LWL_5) as such a second vectorial optical functional element. Typically, and most preferably, the second vectorial optical system may comprise device parts which are identical to device parts of the first optical system. The document presented here refers to the figures and the associated descriptions. The vectorial sensor element channel preferably further comprises the photo detector (PD), which typically converts the intensity of the received fluorescence radiation (FL) into a receiver output signal (S0), or the vectorial photo detector (PD) comprising a plurality of photo detectors (PD_1, PD_2, PD_3, PD_4, PD_5) as photo detector components, each representing the respective intensity of the respective fluorescence radiation emitted by the respective photo detector (PD_1, PD_2, PD_3, PD_4, PD_5) of the respective fluorescence radiation (FL_1, FL_2, FL_3, FL_4, FL_5) vectorial fluorescence radiation (FL) into a respective receiver output signal (S0_1, S0_2, S0_3, S0_4, S0_5) of the respective photo detector (PD_1, PD_2, PD_3, PD_4, PD_5) as a receiver output signal component of a vectorial receiver output signal (S0) of the vectorial photo detector (PD). Preferably, the vectorial sensor element channel further comprises the receiver output signal (S0) or the vectorial receiver output signal (S0) converting the receiver output signals (S0_1, S0_2, S0_3, S0_4, S0_5) as the receiver output signal component of the vectorial receiver output signal (S0). Preferably, the vectorial sensor element channel has a first amplifier (V1) for amplification and/or digitization of the receiver output signal (S0) to the amplified receiver output signal (S1) or to the digitized receiver output signal (S1), or a first vectorial amplifier (V1) comprising a plurality of first amplifiers (V1_1, V1_2, V1_3, V1_4, V1_5) as first amplifier components of the first vectorial amplifier (V1) for the respective amplification and/or respective digitization of a respective receiver output signal component (S0_1, S0_2, S0_3, S0_4, S0_5) of the vectorial receiver output signal (S0) to a respective amplified receiver output signal component (S1_1, S1_2, S1_3, S1_4, S1_5) of the vectorial amplified receiver output signal (S1) or to a respective digitized receiver output signal component (S1_1, S1_2, S1_3, S1_4, S1_5) of the vectorial digitized receiver output signal (S1).

Furthermore, preferably and in contrast to the prior art, the vectorial sensor element channel comprises a multiple correlator (LIV), which is preferably configured thereto:
to form a filter output signal (S4) as a function of the amplified receiver output signal (S1) or of the digitized receiver output signal (S1) and of the LED modulation signal (S5w) and of the microwave modulation signal (S5m), and
to make data of the filter output signal (S4) thus formed available to the control device (CTR) and/or
to keep available data of the filter output signal (S4) thus formed, in particular for the control device (CTR) and/or a
to transfer data of the filter output signal (S4) thus formed to the control device (CTR) or another device (e.g. the pattern recognition device MEV), in particular for evaluation
   or wherein the vectorial sensor element channel comprises a plurality of multiple correlators (LIV_1, LIV_2, LIV_3, LIV_4, LIV_5) of a vectorial multiple correlator (LIV) as multiple correlator components, wherein each of the multiple correlator components (LIV_1, LIV_2, LIV_3, LIV_4, LIV_5) of the vectorial multiple correlator (LIV) is configured as such:
a respective filter output signal (S4_1, S4_2, S4_3, S4_4, S4_5) as a respective filter output signal component of a common vectorial filter output signal (S4) in respective dependence on the respective amplified receiver output signal component (S1_1, S1_2, S1_3, S1_4, S1_5) of the vectorial amplified receiver output signal (S1) or in respective dependence on the respective digitized receiver output signal component (S1_1, S1_2, S1_3, S1_4, S1_5) of the vectorial digitized receiver output signal (S1) and in respective dependence on the respective LED modulation signal component (S5w_1, S5w_2, S5w_3, S5w_4, S5w_5) of the vectorial LED modulation signal (S5w) and in respective dependence on the respective microwave modulation signal component (S5m_1, S5m_2, S5m_3, S5m_4, S5m_5) of the vectorial microwave modulation signal (S5m) and
to provide data of the thus formed vectorial filter output signal (S4) to the control device (CTR) and/or
to keep available data of the thus formed vectorial filter output signal (S4) for the control device (CTR) and/or
to transfer data of the vectorial filter output signal (S4) thus formed to the control device (CTR) or another device (e.g. the pattern recognizer (MEV) in particular for evaluation.

The vectorial sensor element channel may comprise an optional pattern recognition device (MEV) in addition to accelerating and/or unloading, for example, the control device (CTR). Typically, this optional pattern recognition device (MEV) and/or the control device (CTR) are configured to receive one or more vectorial filter output signals (S4, S4_1, S4_2, S4_3, S4_4, S4_5) and/or evaluate and/or analyze the common vectorial filter output signal (S4) and/or process it by means of computer-implemented methods and/or generate one or more pattern data sets (MDS) and make them available and/or keep them available and/or transfer them to other external systems and/or internal device parts (CTR).

Preferably at least one, better two, better three, better four, better five of the following device subgroups is vectorially designed:
Group 1: The first vectorial signal generator (G1), the vectorial LED modulation signal (S5w), the vectorial light source driver (LDRV), the vectorial transmission signal (S5), the vectorial light source (LED).
Group 2: the first vector optical system.
Group 3: vector sensor element (SE).
Group 4: the second vector optical system; and
Group 5: the vectorial photo detector (PD), the vectorial receiver output signal (S0), the vectorial first amplifier (V1), the amplified receiver output signal (S1) or the digitized receiver output signal (S1), the vectorial multiple correlator (LIV).

This can be summarized in a requirement that preferably at least subgroups of the sensor element channel are vectorial.

### Micro-Optical

The carrier substrate (1360) can also comprise micro-optical functional elements. Here is an incomplete list of examples:

Micro-optical lenses: Micro-optical lenses are used to focus or collimate light. They often consist of a converging lens or a microlens that can be integrated into the wafer.

Micro-structured optical filters: These filters use micro-optical structures to block or transmit certain wavelength ranges. Examples include micro-grating filters or micro-optical interference filters.

Micro-optical waveguides: Micro-optical waveguides are used to guide and direct light within the wafer. They can take the form of micro-optical fibers or waveguide structures, for example.

Micromirrors: Micromirrors consist of small, movable mirrors that can reflect the incident light in different directions. They enable the optical control of light beams and are often used in optical communication or optical switch technology.

Microstructures for surface structuring: Micro-optical surface structures can be used to scatter, refract or polarize the incident light. Such structures can be realized in the form of microprisms, microgratings, or microreliefs, for example.

Micro-optical diffraction gratings: Micro-optical diffraction gratings consist of regular micro-optical structures that split the incident light into different diffraction orders. They are often used in spectral analyzers or as optical coding structures.

Micro-optical phase elements: Micro-optical phase elements allow the phases of the incident light to be manipulated. These include, for example, micro-optical phase gratings, which modulate the phase distribution of light and can be used to generate interference patterns.

Micro-optical detectors: Micro-optical detectors are optical sensors that can be integrated into the wafer. They can comprise, for example, photodiodes, phototransistors or other light-sensitive elements. These detectors convert light signals into electrical signals and are used in optical communication systems or sensors.

Micro-optical beam splitters and couplers: These functional elements enable the splitting or coupling of light into several channels. They are often used in optical communication systems, optical switches or optical sensors.

Micro-optical cavity resonators: Micro-optical cavity resonators consist of micro-structured materials that trap light in a limited volume and comprise certain resonant modes. They are used in optical filters, lasers or as optical amplifiers.

In NV center sensing and/or paramagnetic center sensing, micro-optical devices can be used in combination with NV centers and/or paramagnetic centers to obtain information about analytical substances and/or physical parameters in the environment of the NV centers and/or paramagnetic centers. The document presented here identifies some interactions between micro-optical devices and NV centers and/or paramagnetic centers in NV center sensing and/or paramagnetic center sensing:
1. Light emission and absorption: NV centers and/or paramagnetic centers can emit and absorb light, and their optical properties are influenced by the environment and interactions with analytical substances and/or physical parameters in the vicinity of the NV centers and/or paramagnetic centers. Micro-optical devices such as micromirrors, microresonators, or micro-structured optical waveguides can be used to control and manipulate NV centers and/or paramagnetic centers with light. By observing changes in the light emission or absorption of the paramagnetic centers and/or NV centers, information about analyzed substances and/or physical parameters in the environment of the NV centers and/or paramagnetic centers can be obtained.
2. Light guidance and coupling: Micro-optical devices can be used to focus, direct or couple light to the NV centers and/or paramagnetic centers. By precisely controlling the light path and intensity, targeted interactions between the light and the NV centers and/or paramagnetic centers can be fabricated. This enables the detection of optical signal changes that are due to the presence or interaction of analytical substances and/or physical parameters in the vicinity of the NV centers and/or paramagnetic centers.
3. Plasmonic interactions: Micro-optical devices may contain plasmonic structures that amplify the interaction between light and NV centers and/or paramagnetic centers. Plasmonic effects can be used to improve the sensitivity and resolution of NV center sensing and/or paramagnetic center sensing. By integrating NV centers and/or paramagnetic centers into plasmonic structures, minute changes in the optical properties of the NV centers and/or paramagnetic centers can be detected, resulting in high sensitivity in the detection of analytes and/or physical parameters in the vicinity of the NV centers and/or paramagnetic centers.
4. Spectral analysis: Micro-optical devices can be used to spectrally analyze the emitted or absorbed light from NV centers and/or paramagnetic centers. By splitting the light into different spectral components, information can be obtained about the spectral signature of the NV centers and/or paramagnetic centers and its changes due to interactions with analytical substances and/or physical parameters in the environment of the NV centers and/or paramagnetic centers.
5. Interference and modulation: Micro-optical devices can use interference and modulation techniques to detect changes in optical phase or intensity. By integrating NV centers and/or paramagnetic centers into interferometer or modulation structures, slight changes in the optical properties of the NV centers and/or paramagnetic centers can be detected, indicating the presence or interaction of analytical substances and/or changes in physical parameters in the vicinity of the NV centers and/or paramagnetic centers.
6. Coherence effects: NV centers and/or paramagnetic centers can produce coherent optical signals that can be used to measure phase and frequency changes. Micro-optical devices can be used to maintain and enhance the coherence of NV centers and/or paramagnetic centers. By precisely controlling the coherence properties, subtle optical signals can be detected that indicate the presence or interaction with analytical substances and/or changes in physical parameters in the vicinity of the NV centers and/or paramagnetic centers.
7. Polarization sensitivity: NV centers and/or the paramagnetic centers show a strong sensitivity to the polarization of light. Micro-optical devices can be used to manipulate and analyze the polarization of light incident on the NV centers and/or the paramagnetic centers. By measuring polarization effects, information can be obtained about the environment of the NV centers and/or the paramagnetic centers and the interactions with analytical substances and/or with physical parameters in the environment of the NV centers and/or paramagnetic centers.
8. Near-field optics: Micro-optical devices can be used in combination with NV centers and/or paramagnetic centers for near-field optics. This enables the manipulation and detecting of light in the region of the optical near field, providing high spatial resolution and, for example, improved interaction with analytical substances and/or physical parameters in the vicinity of the NV centers and/or paramagnetic centers. By selectively controlling the light field in the vicinity of the NV centers and/or the paramagnetic centers, information can be obtained about the substances in the immediate vicinity and/or physical parameters in the vicinity of the NV centers and/or paramagnetic centers.
9. Integration of microlenses or microlenses: Micro-optical devices may incorporate microlenses or micro objectives that are used to focus light onto the NV centers and/or paramagnetic centers or to collect the emitted light. By precisely controlling the lens position and geometry, optimal light conditions can be created for interaction with analytical substances and/or physical parameters in the vicinity of the NV centers and/or paramagnetic centers.
10. Waveguide integration: Micro-optical devices can contain optical waveguide structures that guide the light to the NV centers and/or the paramagnetic centers or collect the emitted light. By integrating NV centers and/or paramagnetic centers into these waveguide structures, the interactions between the light and the analytical substances and/or physical parameters in the vicinity of the NV centers and/or paramagnetic centers can be amplified and specifically controlled.

These interactions between micro-optical devices and NV centers and/or the paramagnetic centers open up a wide range of applications in optical sensing, chemical analysis, biotechnology and other regions. By integrating NV centers and/or the paramagnetic centers into micro-optical systems, highly sensitive, high-resolution and precise measurements of analytical substances and/or physical parameters in the environment of the NV centers and/or paramagnetic centers can be enabled.

### Micro-Fluidics

In micro-fluidics, there are various functional elements that can be considered for integration into the carrier substrate (1360). Here are some examples:

Microchannels: Microchannels are tiny channels that can transport liquids or gases on a microscopic scale. They can be integrated into the wafer to direct, mix or separate fluid flows. Microchannels can be used, for example, to perform lab-on-a-chip applications, to analyze biological samples or for chemical reaction engineering.

Microvalves: Microvalves are used to control the flow in microchannels. They allow the fluid flow to be opened, closed or regulated. Microvalves can be used in micro-fluidic systems, for example, to stop or redirect the flow and thus influence interaction between the NV centers and/or paramagnetic centers.

Micropumps: Micropumps generate pressure differences to move liquids in microchannels. They can work with the help of piezoelectric or electro-osmotic effects, for example. Micropumps enable active flow control and are used in various regions such as medical diagnostics, chemical analysis, or micro reaction systems.

Micro-structured mixing chambers: Micro-structured mixing chambers are used to efficiently mix liquids or gases. They contain special structures such as vortex generators or micro-structured obstacles to achieve fast and homogeneous mixing. Micro-structured mixing chambers are used in chemical reaction systems, biological analyses or in lab-on-a-chip technology.

Microfilters and separation structures: Microfilters and separation structures are used to separate particles or impurities in liquids. They can, for example, consist of micro-structured membranes, micro-fabric or micro-sieves. Such structures are used in micro-fluidics to filter samples, sort cells or separate particles.

These functional elements can be integrated into the carrier substrate (1360) as needed by using microfabrication processes such as photolithography, etching, additive manufacturing, injection molding or coating techniques, etc. The integration of microfluidic elements into the carrier substrate (1360) enables the miniaturization and integration of liquid manipulation systems on a chip.

In NV center sensing and/or paramagnetic center sensing, micro-fluidic devices can be used in combination with NV centers and/or paramagnetic centers to obtain information about analytical substances and/or physical parameters in the vicinity of the NV centers and/or paramagnetic centers. Here are some known interactions between micro-fluidic devices and NV centers in NV center sensing and/or sensing by means of paramagnetic centers. The present document hereby describes the combination of the methods and devices presented herein based on a multiplicity of crystals and/or diamond nano crystals (ND) with the interactions listed below as examples:
1. Fluorescence detection: Paramagnetic centers and/or NV centers can emit fluorescence radiation (FL), which can be detected as a fluorescent signal. Micro-fluidic devices can be used to place samples containing analytical substances in the vicinity of the NV centers and/or paramagnetic centers. When the analytical substances interact with the NV centers and/or the paramagnetic centers, changes in the respective fluorescence signal can be observed. This enables the detection and quantification of analytes and/or the detection of changes in physical parameters in the vicinity of the NV centers and/or paramagnetic centers.
2. Magnetic field measurements: NV centers and/or paramagnetic centers show a sensitive dependence of their optical properties on magnetic fields. Micro-fluidic devices can be used to place samples with magnetic substances in the vicinity of the NV centers and/or paramagnetic centers. The interaction between the magnetic substances and the NV centers and/or paramagnetic centers leads to changes in the respective optical fluorescence signal of the intensity (Iᵢₛₜ(t)) of the fluorescence radiation (FL), which can be used to measure magnetic fields.
3. Surface plasmon resonance (SPR): Micro-fluidic devices can contain specially designed surface structures that amplify the interaction between NV centers and/or paramagnetic centers on the one hand and analytical substances on the other. By combining NV centers and/or paramagnetic centers with surface plasmon resonance (SPR), minute changes in the optical properties of the NV centers and/or paramagnetic centers can be detected, resulting in high sensitivity in the detection of analytes and/or the detection of changes in physical parameters in the vicinity of the NV centers and/or paramagnetic centers.
4. Chemical reactions: Micro-fluidic devices can be used to enable chemical reactions between analytical substances on the one hand and NV centers and/or paramagnetic centers. By precisely controlling reaction conditions such as temperature, pressure and flow rate, specific chemical reactions can be initiated and monitored. The resulting changes in the optical or magnetic properties of the NV centers and/or paramagnetic centers can provide information about the analyzed substances and/or information about physical parameters in the environment of the NV centers and/or paramagnetic centers.

These interactions enable the application of NV centers and/or paramagnetic centers in sensor diagnostics, chemical analysis, medical diagnostics and other regions. The integration of micro-fluidic devices allows precise control of the sample environment and efficient analysis of analytes by utilizing the unique optical and magnetic properties of NV centers and/or paramagnetic centers.

### Micro-Mechanical

In micro-mechanical applications, there are various functional elements that can be considered for integration into the carrier substrate (1360). Here are some examples:
Microactuators: Microactuators are mechanical components that can generate translational and/or rotational movements or deformations on a microscopic scale. They can be realized, for example, in the form of micro-electromechanical systems (MEMS) and comprise various principles of action, such as electrostatic, piezoelectric or electromagnetic actuators. Microactuators are used in regions such as optics, robotics, sensor technology and medical technology.
Microsensors: Microsensors are used for detecting physical quantities such as pressure, temperature, acceleration or chemical parameters on a microscopic scale. They can be realized in the form of MEMS sensors, for example, and comprise various operating principles, such as capacitance, piezoresistive or optical sensors. Microsensors are used in many applications, including automotive electronics, medical diagnostics, environmental monitoring and industrial automation.
Microstructures: Microstructures comprise a multiplicity of micro-mechanical structures such as beams, springs, levers or gear systems. These structures can be used to realize mechanical functions such as force transmission, motion conversion or energy transfer. Microstructures are used in many applications, including mechanical switches, micro gears, micro actuators or micro pumps.
Microresonators: Microresonators are mechanical structures that can generate vibrations with specific resonance frequencies. They can be realized, for example, in the form of micro bridges, micro clamps or micro bending beams. Microresonators are used in precision engineering, frequency standardization, sensor technology or vibration analysis.
Microstructuring techniques: In addition to the individual functional elements, microfabrication methods and techniques are also part of micro-mechanical engineering. These include, for example, photolithographic structuring, etching technology, thin-film technology and microfabrication techniques. These techniques enable the precise fabrication of micro-mechanical structures and the integration of functional elements into a wafer.

The integration of these functional elements and techniques in the carrier substrate (1360) enables the fabrication of micro-mechanical-based components and systems on a chip.

The combination of micro-mechanical devices, in particular when they comprise ferro- or permanent magnetic device parts, with NV centers and/or paramagnetic centers in NV center sensing and/or paramagnetic center sensing enables the use of the unique properties of NV centers and/or paramagnetic centers for the detection and characterization of analytical substances and/or physical parameters in the vicinity of the NV centers and/or paramagnetic centers. Here are some known interactions between micro-mechanical devices and NV centers and/or paramagnetic centers in NV center sensing and/or paramagnetic center sensing:
1. Surface functionalization: Micromechanical devices can be provided with surface structures or coatings, in particular ferromagnetic or permanent magnetic coatings, in order to immobilize or position NV centers and/or paramagnetic centers and/or to bring magnetic functional elements in the vicinity of the NV centers and/or paramagnetic centers. The targeted placement of the NV centers and/or paramagnetic centers in the vicinity of the substances to be analyzed can enable specific interactions that lead to detectable changes in the optical or magnetic properties of the NV centers and/or paramagnetic centers.
2. Vibration analysis: Micro-mechanical devices can be used to analyze the mechanical influences on NV centers and/or paramagnetic centers by means of ferro- and permanent magnetic functional elements. By integrating NV centers and/or paramagnetic centers into micro-mechanical resonators or bending beams and/or ferro- or permanent magnetic device parts, mechanical forces or deformations can be detected, which are caused, for example, by interactions with analytical substances and/or physical parameters such as pressure, acceleration, rotation, force, tension. These changes can, for example, serve as indicators for the presence or concentration of the analytical substances and/or physical parameters.
3. Force detection: NV centers and/or paramagnetic centers and/or the systems of these and ferromagnetic or permanent magnetic device parts can be sensitive to mechanical forces exerted on them. Micro-mechanical devices can be used to detect the interaction forces between NV centers and/or paramagnetic centers on the one hand and analytical substances on the other hand. By measuring the changes in the optical or magnetic properties of the NV centers and/or paramagnetic centers, information about the analyzed substances and/or information about physical parameters in the environment of the NV centers and/or paramagnetic centers and/or about the ferro- or permanent magnet device parts can be obtained.
4. Pressure and voltage measurement: NV centers and/or paramagnetic centers can serve as pressure and voltage sensitive sensors. Micro-mechanical devices can be used to generate pressure or stress changes in the environment of the NV centers and/or paramagnetic centers, convert them into changes in magnetic fields if necessary, and measure them. This enables the analysis of mechanical properties of materials or the detection of pressure or stress changes in analytical samples or materials.
5. Acoustic detection: Micro-mechanical devices can act as acoustic transducers to generate or detect sound waves. By integrating NV centers and/or paramagnetic centers into such devices, acoustic interactions between the NV centers and/or paramagnetic centers on the one hand and the substances to be analyzed or physical parameters on the other hand can be detected, for example by means of magnetic device parts. This enables the acoustic detection and characterization of analytes and/or physical parameters in the vicinity of the NV centers and/or paramagnetic centers.

These direct interactions between micro-mechanical devices and NV centers and/or paramagnetic centers open up new possibilities for the application of NV centers and/or paramagnetic centers and indirect interactions via magnetic ferromagnetic or permanent magnetic device parts in sensor technology, in particular in regions such as material characterization, environmental monitoring, medical diagnostics and nanotechnology. However, the exact design and integration of these devices depend on the specific applications.

### Essential Findings on Producibility

During the elaboration of the technical teaching of the document presented here, it was recognized that although the use of many crystals or diamond nano crystals (ND) leads to smearing of the V-formations of the fluorescence structures of the single crystals (see FIG. 1), this does not apply to the outer resonance edges (522, 525, see FIG. 51b). A basic idea is therefore to use NV diamond powder or crystal powder with paramagnetic centers for the sensor elements (SE) instead of single crystals and to measure the resonance edges in order to infer the magnetic flux density and/or the microwave frequency. This is because the outer V-formation is retained. (see FIG. 2)

Depending on the unknown microwave frequency (ωₙₖ) and magnetic flux density (Bₑₓₜ), the position of this V-formation shifts in the diagram in FIG. 2. The unknown magnetic flux density (Bₑₓₜ) is superimposed with a known additional magnetic flux density (B_{ad}) generated by the proposed device to form the total magnetic flux density By, which determines the vertical position of the V-formation in FIG. 2. The microwave signal (S_{ωnk}) with unknown microwave frequency (ωₙₖ) is mixed with a microwave signal with known microwave frequency. One of the sidebands and the carrier signal should be filtered out. The sideband that is not filtered out then shifts the V-formation in FIG. 2 horizontally.

The magnetic flux density Bₑₓₜ and the unknown microwave frequency ωₙₖ can then be deduced from the shift of the V-formation. If two microwave signals with two unknown microwave frequencies are added, the V-formation doubles at two different horizontal positions. This means that a cross-correlation between the V-formation without admixture and with the formations with admixtures can be used to draw conclusions about the microwave frequency spectrum of the admixture.

In order to determine the unknown microwave frequency, it is particularly advantageous to determine the most prominent point of the V-formation, as this is independent of external influences in its shape and is known in advance and can be predetermined. This is the peak (530) of the V-formation (522, 525) Instead of the peak (530) of the V-formation (522, 525), functionally equivalent information, such as B two points on the left branch of the V-formation and two points on the right branch of the V-formation, can of course also be used. The gradients of the degrees through the two points on the left branch of the V-formation are already known. The gradients of the degrees through the two points on the right branch of the V-formation are already known. This means that once four such points are known, the position of the tip of the V-formation can be determined from the positions of these four points in the magnetic flux density and microwave frequency diagram.

Various methods can be used to determine the position of the lower tip of the V-shape in the X-Y plane, i.e. the position of the V-formation. The following text lists five exemplary methods for determining the next measurement point from the next first measurement parameter and the next second measurement parameter:
1. Grid method: In this method, the measuring range is divided into a regular grid. The control device can systematically process the measuring points of the grid, starting from a starting point. The next measuring point is selected in a predefined sequence, for example by gradually increasing or decreasing the first and/or second measuring parameter. This method enables uniform coverage of the measuring range, but can be inefficient if the V-formation is not regular.
2. Step width adjustment: The step width is used to adjust the measurement parameters based on the previous measurements. The control device starts with a specific step and adjusts it based on the measured values detected. If the absolute value of the gradient of the measured value of the sensor element increases, the step size can be reduced to enable a more accurate determination of the position of the V-formation. However, this method requires iterative adjustment and can claim time depending on the complexity of the V-formation.
3. Gradient method: The gradient method uses the gradient of the measured value of the sensor element to determine the direction of the maximum gradient. The control device can adjust the measurement parameters along this direction to determine the next measurement point. By taking the gradient into account, the method can quickly lead to the peak of the V-formation. However, it may be less effective in regions with a flat gradient or when the V-formation is asymmetrical.
4. Optimization algorithms: Various optimization algorithms such as the Nelder-Mead algorithm or the Powell algorithm can be used to determine the position of the V-formation. These algorithms use a combination of direct search and gradient information to find the nearest measurement point. They can be efficient, but may require complex mathematical calculations and more computing power.
5. Machine learning methods: Advanced machine learning techniques such as neural networks or genetic algorithms can be used to determine the location of the V-formation. These approaches can learn from previous measurement data and make a prediction for the next measurement point. However, this requires an extensive data collection and model training phase before the system is ready for use.

It is important to note that the selection of the most suitable method depends on several factors, the accuracy requirements, the available resources and the context of the application.

A detailed analysis and evaluation of these factors will enable the selection of the most suitable method for determining the position of the top of the V-formation in the X-Y plane. The following aspects should be taken into account:

Complexity of the V-formation: The more complex the shape of the V-formation is, i.e. the more features of FIG. 2 and the following figures are taken into account, the more challenging the determination of the position can be. Since the internal structures of the V-formation of FIG. 2 are asymmetrical and non-linear, methods such as the gradient method or machine learning methods can be particularly advantageous for achieving accurate results.
Accuracy requirements: The required precision influences the choice of method. If high accuracy is required, optimization algorithms or precision-based step size adjustment methods can be used. For less stringent requirements, a grid method or a coarser step size adjustment method may be sufficient.
Available resources: The available technical resources, such as computing power, power consumption, functional safety, storage space or measuring instruments, can influence the selection. More complex methods such as machine learning methods may require more resources for training models or processing large amounts of data.
Context of the application: The specific area of application and the underlying framework conditions also play a role. In some applications, a quick but rough approximation may be sufficient, while other applications require a detailed and precise determination.

Selecting the best method for determining the position of the V-formation tip requires careful consideration of these factors. It is also often helpful to combine or adapt different methods to achieve optimal results. It may be advisable to carry out a prototype development or simulation to evaluate the performance of the different methods and identify the most suitable solution for the specific situation.

### Determining the Position of the V-Formation

The device presented here thus enables the measurement of a two-dimensional field consisting of the total magnetic flux density By or the external magnetic flux density Bₑₓₜ and the microwave frequency ωₙₖ. (see also FIG. 51b) Depending on the applied microwave frequency ωₙₖ and the total magnetic flux density By, the V-formation consisting of the lower resonance edge 522 and the upper resonance edge 525 is located at a different position in the two-dimensional field of the two measurement parameters total flux density By and microwave frequency ωₙₖ. The shape of the V-formation consisting of the lower resonance edge 522 and the upper resonance edge 25 remains unchanged.

The task that typically arises is therefore often to determine the exact position of the V-formation from the lower resonance edge 522 and the upper resonance edge 525 and, at the same time, the exact position of the peak 530 of this V-formation as precisely and quickly as possible, in order to determine the values of the zero-point microwave frequency ω_{μW0} and the zero-point flux density B₀, which characterize the position 530 of the tip 530 of the V-formation from the lower resonance edge 522 and the upper resonance edge 525, and then to infer the measured values sought in each case.

Since the device can usually measure only a few discrete points, the control device of the device preferably applies a computer-implemented iteration procedure to quickly specify the measured values. In the following, the document presented here therefore lists some possible methods that the control device of the device can use to make the measurement points more precise. When the following refers to measurement parameters, namely a first measurement parameter and a second measurement parameter, this refers to the two parameters magnetic flux density and microwave frequency. The X-Y plane refers to the plane of these two measurement parameters. A core idea is that the control device uses advanced computer-implemented AI methods to determine the next measurement points based on the previous measurement results and thus increase precision at maximum speed. A measurement point (also called the operating point of the system) typically comprises a certain value of magnetic flux density and a certain value of microwave frequency. The application of the following AI methods to fluorescence pictures is described here as an example for all images from magnetic field cameras—including those described above—in the document presented here.

### Machine Learning

Various approaches can be used to determine the next measurement point from the next first measurement parameter and the next second measurement parameter by means of machine learning methods. Here are five known machine learning methods for solving this problem:
1. Neural networks: Neural networks are a powerful method in the region of machine learning. By training a neural network with suitable input and output data, it can learn a function to predict the next measurement point based on the current measurements. Different architectures such as simple feedforward networks or recurrent neural networks can be used.
2. Genetic algorithms: Genetic algorithms use evolutionary principles to find the optimal solution. By defining suitable fitness functions and applying genetic operators such as mutation and recombination, genetic algorithms can gradually improve and adapt the next measurement point to determine the location of the V-formation.
3. Decision trees: Decision trees are an intuitive and interpretable machine learning model. By training a decision tree with the existing measurement data, it can be used to select the next measurement point based on the current measurements. The decision trees can be used in close conjunction with other methods such as Random Forest to improve prediction accuracy.
4. Support Vector Machines (SVM): SVM is a supervised learning method that can be used in classification and regression. By training an SVM with the existing measurement data, it can be used to predict the next measurement point. SVM can be useful in particular when the V-formation is non-linearly separable.
5. K-means clustering: K-means is a clustering algorithm that can be used to divide the V-formation into different clusters. By training a K-means model with the existing measurement data, the cluster centers can be determined, and the next measurement point can be selected in the vicinity of the most suitable cluster center.

It is important to note that the choice of the best method depends on various factors, including the available data, the number of measurements, the accuracy requirements and the context of the application. Choosing the right machine learning method may require experimentation and evaluation of the performance of different approaches.

### Optimization Algorithms

Various optimization algorithms can be used to determine the next measurement point from the next first measurement parameter and the next second measurement parameter. Here are five exemplary optimization algorithms that could be relevant for this sensor system during rework:
1. Gradient descent: Gradient descent is an optimization algorithm that attempts to find the minimum of a function by descending stepwise along the negative gradient. In this case, the algorithm could calculate the negative gradient of the absolute value of the gradient of the sensor element measurement value after the first and second measurement parameters and select the next measurement point based on the direction of descent.
2. Genetic algorithms: Genetic algorithms can also be used to optimize the next measurement point. By using a population of candidate solutions and applying genetic operators such as recombination and mutation, genetic algorithms can gradually improve the location of the V-formation and determine the next measurement point.
3. Particle swarm optimization (PSO): Particle swarm optimization uses a group of virtual particles that move through the search space—in this case the plane of magnetic flux density and microwave frequency. Each virtual particle stores its own position and speed and adjusts these based on the best result so far and the best result globally, after the measurement. Through the interaction and cooperation of the particles, PSO can find a good solution by effectively exploring the search space.
4. Nelder-Mead algorithm: The Nelder-Mead algorithm is a direct optimization algorithm that does not require gradient information. It uses a simplex that represents a geometric structure in the search space. The algorithm performs iterations in which it uses the best, worst and middle points of the simplex to determine the next position. This algorithm can be effective if the search space is not differentiable.
5. Simulated Annealing: Simulated Annealing is a probabilistic optimization algorithm inspired by the metalworking technique of “annealing”. The algorithm simulates the heating and slow cooling of a metal in order to optimize its crystal structure. Similarly, simulated annealing explores the search space and occasionally accepts worse solutions in order to escape from local minima, and find a global minimum.

It is important to note that the selection of the most appropriate optimization algorithm depends on several factors, including the complexity of the V-formation and the internal structures of the V-formation that may be considered, the number of available measurements, the accuracy requirements and the available resources. Choosing the right optimization algorithm may require experimentation and evaluation of the performance of different approaches.

### Machine Learning Methods Similar to Bayesian Optimization

Various machine learning methods similar to Bayesian optimization could be used to determine the next measurement point from the next first measurement parameter and the next second measurement parameter to determine the location of the V-formation in the X-Y plane. Here are five important methods that could be relevant in this context:
Bayesian optimization: Bayesian optimization is a probabilistic method for global optimization under uncertainty. It combines the modeling of the objective function with a Bayesian probability estimate to enable the most efficient possible search for the optimum point. A probabilistic model is created that detects the relationships between the input parameters (first measurement parameter and second measurement parameter) and the objective function values (position of the V-formation). Based on this modeling, a probabilistic search is performed that combines the exploration of the search space with the exploitation of already known good regions. Bayesian optimization can therefore help to determine the location and position of the top of the V-formation with as few iterations as possible.
Random Forest Regression: Random Forest Regression is an ensemble method based on decision trees. It can be used to model the relationship between the input parameters (first measurement parameter, second measurement parameter) and the objective function values (position of the V-formation). By using multiple decision trees that are randomly generated and make a prediction, a robust model can be created that can also detect non-linear relationships.
Gaussian Process Regression: Gaussian Process Regression is a non-parametric method that takes into account the uncertainty in the data. It uses a set of functions to model the relationships between the input parameters and the target function values. This creates a distribution over possible functions that fit the observed data. This method can be effective in quantifying the uncertainty in the predictions and providing a good estimate of the position of the V-formation.
Artificial neural networks: Artificial neural networks are a powerful class of machine learning models that are capable of modeling complex relationships between the input parameters and the target function values. By training a neural network on the available data, a function can be learned that predicts the next measurement point. Artificial neural networks can be used for both regression and classification and offer flexibility and high capacity for modeling complex processes.
Gradient-based optimization: In gradient-based optimization, the gradient of the objective function with respect to the input parameters is calculated and used to determine the next measuring point. The gradient shows the direction of the steepest increase in the objective function, which indicates the direction in which the parameters must be adjusted in order to achieve an improvement.
A well-known algorithm for gradient-based optimization is the gradient descent method. It starts with an initial measuring point and the gradient at this point is calculated iteratively. The next measurement point is then selected along the negative gradient in order to minimize the objective function. This process is repeated until a convergence criterion is met or a sufficiently good solution is found.
The gradient descent method can be effective if the objective function is differentiable and the parameters form a continuous search space. However, it can get stuck in complex optimization problems if the method runs into local minima or saddle points. To counteract this problem, techniques such as Momentum, AdaGrad or Adam can be used to accelerate convergence and avoid local minima.

It should be noted that gradient-based optimization does not explicitly target Bayesian optimization. Bayesian optimization uses probabilistic models to model the search space and find a balance between exploration and exploitation. In contrast, the gradient-based method directly optimizes the value of the objective function and does not explicitly consider uncertainty. However, both approaches can be used in combination, for example by using Bayesian optimization for global search and gradient-based optimization for fine-tuning in the vicinity of a solution.

Gradient-based optimization is used to determine the next measurement point in the vicinity of the steepest slope of the objective function. This approach requires the objective function to be differentiable in order to calculate the gradient. By using the gradient, the control device of the sensor system can iteratively adjust the next measurement point to localize the V-formation in the X-Y plane.

Various optimization algorithms based on the gradient can be used to make the search more efficient. Here are two important optimization algorithms:
Gradient descent: In gradient descent, the gradient of the target function is calculated and used in the opposite direction to the steepest descent of the target function. The algorithm iteratively updates the values of the input parameters (first measurement parameter, second measurement parameter) to bring the next measurement point closer to the top of the V-formation. Gradient descent is a simple and widely used optimization algorithm, but it may get stuck in local minima.
Stochastic gradient descent: Stochastic gradient descent is a variant of gradient descent in which the gradient is calculated based on a random subset of the available data points. Instead of calculating the gradient over the entire data set, stochastic gradient descent is used to make the calculation of the gradient more efficient and to accelerate convergence. This algorithm is well suited for large data sets and can reduce the number of iterations required.

These optimization algorithms can be used to determine the next measurement point from the next first measurement parameter and the next second measurement parameter and thus determine the position of the V-formation in the X-Y plane. By applying machine learning methods and optimization algorithms, the sensor system can determine the location and position of the V-formation with as few iterations as possible and precisely locate the peak of the V-formation in the X-Y plane.

### Random Forest Regression

In one embodiment, the sensor system comprises a control device that is capable of setting the first measurement parameter within a specific measurement parameter interval and also setting the second measurement parameter within a different measurement parameter interval. A sensor element is used to determine a sensor element measured value for a set measuring point. The measured value depends on the values of the first and second measurement parameters. A computer-implemented method of random forest regression is used to precisely determine the next measurement point with as few iterations as possible.

In one embodiment of the proposal, the computer-implemented method of random forest regression is used to determine the position of the peak of the V-formation or function-equivalent information in the X-Y plane. The first measurement parameter is used as the X-coordinate and the second measurement parameter as the Y-coordinate. This enables the position of the V-formation to be determined efficiently.

In addition, the control device keeps the determined position of the lower tip of the V-formation available for use by a higher-level system. This ensures that the determined data can be used by other systems.

The sensor system combines the computer-implemented method of Random Forest Regression with the sensor element and the control device to determine the position of the lower peak of the V-formation based on the measurement parameters and keep it available for use by a higher-level system. Here, the computer-implemented method of random forest regression is stored on a memory-based medium and is executed by a processor of the control device. The memory-based medium can be, for example, a computer program product, a hard disk, a flash memory or another non-volatile storage medium. This implementation enables efficient and reliable determination of the position of the V-formation.

The control device of the sensor system comprises a processor and a memory. The memory contains the code for the computer-implemented Random Forest Regression method, while the processor retrieves and executes the code from the memory. This ensures that the method is executed correctly and efficiently.

In one variant of the proposal, the sensor system can comprise a communication interface that enables data transmission between the sensor system and other systems. This allows the determined position data of the V-formation to be easily passed on to other systems and used for further processing.

Furthermore, the sensor system can be connected to a database system in which the determined position information of the V-formation is stored. This enables simple and structured management of the position data for future analyses or evaluations.

Another advantage of the sensor system is that the computer-implemented method of random forest regression can be flexibly adapted. By adding or removing training data, the method can be improved and adapted to different application scenarios. This enables optimal performance of the sensor system in different application areas and environments.

Another advantage of the sensor system is its scalability. By using storage media such as RAM or NVM, the sensor system can be easily adapted to the requirements of the respective application. This enables efficient and reliable processing of large amounts of data.

In addition, the sensor system offers high accuracy and precision in determining the position of the V-formation. By combining the sensor element with the computer-implemented Random Forest Regression method, possible measurement errors are minimized, and measurement accuracy is maximized.

Another important aspect of the sensor system is its robustness and reliability. By using modern technologies and high-quality materials, the sensor system ensures long-term and stable performance even under demanding conditions.

In summary, the sensor system with the control device, the sensor element and the computer-implemented method of Random Forest Regression offers an efficient, precise and reliable solution for determining the position of a V-formation. The flexibility, scalability and high accuracy of the system make it ideal for various applications in regions such as aviation, logistics or animal behavior. By using modern technologies and materials, the sensor system sets new standards in position determination and enables innovative solutions for the challenges of our time.

### Gaussian Process Regression

In a further embodiment of the sensor system, the sensor system comprises a control device for setting a first measurement parameter within a first measurement parameter interval and a second measurement parameter within a second measurement parameter interval. A sensor element determines a sensor element measured value depending on the set measurement parameters for a specific measurement point. The sensor system uses a computer-implemented method of Gaussian Process Regression, which is applied by the control device to determine the next measurement point based on the next first measurement parameter and the next second measurement parameter with as few iterations as possible.

In one embodiment of the sensor system, the computer-implemented method of Gaussian Process Regression is used to determine the position of the V-formation in the X-Y plane from the first measurement parameter as the X-coordinate and the second measurement parameter as the Y-coordinate. By precisely determining the position of the tip (30) of the V-formation, the sensor system enables accurate positioning.

In a further embodiment, the sensor system is used to determine the position of the tip (30) of the V-formation in the X-Y plane from the first measurement parameter as the X coordinate and the second measurement parameter as the Y coordinate. This enables the precise detecting and deployment of the tip position, which can be used by a higher-level system to enable optimal coordination and control of processes in which the position of the V-formation, in particular the tip (30) of the V-formation, and/or the value of information derived from it and/or the value of function-equivalent information is of importance.

The computer-implemented Gaussian Process Regression method in conjunction with the sensor element and the control device enables precise and efficient determination of the position of the lower tip of the V-formation based on the measurement parameters. This is achieved by the method using steps to optimize the next measurement points based on the uncertainty of the predictions and adaptively adjusting the distribution of measurement points to more efficiently determine the location of the V-formation.

Another advantage of the sensor system is that the computer-implemented method of Gaussian Process Regression is stored on a memory-based medium and is executed by a processor of the control device. The memory-based medium can be, for example, a computer program product, a hard disk, a flash memory or another non-volatile storage medium (NVM). This increases the flexibility and scalability of the system.

In a variant of the proposal, the control device of the sensor system comprises a processor and a memory, wherein the memory contains the code for the computer-implemented method of Gaussian Process Regression and the processor retrieves and executes the code from the memory. This ensures efficient execution of the method and enables fast and precise determination of the position of the V-formation, in particular the tip (30) of the V-formation, and/or information derived therefrom and/or function equivalent information.

It should be noted that this description provides additional explanations of how the sensor system works and the computer-implemented method of Gaussian Process Regression. By applying Gaussian Process Regression, the next measurement points are determined based on the next first and second measurement parameters. As few iterations as possible are required to ensure high accuracy and efficiency.

The use of Gaussian Process Regression enables the precise determination of the position of the V-formation in the X-Y plane by using the first measurement parameter as the X-coordinate and the second measurement parameter as the Y-coordinate. By efficiently detecting the position of the V-formation, in particular the tip (30) of the V-formation, and/or information derived therefrom and/or functionally equivalent information, the sensor system can be used in various applications.

The control device of the sensor system stores the determined position value of the V-formation, in particular the tip (30) of the V-formation, and/or information derived from it and/or functionally equivalent information for use by a higher-level system. This enables seamless integration of the sensor system into a comprised system and provides a reliable information basis for higher-level processes.

By combining the computer-implemented method of Gaussian Process Regression with the sensor element and the control device, the measurement parameters are used to accurately determine the position of the V-formation, in particular the tip (30) of the V-formation, and/or a derived information and/or a function-equivalent information n and keep it available for use by a higher-level system. This integration enables precise control and optimal utilization of the V-formation in various applications.

In summary, the sensor system with the computer-implemented method of Gaussian Process Regression offers an efficient and precise method for determining the position of the V-formation. The use of a memory-based medium, which contains the code for the method, and the integration of a processor enable optimal execution of the method. This achieves accurate position results and provides a reliable basis for higher-level systems.

### Artificial Neural Network Models

In a further embodiment of the sensor system, the control device comprises a processor unit (control device CTR) and a storage medium (RAM, NVM), wherein the storage medium (RAM, NVM) preferably contains the code for the computer-implemented method using artificial neural network models and the processor unit retrieves and executes the code from the storage medium. This ensures efficient execution of the method and enables fast and precise determination of the position of the tip 30 of the V-formation or function-equivalent information.

In a variant of the proposal, the computer-implemented method using artificial neural network models is used to determine the position of the V-formation in the X-Y plane based on the first measurement parameter as the X-coordinate and the second measurement parameter as the Y-coordinate. By applying this method with as few iterations as possible, high accuracy and efficiency in position detection is achieved.

The control device of the sensor system keeps the specific position of the V-formation, in particular the tip (30) of the V-formation, and/or information derived from it and/or functionally equivalent information available for use by a higher-level system. This enables seamless integration of the sensor system into a comprised system and creates a reliable information basis for higher-level processes.

The computer-implemented method using artificial neural network models is preferably stored on a memory-based medium, such as a RAM (Random Access Memory) or a NVM (Non-Volatile Memory), and is executed by the processor unit of the control device. This storage and execution enable optimal utilization and scalability of the method.

The sensor system thus provides an efficient and precise method for determining the position of the tip 30 of the V-formation or functionally equivalent information. By using artificial neural network models in combination with the sensor element and the control device, the measurement parameters are used to precisely determine the position and keep it available for use by a higher-level system. This enables precise control and optimal use of the V-formation in various applications.

Furthermore, the sensor system is flexible and versatile as it supports different types of memory-based media, such as computer program products, hard disks, flash memory or other non-volatile memory media. This allows the sensor system to be adapted to the specific requirements and conditions of the respective application.

### Gradient-Based Optimization

In a further embodiment of the sensor system, a computer-implemented method of gradient-based optimization is used to determine the exact position of the tip 30 of the V-formation or a functionally equivalent position in the X-Y plane. The method uses the control device to determine the next measurement point based on the first and second measurement parameters with as few iterations as possible.

The sensor system enables precise determination of the position of the tip 30 of the V-formation or a function-equivalent position by using the computer-implemented method of gradient-based optimization. The control device ensures that the first and second measurement parameters are set within their respective intervals to achieve accurate measured values. By using the gradient-based optimization method, the next measurement points are determined with high efficiency and accuracy, enabling precise position detection.

The combination of the sensor element and the control device makes it possible to accurately determine the position of the tip 30 of the V-formation and/or a functionally equivalent position. The sensor system can provide the position information for a multiplicity of applications, such as in aviation, robotics, logistics and agriculture.

The use of the computer-implemented method of gradient-based optimization offers numerous advantages. By using the gradient of the sensor element measurement value according to the measurement parameters, accurate and efficient measurement points can be determined. The method also allows adaptive steps to adjust the step size or the step procedure, resulting in improved adaptability. In addition, further optimization techniques such as conjugate gradients or L-BFGS can be used to achieve an even more efficient and accurate determination of the positions.

Preferably, the sensor system comprises the control device comprises a processor and a non-volatile memory containing the code for the computer-implemented method of gradient-based optimization. This allows the processor to retrieve and execute the code to enable the determination of the positions of the V-formation, in particular the peak (30) of the V-formation, and/or information derived therefrom and/or function equivalent information. The use of a non-volatile storage medium ensures that the code is permanently stored and can be retrieved at any time.

The user interface of the sensor system allows the user to adjust the settings of the measurement parameter intervals and retrieve the results of the position detection. This enables user-friendly adaptation to different requirements and application scenarios.

The sensor system is able to determine the position of the tip 30 of the V-formation or a functionally equivalent position in real time and transmit the results to a higher-level system. This enables real-time monitoring and processing of the position data for rapid response and decision-making.

In addition to the description of the sensor system, the patent application also comprises further claims. In a variant of the proposal, a computer-implemented device for carrying out the method may be deployed. This device comprises a processor (control device CTR) and a memory (RAM, NVM) containing the code for the computer-implemented method, which is retrieved and executed by the processor (control device CTR).

Another storage medium (RAM, NVM) can be used to store the code for the computer-implemented method. This storage medium (RAM, NVM) is used in conjunction with the control device of the sensor system.

A user interface makes it possible to set the measurement parameter intervals and retrieve the results of the position detection. This allows the user to interact easily with the sensor system.

The higher-level system communicates with the sensor system and receives the position results. These results can be used for further processing or display, for example to enable coordinated behavior of multiple sensor systems. By exchanging position data between the individual sensor systems, they can work together on a task, such as monitoring a large area or carrying out cooperative processes and methods.

In addition, the sensor system offers the possibility of integration with other systems or platforms. For example, it could be integrated into an airplane or drone to enable precise positioning during flight by using the earth's magnetic field. It could also be integrated into autonomous vehicles to improve their navigation and avoid collisions.

The sensor system could also be used in agriculture to determine the position of agricultural equipment or vehicles and assist them in carrying out tasks such as plowing, sowing or harvesting. Precise positioning can help to improve the efficiency and accuracy of agricultural processes.

Furthermore, the sensor system could be used in robotics to detect the position of robots in a production environment or in other applications. This allows robots to perform precise tasks, avoid collisions and work efficiently with other robots or human workers.

Overall, the described sensor system with its computer-implemented method of gradient-based optimization enables precise and efficient position determination of the V-formation, in particular the tip (30) of the V-formation, and/or information derived therefrom and/or function-equivalent information. Through integration into various systems and applications, it opens up a wide range of possibilities for improving processes, safety and coordination.

### Gradient Descent

In a further embodiment of the sensor system, the higher-level system communicates with the sensor system and receives the position results. These results, which represent the position of the lower tip 30 of the V-formation in the X-Y plane or functionally equivalent information, can be used for further processing or display, for example to enable coordinated behavior of multiple sensor systems.

The sensor system uses a computer-implemented gradient descent method to determine the position of the lower tip 30 of the V-formation in the X-Y plane or a function-equivalent information from the first measurement parameter as the X coordinate and the second measurement parameter as the Y coordinate with as few iterations as possible. The gradient descent method enables efficient and accurate position determination by using adaptive steps to adjust the step size or step method. This allows the next measuring point to be determined precisely.

To further improve accuracy and efficiency, other optimization techniques such as conjugate gradients or L-BFGS (Limited-memory Broyden-Fletcher-Goldfarb-Shanno) can be added to the computer-implemented gradient descent method. These techniques help to determine the position of the lower peak 30 of the V-formation in the X-Y plane or a function equivalent information even more accurately.

To increase user-friendliness, the control device has a user interface that allows the user to adjust settings such as the first measurement parameter interval and the second measurement parameter interval. In addition, the results of the position determination can be retrieved via the user interface.

The sensor system is able to determine the position of the lower tip 30 of the V-formation in the X-Y plane or functionally equivalent information in real time and transmit the results to the higher-level system in real time. This enables real-time monitoring and control.

A computer-implemented device comprising a processor and a memory is provided for implementing the method described. The memory contains the code for the computer-implemented gradient descent method, while the processor retrieves and executes the code from the memory.

In addition, a non-volatile storage medium (NVM) is preferably provided which stores the code for the computer-implemented gradient descent method and is used in conjunction with the control device of the sensor system. This allows the method to be transferred to and used on other systems or platforms.

The user interface allows the user to adjust the measurement parameter intervals and retrieve the results of the position determination. This increases the flexibility and adaptability of the sensor system. The user can adjust the measurement parameter intervals according to the specific requirements and environmental conditions to achieve optimal results. The user can be a device.

Furthermore, the user interface enables the user to conveniently access the determined position data of the V-formation, in particular the tip (30) of the V-formation, and/or information derived therefrom and/or function-equivalent information. This information can be used for various purposes, for example for monitoring and analyzing the V-formation or for integration into a higher-level system.

The use of the computer-implemented method of gradient descent in conjunction with adaptive steps and further optimization techniques ensures efficient and accurate position determination of the V-formation, in particular the tip (30) of the V-formation, and/or information derived therefrom and/or function-equivalent information. By adapting the step size or the step method, the sensor system can determine the position with high precision and at the same time minimize the calculation effort.

The real-time capability of the sensor system enables fast and continuous detecting of the position data of the V-formation, in particular the tip (30) of the V-formation, and/or information derived therefrom and/or function-equivalent information. This is particularly important in applications where real-time information is required, for example to ensure smooth navigation or coordination of multiple sensor systems.

The implementation of the computer-implemented method of gradient descent in a computer-implemented device with processor (control device CTR) and memory (RAM, NVM) offers an efficient and flexible solution. The code for the method can be stored on the storage medium as memory (RAM, NVM) and can be retrieved and executed by the processor as required. This makes it easy to integrate the sensor system into existing systems or platforms.

The non-volatile storage medium (NVM) serves as a reliable and permanent storage of the code for the method. This means that the sensor system can retain its functionality even after a restart or power failure and can be seamlessly resumed.

Overall, the sensor system enables precise, efficient and real-time positioning of the lower tip 30 of the V-formation or function-equivalent information using the computer-implemented method of gradient descent. The user interface, customization options and integration into existing systems contribute to the versatility and applicability of the sensor system. By improving the position determination of the V-formation, in particular the tip (30) of the V-formation, and/or information derived therefrom and/or function-equivalent information in various application areas, the sensor system can contribute to optimized performance and efficiency.

### Stochastic Gradient Descent

In a further embodiment of the sensor system, a computer-implemented method of stochastic gradient descent is used to determine the next measurement point from the next first and second measurement parameters. This determines the position of the peak 30 of the V-formation or functionally equivalent information in the X-Y plane with as few iterations as possible. The method uses the first measurement parameter as the X-coordinate and the second measurement parameter as the Y-coordinate. The control device of the sensor system applies adaptive steps to adjust the step size or the step method, which enables efficient and accurate position determination.

The use of stochastic gradient descent in conjunction with adaptive steps enables the sensor system to determine precise measurement points and accurately detect the position of the tip 30 of the V-formation or function-equivalent information. By adapting the step size or the step method, the sensor system can determine the position with high precision and at the same time minimize the calculation effort.

The use of further optimization techniques such as Momentum or Nesterov Momentum improves the efficiency of the stochastic gradient descent and contributes to a more accurate position determination. These techniques enable the sensor system to find converging solutions faster and overcome potential local minima.

The control device of the sensor system is equipped with a user interface that enables the user, who may also be a device, r to adjust the measurement parameter interval and to retrieve the results of the position determination of the V-formation, in particular the tip (30) of the V-formation, and/or information derived therefrom and/or function-equivalent information. The user interface provides interactive setting options, B. sliders or input fields, to adjust the measurement parameter interval. Furthermore, it is preferably adapted to the intended use by human users such that it deploys a graphical user interface that visually represents the position of the peak 30 of the V-formation or the function-equivalent information on a graph in the X-Y plane and displays the numerical coordinates.

By using the computer-implemented method of stochastic gradient descent in conjunction with adaptive steps and other optimization techniques, the sensor system ensures efficient and accurate positioning of the V-formation and/or function equivalent information. The user interface allows easy adjustment of the measurement parameter intervals and convenient access to the results. These functions contribute to the flexibility and adaptability of the sensor system.

The sensor system can determine the position of the tip 30 of the V-formation or functionally equivalent information in real time and transmit the results to a higher-level system in real time. This enables fast and continuous detecting of position data and is particularly important in applications where real-time information is required, for example for precise navigation or coordination of multiple sensor systems.

### Gradient-Based Optimization

In a further embodiment of the sensor system, a control device is deployed which is able to set a first measurement parameter within a first measurement parameter interval and to set a second measurement parameter within a second measurement parameter interval. A sensor element is also provided, which provides a sensor element reading depending on the set measurement parameters. The control device applies a computer-implemented method of gradient-based optimization to determine the next measurement point based on the next measurement parameters. Furthermore, the sensor system comprises a system for determining the position of the tip of a V-formation in the X-Y plane or functionally equivalent information, the position being defined by the X coordinate of the first measurement parameter and the Y coordinate of the second measurement parameter. A storage device is used to keep the specific position of the V-formation or function-equivalent information available for use by a higher-level system. There is also a user interface that enables the measurement parameter intervals to be set and the results of the position of the V-formation or the function-equivalent information to be retrieved. A device can be a user.

In a variant of the proposal, a device for carrying out the method according to the previous section may be deployed. This device comprises a processor (control device CTR) for executing the computer-implemented method of gradient-based optimization and for controlling the sensor system. Further, a memory is provided to store the code for the computer-implemented method and the required data. A non-volatile storage medium is used in conjunction with the control device of the sensor system to store the code for the method and the required data.

In one embodiment, the control device of the sensor system may perform adaptive step size adjustment as part of the computer-implemented method of gradient-based optimization to improve convergence of the method. In another embodiment, the control device may perform step size adaptation as part of the method to optimize efficiency. In another embodiment, the control device may perform an adaptive adjustment of the measurement parameter intervals based on the progression of the gradient-based optimization procedure to accelerate the search for the position of the V-formation.

The sensor element and/or the sensor system may comprise a noise suppression function to reduce interference on the measured values and improve the accuracy of the determination of the position of the V-formation. The user interface may additionally provide a visualization of the position of the V-formation on the X-Y plane to provide the user with an intuitive representation of the determined position. The memory device may store further information about the V-formation to enable a comprise characterization.

The computer-implemented method of gradient-based optimization can use various optimization techniques to determine the next measurement point based on the next measurement parameters. Examples of such techniques are the steepest-descent method or the Newton method. The selection of the appropriate optimization technique may depend on the specific requirements of the sensor system.

Determining the position of the tip of a V-formation in the X-Y plane or function-equivalent information can be useful in various applications. For example, the sensor system could be used in aviation to determine the position of an aircraft formation. In robotics, it could be used to determine the position of a robot. The possible applications are diverse and depend on the specific requirements of the system in question.

Overall, the proposed sensor system with the computer-implemented method of gradient-based optimization provides an efficient and precise method for determining the position of a V-formation. By integrating functions such as noise reduction, visualization and storage, a comprehensive characterization of the V-formation is made possible. This can lead to improved control, monitoring or analysis in various application areas.

### Simulated Annealing

The sensor system comprises a control device which is used to set a first measurement parameter within a first measurement parameter interval and a second measurement parameter within a second measurement parameter interval. A sensor element determines a sensor element measured value as a function of the set measurement parameters. The sensor system is preferably able to form measurement points in the Cartesian coordinate system, whereby the first measurement parameter determines the x-coordinate on the x-axis and the second measurement parameter determines the y-coordinate on the y-axis and the sensor element measured value determines the z-coordinate on the z-axis.

Furthermore, the sensor system can determine and output the position 30 of the lower tip of a V-formation on the X-Y plane or functionally equivalent information that can be derived from the first measurement parameter as the X coordinate and the second measurement parameter as the Y coordinate.

To determine the position 30 of the lower peak of the V-formation or the function-equivalent information, the control device uses the computer-implemented method of simulated annealing. This method makes it possible to determine the next measurement point based on the next measurement parameters in order to determine the position 30 of the lower peak of the V-formation or the function-equivalent information with as few iterations as possible. The calculated position 30 of the lower peak of the V-formation or the function-equivalent information is then kept available for use by a higher-level system.

In addition to the above features, the sensor system comprises further functional features and advantages. A communication interface of the sensor system (e.g. a data interface) enables the transfer of the determined position 30 of the lower tip of the V-formation or the function-equivalent information to the higher-level system. A memory unit in the control device contains a storage medium on which the computer-implemented method of simulated annealing is stored. A data analysis unit (e.g. as part of the control device CTR and/or pattern recognition device MEV) performs an analysis of the detected sensor element readings and/or the filter output signal (S4) in order to recognize patterns or structures and improve the determination of the position 30 of the lower peak of the V-formation or the function equivalent information.

The user interface allows a user to make inputs for adjusting the measurement parameters and controlling the method of simulated annealing. The user can be a device. A calibration unit (e.g. as part of the control device CTR and/or pattern recognition device MEV) makes it possible to calibrate the sensor system based on known reference values and to ensure an accurate determination of the position 30 of the lower tip of the V-formation or the function-equivalent information.

By using high-resolution sensor technology in the sensor element, precise sensor element readings are provided, resulting in an accurate determination of position 30. This enables precise localization of the lower tip of the V-formation or accurate determination of the function equivalent information.

### Nelder-Mead Algorithm

In a further embodiment of the sensor system, a first measurement parameter is set within a first measurement parameter interval, and a second measurement parameter is set within a second measurement parameter interval by a control device. A sensor element determines a sensor element measured value for a set measuring point based on the first measuring parameter and the second measuring parameter. The measured value of the sensor element is entered into a three-dimensional Cartesian coordinate system, whereby the x-coordinate on the x-axis is determined by the first measurement parameter and the y-coordinate on the y-axis by the second measurement parameter. The z-coordinate on the z-axis is determined by the measured value of the sensor element. A position detection unit recognizes that the maxima of the absolute value of the gradient of the measured value of the sensor element according to the x-coordinate and the y-coordinate result in a V-formation on the X-Y-plane with a peak 30 of this V-formation. The task of the sensor system is to determine and output the position 30 of this lower peak of this V-formation in the X-Y plane and/or functionally equivalent information.

According to an embodiment of the sensor system according to the preceding section, the control device will apply the Nelder-Mead algorithm, a computer-implemented method, to determine the next measurement point from a next first measurement parameter and a next second measurement parameter. As a result, the position 30 of this lower peak of this V-formation in the X-Y plane and/or a function equivalent information is calculated and deployed for use by a higher-level system. The Nelder-Mead algorithm is a heuristic optimization method based on an iterative process for adjusting the measurement parameters to determine the position 30 of this lower peak of this V-formation in the X-Y plane and/or the function-equivalent information with as few iterations as possible. This enables efficient and accurate position detection.

The control device of the sensor system may also comprise a separate storage medium, wherein the storage medium stores the current values of the first measurement parameter, the second measurement parameter and the sensor element measurement value. Thereby, the Nelder-Mead algorithm is iteratively performed to determine the position 30 of this lower peak of this V-formation in the X-Y plane and/or a function equivalent information.

To check the convergence of the calculation of the position 30 of this lower peak of this V-formation in the X-Y plane and/or the function-equivalent information, the control device can perform a convergence criterion check and end the iterations of the Nelder-Mead algorithm accordingly. This ensures that the position detection is reliable and precise.

In order to detect and correct errors in the measurements of the sensor element, the control device can use an error detection and correction procedure. This method makes it possible to identify and correct errors in the measurements of the sensor element.

The error detection and correction process can comprise various techniques, depending on the specific requirements of the system. One option is to compare the detected data with predefined threshold values. If the measured values are outside the expected limits, an error is detected. In such cases, the control device can take appropriate corrective action to improve the accuracy of the position detection.

Another option is to use statistical methods for error detection and correction. This involves analyzing the measured values to identify deviations and anomalies. Based on these findings, the control device can carry out error corrections, for example by adjusting the data filtering or recalculating the measured values.

In addition, the control device can also rely on redundancy by using multiple sensor elements. By comparing the measured values of the different sensor elements, the device can detect and correct errors, for example by eliminating outlier values or using the average of the measurements.

Overall, the error detection and correction function serves to ensure the reliability and accuracy of the position detection. By detecting and correcting potential errors, the control device can enable precise determination of the position of the lower tip of the V-formation in the X-Y plane or the function-equivalent information.

### Particle Swarm Optimization (PSO)

In a further embodiment of the sensor system, the computer-implemented method of particle swarm optimization (PSO) is used to determine the next measurement point from the next first measurement parameter and the next second measurement parameter. In this process, the control device simulates a group of particles in the multidimensional search space, with each particle representing a set of measurement parameters. The particles search for the optimum of the V-formation, maximizing the position 30 of the lower peak of the V-formation in the X-Y plane and/or a function equivalent information from the first measurement parameter as X-coordinate and the second measurement parameter as Y-coordinate.

The computer-implemented Particle Swarm Optimization (PSO) method uses a particle position update function where particles update their position based on their current positions, their individual best positions and the best positions of other particles. This leads to a convergence to the optimum of the V-formation and enables precise position determination.

To prevent the particles from converging or leaving the search space too quickly and to ensure a comprise exploration of the search space, the computer-implemented method of PSO applies various velocity and motion constraints to the particles.

The PSO method uses a predefined termination criterion to end the search process. This can happen when a certain number of iterations has been reached or a predefined accuracy of determining the position 30 of the lower peak of the V-formation in the X-Y plane and/or the function equivalent information has been reached. This ensures efficient and accurate V-formation detection.

To enable efficient and accurate V-formation detection, the computer-implemented method of PSO uses adaptive parameter adjustment. The control device adjusts the parameters of the PSO method based on the progress of the search process and the quality of the determined position 30 of the lower peak of the V-formation in the X-Y plane and/or the determined function-equivalent information.

The PSO method contains a stochastic component that introduces random fluctuations in the particle positions. This enables a broader exploration of the search space and reduces the risk of local optima.

In order to achieve faster convergence and better position determination, the control device adjusts the step size of the particles based on the convergence speed and the progress of the search process. This enables an effective and efficient search in the search space.

To achieve higher position detection accuracy, the particles perform a tight spiral motion in the vicinity of promising positions 30 of the lower peak of the V-formation in the center of the V-formation. This spiral allows the particles to fine-tune their positions and enable more accurate detection of the target position. Meanwhile, the outer particles keep their positions stable to maintain the shape of the V-formation and ensure the stability of the swarm.

This combination of tight spiral motion and maintaining V-formation allows the particles to continuously improve their positions and increase tracking accuracy. In addition, the close cooperation within the swarm enables effective information transfer between the particles, resulting in optimized position detection.

The behavior of particles in the V-formation is an example of cooperative behavior that is frequently observed in swarm intelligence. Through cooperation and communication within the swarm, complex tasks can be solved more efficiently and accurately. This principle is applied in various regions such as robotics, optimization algorithms and artificial intelligence to solve diverse problems and find innovative solutions.

### Genetic Algorithms

In one embodiment of the proposed sensor system for determining the position 30 of the apex of a V-formation in an X-Y plane or functionally equivalent information, the following components are used:

The sensor system comprises a sensor element that detects measured values depending on a first and a second measurement parameter. A pair of first and second measurement parameters each form a measurement point. A control device is used to set the measurement parameters within predefined measurement parameter intervals.

A computer-implemented method, preferably using computer-implemented genetic algorithms, is used to determine the next measurement point based on the next first and second measurement parameters. This method enables efficient position determination of the peak of the V-formation or function equivalent information.

An output unit is preferably used to provide the position 30 of the tip of the V-formation in the X-Y plane or the function-equivalent information. The first measurement parameter is preferably used as the X-coordinate and the second measurement parameter as the Y-coordinate. This information can be used by a higher-level system.

The computer-implemented method preferably uses a storage medium (RAM, NVM) to store the data, parameters and intermediate results of the genetic algorithm. By applying the genetic algorithm, the position of the peak of the V-formation or the function-equivalent information is determined with as few iterations as possible. The measurement parameters are optimized by the genetic algorithm to ensure efficient position determination.

The sensor system preferably comprises a data interface for communication of the control device (CTR) with the higher-level system in order to provide the position 30 of the tip of the V-formation in the X-Y plane or the function-equivalent information.

The sensor element of the sensor system is preferably a novel and inventive element that determines and provides the measured value depending on the measurement parameters with a good Cpk value in series production. This enables precise positioning of the tip of the V-formation in the X-Y plane or the function-equivalent information.

The computer-implemented method of genetic algorithms preferably uses a multi-point search in which several measuring points are explored simultaneously in the search space. This increases the efficiency of the method for determining the position of the V-formation.

The sensor system preferably has an error detection function and error correction function, which makes it possible to identify and eliminate measurement errors, outliers or faults in the measurement process. This ensures precise positioning.

In addition, the sensor system offers a data backup function to back up, archive or restore the stored data in the long term and thus ensure the integrity of the measurement data.

The sensor system is preferably expandable and can preferably be supplemented with additional components or functions in order to meet the requirements and needs of the user. Possible extensions comprise:

Additional sensors: Depending on the area of application, further sensors can be added to detect additional data. For example, temperature sensors, humidity sensors or air quality sensors could be integrated to provide more comprehensive environmental information.

Communication modules: To improve the connectivity of the sensor system, communication modules such as WLAN, Bluetooth or mobile phone technologies can be integrated. This allows the collected data to be transferred wirelessly to other devices or cloud services.

Data analysis and processing: By integrating powerful software, the sensor system can analyze and process data in real time by means of computer-implemented methods. This enables an immediate response to specific events or the execution of complex computer-implemented algorithms to extract valuable information.

Energy efficiency: To extend the battery life of a battery-based power supply for the sensor system, the sensor system can be equipped with energy-efficient components. This comprises, for example, the use of low-power microcontrollers, intelligent energy management and energy recovery technologies.

User interfaces: To improve operation and interaction with the sensor system, additional user interfaces can be implemented. This could comprise the integration of touchscreens, voice control or remote controls to enable intuitive control.

These expansion options make the sensor system flexible and adaptable for different application scenarios. Users can extend the system's functions to meet their specific requirements and benefit from the sensor system's versatile capabilities.

### Bayesian Optimization

In a variant of the proposed sensor system, the position 30 of the lower tip of a V-formation is determined in an X-Y plane or functionally equivalent information. The sensor system comprises a control device for setting a first measurement parameter within a first measurement parametric interval and a second measurement parameter within a second measurement parametric interval. A pair of a first measurement parameter and a second measurement parameter forms a measurement point. A sensor element detects a sensor element measured value depending on the set measuring points. The measured value of the sensor element is preferably entered in a virtual, three-dimensional Cartesian coordinate system. The x-coordinate is determined by the first measurement parameter, the y-coordinate by the second measurement parameter and the z-coordinate by the sensor element measurement value.

For example, to determine the position 30 of the lower peak of the V-formation or function-equivalent information, the sensor system uses a Bayesian optimization function. This function implements a computer-implemented method to determine the next measurement point from a next first measurement parameter and a next second measurement parameter. A position detection unit (pattern recognition device MEV, control device CTR) then determines the position 30 of the lower peak of the V-formation or function-equivalent information from the determined measurement point. In addition, a storage medium function (RAM, NVM) deploys the position 30 of the lower peak of the V-formation or function-equivalent information for use by a higher-level system.

The Bayesian optimization function of the sensor system minimizes the number of iterations required to determine the position 30 of the lower peak of the V-formation in the X-Y plane or the function-equivalent information. This increases the efficiency of the method and enables faster position detection.

The sensor system can also be implemented as a computer program product function, which deploys a computer-readable program that implements the Bayesian optimization function to determine the next measurement point. This increases the flexibility of the system and makes it easy to update or extend the functions.

A wireless and/or wired communication interface function, for example by means of a data interface, enables the transfer of data or information between the sensor system and other devices or systems. This enables seamless integration of the sensor system into existing networks or systems.

The sensor system comprises a processor unit (control device CTR) and a storage medium (RAM, NVM) to enable the execution of the computer-implemented method and the storage of data. This ensures efficient processing and storage of the detected measurement data and results.

A typically computer-implemented error detection function and error correction function is preferably integrated into the sensor system in order to identify and eliminate measurement errors, outliers or disturbances in the measurement process. This improves the accuracy of position detection and achieves reliable results.

To secure and maintain data integrity in the long term, the sensor system preferably has a memory mechanism that logs the detected measurement data and stores it securely in a memory (RAM, NVM). This ensures that the measurement results are protected against loss or damage even after detecting.

In addition, the sensor system is preferably equipped with a calibration function, which is preferably performed regularly in order to maintain the measurement accuracy. Internal reference values are used to detect and correct any deviations or drifts. This regular calibration ensures high precision and reliability of the position detection.

Another feature of the sensor system is preferably the integration of a real-time monitoring function. This enables continuous monitoring of the sensor data during the measurement process. Deviations or anomalies are detected immediately and can be rectified quickly to ensure uninterrupted and reliable detection of the position information.

In summary, the sensor system enables precise, reliable and safe position detection by integrating an error detection function and error correction function, a memory mechanism, a calibration function and a real-time monitoring function. These functions help to identify and eliminate measurement errors and improve the accuracy of position information, which in turn provides reliable results.

### Other

The above description makes no claim to completeness and does not limit this disclosure to the examples shown. Other variations on the disclosed examples may be understood and practiced by those of ordinary skill in the art from the drawings, the disclosure, and the claims. The indefinite articles “one” or “a” and its inflections do not preclude multiplicity, while the mention of a specific number of elements does not preclude the possibility of more or fewer elements. A single entity can fulfill the functions of several elements mentioned in the revelation, and conversely, several elements can fulfill the function of one entity. Numerous alternatives, equivalents, variations and combinations are possible without departing from the scope of the present disclosure.

Unless otherwise indicated, all features of the present disclosure can be freely combined with one another. This applies to the entire document presented here. The features described in the figure description can also be freely combined with the other features as features of the disclosure, unless otherwise stated. A restriction of individual features of the embodiments to the combination with other features of the embodiments is expressly not intended. In addition, object features of the device can also be reformulated as process features and process features can be reformulated as object features of the device. Such a reformulation is thus automatically disclosed.

Reference is made to the accompanying drawings in the preceding detailed description. The examples in the description and drawings should be regarded as illustrative and should not be regarded as limiting the specific example or element described. Several examples may be derived from the preceding description and/or the drawings and/or the claims by modifying, combining or varying certain elements. In addition, examples or elements that are not described verbatim may be derived by a person skilled in the art from the description and/or drawings.

### BRIEF DESCRIPTION OF FIGURES

FIG. 1 shows an exemplary and schematically simplified system of an application device according to the second application example of a motor.

FIG. 2 shows an optical waveguide LWL with a sensor element SE directly on the center MP of the core of the optical waveguide LWL.

FIG. 3 shows a motor of an application device corresponding to the second application example of a motor as schematically sketched in simplified form in FIG. 1, wherein in addition to the optical waveguide LWL) with the sensor element SE, which extends into the motor via the said opening OF and which is encased by the mechanical sheath MH, the suspension of the motor comprises a position sensor POS with an LED and a photodiode, which generates the position signal POSS with the aid of a marking MRK on the rotor housing GHR.

FIG. 4 shows the filter output signal S4 generated by the lock-in amplifier LIV as a flux density measurement signal and the position signal POSS of the position detector POS of FIG. 3.

FIG. 5 shows a cross-section through the exemplary first end ELWL1 of a proposed optical waveguide LWL).

FIG. 6 shows an exemplary and schematically simplified material measuring system with a sensor head SK according to the proposal.

FIG. 7 shows a sensor head SK with the mechanical sheath of the optical waveguide LWL) covered by the mechanical sheath MH.

FIG. 8 shows the sensor head SK of FIG. 7 in top view (FIG. 8a) and in side view (FIG. 8b) as a sectional view.

FIG. 9 shows the steps of the method for the fabrication of a proposed sensor head SK and its use.

FIG. 10a shows a top view of an exemplary workpiece made of a ferromagnetic material FM.

FIG. 10b shows an exemplary value curve of the measurement signal S4 obtained as a function of the position x of the sensor head SK on the surface OF of the workpiece of FIG. 10a.

FIG. 11 shows the device.

FIG. 12 shows the device with the cover fitted for light tight closure of the housing 8.

FIG. 13 corresponds to FIG. 11, whereby the exemplary device is now shown from a different angle.

FIG. 14 shows a cross-section of the device.

FIG. 15 shows an exemplary cross-section, not to scale, of the sensor layer 5.

FIG. 16 shows a typical situation in which the magnetic field camera head 21 is preferably placed on the surface 34 of the respective measurement object with the underside 24 of the housing 8.

FIG. 17 shows the system of FIG. 14 simplified with the control and evaluation devices as a block diagram.

FIG. 18 shows a drawing based on an exemplary photograph of an exemplary sensor head 21 with the cover removed, created during the preparation of the proposal presented here.

FIG. 19a shows a drawing based on an exemplary photograph of an exemplary sensor head 21 with the cover removed, created during the preparation of the proposal presented here.

FIG. 19b essentially corresponds to FIG. 19a and shows the same magnetic field camera head 21 from a slightly different perspective.

FIG. 20 shows a drawing of the prototype with the cover in place. The interior of the housing 8 of the magnetic field camera head 21 is then sealed light-tight.

FIG. 21 shows an arrangement of permanent magnets 37 used for to generate the magnetic flux image 39 of FIG. 22.

FIG. 22 shows the magnetic flux density image 39 of the arrangement of the permanent magnets 37 of FIG. 21.

FIG. 23 shows a representation for four magnetized rings.

FIG. 24 corresponds to FIG. 21 and FIG. 25 corresponds to FIG. 22, but a magnetizable ferromagnetic flat figure (see FIG. 23) was used to create FIG. 25.

FIG. 25 above shows the two-dimensional pattern-coded magnetic flux density magnitude image 39 of the distribution of the magnetic flux density of the magnetized figure on a glass plate 38 in arbitrary units.

FIG. 26 shows an illustration of an inhomogeneously magnetized ring. FIG. 26 shows the corresponding arrangement at the bottom left as a drawing based on a photo.

FIG. 27 shows the sensor head with attached auxiliary magnets 19.

FIG. 28 shows the detection and visualization of holes in a ferromagnetic material 17 with a device of FIGS. 28, 16 and 17.

FIG. 29 shows an exemplary, alternative magnetic field camera head 21 of an exemplary, alternative magnetic field camera.

FIG. 30 shows a schematic and simplified cross-section of the magnetic field camera head 21 of FIG. 29.

FIG. 31 essentially corresponds to FIG. 30 and shows the same magnetic field camera head 21 as the device of FIG. 30 and FIG. 29 from a different perspective.

FIG. 32 essentially corresponds to FIGS. 29 to 31 in that FIG. 32 now shows a cross-section through the magnetic field camera head 21 of FIGS. 29 to 31 transversely to the first heat sink 50.

FIG. 33 corresponds to FIGS. 29 to 32 in that FIG. 33 is a side view without section from a different perspective.

FIG. 34 corresponds to FIGS. 29 to 33 in that FIG. 34 is a side view with horizontal section from a perspective from below looking at the sensor layer 5 on the underside 24 of the sensor head 21 of FIGS. 29 to 33.

FIG. 35 corresponds to FIG. 34 with the difference that the cut part of the magnetic field camera head 21 shown in FIG. 34 is now shown with the cut surface facing upwards instead of downwards.

FIG. 36 shows the first heat sink 50 before insertion into the housing 8.

FIG. 37 shows an exemplary second heat sink 49 for cooling the printed circuit board (PCB) 43 for the LEDs 44 and their power supply 45 and the LEDs 44 before it is installed in a sensor head according to FIGS. 29 to 36.

FIG. 38 shows the lower housing part 41 of the housing 8 of a magnetic field camera head 21 according to FIGS. 29 to 37 with the printed circuit board (PCB) 43 before installation in the housing 8.

FIG. 39 shows the underside of the printed circuit board (PCB) 43 of a magnetic field camera head 21 according to FIGS. 29 to 38 with the series resistors 59 of the LEDs 44.

FIG. 40 shows the underside of the printed circuit board (PCB) 43 of a magnetic field camera head 21 according to FIGS. 29 to 39 with the LEDs 44.

FIG. 41 shows the underside of the printed circuit board (PCB) 43 of the magnetic field camera head 21 as shown in FIGS. 29 to 40.

FIG. 42 shows a section through a magnetic field camera head 21 as shown in FIGS. 29 to 41.

FIG. 43 shows a section through a magnetic field camera head 21 as shown in FIGS. 29 to 42.

FIG. 44 largely corresponds to FIG. 23, whereby the magnetic field camera head 21 of FIG. 44 additionally comprises the second heat sink 49 compared to the magnetic field camera head 21 of FIG. 33.

FIG. 45 shows the fluorescence camera of a magnetic field camera head 21 according to FIGS. 29 to 44 in conjunction with the first heat sink 50 as a sectional view.

FIG. 46 shows the fluorescence camera of a magnetic field camera head 21 according to FIGS. 29 to 45 in conjunction with the first heat sink 50, but now not as a sectional view.

FIG. 47 shows the functional principle of the sensor layer 5 as used in the device parts of the sensor head of FIGS. 29 to 46 in FIGS. 30, 31, 32, 34, 35, 38, 39, 40, 41, 42 and 43.

FIG. 48 shows in a schematically simplified manner the functional principle of the sensor layer 5 as it may be used in the device parts of the sensor head of FIGS. 29 to 46 in FIGS. 30, 31, 32, 34, 35, 38, 39, 40, 41, 42 and 43.

FIG. 49 shows the system of FIG. 7 with a magnetic field sensor head of FIGS. 29 to 48.

FIG. 50 corresponds as far as possible to FIG. 47, which shows the functional principle of the sensor layer 5 as used in the device parts of the sensor head of FIGS. 29 to 46 in FIGS. 30, 31, 32, 34, 35, 38, 39, 40, 41, 42 and 43.

FIG. 51a shows the resonances of a diamond single crystal comprising NV centers.

FIG. 51b shows the resonances of a multiplicity of diamonds comprising different NV centers oriented in space.

FIG. 51c explains the determination of an unknown effective magnetic flux density Bₙₖ on the basis of FIG. 51b by means of a variation of the microwave frequency ω_{(μw) in} the region of interest and by means of a simultaneous determination of that portion of the fluorescence radiation FL intensity signal of the multiplicity of diamond nano crystals ND provided with NV centers, in which this proportion of the intensity signal of the fluorescence radiation FL comprises the microwave modulation frequency f_{μW}, as a function of this microwave frequency ω_{μW} in the region of interest.

FIG. 51d explains the determination of an unknown microwave frequency ω_{μWnk}. based on FIG. 51b.

FIG. 52a shows the resonances of a multiplicity of diamonds comprising NV centers oriented differently in space.

FIG. 52b corresponds to FIG. 52a, with different reference lines (561, 562, 563) now drawn in for measurement.

FIG. 52c shows the resonances of a multiplicity of diamonds comprising different NV centers oriented in space.

FIG. 52d corresponds to FIG. 52c, whereby the various reference lines (561, 562, 563) for measurement are now drawn in again. One problem is the noise background, which the control device CTR must suppress.

FIG. 53a shows the resonances of a multiplicity of diamonds comprising NV centers oriented differently in space.

FIG. 53b corresponds to FIG. 53a, whereby the various reference lines (561, 562, 563) for measurement are now drawn in again.

FIG. 53c shows the resonances of a multiplicity of diamonds comprising different NV centers oriented in space.

FIG. 53d corresponds to FIG. 53c, whereby the various reference lines (561, 562, 563) for measurement are now drawn in again.

FIG. 54 shows a single microstrip line 1380 as an example of a microstrip line.

FIG. 55 shows a single slot line 1880 as an example of a slot line.

FIG. 56 shows various placements of different sensor elements in connection with an exemplary trip-plate waveguide 2380.

FIG. 57 corresponds to FIG. 57 supplemented by a flat coil 2520 as magnetic field generation means L_{c}.

FIGS. 58 to 61 illustrate the fabrication of the center sensor element SE(1320) at the second end of the center optical waveguide LWL (4630).

FIGS. 62 to 66 illustrate the fabrication of the center sensor element SE(1320) at the second end of the center optical waveguide LWL (4630) by means of a mask-controlled method.

FIG. 67 corresponds to FIG. 61 supplemented by a flat coil 2520 as magnetic field generation means L_{c}.

FIG. 68 applies the principles of sensor element manufacture to all three sensor elements (1410, 1420, 1430). Corresponding to these are three optical waveguides (4610, 4620, 4630), which are optically isolated from each other, preferably by means of diaphragms etc.

FIG. 69 shows an exemplary, schematic and simplified device for the control, measurement and evaluation of exemplary sensor heads, as shown in FIGS. 54 to 68, if they comprise a sensor element SE.

FIG. 70 shows an exemplary schematic realization of an analog multiple correlator LIV in a schematically sketched construction of FIG. 69.

FIG. 71 shows a device for controlling exemplary three sensor elements SE(1410, 1420, 1430), which are placed on the carrier substrate 1360, by means of an exemplary trip-plate waveguide 2380.

FIG. 72 shows a differential microstrip line 6880. The differential microstrip line 6880 of FIG. 68 again comprises a preferably non- or only slightly electrically conductive carrier substrate 1360.

FIG. 73 corresponds to FIG. 69, with the trip-plate waveguide 2380 replaced by a differential trip-plate waveguide 6980.

ws 7170, 7180 and 7190.

FIG. 74 corresponds to FIG. 69, with the trip-plate waveguide 2380 replaced by a differential microstrip line 6880.

FIG. 75 corresponds to FIG. 69, with the trip-plate waveguide 2380 replaced by a microstrip line 1380.

FIG. 76 corresponds to FIG. 69, with the trip-plate waveguide 2380 replaced by a slot line 1880.

FIG. 77 corresponds to FIG. 71 with the difference that the waveguide is a differential trip-plate waveguide 6830 instead of a trip-plate waveguide 2380.

FIG. 78 corresponds to FIG. 71 with the difference that the waveguide is a differential trip-plate waveguide 6830 instead of a trip-plate waveguide 2380 and that the device of FIG. 78 uses a microwave signal source μWG and a radio wave signal source RFG for control.

FIG. 79 corresponds to FIG. 77, whereby now, firstly, five central sensor elements 1420 are arranged along the differential trip-plate waveguide, each of which is assigned a sensor element channel.

FIG. 80 corresponds to FIG. 79 with the difference that a gradient afflicted permanent magnet GPM as magnetic field generating means Le generates the different additional magnetic flux densities (B_{ad}_1, B_{ad}_2, B_{ad}_3, B_{ad}_4, B_{ad}_5).

FIG. 81 shows, as a consistent further development of the use of several more or less point-shaped sensor elements SE, the use of linear and/or planar sensor element layers 5 as a finely granular extended sensor element SE.

FIG. 82 shows the diagram of FIG. 51b, wherein four exemplary microwave frequencies (ω_{μW_I}, ω_{μW_II}, ω_{μW_III}, ω_{μW_IV}) are now drawn as examples, with which, for example, a device corresponding to FIG. 81 determines the measured values of the intensity of the I_{fl}(B_{ad}) fluorescence radiation FL along the four drawn vertical lines for various additional absolute values of the magnetic flux density B_{ad}.

FIG. 83 shows an example of the internal structure of a vector microwave source μWG with the microwave sources (μWG_I, μWG_II, μWG_III, μWG_IV) of FIG. 81 in the case of the addition of an external signal S ωₙₖ with unknown microwave frequency ωₙₖ using the microwave sources (μWG_I, μWG_II, μWG_III, μWG_IV) of FIG. 81 as an example.

FIG. 84 illustrates the function formation of the curve of the lower resonance edge 522 by low-pass filtering in the microwave filters (μW_F_I, μW_F_II, μW_F_III, μW_F_IV) (see FIGS. 81, 82 and 83).

FIG. 85 illustrates the idea of the fabrication of a colloidal varnish KL for coating and/or printing the carrier substrate 1360.

FIG. 86 is a method for applying a colloidal varnish KL comprising a substrate material TM and crystals and/or diamond nano crystals ND to the carrier substrate 1360.

FIG. 87 illustrates exemplary steps of a wafer-based coating process are shown schematically and in simplified form in FIG. 87.

FIG. 88 shows a second method of patterning. This second method of patterning may be performed by pre-baking the colloidal film of colloidal varnish KL on the surface of the support substrate 1360.

FIG. 89 shows a schematic and roughly simplified sectional view of an exemplary system to illustrate the content of the preceding proposal when applied to a CMOS microelectronic circuit.

FIG. 90 shows a spectrum of a MESA structure MESA of FIG. 89 from the prior art for an operating voltage of 15V.

FIG. 91 shows an exemplary carrier substrate 1360 with an angularly applied waveguide 6980.

FIG. 92 illustrates in a schematically simplified manner the aforementioned method for the fabrication of a self-aligned sensor element SE optical waveguide LWL (4630), as previously described and used.

FIG. 93 illustrates in a schematically simplified manner the aforementioned method for the fabrication of a mask-adjusted sensor element SE on the optical waveguide LWL (4630), as previously described and used. The proposed method comprises the steps:

FIG. 94 shows an exemplary optically transparent carrier substrate 1360 with an exemplary waveguide in the form of a trip-plate waveguide 2380.

FIG. 95 shows an example of the fabrication of a device according to FIG. 94.

FIG. 96 schematically shows the implementation of the curing of the substrate material TM of the colloidal mixture KL according to the method according to FIG. 96 in step 20350.

FIG. 97a schematically shows an exemplary carrier substrate 1360 with an exemplary tri-plate waveguide 2389 as an example of a waveguide (1380, 1880, 2380, 6880, 6990).

FIG. 97b schematically shows an exemplary carrier substrate 1360 with an exemplary tri-plate waveguide 2389 as an example of a waveguide (1380, 1880, 2380, 6880, 6990).

FIG. 98 corresponds as far as possible to FIG. 78, with the additional reference sign of the first microwave and/or RF connector 15710 for the connection of the waveguide (1380, 1880, 2380, 6880, 6990) to the microwave signal source μWG and the RF signal source RFG and to a reflection microwave signal analyzer (μWAR) and to a reflection RF signal analyzer (RWAR) being drawn with the reference sign 15710.

### DESCRIPTION

The figures explain the proposal schematically and in simplified form. The disclosure of the present document is not limited to the figures and also comprises other combinations.

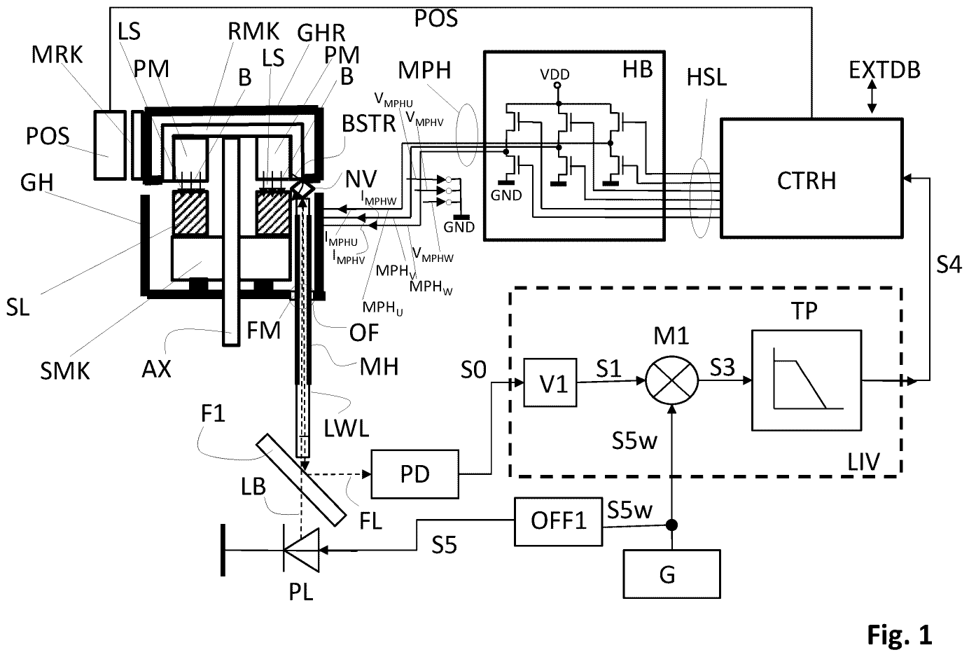

### FIG. 1

FIG. 1 shows an exemplary and schematically simplified system according to the proposal. The motor comprises the stator housing GH. The magnetic stator circuit is attached to the stator housing GH. The magnetic stator circuit may comprise a ferrite body, for example. The motor further comprises the stator coil windings SL. The motor further comprises the axis AX, which the stator preferably rotatably supports. Preferably, the axle AX is rotatably mounted in the stator about the longitudinal axis of the axle. Preferably, the axle AX is secured against displacement along the longitudinal axis of the axle AX. A rotor housing GHR is preferably attached to the axle AX. A magnetic rotor circuit RMK is preferably attached to the rotor housing and/or the axle AX. Preferably, the magnetic rotor circuit RMK comprises a ferromagnetic laminated core or the like. Several permanent magnets PM are typically attached to the magnetic rotor circuit RMK and/or to the rotor housing GHR. There is typically an air gap LS between the stator coils SL and the permanent magnets PM.

A half-bridge control unit CTRH controls several half-bridges HB by means of half-bridge control lines HSL. The half-bridges supply current to the motor phases, which are connected to the stator coils SL. In the example in FIG. 1, the exemplary motor is three-phase. The exemplary motor then preferably comprises N*3 stator coils. Here, N is a positive integer greater than 0. The half-bridges commutate the control of the stator coils as a function of the half-bridge control lines HSL by means of the motor phases MPH.

The generator G generates the transmission pre-signal S5w. Preferably, the transmission pre-signal S5w is pulse-modulated with a pulse frequency. A square-wave signal with a duty cycle of preferably 50% is particularly preferred. Other duty cycles are conceivable. The offset addition OFF1 preferably adds an offset to the value of the transmission pre-signal in order to be able to use the pump radiation source PL. Preferably, the resulting transmission signal S5 comprises no negative signal components. The pump radiation source PL generates a modulated pump radiation LB as a function of the transmission signal S5. In the example shown in FIG. 1, the pump radiation source transmits the pump radiation LB through a dichroitic mirror F1 and radiates pump radiation LB into the optical waveguide LWL). The motor housing GH comprises at least one opening OF through which the optical waveguide LWL the housing GH. The sensor element SE is preferably located at the end of the optical waveguide LWL). The sensor element SE preferably comprises a multiplicity of nano-diamonds or diamonds DM and/or a multiplicity of crystals, which preferably comprise a statistically uniformly distributed different crystal orientation and which are embedded in a matrix material. Typically, the matrix material consisting of a substrate material TM mechanically connects these nano-diamonds ND to the first end ELWL1 of the optical waveguide LWL. Preferably, the actual optical waveguide LWL has an optical waveguide diameter D_{LWL} of approximately 100 μm. Smaller optical fiber diameters D_{LWL} are preferred. However, larger fiber optic cable diameters D_{LWL} are possible. In addition, the optical waveguide (LWL) is typically protected against kinking. The bend protection is preferably designed as a mechanical sheath MH. The pump radiation LB from the pump radiation source PL the nano-diamonds or diamonds DM and/or crystals in the sensor element SE at the first end of the optical waveguide ELWL1). The nano-diamonds or diamonds DM and/or crystals in the sensor element SE preferably comprise NV centers and/or paramagnetic centers. Preferably, the sensor element SE comprises diamonds with NV centers. Typically, the pump radiation LB the nano-diamonds or diamonds DM and/or crystals to emit a fluorescence radiation FL with a fluorescence wavelength λ n. Preferably, the sensor element SE is located at the first end ELWL1 of the optical waveguide LWL. Preferably, the sensor element has a diameter that is smaller than the diameter D_{LWL} of the optical waveguide LWL. Typically, the NV centers NVZ of the sensor element SE radiate the fluorescence radiation FL back the optical waveguide LWL via the first end ELWL1 of the optical waveguide LWL. The fluorescence radiation FL exits the optical waveguide LWL again at the other, second end ELWL2) of the optical waveguide LWL and preferably exposes the photo detector PD, for example deflected by the dichroitic mirror F1. In the example in FIG. 1, the dichroitic mirror F1 does not direct the scattered pump radiation LB in the direction of the photo detector PD. As a result, the photo detector PD essentially only receives fluorescence radiation FL. Essentially means here that the pump radiation LB and the other radiation that nevertheless hits the photo detector PD are essentially insignificant for the technical purpose of the device. To achieve this, the document presented here proposes the use of a light-tight housing for the light-sensitive device parts and the use of shutters to prevent the entry of unwanted radiation and unwanted effects due to scattered radiation. The photo detector PD preferably converts the intensity of the fluorescence radiation FL into a temporal value curve of a received signal S0. An exemplary amplifier V1 amplifies and, if necessary, filters the receiver output signal S0 in the example of FIG. 1 to the amplified receiver output signal S1. In the example of FIG. 1, an exemplary multiplier M1 multiplies the amplified receiver output signal S1 with the transmitter pre-signal S5w to form the filter input signal S3. A low pass filter TP typically removes the frequency components with the added frequencies of the transmitter pre-signal S5w and the amplified receiver output signal S1 from the spectrum. The low pass filter TP thus filters the receiver input signal to the filter output signal S4. The half-bridge control CTRH controls the commutation of the motor by means of the half-bridge HB depending on the filter output signal S4. The combination of the first multiplier M1 and the low pass filter TP forms a scalar product between the signal vector of the amplified receiver output signal S1 and the transmission pre-signal S5w. This is a simple example of a synchronous demodulator. The synchronous demodulator generates a signal S4 that symbolizes the correlation between the amplified receiver output signal S1 and the transmitter pre-signal S5w. This signal S4 is the filter output signal S4. The use of other correlators instead of a synchronous demodulator, for example the use of optimal filters, Kalmann filters and/or matched filters and/or other estimation devices to determine the proportion of the transmission signal S5 in the receiver output signal S0 is conceivable. The special feature of the measurement method of FIG. 1 is that the optical waveguide LWL) together with the sensor element SE and the other device parts typically does not comprise any ferromagnetic and/or electrically conductive materials and thus does not essentially influence the magnetic field of the motor.

For example, the half-bridge control CTRH can detect a zero crossing of the magnetic flux density in the air gap LS or the magnetic flux density of the stray field of the air gap.

The intensity of the fluorescence radiation FL of the diamonds DM or nano-diamonds and/or the crystals of the sensor element SE on the magnetic flux density B at the location of the NV centers NVZ of the sensor element SE. Since the value of the filter output signal S4 indicates how much of the transmitter pre-signal S5w is contained in the amplified receiver output signal S1, this filter output signal S4 is a measure of the intensity of the fluorescence radiation FL. Thus, the filter output signal S4 is a measure of the magnetic flux density B at the location of the NV centers NVZ in the sensor element SE.

The half-bridge control CTRH evaluates the zero crossing of the alternating signal component of the filter output signal S4 and preferably controls the commutation of the motor by means of the half-bridges HB as a function of this.

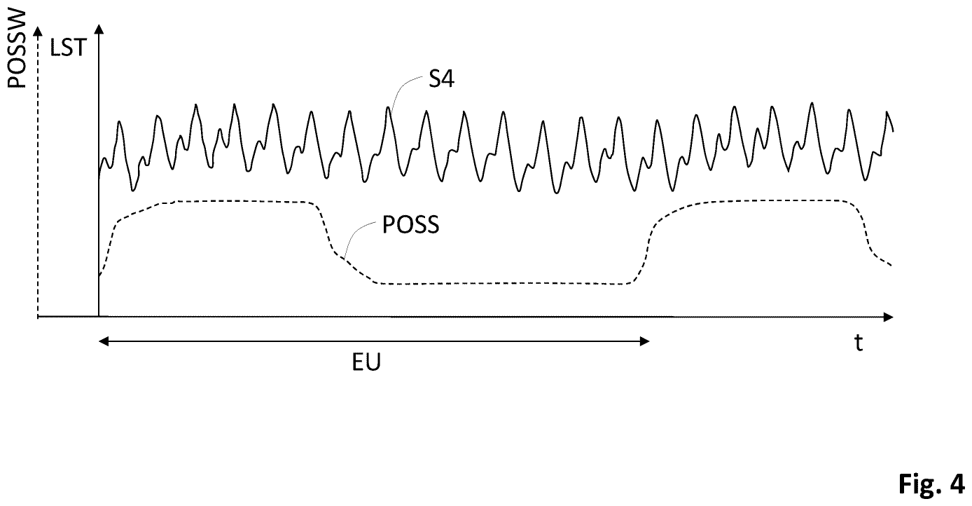

In the example shown in FIG. 1, the sensor element SE is placed in the stray field BSTR of the air gap LS of the motor. A position sensor POS provides a position signal by means of a marking MRK on the rotor of the motor. In the following example of FIG. 4, it is clear that the signal is a binary signal with an exemplary 1-bit resolution. The magnetic stator circuit SMK is attached to the housing GH. A mechanical sheath MH made of ceramic protects the common optical waveguide LWL). A filling compound FM seals the opening OF in the motor.

An external data bus EXTDB enables the half-bridge control CTRH to communicate with a higher-level control system. The external data bus can be a wired or wireless data connection. Several parallel data connections, which can be realized in different ways, are conceivable.

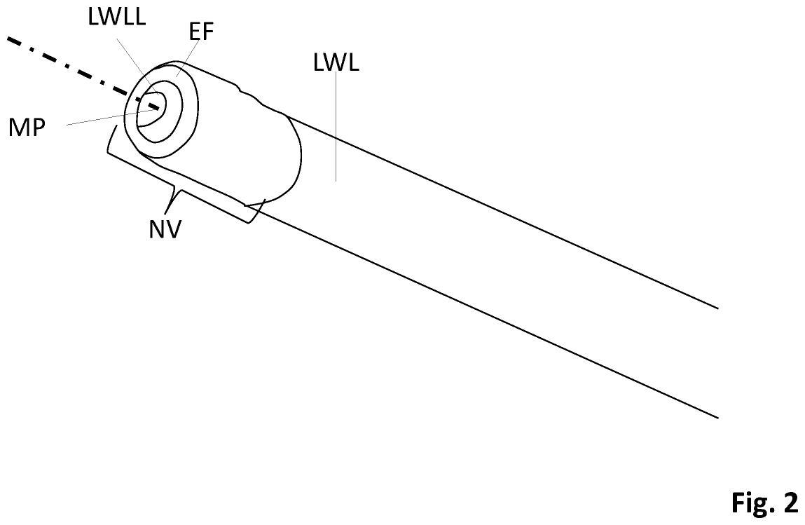

### FIG. 2

FIG. 2 shows an optical waveguide LWL with a sensor element SE directly on the center MP of the core of the optical waveguide LWL. On a part of the end face EF of the optical waveguide LWL, the sensor element SE is designed as an optical waveguide lens LWLL.

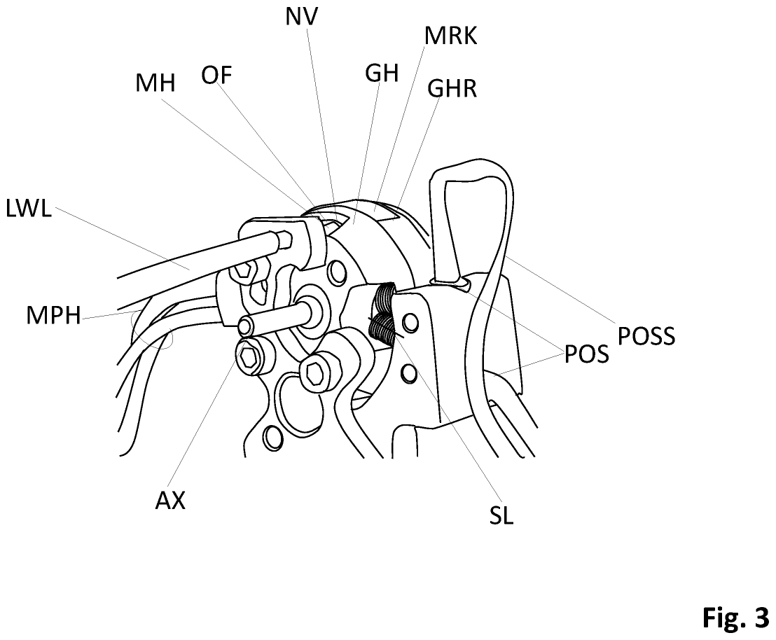

### FIG. 3

FIG. 3 shows a motor as schematically sketched in simplified form in FIG. 1. In addition to the optical waveguide LWL) with the sensor element SE, which extends into the motor via the aforementioned opening OF and which is encased in the mechanical sheath MH, the suspension of the motor comprises a position sensor POS with an LED and a photodiode, which generates the position signal POSS with the aid of a marking MRK on the rotor housing GHR. The cables of the motor phases drive and control the motor. The rotor is rotatably mounted in the stator by means of the AX axis. The motor phases MPH supply current to the stator coils SL. The housing fixes the components of the stator, such as the stator coils SL, the axle and AX (without impairing the rotatability of the axle) and the optical waveguide LWL with the mechanical sheath MH.

### FIG. 4

FIG. 4 shows the filter output signal S4 generated by the lock-in amplifier LIV and the position signal POSS of the position detector POS of FIG. 3. The motor rotates with the motor rotation period EU. It is a three-phase motor with four coils per motor phase.

The special feature is that the measurement of the magnetic field B in the scattering range BSTR of the motor air gap LS is purely optical. The frequencies of the measurement signals for measuring the position of this magnetic field B in the air gap LS of the motor are all, and only in the example in FIGS. 3 and 4, in the optical region, i.e. between 3*10¹⁴ Hz and 10¹⁴ Hz. As a result, crosstalk between electrical device parts of the motor and the measuring device is very low if the control and evaluation elements of the device are far enough away from the motor. Preferably, the energy intensity of the electromagnetic radiation which the optical waveguide transports into the motor and which the measuring device uses in the motor is −40 dB, better −60 dB, better −90 dB, better −120 dB, better −200 dB lower in the frequency range from 1 Hz to 1010 Hz compared to the energy intensity in the frequency range between 3*10¹⁴ Hz and 10¹⁴ Hz. The device therefore works without microwaves.

This is an essential advantage compared to measurements with Hall probes or the like or measurements with NV centers using microwaves.

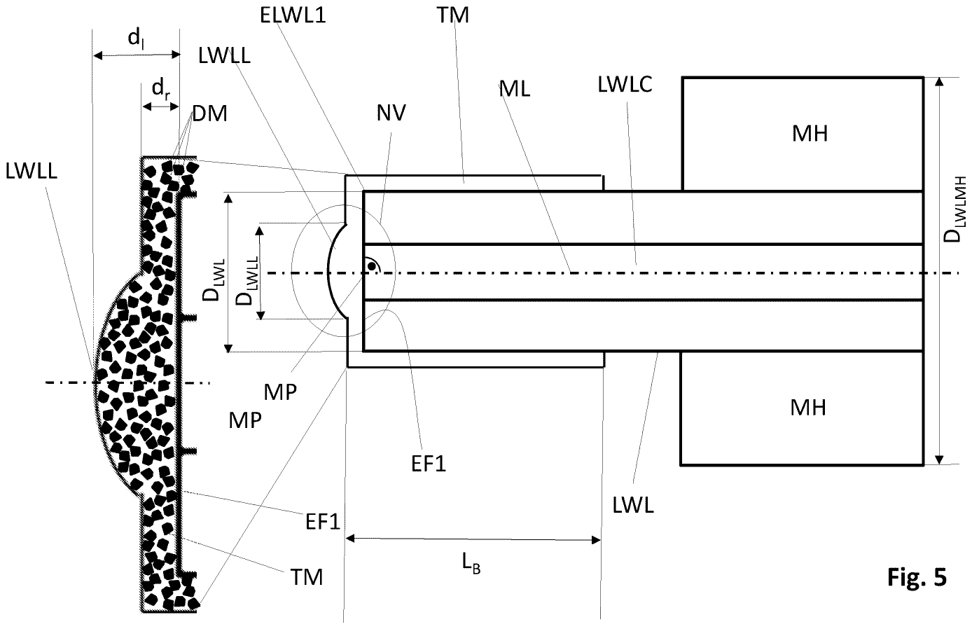

### FIG. 5

FIG. 5 shows a cross-section through the exemplary first end ELWL1 of an optical waveguide LWL) according to the proposal. The optical waveguide LWL) comprises an optical waveguide core LWLC). The optical waveguide LWL) can be a single-mode optical waveguide or a multimode optical waveguide. The optical waveguide LWL can be a gradient optical waveguide or a step-index waveguide or the like, in which the optical waveguide core LWLC merges smoothly into the outer area of the optical waveguide LWL with regard to the refractive index. The mechanical sheath MH protects the optical waveguide LWL and preferably leaves the first end ELWL1 of the optical waveguide LWL exposed. The substrate material TM of the sensor element SE surrounds the first end ELWL1 of the optical waveguide LWL. The substrate material TM of the optical waveguide LWL) is preferably transparent for the pump radiation wavelength λₚₘₚ and the fluorescence wavelength λ_{fl}. The transparency here refers to the dimensions of the optical waveguide LWL, which may well comprise a diameter D_{LWL} of less than 100 μm. The end face EF of the optical waveguide LWL is preferably perpendicular to the optical axis of the optical waveguide LWL, which is drawn here as the center line ML by way of example. At the point where the optical axis, i.e. the center line ML, passes through the end face EF, an optical waveguide lens LWLL is produced in the substrate material TM as a thickening of the substrate material TM. The thickness dₗ of the substrate material TM is typically thickest there. In the other regions of the sensor element SE, the optical waveguide LWL may only be thinly coated with a smaller thickness dᵣ with the substrate material TM. The thickness dᵣ can also be 0m. The diameter D_{LWLL} of the optical waveguide lens LWLL is typically smaller than the diameter D_{LWL} of the optical waveguide LWL. To illustrate this, the first end EL WL1 of the optical waveguide LWL with the end face EF and the optical waveguide lens LWLL is enlarged again on the left. The small stochastically uniformly distributed diamonds or nano-diamonds DM and/or crystals in the substrate material TM are indicated for clarification. Preferably, the diamonds DM are nano-diamonds with a size smaller than 500 μm, better smaller than 200 μm, better smaller than 100 μm, better smaller than 50 μm, better smaller than 20 μm, better smaller than 10 μm, better smaller than 5 μm, better smaller than 2 μm, better smaller than 1 μm, better smaller than 0.5 μm, better smaller than 0.2 μm, better smaller than 0.1 μm, better smaller than 50 nm, better smaller than 20 nm, better smaller than 10 nm. Preferably, the crystals comprise a size smaller than 500 μm, better smaller than 200 μm, better smaller than 100 μm, better smaller than 50 μm, better smaller than 20 μm, better smaller than 10 μm, better smaller than 5 μm, better smaller than 2 μm, better smaller than 1 μm, better smaller than 0.5 μm, better smaller than 0.2 μm, better smaller than 0.1 μm, better smaller than 50 nm, better smaller than 20 nm, better smaller than 10 nm. Sizes above 100 nm are particularly preferred, since sizes smaller than 100 nm can cause special surface effects between NV center NVZ or paramagnetic centers and diamond surface of the diamond DM in question. Particularly preferred are crystal sizes above 100 nm, as sizes smaller than 100 nm can cause special surface effects between paramagnetic centers and the crystal surface of the respective crystal. Preferably, a multiplicity of these diamonds or nano-diamonds DM and/or crystals comprise one or more NV centers NVZ and/or one or more paramagnetic centers, which then generate the fluorescence radiation FL upon exposure to suitable pump radiation LB.

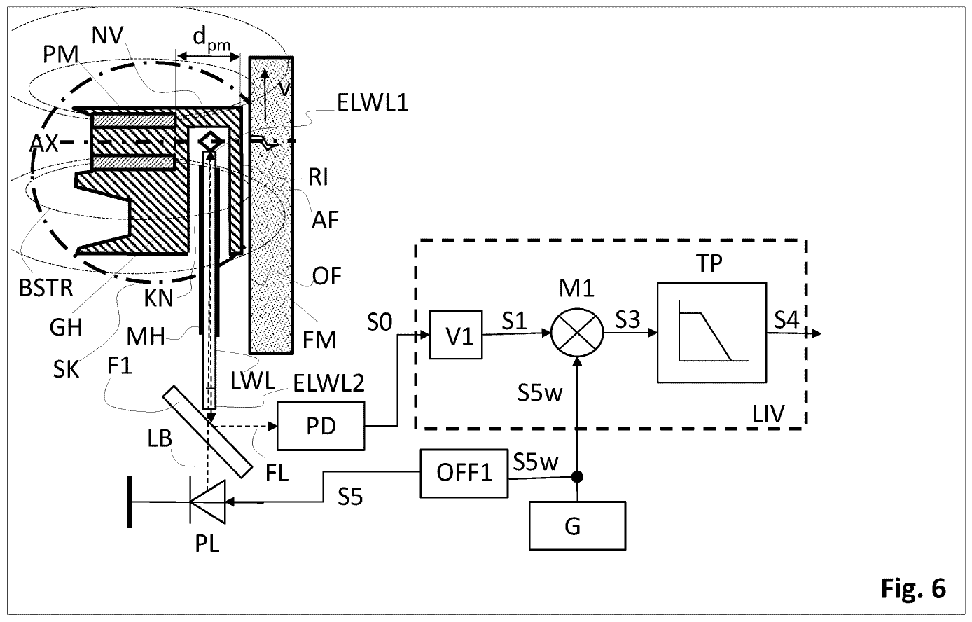

### FIG. 6

FIG. 6 shows an exemplary and schematically simplified material measuring system with a sensor head SK according to the proposal. The sensor head SK comprises the sensor head housing GH. The sensor head housing GH preferably comprises a permanent magnet PM. Preferably, the permanent magnet PM is tubular. Preferably, the permanent magnet PM comprises a permanent magnet symmetry axis AX. Preferably, the permanent magnet PM is magnetized parallel to the permanent magnet symmetry axis AX. The preferably tubular permanent magnet PM typically comprises a first end and a second end. The second end of the permanent magnet PM comprises a permanent magnet distance dₚₘ from the contact surface AF of the sensor head SK. Since the diameter of the optical waveguide (LWL) is less than 1 mm, the permanent magnet distance dₚₘ is less than 1 mm, preferably less than 0.5 mm, preferably less than 200 μm, preferably less than 100 μm, preferably less than 20 μm. The permanent magnet spacing dₚₘ is preferably slightly larger in the region of the sensor element SE than the diameter of the optical waveguide LWL. The permanent magnet spacing dₚₘ is preferably less than 200% greater than the diameter of the optical waveguide LWL in the region of the sensor element SE, preferably less than 100% greater than the diameter of the optical waveguide LWL, preferably less than 50% greater than the diameter of the optical waveguide LWL, preferably less than 25% greater than the diameter of the optical waveguide LWL, preferably less than 10% greater than the diameter of the optical waveguide LWL, preferably less than 5% greater than the diameter of the optical waveguide LWL. Preferably, the material of the housing GH of the sensor head SK is non-magnetic and/or non-magnetizable. For the purposes of the document presented here, a material is considered to be non-magnetic if μ_{(T})<1 applies to the magnetic permeability _{T} of this material. The document presented here recommends the use of materials with the lowest possible magnetic permeability μ_{T} as the material of the sensor head housing GH. Preferably, the sensor element SE is located on the extended axis of symmetry, the permanent magnet axis of symmetry AX of the permanent magnet PM.

For the measurement, the operator or a mechanical actuator brings the contact surface AF of the sensor head SK into contact with the surface OF of the workpiece to be measured. Preferably, the surface OF of the workpiece to be measured comprises a ferromagnetic material FMM (17).

If the workpiece to be measured now has a disturbance on its surface OF that influences the magnetic flux density B, the magnetic flux density B that flows through the sensor element SE changes when this disturbance comes into the vicinity of the permanent magnet's axis of symmetry AX and thus into the vicinity of the sensor element SE. Such a disturbance may be, for example, a crack Ri or a hole or a recess or other defect in the material of the workpiece in the vicinity of the surface OF of the workpiece.

The generator G generates the transmission pre-signal S5w. Preferably, the transmission pre-signal S5w is pulse-modulated with a pulse frequency. A rectangular signal with a duty cycle of preferably 50% is particularly preferred. Other duty cycles are conceivable. The offset addition OFF1 preferably adds an offset to the value of the transmission pre-signal in order to be able to use the pump radiation source PL. Preferably, the resulting transmission signal S5 comprises no negative signal components. The pump radiation source PL generates a modulated pump radiation LB as a function of the transmission signal S5. In the example shown in FIG. 1, the pump radiation source transmits the pump radiation LB through a dichroitic mirror F1 and radiates pump radiation LB into the optical waveguide LWL). The sensor head housing GH comprises at least one channel KN through which the optical waveguide LWL) is inserted into the sensor head housing GH. The sensor element SE is preferably located at the end of the optical waveguide LWL). The sensor element SE preferably comprises a multiplicity of nano-diamonds or diamonds DM, which preferably comprise a statistically uniformly distributed different crystal orientation and which are embedded in a matrix material. Typically, the matrix material consisting of a substrate material TM mechanically connects these nano-diamonds ND to the first end ELWL1 of the optical waveguide LWL. Preferably, the actual optical waveguide LWL has an optical waveguide diameter D_{LWL} of approximately 100 μm. Smaller optical fiber diameters D_{LWL} are preferred. However, larger fiber optic cable diameters D_{LWL} are possible. In addition, the optical waveguide (LWL) is typically protected against kinking. The bend protection is preferably designed as a mechanical sheath MH. The pump radiation LB from the pump radiation source PL strikes the nano-diamonds or diamonds DM in the sensor element SE at the first end of the optical waveguide ELWL1). Preferably, the sensor element SE comprises diamonds with NV centers. Typically, the pump radiation LB excites the nano-diamonds or diamonds DM to emit a fluorescence radiation FL with a fluorescence wavelength λ n. Preferably, the sensor element SE is located at the first end ELWL1 of the optical waveguide LWL. Preferably, the sensor element has a diameter that is smaller than the diameter D_{LWL} of the optical waveguide LWL. Typically, the NV centers NVZ of the sensor element SE radiate the fluorescence radiation FL back into the optical waveguide LWL via the first end ELWL1 of the optical waveguide LWL. The fluorescence radiation FL exits the optical waveguide LWL again at the other, second end ELWL2) of the optical waveguide LWL and preferably exposes the photo detector PD, for example deflected by the dichroitic mirror F1. In the example in FIG. 1, the dichroitic mirror F1 does not direct the scattered pump radiation LB in the direction of the photo detector PD. As a result, the photo detector PD essentially only receives fluorescence radiation FL. Essentially, here means that the pump radiation LB and the other radiation that nevertheless hits the photo detector PD are essentially insignificant for the technical purpose of the device. To achieve this, the document presented here proposes the use of a light-tight housing for the light-sensitive device parts and the use of shutters to prevent the entry of unwanted radiation and unwanted effects due to scattered radiation. The photo detector PD preferably converts the intensity of the fluorescence radiation FL into a temporal value curve of a received signal S0. An exemplary amplifier V1 amplifies and, if necessary, filters the receiver output signal S0 in the example of FIG. 1 to the amplified receiver output signal S1. In the example of FIG. 1, an exemplary multiplier M1 multiplies the amplified receiver output signal S1 with the transmitter pre-signal S5w to form the filter input signal S3. A low pass filter TP typically removes the frequency components with the added frequencies of the transmitter pre-signal S5w and the amplified receiver output signal S1 from the spectrum. The low pass filter TP thus filters the receiver input signal to the filter output signal S4. The combination of the first multiplier M1 and the low pass filter TP forms a scalar product between the signal vector of the amplified receiver output signal S1 and the transmitter input signal S5w. This is a simple example of a synchronous demodulator. The synchronous demodulator generates a signal S4 that symbolizes the correlation between the amplified receiver output signal S1 and the transmitter pre-signal S5w. This signal S4 is the filter output signal S4. The use of other correlators instead of a synchronous demodulator, for example the use of optimum filters, Kalmann filters and/or matched filters, is conceivable. The special feature of the measurement method of FIG. 1 is that the optical waveguide LWL) together with the sensor element SE and the other device parts of the sensor head SK typically does not comprise any ferromagnetic and/or electrically conductive materials and thus does not essentially influence the magnetic field of the workpiece or the ferromagnetic material FM and the permanent magnet PM.

The intensity of the fluorescence radiation FL of the diamonds DM or nano-diamonds of the sensor element SE depends on the magnetic flux density B at the location of the NV centers NVZ of the sensor element SE. Since the value of the filter output signal S4 indicates how much of the transmitter pre-signal S5w is contained in the amplified receiver output signal S1, this filter output signal S4 is a measure of the intensity of the fluorescence radiation FL. Thus, the flux density measurement signal S4 is a measure of the magnetic flux density B at the location of the NV centers NVZ in the sensor element SE.

In the example in FIG. 1, the sensor element SE is placed in the stray field BSTR of the permanent magnet PM. The ferromagnetic material FM of the workpiece influences this stray field BSTR. If an operator or an actuator now pushes the workpiece and thus the ferromagnetic material FM on the surface OF of the workpiece along the support surface AF, an influence on the magnetic stray field BSTR only changes if this translational movement with the speed v influences the region of the ferromagnetic material influencing the magnetic stray field BSTR in its distribution of physical parameters. Such an influence can cause an uneven distribution of physical parameters in the ferromagnetic material FM, which influences the magnetic stray field BSTR. Preferably, the feed speed v of the sensor head SK is constant with respect to the workpiece with the ferromagnetic material FM. Preferably, an operator manually performs the feed of the sensor head SK with respect to the workpiece at the feed speed v. The document presented here proposes to provide an actuator for production tests, which places the sensor head SK with the contact surface AF on the surface OF of the workpiece or close to the surface OF of the workpiece and then moves it parallel to the surface OF of the workpiece along a line to be examined. Preferably, a computer system detects the position of the sensor head SK and thus of the sensor element SE relative to the workpiece and thus to the ferromagnetic material FM by means of a coordinate sensor system. Preferably, the computer system detects the value of the filter output signal S4 together with the coordinates of the position of the sensor head SK and thus the position of the sensor element SE. Preferably, the computer system stores these pairs of coordinates of the measuring point and measured value of the filter output signal S4 in a memory of the computer system. The computer system can further process this data, for example into a two- or three-dimensional model of the distribution of magnetizability. For example, the computer system can determine a two-dimensional distribution of the values of the filter output signal S4 on the surface OF of the workpiece and thus of the ferromagnetic material FM and display it on a screen or keep it available, for example, as a JPEG image or functionally equivalent form. The feed speed v can be 0 m/s for a point measurement. A mechanical sheath MH comprising ceramic or a fabric or a robust plastic protects the common optical waveguide LWL. The optical waveguide LWL) can be fixed in the channel KN of the sensor head housing GH by means of a screw SCHR. An external data bus EXTDB enables the half-bridge control CTRH to communicate with a higher-level control system. The external data bus can be a wired or wireless data connection. Several parallel data connections, which can be realized in different ways, are conceivable.

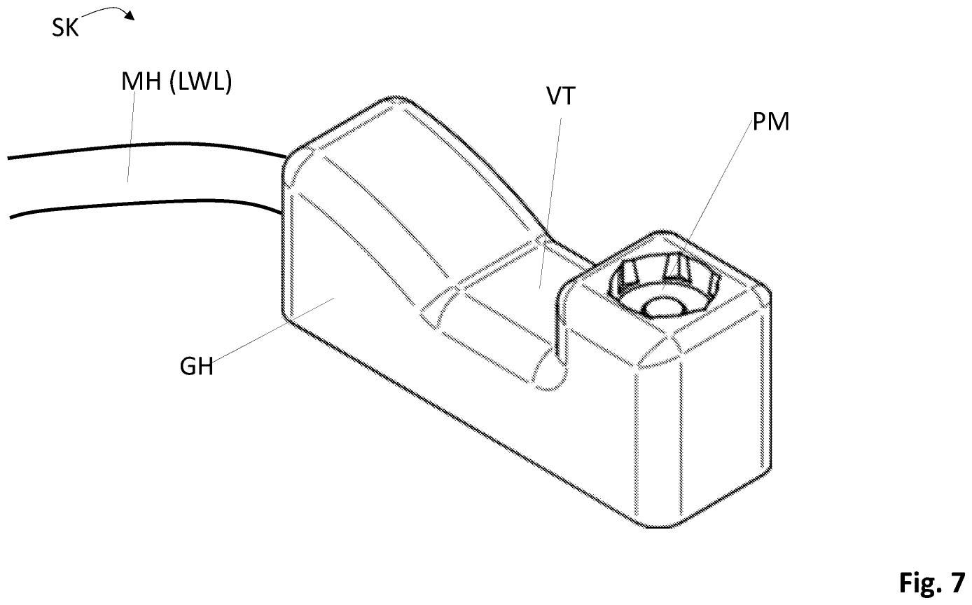

### FIG. 7

FIG. 7 shows a sensor head SK with the mechanical sheath of the optical waveguide LWL) covered by the mechanical sheath MH. The drawing shows the permanent magnet PM. The contact surface AF is at the bottom and concealed.

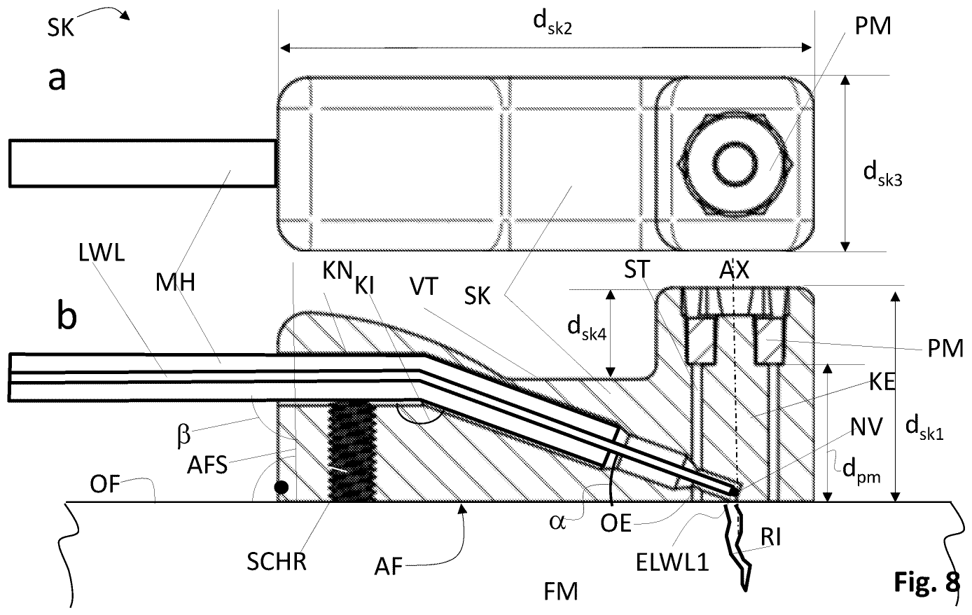

### FIG. 8

FIG. 8 shows the sensor head of FIG. 7 in top view (FIG. 8a) and in side view (FIG. 8b) as a sectional view.

The mechanical sheath MH of the optical waveguide LWL is fixed to the optical waveguide LWL in the channel KN of the sensor head housing GH of the sensor head SK by means of a screw SCHR. It is conceivable to fix the mechanical sheath MH of the optical waveguide LWL to the optical waveguide LWL in the channel KN of the sensor head housing GH of the sensor head SK by means of an adhesive bond. The permanent magnet PM is exemplarily designed as a cylinder. The lower end of the permanent magnet PM is at a distance dₚₘ from the contact surface AF. In the example shown in FIG. 5, the contact surface AF rests on the surface OF of the exemplary ferromagnetic material FM of the workpiece. In the ferromagnetic material FM, for example, there should be a crack RI. This crack RI influences the stray field BSTR of the permanent magnet PM. The sensor element SE is located at the first end ELWL1 of the optical waveguide LWL. Preferably, the sensor element SE is located in the vicinity of the extension of the axis AX of the cylindrical permanent magnet PM. The crack RI influences the stray field BSTR of the permanent magnet PM in the region of the sensor element SE. Therefore, the crack RI influences the intensity of the fluorescence radiation FL of the NV centers NVZ or paramagnetic centers in the sensor element SE.

The exemplary sensor head SK has the height d_{SK1}. The exemplary sensor head SK has the length d_{SK2}. The exemplary sensor head SK has the width d_{SK3}.

On the upper side opposite the contact surface AF, the sensor head SK comprises a recess VT with a depth d_{SK4} relative to the upper side of the sensor head SK. If the sensor head SK is intended for manual positioning on the surface OF of the workpiece, the recess VT preferably has a depth d_{SK4} of between 3 mm and 1.5 cm, with 5 mm to 8 mm being preferred. This improves manageability.

In the example shown in FIG. 5, the channel KN comprises a kink KI around an angle. This has, firstly, the positive effect of a certain mechanical clamping of the optical waveguide LWL in the channel KN and, secondly, the effect that the optical waveguide LWL can emerge from the sensor head SK parallel to the contact surface AF. This has the advantage that, due to its flexibility, the optical waveguide LWL comes to rest at a shorter distance from the sensor head SK, for example on a worktop, than without this kink KI. This reduces the torque that the optical waveguide LWL) exerts on the sensor head SK. Thirdly, the sensor element SE can thus be positioned closer to the contact surface AF of the sensor head SK. Preferably, the optical waveguide LWL therefore forms an angle α with the contact surface AF in the vicinity of the sensor element SE, which is different from 90° and 0°. Typically, the angle α is between 15° and 65°, or preferably 25° and 55°. Angles α of 30° and 45° are currently in use.

In FIG. 5, a ferromagnetic support ST is provided, which conducts the magnetic excitation H of the permanent magnet PM to the material of the workpiece, in this case the ferromagnetic material FM. In the example in FIG. 5, the ferromagnetic support ST is an exemplary ferromagnetic tube. In the example of FIG. 5, the ferromagnetic support ST has approximately the same diameter as the permanent magnet PM. In the example of FIG. 5, the ferromagnetic support ST comprises an opening OE in the region below. The optical waveguide LWL) passes through this opening OE into the interior of the ferromagnetic support ST. This opening OE is therefore part of the channel KN in the sensor head housing GH. The ferromagnetic support ST is filled with a filling material of a core KE of the support ST and the permanent magnet PM. The channel KN continues from the material of the remaining sensor head housing GH through the opening OE into this core KE. In the example in FIG. 5, the axis of rotational symmetry AX of the permanent magnet PM coincides with the axis of rotational symmetry of the ferromagnetic support ST. Preferably, the channel KN in the core KE is therefore designed in such a way that, after the optical waveguide LWL) has been inserted, the sensor element SE is located in the vicinity of the extension of this axis of symmetry AX.

Preferably, the sensor head SK thus comprises at least one means for generating a magnetic excitation, namely the permanent magnet PM, and a sensor element SE, which is connected via at least one optical waveguide LWL). The optical waveguide LWL is configured to be connected to a control and evaluation device (see FIG. 1) or is connected to it. The sensor head further comprises a sensor head housing GH made of a non-ferromagnetic material (μ₍ₜ)<1). Preferably, the sensor head SK comprises further functional elements of one or more magnetic circuits. Such a further functional elements of one or more magnetic circuits can be, for example, the ferromagnetic support ST. Preferably, the sensor head SK is designed so that the permanent magnet PM and the further functional elements of one or more magnetic circuits of the sensor head SK form at least one common magnetic circuit with a region of the surface OF of a workpiece via a contact surface AF when the sensor head SK is placed with the contact surface AF on the surface OF of the workpiece.

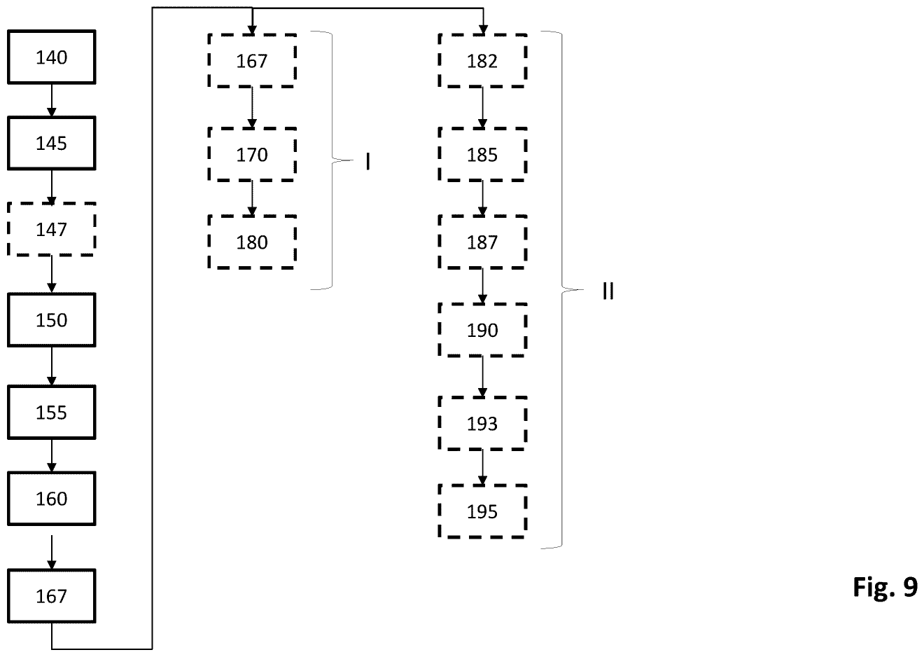

### FIG. 9

FIG. 9 shows the steps of the method for the fabrication of a proposed sensor head SK and its use. The method comprises the steps:
Deployment 140 of an optical waveguide LWL, wherein the optical waveguide LWL comprises a first end ELWL1 and a second end ELWL2;
Deployment 145 of a liquid substrate material TM which is curable by means of electromagnetic radiation of a curing wavelength λ_{H}, wherein a multiplicity of diamonds DM or nano-diamonds are embedded in the substrate material (TM) and wherein one or more or all diamonds DM or nano-diamonds DM have NV centers NVZ and/or other paramagnetic centers and wherein the NV centers NVZ of the substrate material TM and/or the other paramagnetic centers of the substrate material TM have NV centers NVZ and/or other paramagnetic centers of the substrate material TM. nanodiamonds of these diamonds DM comprise NV centers NVZ and/or other paramagnetic centers and wherein the NV centers NVZ of the substrate material TM and/or the other paramagnetic centers of the substrate material TM emit at least one fluorescence radiation FL upon exposure to pump radiation LB;
if necessary, pre-baking 147 (pre-bake) of the sensor element SE by means of a preceding temperature treatment.
Wetting 150 of the first end of the optical waveguide TM to a wetting length LTM with the substrate material TM comprising the multiplicity of embedded diamonds DM or nano-diamonds and/or crystals with one or more NV centers and/or one or more paramagnetic centers;
Feeding 155 electromagnetic radiation into the second end ELWL2 of the optical waveguide LWL, the wavelength of this electromagnetic radiation, the curing wavelength λ_{(H)}, being selected such that the substrate material TM at the second end ELWL2 of the optical waveguide LWL hardens and transforms into a solid, the hardened substrate material TM forming the sensor element SE;
Removal 160 of the uncured substrate material TM, in particular by means of a solvent, the remaining film of the substrate material TM at the first end of the optical waveguide LWL) forming the sensor element;
If necessary, post-baking 165 (post-bake) of the sensor element SE by subsequent temperature treatment.
   In the first application example of a sensor head SK, the following optional steps of a first exemplary application process can follow as a subsequent (variant I):
deployment 167 of a sensor head housing GH of the sensor head SK and an excitation source for a magnetic excitation H, in particular a permanent magnet PM;
installation 170 of the optical waveguide LWL) with the newly formed sensor element SE in the channel KN of the sensor head housing GH of the sensor head SK and installation of an excitation source for a magnetic excitation H in the sensor head housing GH of the sensor head SK;
use 180 of the sensor head SK for spatially resolved measurement of the magnetic properties of the material of a workpiece in the vicinity of the surface OF of the workpiece, wherein the spatial resolution is better than 500 μm and/or better than 200 μm and/or better than 100 μm and/or better than 50 μm and/or better than 20 μm and/or better than 10 μm. Resolution is the possibility of being able to detect two adjacent disturbances of the magnetic properties of a surface OF a workpiece even by an extremum of 5% of the signal amplitude if they are spaced apart according to the resolution. Such disturbances can be, for example, cracks, blowholes, material inhomogeneities, etc.;
in the second application example of a motor, the following optional steps of a second exemplary application process can follow as a subsequent (variant II): Deployment 182 of a housing GH of the motor;
installation 185 of the optical waveguide LWL) with the newly formed sensor element SE in the opening OF of the housing GH of the motor;
use 187 of the optical waveguide LWL) with the newly formed sensor element SE for measuring the magnetic flux density B within the air gap LS of the motor or in the stray field BSTR of the magnetic field in the air gap LS;
if necessary, determining 190 the point in time of the zero crossing of the absolute value of the magnetic flux density B of the magnetic flux density B within the air gap LS of the motor or in the stray field BSTR of the magnetic field in the air gap LS and/or, if necessary, determining 190 the absolute value of the magnetic flux density B of the magnetic flux density B within the air gap LS of the motor or in the stray field BSTR of the magnetic field in the air gap LS;
if necessary, determine 193 or estimate the position of the magnetic field within the air gap of the motor;
if necessary, commutation 195 of the current supply to one or more stator coils of the motor and/or one or more rotor coils of the motor as a function of
   of the determined crossing times of the zero crossing of the absolute value of the magnetic flux density B of the magnetic flux density B within the air gap LS of the motor or in the stray field BSTR of the magnetic field in the air gap LS and/or
   from the determined absolute value of the magnetic flux density B of the magnetic flux density B within the air gap LS of the motor or in the stray field BSTR of the magnetic field in the air gap LS and/or from the determined or estimated position of the magnetic field within the air gap of the motor.

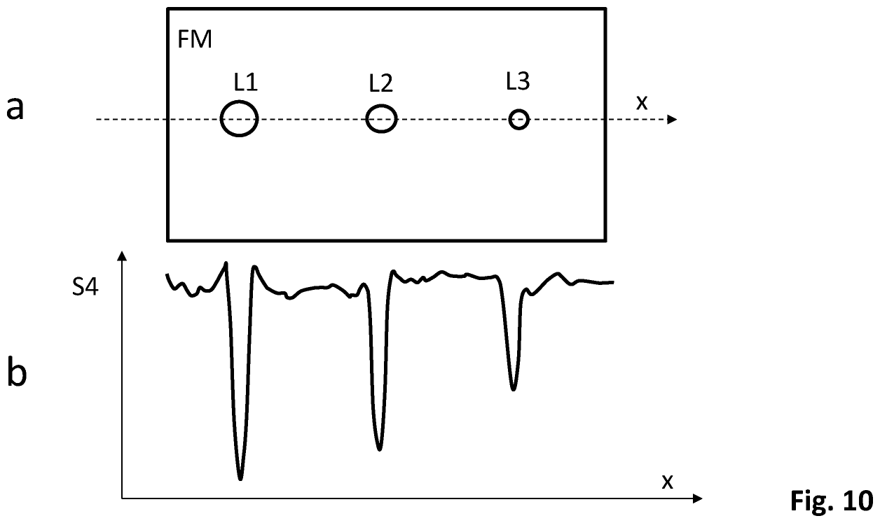

### FIG. 10

FIG. 10a shows a top view of an exemplary workpiece made of a ferromagnetic material FM. Various holes L1 to L3 have been drilled into the surface of the workpiece to simulate a crack RI. For example, the first hole L1 comprises an exemplary diameter of 4 mm. The second hole L2 should comprise an exemplary diameter of 3 mm, for example. The third hole L3 should comprise an exemplary diameter of 2 mm, for example.

To create FIG. 10b, a sensor head SK, as shown in FIGS. 7 and 8, was moved over the surface OF of the workpiece along the path labeled x, while maintaining contact between the contact surface AF and the surface OF of the workpiece.

The value curve of the measurement signal S4 obtained in this way is shown in FIG. 10b as a function of the position x of the sensor head SK on the surface OF. Due to the small size D_{LWL} of the sensor element SE, the spatial resolution is considerable, which is unknown in the prior art and thus enables the detection of manufacturing defects and workpiece irregularities with completely new speed and precision.

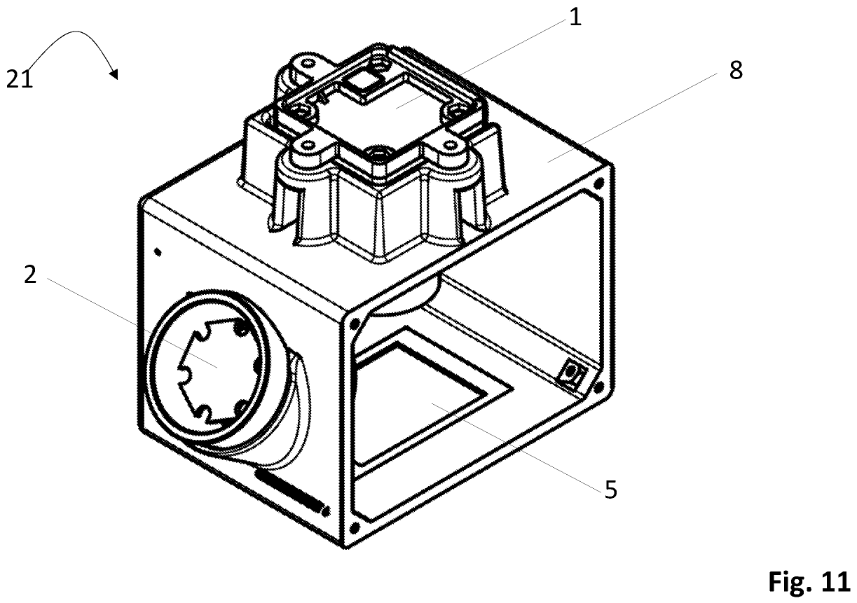

### FIG. 11

FIG. 11 shows a proposed application device in the form of a magnetic field camera in the form of the proposed magnetic field camera head 21 from a first view. A light source 2 (laser, LED) of the magnetic field camera head 21 according to the proposal exposes the sensor layer 5 of the magnetic field camera head 21 according to the proposal to pump radiation 13 of a pump radiation wavelength λₚₘₚ. The sensor layer 5 preferably comprises crystals with paramagnetic centers. Preferably, the crystals 66 of the sensor layer 5 comprise diamonds. Preferably, the crystals 66 of the sensor layer 5 comprise nano crystals 66. Preferably, the paramagnetic centers in the sensor layer 5 comprise NV centers in diamond crystals. Preferably, the substrate material of the sensor layer 5 comprises the crystals and/or nano crystals 66. This sensor layer 5 is preferably applied to a flat surface inside the housing 8 of the magnetic field camera head 21 according to the proposal. The sensor layer 5 thus comprises paramagnetic centers. Since the crystals 66 can be very small as nano crystals 66, the thickness 25 of the sensor layer 5 can be made very thin and the sensor layer 5 can be very densely filled with crystals 66 with paramagnetic centers. Upon exposure to pump radiation 13 of the pump radiation wavelength λₚₘₚ, the paramagnetic centers of the sensor layer 5 emit fluorescence radiation 14 of a fluorescence wavelength λ_{fl}. An exemplary size of the sensor layer 5 can be, for example, 32 mm×22 mm. Other dimensions are possible. In the case of rework, the persons carrying out the rework should select the dimensions of the sensor layer 5 according to the specific intended application. A light sensor array 1 with n×m light sensors and with evaluation electronics of the light sensor array 1 detects this fluorescence radiation 14. The successful testing of the device presented here with the magnetic field camera head 21 presented here comprised a light sensor array 1 with n×m light sensors with n=900 and m=600. Preferably, the evaluation electronics 15 of the light sensor array 1 comprises the control of the light sensor array 1 and that of the light sensors of the light sensor array 1, the power supply of the light sensors of the light sensor array 1, the processing circuit 30 for the output signals 31 of the light sensors of the light sensor array 1, and an interface circuit 36 for passing on the values of the output signals 31 of the light sensors of the light sensor array 1 to a higher-level computer system, for example a computer system 28 for operating the magnetic field camera head 21 with a screen 32 via a data bus 29 or the like. Preferably, the beam path of the pump radiation 13 and the fluorescence radiation 14 is located within a housing 8. The document presented here calls the surface of the sensor layer 5 that faces the light sensor array 1 the underside 23 of the sensor layer 5. The document presented here calls the opposite surface of the sensor layer 5 that does not face the light sensor array 1 the underside 22 of the sensor layer 5.

The upper side 23 of the sensor layer 5 is preferably located inside the housing 8.

The underside 22 of the sensor layer 5 is preferably located outside the housing 8. on its surface. Preferably, a light shield covers the underside 22 of the sensor layer 5. This prevents light from penetrating the housing 8 and reaching the light sensor array 1. The sensor layer 5 is preferably transparent to electromagnetic radiation, in particular pump radiation 13, of the pump radiation wavelength λₚₘₚ. The sensor layer 5 is preferably transparent to electromagnetic radiation, in particular fluorescence radiation 14, of the fluorescence radiation wavelength λ_{fl}. For example, the light shield can be a paint on the underside 22 of the sensor layer 5 or a particularly thin, light-impermeable part of the housing wall of the housing 8. Preferably, such a thin housing wall of the housing 8 in the region of the sensor layer 5 does not influence the magnetic field, for example the magnetic flux density B.

Preferably, the light sensor array comprises 1 n×m light sensors, which are preferably arranged in a surface. Here, n and m are positive integers.

For a better overview, the cover that covers the interior of the housing 8 is not shown in FIG. 11.

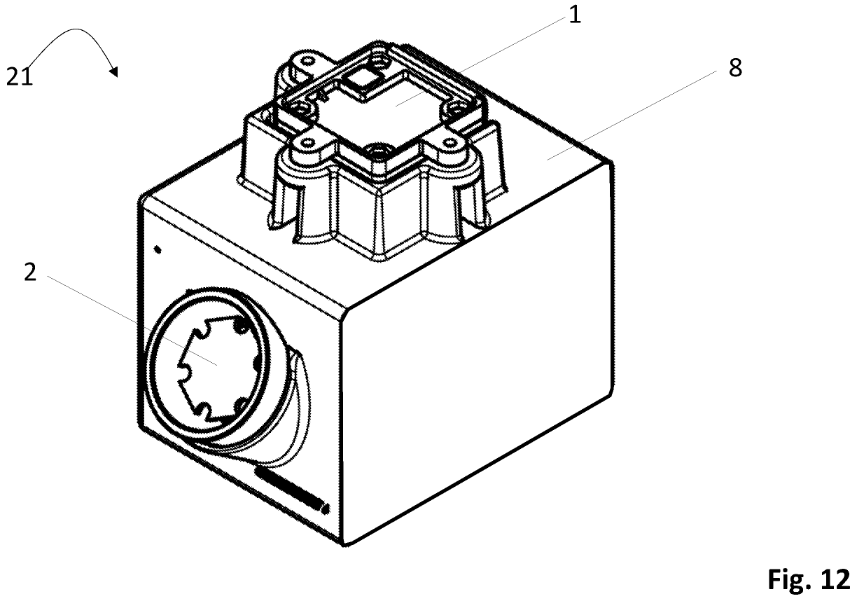

### FIG. 12

FIG. 12 shows the device with the cover fitted for light-tight closure of the housing 8.

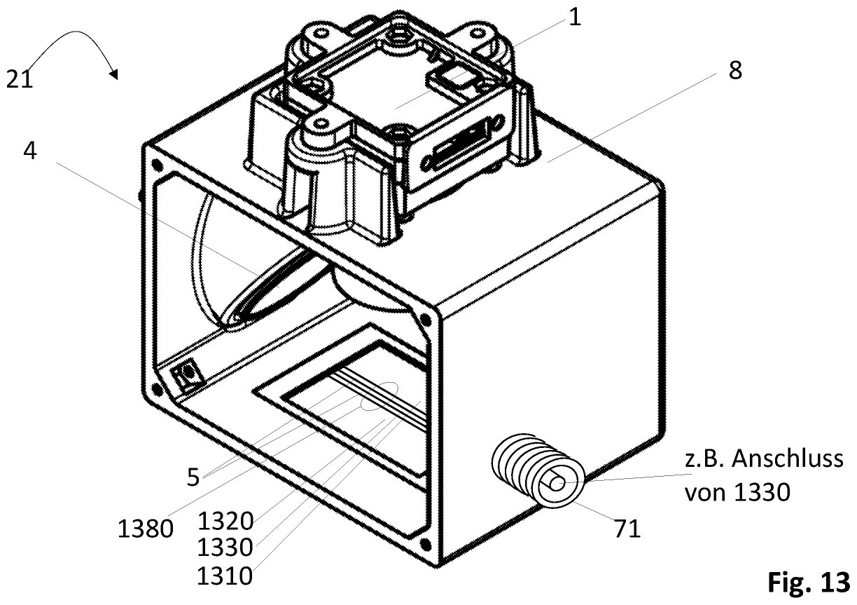

### FIG. 13

FIG. 13 corresponds to FIG. 11, whereby the exemplary device is now shown from a different angle. In the camera's field of view, there are lines 1320, 1310, 1330 of an exemplary trip-plate waveguide 1380 with a sensor element in the clearances 2340 and 2350. The use of other waveguides (1380, 1880, 2380, 6880, 6980) is conceivable. The use of a continuous sensor layer 5 without waveguides (1380, 1880, 2380, 6880, 6980) is also conceivable, in which case the use of microwave and/or RF excitation of the NV centers and/or paramagnetic centers of the sensor layer 5 is not possible. The waveguide (1380, 1880, 2380, 6880, 6980) can preferably be connected, for example, via a plug connection such as a coaxial socket or a triaxial socket 71.

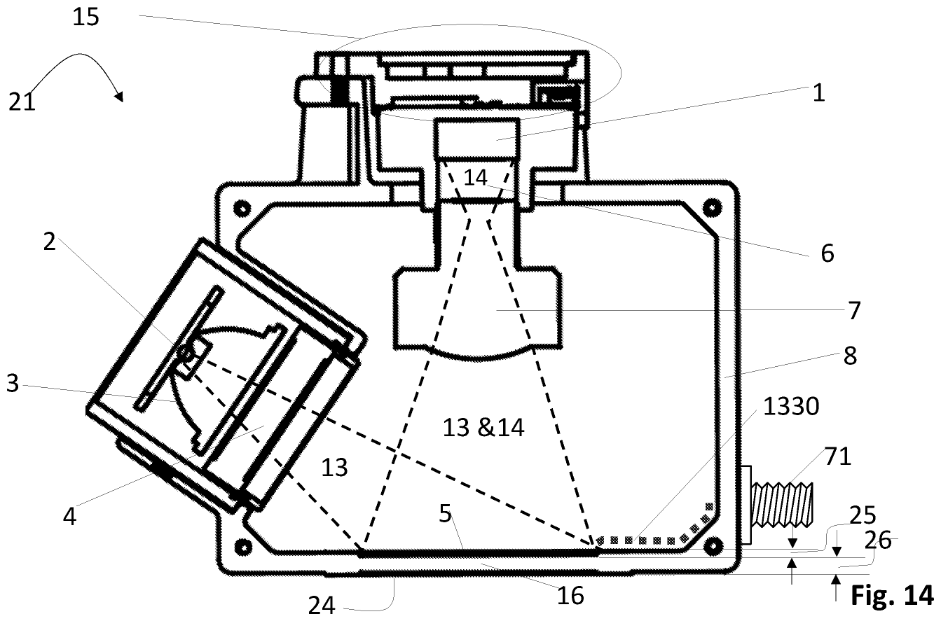

### FIG. 14

FIG. 14 shows a cross-section of the device. The light source 2 (laser, LED) emits the pump radiation 13 with ₚᵤₘₚ radiation wavelength λ (pmp) and possibly also electromagnetic radiation of other wavelength ranges 27. Optical functional elements of illumination optics 3, such as one or more parabolic mirrors, direct as much pump radiation 13 with pump radiation wavelength (pmp) as possible towards the sensor layer 5. direct as much pump radiation 13 with pump radiation wavelength λₚₘₚ as possible in the direction of sensor layer 5. An optical short pass filter 4 preferably transmits the pump radiation 13 with pump radiation wavelength λₚₘₚ and preferably not the electromagnetic radiation of said other wavelength ranges. As a result, the light source 2 essentially exposes the sensor layer 5 exclusively to pump radiation 13 of a pump radiation wavelength λₚₘₚ. The sensor layer 5 preferably comprises crystals and/or nano crystals 66 with paramagnetic centers. Optical functional elements and/or filter foils etc. of the illumination optics 3 in the beam path between the light source 2 and the sensor layer 5 preferably homogenize the intensity distribution of the pump radiation 13 with pump radiation wavelength λₚₘₚ on the sensor layer 5. In the case of a sensor layer 5 with a homogeneous distribution of the paramagnetic centers over the area of the sensor layer 5, this homogenizes the intensity of the fluorescence radiation 14 of the paramagnetic centers of the crystals and/or nano crystals 66 of the sensor layer 5 in a homogeneous magnetic field B. Preferably, the crystals and/or nano crystals 66 of the sensor layer 5 comprise diamonds. Preferably, the crystals 66 of the sensor layer 5 comprise nano crystals 66. Preferably, the paramagnetic centers are NV centers in diamond crystals of the sensor layer 5. Preferably, the substrate material of the sensor layer 5 comprises these crystals and/or nano crystals 66. Preferably, this sensor layer 5 is deposited on a flat surface 15. The sensor layer 5 thus comprises these paramagnetic centers. Since the crystals 66 can be very small as nano crystals 66, the sensor layer 5 can be very thin and very densely filled with crystals and/or nano crystals 66. Since the preferably flat surface 16 is preferably designed as a very thin housing wall of the housing 8, the distance between the sensor layer 5 and the outer surface of the housing 8 in the region of the sensor layer 5 is very small. Preferably, the distance 26 between the sensor layer 5 and the outer surface of the housing 8 in the region of the sensor layer 5 is less than 1 mm, better less than 500 μm, better than 200 μm, better than 100 μm, better than 50 μm, better than 20 μm, better than 10 μm, better than 5 μm, better than 2 μm, better than 1 μm. Preferably, the thickness 25 of the sensor layer 5 is less than 1 mm, better than 500 μm, better than 200 μm, better than 100 μm, better than 50 μm, better than 20 μm, better than 10 μm, better than 5 μm, better than 2 μm, better than 1 μm. Preferably, the ratio between the thickness 25 of the sensor layer 5 divided by the distance 26 between the sensor layer 5 and the outer surface of the housing 8 in the region of the sensor layer 5 is less than 1, better than 0.5, better than 0.2, better than 0.1, better than 0.05, better than 0.02, better than 0.01. The lower limit of the preferably is the ratio between the thickness 25 of the sensor layer 5 divided by the distance 26 between the sensor layer 5 and the outer surface of the housing 8 in the region of the sensor layer 5 they determine requirement of the respective application. A low ratio ultimately leads to a poorer resolution, so that a lower ratio does not always offer an advantage. Depending on the material of the housing wall of the housing in the region of sensor layer 5 and depending on the requirements, this distance between sensor layer 5 and the outer surface of housing 8 in the region of sensor layer 5 may be limited downwards by requirements of mechanical stability, service life, etc. Larger distances between sensor layer 5 and the outer surface of housing 8 in the region of sensor layer 5 reduce the resolution of the sensor measuring device. Upon exposure to pump radiation 13 of the pump radiation wavelength λₚₘₚ by the light source 2, the paramagnetic centers of the sensor layer 5 emit fluorescence radiation 14 with a fluorescence wavelength λ_{fl}. The intensity of the fluorescence radiation 14 with a fluorescence wavelength λ_{fl} depends on the magnetic flux density B at the location of the respective paramagnetic center in the sensor layer 5. An imaging optics 7 detects the fluorescence radiation 14 with the fluorescence wavelength λ_{fl} and maps the intensity distribution of the emission intensity of the fluorescence radiation 14 with the fluorescence wavelength λ_{fl} onto the n×m light sensors of the light sensor array 1, which are preferably arranged in a plane, as a fluorescence picture of the emission intensity of the fluorescence radiation 14 with the fluorescence wavelength λ_{fl}. The light sensor array 1 with the evaluation electronics 15 detects this fluorescence picture of the emission intensity of the fluorescence radiation 14 with the fluorescence wavelength λ_{fl} as an n×m matrix of measured values of the n×m light sensors of the light sensor array 1. The magnetic field camera head 21 used during the testing of the proposal achieved an effective resolution of 33 μm×3 μm. The theoretically achievable resolution is typically in the region of the fluorescence radiation wavelength λ_{FL} of the fluorescence radiation 14. The document presented here thus discloses a technical teaching for a magnetic field camera head 21 for spatially resolved and imaging detection of the distribution of the strength of the magnetic flux density B with a resolution of better than less than 100 μm×100 μm, or better than 50 μm×50 μm, or better than 20 μm×20 μm, or better than 10 μm×10 μm, or better than 5 μm×5 μm, or better than 2 μm×2 μm, or better than 1 μm×1 μm. For these high resolutions, the crystals and/or nano crystals 66 with the paramagnetic centers in the sensor layer 5 should be smaller than the effective length of the outer edge of the effective size of a pixel of the resolution by a factor greater than 2, better by a factor greater than 5, by a factor greater than 10, better by a factor greater than 20, better by a factor greater than 50, by a factor greater than 100, as previously indicated. For these high resolutions, the thickness 25 of the sensor layer 5 should be smaller than the effective length of the outer edge of the effective size of a pixel of the resolution by a factor greater than 2, better by a factor greater than 5, by a factor greater than 10, better by a factor greater than 20, better by a factor greater than 50, by a factor greater than 100, than the effective length of the outer edge of the effective size of a pixel of the resolution as previously indicated. The conditioning circuit for the n×m output signals 31 of the n×m light sensors of the light sensor array 1 conditions the typically analog signals of the n×m output signals 31 of the n×m light sensors of the light sensor array 1 and preferably digitizes them. This processing preferably comprises amplification and/or filtering. Preferably, a computer system of the evaluation electronics 15, which is preferably part of the processing circuit, or of a subsequent computer system 28 for operating the magnetic field camera head 21 multiplies the n×m measured values with n×m calibration values of an n×m calibration matrix. This serves to eliminate any inhomogeneities that may still be present in the fluorescence intensity of the fluorescence radiation 14 with a homogeneous magnetic field B. Preferably, the computer system of the processing circuit of the evaluation electronics 15 passes on the corrected values of the output signals 31 of the light sensors of the light sensor array 1 to a higher-level system, for example a higher-level computer system with a screen via a data bus or the like, via an interface circuit. Preferably, the beam path of the pump radiation 13 and the fluorescence radiation 14 from the light source 2 to the light sensor array 1 is located within a preferably light-tight housing 8. Preferably, the long pass filter 6 is located in the optical path between the sensor layer 5 and the light sensor array 1. Preferably, the optical long pass filter 6 is located as close as possible to the surface or on the surface of the light sensor array 1. The optical long pass filter 6 preferably ensures that essentially only electromagnetic radiation 14 with the fluorescence wavelength λ_{fl}, i.e. essentially only fluorescence radiation 14 with the fluorescence wavelength λ_{(fl)}, reaches the light sensors of the light sensor array 1.

The upper side 23 of the sensor layer 5 is preferably located inside the housing 8.

The underside 22 of the sensor layer 5 is preferably located outside the housing 8. on its surface. Preferably, a light shield covers the underside 22 of the sensor layer 5. This prevents light from penetrating the housing 8 and reaching the light sensor array 1. The sensor layer 5 is preferably transparent to electromagnetic radiation of the pump radiation wavelength λₚₘₚ. The sensor layer 5 is preferably transparent to electromagnetic radiation of the fluorescence radiation wavelength λ_{fl}. For example, the light shield can be a paint on the underside 22 of the sensor layer 5 or a particularly thin, light-impermeable part 16 of the housing wall of the housing 8. Preferably, such a thin housing wall 16 of the housing 8 in the region of the sensor layer 5 does not influence the magnetic field, for example the magnetic flux density B.

Preferably, the light sensor array comprises 1 n×m light sensors, which are preferably arranged in a surface. Here, n and m are positive integers.

In the field of view of the camera, there are lines 1320, 1310, 1330 of an exemplary trip-plate waveguide 1380 with a sensor element in the clearances 2340 and 2350. The use of other waveguides (1380, 1880, 2380, 6880, 6980) is conceivable. The use of a continuous sensor layer 5 without waveguides (1380, 1880, 2380, 6880, 6980) is also conceivable, in which case the use of microwave and/or RF excitation of the NV centers and/or paramagnetic centers of the sensor layer 5 is not possible. The waveguide (1380, 1880, 2380, 6880, 6980) can preferably be connected, for example, via a plug connection such as a coaxial socket or a triaxial socket 71.

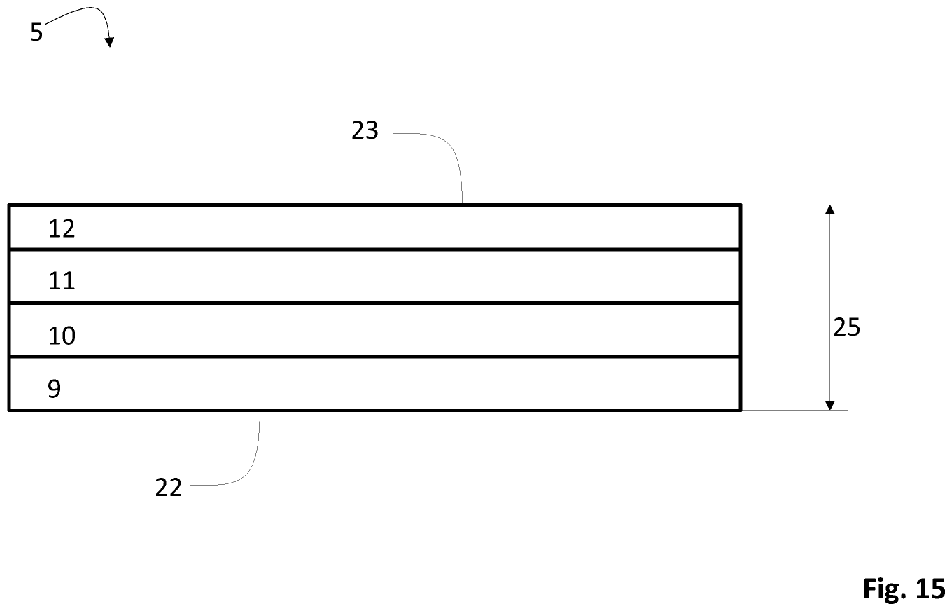

### FIG. 15

FIG. 15 shows an exemplary cross-section, not to scale, of the sensor layer 5.

A reflective coating 10 is applied to a substrate material 9. The substrate material 9 is located in the direction of the underside 22 of the sensor layer 5. The reflective coating 10 is located in the direction of the upper side 23 of the sensor layer 5 with respect to the substrate material 9. The reflective coating 10 is preferably impermeable to electromagnetic radiation with the pump radiation wavelength λₚₘₚ. The reflective coating 10 preferably reflects electromagnetic radiation with the pump radiation wavelength λₚₘₚ back into the interior of the housing 8. This has the advantage that the pump radiation 13 with pump radiation wavelength λₚₘₚ passes through the layer with crystals and/or nano crystals 66 with paramagnetic centers 11 twice. This doubles the pump power and thus the intensity of the fluorescence radiation 14, which reaches n×m light sensors of the light sensor array 1.

The reflective coating 10 preferably reflects electromagnetic radiation with the fluorescence radiation wavelength λ_{(fl)} back into the interior of the housing 8. This has the advantage that the fluorescence radiation 14 with fluorescence radiation wavelength λ_{fl} emitted by the paramagnetic centers of the layer with crystals and/or nano crystals 66 with paramagnetic centers 11 towards the underside 22 of the sensor layer 5 is reflected back towards the surface of the upper side 23 of the sensor layer 5. This again doubles the intensity of the fluorescence radiation 14 that reaches n×m light sensors of the light sensor array 1.

On the reflective coating 10 in the direction of the upper side 23 of the sensor layer 5, the layer with crystals and/or with nano crystals 66 with paramagnetic centers 11 is located as proposed.

A further carrier material layer 12 preferably covers the layer with crystals and/or nano crystals 66 with paramagnetic centers 11. Preferably, the material of the carrier material layer 12 is transparent to electromagnetic radiation, in particular pump radiation 13, with pump radiation wavelength λₚₘₚ. Preferably, the material of the substrate layer 12 is transparent to electromagnetic radiation with fluorescence radiation wavelength λ_{fl}.

The sensor layer 5 may comprise optical functional elements such as optical waveguides and/or filters and/or photonic crystals and/or digital optics. The digital optics can be embossed or otherwise incorporated into the surface of the sensor layer 5.

The sensor layer 5 can comprise optical functional elements such as optical waveguides and/or filters.

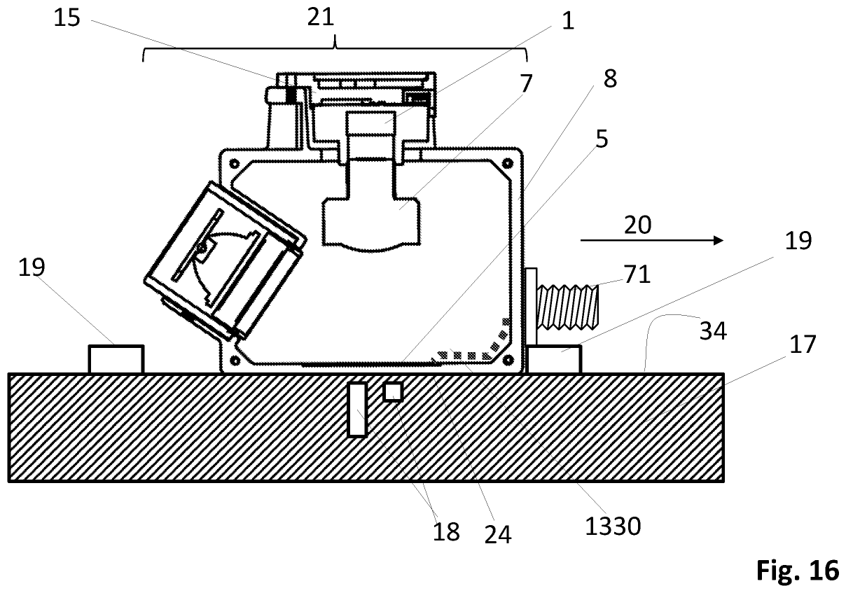

### FIG. 16

FIG. 16 shows a typical usage situation. The magnetic field camera head 21 is preferably placed on the surface 34 of the respective measurement object with the underside 24 of the housing 8. In FIG. 16, the surface 34 of the respective measurement object is the surface of the exemplary ferromagnetic material 17. The exemplary ferromagnetic material 17 of FIG. 16 comprises exemplary inhomogeneities in the form of exemplary defects 18 in the exemplary ferromagnetic material 17 of FIG. 16. Two auxiliary magnets 19 deploy a magnetic excitation of the magnetic test circuit. The exemplary magnetic test circuit here comprises the two auxiliary magnets 19, the material of the measurement object in the form of the exemplary ferromagnetic material 17 and the air space around these objects. The exemplary defects 18 in the exemplary ferromagnetic material 17 of FIG. 16 distort the magnetic field in the region of these defects 18. The defects can be, for example, cracks, holes, grooves, cavities, material composition fluctuations and other structures whose magnetic material parameters lead to a change in the structure of the magnetic flux lines of the magnetic flux B in this region of these defects 18.

The errors 18 lead to a change in the distribution and strength of the magnetic flux B that emerges from the material of the measurement object in the form of the exemplary ferromagnetic material 17 into the air space around these objects. This changes the distribution and direction of the magnetic flux density B as it penetrates the sensor layer 5. This in turn changes the intensity distribution of the intensity of the fluorescence radiation 14 of the paramagnetic centers of the sensor layer 5 in the sensor layer 5. This changes the fluorescence picture of the sensor layer 5, which the fluorescence camera records by means of the imaging optics 7 and the n×m light sensors of the light sensor array 1. The light sensor array 1 detects the fluorescence picture of the sensor layer 5 and transmits this fluorescence picture of the sensor layer 5 to a computer system 28 for operating the magnetic field camera head 21. Preferably, the computer system 28 executes an image processing program for operating the magnetic field camera head 21. Preferably, the computer system 28 for operating the magnetic field camera head 21 determines a deviation between the fluorescence picture of the defective measurement object and the fluorescence picture of a defect-free measurement object or a calculated or otherwise generated reference fluorescence picture. For example, the computer system 28 for operating the magnetic field camera head 21 may execute an AI program for classifying the deviations and/or the errors and/or for evaluating the deviations and/or the errors. For example, the computer system 28 may execute a neural network model to classify the deviations and/or the errors and/or to evaluate the deviations and/or the errors to operate the magnetic field camera head 21. For example, the computer system 28 may execute an AI program to classify and/or evaluate one or more fluorescence pictures to operate the magnetic field camera head 21. For example, the computer system 28 may execute a neural network model for classifying and/or evaluating one or more fluorescence pictures to operate the magnetic field camera head 21.

In order to obtain a complete image of the state of the surface 34 of the material of the measurement object, here in the form of the exemplary ferromagnetic material 17, the person taking the measurement and/or a mechanical positioning device preferably moves the magnetic field camera head 21 over the surface 34 of the material of the measurement object, here in the form of the exemplary ferromagnetic material 17, at a speed 20.

Preferably, the auxiliary magnets 19 are firmly connected to the magnetic field camera head 21 and/or are a part thereof. The auxiliary magnets 19 generate the necessary magnetic excitation H of the magnetic circuit, of which the sensor layer 5 is preferably a part.

The auxiliary magnets 19 preferably comprise permanent magnets. The auxiliary magnets 19 can be or comprise electromagnets. If the auxiliary magnets 19 can comprise electromagnets, the processing circuit 30 for the output signals 31 of the light sensors of the light sensor array 1 and/or a computer system 28 for operating the magnetic field camera head 21 and/or another control device and/or another computer system can modulate, for example, the amplitude of the magnetic excitation H of the auxiliary magnets 19 by means of a control device for the electromagnets of the auxiliary magnets 19 with a code and/or a frequency.

The code can be a spreading code, for example. For example, a pseudo-random number generator PRNG of the control device 39 for the electromagnets of the auxiliary magnets 19 can generate the spreading code in the form of a spreading code signal. Preferably, the spreading code signal comprises the clock frequency of the pseudo-random number generator PRNG. For example, the pseudo-random number generator PRNG can be a shift register fed back with a simple primitive polynomial. Typically, the auxiliary magnets then modulate the magnetic field strength H generated by them at least in part with the respective amplitude of the spreading code signal of the drive device 39 for the electromagnets of the auxiliary magnets 19. For the sake of simplicity, we also refer to a mono-frequency spreading code in the form of a single modulation frequency as a spreading code signal. Preferably, the spreading code signal comprises a lower cut-off frequency ωᵤ and an upper cut-off frequency ωₒ. Preferably, the spreading code signal below the lower cut-off frequency ωᵤ has essentially an amplitude of 0 in. Preferably, the spreading code signal above the upper cut-off frequency ωₒ has essentially an amplitude of 0.

Preferably, the carrier signal of the spreading code signal comprises a carrier frequency that is typically equal to the frequency of the shift frequency of the typically linear feedback shift register of the pseudorandom number generator PRNG. In the case of a mono-frequency spreading code, the carrier frequency corresponds to this frequency of the spreading code. Preferably, the carrier frequency is equal to the frame rate at which the light sensors of the light sensor array 1 of the fluorescence camera detect the fluorescence picture of the sensor layer 5. For the magnetic field camera head 21 of the examples shown here, this frame rate was up to 160 frames per second. For the purposes of the document presented here, the frame rate of the magnetic field camera is the rate of fluorescence pictures generated and transferred by the light sensors of the light sensor array 1 per second. Preferably, the spreading code signal fluctuates between the values 0 and 1, for example.

Since the magnetic field strength H is then modulated with the spreading code signal, the magnetic flux density B, which penetrates the sensor layer 5, is also modulated with the spreading code signal. Therefore, the intensity of the fluorescence radiation 14 is also modulated with the spreading code signal. Preferably, the processing circuit 30 for the output signals 31 of the light sensors of the light sensor array 1 and/or the computer system 28 for operating the magnetic field camera head 21 detects a plurality of fluorescence pictures of the light sensors of the light sensor array 1 of the fluorescence camera and multiplies the amplitudes of the pixel values of the measured values of the light sensors of the light sensor array 1 by the inverse of the value of the spreading code signal or by the inverse of the value of the sum of the value of the spreading code signal plus an offset. Division by 0 is not possible.

Preferably, the processing circuit 30 for the output signals 31 of the light sensors of the light sensor array 1 and/or the computer system 28 for operating the magnetic field camera head 21 evaluate several frames, i.e. fluorescence pictures, of the fluorescence camera, as the light sensors of the light sensor array 1, in an evaluation picture sequence.

At the beginning of the evaluation sequence, the processing circuit 30 for the output signals 31 of the light sensors of the light sensor array 1 and/or the computer system 28 for operating the magnetic field camera head 21 initialize each light sensor of the light sensor array 1 from a respective pixel sum for the sum value of the relevant light sensor of the light sensor array 1 to a predeterminable initial value. Typically, this initial value is 0.

Preferably, the processing circuit 30 for the output signals 31 of the light sensors of the light sensor array 1 and/or the computer system 28 for operating the magnetic field camera head 21 evaluate pixel values of a light sensor of the light sensor array 1 negatively at times at which the spreading code signal assumes the value 0, for example, and therefore subtract the respective pixel value of a light sensor of the light sensor array 1 in that case from a pixel sum for the sum value of the relevant light sensor of the light sensor array 1.

Preferably, the processing circuit 30 for the output signals 31 of the light sensors of the light sensor array 1 and/or the computer system 28 for operating the magnetic field camera head 21 evaluate pixel values of a light sensor of the light sensor array 1 positively at times at which the spreading code signal assumes the value 1, for example, and therefore add the respective pixel value of a light sensor of the light sensor array 1 to a pixel sum for the sum value of the relevant light sensor of the light sensor array 1.

After the evaluation sequence is completed and the processing circuit 30 for the output signals 31 of the light sensors of the light sensor array 1 and/or the computer system 28 for operating the magnetic field camera head 21 have evaluated the planned multiple frames, i.e. fluorescence pictures, of the fluorescence camera, i.e. the light sensors of the light sensor array 1, in the evaluation picture sequence, the processing circuit 30 for the output signals 31 of the light sensors of the light sensor array 1 and/or the computer system 28 for operating the magnetic field camera head 21 generate an improved fluorescence picture from the resulting respective pixel sums for the respective sum values of the respective light sensors of the light sensor array 1.

This procedure eliminates background noise and increases sensitivity.

In the field of view of the camera, there are lines 1320, 1310, 1330 of an exemplary trip-plate waveguide 1380 with a sensor element in the clearances 2340 and 2350. The use of other waveguides (1380, 1880, 2380, 6880, 6980) is conceivable. The use of a continuous sensor layer 5 without waveguides (1380, 1880, 2380, 6880, 6980) is also conceivable, in which case the use of microwave and/or RF excitation of the NV centers and/or paramagnetic centers of the sensor layer 5 is not possible. The waveguide (1380, 1880, 2380, 6880, 6980) can preferably be connected, for example, via a plug connection such as a coaxial socket or a triaxial socket 71.

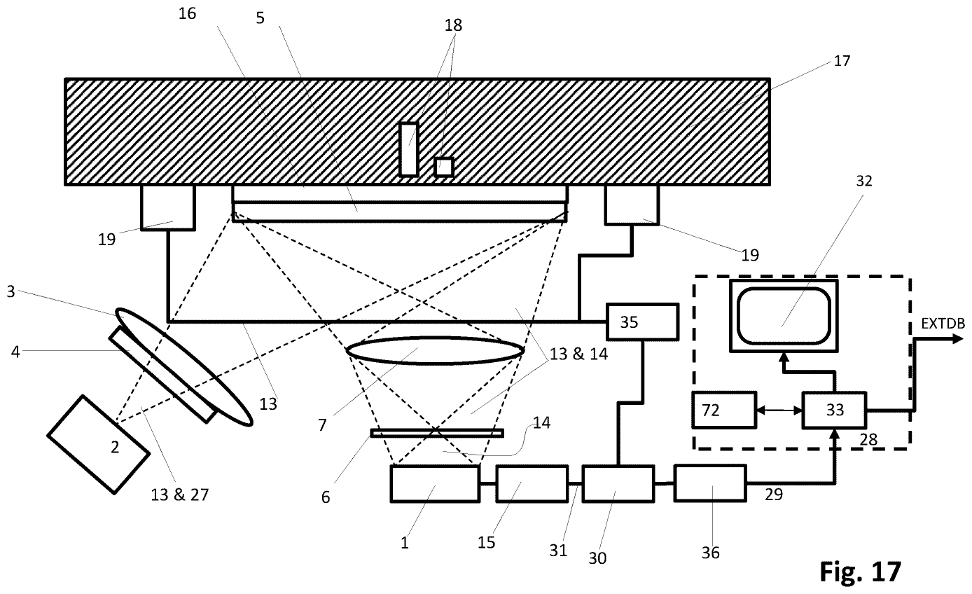

### FIG. 17

FIG. 17 shows a simplified block diagram of the system in FIG. 14 with the control and evaluation devices.

The light source 2 emits pump radiation 13 with a pump radiation wavelength λₚₘₚ and unwanted electromagnetic radiation 27 of other wavelength ranges. An optical short pass filter 4 preferably allows only the pump radiation 13 to pass and preferably retains the electromagnetic radiation 27 of other wavelength ranges. Provided that the light source 2 does not emit any unwanted electromagnetic radiation 27 of other wavelength ranges, this optical short pass filter 4 is not necessary. Illumination optics 3 ensure that the pump radiation 13 illuminates the sensor layer 5 as homogeneously as possible. The illumination optics 3 may comprise one or more optical functional elements. The sensor layer 5 is preferably applied to a mechanical carrier, for example a flat surface 16. Preferably, the flat surface 16 is part of the housing wall of the housing 8 not shown here. The material of this flat surface 16 or of the housing wall of the housing 8 in the region is preferably non-magnetic and preferably does not essentially influence the magnetic field. The sensor layer 5 preferably comprises a multiplicity of randomly and preferably uniformly oriented crystals and/or nano crystals 66 with paramagnetic centers. When diamond is used as the crystal material, the paramagnetic centers may be, for example, NV centers and/or SiV centers and/or TiV centers and/or GeV centers and/or SnV centers and/or NiN4 centers and/or PbV centers and/or ST1 centers. The pump radiation 13 preferably comprises a pump radiation wavelength λₚₘₚ in a wavelength range from 400 nm to 700 nm and/or preferably 450 nm to 650 nm and/or preferably 500 nm to 550 nm and/or preferably 515 nm to 540 nm when using NV centers in dimant as crystals and/or nano crystals 66 of the sensor layer 5. A wavelength of 532 nm is clearly preferred as the pump radiation wavelength λₚₘₚ. In the case of the use of NV centers in diamond or in diamonds of the sensor layer 5, a laser diode of the type PLT5 520B from Osram, for example, is suitable as light source 2 with 520 nm pump radiation wavelength λ₍ₚₘₚ₎. When using NV centers in diamond crystals in the sensor layer 5 as paramagnetic centers of the sensor layer 5, the NV centers of the sensor layer 5 typically emit fluorescence radiation 14 with a typical fluorescence wavelength λ_{fl} of approx. 637 nm for NV centers when exposed to pump radiation 13 of the pump radiation wavelength λₚₘₚ described above. An imaging optics 7 preferably detects the fluorescence picture of the position-dependent fluorescence intensity of the fluorescence radiation 14 with the fluorescence wavelength λ_{fl}, which the sensor layer 5 generates by means of the paramagnetic centers in the sensor layer 5. An optical long pass filter 6 preferentially allows electromagnetic radiation with the fluorescence wavelength λ_{fl} and thus the fluorescence radiation 14 to pass. The optical long pass filter 6 preferably blocks the passage of electromagnetic radiation with the pump radiation wavelength λₚₘₚ and thus the passage of the pump radiation 13. As a result, the imaging optics 7 can detect the fluorescence picture of the sensor layer 5 in the wavelength range of the fluorescence wavelength λ_{fl} and image it onto the n×m light sensors of the n×m light sensor array 1 of the fluorescence camera. Since the intensity of the fluorescence radiation 14 of the sensor layer 5 locally in the sensor layer 5 depends on the magnetic flux density B at the location of the respective paramagnetic center in the sensor layer 5, the fluorescence picture of the sensor layer 5 corresponds to a magnetic flux density magnitude picture of the magnetic flux density field that flows through the sensor layer 5. Since the density distribution of the paramagnetic centers in the sensor layer 5 and/or the illumination of the sensor layer 5 with pump radiation 13 and/or the detecting of the fluorescence intensity of the fluorescence radiation 14 over the area of the sensor layer 5 are usually not completely homogeneous despite all efforts, it has proven useful to calibrate the system by means of calibration measurements before the first use. To process the measured values of the light sensors of the light sensor array 1, evaluation electronics 15 of the light sensor array 1 detect the measured values of the signals of the light sensors of the light sensor array 1 and form the output signals 31 of the light sensors of the light sensor array 1 from them, in particular by amplification and/or filtering. The conditioning circuit 30 for the output signals 31 of the light sensors of the light sensor array 1 preferably controls the auxiliary magnets 19 by means of a control device 35 for the electromagnets of the auxiliary magnets 19, if these do not comprise only permanent magnets. The processing circuit 30 for the output signals 31 of the light sensors of the light sensor array 1 generates a fluorescence picture and/or, for example, possibly also an improved fluorescence picture from the output signals 31 of the light sensors of the light sensor array 1, as described above. Due to the relationships described above, the fluorescence picture and/or, for example, possibly also the improved fluorescence picture represent a magnetic flux density magnitude picture of the magnetic flux density field in the sensor layer 5 or an improved magnetic flux density magnitude picture of the magnetic flux density field in the sensor layer 5. The processing circuit 30 for the output signals 31 of the light sensors of the light sensor array 1 preferably transfers this fluorescence picture or the improved fluorescence picture by means of the interface circuit 36 via a data bus 29 to a computer system 28 for operating the magnetic field camera head 21. Preferably, the computer system 28 for operating the magnetic field camera head 21 generates a one- or two- or three-dimensional representation of the distribution of the magnetic flux density in the sensor layer 5 from this fluorescence picture or from the improved fluorescence picture and displays it on the screen 32. The data bus 29 is used for fabrication of the data connection between the processing circuit 30 for the output signals 31 of the light sensors of the light sensor array 1 and the computer system 28 for operating the magnetic field camera head 21. The measurement object, here exemplarily a ferromagnetic material 17 with defects 18, generates the variations of the magnetic flux density B in the sensor layer 5, which lead to the said magnetic flux density magnitude images of the magnetic flux density field in the sensor layer 5 or the improved magnetic flux density magnitude images of the magnetic flux density field in the sensor layer 5.

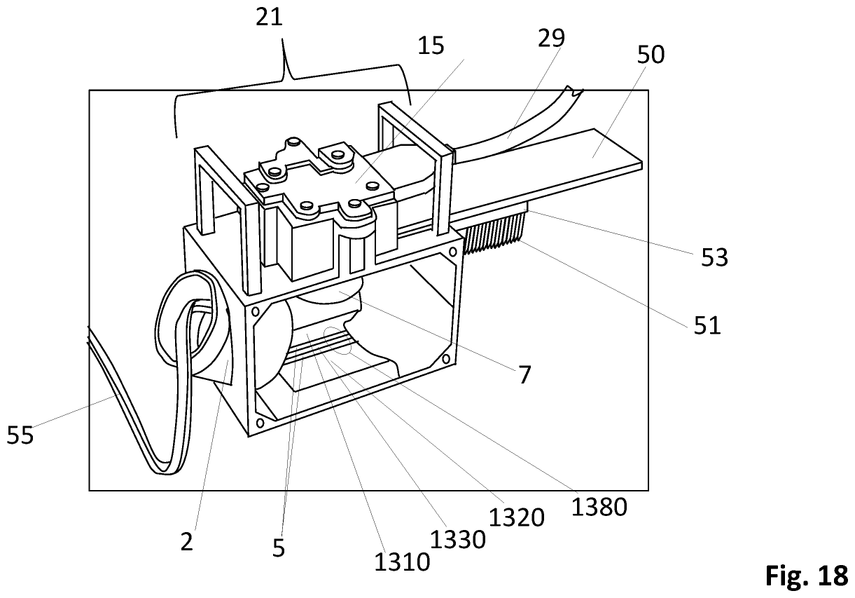

### FIG. 18

FIG. 18 shows a drawing based on an exemplary photograph of an exemplary sensor head 21 with the cover removed, which was created during the preparation of the proposal presented here. The drawing essentially corresponds to FIG. 13. The supply line with the data bus 29 for fabrication of the data connection between the processing circuit 30 for the output signals 31 of the light sensors of the light sensor array 1 and the computer system 28 for operating the magnetic field camera head 21 can be seen. In addition, the light source 2 and the sensor layer 5 exposed to green pump radiation 13 can be seen.

In the field of view of the camera, there are lines 1320, 1310, 1330 of an exemplary trip-plate waveguide 1380 with a sensor element in the clearances 2340 and 2350. The use of other waveguides (1380, 1880, 2380, 6880, 6980) is conceivable. The use of a continuous sensor layer 5 without waveguides (1380, 1880, 2380, 6880, 6980) is also conceivable, in which case the use of microwave and/or RF excitation of the NV centers and/or paramagnetic centers of the sensor layer 5 is not possible. The waveguide (1380, 1880, 2380, 6880, 6980) can preferably be connected, for example, via a plug connection such as a coaxial socket or a triaxial socket 71.

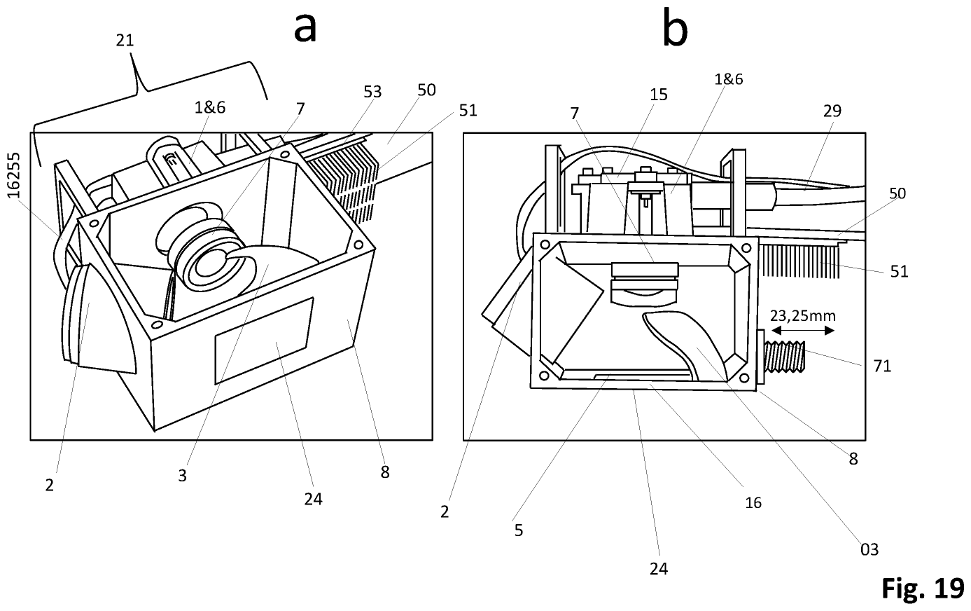

### FIG. 19a

FIG. 19a shows a drawing based on an exemplary photograph of an exemplary sensor head 21 created during the preparation of the proposal presented here with the cover removed. The drawing also essentially corresponds to FIG. 13. The light source 2, underside 24 of the housing 8, the imaging optics 7 in the form of a camera lens and a previously unmentioned mirror 3 for homogenizing the pump radiation intensity of the pump radiation 13 on the sensor layer 5 can be seen. The magnetic field camera head 21 of FIG. 19a is an example of an illumination optics 3 comprising several optical functional elements.

### FIG. 19b

FIG. 19b essentially corresponds to FIG. 19a and shows the same magnetic field camera head 21 from a slightly different perspective. The light sensor array 1 and the optical long pass filter 6 are housed in the gray protuberance. The thickness of the housing wall of the housing 8 in the region of the sensor layer 5 and the underside 24 of the housing 8 are clearly visible. The supply line with the data bus 29 for fabrication of the data connection between the processing circuit 30 for the output signals 31 of the light sensors of the light sensor array 1 and the computer system 28 for operating the magnetic field camera head 21. The light source 2 and the sensor layer 5 exposed to green pump radiation 13 can also be seen. The exemplary magnetic field camera head 21 is capable of displaying the local distribution of magnetic flux densities with absolute values from 0mT to approx. 50mT.

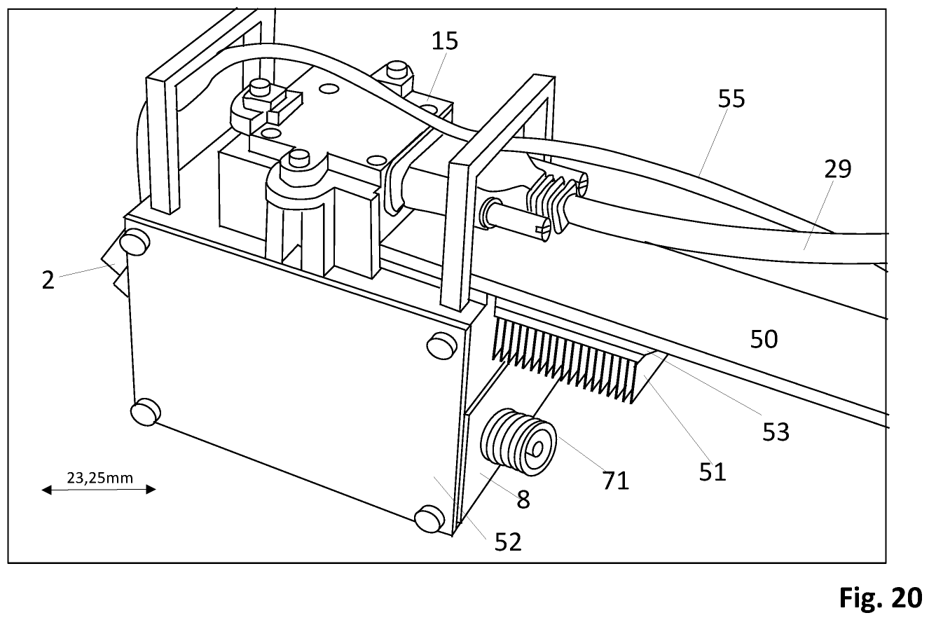

### FIG. 20

FIG. 20 shows a drawing of the prototype with the cover in place. The interior of the housing 8 of the magnetic field camera head 21 is then sealed light-tight.

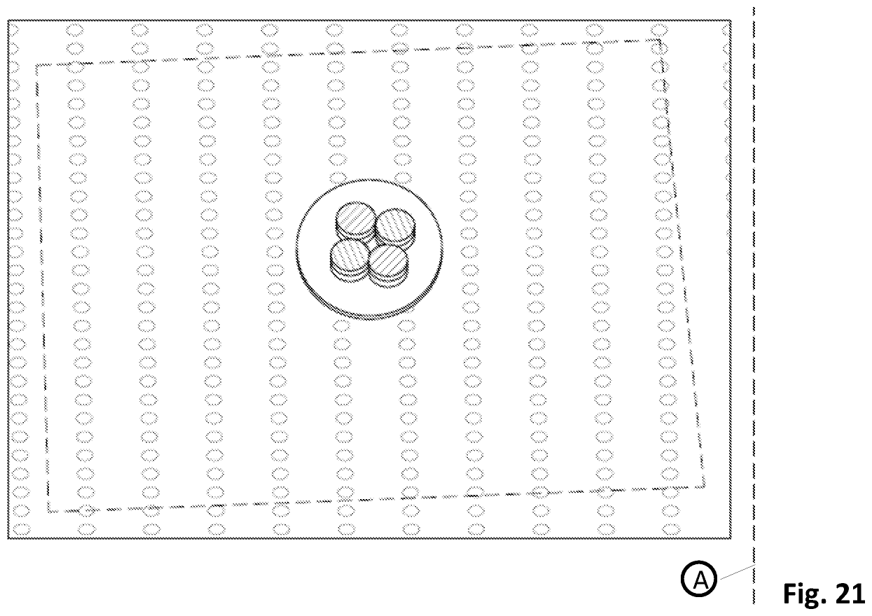

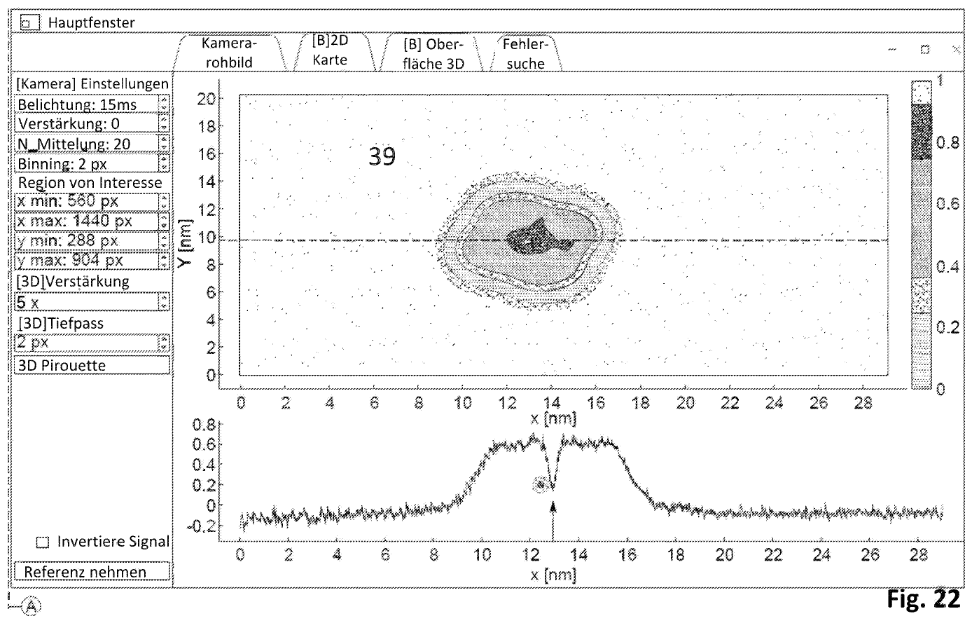

### FIGS. 21 and 22

FIG. 22 above shows the pattern-coded magnetic flux density magnitude image 39 of the distribution of the magnetic flux density of four permanent magnets 37 on a glass plate 38 in arbitrary units. The system of FIG. 17 generated this two-dimensional false-color magnetic flux density magnitude image 39 of the distribution of the magnetic flux density of four permanent magnets 37 on a glass plate 38 by placing the magnetic field camera head 21 of the preceding pages with its underside 24 on the permanent magnets 37 (see FIG. 21).

FIG. 22 below shows the one-dimensional course of the fluorescence intensity along a line through the grouping of permanent magnets 37. The magnetic field camera can resolve structures smaller than 500 μm.

These two images are drawings based on screen shots of the display on screen 32.

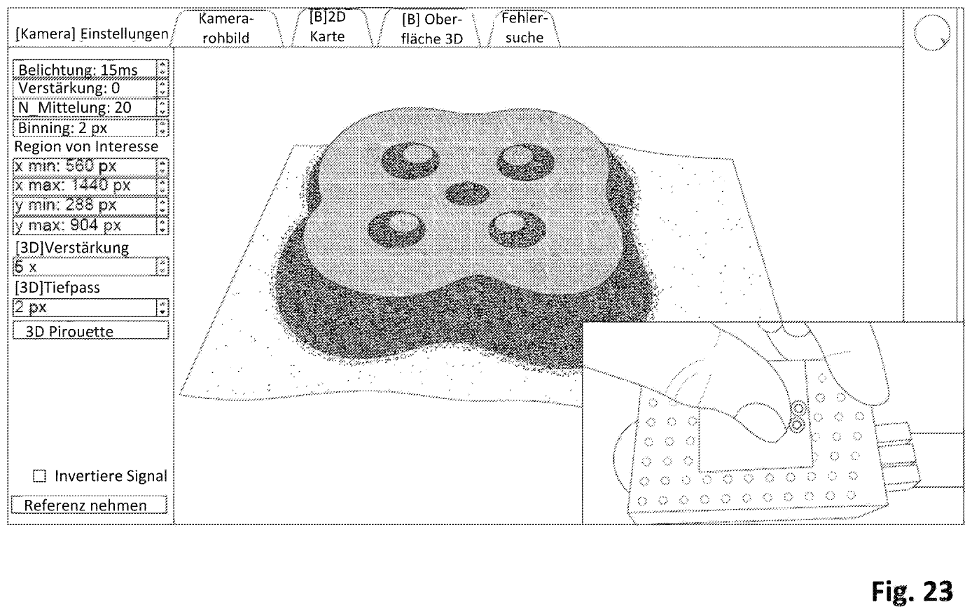

### FIG. 23

FIG. 23 shows an illustration for four magnetized rings. FIG. 22 shows the corresponding arrangement at the bottom left as a drawing based on a photo.

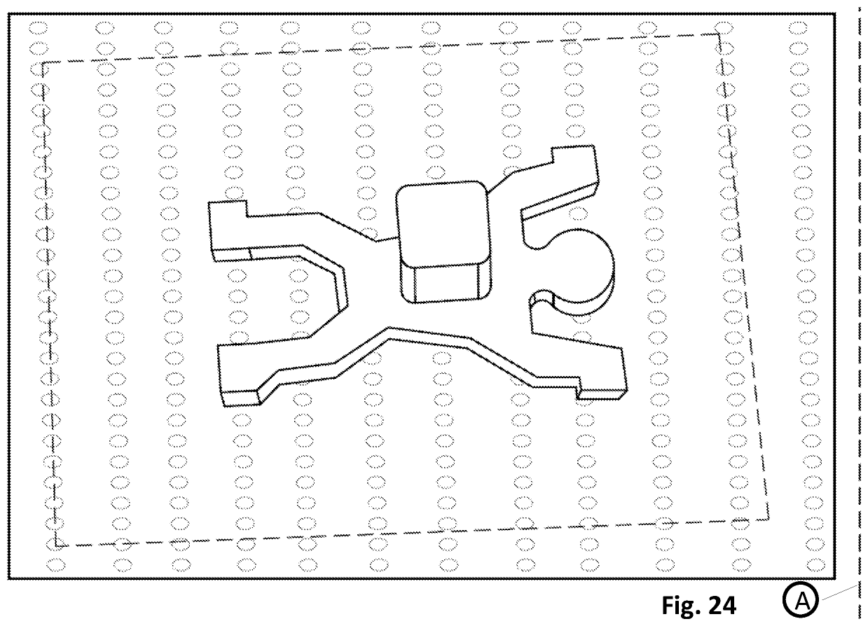

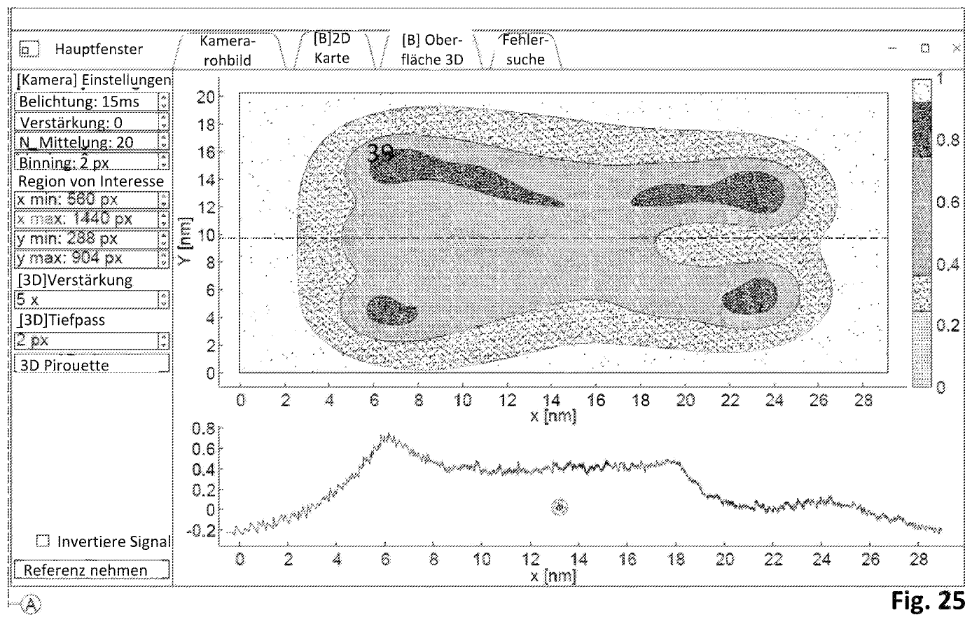

### FIGS. 24 and 25

FIG. 24 corresponds to FIG. 21 and FIG. 25 corresponds to FIG. 22, but a magnetizable ferromagnetic flat figure (see FIG. 23) was used to create FIG. 25.

FIG. 25 above shows the two-dimensional pattern-coded magnetic flux density magnitude image 39 of the distribution of the magnetic flux density of the magnetized figure on a glass plate 38 in arbitrary units. The system of FIG. 17 generated this pattern-coded magnetic flux density magnitude image 39 of the distribution of the magnetic flux density of four permanent magnets 37 on a glass plate 38 by placing the magnetic field camera head 21 of the preceding pages with its underside 24 on the magnetized figure of FIG. 24.

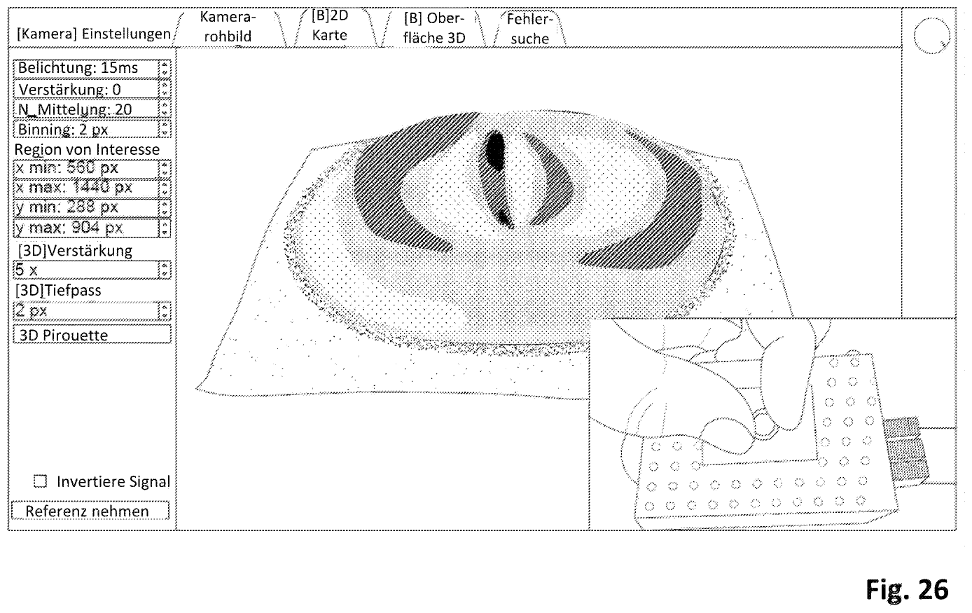

FIG. 26 below shows the one-dimensional progression of fluorescence intensity along a line through the magnetized figure in FIG. 24.

These two images are drawings based on screen shots of the display on screen 32.

### FIG. 26

FIG. 26 shows an illustration of an inhomogeneously magnetized ring. FIG. 26 shows the corresponding arrangement at the bottom left as a drawing based on a photo.

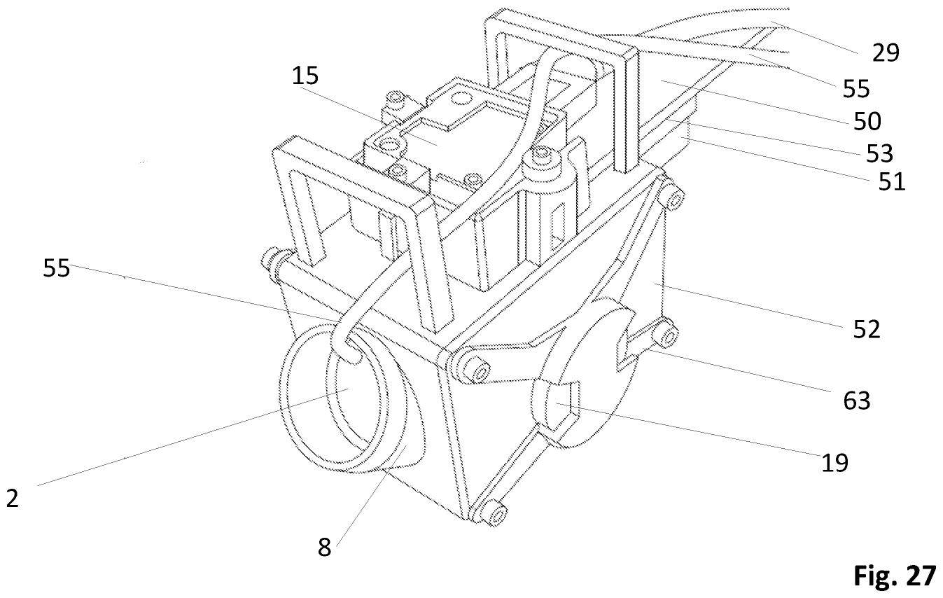

### FIG. 27

FIG. 27 shows the sensor head with attached auxiliary magnets 19.

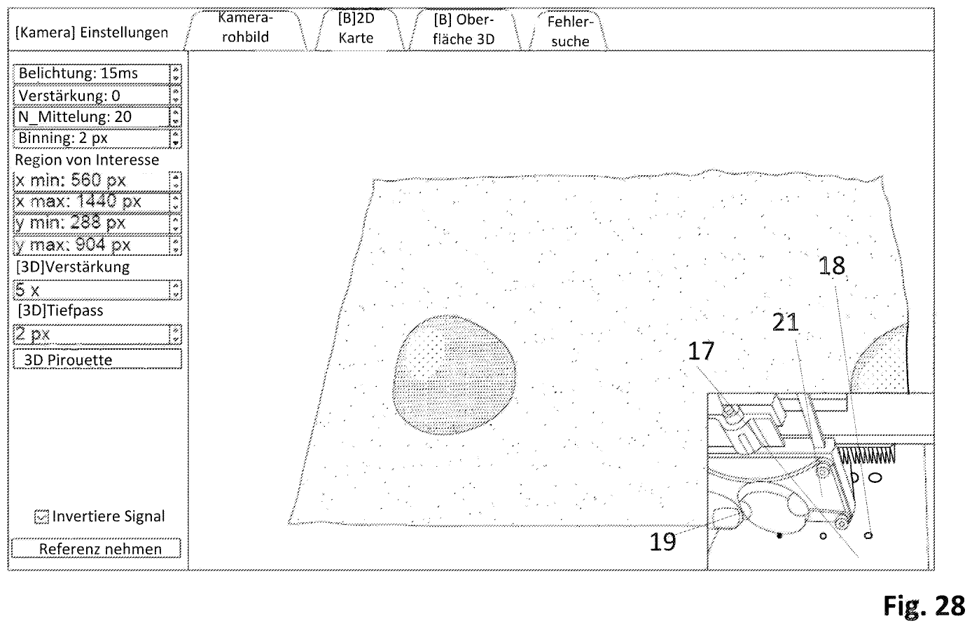

### FIG. 28

FIG. 28 shows the detection and visualization of holes in a ferromagnetic material 17 with a device of FIGS. 28, 16 and 17. One of the two images is a drawing based on a screen shot of the display on the screen 32. The other image is a drawing based on a photograph of the measurement situation.

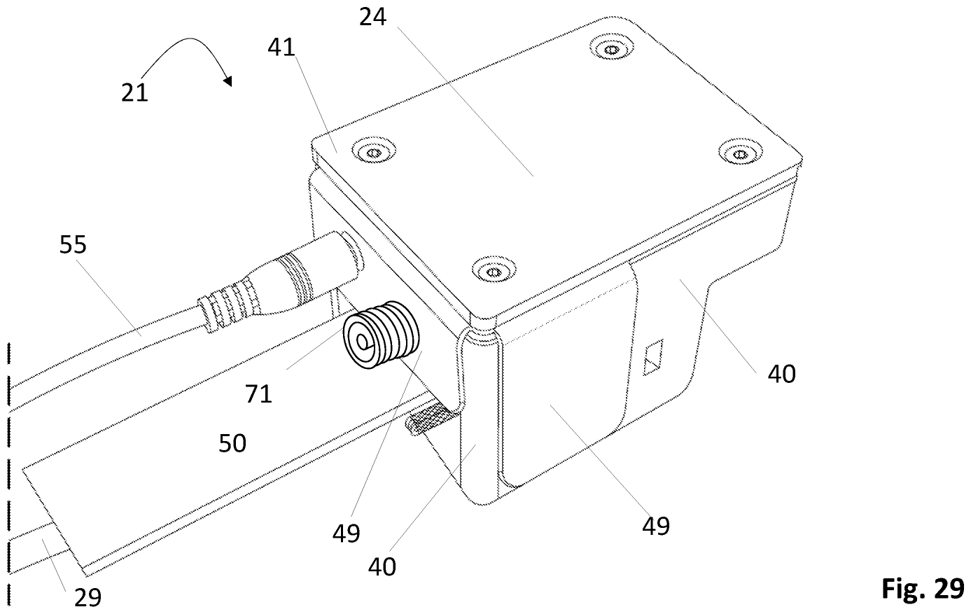

### FIG. 29

FIG. 29 shows an exemplary, alternative magnetic field camera head 21 of an exemplary, alternative magnetic field camera. The housing 8 of this exemplary, alternative magnetic field camera head 21 of the exemplary, alternative magnetic field camera comprises, by way of example, an upper housing part 40 of the housing 8 and a lower housing part 41 of the housing 8. For example, the upper housing part 40 of the housing 8 may be an upper 3D printing housing part of the exemplary 3D printing housing 8. For example, the lower housing portion 41 of the housing 8 may be a lower 3D printed housing portion of the exemplary 3D printed housing 8. Here, the lower housing part 41 of the housing 8 comprises, by way of example, the underside 24 of the housing 8 with the sensor layer 5, which preferably comprises the layer 11 with crystals and/or nano crystals 66 with paramagnetic centers. The sensor layer 5 is preferably covered by a thin material layer of the lower housing part 41 of the housing 8 on the underside 24 of the housing 8 and is thus mechanically protected. The material of this thin material layer of the lower housing part 41 of the housing 8 at the underside 24 of the housing 8 preferably does not influence the magnetic flux density in absolute value and direction, which flows through the sensor layer 5, preferably essentially. Essentially means here that the material of this thin material layer of the lower housing part 41 of the housing 8 on the underside 24 of the housing 8 influences the magnetic flux density flowing through the sensor layer 5, that this influence is insignificant for the respective technical purpose and/or that this influence for influencing a measured value, which is dependent on the fluorescence radiation 14 of the layer 11, only has such a small influence that this measured value only undergoes a change in terms of magnitude which is within a predetermined tolerance interval in terms of magnitude. A power supply line 55 is electrically connected by means of a connector 56 for the power supply line 55 to the printed circuit board (PCB) 43 for the LEDs 44 and their power supply 45 and the LEDs 44 in the lower housing part 41 of the housing 8. The power supply line 55 serves to supply power to the printed circuit board (PCB) 43 for the LEDs 44 and their power supply 45 and the LEDs 44.

A data bus line of a data bus 29 is used for fabrication of the data connection between the processing circuit 30 for the output signals 31 of the light sensors of the light sensor array 1 and the computer system 28 for operating the magnetic field camera head 21 (see also FIG. 17).

A second heat sink 49 serves to cool the printed circuit board (PCB) 43 for the LEDs 44 and their power supply 45 and the LEDs 44. The second heat sink 49 preferably comprises copper or another material with good thermal conductivity, which preferably has little or essentially no effect on the magnetic flux density flowing through the layer 11 of the sensor layer 5, or a worse effect than the heat sink material of the second heat sink 49. Elaboration of the proposal revealed that it is advantageous to keep the temperature of the light sensor array 1 and/or the sensor layer 5 low in order to keep the signal-to-noise ratio as large as possible. Despite their relatively good efficiency, the LEDs 44 generate a large amount of waste heat during operation, which the second heat sink 49 dissipates from the housing 8 to improve the signal-to-noise ratio.

For the same reason, the magnetic field camera head 21 proposed here as an example comprises a first heat sink 50 for cooling the evaluation electronics 15 of the light sensor array 1 and/or the light sensor array 1. The first heat sink 50 thereby improves the signal-to-noise ratio of the video signal of the light sensor array 1 in the fluorescence camera of the sensor head 21.

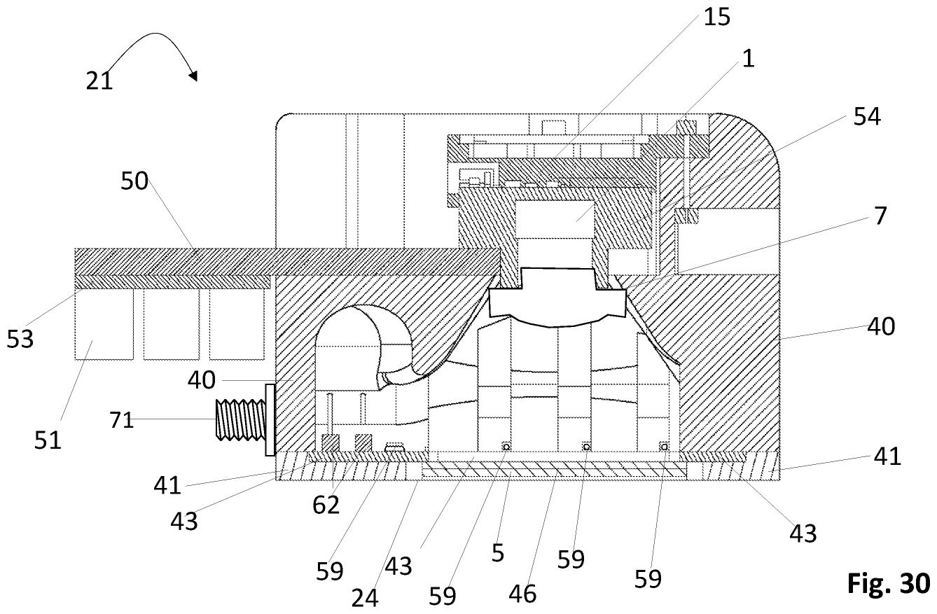

### FIG. 30

FIG. 30 shows a schematic and simplified cross-section of the magnetic field camera head 21 of FIG. 29.

The housing 8 of the magnetic field camera head 21 again comprises, by way of example, as in FIG. 29, an upper housing part 40 of the housing 8 and a lower housing part 41 of the housing 8.

The lower housing part 41 of the housing 8 comprises, by way of example, a printed circuit board (PCB) 43 for the LEDs 44 and their power supply 45.

In this example, LED series resistors 59 are mounted on the printed circuit board (PCB) 43, for example soldered or glued on. These LED series resistors 59 are typically LED series resistors 59 of the LEDs 44 on the printed circuit board (PCB) 43 for current limitation of the diode current of the LEDs 44 during operation. Preferably, a thin material layer of the lower housing part 41 of the housing 8 covers the sensor layer 5 and protects it. For a better overview, this preferably thin material layer of the lower housing part 41 of the housing 8 is not shown in FIG. 30. The bearing of this thin material layer is essentially the same as the underside 24 of the housing 8 in the region of the sensor layer 5.

A coding plug 62 with jumper mounted on the printed circuit board (PCB) 43 can be used, for example, to change analog operating parameters of the electronic circuit on the printed circuit board (PCB) 43. For example, it is conceivable that it is possible to adjust the electrical LED current through the LEDs 44 on the printed circuit board (PCB) 43 by means of such a coding plug 62 by positioning the jumper. The coding plug 62 typically provides for several different possible positions of the jumper on the coding plug 62, each of these positions preferably corresponding to a very specific current supply to the LEDs 44 with an electrical current with a very specific current value.

In the example shown in FIG. 30, the LED series resistors 59 are mounted on the side of the printed circuit board (PCB) 43 facing the fluorescence camera. In the example of FIG. 30, the LEDs 44 are mounted on the side of the printed circuit board (PCB) 43 facing away from the fluorescence camera. This has the advantage that no or only little stray light from the LEDs 44 can reach the light sensor array 1 in the fluorescence camera of the magnetic field camera head 21. This improves the signal-to-noise ratio of the measurement signal of the magnetic field camera head 21. Preferably, the sensor layer 5 is mechanically bonded to the printed circuit board (PCB) 43, for example by means of an adhesive 48.

The sensor layer 5 preferably, but not necessarily, comprises a glass plate 46.

In the example of FIG. 30, the glass plate serves here as an exemplary optical functional element that the paramagnetic centers of the pump radiation 13 with the pump radiation wavelength λₚₘₚ. Preferably, the glass plate 46 forms the flat surface 16 of the lower housing part 41 of the housing 8. In the example of FIG. 30, the glass plate 46 also has the function of the substrate material II 12.

The first heat sink 50 serves to cool the evaluation electronics 15 of the light sensor array 1 and/or the light sensor array 1. The first heat sink 50 preferably comprises copper and/or another material with good thermal conductivity, preferably essentially non-magnetic, as the heat sink material of the first heat sink 50. Preferably, the first heat sink 50 is in the best possible thermal contact with the camera housing 54 of the fluorescence camera with the light sensor array 1 with its evaluation electronics 15 and the imaging optics 7.

For example, heat-conducting paste 53 and/or a heat-conducting adhesive 53 can thermally and/or mechanically connect cooling fins 51 to the first heat sink 50. In this way, the heat sink 50 can dissipate the heat of the evaluation electronics 15 of the light sensor array 1 of the fluorescence camera to the ambient air and reduce the temperature of the light sensor array 1. This improves the signal-to-noise ratio of the data signal of the light sensor array 1 via the data line 29.

In the example of FIG. 30, the fluorescence camera comprises a camera housing 54 of the fluorescence camera with the light sensor array 1. In the example of FIG. 30, the camera housing 54 of the fluorescence camera with the light sensor array 1 with its evaluation electronics 15 and the imaging optics 7 is inserted or screwed or glued or the like into the upper housing part 40 of the housing 8. In contrast to the devices of FIGS. 11, 12, 13, 14, 16, 18, 19, 20, the pump radiation sources now do not expose the sensor layer 5 from above, as in FIGS. 11, 12, 13, 14, 16, 18, 19, 20, but from the side of the glass plate 46. In the example of FIG. 30, the LEDs 44 irradiate the pump radiation 13 with the pump radiation wavelength λₚₘₚ into the glass plate 46 from the side. The pump radiation 13 preferably emerges from the glass plate 46 over the entire surface of the glass plate 46 and exposes the layer 11 with the crystals and/or nano crystals 66 with the paramagnetic centers, for example the NV centers, on the underside of the glass plate 46 on the side of the glass plate 46 facing away from the light sensor array 1. As a result, the LEDs 44 excite the crystals and/or nano crystals 66 with the paramagnetic centers, for example the NV centers, on the underside of the glass plate 46 on the side of the glass plate 46 facing away from the light sensor array 1 to emit fluorescence radiation 14. A preferably present reflective layer 10 underneath the layer 11 with the crystals and/or with the nano crystals 66 with the paramagnetic centers, for example the NV centers, on the underside of the glass plate 46 on the side of the glass plate 46 facing away from the light sensor array 1 reflects pump radiation 13 and fluorescence radiation 14, which emerges downwards from the layer 11 on the side of the glass plate 46 facing away from the light sensor array 1, back into the layer 11. The reflected pump radiation 13 amplifies the generation of fluorescence radiation 14 in the layer 11. The reflected fluorescence radiation 14, like the fluorescence radiation 14 emitted directly in the direction of the light sensor array 1, reaches the light sensor array 1 and thus improves the signal-to-noise ratio.

Typically, the local intensity of the fluorescence radiation 14 of the paramagnetic centers in the layer 11 of the sensor layer 5 at different positions in the layer 11 depends on the intensity of the pump radiation 13 and the absolute value of the magnetic flux density B at these positions.

This results in an intensity pattern of the emission of the fluorescence radiation 14 of the paramagnetic centers in the layer 11 of the sensor layer 5 at different positions in the layer 11, which reflects the areal differences in the absolute values of the intensity of the fluorescence radiation 14 of the paramagnetic centers in the layer 11 of the sensor layer 5 at different positions of the layer 11.

The imaging optics 7 detects this intensity pattern of the emission of the fluorescence radiation 14 of the paramagnetic centers in the layer 11 of the sensor layer 5 and maps this intensity pattern onto the light sensor array 1.

The camera housing 54 of the fluorescence camera mechanically connects the light sensor array 1 in the example of FIG. 30 with its evaluation electronics 15 and the imaging optics 7 and with the upper housing part 40 of the housing 8.

The data bus 29 for fabrication of the data connection between the conditioning circuit 30 for the output signals 31 of the light sensors of the light sensor array 1 and the computer system 28 for operating the magnetic field camera head 21 is omitted in the example of FIG. 30 for simplification. When reading this text, a person skilled in the art should imagine this data bus 29 for fabrication of the data connection between the processing circuit 30 for the output signals 31 of the light sensors of the light sensor array 1 and the computer system 28 for operating the magnetic field camera head 21.

The power supply line 55 for the power supply of the printed circuit board (PCB) 43 for the LEDs 44 and their power supply 45 and the LEDs 44 is omitted in the example of FIG. 30 for simplification. When reading this text, a person skilled in the art should this power supply line 55 for the power supply of the printed circuit board (PCB) 43 for the LEDs 44 and their power supply 45 and the LEDs 44.

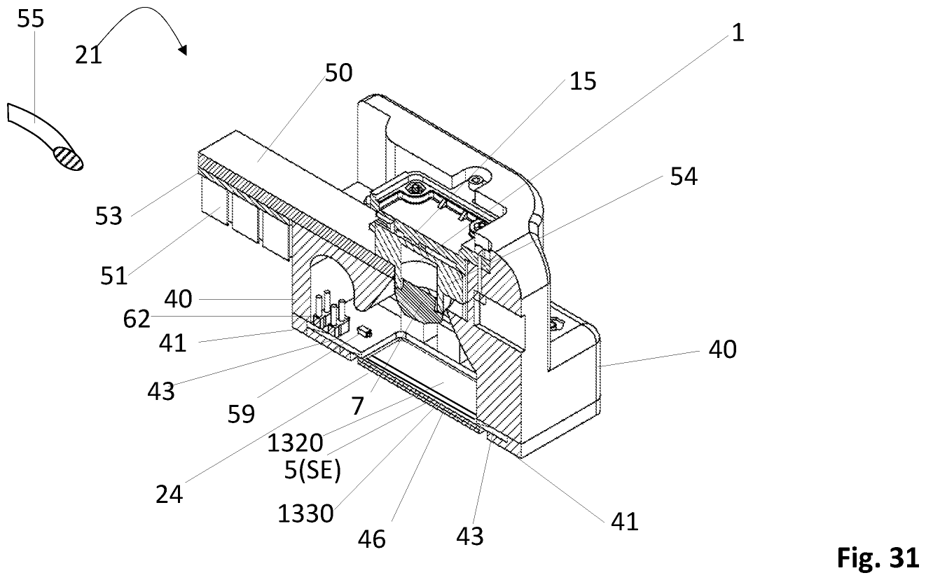

### FIG. 31

FIG. 31 essentially corresponds to FIG. 30 and shows the same magnetic field camera head 21 as the device of FIG. 30 and FIG. 29 from a different perspective. The document presented here therefore refers to the descriptions of FIGS. 29 and 30 and the list of reference symbols. The power supply line 55 for the power supply of the printed circuit board (PCB) 43 for the LEDs 44 and their power supply 45 and the LEDs 44 is cut in the example of FIG. 31 and is therefore only incompletely shown. The data bus 29 for fabrication of the data connection between the processing circuit 30 for the output signals 31 of the light sensors of the light sensor array 1 and the computer system 28 for operating the magnetic field camera head 21 is omitted in the example of FIG. 31 for simplification. When reading this text, a person skilled in the art should imagine this data bus 29 for fabrication of the data connection between the processing circuit 30 for the output signals 31 of the light sensors of the light sensor array 1 and the computer system 28 for operating the magnetic field camera head 21.

In the field of view of the camera, there are lines 1320, 1310, 1330 of an exemplary trip-plate waveguide 1380 with a sensor element in the clearances 2340 and 2350. The use of other waveguides (1380, 1880, 2380, 6880, 6980) is conceivable. The use of a continuous sensor layer 5 without waveguides (1380, 1880, 2380, 6880, 6980) is also conceivable, in which case the use of microwave and/or RF excitation of the NV centers and/or paramagnetic centers of the sensor layer 5 is not possible. The waveguide (1380, 1880, 2380, 6880, 6980) can preferably be connected, for example, via a plug connection such as a coaxial socket or a triaxial socket 71.

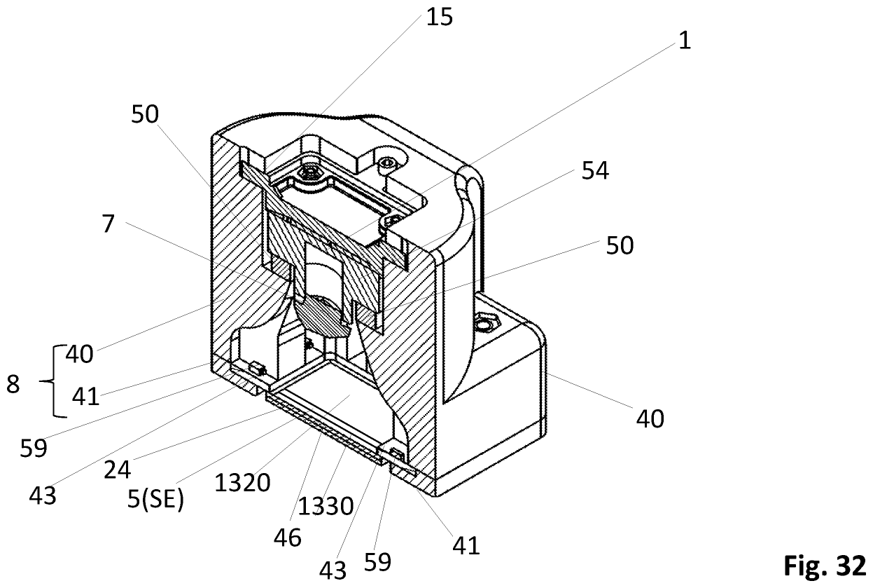

### FIG. 32

FIG. 32 essentially corresponds to FIGS. 29 to 31 in that FIG. 32 now shows a cross-section through the magnetic field camera head 21 of FIGS. 29 to 31 transversely to the first heat sink 50. The document presented here therefore refers here to the descriptions of FIGS. 29 to 31 and the list of reference symbols.

In the field of view of the camera, there are lines 1320, 1310, 1330 of an exemplary trip-plate waveguide 1380 with a sensor element in the clearances 2340 and 2350. The use of other waveguides (1380, 1880, 2380, 6880, 6980) is conceivable. The use of a continuous sensor layer 5 without waveguides (1380, 1880, 2380, 6880, 6980) is also conceivable, in which case the use of microwave and/or RF excitation of the NV centers and/or paramagnetic centers of the sensor layer 5 is not possible. The waveguide (1380, 1880, 2380, 6880, 6980) can preferably be connected, for example, via a plug connection such as a coaxial socket or a triaxial socket 71.

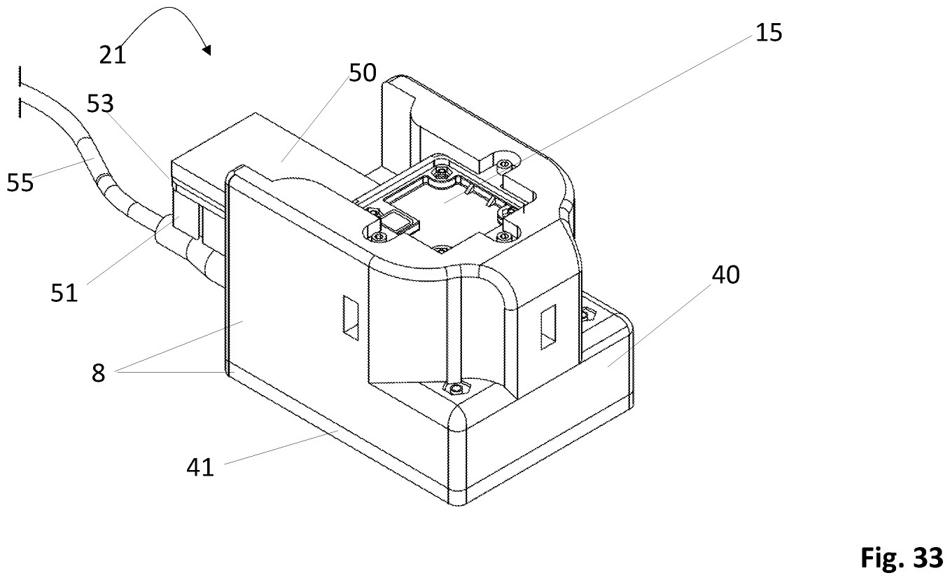

### FIG. 33

FIG. 33 essentially corresponds to FIGS. 29 to 32 in that FIG. 33 is a side view without section from a different perspective. The document presented here therefore refers to the descriptions of FIGS. 29 to 32 and the list of reference symbols.

The data bus 29 for fabrication of the data connection between the conditioning circuit 30 for the output signals 31 of the light sensors of the light sensor array 1 and the computer system 28 for operating the magnetic field camera head 21 is omitted in the example of FIG. 33 for simplification. When reading this text, a person skilled in the art should imagine this data bus 29 for fabrication of the data connection between the processing circuit 30 for the output signals 31 of the light sensors of the light sensor array 1 and the computer system 28 for operating the magnetic field camera head 21.

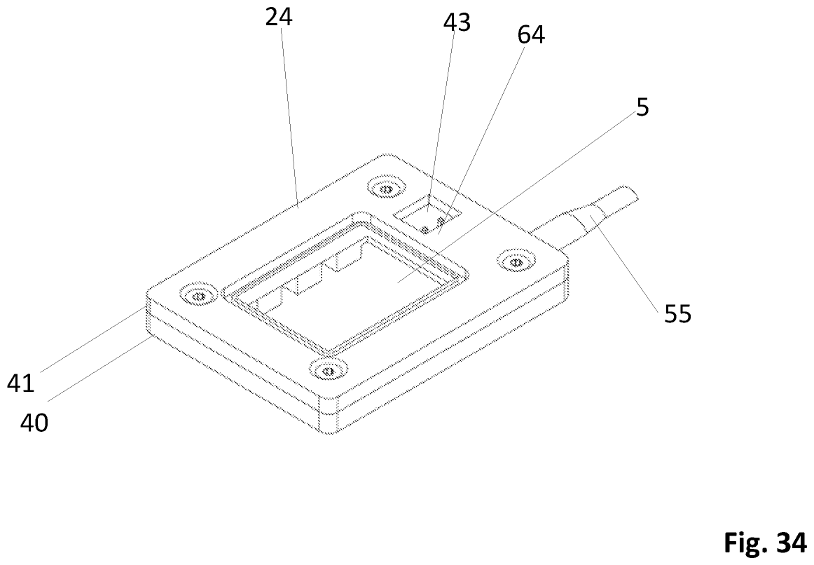

### FIG. 34

FIG. 34 corresponds essentially to FIGS. 29 to 33 in that FIG. 34 is a side view with horizontal section from a perspective from below looking at the sensor layer 5 on the underside 24 of the sensor head 21 of FIGS. 29 to 33. The document presented here therefore refers here to the descriptions of FIGS. 29 to 33 and the reference symbol list.

The upper housing part 40 of the housing 8 and the energy supply line 55 are cut and therefore only partially shown without the cut surfaces being visible in FIG. 34.

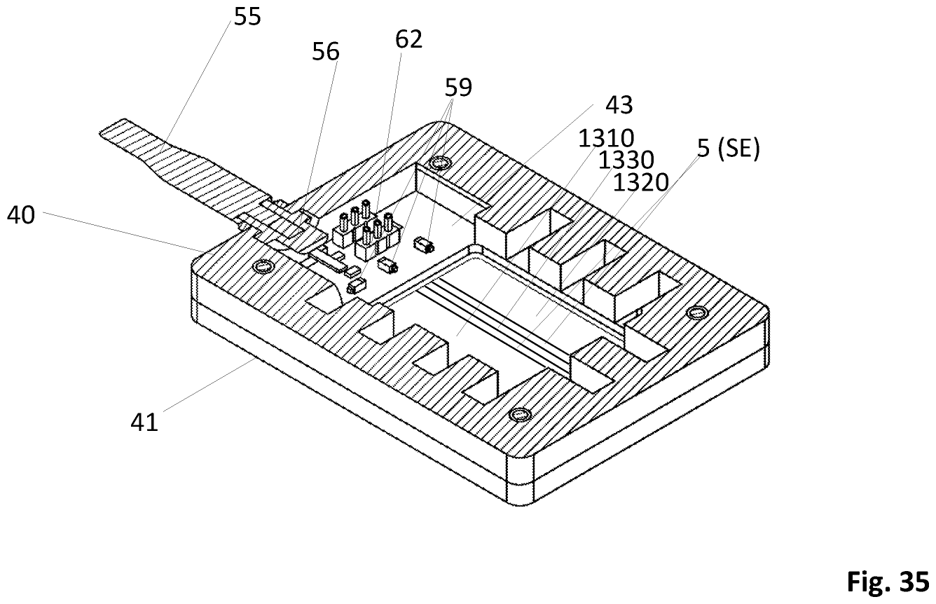

### FIG. 35

FIG. 35 corresponds to FIG. 34 with the difference that the cut part of the magnetic field camera head 21 shown in FIG. 34 is now shown with the cut surface facing upwards instead of downwards.

FIG. 35 essentially corresponds to FIGS. 29 to 35 in that FIG. 35 shows a side view with a horizontal section and a view from above. The document presented here therefore refers to the descriptions of FIGS. 29 to 34 and the list of reference symbols.

In the later field of view of the camera, there are lines 1320, 1310, 1330 of an exemplary trip-plate waveguide 1380 with a sensor element in the clearances 2340 and 2350. The use of other waveguides (1380, 1880, 2380, 6880, 6980) is conceivable. The use of a continuous sensor layer 5 without waveguides (1380, 1880, 2380, 6880, 6980) is also conceivable, in which case the use of microwave and/or RF excitation of the NV centers and/or paramagnetic centers of the sensor layer 5 is not possible. The waveguide (1380, 1880, 2380, 6880, 6980) can preferably be connected, for example, via a plug connection such as a coaxial socket or a triaxial socket 71.

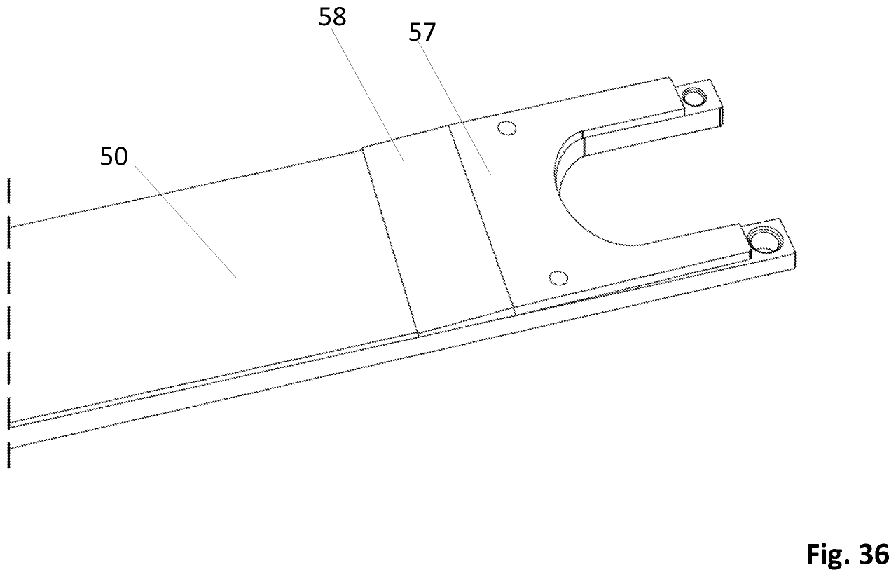

### FIG. 36

FIG. 36 shows the first heat sink 50 before insertion into the housing 8. In the example of FIGS. 29 to 36, the document presented here proposes to provide an elastic and thermally conductive material 57 and/or a thermally conductive insulation film 58 between the heat sink 50 and the housing 8, which ensure electrical insulation and/or reduce the occurrence of mechanical stresses when heated as a result of different thermal expansion coefficients.

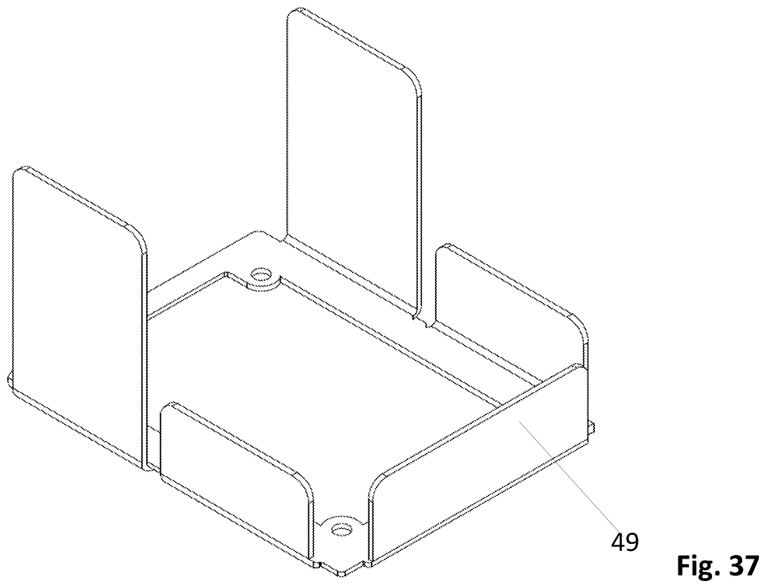

### FIG. 37

FIG. 37 shows an exemplary second heat sink 49 for cooling the printed circuit board (PCB) 43 for the LEDs 44 and their power supply 45 and the LEDs 44 before it is installed in a sensor head according to FIGS. 29 to 36. The second heat sink 49 preferably comprises copper as the heat sink material of the second heat sink 49 or another heat sink material with good thermal conductivity.

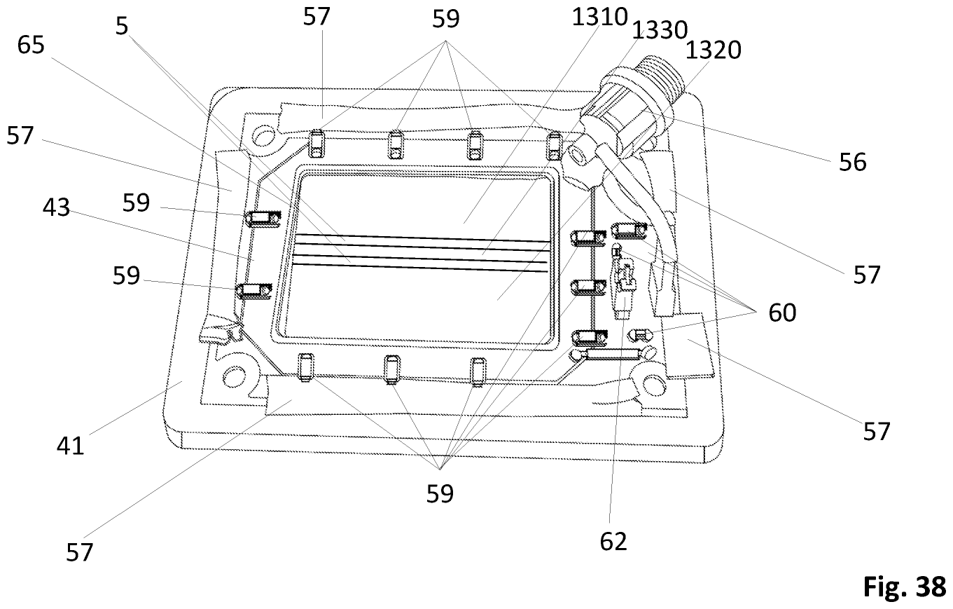

### FIG. 38

FIG. 38 shows the lower housing part 41 of the housing 8 of a magnetic field camera head 21 according to FIGS. 29 to 37 with the printed circuit board (PCB) 43 before installation in the housing 8. The printed circuit board (PCB) 43 is mounted with the LEDs 44 facing downwards on the lower housing part 41 of the housing 8. The LEDs 44 are therefore not visible. The LED series resistors 59 of the LEDs 44 are located on the visible upper side on the printed circuit board (PCB) 43 for the LEDs 44. For better clarity, it should be mentioned here that the reference sign 59 refers to the series resistors 59 of the LEDs 44 and not to the sensor layer 5. The sensor layer 5 is attached with its glass plate 46 to the printed circuit board (PCB) 43 for the LEDs 44. The printed circuit board (PCB) 43 for the LEDs 44 comprises an opening so that the fluorescence radiation 14 of the paramagnetic centers in the layer 11 on the underside of the glass plate 46 can pass through the glass plate 46 and the opening in the printed circuit board (PCB) 43 to the light sensor array 1.

By means of a jumper on the exemplary coding plug 62, the intensity of the pump radiation 13 of the LEDs 44 can be set, for example, by selecting voltage divider output values or the like.

A connector 56 for the power supply line 55 is used to supply power to the printed circuit board (PCB) 43 for the LEDs 44 and their power supply 45 and the LEDs 44.

Typically, further electronic components 60 are located on the upper side of the printed circuit board (PCB) 43 for the LEDs 44, for example for the power supply of the LEDs 44.

For example, a voltage regulator 61 can be located as such a further component 60 on the top side of the printed circuit board (PCB) 43 for the LEDs 44.

In the example of FIG. 38, elastic and thermally conductive materials 57 between the lower housing part 41 of the housing 8 and the upper housing part 40 of the housing 8 serve to reduce the occurrence of mechanical stresses when heated as a result of different thermal expansion coefficients and/or different thermal loads.

In the later field of view of the camera, there are lines 1320, 1310, 1330 of an exemplary trip-plate waveguide 1380 with a sensor element in the clearances 2340 and 2350. The use of other waveguides (1380, 1880, 2380, 6880, 6980) is conceivable. The use of a continuous sensor layer 5 without waveguides (1380, 1880, 2380, 6880, 6980) is also conceivable, in which case the use of microwave and/or RF excitation of the NV centers and/or paramagnetic centers of the sensor layer 5 is not possible. The waveguide (1380, 1880, 2380, 6880, 6980) can preferably be connected, for example, via a plug connection such as a coaxial socket or a triaxial socket 71.

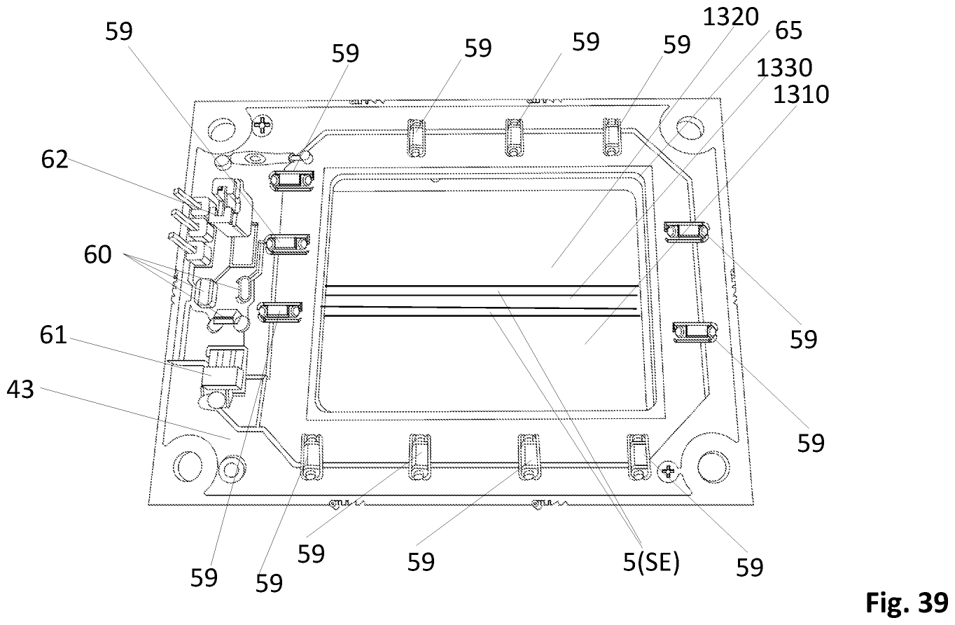

### FIG. 39

FIG. 39 shows the underside of the printed circuit board (PCB) 43 of a magnetic field camera head 21 according to FIGS. 29 to 38 with the series resistors 59 of the LEDs 44. The printed circuit board (PCB) 43 is intended for use in a magnetic field camera head 21 according to FIGS. 29 to 38. The opening 65 in the printed circuit board (PCB) 43 serves to allow the fluorescence radiation 14 of the paramagnetic centers, for example the NV centers, in the layer 11 of the sensor layer 5 on the underside of the glass plate 46 to pass through the glass plate 46 and the opening in the printed circuit board (PCB) 43 to the light sensor array 1. By means of a coding plug 62, the user can adjust the brightness of the LEDs 44 in the example of FIG. 39. Preferably, the user can adjust the output voltage of the voltage regulator 61 by means of the coding plug 62. Preferably, the voltage regulator 62 supplies the LEDs 44 via the series resistors 59 of the LEDs 44. The coding plug 62 thus preferably serves to change analog operating parameters of the electronic circuit on the printed circuit board (PCB) 43.

In the later field of view of the camera, there are lines 1320, 1310, 1330 of an exemplary trip-plate waveguide 1380 with a sensor element in the clearances 2340 and 2350. The use of other waveguides (1380, 1880, 2380, 6880, 6980) is conceivable. The use of a continuous sensor layer 5 without waveguides (1380, 1880, 2380, 6880, 6980) is also conceivable, in which case the use of microwave and/or RF excitation of the NV centers and/or paramagnetic centers of the sensor layer 5 is not possible. The waveguide (1380, 1880, 2380, 6880, 6980) can preferably be connected, for example, via a plug connection such as a coaxial socket or a triaxial socket 71.

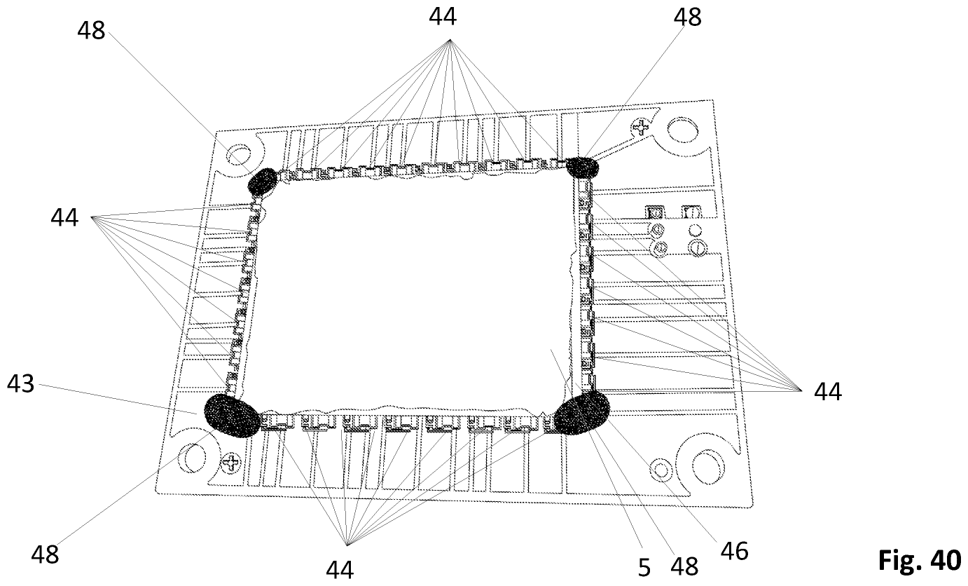

### FIG. 40

FIG. 40 shows the underside of the printed circuit board (PCB) 43 of a magnetic field camera head 21 according to FIGS. 29 to 39 with the LEDs 44. FIG. 40 shows the underside of the printed circuit board (PCB) 43 of the preceding FIG. 39. A glass plate 46 is attached to the printed circuit board (PCB) 43 by means of four adhesive dots with Adhesive 48. This glass plate 46 serves as an exemplary optical functional element. The LEDs 44 emit the pump radiation 13 with the pump radiation wavelength λₚₘₚ via the edges of the glass plate 46 into the material of the glass plate 46, which is transparent to electromagnetic radiation, in particular pump radiation 13, with the pump radiation wavelength λₚₘₚ. Typically, part of this pump radiation 13 emerges in the direction from that glass plate surface of the glass plate 46 that faces away from the light sensor array 1 and exposes the sensor layer 5, which comprises the layer 11 with the paramagnetic centers, for example NV centers, to pump radiation 13 of the pump radiation wavelength λₚₘₚ. This excites the paramagnetic centers in the layer 11 to emit magnetic field-dependent fluorescence radiation 14, which the light sensor array 1 can detect spatially resolved by means of the imaging optics 7 and capture as an image.

Unfortunately, the intensity distribution of the intensity of the pump radiation 13 emerging at a point on the surface of the glass plate 46 from this averted glass plate surface of the glass plate 46 is dependent on the inverse square distance of this point on the surface of the glass plate 46 from the LED 44 in question. This distance dependence can be compensated for by a diffuser structure in a diffuser layer 69 on this averted glass plate surface of the glass plate 46. Preferably, the glass plate 46 is thus provided with a diffuser structure in a diffuser layer 69 on the surface facing away from the light sensor array 1, which ensures homogeneous illumination of the layer 11 and thus of the paramagnetic centers contained in the layer 11 with pump radiation 13 by the LEDs 44.

This system comprising a glass plate 46, the LEDs 44 which emit pump radiation 13 from the edges of the glass plate 46 into the material of the glass plate 46, the diffuser layer 69 and the layer 11 with the paramagnetic centers is ultimately a flat surface illumination system, with: (a) a planar pump radiation source (44, 46) for pump radiation 13 having the pump radiation wavelength λₚₘₚ comprising a substrate and at least one essentially non-pixelated pump radiation 13 emitting region formed on the substrate (glass wafer 46) which emits pump radiation 13 from at least one pump radiation 13 emitting side of the planar pump radiation source in each direction (downwardly facing surface of the glass plate 46); and b) a pump radiation 13 directing optical layer—for example the glass plate 46—which is arranged on the at least one pump radiation 13 emitting side (edge of the glass plate 46) above the pump radiation 13 emitting region of a punctiform or planar pump radiation source (exemplary LEDs 44), wherein the optical layer directing the pump radiation 13—in particular the glass plate 46—preferably directs pump radiation 13 away from a direction which extends at right angles to the surface of the pump radiation 13 (light propagation layer of the pump radiation 13 in the glass plate 46) emitting side of the flat or point pump radiation source (46, 44).

In one embodiment of the flat surface illumination system, the optical layer (glass plate 46) directing the pump radiation 13 comprises a structured first surface (underside of the glass plate 46), which is arranged adjacent to the side of the punctiform or planar pump radiation source (LEDs 44) emitting the pump radiation 13.

In one embodiment of the flat surface illumination system, the optical layer (glass plate 46) directing the pump radiation 13 comprises a flat first surface which is arranged at right angles to the side of the point or flat pump radiation source (LEDs 44) emitting the pump radiation 13.

In one embodiment of the flat surface illumination system, the optical layer (glass plate 46) directing the pump radiation 13 comprises a flat first surface which is arranged opposite the side of the flat pump radiation source (LEDs 44) emitting the pump radiation 13.

In one embodiment of the flat surface illumination system, the structured first surface of the pump radiation 13 directing optical layer (glass plate 46) comprises triangular prisms or a diffuser layer 69 applied to the first surface of the pump radiation 13 directing optical layer (glass plate 46), for example as a diffuser.

In one embodiment of the flat surface illumination system, the structured surface comprises, for example, cylindrical lenses or other optical and/or micro-optical functional elements.

In one embodiment of the flat surface illumination system, the structured surface comprises a multiplicity of wedge-shaped structures comprising a long axis, the axes of the wedge-shaped structures preferably then being aligned in a common direction.

In one embodiment of the flat surface illumination system, a flat pump radiation source comprises OLEDs or VCSELs as LEDs 44.

In one embodiment of the flat surface illumination system, the optical layer (glass plate 46) directing the pump radiation 13 comprises a flat first surface which is arranged opposite the side of the point or planar pump radiation source (LEDs 44) emitting the pump radiation 13, wherein preferably the planar pump radiation sources (LEDs 44) comprise OLEDs or VCSELs as LEDs 44.

In one embodiment of the flat surface illumination system, the flat surface illumination system comprises, in a diffuser layer 69, a diffuser disposed between the pump radiation directing optical layer 13 and the flat pump radiation source.

In one embodiment of the flat surface illumination system, the surface illumination system comprises a second optical layer directing pump radiation 13, which is arranged above the optical layer directing pump radiation 13 and parallel to the optical layer directing pump radiation 13.

For example, in one embodiment of the flat surface illumination system, the pump radiation 13 directing optical layer is divided into a multiplicity of regions and pump radiation 13 directing structures in one region are oriented at an angle that is different from the angle of light directing structures in a second region.

Preferably, the layer 11 with the paramagnetic centers is located on the surface of the flat surface illumination system, for example on the surface of a diffuser layer 69 of a diffuser, which is preferably again located on a surface of said glass plate 46.

The flat surface illumination system thus preferably comprises:
pump radiation sources, here exemplified in the form of LEDs 44;
a layer transporting pump radiation 13, in this case the glass plate 46;
wherein the pump radiation sources feed a pump radiation 13 with the pump radiation wavelength λₚₘₚ into a layer transporting this pump radiation, here the glass plate 46, the pump radiation 13 from the side via an edge of the glass plate 46;
a diffuser layer 69, which is another optical layer directing pump radiation 13; and
the diffuser layer 69 being arranged on the at least one pump radiation 13 emitting side above the pump radiation 13 emitting region of the planar pump radiation source, wherein the optical layer directing the pump radiation 13 preferably directs pump radiation 13 away from a direction which preferably extends essentially at right angles to the surface of the pump radiation 13 emitting side of the point or planar pump radiation source (in particular the LEDs 44).

The diffuser layer 69 thus preferably directs the pump radiation 13 in the glass plate 46 onto the layer 11 preferably located on the diffuser layer 69 with the paramagnetic centers, which then emit fluorescence radiation 14. The diffuser layer 69 can also be achieved by matting and/or texturing the first surface 67 of the glass plate 46. The second surface 68 of the glass plate 46 may also comprise a diffuser layer 69. For example, by varying the roughness of the surface of the glass plate 46, it can be achieved that a locally different proportion of the pump radiation 13 in the glass plate 46 is coupled out of the glass plate 46 and into the layer 11. For example, the surface of the glass plate can be structured in such a way that at a greater distance from the pump radiation sources (LEDs 44), a greater proportion of the pump radiation 13 is coupled out of the glass plate 46 into the layer 11 with the paramagnetic centers. In this way, it can be achieved that with a homogeneous external magnetic field with a homogeneous magnetic flux density, the intensity of the fluorescence radiation 14 generated at points on the surface of the layer 11 essentially no longer depends on the distance from the pump radiation sources, in this case the LEDs 44.

the planar pump radiation source constructed in this way comprising LEDs 44 and glass plate 46 and optional diffusor layer 69 or diffusor surface structure of the glass plate 46 then exposes the paramagnetic centers of the layer 11 to pump radiation 13 with the pump radiation wavelength λₚₘₚ. The layer 11 preferably comprises crystals 66, particularly preferably micro or nano crystals 66, with these paramagnetic centers, which are preferably NV centers in diamond crystals. Preferably, the glass plate 46 forms the flat surface 16 of the lower housing part 41 of the housing 8. The glass plate 46 here also has the function of the substrate material II 12.

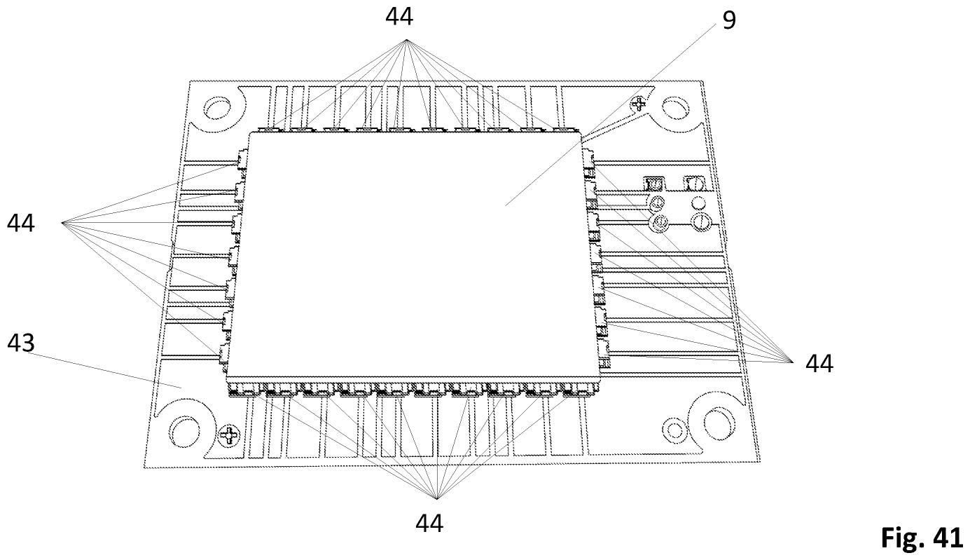

### FIG. 41

FIG. 41 shows the underside of the printed circuit board (PCB) 43 of the magnetic field camera head 21 as shown in FIGS. 29 to 40. FIG. 41 corresponds in particular to FIG. 40, whereby the layer 11 of the sensor layer 5 is now covered with a substrate material I 9 as a reflective layer 10.

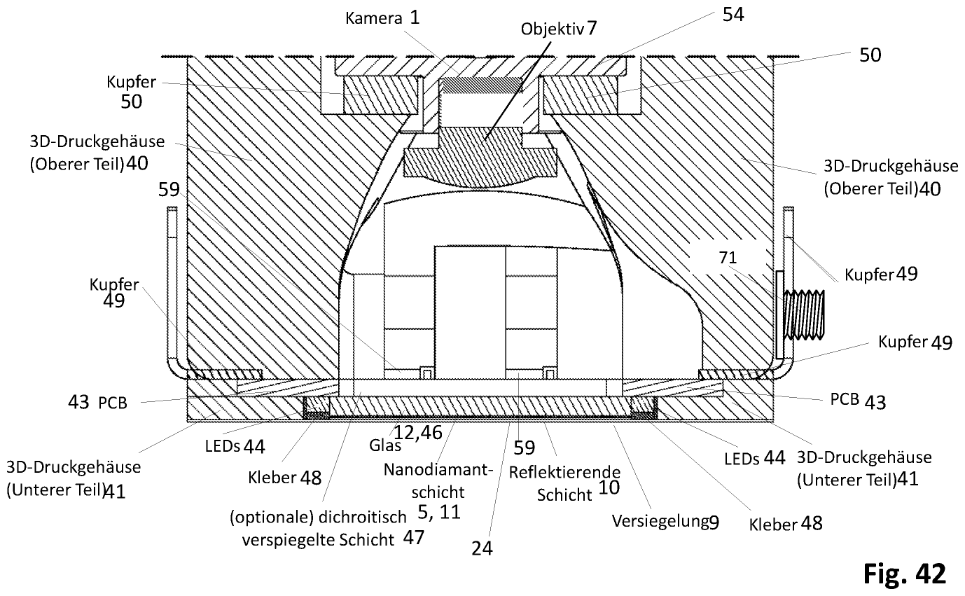

### FIG. 42

FIG. 42 shows a section through a magnetic field camera head 21 as shown in FIGS. 29 to 41. FIG. 42 corresponds largely to FIG. 32, although now only the sectional area is shown and the section is now led through the LEDs 44. In addition, the sensor head of FIG. 42 comprises the second heat sink 49 for cooling the printed circuit board (PCB) 43 of the magnetic field camera head 21 and for dissipating the waste heat from the LEDs 44. The upper part of the fluorescence camera with the evaluation electronics 15 is missing for better clarity. A person skilled in the art can take these details from FIG. 32, for example, and add them here, so that the upper part of the fluorescence camera in the figure, even if not explicitly drawn in, is nevertheless deemed to be disclosed.

FIG. 42 shows two adhesive dots with Adhesive 48, with which the printed circuit board (PCB) 43 of the magnetic field camera head 21 with the LEDs 44 and the other electronic components (59, 60, 61) is attached to the lower housing part 41 of the housing 8.

During operation, the LEDs 44 emit pump radiation 13 into the glass plate 46 in a horizontal direction. The glass plate 46 serves as a waveguide for the pump radiation 13 of the pump radiation sources, for example the LEDs 44, with pump radiation wavelength λₚₘₚ. The glass plate 46 distributes the pump radiation 13 from the LEDs 44 over a wide area. Part of the pump radiation 13 thus transported in the glass plate 46 emerges from the glass plate 46 in the vertical direction upwards and downwards.

The pump radiation 13 of the LEDs 44, which emerges downwards from the glass plate 46, strikes the sensor layer 5, in this case the layer 11 with the crystals and/or with the nano crystals 66 with paramagnetic centers. Preferably, the paramagnetic centers are NV centers. As a result of exposure to pump radiation 13 of the pump radiation wavelength λₚₘₚ, the paramagnetic centers of the layer 11 emit fluorescence radiation 14 of the fluorescence wavelength λ_{fl}. Typically, the pump radiation 13 of NV centers is green and the fluorescence radiation 14 is red.

A reflective layer 10 preferably reflects the pump radiation 13, which is transmitted by the layer 11 and not reflected and not absorbed, back in the direction of the light sensor array 1. The reflected pump radiation 13 passes the layer 11 with the paramagnetic centers a second time and causes the emission of fluorescence radiation 14 there a second time. This further increases the signal contrast of the local magnetic field-dependent intensity of the local fluorescence radiation 14.

The reflective layer 10 preferably also reflects the portion of the fluorescence radiation 14 that is emitted downwards from the layer 11 back towards the light sensor array 1, whereby the reflected fluorescence radiation 14 passes the layer 11 with the paramagnetic centers a second time.

The layer 11 thus emits a first portion of the fluorescence radiation 14 directly in the direction of the light sensor array 1 and transmits a second portion of the fluorescence radiation 14, which was reflected at the reflecting layer 10, at least partially typically also in the direction of the light sensor array 1. This thus also further enhances the signal contrast of the local magnetic field-dependent intensity of the local fluorescence radiation 14 of the paramagnetic centers of the layer 11.

In the example shown in FIG. 42, an optional dichroic reflecting layer 47 prevents the pump radiation 13 of the LEDs 44 with pump radiation wavelength λₚₘₚ from escaping from the glass plate 46 in the direction of the light sensor array 1, i.e. this optional dichroic reflecting layer 47 can assume the role of the optical filter (long pass) 6 and replace it.

In the example of FIG. 42, the optional dichroic reflecting layer 47 enables the transmission of the fluorescence radiation 14 of the paramagnetic centers of the layer 11 with fluorescence radiation wavelength λ_{FL} through the glass plate 46 in the direction of the light sensor array 1, i.e. this optional dichroic reflecting layer 47 can also assume the role of the optical filter (long pass) 6 here and replace it.

Therefore, the optional dichroic reflecting layer 47 is typically essentially non-transparent to electromagnetic radiation, for example pump radiation 13, with pump radiation wavelength λₚₘₚ and preferably essentially reflective.

Here, “essentially non-transparent” means that the intensity of the remaining transmitted electromagnetic radiation, for example pump radiation 13, with pump radiation wavelength λₚₘₚ is so low that the remaining transmitted electromagnetic radiation with pump radiation wavelength λₚₘₚ preferably does not impair the achievement of the intended purpose in the respective application.

Here, “essentially reflected” means that the intensity of the non-reflected electromagnetic radiation with pump radiation wavelength λₚₘₚ is so low that the remaining reflected electromagnetic radiation with pump radiation wavelength λₚₘₚ is preferably sufficient to achieve the intended purpose in the respective application.

In the example of FIG. 42, the combination of the LEDs 44 with the glass plate 46 forms an example of an areal pump radiation source for exposure of the paramagnetic centers of the crystals and/or nano crystals 66 of the layer 11 of the sensor layer 5 with pump radiation 13 of the pump radiation wavelength λₚₘₚ.

The present document thus discloses an areal pump radiation source comprising one or more primary pump radiation sources, here the LEDs 44, and an optical functional element, here the glass plate 46 for areal distribution of the pump radiation 13 of the primary pump radiation sources, here the LEDs 44.

In a preferred variant, this planar pump radiation source exposes a layer 11 with crystals and/or nano crystals 66 with paramagnetic centers, in this case the layer 11, to pump radiation 13 of the pump radiation wavelength λₚₘₚ.

In a further variant, this layer 11 then emits fluorescence radiation 14 with a fluorescence radiation wavelength λ_{(FL)}, which may vary locally depending on the value of the local absolute value of the magnetic flux density.

In a further variant, an optical functional element, for example the dichroic reflecting optional layer 47 and/or the optical filter (long pass) 6, separates the electromagnetic radiation with the pump radiation wavelength λₚₘₚ from the electromagnetic radiation with the fluorescence radiation wavelength λ_{fl}. In this further variant, the optical functional element, for example the dichroically reflecting optional layer 47 and/or the optical filter (long pass) 6, thus separates the pump radiation 13 with the pump radiation wavelength λₚₘₚ from the fluorescence radiation 14 with the fluorescence radiation wavelength λ_{fl}. This means that only electromagnetic radiation with the fluorescence radiation wavelength λ_{fl} or fluorescence radiation 14 with the fluorescence radiation wavelengthan can reach the light sensor array 1.

Preferably, the housing 8 of the magnetic field camera head 21 is designed to be light-tight for the same purpose.

The imaging optics 7 maps the locally different intensity of the fluorescence radiation 14 of the paramagnetic centers of the layer 11 onto the light sensor array 1.

By means of the evaluation electronics 15, which is not shown but is hereby expressly disclosed, and the light sensor array 1, the magnetic field camera head 21 thus detects the locally different intensity of the fluorescence radiation 14 of the paramagnetic centers of the layer 11 and thus the locally different values of the absolute value of the magnetic flux density in the layer 11 in the form of an image.

The first heat sink 50 cools the evaluation electronics 13 of the fluorescence camera and the light sensor array 1 of the fluorescence camera, thus increasing the signal-to-noise ratio of the light sensors of the light sensor array 1.

The second heat sink 49 cools the printed circuit board (PCB) 43 for the LEDs 44 and their power supply 45. In particular, the second heat sink 49 cools the LEDs 44, which emit considerable heat, and thus prevents the housing (8, 40, 41) from heating up and thus the light sensor array 1 from heating up. Also, and increases the signal-to-noise ratio of the light sensors of the light sensor array 1.

The magnetic field camera head 21 of FIG. 42 is thus largely a sensor head 21 as shown in FIGS. 29 to 41.

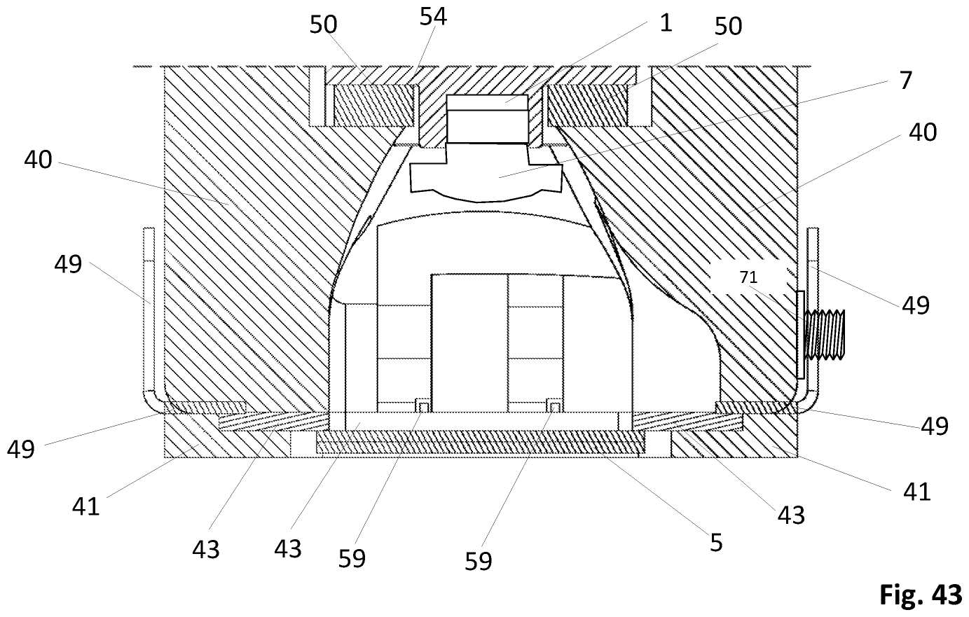

### FIG. 43

FIG. 43 shows a section through a magnetic field camera head 21 as shown in FIGS. 29 to 42. FIG. 43 corresponds as far as possible to FIG. 42, although the section does NOT pass through the LEDs 44. FIG. 42 also largely corresponds to FIG. 32, although now only the cut surface is shown. The magnetic field camera head 21 of FIG. 43 is thus largely a magnetic field camera head 21 corresponding to FIGS. 29 to 42.

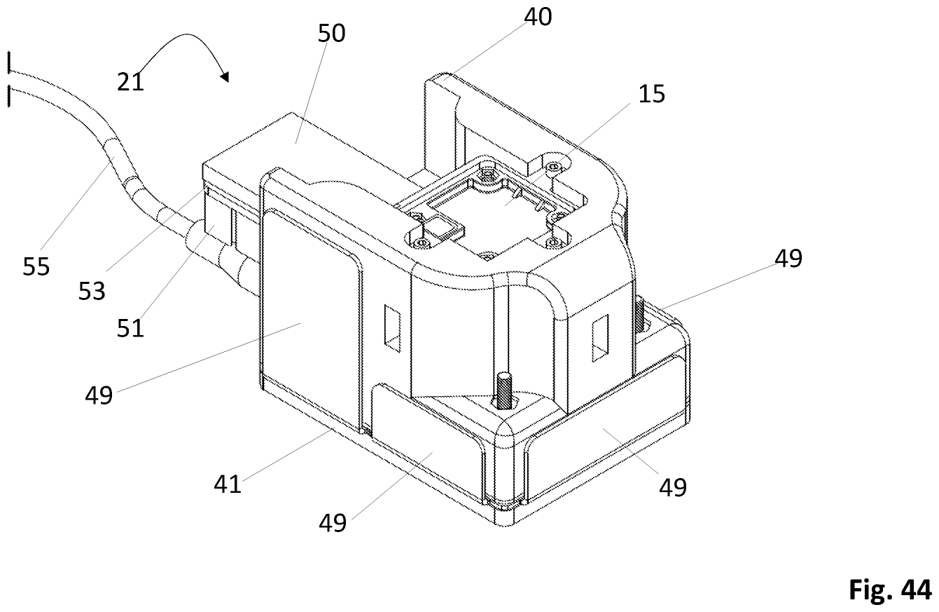

### FIG. 44

FIG. 44 largely corresponds to FIG. 23, whereby the magnetic field camera head 21 of FIG. 44 additionally comprises the second heat sink 49 compared to the magnetic field camera head 21 of FIG. 33. The magnetic field camera head 21 of FIG. 44 is thus largely a magnetic field camera head 21 corresponding to FIGS. 29 to 43.

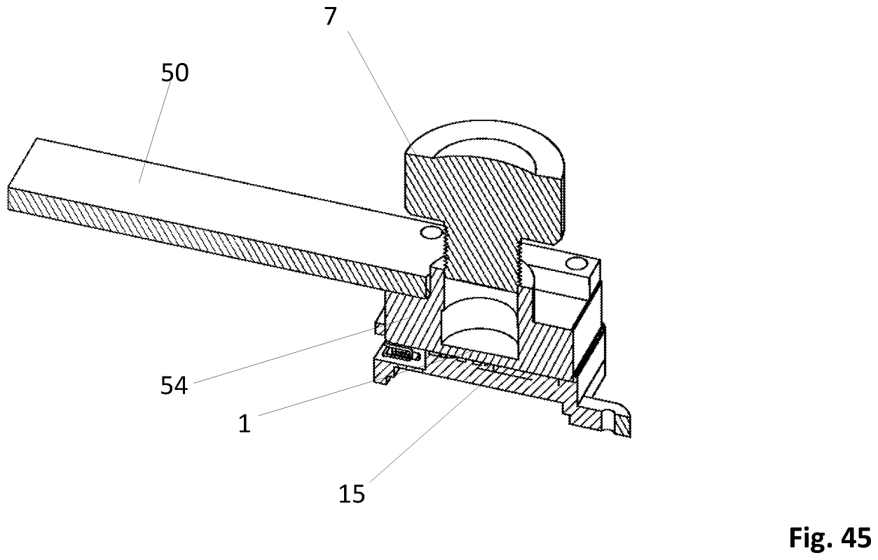

### FIG. 45

FIG. 45 shows the fluorescence camera of a magnetic field camera head 21 according to FIGS. 29 to 44 in conjunction with the first heat sink 50 as a sectional view. The fluorescence camera comprises here, for example, the evaluation electronics 15, the camera housing 54, the light sensor array 1 and the imaging optics 7. If necessary, the fluorescence camera can also comprise the optical filter (long pass) 6 in the beam path of the imaging optics 7 and the light sensor array 1.

The first heat sink 50 is preferably thermally connected to the evaluation electronics 15 and/or the light sensor array 1 with a low thermal resistance. Particularly preferably, the first heat sink 50 is thermally connected to the light sensor array 1 with a low thermal resistance. In this way, the first heat sink 50 improves the signal-to-noise ratio of the light sensor array 1.

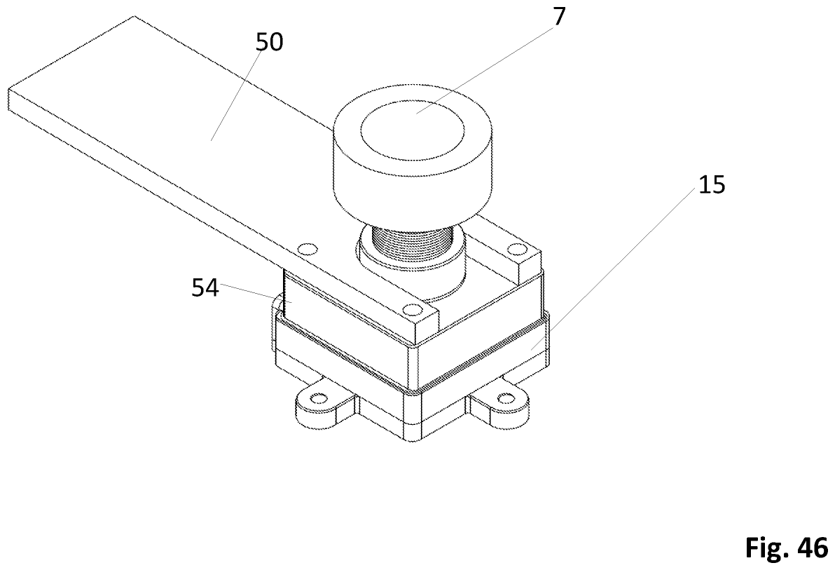

### FIG. 46

Like FIG. 45, FIG. 46 shows the fluorescence camera of a magnetic field camera head 21 according to FIGS. 29 to 45 in conjunction with the first heat sink 50, but now not as a sectional view.

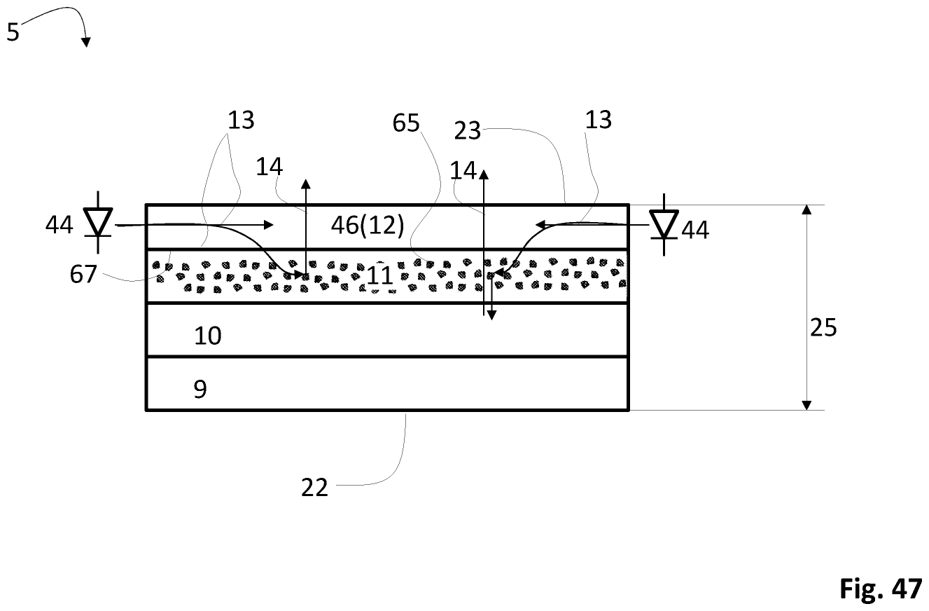

### FIG. 47

FIG. 47 shows the functional principle of the sensor layer 5 as used in the device parts of the sensor head of FIGS. 29 to 46 in FIGS. 30, 31, 32, 34, 35, 38, 39, 40, 41, 42 and 43. Here, the two light emitting diodes (LEDs) 44 form the primary pump radiation sources for generating the pump radiation 13 with the pump radiation wavelength λₚₘₚ. The primary pump radiation sources in the form of the LEDs 44 radiate the pump radiation 13 from the side into the flat first optical functional element in the form of a glass plate 46. The pump radiation 13 spreads from the feed point of the pump radiation 13 into the two-dimensional first optical functional element—in this case the glass plate 46—in a two-dimensional manner, whereby the intensity decreases continuously with the distance from the feed point of the pump radiation 13 into the two-dimensional first optical functional element—in this case the glass plate 46. Part of the pump radiation 13 leaves the first optical functional element (glass plate 46) in the direction of a first surface 67 and passes into the layer 11. The layer 11 preferably comprises a multiplicity of crystals and/or nano crystals 66, which preferably comprise paramagnetic centers. The crystals and nano crystals 66 are preferably embedded in a substrate material of the layer 11 that is transparent to electromagnetic radiation with the pump radiation wavelength λₚₘₚ. The crystals and nano crystals 66 are preferably embedded in a substrate material of the layer 11 that is transparent to electromagnetic radiation with the fluorescence radiation wavelength λf.

The crystals and nano crystals 66 are preferably embedded in a substrate material of the layer 11 that is transparent to pump radiation with the pump radiation wavelength λₚₘₚ. The crystals and nano crystals 66 are preferably embedded in a substrate material of the layer 11 that is transparent to fluorescence radiation with the fluorescence radiation wavelength λ_{fl}.

A portion of the pump radiation 13 in the layer 11 irradiates paramagnetic centers of crystals and nano crystals 66 in the layer 11. Due to the exposure to pump radiation 13 of the pump radiation wavelength λₚₘₚ, paramagnetic centers of crystals and nano crystals 66 in the layer 11 emit fluorescence radiation 14.

A reflective coating 10 reflects the part of the fluorescence radiation 14 that does not leave the layer 11 in the direction of the light sensor array 1, but in the opposite direction, back into the layer 11.

The reflective coating 10 reflects the part of the pump radiation 13 that does not leave the layer 11 in the direction of the light sensor array 1, but in the opposite direction, back into the layer 11.

In the example of FIG. 47, the reflective coating 10 is covered with an optional substrate material I 9. Typically, the substrate material I 9 is a partial device of the lower housing part 41 of the housing 8 of the magnetic field camera.

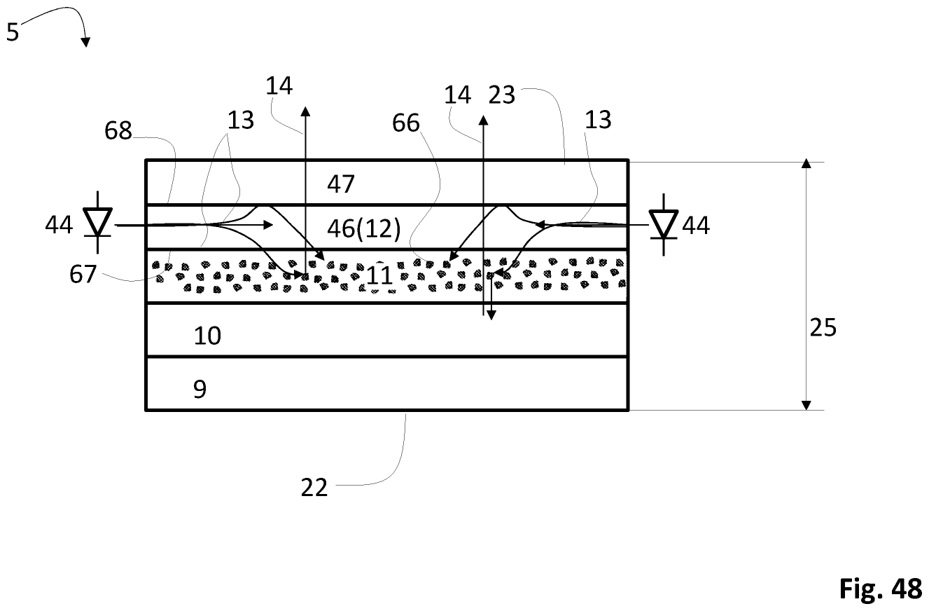

### FIG. 48

FIG. 48 shows in a schematically simplified manner the functional principle of the sensor layer 5 as it may be used in the device parts of the sensor head of FIGS. 29 to 46 in FIGS. 30, 31, 32, 34, 35, 38, 39, 40, 41, 42 and 43. Essentially, FIG. 48 corresponds to FIG. 47, wherein a dichroic reflecting layer 47 is applied to the second surface 68 of the first optical functional element (glass plate 46).

The optional dichroic reflecting layer 47 is preferably essentially transparent to electromagnetic radiation having the fluorescence radiation wavelength λ_{fl}.

The optional dichroic reflecting layer 47 is preferably essentially NOT transparent to electromagnetic radiation having the pump radiation wavelength λₚₘₚ.

The optional dichroic reflecting layer 47 is preferably essentially transparent to fluorescence radiation 14 having the fluorescence radiation wavelength λ_{fl}.

The optional dichroic reflecting layer 47 is preferably essentially NOT transparent to pump radiation 13 having the pump radiation wavelength pmp.

Preferably, the optional dichroic reflecting layer 47 reflects pump radiation 13 with the pump radiation wavelength λₚₘₚ, which emerges from the first optical functional element (glass plate 46) via the second surface 68 of the first optical functional element (glass plate 46), back into the first optical functional element (glass plate 46). As a result, the paramagnetic centers in the crystals and/or nano crystals 66 of the layer 11 are exposed to a maximum intensity of the pump radiation 13. This further improves the signal-to-noise ratio.

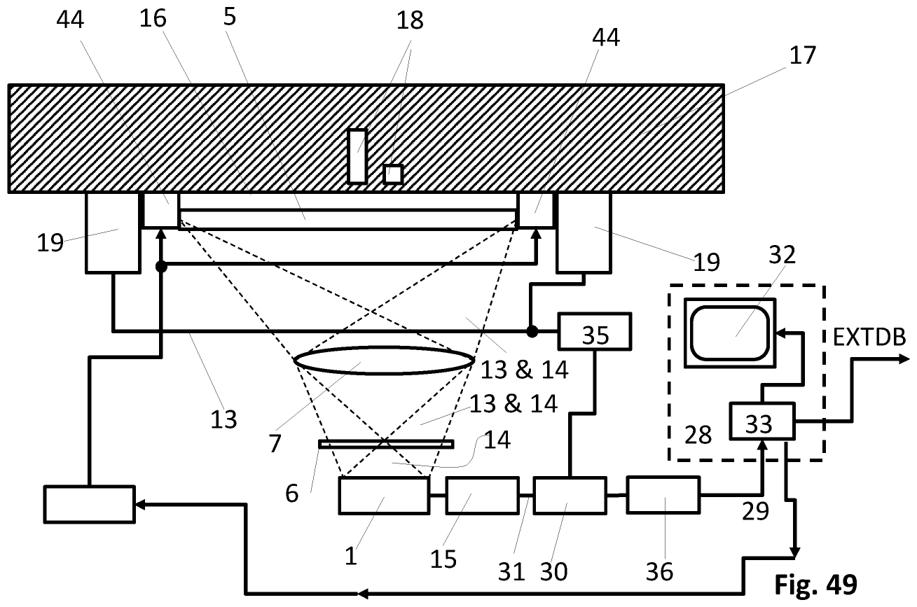

### FIG. 49

FIG. 49 shows the system of FIG. 7 with a magnetic field sensor head of FIGS. 29 to 48.

The LEDs 44 emit pump radiation 13 with a pump radiation wavelength λₚₘₚ. The sensor layer 5 preferably corresponds to the structure of FIG. 48. The sensor layer 5 is preferably applied to a mechanical carrier, for example a flat surface 16. Preferably, the flat surface 16 is part of the housing wall of the housing 8 not shown here. The material of this flat surface 16 or of the housing wall of the housing 8 in the region is preferably non-magnetic and preferably does not essentially influence the magnetic field. The sensor layer 5 preferably comprises a multiplicity of randomly and preferably uniformly oriented crystals and/or nano crystals 66 with paramagnetic centers. When diamond is used as the crystal material, the paramagnetic centers may be, for example, NV centers and/or SiV centers and/or TiV centers and/or GeV centers and/or SnV centers and/or NiN4 centers and/or PbV centers and/or ST1 centers. The pump radiation 13 preferably comprises a pump radiation wavelength λₚₘₚ in a wavelength range from 400 nm to 700 nm and/or preferably 450 nm to 650 nm and/or preferably 500 nm to 550 nm and/or preferably 515 nm to 540 nm when using NV centers in dimant as crystals and/or nano crystals 66 of the sensor layer 5. A wavelength of 532 nm is clearly preferred as the pump radiation wavelength λₚₘₚ. In the case of the use of NV centers in diamond or in diamonds of the sensor layer 5, a laser diode of the type PLT5 520B from Osram, for example, is suitable as LED 44 with 520 nm pump radiation wavelength λ₍ₚₘₚ₎. When using NV centers in diamond crystals in the sensor layer 5 as paramagnetic centers of the sensor layer 5, the NV centers of the sensor layer 5 typically emit fluorescence radiation 14 with a typical fluorescence wavelength n of approx. 637 nm for NV centers when exposed to pump radiation 13 of the pump radiation wavelength λₚₘₚ described above. An imaging optics 7 preferably detects the fluorescence picture of the position-dependent fluorescence intensity of the fluorescence radiation 14 with the fluorescence wavelength λ_{fl}, which the sensor layer 5 generates by means of the paramagnetic centers in the sensor layer 5. An optical long pass filter 6 and/or a dichroic reflecting optional layer 47 in the sensor layer 5 preferably allow electromagnetic radiation with the fluorescence wavelength λ_{fl} and thus the fluorescence radiation 14 to pass. The optical long pass filter 6 and/or a dichroically reflecting optional layer 47 in the sensor layer 5 preferably block the passage of electromagnetic radiation with the pump radiation wavelength λₚₘₚ and thus the passage of the pump radiation 13. As a result, the imaging optics 7 can detect the fluorescence picture of the sensor layer 5 in the wavelength range of the fluorescence wavelength λ_{fl} and image it onto the n×m light sensors of the n×m light sensor array 1 of the fluorescence camera. Since the intensity of the fluorescence radiation 14 of the sensor layer 5 locally in the sensor layer 5 depends on the magnetic flux density B at the location of the respective paramagnetic center in the sensor layer 5, the fluorescence picture of the sensor layer 5 corresponds to a magnetic flux density magnitude picture of the magnetic flux density field that flows through the sensor layer 5. Since the density distribution of the paramagnetic centers in the sensor layer 5 and/or the illumination of the sensor layer 5 with pump radiation 13 and/or the detecting of the fluorescence intensity of the fluorescence radiation 14 over the area of the sensor layer 5 are usually not completely homogeneous despite all efforts, it has proven useful to calibrate the system by means of calibration measurements before the first use. To process the measured values of the light sensors of the light sensor array 1, evaluation electronics 15 of the light sensor array 1 detect the measured values of the signals of the light sensors of the light sensor array 1 and form the output signals 31 of the light sensors of the light sensor array 1 from them, in particular by amplification and/or filtering. The conditioning circuit 30 for the output signals 31 of the light sensors of the light sensor array 1 preferably controls the auxiliary magnets 19 by means of a control device 35 for the electromagnets of the auxiliary magnets 19, if these do not comprise only permanent magnets. The processing circuit 30 for the output signals 31 of the light sensors of the light sensor array 1 generates, for example, a fluorescence picture and/or, for example, possibly also an improved fluorescence picture from the output signals 31 of the light sensors of the light sensor array 1, as described above. Due to the relationships described above, the fluorescence picture and/or, for example, possibly also the improved fluorescence picture represent a magnetic flux density magnitude picture of the magnetic flux density field in the sensor layer 5 or an improved magnetic flux density magnitude picture of the magnetic flux density field in the sensor layer 5. The processing circuit 30 for the output signals 31 of the light sensors of the light sensor array 1 preferably transfers this fluorescence picture or the improved fluorescence picture by means of the interface circuit 36 via a data bus 29 to a computer system 28 for operating the magnetic field camera head 21. Preferably, the computer system 28 for operating the sensor head 21 generates a one- or two- or three-dimensional representation of the distribution of the magnetic flux density in the sensor layer 5 from this fluorescence picture or from the improved fluorescence picture and displays it on the screen 32. The data bus 29 is used for fabrication of the data connection between the processing circuit 30 for the output signals 31 of the light sensors of the light sensor array 1 and the computer system 28 for operating the magnetic field camera head 21. The measurement object, here exemplarily a ferromagnetic material 17 with defects 18, generates the variations of the magnetic flux density B in the sensor layer 5, which lead to the said magnetic flux density magnitude images of the magnetic flux density field in the sensor layer 5 or the improved magnetic flux density magnitude images of the magnetic flux density field in the sensor layer 5.

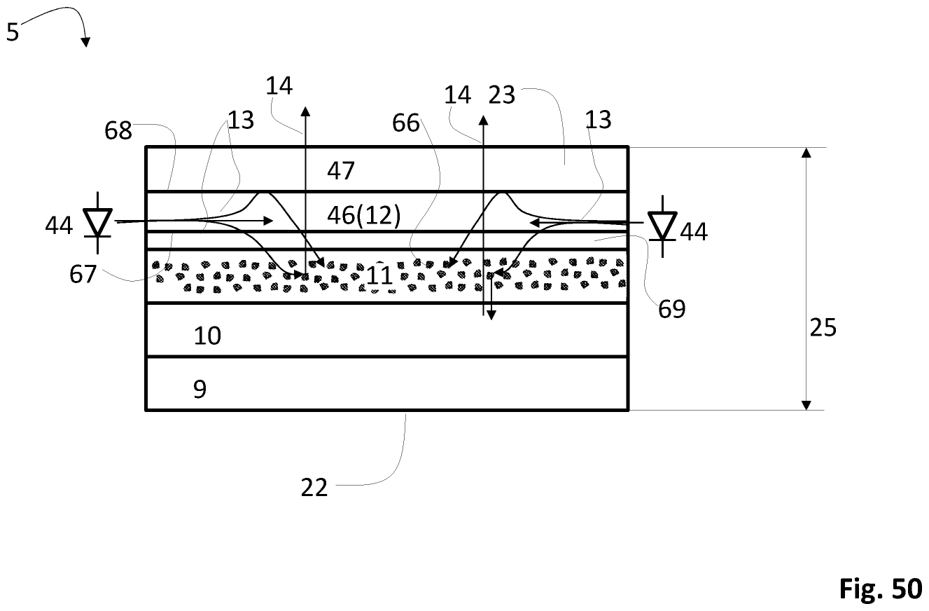

### FIG. 50

FIG. 50 corresponds as far as possible to FIG. 47, which shows the functional principle of the sensor layer 5 as used in the device parts of the sensor head of FIGS. 29 to 46 in FIGS. 30, 31, 32, 34, 35, 38, 39, 40, 41, 42 and 43. FIG. 50 differs from FIG. 47 by a diffuser layer 69.

Unfortunately, the intensity distribution of the intensity of the pump radiation 13 emerging at a point on the surface of the glass plate 46 from this averted glass plate surface of the glass plate 46 is dependent on the inverse square distance of this point on the surface of the glass plate 46 from the LED 44 in question. This distance dependence can be compensated for by a diffuser structure in a diffuser layer 69 on this averted glass plate surface of the glass plate 46. Preferably, the glass plate 46 is thus provided with a diffuser structure in a diffuser layer 69 on the surface facing away from the light sensor array 1, which ensures homogeneous illumination of the layer 11 and thus of the paramagnetic centers contained in the layer 11 with pump radiation 13 by the LEDs 44.

This system comprising a glass plate 46, the LEDs 44 which emit pump radiation 13 from the edges of the glass plate 46 into the material of the glass plate 46, the diffuser layer 69 and the layer 11 with the paramagnetic centers is ultimately a flat surface illumination system, with: (a) a planar pump radiation source (44, 46) for pump radiation 13 having the pump radiation wavelength λₚₘₚ comprising a substrate and at least one essentially non-pixelated pump radiation 13 emitting region formed on the substrate (glass wafer 46) which emits pump radiation 13 from at least one pump radiation 13 emitting side of the planar pump radiation source in each direction (downwardly facing surface of the glass plate 46); and b) a pump radiation 13 directing optical layer—for example the glass plate 46—which is arranged on the at least one pump radiation 13 emitting side (edge of the glass plate 46) above the pump radiation 13 emitting region of a punctiform or planar pump radiation source (exemplary LEDs 44), wherein the optical layer directing the pump radiation 13—in particular the glass plate 46—preferably directs pump radiation 13 away from a direction which extends at right angles to the surface of the pump radiation 13 (light propagation layer of the pump radiation 13 in the glass plate 46) emitting side of the flat or point pump radiation source (46, 44).

In one embodiment of the flat surface illumination system, the optical layer (glass plate 46) directing the pump radiation 13 comprises a structured first surface (underside of the glass plate 46), which is arranged adjacent to the side of the punctiform or planar pump radiation source (LEDs 44) emitting the pump radiation 13.

In one embodiment of the flat surface illumination system, the optical layer (glass plate 46) directing the pump radiation 13 comprises a flat first surface which is arranged at right angles to the side of the point or flat pump radiation source (LEDs 44) emitting the pump radiation 13.

In one embodiment of the flat surface illumination system, the optical layer (glass plate 46) directing the pump radiation 13 comprises a flat first surface which is arranged opposite the side of the flat pump radiation source (LEDs 44) emitting the pump radiation 13.

In one embodiment of the flat surface illumination system, the structured first surface of the pump radiation directing optical layer 13 (glass plate 46) comprises triangular prisms or a diffuser layer 69 applied to the first surface of the pump radiation directing optical layer 13 (glass plate 46), for example as a diffuser.

In one embodiment of the flat surface illumination system, the structured surface comprises, for example, cylindrical lenses or other optical and/or micro-optical functional elements.

In one embodiment of the flat surface illumination system, the structured surface comprises a multiplicity of wedge-shaped structures comprising a long axis, the axes of the wedge-shaped structures preferably then being aligned in a common direction.

In one embodiment of the flat surface illumination system, a flat pump radiation source comprises OLEDs or VCSELs as LEDs 44.

In one embodiment of the flat surface illumination system, the optical layer (glass plate 46) directing the pump radiation 13 comprises a flat first surface which is arranged opposite the side of the point or flat pump radiation source (LEDs 44) emitting the pump radiation 13, wherein preferably the flat pump radiation sources (LEDs 44) comprise OLEDs or VCSELs as LEDs 44.

In one embodiment of the flat surface illumination system, the flat surface illumination system comprises, in a diffuser layer 69, a diffuser disposed between the pump radiation directing optical layer 13 and the flat pump radiation source.

In one embodiment of the flat surface illumination system, the surface illumination system comprises a second optical layer directing pump radiation 13, which is arranged above the optical layer directing pump radiation 13 and parallel to the optical layer directing pump radiation 13.

For example, in one embodiment of the flat surface illumination system, the pump radiation 13 directing optical layer is divided into a multiplicity of regions and pump radiation 13 directing structures in one region are oriented at an angle that is different from the angle of light directing structures in a second region.

Preferably, the layer 11 with the paramagnetic centers is located on the surface of the flat surface illumination system, for example on the surface of a diffuser layer 69 of a diffuser, which is preferably again located on a surface of said glass plate 46.

The flat surface illumination system thus preferably comprises:
Pump radiation sources, here exemplified in the form of LEDs 44; and
a layer transporting pump radiation 13, in this case the glass plate 46,
wherein the pump radiation sources feed a pump radiation 13 with the pump radiation wavelength λₚₘₚ into a layer transporting this pump radiation, here the glass plate 46, the pump radiation 13 from the side via an edge of the glass plate 46;
a diffuser layer 69, which is another optical layer directing pump radiation 13; and
the diffuser layer 69 being arranged on the at least one pump radiation 13 emitting side above the pump radiation 13 emitting region of the planar pump radiation source, wherein the optical layer directing the pump radiation 13 preferably directs pump radiation 13 away from a direction which preferably extends essentially at right angles to the surface of the pump radiation 13 emitting side of the point or planar pump radiation source (in particular the LEDs 44).

The diffuser layer 69 thus preferably directs the pump radiation 13 in the glass plate 46 onto the layer 11 preferably located on the diffuser layer 69 with the paramagnetic centers, which then emit fluorescence radiation 14. The diffuser layer 69 can also be achieved by matting and/or texturing the first surface 67 of the glass plate 46. The second surface 68 of the glass plate 46 may also comprise a diffuser layer 69. For example, by varying the roughness of the surface of the glass plate 46, it can be achieved that a locally different proportion of the pump radiation 13 in the glass plate 46 is coupled out of the glass plate 46 and into the layer 11. For example, the surface of the glass plate can be structured in such a way that at a greater distance from the pump radiation sources (LEDs 44), a greater proportion of the pump radiation 13 is coupled out of the glass plate 46 into the layer 11 with the paramagnetic centers. In this way, it can be achieved that with a homogeneous external magnetic field with a homogeneous magnetic flux density, the intensity of the fluorescence radiation 14 generated at points on the surface of the layer 11 essentially no longer depends on the distance to the pump radiation sources, in this case the LEDs 44.

The planar pump radiation source constructed in this way comprising LEDs 44 and glass plate 46 and optional diffusor layer 69 or diffusor surface structure of the glass plate 46 then exposes the paramagnetic centers of the layer 11 to pump radiation 13 with the pump radiation wavelength λₚₘₚ. The layer 11 preferably comprises crystals 66, particularly preferably micro or nano crystals 66, with these paramagnetic centers, which are preferably NV centers in diamond crystals. Preferably, the glass plate 46 forms the flat surface 16 of the lower housing part 41 of the housing 8. The glass plate 46 here also has the function of the substrate material II 12.

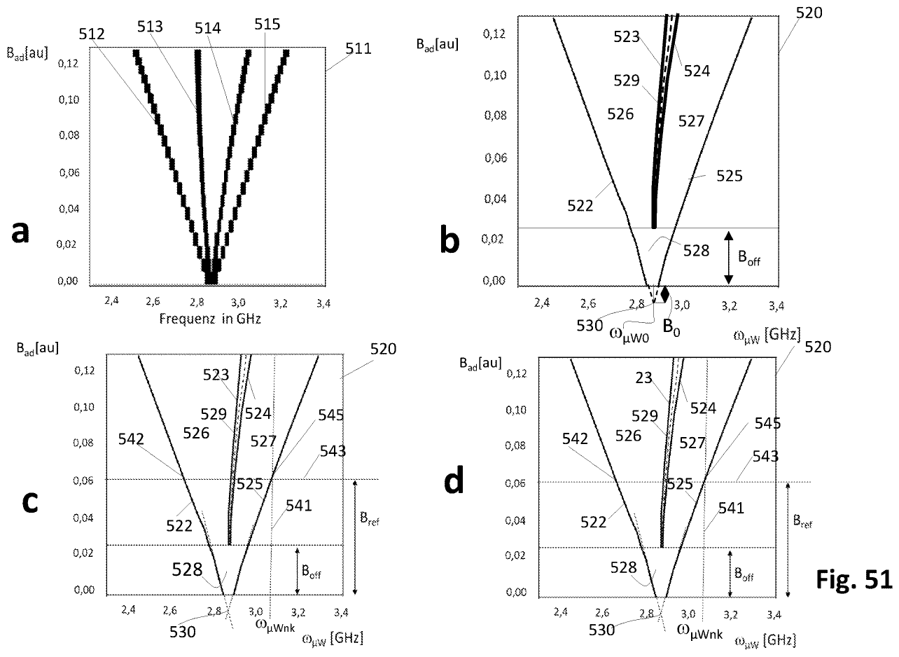

### FIG. 51

FIG. 51a shows the resonances of a diamond single crystal comprising NV centers. FIG. 51a shows in diagram 501 the resonance lines of the proportion of the intensity Iᵢₛₜ(t) of the fluorescence radiation FL of a diamond single crystal provided with NV centers, in which the proportion of the relative intensity signal of the intensity Iᵢₛₜ(t) of the fluorescence radiation FL, which comprises the microwave modulation frequency f_{μW}, is shown as a function of the microwave frequency ω_{μW} and of the magnetic flux density B. The microwave frequency ω_{μW} is plotted on the x-axis of the diagram 501. The magnetic flux density B is plotted on the Y-axis of the diagram 501 in arbitrary units (abbreviated to “au”). In the example, a single diamond crystal in [111] is oriented with respect to the direction of the magnetic flux density B of a magnetic field. The behavior shown in diagram 501 is known from the prior art.

The X-axis shows the microwave frequency ω_{μW} of the microwave signal μW in the region from 2.4 GHz to 3.4 GHz. In the Y-axis, the magnetic flux density B is plotted in arbitrary units. The intensity of the resonance is represented by the blackening of the corresponding area segment of the diagram 501 of FIG. 51a.

To record the values on which the diagram 501 of FIG. 51a is based, a microwave signal source μWG exposes the diamond single crystal to microwave radiation of the microwave frequency ω_{μW} between 2.4 GHz and 3.4 GHz. At the same time, a light source LED exposes the diamond single crystal to pump radiation LB of a pump radiation wavelength λₚₘₚ. Preferably, an optical waveguide LWL) transports the pump radiation LB from the light source LED to the diamond single crystal with the NV centers. As a result of the exposure to pump radiation LB, the diamond single crystal emits fluorescence radiation FL with an intensity Iᵢₛₜ(t). A light-sensitive component, called photo detector PD in the following, detects this fluorescence radiation FL and generates a received signal S0. The permanent magnet axis of symmetry AWV, which will be further explained later, processes the received signal S0 and thus generates a measured value of the intensity component in the fluorescence radiation FL, the modulation frequency of which corresponds to the microwave modulation frequency f_{μW} of the microwave signal μW of the microwave signal source μWG. The evaluation device preferably comprises a first amplifier V1 and a multiple correlator LIV, which will be explained later. Thus, preferably 100% amplitude modulation of the microwave signal μW is performed by the microwave signal source μWG corresponding to a microwave modulation signal S5m. A second signal generator G2 generates this microwave modulation signal S5m. Preferably, the microwave modulation signal S5m is a PWM modulation signal with a duty cycle of preferably 50%. The permanent magnet axis of symmetry AWV preferably correlates the intensity signal of the intensity Iᵢₛₜ(t) of the fluorescence radiation FL in the received signal S0 with the microwave modulation signal S5m. In doing so, the permanent magnet axis of symmetry AWV determines a value for the strength of the resonance. The document presented here calls this value the resonance value in the following. The NV centers of the diamond single crystal emit fluorescence radiation FL with an intensity Iᵢₛₜ(t) when the microwave frequency ω_{μW} of the microwave signal μW is not in resonance with the NV centers of the diamond single crystal. The dark fields in the diagram 501 of FIG. 51a thus reflect combinations of strengths of the magnetic flux density B and the microwave frequency ω_{μW} of the microwave signal μW, in which the intensity of the fluorescence radiation FL emitted by the NV centers of the diamond single crystal is reduced. When the microwave frequency ω_{μW} of the microwave signal μW resonates with the resonance frequency of the NV centers of the diamond single crystal, a signal component comprising the microwave modulation frequency f_{μW} of the microwave radiation μW of the microwave signal source μWG appears in the intensity signal of the received signal S0. This component is missing if there is no resonance of the microwave modulation frequency f_{μW} of the microwave radiation μW of the microwave signal source μWG with the resonance frequency of the NV centers of the diamond single crystal. The NV center comprises an axis in the diamond single crystal. The document presented here refers to this axis as the NV axis in the following. The left resonance line 502 for the spin quantum number mₛ=−1 and the rightmost resonance line 505 for the spin quantum number mₛ=+1 mean that the vector of the magnetic flux density B is aligned in the direction of the NV axis [111].

The resonance line 502 stands for a spin quantum number mₛ=−1. The resonance line 505 stands for a spin quantum number mₛ=+1. The resonance lines 3 and 4 originate from the superposition of the other three possible orientations of the NV axes of NV centers of the diamond single crystal. These other three possible orientations of the NV axes are also perpendicular to the vector of the magnetic flux density B. The effective B field of the microwave radiation of the microwave signal μW of the microwave signal source μWG must always be perpendicular to the NV axis of the respective NV center in order to be effective. If this is not the case, only the portion of the B field of the microwave radiation of the microwave signal μW of the microwave signal source μWG that is perpendicular to the NV axis of the respective NV center for effectiveness influences the intensity Iᵢₛₜ(t) of the fluorescence radiation FL of the respective NV center.

Thus, for these other three possible orientations of the NV axes, the effective magnetic flux density B is smaller than for the resonance lines 502 and 505. For a measurement to generate the diagram 501 according to FIG. 51a, the crystal preferably rests with the surface with normal vector [111] on the line that transports the microwave modulation signal S5m from the microwave signal source μWG to the diamond single crystal. The normal vector [111] is the vector perpendicular to the surface of the diamond crystal in question, which is parallel to the NV axis of at least some of the NV centers.

The following finding goes beyond the state of the art:

This method can also be used to analyze an unknown microwave signal S_{ω (nk)}. For this purpose, a device can introduce a single-crystal diamond platelet with NV centers into a magnetic field with a gradient of magnetic flux density B. Preferably, the device then comprises a mixer. This mixer mixes the unknown microwave signal with a carrier signal. Preferably, the carrier signal is the microwave signal μW of the microwave signal source μWG. The device in question then preferably feeds the microwave signal mixed in this way to the NV centers via a trip-plate waveguide 1330. The NV centers, which are in resonance, then exhibit the modulation corresponding to the microwave modulation signal S5m of the microwave signal source μWG which then generates the carrier signal modulated with the microwave modulation signal S5m before mixing by the mixer of the device. The device can then use the resulting resonance lines (502, 503, 504, 505) to determine the unknown microwave frequency of the unknown microwave signal.

### FIG. 51b

FIG. 51b shows the transition from FIG. 51a to FIG. 51b. This corresponds to a transition from a monocrystalline to a multicrystalline fluorescent substrate. In FIG. 51b, the light source LED exposes a multiplicity of diamond nano crystals ND. Instead of the diamond nano crystals ND, it can also be a multiplicity of other diamond crystals with NV centers and/or a multiplicity of crystals with paramagnetic centers of comparable properties. In this respect, the diamond nano crystals ND are only exemplary here. A person skilled in the art can easily arrive at the corresponding technical teaching by replacing the term diamond nano crystals ND with the term diamonds. The term diamond nano crystals ND thus denotes the optimum embodiment according to current knowledge, but expressly comprises less optimum embodiments such as diamonds per se also within the meaning of the technical teaching of the document presented here. In the example of FIG. 51b, the diamond nano crystals ND comprise a different orientation in space. Due to the statistically equally distributed different orientation of the diamond nano crystals ND, the diamond nano crystals ND do not show the resonance pattern of FIG. 51a. The same applies when using other suitable small crystals with suitable functionally equivalent paramagnetic centers that are stochastically uniformly distributed and oriented differently in space. The resonance lines (502, 503, 504, 505) of FIG. 51 are widened by the number of diamond nano crystals ND and their equally distributed stochastic orientation in space. Preferably, the diamond nano crystals ND are present as diamond powder or crystal powder. Preferably, at least some of the diamonds are HDNV diamonds according to the prior art. In this regard, the document presented here refers, for example, to DE 10 2021 132 148 A1.

FIG. 51b shows the resonances of a multiplicity of diamonds comprising different NV centers oriented in space. FIG. 51b shows in diagram 2 the resonances of the proportion of the intensity Iᵢₛₜ(t) of the fluorescence radiation FL of the multiplicity of diamonds provided with NV centers, in which the proportion of the intensity signal of the fluorescence radiation FL comprising the microwave modulation frequency f_{μW} is shown as a function of the microwave frequency ω_{μW} and of the magnetic flux density B. The microwave frequency ω_{μW} is plotted on the x-axis of the diagram 501. The magnetic flux density B is plotted on the Y-axis of the diagram 520 in arbitrary units (abbreviated to “au”). In the example, a multiplicity of diamond crystals oriented differently in space are oriented differently and typically equally distributed with respect to the direction of the magnetic flux density B of a magnetic field.

Due to the stochastically uniformly distributed orientation of the diamond nano crystals ND, the resonance lines (502, 503, 504, 505) of the diagram 501 of FIG. 51a are widened. Instead of resonance lines (502, 503, 504, 505), the diagram 520 of FIG. 51b now comprises resonance sub-fields (526, 527, 528).

A first resonance sub-field is the lower resonance field 528. If the effective magnetic flux density B of the magnetic field exceeds a limit value B_{off} of the absolute value of the effective magnetic flux density B of the magnetic field, the lower resonance field 528 splits into a lower resonance sub-field 522 and an upper resonance sub-field 525. Between the lower resonance sub-field 522 and the upper resonance sub-field 525, a middle resonance minimum 529 is formed at an absolute value of the effective magnetic flux density B above the limit value Boff of the absolute value of the effective magnetic flux density B of the magnetic field.

The lower resonance edge 522 limits the lower resonance field 528 to lower microwave frequencies and to lower magnetic flux densities B. The upper resonance edge 25 limits the lower resonance sub-field 528 towards higher microwave frequencies ω_{μW} and towards smaller effective magnetic flux densities B. An effective offset flux density Boff limits the lower resonant field 528 towards higher effective magnetic flux densities B. The middle resonance minimum 529 does not divide the lower resonant field 528.

A second resonance sub-field is the lower resonance sub-field 526. The lower resonance edge 522 limits the lower resonance sub-field 526 to lower microwave frequencies ω_{μW} and to lower effective magnetic flux densities B. The lower middle resonance edge 523 limits the lower resonance sub-field 526 to higher microwave frequencies ω_{μW} and to lower effective magnetic flux densities B. An offset flux density B_{off} further limits the lower resonance sub-field 526 towards lower effective magnetic flux densities B.

A third resonance sub-field is the upper resonance sub-field 527. The upper resonance edge 525 limits the upper resonance sub-field 527 to lower microwave frequencies ω_{μW} and to higher effective magnetic flux densities B. The upper middle resonance edge 524 limits the upper resonance sub-field 527 to higher microwave frequencies ω_{μW} and to higher effective magnetic flux densities B. An effective offset flux density Boff further limits the upper resonance sub-field 527 towards lower effective magnetic flux densities B.

A portion of the diamond nano crystals ND comprising the same orientation as the diamond single crystal of FIG. 51a generates the lower resonance edge 522. These diamond nano crystals ND have a resonance line 502 for the spin quantum number mₛ=−1. These diamond nano crystals ND are oriented in the [111] direction with respect to the effective magnetic flux density B of the magnetic field. The NV centers of this part of the diamond nano crystals ND interacting at this resonance line are aligned in the [111] direction of the respective diamond nano crystal ND. The B component of the microwave field of the microwave signal μW is oriented perpendicularly with respect to the effective magnetic flux density B of the magnetic field. The lower resonance edge 522 thus corresponds to the spin quantum number mₛ=−1;

A portion of the diamond nano crystals ND comprising the same orientation as the diamond single crystal of FIG. 51a generates the upper resonance edge 525. These diamond nano crystals ND have a resonance line 505 for the spin quantum number mₛ=+1. These diamond nano crystals ND are oriented in the [111] direction with respect to the effective magnetic flux density B of the magnetic field. The NV centers of this part of the diamond nano crystals ND interacting at this resonance line are aligned in the [111] direction of the respective diamond nano crystal ND. The B component of the microwave field of the microwave signal μW is oriented perpendicularly with respect to the effective magnetic flux density B of the magnetic field. The upper resonance edge 525 thus corresponds to the spin quantum number mₛ=+1;

Surprisingly, the middle resonance minimum 529 does not share a distance parallel to the x-axis in the diagram 20 between the lower resonance edge 522 and the upper resonance edge 525 at a ratio of 50:50 above the effective offset flux density Boff everywhere. At the effective offset flux density Boff, the middle resonance minimum 529 still divides a distance parallel to the x-axis in the diagram 520 between the lower resonance edge 522 and the upper resonance edge 525 in a ratio of 50:50. However, the line of the middle resonance minimum 529 then swings non-linearly to the right. This means that the ratio of the distances can be used as a measure of the magnetic flux density B.

### FIG. 51c

FIG. 51c explains the determination of an unknown effective magnetic flux density Bₙₖ on the basis of FIG. 51b by means of a variation of the microwave frequency ω_{(μw) in} the region of interest and by means of a simultaneous determination of that portion of the fluorescence radiation FL intensity signal of the multiplicity of diamond nano crystals ND provided with NV centers, in which this proportion of the intensity signal of the fluorescence radiation FL comprises the microwave modulation frequency f_{μW}, as a function of this microwave frequency ω_{μW} in the region of interest. The diagram 520 of FIG. 51c corresponds to that of FIG. 51b, whereby now distinctive points in the diagram 520 are additionally marked by means of reference lines and reference signs for better clarity.

The unknown effective flux density Bₙₖ is the part of the unknown total flux density BE, the vectorial part of which is perpendicular to the magnetic B field components of the microwave field of the microwave signal μW of the microwave signal source μWG. As will be explained in more detail below, this portion depends significantly on the positioning of the sensor element SE, which preferably comprises the multiplicity of diamond nano crystals ND and typically in substrate material TM, relative to the signal conductor 1330 and to the non-conductive left insulation gap 1440 and the non-conductive right insulation gap 1450 of the exemplary triplate line 1480. When the sensor element SE is positioned in the non-conductive left insulation gap 1440 and/or in the non-conductive right insulation gap 1450, the unknown effective flux density Bₙₖ corresponds to the portion of the unknown flux density B that is parallel to the plane of the carrier substrate 1360 of the exemplary triplate line 1480. When the sensor element SE is positioned on and/or below the signal conductor 1330 of the exemplary triplate line 1480, the unknown effective flux density Bₙₖ corresponds to the portion of the unknown flux density B that is in the direction of the waveguide 2380 or perpendicular to the plane of the carrier substrate 1360 of the exemplary triplate line 1480. Insofar as the sensor element SE comprises both a positioning of the sensor element SE in the non-conductive left insulation gap 1440 and/or in the non-conductive right insulation gap 1450 and a positioning of the sensor element SE on and/or below the signal conductor 1330 of the exemplary triplate line 1480 at least partially, it generally exhibits a mixture of these sensitivities. This may be intentional under certain circumstances.

The present document proposes that the proposed device for determining the unknown effective magnetic flux density Bₙₖ scans the microwave frequency ω_{μW} in the region of interest and determines, for a plurality of measurement points with different microwave frequency ω_{μW}, a respective measured value for the portion of the intensity signal of the fluorescence radiation FL of the multiplicity of diamond nano crystals ND provided with NV centers, in which the proportion of the intensity signal of the fluorescence radiation FL comprises the microwave modulation frequency f_{μW}.

From these associated measured values for the proportion of the intensity Iᵢₛₜ(t) of the fluorescence radiation FL of the multiplicity of diamond nano crystals ND provided with NV centers, the device according to the proposal can then determine the lower microwave frequency ω_{μW22} of the lower resonance edge 522. Preferably, a first calibration table and/or the first parameters of a first calibration function are stored in a memory (RAM, ROM, flash) (RAM, NVM) of the device, with the aid of which the device can determine the value of the absolute value of the lower effective magnetic flux density B₂₂ from the determined value of the lower microwave frequency ω_{(μW)(22)}.

The device according to the proposal can also determine the upper microwave frequency ω_{μW25} of the upper resonance edge 525 from the associated measured values for the proportion of the intensity Iᵢₛₜ(t) of the fluorescence radiation FL of the multiplicity of diamond nano crystals ND provided with NV centers. Preferably, a second calibration table and/or the second parameters of a second calibration function are stored in a memory (RAM, ROM, flash) (RAM, NVM) of the device, with the aid of which the device can determine the value of the absolute value of the upper effective magnetic flux density B₂₅ from the determined value of the upper microwave frequency ω_{μW25}.

From the associated measured values for the proportion of the intensity of the fluorescence radiation FL of the multiplicity of diamond nano crystals ND provided with NV centers, the device according to the proposal can also determine the presence of the middle resonance minimum 529 and determine the resonance minimum microwave frequency ω_{μW29} of the middle resonance minimum 529. Preferably, a third calibration table and/or the third parameters of a third calibration function are stored in a memory (RAM, ROM, flash) (RAM, NVM) of the device, with the aid of which the device can determine the value of the absolute value of the effective magnetic resonance minimum flux density B₂₉ from the determined value of the resonance minimum microwave frequency ω_{μW29} of the middle resonance minimum 529.

The decrease in the absolute value of the measured values for the portion of the intensity Iᵢₛₜ(t) of the fluorescence radiation FL of the multiplicity of diamond nano crystals ND provided with NV centers from the lower resonance sub-field 526 to the middle resonance minimum 529 occurs at a constant effective magnetic flux density B and with an increase in the microwave frequency ω_{μW} exceeding the lower middle microwave frequency ω_{μW23}, so that the device can detect a lower mean resonance edge 523 when the effective magnetic flux density B is above that of the effective offset flux density Boff. Preferably, a fourth calibration table and/or the fourth parameters of a fourth calibration function are stored in a memory (RAM, ROM, flash) (RAM, NVM) of the device, with the aid of which the device can determine the value of the absolute value of the lower mean effective magnetic flux density B₂₃ from the determined value of the lower mean microwave frequency ω_{μW23} of the lower mean resonance edge 523.

The increase in the absolute value of the measured values for the portion of the intensity Iᵢₛₜ(t) of the fluorescence radiation FL of the multiplicity of diamond nano crystals ND provided with NV centers from the middle resonance minimum 529 to the upper resonance sub-field 527 takes place at a constant effective magnetic flux density B and with a further increase in the microwave frequency ω_{μW} exceeding the upper middle microwave frequency ω_{μW24}, so that the device can detect an upper mean resonance edge 524 when the effective magnetic flux density B is above that of the effective offset flux density Boff. Preferably, a fifth calibration table and/or the fifth parameters of a fifth calibration function are stored in a memory (RAM, ROM, flash) (RAM, NVM) of the device, with the aid of which the device can determine the value of the absolute value of the upper mean effective magnetic flux density B₂₄ from the determined value of the upper mean microwave frequency ω_{μW24} of the upper mean resonance edge 524.

With an unknown effective magnetic flux density Bₙₖ, the device can thus be used to determine one or more of the measured values by varying the microwave frequency ω_{μW}:
lower microwave frequency ω_{(μW22)};
lower average microwave frequency ω_{(μW23)};
upper mean microwave frequency ω_{(μW24)};
upper microwave frequency ω_{(μW25)}; or resonance minimum microwave frequency ω_{μW29}.

For an unknown effective magnetic flux density Bₙₖ, the device can thus be configured from these microwave frequencies (ω_{μW22}, ω_{μW23}, ω_{μW24}, ω_{μW25}, ω_{μW29}) by varying the microwave frequency ω_{μW} and using one or more of the measured values:
lower microwave frequency ω_{(μW22)};
lower average microwave frequency ω_{(μW23)};
upper mean microwave frequency ω_{(μW24)};
upper microwave frequency ω_{(μW25)}; or
resonance minimum microwave frequency ω_{μW29};
one or more of the associated measured values:
lower effective magnetic flux density B₂₂;
upper effective magnetic flux density B₂₅;
effective magnetic resonance minimum flux density B₂₉;
lower mean effective magnetic flux density B₂₃; or
upper mean effective magnetic flux density B₂₄;
must be determined. These should generally correspond to the unknown effective magnetic flux density B₍ₙₖ₎. For example, the device can calculate the measured value of an averaged mean effective flux density Bg by averaging over two or more values (B₂₂, B₂₃, B₂₄, B₂₅, B₂₉).

### FIG. 51d

FIG. 51d explains the determination of an unknown microwave frequency ω_{μWnk}. based on FIG. 51b.

By means of a variation of the effective magnetic reference flux density B_{ref} in the region of interest and by means of a simultaneous determination of that portion of the intensity of the fluorescence radiation FL of the diamond nano crystals ND provided with NV centers, in which this portion of the intensity signal of the fluorescence radiation FL comprises the microwave modulation frequency f_{μW}, as a function of this effective magnetic reference flux density B_{ref} in the region of interest. The diagram 520 of FIG. 51d corresponds to that of FIG. 51b, whereby now distinctive points in the diagram 520 are additionally marked by means of reference lines and reference signs for better clarity.

The linear extrapolation of the lower resonance edge 522 and the upper resonance edge 525 typically intersect at a point on the peak 530 of the V-formation (522, 525) with zero-point flux density B₀ and zero-point microwave frequency ω_{μW0}.

Preferably, the device determines the zero-point flux density B₀ and the zero-point microwave frequency ω_{μW0} of the tip 530 of the V-formation (522, 525) or functionally equivalent information by changing the magnetic reference flux density B_{ref} before the device is used as intended and/or in an initialization process when the device according to the proposal is put into operation. If present, the device according to the proposal compensates the zero-point flux density B₀ by means of optional magnetic field compensation means (LCTR, DRLV, L_{c}, SIS, MS). For example, these magnetic field compensation means (LCTR, DRLV, L_{c}, SIS, MS) may a magnetic field controller LCTR which controls the magnetic field generation means L_{c} and the driver stage DRVL for supplying the magnetic field generation means L_{c}. For example, the device according to the proposal may thus have means for generating an additional, superimposed magnetic flux density B_{ad}. These means for generating an additional superimposed magnetic flux density B_{ad} may comprise said magnetic field generation means L_{c}.

These means for generating an additional, superimposed magnetic flux density B_{ad} can comprise a permanent magnet PM or a gradient afflicted permanent magnet GPM. These means for generating an additional, superimposed magnetic flux density B_{ad} may comprise a positioning device PV, which positions the permanent magnet PM or the gradient afflicted permanent magnet GPM relative to the sensor element SE. Preferably, the control device CTR then controls the positioning device PV of the permanent magnet PM or the gradient afflicted permanent magnet GPM via a data bus DB and thus the positioning of the permanent magnet PM or the gradient afflicted permanent magnet GPM relative to the sensor element SE. This allows the control device CTR to influence the additional magnetic flux density B_{ad} flowing through the sensor element SE. Preferably, the control device CTR controls the positioning of the permanent magnet PM or the gradient afflicted permanent magnet GPM relative to the sensor element SE and influences the additional magnetic flux density B_{ad} that flows through the sensor element SE, depending on one or more measured values of a magnetic flux density.

A first of these measured values of such a magnetic flux density can, for example, be a measured value of a magnetic field sensor MS, which the control device CTR detects by means of the magnetic field sensor MS and, if applicable, a magnetic field sensor controller SIS, for example via a data bus DB.

A second of these measured values of such a magnetic flux density may, for example, be a measured value detected by the control device CTR by means of the sensor element SE and its fluorescence radiation FL and further device parts described herein.

The effective magnetic flux density B_{w} is then composed of the effective external magnetic flux density B_{extw} and the effective additional flux density B_{adw}. (B_{w}=B_{extw}+B_{adw}) In this case, the device can tune the effective magnetic flux density B_{w} by changing the additional magnetic flux density B_{ad}.

The effective additional flux density B_{adw} is the portion of the additional flux density B_{ad} that is perpendicular to the vector of the magnetic flux density B_{μW} of the microwave radiation of the microwave signal μW.

The effective magnetic flux density B_{w} is the proportion of the total flux density BE that is perpendicular to the vector of the magnetic flux density B_{μW} of the microwave radiation of the microwave signal μW.

The effective external magnetic flux density B_{extw} is the portion of the external magnetic flux density Bₑₓₜ that is perpendicular to the vector of the magnetic flux density B_{μW} of the microwave radiation of the microwave signal μW. The external magnetic flux density Bₑₓₜ preferably acts on the sensor element SE from outside the device.

To determine an unknown microwave frequency ω_{μWnk}, the device can, for example, change the effective magnetic reference flux density B_{ref} by means of changing the additional effective magnetic flux density B_{adw}. This causes the operating point of the sensor element SE to move along the line 541.

To determine an unknown microwave frequency ω_{μWnk}, the device can, for example, mix a microwave signal μW with the microwave frequency ω_{μW}. This results in microwave signal portions with a mixed microwave frequency of ω_{μWmix}+ω_{μWnk}+ω_{μW} and ω_{μWmix}−ω_{pWnk}−ω_{μW} within the sensor element SE. As a result, the operating point of the sensor element SE moves along the line 543. Preferably, the unknown microwave frequency ω_{μWnk} is greater in magnitude than the frequency distance between the intersection 542 of the line 543 with the lower resonance edge 522 from the intersection 545 of the line 543 with the upper resonance edge 525.

It is therefore advantageous if the device increases the additional magnetic flux density B_{ad} during the measurement in order to shift the operating point of the measurement from the bottom to the top. The operating point is typically defined by the mixed microwave frequencies of ω_{μWmix}+ω_{μWnk}+ω_{μW} and ω_{μWmix}−=ω_{μWnk}−ω_{μW} and by the effective magnetic flux density B_{w} (B_{w}=B_{extw}+B_{adw}).

Thus, the device according to the proposal can determine the position of the lower resonance edge 522 and the upper resonance edge 525 and/or the peak 530 of the V-formation (522, 525) by interpolation from the values obtained at an unknown effective microwave frequency ω_{μWnk} by variation of the microwave frequency ω_{μW} and/or by variation of the effective additional magnetic flux density B_{adw} and, if applicable, the positions of the lower middle resonance edge 523 and/or the upper middle resonance edge 524 and/or the position of the middle resonance minimum 529 and, for example, can determine therefrom the position of the zero point flux density 529. determine the positions of the lower middle resonance edge 523 and/or the upper middle resonance edge 524 and/or the position of the middle resonance minimum 529 and, for example, determine the position of the zero-point flux density B₀ and/or the zero-point microwave frequency ω_{μW0} from this. From this, the device can infer the effective external magnetic flux density B_{extw} and/or the unknown microwave frequency ω_{μWnk}. For this purpose, the control device CTR preferably controls the microwave signal source μWG and the magnetic field generation means L_{c} with its control device LCTR typically via the data bus DB.

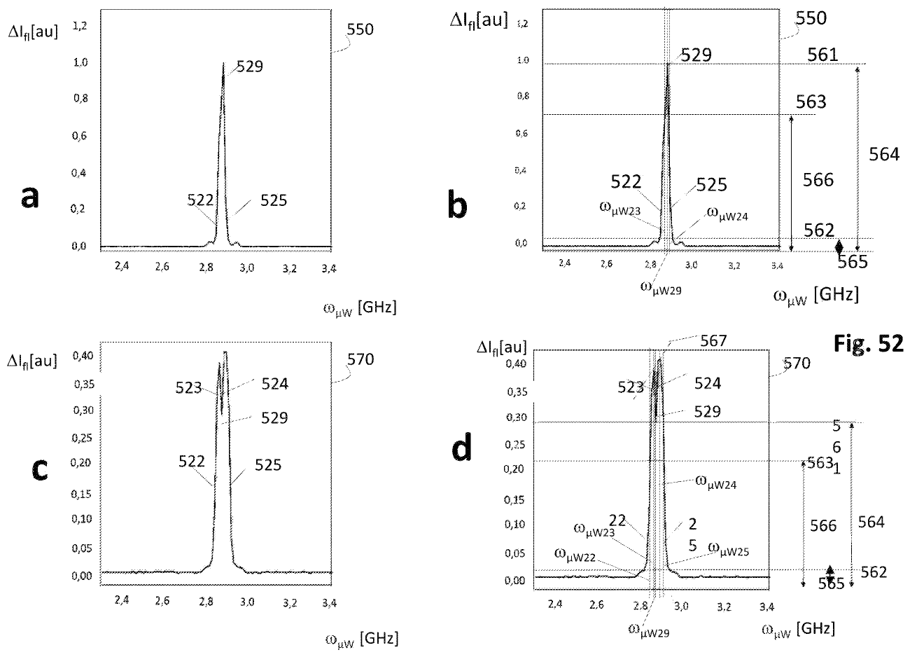

### FIG. 52a

FIG. 52a shows the resonances of a multiplicity of diamonds comprising NV centers oriented differently in space. FIG. 52a shows in diagram 550 the amplitude of the proportion of the intensity of the fluorescence radiation FL of the multiplicity of diamonds provided with NV centers, in which the proportion of the intensity signal of the fluorescence radiation FL comprising the microwave modulation frequency f_{W} is shown as a function of the microwave frequency ω_{μW} and at a constant effective magnetic flux density B_{(w)}. The magnetic flux density B corresponds to the value 0.0 of the Y-axis of the diagram 520 of FIG. 51b. The microwave frequency ω_{(μW) is} plotted on the X-axis of diagram 550. The amplitude of the portion of the intensity Iᵢₛₜ(t) of the fluorescence radiation FL of the multiplicity of diamonds provided with NV centers, in which the portion of the intensity signal of the fluorescence radiation FL comprises the microwave modulation frequency f_{μW}, is plotted in the Y-axis of the diagram 550 in arbitrary units (abbreviated “au”). In the example, a multiplicity of diamond crystals oriented differently in space are oriented differently and typically uniformly distributed with respect to the direction of the magnetic flux density B of a magnetic field.

In FIG. 52a, the lower resonance edge 522 and the upper resonance edge 525 and the middle resonance minimum 529 are provided with reference signs for orientation.

### FIG. 52b

FIG. 52b corresponds to FIG. 52a, with different reference lines (561, 562, 563) now drawn in for measurement. One problem is the noise background, which the control device CTR must suppress by means of a computer-implemented noise suppression method, for example.

Preferably, the control device CTR sets the upper reference line 561 such that the value 564 of the magnetic flux density B₆₁ associated with the upper reference line 561 is maximum and the upper reference line 561 is crossed by the detected curve at least once and not more than four times.

Preferably, the control device CTR sets the lower reference line 562 such that the value 565 of the magnetic flux density B₆₂ associated with the lower reference line 562 is minimal and the lower reference line 562 is crossed at least twice and no more than four times by the detected curve.

Preferably, the control device CTR of the proposed device then selects the middle reference line 563 such that the difference of the value 566 of the magnetic flux density B₆₃ associated with the middle reference line 563 minus the value 565 of the magnetic flux density B₆₂, which is assigned to the lower reference line 562, corresponds to a factor X times the difference of the value 564 of the magnetic flux density B₆₁ which is assigned to the upper reference line 561 minus the value 565 of the magnetic flux density B₆₂ which is assigned to the lower reference line 562. An exemplary value for the factor X may be 80% to 50% or 75% or 70% etc. Depending on the application, the document presented here suggests optimizing this factor X in the development phase by means of a DoE. (see also https://de.wikipedia.org/wiki/Statistische_Versuchsplanung)

The lower resonance edge 522 is assigned the lower microwave frequency ω_{(μW22)}.

The upper resonance edge 525 is assigned the upper microwave frequency ωμ_{W2(5)}.

The middle resonance minimum 529 is assigned the resonance minimum microwave frequency ω_{(μW29)}.

### FIG. 52c

FIG. 52c shows the resonances of a multiplicity of diamonds comprising different NV centers oriented in space. FIG. 52c shows in diagram 570 the amplitude of the proportion of the intensity of the fluorescence radiation FL of the multiplicity of diamonds provided with NV centers, in which the proportion of the intensity signal of the fluorescence radiation FL comprising the microwave modulation frequency f_{μW} is shown as a function of the microwave frequency ω_{μW} and at a constant effective magnetic flux density B_{(w)}. The magnetic flux density B corresponds approximately to the value 0.003 of the Y-axis of the diagram 520 of FIG. 51b. The microwave frequency ω_{μW} is plotted on the X-axis of diagram 570. The amplitude of the portion of the intensity of the fluorescence radiation FL of the multiplicity of diamonds provided with NV centers, in which the portion of the intensity signal of the fluorescence radiation FL comprises the microwave modulation frequency f_{μW}, is plotted in arbitrary units (abbreviated as “au”) in the Y-axis of the diagram 570. In the example, a multiplicity of diamond crystals oriented differently in space are oriented differently and typically uniformly distributed with respect to the direction of the magnetic flux density B of a magnetic field.

In FIG. 52c, the lower resonance edge 522 and the upper resonance edge 525 and the lower middle resonance edge 523 and the upper middle resonance edge 524 and the middle resonance minimum 529 are provided with reference signs for orientation.

### FIG. 52d

FIG. 52d corresponds to FIG. 52c, whereby the various reference lines (561, 562, 563) for measurement are now drawn in again. One problem is the noise background, which the control device CTR must suppress.

Preferably, the control device CTR sets the upper reference line 561 such that the value 564 of the magnetic flux density B₆₁ associated with the upper reference line 561 is maximum and the upper reference line 561 is crossed by the detected curve at least once and not more than four times.

Preferably, the control device CTR sets the lower reference line 562 such that the value 565 of the magnetic flux density B₆₂ associated with the lower reference line 562 is minimal and the lower reference line 562 is crossed at least twice and no more than four times by the detected curve.

Preferably, the control device CTR of the proposed device then selects the middle reference line 563 such that the difference of the value 566 of the magnetic flux density B₆₃ associated with the middle reference line 563 minus the value 565 of the magnetic flux density B₆₂, which is assigned to the lower reference line 562, corresponds to a factor X times the difference of the value 564 of the magnetic flux density B₆₁ which is assigned to the upper reference line 561 minus the value 565 of the magnetic flux density B₆₂ which is assigned to the lower reference line 562. An exemplary value for the factor X can be 80% to 50% or 75% or 70% etc. Depending on the application, the document presented here suggests optimizing this factor X in the development phase by means of a DoE. (see also https://de.wikipedia.org/wiki/Statistische_Versuchsplanung)

The lower resonance edge 522 is assigned the lower microwave frequency ω_{(μW22)}.

The lower mean resonance edge 523 is assigned the lower mean microwave frequency ωμ_{W2(3)}.

The upper mean resonance edge 524 is assigned the upper mean microwave frequency ωμ_{W2(4)}.

The upper resonance edge 525 is assigned the upper microwave frequency ω_{μW2(5)}.

The middle resonance minimum 529 is assigned the resonance minimum microwave frequency ω_{(μW29)}.

The slope 567 of the curve is also shown. This can only be measured above a certain magnetic flux density B.

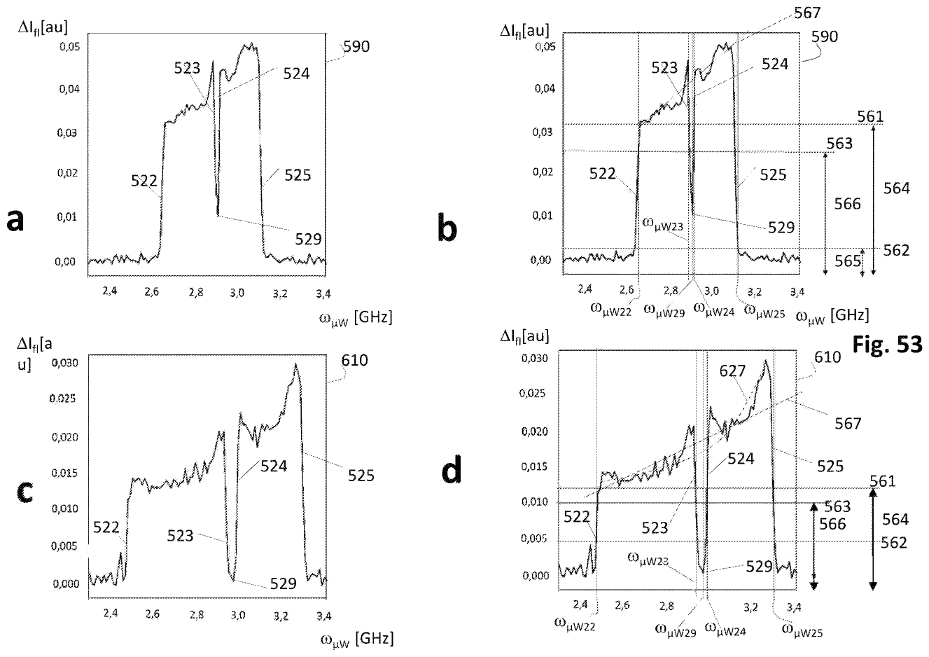

### FIG. 53a

FIG. 53a shows the resonances of a multiplicity of diamonds comprising NV centers oriented differently in space. FIG. 53a shows in diagram 590 the amplitude of the proportion of the intensity of the fluorescence radiation FL of the multiplicity of diamonds provided with NV centers, in which the proportion of the intensity signal of the fluorescence radiation FL comprising the microwave modulation frequency f_{μW} is shown as a function of the microwave frequency ω_{μW} and at a constant effective magnetic flux density B_{(w)}. The magnetic flux density B corresponds approximately to the value 0.07 of the Y-axis of the diagram 520 of FIG. 51b. The microwave frequency ω_{(μW) is} plotted on the X-axis of the diagram 590. The amplitude of the portion of the intensity Iᵢₛₜ(t) of the fluorescence radiation FL of the multiplicity of diamonds provided with NV centers, in which the portion of the intensity signal of the fluorescence radiation FL comprises the microwave modulation frequency f_{μW}, is plotted in the Y-axis of the diagram 590 in arbitrary units (abbreviated “au”). In the example, a multiplicity of diamond crystals oriented differently in space are oriented differently and typically uniformly distributed with respect to the direction of the magnetic flux density B of a magnetic field.

In FIG. 53a, the lower resonance edge 522 and the upper resonance edge 525 and the lower middle resonance edge 523 and the upper middle resonance edge 524 and the middle resonance minimum 529 are provided with reference signs for orientation.

### FIG. 53b

FIG. 53b corresponds to FIG. 53a, whereby the various reference lines (561, 562, 563) for measurement are now drawn in again. One problem is the noise background, which the control device CTR must suppress.

Preferably, the control device CTR sets the upper reference line 561 such that the value 564 of the magnetic flux density B₆₁ associated with the upper reference line 561 is maximum and the upper reference line 561 is crossed by the detected curve at least once and not more than four times.

Preferably, the control device CTR sets the lower reference line 562 such that the value 565 of the magnetic flux density B₆₂ associated with the lower reference line 562 is minimal and the lower reference line 562 is crossed at least twice and no more than four times by the detected curve.

Preferably, the proposed device then selects the middle reference line 563 such that the difference of the value 566 of the magnetic flux density B₆₃ associated with the middle reference line 563 minus the value 565 of the magnetic flux density B₆₂ associated with the lower reference line 562 is equal to a factor X times the difference of the value 564 of the magnetic flux density B₆₍₁₎ associated with the upper reference line 561 minus the value 565, which is assigned to the lower reference line 562, corresponds to a factor X times the difference of the value 564 of the magnetic flux density B₆₁ which is assigned to the upper reference line 561 minus the value 565 of the magnetic flux density B₆₂ which is assigned to the lower reference line 562. An exemplary value for the factor X may be 80% to 50% or 75% or 70% etc. Depending on the application, the document presented here suggests optimizing this factor X in the development phase by means of a DoE. (see also https://de.wikipedia.org/wiki/Statistische_Versuchsplanung)

The lower resonance edge 522 is assigned the lower microwave frequency ω_{(μW22)}.

The lower mean resonance edge 523 is assigned the lower mean microwave frequency ω_{μW2(3)}.

The upper mean resonance edge 524 is assigned the upper mean microwave frequency ω_{μW2(4)}.

The upper resonance edge 525 is assigned the upper microwave frequency ω_{μW2(5)}.

The middle resonance minimum 529 is assigned the resonance minimum microwave frequency ω_{(μW29)}.

The gradient 567 of the curve is also shown.

Preferably, the control device CTR of the device determines the slope 567 of the curve in the central regions of the curve firstly between the lower resonance edge 522 and the lower middle resonance edge 523 and secondly between the upper middle resonance edge 524 and the upper resonance edge 525. Preferably, the control device CTR of the device does not use the regions of the curve in the vicinity of the lower resonance edge 522 and in the vicinity of the lower middle resonance edge 523 and in the vicinity of the upper middle resonance edge 524 and in the vicinity of the upper resonance edge 25 for determining the slope 567 of the curve. Therefore, the control device CTR of the device can generally only determine the slope 567 of the curve from a certain minimum flux density B of the magnetic flux density B.

### FIG. 53c

FIG. 53c shows the resonances of a multiplicity of diamonds comprising different NV centers oriented in space. FIG. 53c shows in diagram 610 the amplitude of the proportion of the intensity of the fluorescence radiation FL of the multiplicity of diamonds provided with NV centers, in which the proportion of the intensity signal of the fluorescence radiation FL comprising the microwave modulation frequency f_{μW} is shown as a function of the microwave frequency ω_{μW} and at a constant effective magnetic flux density B_{(w)}. The magnetic flux density B corresponds approximately to the value 0.124 of the Y-axis of the diagram 520 of FIG. 51b. The microwave frequency ω_{(μW) is} plotted on the X-axis of the diagram 610. The amplitude of the portion of the intensity Iᵢₛₜ(t) of the fluorescence radiation FL of the multiplicity of diamonds provided with NV centers, in which the portion of the intensity signal of the fluorescence radiation FL comprises the microwave modulation frequency f_{μW}, is plotted in the Y-axis of the diagram 610 in arbitrary units (abbreviated “au”). In the example, a multiplicity of diamond crystals oriented differently in space are oriented differently and typically uniformly distributed with respect to the direction of the magnetic flux density B of a magnetic field.

In FIG. 53c, the lower resonance edge 522 and the upper resonance edge 525 and the lower middle resonance edge 523 and the upper middle resonance edge 524 and the middle resonance minimum 529 are provided with reference signs for orientation.

### FIG. 53d

FIG. 53d corresponds to FIG. 53c, whereby the various reference lines (561, 562, 563) for measurement are now drawn in again. One problem is the noise background, which the control device CTR must suppress.

Preferably, the control device CTR sets the upper reference line 561 such that the value 564 of the magnetic flux density B₆₁ associated with the upper reference line 561 is maximum and the upper reference line 561 is crossed by the detected curve at least once and not more than four times.

Preferably, the control device CTR sets the lower reference line 562 such that the value 565 of the magnetic flux density B₆₂ associated with the lower reference line 562 is minimal and the lower reference line 562 is crossed at least twice and no more than four times by the detected curve.

Preferably, the proposed device then selects the middle reference line 563 such that the difference of the value 566 of the magnetic flux density B₆₃ associated with the middle reference line 563 minus the value 565 of the magnetic flux density B₆₂ associated with the lower reference line 562 is equal to a factor X times the difference of the value 564 of the magnetic flux density B(61) associated with the upper reference line 561 minus the value 565 of the magnetic flux density B₍₆₁₎ associated with the lower reference line 562, which is assigned to the lower reference line 562, corresponds to a factor X times the difference of the value 564 of the magnetic flux density B₆₁ which is assigned to the upper reference line 561 minus the value 565 of the magnetic flux density B₆₂ which is assigned to the lower reference line 562. An exemplary value for the factor X may be 80% to 50% or 75% or 70% etc. Depending on the application, the document presented here suggests optimizing this factor X during the development phase by means of a DoE. (see also https://de.wikipedia.org/wiki/Statistische_Versuchsplanung)

The lower resonance edge 522 is assigned the lower microwave frequency ω_{(μW22)}.

The lower mean resonance edge 523 is assigned the lower mean microwave frequency ω_{μW2(3)}.

The upper mean resonance edge 524 is assigned the upper mean microwave frequency ω_{μW2(4)}.

The upper resonance edge 525 is assigned the upper microwave frequency ω_{μW2(5)}.

The middle resonance minimum 529 is assigned the resonance minimum microwave frequency ω_{(μW29)}.

The gradient 567 of the curve is also shown.

Preferably, the control device CTR of the device determines the slope 567 of the curve in the central regions of the curve firstly between the lower resonance edge 522 and the lower middle resonance edge 523 and secondly between the upper middle resonance edge 524 and the upper resonance edge 525. Preferably, the control device CTR of the device does not use the regions of the curve in the vicinity of the lower resonance edge 522 and in the vicinity of the lower middle resonance edge 523 and in the vicinity of the upper middle resonance edge 524 and in the vicinity of the upper resonance edge 525 for determining the slope 567 of the curve. Therefore, the control device CTR of the device can generally determine the slope 567 of the curve only above a certain minimum flux density B of the magnetic flux density B.

In addition, a polynominal approximation 627 of the curve is entered, which can typically be described by means of a polynomial with polynomial coefficients.

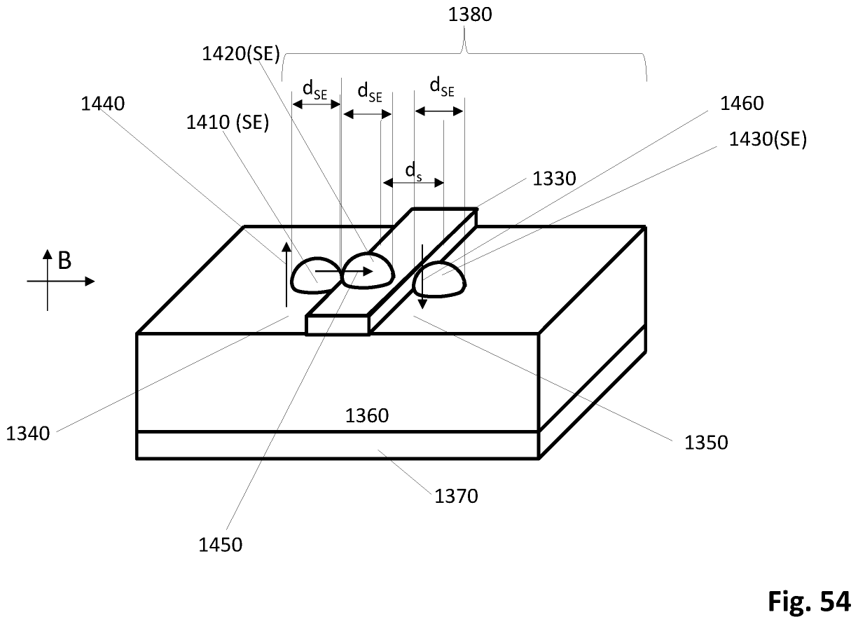

### FIG. 54

FIG. 54 shows a single microstrip line 1380 as an example of a microstrip line.

The document presented here refers as an example to the book R. K. Hoffmann “Integrated Microwave Circuits: Elektrische Grundlagen, Dimensionierung, technische Ausführung, Technologien” Springer; 1st Edition (Jun. 1, 1983), ISBN-10:3540123520, ISBN-13:978-3540123521.

Various microstrip lines are listed there. The combination of the technical teaching presented in this document with a microstrip line of any design is comprised by the disclosure presented here.

The exemplary single microstrip line 1380 of FIG. 54 comprises a preferably non- or only slightly electrically conductive, dielectric, or semiconductive carrier substrate 1360, an electrically conductive backside contact 1370 on the underside of the electrically non-conductive carrier substrate 1360, an electrically conductive signal line 1330 on the top side of the electrically non-conductive carrier substrate 1360. The carrier substrate 1360 may be, for example, an insulating layer in the metallization stack of a micro integrated circuit, in particular a micro integrated semiconductor circuit, in particular a CMOS or BiCMOS or bipolar circuit or a circuit based on III/V materials, or a dielectric layer. For example, the carrier substrate 1360) can be made of materials such as FR-4 (flameresistant-4) or PTFE (polytetrafluoroethylene) or of semiconducting materials such as pieces of semiconductor wafers, for example pieces of CMOS wafers or for example pieces of BICMOS wafers for example pieces of wafers from a bipolar technology or pieces of a wafer from a III/V material or the like and/or for example pieces of MEMS wafers and/or for example pieces of MEOS wafers (MEOS=micro electro optical system) and/or for example pieces of MOEMS wafers etc. and/or pieces of MOEMS wafers comprise micro-electronic circuits and functional elements and/or micro-optical functional elements and/or micro-mechanical functional elements and/or micro-fluidic functional elements. The individual microstrip line 1380 may possibly still be covered with an insulating layer, which would make it an embedded microstrip line. In the interests of brevity of the technical teaching presented here, we have refrained from illustrating this variant here. However, it is comprised in the disclosure of the document presented here. In the exemplary single microstrip line 1380 of FIG. 54, an electrically substantially non-conductive left insulation area 1340 separates the electrically conductive signal line 1330 from other circuit portions on the carrier substrate 1360. In addition, an electrically substantially non-conductive right insulation area 1350 also separates the electrically conductive signal line 1330 from other circuit portions on the carrier substrate 1360. Preferably, the individual microstrip line 1380 comprises a characteristic impedance with respect to the electrically conductive signal line 1330 as “hot” inner conductor and the electrically conductive backside contact 1370 as ground electrode, which preferably matches the output impedance of the microwave signal source μWG.

According to the proposal, it was recognized that the placement and the size of the sensor element SE relative to the electrically conductive signal line 1330 is decisive for the directional sensitivity of the fluorescence radiation FL of the NV centers in the diamond nano crystals ND of the sensor element SE with respect to the direction of an external magnetic flux density B₍ₑₓₜ₎.

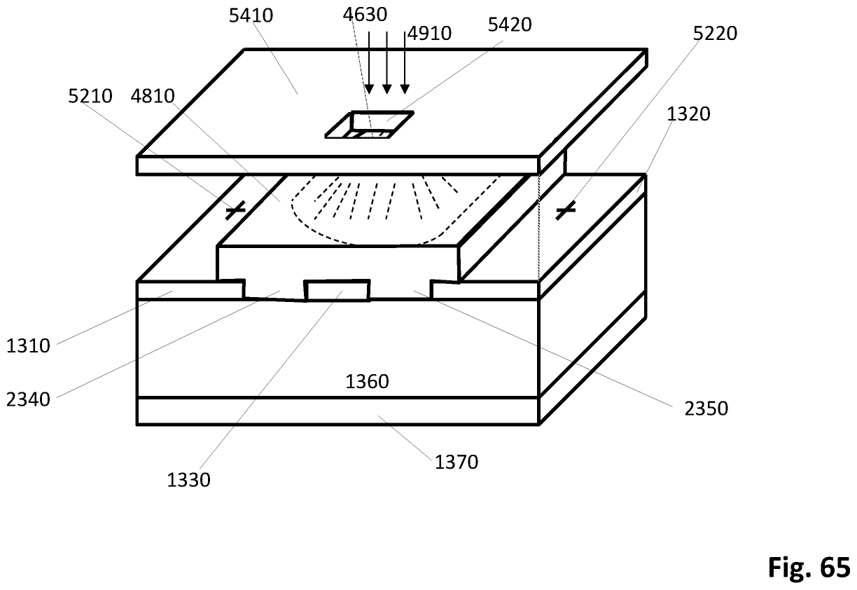

When the sensor element SE is placed on or above the electrically conductive signal line 1330 (See the following FIG. 65), the vector of the magnetic flux density of the microwave field of the microwave signal μW, which the microwave signal source μWG feeds into the signal line 1330, is essentially parallel to the surface of the electrically non-conductive carrier substrate 1360 and transverse to the direction of the signal line 1330 in the region of the sensor element SE. As a result, the fluorescence radiation FL of the NV centers in the diamond nano crystals ND of the sensor element SE is essentially sensitive to the effective portion B_{W} of the external magnetic flux density Bₑₓₜ whose flux density vector is perpendicular to the surface of the electrically non-conductive carrier substrate 1360 within the sensor element SE and/or whose flux density vector is parallel to the signal line 1360.

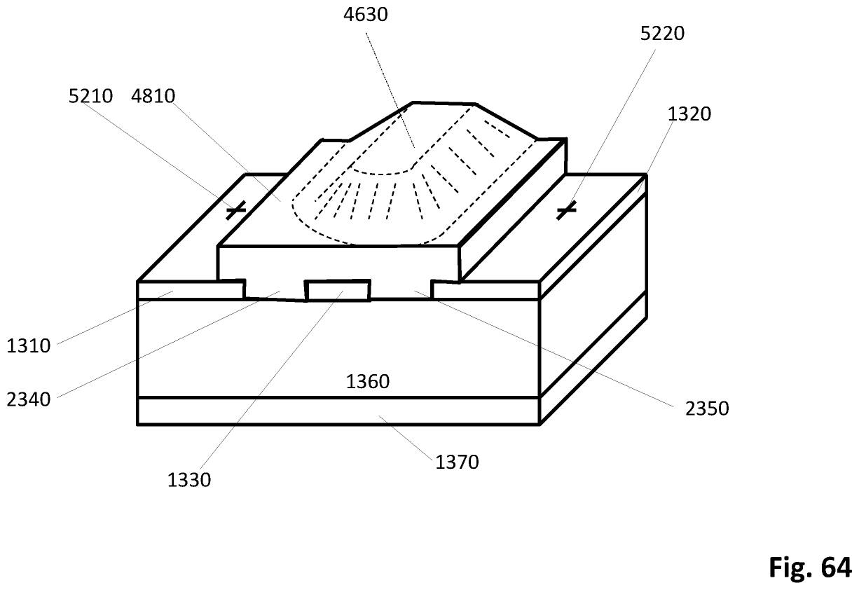

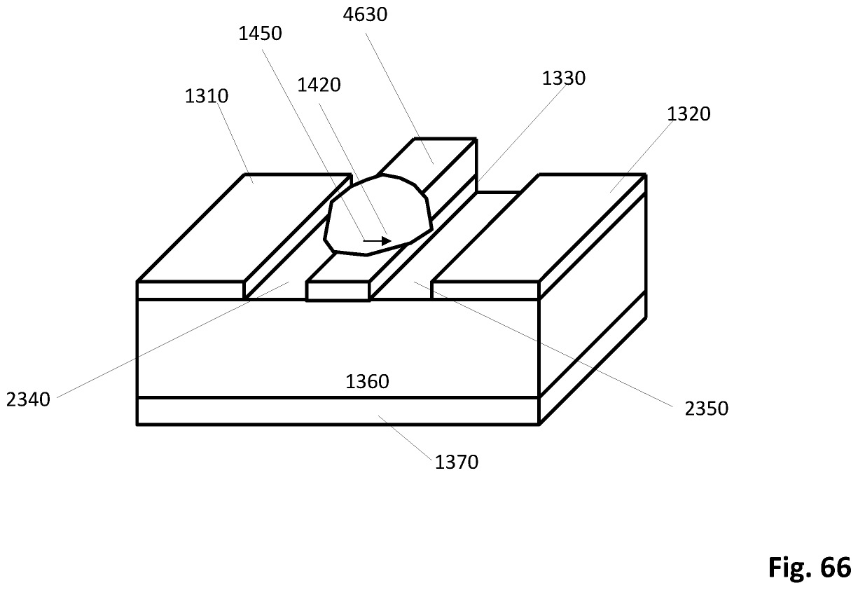

When the sensor element SE is placed directly next to the electrically conductive signal line 1330 (See also the following FIG. 64 and the following FIG. 66), the vector 1440 of the magnetic flux density of the microwave field of the microwave signal μW, which the microwave signal source μWG feeds into the signal line 1330, is essentially perpendicular to the surface of the electrically non-conductive carrier substrate 1360 within the sensor element SE. As a result, the fluorescence radiation FL of the NV centers in the diamond nano crystals ND of the sensor element SE is essentially sensitive to the effective portion B_{W} of the external magnetic flux density Bₑₓₜ whose flux density vector is parallel to the surface of the electrically non-conductive carrier substrate 1360 within the sensor element SE.

The elaboration of the proposal of the technical teaching of the document presented here thus revealed as an essential idea of the technical teaching presented here that:
the positioning of the sensor element SE relative to the electrically conductive signal line 1330 makes it possible to set a preferred direction of sensitivity:
if the diameter d_{SE} of the sensor element SE does not exceed the width d_{S} of the electrically conductive signal line 1330 by more than 50%, preferably not more than 25%, even better not more than 10%, even better not more than 5%, better not more than 2%, even better not more than 1%; or
if, particularly preferably, the diameter d_{SE} of the sensor element SE is less than the width d_{S} of the electrically conductive signal line 1330 by more than 1%, preferably more than 2%, preferably more than 5%, preferably more than 10%, preferably more than 25%, preferably more than 50%, preferably more than 75%.
the positioning of the sensor element SE relative to the electrically conductive signal line 1330 suppresses an unintentional setting of a preferred direction of sensitivity,
if the diameter d_{SE} of the sensor element SE exceeds the width d_{S} of the electrically conductive signal line 1330 by more than 1%, better more than 2%, even better more than 5%, even better more than 10%, even better more than 25%, even better more than 50%, even better more than 75%, even better more than 100%.

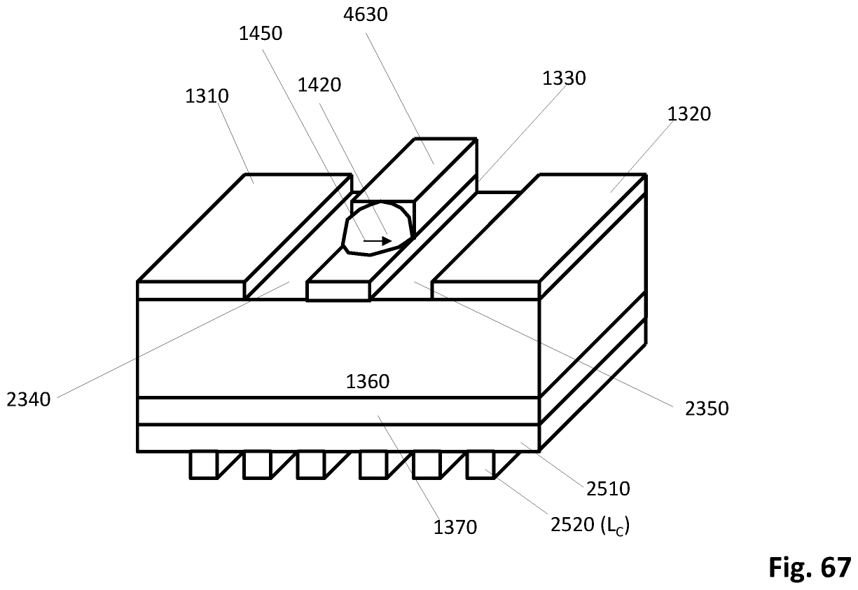

Thus, the technical teaching of the present document has recognized that the diameter d_{SE} of the sensor element SE relative to width d_{S} of the electrically conductive signal line 1330 and the positioning of the sensor element SE relative to the electrically conductive signal line 1330 of a single microstrip line 1380 can predictably adjust the directional sensitivity of the intensity of the microwave-dependent fluorescence radiation FL of the NV centers in the diamond nano crystals ND of the sensor element SE with respect to the effective portion B_{W} of the external magnetic flux density Bₑₓₜ, related to the orientation of the flux density vector within the sensor element SE relative to the surface of the electrically non-conductive carrier substrate 1360 can be predictably set and that at the same time the choice of these parameters (position SE and d_{S}) determines the extent to which this directional dependence is expressed. This directional dependence can also be completely suppressed. (See also the following FIG. 67.)

The left sensor element 1410 is shown as sensor element SE to the left of the electrically conductive signal line 1330.

In the example of FIG. 54, the diameter d_{SE} of the sensor element SE is exemplarily comparable to the width dₛ of the electrically conductive signal line 1330. For better clarity, the direction of the vector 1440 of the magnetic flux density of the microwave field of the microwave signal μW, which the microwave signal source μWG feeds into the signal line 1330, is drawn in the region of the sensor element SE in FIG. 54. The fluorescence radiation FL of the NV centers in the diamond nano crystals ND of the sensor element SE(1410) is essentially sensitive to the effective component B_{W} of the external magnetic flux density Bₑₓₜ, the flux density vector of which is parallel to the surface of the electrically non-conductive carrier substrate 1360 within the sensor element SE. The sensor element SE(1410) comprises a substrate material TM in which the diamond nano crystals ND with the NV centers are typically embedded within the sensor element SE.

The center sensor element 1420 is drawn as sensor element SE on the electrically conductive signal line 1310.

In the example of FIG. 54, the diameter d_{SE} of the sensor element SE is exemplarily comparable to the width dₛ of the electrically conductive signal line 1330. For better clarity, the direction of the vector 1450 of the magnetic flux density of the microwave field of the microwave signal μW, which the microwave signal source μWG feeds into the signal line 1330, is drawn in the region of the sensor element SE in FIG. 54. The fluorescence radiation FL of the NV centers in the diamond nano crystals ND of the middle sensor element SE(1420) is essentially sensitive to the effective portion B_{W} of the external magnetic flux density Bₑₓₜ, the flux density vector of which is perpendicular to the surface of the electrically non-conductive carrier substrate 1360 within the sensor element SE and/or the flux density vector of which is parallel to the signal line 1360. The sensor element SE(1420) comprises a substrate material TM in which the diamond nano crystals ND with the NV centers are typically embedded within the sensor element SE.

The right-hand sensor element 1430 is shown as sensor element SE to the right of the electrically conductive signal line 1330.

In the example of FIG. 54, the diameter d_{SE} of the sensor element SE is exemplarily comparable to the width dₛ of the electrically conductive signal line 1330. For better clarity, the direction of the vector 1460 of the magnetic flux density of the microwave field of the microwave signal μW, which the microwave signal source μWG feeds into the signal line 1330, is drawn in the region of the sensor element SE in FIG. 54. The fluorescence radiation FL of the NV centers in the diamond nano crystals ND of the sensor element SE(1430) is essentially sensitive to the effective component B_{W} of the external magnetic flux density Bₑₓₜ, the flux density vector of which is parallel to the surface of the electrically non-conductive carrier substrate 1360 within the sensor element SE. The sensor element SE(1430) comprises a substrate material TM in which the diamond nano crystals ND with the NV centers are typically embedded within the sensor element SE.

In various embodiments, several of the sensor elements (1410, 1420, 1430) may be omitted to achieve directional sensitivity.

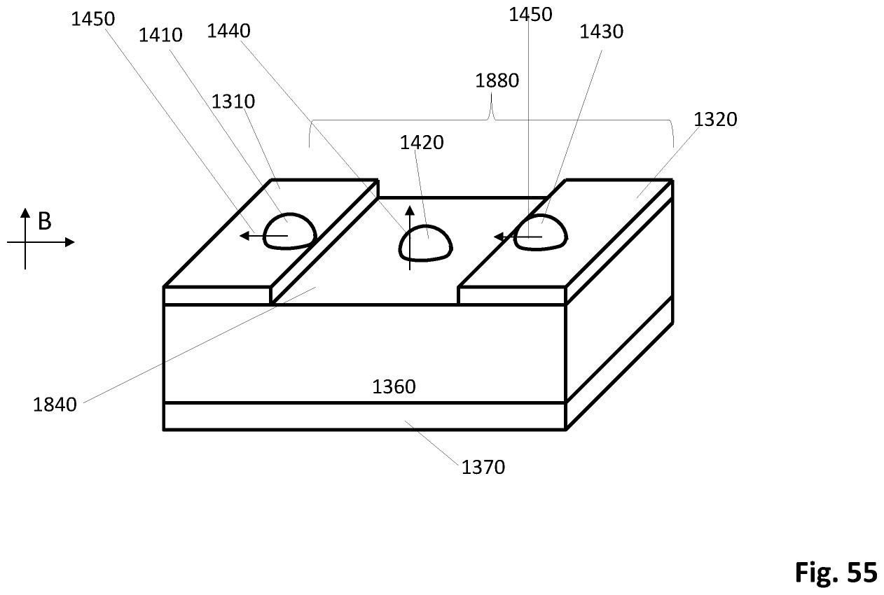

### FIG. 55

FIG. 55 shows a single slot line 1880 as an example of a slot line.

The document presented here refers as an example to the book R. K. Hoffmann “Integrated Microwave Circuits: Elektrische Grundlagen, Dimensionierung, technische Ausführung, Technologien” Springer; 1st Edition (Jun. 1, 1983), ISBN-10:3540123520, ISBN-13:978-3540123521.

Various slot lines are listed there. The combination of the technical teaching presented in this document with a microstrip line of any design is comprised by the disclosure presented here.

The exemplary single slot line 1880 of FIG. 55 comprises a preferably non- or low electrically conductive carrier substrate 1360, an electrically conductive backside contact 1370 on the underside of the electrically non-conductive carrier substrate 1360, an electrically conductive left signal ground plane 1310 on the top side of the electrically non-conductive carrier substrate 1360, and an electrically conductive right signal ground plane 1320 on the top side of the electrically non-conductive carrier substrate 1360. The carrier substrate 1360 may be, for example, an insulating layer in the metallization stack of a micro integrated circuit, in particular a micro integrated semiconductor circuit, in particular a CMOS or BICMOS or bipolar circuit or a circuit based on III/V materials or a dielectric carrier substrate 1360 the like. The electrically conductive left signal ground plane 1310 and the electrically conductive right signal ground plane 1320 may possibly still be covered with an insulating layer, whereby they would become an embedded slot line. In the interests of brevity of the technical teaching presented here, we have refrained from illustrating this variant here. However, it is comprised in the disclosure of the document presented here. In the exemplary single slot line 1880 of FIG. 55, an electrically essentially non-conductive insulation area 1840—the slot—separates the electrically conductive left signal ground plane 1310 from the electrically conductive right signal ground plane 1320 on the carrier substrate 1360. Preferably, the single slot line 1880 comprises a characteristic impedance with respect to the slot 1840 as “hot” inner conductor and the electrically conductive backside contact 1370 as ground electrode, which preferably matches the output impedance of the microwave signal source μWG.

According to the proposal, it has been recognized that the placement and the size of the sensor element SE relative to the electrically conductive left signal ground plane 1310 and the electrically conductive right signal ground plane 1320 and the slot 1840 is decisive for the directional sensitivity of the fluorescence radiation FL of the NV centers in the diamond nano crystals ND of the sensor element SE with respect to the direction of an external magnetic flux density B₍ₑₓₜ₎.

When one or more sensor elements SE are placed on or above the electrically conductive left signal ground plane 1310 and/or on or above the electrically conductive right signal ground plane 1320, the respective vector of the magnetic flux density of the microwave field of the microwave signal μW, which the microwave signal source μWG feeds into the slot line 1880, is essentially parallel to the surface of the electrically non-conductive carrier substrate 1360 in the region of the respective sensor element SE. As a result, the fluorescence radiation FL of the NV centers in the diamond nano crystals ND of the respective sensor element SE is essentially sensitive to the effective portion B_{W} of the external magnetic flux density Bₑₓₜ whose flux density vector is perpendicular to the surface of the electrically non-conductive carrier substrate 1360 or whose flux density vector is parallel to the slot 1840 of the slot line 1880 within the respective sensor element SE.

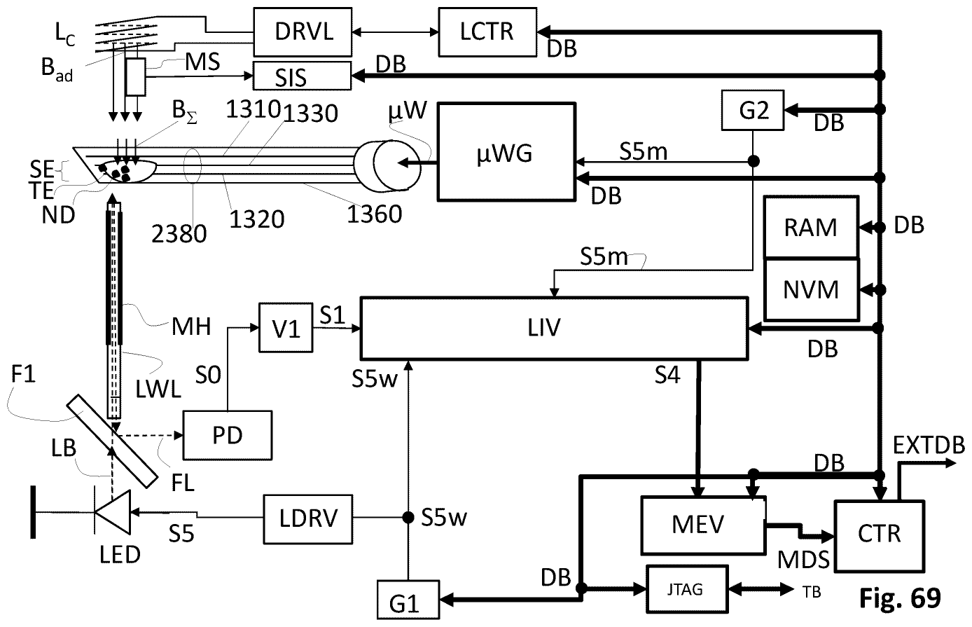

When the sensor element SE is placed directly within the slot 1840 of the slot line 1880 (See also the following FIG. 69), the vector 1440 of the magnetic flux density of the microwave field of the microwave signal μW, which the microwave signal source μWG feeds into the slot line 1880, is essentially perpendicular to the surface of the electrically non-conductive carrier substrate 1360 within the sensor element SE. As a result, the fluorescence radiation FL of the NV centers in the diamond nano crystals ND of the sensor element SE is essentially sensitive to the effective portion B_{W} of the external magnetic flux density Bₑₓₜ whose flux density vector is parallel to the surface of the electrically non-conductive carrier substrate 1360 within the sensor element SE.

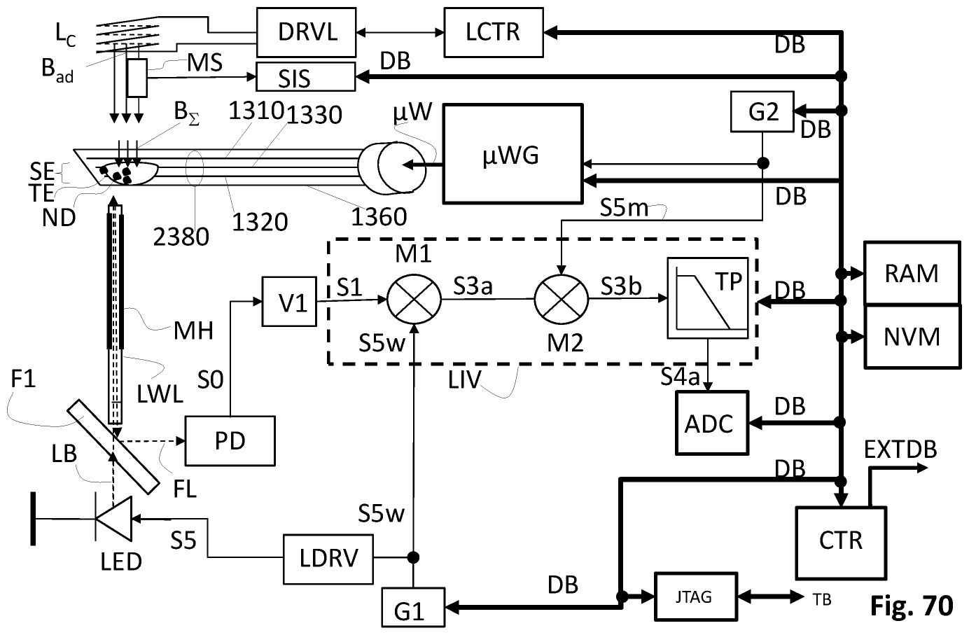

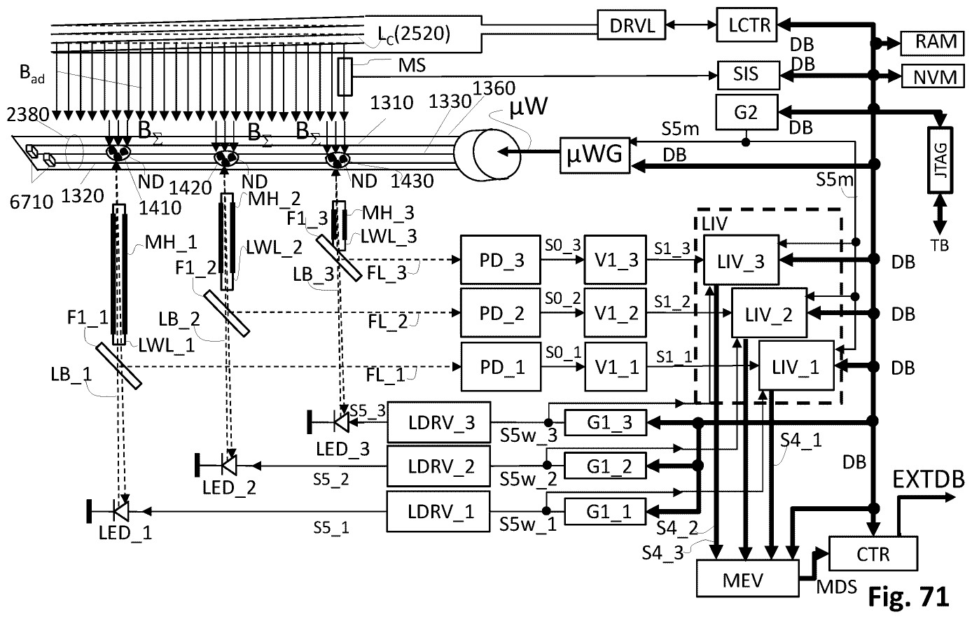

The elaboration of the proposal of the technical teaching of the document presented here thus revealed as an essential idea of the technical teaching presented here that:
the positioning of the sensor element SE relative to the slot 1840 of the slot line 1880 allows an adjustment of a preferred direction of sensitivity:
if the diameter d_{SE} of the sensor element SE does not exceed the width d_{SL} of the slot 1840 of the slot line 1880 by more than 50%, better not more than 25%, even better not more than 10%, even better not more than 5%, better not more than 2%, even better not more than 1%; or
if, particularly preferably, the diameter d_{SE} of the sensor element SE is less than the width d_{SL} of the slot 1840 of the slot line 1880 by more than 1%, preferably more than 2%, preferably more than 5%, preferably more than 10%, preferably more than 25%, preferably more than 50%, preferably more than 75%.
the positioning of the sensor element SE relative to the slot 1840 of the slot line 1880 suppresses an unintentional setting of a preferred direction of sensitivity:
if the diameter d_{SE} of the sensor element SE exceeds the width d_{SL} of the slot 1840 of the slot line 1880 by more than 1%, better more than 2%, even better more than 5%, even better more than 10%, even better more than 25%, even better more than 50%, even better more than 75%, even better more than 100%; and
when sensor element SE is preferably positioned relative to the slot 1840 of the slot line 1880 in such a way that the sensor element SE preferably covers the electrically conductive left signal ground plane 1310 and the electrically conductive right signal ground plane 1320 (see FIGS. 70 and 71 below) in the same way.

Thus, the technical teaching of the present document has recognized that the diameter d_{SE} of the sensor element SE relative to width d_{SL} of the slot 1840 of the slot line 1880 and the positioning of the sensor element SE relative to the slot 1840 of the slot line 1880 can predictably adjust the directional sensitivity of the intensity of the microwave-dependent fluorescence radiation FL of the NV centers in the diamond nano crystals ND of the sensor element SE with respect to the effective portion B_{w} of the external magnetic flux density Bₑₓₜ, in relation to the orientation of the flux density vector within the sensor element SE relative to the surface of the electrically non-conductive carrier substrate 1360, and that at the same time the choice of these parameters (position SE and d_{SL}) determines the extent to which this directional dependence is expressed. This directional dependence can also be completely suppressed.

A center sensor element 1420 is drawn as sensor element SE in the slot 1840 of the slot line 1880.

In the example of FIG. 55, the diameter d_{SE} of the center sensor element SE(1420) is exemplarily smaller than the width d_{SL} of the slot 1840 of the slot line 1880. For better clarity, the direction of the vector 1450 of the magnetic flux density of the microwave field of the microwave signal μW that the microwave signal source μWG feeds into the slot line 1880 is drawn in the region of the center sensor element SE(1420) in FIG. 55. The fluorescence radiation FL of the NV centers in the diamond nano crystals ND of the middle sensor element SE(1420) is essentially sensitive to the effective portion B_{w} of the external magnetic flux density Bₑₓₜ, the flux density vector of which is parallel to the surface of the electrically non-conductive carrier substrate 1360 within the middle sensor element SE(1420). The middle sensor element SE(1420) comprises a substrate material TM in which the diamond nano crystals ND with the NV centers are typically embedded within the sensor element SE.

A left sensor element 1410 is drawn as sensor element SE on the electrically conductive left signal ground plane 1310 of the exemplary slot line 1880.

In the example of FIG. 70, the diameter d_{SE} of the left sensor element SE(1410) is exemplarily smaller than the width d_{SL} of the slot 1840 of the slot line 1880. For better clarity, the direction of the vector 1450 of the magnetic flux density of the microwave field of the microwave signal μW, which the microwave signal source μWG feeds into the slot line 1880, is drawn in the region of the left sensor element SE in FIG. 55. (We have chosen the reference sign 1450 here, as the sensitivity refers to components of the magnetic flux density of the microwave field perpendicular to the surface of the carrier substrate 1370). The fluorescence radiation FL of the NV centers in the diamond nano crystals ND of the left sensor element SE(1420) is essentially sensitive to the effective portion B_{W} of the external magnetic flux density Bₑₓₜ, whose flux density vector is perpendicular to the surface of the electrically non-conductive carrier substrate 1360 or whose flux density vector is parallel to the slot 1840 of the slot line 1880 within the left sensor element SE. The left sensor element SE(1420) comprises a substrate material TM in which the diamond nano crystals ND with the NV centers are typically embedded within the sensor element SE.

A right sensor element 1430 is drawn as sensor element SE on the electrically conductive right signal ground plane 1320 of the exemplary slot line 1880.

In the example of FIG. 55, the diameter d_{SE} of the right sensor element SE is exemplarily smaller than the width d_{SL} of the slot 1840 of the slot line 1880. For better clarity, the direction of the vector 1450 of the magnetic flux density of the microwave field of the microwave signal μW, which the microwave signal source μWG feeds into the slot line 1880, is drawn in the region of the right sensor element SE in FIG. 55. The fluorescence radiation FL of the NV centers in the diamond nano crystals ND of the sensor element SE(1430) is essentially sensitive to the effective component B_{w} of the external magnetic flux density Bₑₓₜ, the flux density vector of which is parallel to the surface of the electrically non-conductive carrier substrate 1350 within the right sensor element SE. The right sensor element SE(1430) comprises a substrate material TM in which the diamond nano crystals ND with the NV centers are typically embedded within the sensor element SE.

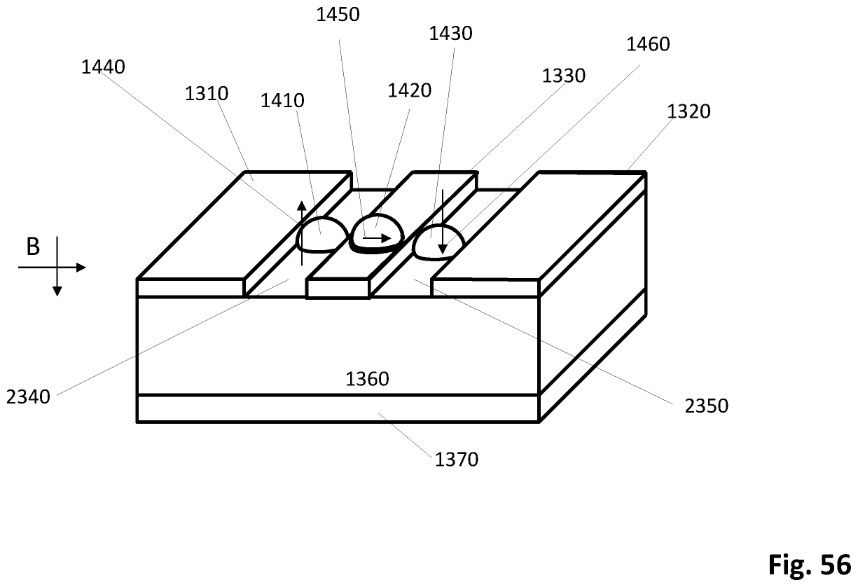

### FIG. 56

FIG. 56 shows various placements of different sensor elements in connection with an exemplary trip-plate waveguide 2380. In an analogous manner, a microstrip line 1380 or a slot line 1880 can also be used instead of a trip-plate waveguide 2380.

The person skilled in the art obtains from FIG. 56 the corresponding figure with a microstrip line 1380, by omitting the electrically conductive left signal ground plane 1310 of the exemplary triplate line 2380 and by omitting the electrically conductive right signal ground plane 1320 of the exemplary triplate line 2380. As a result, the non-conductive left insulation gap 2340 then becomes the electrically essentially non-conductive left insulation area 1340. As a result, the non-conductive right insulation gap 2350 then also becomes the electrically essentially non-conductive left insulation area 1350.

The person skilled in the art obtains from FIG. 56 the corresponding figure with a slot line 1880, by omitting the signal conductor 1330 of the exemplary triplate line 2380. As a result, the non-conductive left insulation gap 2340 and the non-conductive right insulation gap 2350 then become the electrically essentially non-conductive slot 1840 of the slot line 1880.

In order to reduce the complexity, the following text of the description of FIG. 56 therefore only describes the trip-plate waveguide 2380 as representative of other types of strip lines, such as the strip line 1380 or the slot line 1880. Other types of lines, in particular planar waveguides, are therefore comprised by the disclosure.

FIG. 56 shows a trip-plate waveguide 2380 as an example of a microstrip line.

The document presented here refers as an example to the book R. K. Hoffmann “Integrated Microwave Circuits: Elektrische Grundlagen, Dimensionierung, technische Ausführung, Technologien” Springer; 1st Edition (Jun. 1, 1983), ISBN-10:3540123520, ISBN-13:978-3540123521.

Various microstrip lines are listed there. The use of the microstrip lines described there as microstrip lines in a device within the meaning of the document presented here is hereby disclosed.

The exemplary trip-plate waveguide 2380 of FIG. 56 comprises a preferably non- or only slightly electrically conductive carrier substrate 1360, an electrically conductive backside contact 1370 on the underside of the electrically conductive carrier substrate 1360, an electrically conductive left signal ground plane 1310 on the upper side of the electrically conductive carrier substrate 1360, an electrically conductive right signal ground plane 1320 on the upper side of the electrically conductive carrier substrate 1360, an electrically conductive signal line 1330 on the upper side of the electrically conductive carrier substrate 1360 between the electrically conductive left signal ground plane 1310 and the electrically conductive right signal ground plane 1320. The carrier substrate 1360 may be, for example, an insulating layer in the metallization stack of a micro integrated circuit, in particular a micro integrated semiconductor circuit, in particular a CMOS or BiCMOS or bipolar circuit or a circuit based on III/V materials or the like. In the exemplary trip-plate waveguide 1480 of FIG. 56, an electrically essentially non-conductive left insulation gap 2340 separates the electrically conductive signal line 1330 from the electrically conductive left signal ground plane 1310. In addition, an electrically essentially non-conductive right insulation gap 2350 separates the electrically conductive signal line 1330 from the electrically conductive right signal ground plane 1450. Preferably, the trip-plate waveguide 2380 comprises a characteristic impedance with respect to the electrically conductive signal line 1330 as “hot” inner conductor and the community of electrically conductive left signal ground plane 1310, electrically conductive right signal ground plane 1320 and electrically conductive backside contact 1370 as ground electrodes. The advantage of using a trip-plate waveguide 2380 is the good shielding of the environment from the microwave radiation of the microwave signal μW, which the microwave signal source μWG feeds into the electrically conductive signal line 1330 of the trip-plate waveguide 2380.

A left sensor element SE(1410) is drawn as a left sensor element SE(1410) placed in the non-conductive left insulation gap 2340 of the trip-plate waveguide 2380.

In the example of FIG. 56, the diameter d_{SE} of the sensor element SE(1410) is exemplarily smaller than the width d_{IS1} of the non-conductive left insulation gap 2340 of the trip-plate waveguide 2380. In the example of FIG. 56, no parts of the left sensor element SE(1410) are located to the left or right of the non-conductive left insulation gap 2340 of the trip-plate waveguide 2380 and at the same time also on or above the electrically conductive left signal ground plane 1310 of the exemplary trip-plate waveguide 2380 or also on or above the signal conductor 1330 of the exemplary microstrip line 1380 or the exemplary trip-plate waveguide 2380. For better clarity, the direction of the vector 1440 of the magnetic flux density of the microwave field of the microwave signal μW, which the microwave signal source μWG feeds into the trip-plate waveguide 2380, is drawn in the region of the left sensor element SE(1410) in FIG. 56.

For clarity, the direction of the vector 1440 of the magnetic flux density of the microwave field of the microwave signal μW which the microwave signal source μWG feeds into the signal line 1330 of the trip-plate waveguide 2380 is drawn in the region of the left sensor element SE(1410) in the FIG. 56. The fluorescence radiation FL of the NV centers in the diamond nano crystals ND of the left sensor element SE(1410) is essentially sensitive to the effective component B_{W} of the external magnetic flux density Bₑₓₜ, whose flux density vector is perpendicular to the surface of the electrically non-conductive carrier substrate 1360 or whose flux density vector is parallel to the signal line 1330 within the left sensor element SE(1410). The left sensor element SE(1410) comprises a substrate material TM in which the diamond nano crystals ND with the NV centers are typically embedded within the left sensor element SE(1410).

A right sensor element SE(1430) is drawn as a right sensor element SE(1430) placed in the non-conductive right insulation gap 2350 of the trip-plate waveguide 2380.

In the example of FIG. 56, the diameter d_{SE} of the right sensor element SE(1430) is exemplarily smaller than the width d_{IS2} of the non-conductive right insulation gap 2350 of the trip-plate waveguide 2380.

In the example of FIG. 56, no parts of the right sensor element SE(1430) are located to the left or right of the non-conductive right insulation gap 2350 of the trip-plate waveguide 2380 and at the same time on or above the electrically conductive right signal ground plane 1320 of the exemplary trip-plate waveguide 2380 or on or above the signal conductor 1330 of the exemplary microstrip line 1380 or the exemplary trip-plate waveguide 2380.

For greater clarity, the direction of the vector 1460 of the magnetic flux density B_{(μW)} of the microwave field of the microwave signal μW, which the microwave signal source μWG feeds into the trip-plate waveguide 2380, is drawn in the region of the right-hand sensor element SE(1430) in FIG. 56.

For clarity, the direction of the vector 1460 of the magnetic flux density of the microwave field of the microwave signal μW which the microwave signal source μWG feeds into the signal line 1330 of the trip-plate waveguide 2380 is drawn in the region of the right sensor element SE(1430) in the FIG. 56. The fluorescence radiation FL of the NV centers in the diamond nano crystals ND of the right sensor element SE(1430) is essentially sensitive to the effective component B_{W} of the external magnetic flux density Bₑₓₜ, whose flux density vector is perpendicular to the surface of the electrically non-conductive carrier substrate 1360 or whose flux density vector is parallel to the signal line 1330 within the right sensor element SE(1430). The right sensor element SE(1430) comprises a substrate material TM in which the diamond nano crystals ND with the NV centers are typically embedded within the right sensor element SE(1430).

A center sensor element SE(1420) is shown as a center sensor element SE(1420) placed on the signal conductor 1330 of the exemplary microstrip line 1380 or the exemplary triplate line 2380.

In the example of FIG. 56, the diameter d_{SE} of the sensor element SE(1420) is exemplarily smaller than the width dₛ of the signal conductor 1330 of the exemplary microstrip line 1380 or the exemplary triplate line 2380.

In the example of FIG. 56, no parts of the center sensor element SE(1420) are located to the left or right of the signal conductor 1330 of the exemplary microstrip line 1380 or the exemplary trip-plate waveguide 2380 or in the non-conductive left insulation gap 2340 of the exemplary trip-plate waveguide 2380 or in the non-conductive right insulation gap 2350 of the exemplary trip-plate waveguide 2380.

For greater clarity, the direction of the vector 1450 of the magnetic flux density B_{(μW)} of the microwave field of the microwave signal μW, which the microwave signal source μWG feeds into the trip-plate waveguide 2380, is drawn in FIG. 36 in the region of the center sensor element SE(1420).

For clarity, the direction of the vector 1450 of the magnetic flux density B_{μW} of the microwave field of the microwave signal μW which the microwave signal source μWG feeds into the signal line 1330 of the trip-plate waveguide 2380 is drawn in the region of the center sensor element SE(1420) in the FIG. 56. The fluorescence radiation FL of the NV centers in the diamond nano crystals ND of the middle sensor element SE(1420) is essentially sensitive to the effective portion B_{W} of the external magnetic flux density Bₑₓₜ, the flux density vector of which is parallel to the surface of the electrically non-conductive carrier substrate 1360 within the middle sensor element SE(1420). The middle sensor element SE(1420) comprises a substrate material TM in which the diamond nano crystals ND with the NV centers are typically embedded within the middle sensor element SE(1420).

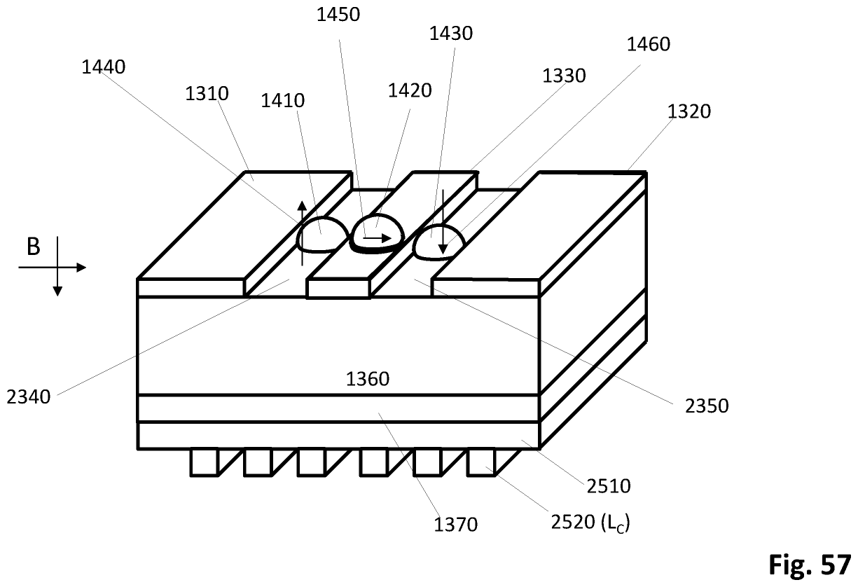

### FIG. 57

FIG. 57 corresponds to FIG. 57 supplemented by a flat coil 2520 as magnetic field generation means L_{C}. Said flat coil 2520 is only one example of a possible magnetic field generation means L_{C}. The flat coil 2520 may comprise several turns and several layers. In the example of FIG. 57, the flat coil 2520 is electrically insulated from the electrically conductive backside contact 1370 of the exemplary triplate conductor 2380 by an insulation layer 2510. When current is supplied to the flat coil 2520 by a driver stage DRVL, which serves to supply the magnetic field generation means L_{C} in the form of the flat coil 2520 with electrical energy and/or to control the magnetic field generation means L_{C} in the form of the flat coil 2520, the flat coil 2520 generates a magnetic field with an additional magnetic flux density B_{ad}. This additional magnetic flux density B_{ad} now flows through the center sensor element SE(1420) placed on the signal conductor 1330 of the exemplary microstrip line 1380 or the exemplary triplate line 2380. Thus, devices according to FIGS. 69 to 71 and 73 to 81 can use this flat coil 2520 as a magnetic field generation means L_{C} compensating and/or modulating and/or changing the total flux density BE. In order for the additional magnetic field with the additional magnetic flux density B_{ad} parallel to the surface of the electrically non-conductive carrier substrate 1360 within the central sensor element SE(1420) to be expressed, it is preferable that the magnetic field generated by the flat coil 2520 in a first partial flat coil to the left of the signal conductor 1330 of the exemplary microstrip line 1380 or of the exemplary triplate line 2380 and a second partial flat coil to the right of the signal conductor 1330 of the exemplary microstrip line 1380 or the exemplary triplate line 2380. Typically, the driver stage DRVL, which serves to supply the magnetic field generation means L_{C} in the form of the flat coil 2520 with electrical energy and/or to control the magnetic field generation means L_{C} in the form of the flat coil 2520, is energized, for generating the magnetic flux density B_{ad} parallel to the surface of the electrically non-conductive carrier substrate 1360 within the central sensor element SE(1420) such that the direction of the flux density vector of the magnetic field generated by the first sub-coil is opposite to the direction of the flux density vector generated by the second sub-coil.

Typically, the driver stage DRVL, which serves to supply the magnetic field generation means L_{C} in the form of the flat coil 2520 with electrical energy and/or to control the magnetic field generation means L_{c} in the form of the flat coil 2520, is energized, for generating the magnetic flux density B_{ad} perpendicular to the surface of the electrically non-conductive carrier substrate 1360 within the central sensor element SE(1420) such that the direction of the flux density vector of the magnetic field generated by the first sub-coil is aligned with the direction of the flux density vector generated by the second sub-coil.

This different current supply to the partial coils of the flat coil 2520 allows the driver stage DRVL to select whether and to what extent the left sensor element 1410 and the right sensor element 1430 on the one hand or the middle sensor element 1420 on the other hand should be influenced by the additional magnetic field with the magnetic flux density B_{ad} generated by the flat coil 2520. The driver stage DRVL can thus adjust the directional sensitivity of the left sensor element 1410 and the right sensor element 1430 on the one hand or the middle sensor element 1420 on the other hand by the different current supply of the partial flat coils of the flat coil 2520.

Thus, devices according to FIGS. 69 to 71 and 73 to 81 can use this flat coil 2520 as a magnetic field generation means L_{c} compensating and/or modulating and/or changing the vector 1440 of the magnetic flux density B_{μW} of the microwave field of the microwave signal μW. Again, the microwave signal source μWG feeds the microwave signal μW the signal line 1330 of the trip-plate waveguide 2380. Here, the vector 1450 of the magnetic flux density B_{μW} of the microwave field of the microwave signal μW represents the total flux density B_{Σ}, which penetrates the middle sensor element SE(1420).

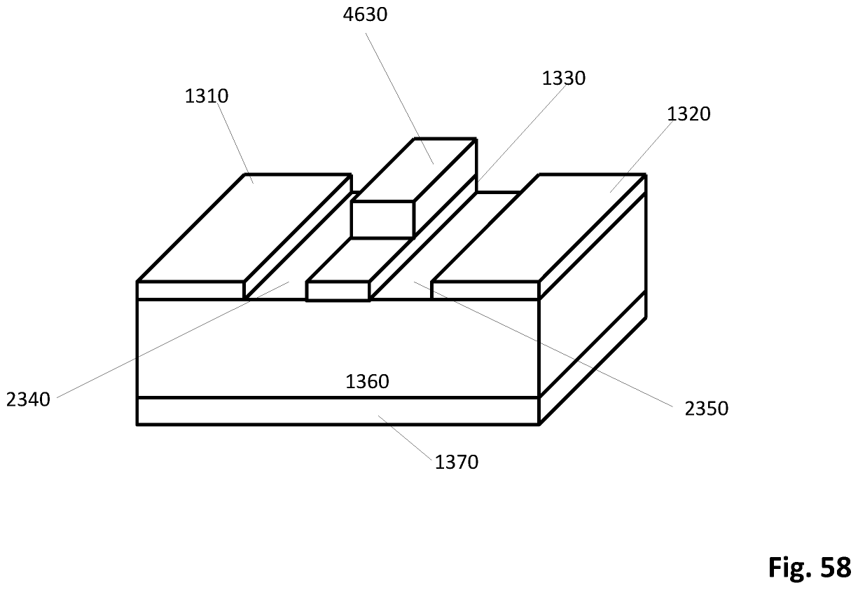

### FIGS. 58 to 61

FIGS. 58 to 61 illustrate the fabrication of the center sensor element SE(1320) at the second end of the center optical waveguide LWL (4630). The method can also be used in an analogous manner for the fabrication of a left sensor element SE(1310) at the second end of a left optical waveguide LWL (4610) and/or for the fabrication of a right sensor element SE(1320) at the second end of a right optical waveguide LWL (4610). In the description, only the corresponding designations need to be exchanged. They can also be used for other waveguides mentioned in this document and in the cited documents if the optical waveguides are preferably arranged essentially parallel to the conductors.

### FIG. 58

The method begins with the deployment of the carrier substrate 1360, wherein in the example of FIG. 47 the carrier substrate 1360 provided comprises the trip-plate waveguide 2380 with the electrically conductive left signal ground plane 1310 and the electrically conductive right signal ground plane 1320 and the center signal conductor 1330 and the electrically conductive backside contact 1370 as well as, by way of example, the center optical waveguide LWL (4630). The second end of the central optical waveguide (LWL) (4630) is located here, by way of example, on the central signal conductor 1330.

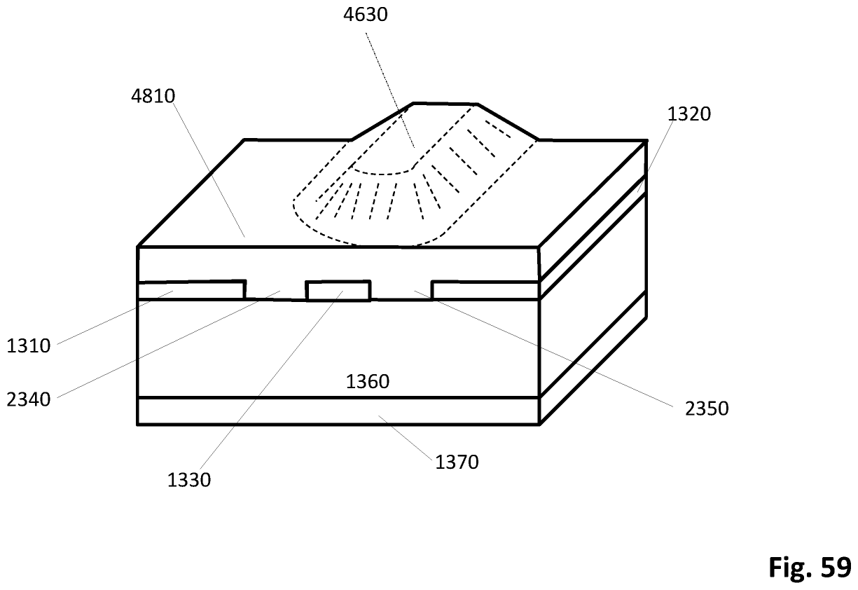

FIG. 59 in a subsequent step of the method, the surface of the carrier substrate 1360 is covered with the sensor element layer 4810. The sensor element layer 4810 preferably comprises one of this colloidal mixture (colloidal varnish KL) of the diamond nano crystals ND and the still liquid substrate material TM. The sensor element layer 4810 is thus preferably filled with diamond nano crystals ND. Preferably, the diamond nano crystals ND comprise paramagnetic centers which, upon exposure to electromagnetic pump radiation LB of the pump radiation wavelength λ₍ₚₘₚ₎, emit fluorescence radiation FL with a fluorescence radiation wavelength λ_{fl}. Preferably, the paramagnetic centers are NV centers. If necessary, the surface of the carrier substrate 1360 is pretreated, for example by plasma termination and/or by an adhesion promoter layer, in order to ensure good wetting of the surface of the carrier substrate 1360 by the still liquid substrate material TM. Preferably, the sensor element layer 4810 is cured, for example, by means of a temperature or storage step. This preferably performed temperature step then preferably cures the substrate material TM in order to stabilize it.

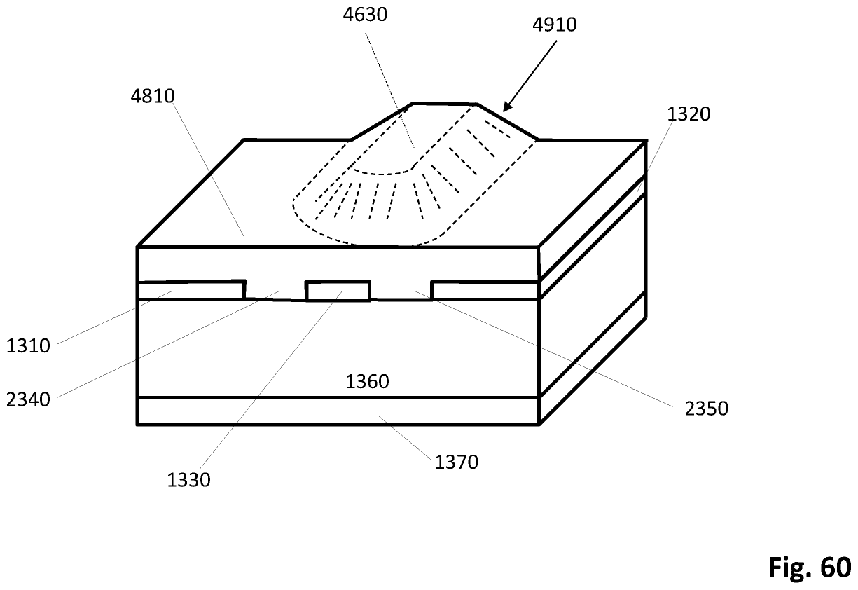

### FIG. 60

In a subsequent step of the method, a curing radiation source typically feeds the curing radiation 4910 with the curing wavelength λ_{H} into the first end of the central optical waveguide LWL (4630) via a central micro-optical coupling structure. In FIG. 49, the sensor element layer 4810 obscures the center optical waveguide LWL (4630), which is located below the sensor element layer 4810. The curing radiation 4910 then re-emerges from the center optical waveguide LWL (4630) at the second end of the center optical waveguide LWL (4630) and enters the bulk of the sensor element layer 4810. As a result, the curing radiation 4910 exposes the initially still liquid or cured substrate material TM of the sensor element layer 4810 to electromagnetic curing radiation 4910 of the curing wavelength λ_{H}. This solidifies the substrate material TM of the sensor element layer 4810 into solidified substrate material TM of the sensor element layer 4810. As a result, the later middle sensor element SE(1320) is already formed in the sensor element layer 4810.

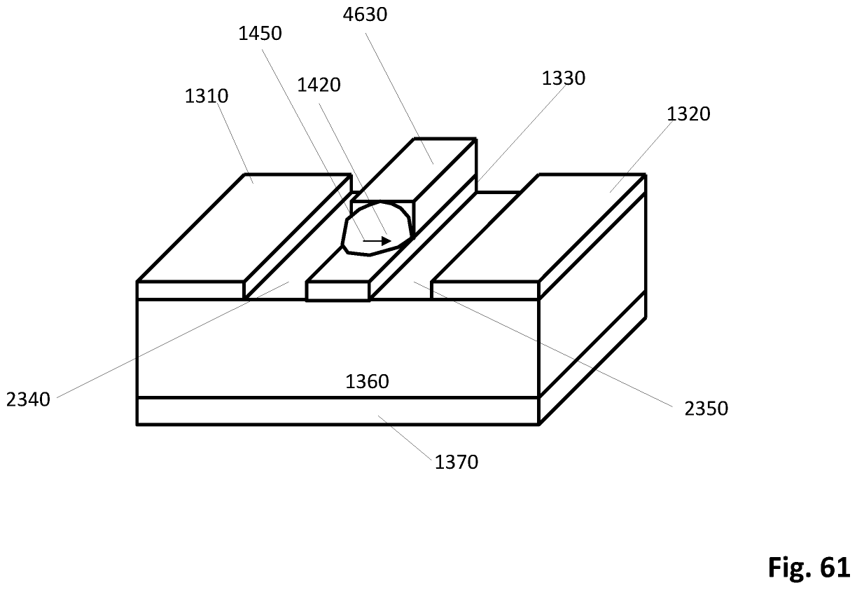

### FIG. 61

In a subsequent step of the method, the already formed central sensor element SE(1320) is now exposed by cleaning with a solvent. The cleaning with the solvent removes the regions of the sensor element layer 4810 that are not or not sufficiently exposed to electromagnetic curing radiation 4910 of the curing wavelength λ_{H}. The remaining middle sensor element SE(1320) is self-aligned and optimally optically coupled to the middle optical waveguide LWL (4630). The special feature of the middle optical waveguide LWL (4630) proposed in the document presented here is that the substrate material TM is a substrate material TM cured by means of electromagnetic curing radiation 4910 and that the substrate material TM is essentially transparent after curing to electromagnetic radiation with a pump radiation wavelength λₚₘₚ of the pump radiation LB, with which the NV centers and/or the other paramagnetic centers in the diamond nano crystals ND are pumped. Preferably, after curing, the substrate material TM is essentially transparent to electromagnetic radiation with a fluorescence radiation wavelength λ_{fl} of the fluorescence radiation FL, with which the NV centers and/or the other paramagnetic centers in the diamond nano crystals ND fluoresce upon exposure to electromagnetic radiation with a pump radiation wavelength λₚₘₚ of the pump radiation LB. Essentially means in each case that the losses that undoubtedly occur are still so small that the functionality of the application in question is still given. By curing a previously liquid or cured carrier medium TM, the production of such a medium optical waveguide LWL (4630) is particularly simple and process-reliable with a high Cₚₖ value

If the second end of the optical waveguide LWL (4630) is thus encased by the substrate material TM of the sensor element 4810, this results in particularly good stabilization of this optical coupling.

Preferably, one end face of the second end of the optical waveguide LWL (4630) forms a planar end face perpendicular to the centerline of the optical waveguide LWL (4630). The centerline typically corresponds to the optical axis of the optical waveguide LWL (4630). Such an end face enables improved decoupling of the electromagnetic pump radiation LB from the optical waveguide LWL (4630) and improved optical coupling of the fluorescence radiation FL into the optical waveguide LWL (4630). Preferably, therefore, the optical fiber LWL (4630) is formed by a suitable etching process (e.g., DRIE or RIE etching) that preferably produces vertical flanks. Preferably, the distance of one or preferably more crystals and/or diamond nano crystals ND from said planar end face is less than the pump radiation wavelength pmp and/or preferably less than ½ of the pump radiation wavelength λₚₘₚ, and/or preferably less than ¼ of the pump radiation wavelength λₚₘₚ, and/or preferably less than ⅛ of the pump radiation wavelength λₚₘₚ, and/or preferably less than 1/10 of the pump radiation wavelength λₚₘₚ, and/or better than 1/20 of the pump radiation wavelength λₚₘₚ, better than 1/50 of the pump radiation wavelength λₚₘₚ, and/or better than 1/100 of the pump radiation wavelength λₚₘₚ, and/or better than 1/200 of the pump radiation wavelength λₚₘₚ, and/or better than 1/500 of the pump radiation wavelength λₚₘₚ, and/or better than 1/1000 of the pump radiation wavelength λₚₘₚ.

The center line, which is an imaginary auxiliary construction to clarify the matter, pierces the end face at a center point of the end face. The thickness dₗ of the substrate material TM is preferably thicker at this center point than the thickness dᵣ at other points of the end face of the second end of the optical waveguide LWL (4630). This has the advantage that light is reflected back through the substrate material TM/air interface into the optical waveguide LWL (4630) and that the efficiency and effectiveness of the light coupling then increases.

Preferably, therefore, the substrate material TM forms a lens at the second end of the optical waveguide LWL (4630). The diameter D_{LWLL} of the lens is preferably, but not necessarily, smaller than the diameter of the optical waveguide LWL (4630). FIG. 66 shows a sensor element whose diameter or lens diameter is larger than the diameter D_{LWL} of the optical waveguide LWL (4630). FIG. 61, on the other hand, shows a sensor element 1420 whose diameter or lens diameter D_{LWLL} is smaller than the diameter of the optical waveguide LWL (4630). However, the diameter D_{LWLL} of the lens can also be as large as the diameter D_{LWL} of the optical waveguide LWL (4630).

Preferably, the optical waveguide LWL (4630) is completely or partially encased and/or covered in a light-tight manner by a mechanical sheath MH, which can also have the sole purpose of preventing crosstalk between different optical waveguides of the device. The mechanical sheath MH is preferably made of glass or ceramic, plastic or the like and is opaque to relevant electromagnetic radiation. The mechanical sheath MH therefore preferably comprises a ceramic material or a plastic material or another non-magnetizable and/or electrically non-conductive material and/or a material that is stable at temperatures above 100° C. and/or a material that is stable at temperatures above 140° C. and/or a material that is stable at temperatures above 170° C. and/or a material that is stable at temperatures above 200° C. and/or a material that is stable at temperatures above 250° C. or comprises these or consists of these in extreme cases. The mechanical sheath MH can thus be made of a ceramic material or a plastic material or of another non-magnetizable and/or electrically non-conductive material and/or of a material stable at temperatures above 100° C. and/or of a material stable at temperatures above 140° C. and/or of a material stable at temperatures above 170° C. and/or of a material stable at temperatures above 200° C. and/or of a material stable at temperatures above 250° C.

Preferably, the mechanical sheath MH forms, at least in sections, a tube or pipe or a capillary or a cannula or a cover of the optical waveguide LWL (4630), which encases or at least partially or completely covers the respective optical waveguide LWL (4630). This simplifies the production of the system consisting of optical waveguide, sensor element SE(1420) and mechanical sheath MH. The inner diameter Dro of such a tube or such a cover or such a tube or such a capillary or such a cannula is preferably only a little larger or the same size as the diameter of the optical waveguide lens and the diameter of the optical waveguide LWL (4630).

The optical waveguide LWL (4630) typically comprises an optical waveguide core LWLC). In the substrate material TM, the substrate material TM preferably forms an optical functional element at the second end of the optical waveguide LWL (4630). This again improves the said optical coupling between optical waveguide LWL (4630) and substrate material TM. The optical functional element then interacts optically with the optical waveguide core of the optical waveguide LWL (4630) at the second end of the optical waveguide LWL (4630).

Preferably, the optical functional element comprises an optical waveguide lens, in particular in the form of a thickening of the substrate material TM in the region of the optical functional element.

Now, the essential feature of the present document is that it also describes and discloses a method for the fabrication of an optical waveguide LWL (4630) as previously described and used. The proposed method comprises the steps of (See FIG. 153):
Deploying 15310 an optical waveguide LWL (4630), wherein the optical waveguide LWL (4630) comprises a first end and a second end;
Deployment 15320 of a liquid substrate material TM which is curable by means of electromagnetic radiation of a curing radiation 4910 with a curing wavelength λ_{H}, wherein a multiplicity of crystals and/or diamond nano crystals ND, preferably nano-diamonds, are embedded in the substrate material TM and wherein one or more or all of the crystals and/or diamond nano crystals ND have NV centers and/or other paramagnetic centers and wherein the NV centers of the crystals and/or diamond nano crystals ND have NV centers and/or other paramagnetic centers and wherein the NV centers of the crystals and/or diamond nano crystals ND have NV centers and/or other paramagnetic centers, are embedded in the substrate material TM and wherein one or more or all of the crystals and/or diamond nano crystals ND comprise NV centers and/or other paramagnetic centers and wherein the NV centers of the crystals and/or diamond nano crystals ND of the substrate material TM and/or the other paramagnetic centers of the crystals and/or diamond nano crystals ND of the substrate material TM emit at least one fluorescence radiation FL upon exposure to pump radiation LB;
Wetting 15330 of the second end of the optical waveguide LWL (4630) at least to a wetting length LTM With the substrate material TM comprising the multiplicity of embedded crystals and/or diamond nano crystals ND with NV centers and/or paramagnetic centers;
Injecting 15340 electromagnetic radiation into the first end of the optical waveguide LWL (4630), the wavelength of this electromagnetic radiation, the curing wavelength λ_{H}, being selected such that the substrate material TM at the second end of the optical waveguide LWL (4630) cures and transforms into a solid.

Removal 15350 of the uncured substrate material TM, in particular by means of a solvent LM, the remaining film of the substrate material TM at the second end of the optical waveguide LWL (4630) forming the sensor element SE.

Typically, the substrate material TM only partially hardens, which enables the formation of the optical functional elements and the sensor element SE.

Thus, a middle optical waveguide LWL (4630) is now placed on the electrically conductive signal line 1330 of the trip-plate waveguide 2380 in an exemplary self-aligning manner. The document presented here thus proposes to combine this central optical waveguide LWL (4630) with a central sensor element SE(1420). Thereby, the center sensor element SE(1420) comprises a substrate material TM in which a multiplicity of diamond nano crystals ND are typically embedded. One or more or all diamond nano crystals ND of these diamond nano crystals ND comprise one or more NV centers and/or one or more other paramagnetic centers. The NV centers of the central sensor element SE(1420) and/or the other paramagnetic centers of the central sensor element SE(1420) emit at least one fluorescence radiation FL. with a fluorescence radiation wavelength λ_{fl} when exposed to pump radiation LB with a pump radiation wavelength λₚₘₚ. The special feature of the central optical waveguide LWL (4630) proposed in the document presented here is that the substrate material TM is preferably a substrate material TM cured by means of electromagnetic radiation (curing radiation 4910) and that the substrate material TM after curing for electromagnetic radiation with a pump radiation wavelength λₚₘₚ of the pump radiation LB, with which the NV centers of the central sensor element SE(1420) and/or the other paramagnetic centers of the central sensor element SE(1420) are pumped by one of the proposed devices, is essentially transparent. Here, essentially means that the losses that undoubtedly occur are still so small that the functionality of the application in question is still given. In the same way, the substrate material TM should be essentially transparent to radiation with a fluorescence wavelength λ_{FL} of the fluorescence radiation LB of the NV centers of the central sensor element SE(1420) and/or of the other paramagnetic centers of the central sensor element SE(1420). Essentially means, in turn, that the losses that undoubtedly occur are still so small that the functionality of the application in question is still given. For the fabrication of the central sensor element SE(1420), the surface of the carrier substrate 1360 is connected to the central electrically conductive signal line 1330 of the trip-plate waveguide 2380 and the other lines 1310, 1320 of the trip-plate waveguide 2380 and with the central optical waveguide LWL (4630) a colloidal mixture (colloidal varnish KL) of the diamond nano crystals ND with paramagnetic centers and/or NV centers and crystals with paramagnetic centers on the one hand and the still liquid substrate material TM on the other hand as sensor element layer 4810 via the central electrically conductive signal line 1330 of the trip-plate waveguide 2380 and the other lines 1310, 1320 of the trip-plate waveguide 2380 and the central optical waveguide (LWL) (4630). If necessary, the varnish layer of the colloidal mixture (colloidal varnish KL) is cured in a subsequent temperature step to stabilize it.

The manufacturing process of the middle sensor element SE(1420) preferably comprises in a subsequent manufacturing step the local exposure of this colloidal mixture (colloidal varnish KL) of the diamond nano crystals ND and the still liquid substrate material TM of the sensor element layer 4810 with an electromagnetic curing radiation 4910 of the curing wavelength λ_{H}. The local exposure of this colloidal mixture (colloidal varnish KL) of the diamond nano crystals ND and the still liquid substrate material TM of the sensor element layer 4810 with an electromagnetic curing radiation 4910 of the curing wavelength λ_{H} is preferably limited to the region of the sensor element layer 4810 at the second end of the central optical waveguide LWL (4630). Preferably, the electromagnetic curing radiation 4910 of the curing wavelength λ_{H} is UV radiation. For example, the region of the sensor element layer 4810 exposed to the electromagnetic curing radiation 4910 of the curing wavelength λ_{H} can be limited by a mask 5410, which has been adjusted in a preceding adjustment step with respect to adjustment marks (5210, 5220) on the surface of the carrier substrate 1360 and aligned, for example, in a mask aligner (mask adjustment and alignment device). Preferably, the carrier substrate 1360 thus comprises the lines 1310, 1320, 1330 of the trip-plate waveguide 2380 (or another possible microstrip line) and the adjustment marks (5210, 5220) for the adjustment of one or more exposure masks 5410. The exposure of the sensor element layer 4810, which comprises the colloidal mixture (colloidal varnish KL) of the diamond nano crystals ND and the still liquid or cured substrate material TM of the sensor element layer 4810, to electromagnetic curing radiation 4910 of the curing wavelength λ_{H} typically causes the previously liquid or cured substrate material TM to solidify. cured substrate material TM of the sensor element layer 4810 solidifies into solidified substrate material TM of the sensor element layer 4810 in the region of the sensor element layer 4810 exposed to the electromagnetic curing radiation 4910 of the curing wavelength λ_{H}. As a result, the middle sensor element SE(1430) is already formed within the sensor element layer 4810. In a typically subsequent process step, non-solidified areas of the sensor element layer 4810, which typically were not previously or only insufficiently exposed to curing radiation 4910 of the curing wavelength λ_{H}, can be removed by means of a solvent for the still liquid or cured carrier material TM. The finished center of the sensor element layer 4810 can be dissolved by means of a solvent for the still liquid or cured substrate material TM of the sensor element layer 4810 and removed from the surface of the carrier substrate 1360 and the other leads 1310, 1320, 1330 and from the electrically essentially non-conductive left insulation area 1340 and from the electrically essentially non-conductive right insulation area 1360 etc. on the surface of the carrier substrate 1360. The finished center sensor element SE(1320) remains. The fabrication of the center sensor element SE(1320) is particularly elegant if a curing radiation source feeds electromagnetic curing radiation 4910 of the curing wavelength λ_{H} into the center optical waveguide LWL (4630) during the fabrication process. Preferably, for the application of the technical teaching presented here, the central optical waveguide LWL (4630) comprises micro-optical structures on the surface of the carrier substrate 1360 which permit the coupling of such electromagnetic curing radiation 4910 of the curing wavelength λ_{H} into the central optical waveguide LWL (4630) in the manufacturing process. Preferably, these micro-optical structures serve to allow the coupling of such electromagnetic curing radiation 4910 of the curing wavelength λ_{H} into the central optical waveguide LWL (4630) during the manufacturing process, later also for coupling the pump radiation LB of the pump radiation wavelength λₚₘₚ into the central optical waveguide LWL (4630) and/or for coupling the fluorescence radiation FL of the fluorescence radiation wavelength λ_{fl} out of the central optical waveguide LWL (4630). Preferably, the surface of the carrier substrate 1360 thus comprises micro-optical structures configured to feed electromagnetic curing radiation 4910 of the curing wavelength λ_{H} into the central optical waveguide LWL (4630) during the manufacturing process. Preferably, in the regions of the surface of the carrier substrate 1360 comprising these micro-optical structures configured to inject electromagnetic curing radiation 4910 of the curing wavelength λ_{H} into the central optical waveguide LWL (4630) in the manufacturing process, the sensor element layer 4810 is removed locally before the curing of the sensor element layer 4810. It is also conceivable, for example, to apply the sensor element layer 4810 in a roughly pre-structured manner by means of a dispenser or by means of screen printing only in the region of the second ends of the central optical waveguide LWL (4630), so that this removal is not necessary from the outset. In the manufacturing process, electromagnetic curing radiation 4910 of the curing wavelength λ_{H} is now fed into the central optical waveguide LWL (4630) at a first end of the central optical waveguide LWL (4630), for example by means of the said micro-optical structures, which allow such electromagnetic curing radiation 4910 of the curing wavelength λ_{H} to be coupled into the central optical waveguide LWL (4630) in the manufacturing process. The center optical waveguide LWL (4630) transports the electromagnetic curing radiation 4910 of the curing wavelength λ_{H} from the first end of the center optical waveguide LWL (4630) to the second end of the optical waveguide LWL (4630). The electromagnetic curing radiation 4910 of the curing wavelength λ_{H} then typically exits the other, second end of the center optical waveguide LWL (4630). Preferably, the second end of the center optical waveguide LWL (4630) is covered with a region of the sensor element layer 4810. The electromagnetic curing radiation 4910 of the curing wavelength λ_{H} exposes the still liquid substrate material TM of the sensor element layer 4810 and thus cures the still liquid substrate material TM of the sensor element layer 4810 to solidified substrate material TM of the sensor element layer 4810. In the said process step, which typically then follows, non-solidified regions of the sensor element layer 4810, which typically have not been or only insufficiently exposed to curing radiation 4910 of the curing wavelength λ_{H}, can be cured by means of a solvent for the still liquid carrier material TM of the sensor element layer 4810, dissolved by means of a solvent for the still liquid substrate material TM of the sensor element layer 4810 and removed from the surface of the carrier substrate 1360 and from the other leads 1310, 1320, 1330 and from the electrically essentially non-conductive left insulation area 1340 and from the electrically essentially non-conductive right insulation area 1360 etc. on the surface of the carrier substrate. on the surface of the carrier substrate 1360. The finished middle sensor element SE(1420) remains again, but is now manufactured in an optimal and self-aligning manner with respect to the second end of the middle optical waveguide LWL (4630). Due to this curing of a previously liquid and possibly cured carrier medium TM, the production of the middle sensor element SE(1420) with respect to the second end of such a middle optical waveguide LWL (4630) is particularly easy and process-reliable in a self-aligning manner with a high Cₚₖ value.

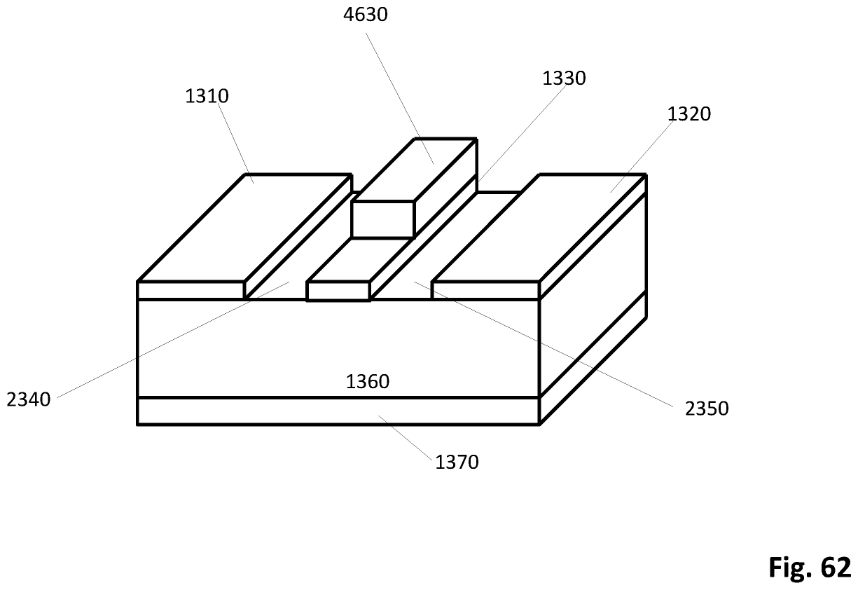

### FIGS. 62 to 66

FIGS. 62 to 66 illustrate the fabrication of the center sensor element SE(1320) at the second end of the center optical waveguide LWL (4630) by means of a mask-controlled method. The method can also be used in an analogous manner for the fabrication of a left sensor element SE(1310) at the second end of a left optical waveguide LWL (4610) and/or for the fabrication of a right sensor element SE(1310) at the second end of a right optical waveguide LWL (4610). This manufacturing principle can be transferred in an analogous and functionally equivalent manner to the fabrication of other sensor elements by a person skilled in the art. In the description, only the corresponding designations need to be exchanged.

### FIG. 62

The method again begins with the deployment of the carrier substrate 1360, wherein in the example of FIG. 62 the carrier substrate 1360 provided comprises the trip-plate waveguide 2380 with the electrically conductive left signal ground plane 1310 and the electrically conductive right signal ground plane 1320 and the center signal conductor 1330 and the electrically conductive backside contact 1370 as well as, by way of example, the center optical waveguide LWL (4630). The second end of the central optical waveguide (LWL) (4630) is located here, by way of example, again on the central signal conductor 1330.

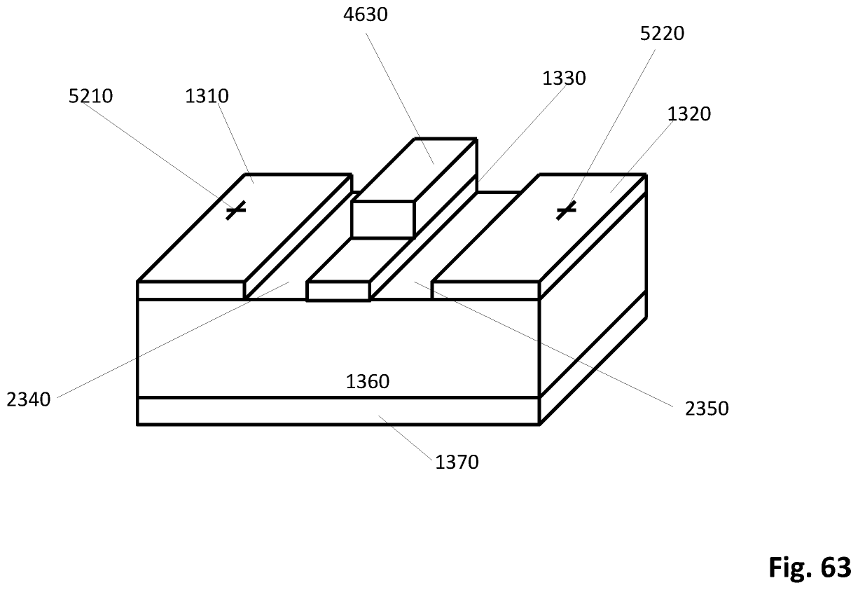

### FIG. 63

In order to carry out the mask-based method proposed herein, the surface of the carrier substrate 1360 is provided with one or more adjustment marks 5210, 5220. The adjustment marks 5210, 5220 may also have been made in a previous process step. For example, it is conceivable to fabricate one or more left adjustment marks 5210 together with the electrically conductive left signal ground plane 1310 of the exemplary triplate line 2380. For example, it is conceivable to manufacture one or more right-hand adjustment marks 5220 together with the electrically conductive right-hand signal ground plane 1320 of the exemplary triplate line 2380.

### FIG. 64

in a subsequent step of the method, the surface of the carrier substrate 1360 is partially covered with the sensor element layer 4810. This can be done, for example, by screen printing and/or a dispenser. The sensor element layer 4810 preferably comprises one of this colloidal mixture (colloidal varnish KL) of the diamond nano crystals ND and the still liquid substrate material TM. The sensor element layer 4810 is thus preferably filled with diamond nano crystals ND. Preferably, the diamond nano crystals ND comprise paramagnetic centers which, upon exposure to electromagnetic pump radiation LB of the pump radiation wavelength λ₍ₚₘₚ₎, emit fluorescence radiation FL with a fluorescence radiation wavelength λ_{fl}. Very preferably, the paramagnetic centers are NV centers. If necessary, the surface of the carrier substrate 1360 is pretreated, for example by plasma termination and/or by an adhesion promoter layer, in order to ensure good wetting of the surface of the carrier substrate 1360 by the still liquid substrate material TM. If necessary, the substrate material TM of the sensor element layer 4810 is hardened in a further step, for example in a subsequent temperature or storage step.

### FIG. 65

In a subsequent step of the method, a curing radiation source typically exposes the sensor element layer 4810 to curing radiation 4910 of the curing wavelength λ_{H}. In FIG. 65, the sensor element layer 4810 obscures the center optical waveguide (LWL) (4630), which is located below the sensor element layer 4810. In FIG. 65, a shadow mask 5410 structures the curing radiation 4910. Typically, the shadow mask 5410 comprises some transmission regions 5420 that are transparent to the electromagnetic curing radiation 4910 of the curing wavelength λ_{H}. The remaining regions of the shadow mask 5410 are typically not essentially transparent to the electromagnetic curing radiation 4910 of the curing wavelength λ_{H}. In the region of the transmission areas 5420, the curing radiation source then irradiates the sensor element layer 4810 with electromagnetic curing radiation 4910 of the curing wavelength λ_{H} in irradiated areas of the sensor element layer 4810. This curing radiation 4910 enters the bulk of the sensor element layer 4810 in these irradiated areas of the sensor element layer 4810. As a result, the curing radiation 4910 irradiates the initially still liquid substrate material TM of the sensor element layer 4810 in these irradiated areas of the sensor element layer 4810 with electromagnetic curing radiation 4910 of the curing wavelength λ_{H}. As a result, the cured substrate material TM of the sensor element layer 4810 solidifies in these irradiated areas of the sensor element layer 4810 to form solidified substrate material TM of the sensor element layer 4810. As a result, the later middle sensor element SE(1320) is already formed in the sensor element layer 4810.

The problem, however, is that the method is not self-adjusting and therefore comprises higher tolerances.

### FIG. 66

In a subsequent step of the method, the already formed central sensor element SE(1320) is now exposed by cleaning with a solvent. The cleaning with the solvent removes the regions of the sensor element layer 4810 that are not or not sufficiently exposed to electromagnetic curing radiation 4910 of the curing wavelength λ_{H}. The remaining middle sensor element SE(1320) is optically coupled to the middle optical waveguide LWL (4630) when the mask 5410 is correctly adjusted with respect to the carrier substrate 1360. The special feature of the middle optical waveguide LWL (4630) proposed in the present document is that the substrate material TM is a substrate material TM cured by means of electromagnetic curing radiation 4910 and that the substrate material TM is essentially transparent after curing to electromagnetic radiation with a pump radiation wavelength λₚₘₚ of the pump radiation LB, with which the NV centers and/or the other paramagnetic centers in the diamond nano crystals ND are pumped. Preferably, after curing, the substrate material TM is essentially transparent to electromagnetic radiation with a fluorescence radiation wavelength λ_{fl} of the fluorescence radiation FL, with which the NV centers and/or the other paramagnetic centers in the diamond nano crystals ND fluoresce upon exposure to electromagnetic radiation with a pump radiation wavelength λₚₘₚ of the pump radiation LB. Essentially means in each case that the losses that undoubtedly occur are still so small that the functionality of the application in question is still given. By curing a previously liquid carrier medium TM, the production of such a medium optical waveguide LWL (4630) is particularly easy and process-reliable with an acceptable Cₚₖ value.

With regard to the substrate material TM, the document presented here refers to the other descriptions of the substrate material TM in this document.

Now, the essential feature of the present document is that it also describes and discloses a method for the fabrication of an optical waveguide LWL (4630) as previously described and used. The proposed method comprises the steps of:
deploying 15410 an optical waveguide LWL (4630), wherein the optical waveguide LWL (4630) comprises a first end and a second end;
deployment 15420 of a liquid substrate material TM which is curable by means of electromagnetic radiation (curing radiation 49₁₀) of a curing wavelength λ(H), wherein a multiplicity of crystals and/or diamond nano crystals ND, preferably nano-diamonds, are embedded in the substrate material TM and wherein one or more or all of the crystals and/or diamond nano crystals ND have NV centers and/or other paramagnetic centers and wherein the NV centers of the crystals and/or diamond nano crystals ND have NV centers and/or other paramagnetic centers, and wherein one or more or all of the crystals and/or diamond nano crystals ND comprise NV centers and/or other paramagnetic centers and wherein the NV centers of the crystals and/or diamond nano crystals ND of the carrier material TM are embedded in the carrier material TM.crystals ND of the substrate material TM and/or the other paramagnetic centers of the crystals and/or diamond nano crystals ND of the substrate material TM emit at least one fluorescence radiation FL with a fluorescence radiation wavelength λ_{fl} upon exposure to pump radiation LB with a pump radiation wavelength pmp;
coating 15430 the second end of the optical waveguide LWL (4630) at least to a wetting length L_{TM} with the substrate material TM comprising the multiplicity of embedded crystals and/or diamond nano crystals ND with NV centers and/or paramagnetic centers;
adjustment 15440 of an exposure mask 5410 in relation to the carrier substrate 1360;
exposure 15450 of the second end of the optical waveguide LWL (4630) through the exposure mask 5410 to electromagnetic radiation (curing radiation 4910), the wavelength of this electromagnetic radiation, the curing wavelength λ_{H}, being selected such that the substrate material TM at the second end of the optical waveguide LWL (4630) cures and transforms into a solid; and
removal 15460 of the uncured substrate material TM, in particular by means of a solvent LM, the remaining film of the substrate material TM at the second end of the optical waveguide LWL (4630) at least partially forming the sensor element SE.

Typically, the substrate material TM only partially hardens, which enables the formation of the optical functional elements and the sensor element SE.

The radiation of the curing radiation 4910 irradiated at the second end of the optical waveguide LWL (4630) for curing is preferably UV radiation. A curing radiation 4910 for curing with a curing wavelength λ_{H} between 320-380 nm is particularly preferred.

In certain applications, nanoparticles with a diameter smaller than 200 nm and/or smaller than 100 nm and/or smaller than 50 nm and/or smaller than 20 nm and/or smaller than 10 nm and/or smaller than 5 nm can be added to the substrate material TM before deployment, so that these are embedded in the substrate material TM after curing. Preferably, these are metallic nanoparticles. In this context, the document presented here refers to the other descriptions of these nanoparticles, which should also apply here.

### FIG. 67

FIG. 67 corresponds to FIG. 61 supplemented by a flat coil 2520 as magnetic field generation means L_{C}. Said flat coil 2520 is only one example of a possible magnetic field generation means L_{C}. The flat coil 2520 may comprise multiple turns and multiple layers. In FIG. 67, the flat coil 2520 is electrically insulated from the electrically conductive backside contact 1370 of the exemplary triplate conductor 2380 by an insulation layer 2510. The flat coil 2520 generates a magnetic field with an additional magnetic flux density B_{ad} when current is supplied by a driver stage DRVL, which serves to supply the magnetic field generation means L_{C} in the form of the flat coil 2520 with electrical energy and/or to control the magnetic field generation means L_{C} in the form of the flat coil 2520.

This additional magnetic flux density B_{ad} now flows through the middle sensor element SE(1420) placed on the signal conductor 1330 of the exemplary microstrip line 1380 or the exemplary triplate line 2380.

Thus, devices according to FIGS. 69 to 71 and 73 to 81 can use this flat coil 2520 as a magnetic field generation means L_{C} compensating and/or modulating and/or changing the total flux density B_{Σ}.

Thus, devices according to FIGS. 69 to 71 and 73 to 81 can use this flat coil 2520 as a magnetic field generation means L_{C} compensating and/or modulating and/or changing the vector 1450 of the magnetic flux density B_{μW} of the microwave field of the microwave signal μW which the microwave signal source μWG feeds into the signal line 1330 of the trip-plate waveguide 2380.

Here, the vector 1450 represents the magnetic flux density B_{μW} of the microwave field of the microwave signal μW that penetrates the middle sensor element SE(1420).

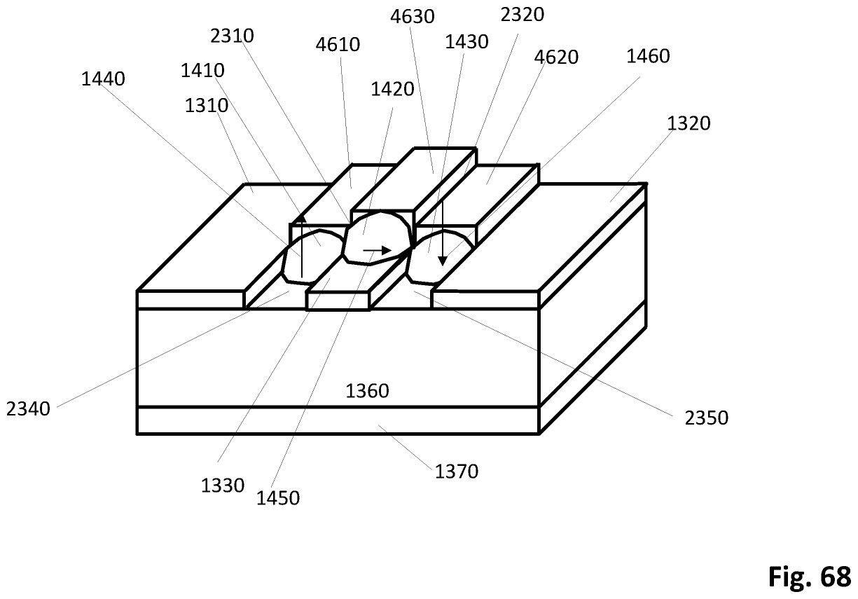

### FIG. 68

FIG. 68 applies the principles of sensor element manufacture to all three sensor elements (1410, 1420, 1430). Corresponding to these are three optical waveguides (4610, 4620, 4630), which are optically isolated from each other, preferably by means of diaphragms etc.

With regard to the manufacturing methods of the right sensor element SE(1430) and the left sensor element SE(1410) and the center sensor element SE(1420), the document presented here refers to the descriptions of FIGS. 58 to 66, wherein the methods described therein for the fabrication of the middle sensor element SE(1420) in functional connection with the middle optical waveguide LWL (4630) can now be applied here to the fabrication of the right sensor element SE(1430) in connection with the right optical waveguide LWL (4620) and to the fabrication of the left sensor element SE(1410) in connection with the left optical waveguide LWL (4610) and to the fabrication of the middle sensor element SE(1420) in connection with the middle optical waveguide LWL (4630).

### FIG. 69

FIG. 69 shows an exemplary, schematic and simplified device for the control, measurement and evaluation of exemplary sensor heads, as shown in FIGS. 54 to 68, if they comprise a sensor element SE. The document presented here also refers to such devices as measuring devices.

The measurement device of FIG. 69 comprises a sensor head comprising an exemplary carrier substrate 1360 with an exemplary trip-plate waveguide 2380. The document presented here indicates that other high-frequency strip lines such as microstrip lines 1380, or slot lines 1880, or differential microstrip lines 6830, or differential trip-plate waveguides 7080, for example, may be used instead of the trip-plate line 2380.

The trip-plate waveguide 2380 in the example of FIG. 69 comprises a preferably non- or only slightly electrically conductive, preferably dielectric carrier substrate 1360, typically an electrically conductive backside contact 1370 not shown here on the underside of the electrically non-conductive carrier substrate 1360, an electrically conductive left signal ground plane 1310 on the upper side of the electrically non-conductive carrier substrate 1360, an electrically conductive right signal ground plane 1320 on the upper side of the electrically non-conductive carrier substrate 1360, an electrically conductive signal line 1330 on the upper side of the electrically non-conductive carrier substrate 1360 between the electrically conductive left signal ground plane 1310 and the electrically conductive right signal ground plane 1320. Here, an electrically essentially non-conductive left insulation gap 2340 separates the electrically conductive signal line 1330 from the electrically conductive left signal ground plane 1310. In addition, an electrically essentially non-conductive right insulation gap 2350 separates the electrically conductive signal line 1330 from the electrically conductive right signal ground plane 1320. Preferably, the trip-plate waveguide 2380 comprises a characteristic impedance with respect to the electrically conductive signal line 1330 as “hot” inner conductor and the community of electrically conductive left signal ground plane 1310, electrically conductive right signal ground plane 1320 and electrically conductive backside contact 1370 as ground electrodes.

For example, a microwave signal source μWG generates a microwave signal μW and feeds it into the waveguide, here the exemplary trip-plate waveguide 2380. The magnetic field with a magnetic flux density B_{μW} of the microwave field of the microwave signal μW acts on the sensor element SE. Preferably, the waveguide, in this case the exemplary trip-plate waveguide 2380, is terminated at its end facing away from the microwave signal source μWG by means of one or more terminal resistors 6710 in an anechoic manner with the characteristic impedance of the waveguide, in this case the exemplary trip-plate waveguide 2380, or is provided with a microwave-capable coupling. These terminal resistors are not shown in FIG. 69, but are part of the claim. By using terminal resistors 6710 at the end of the waveguide facing away from the microwave signal source μWG, here the exemplary trip-plate waveguide 2380, the end of the waveguide facing away from the microwave signal source μWG, here the exemplary trip-plate waveguide 2380, reflects very little power back towards the sensor element SE and microwave signal source μWG. By using terminal resistors 6710 at the end of the waveguide facing away from the microwave signal source μWG, here the exemplary trip-plate waveguide 2380, the microwave signal μW acting on the sensor element SE can therefore be very precisely generated and controlled by the microwave signal source μWG. In addition, this design avoids unnecessary heating of the sensor element SE and thus of the substrate material TM. Preferably, the internal impedance of the microwave signal source μWG essentially corresponds to the characteristic impedance of the waveguide, here the exemplary trip-plate waveguide 2380. As a result, the microwave signal source μWG reflects only little power back towards the sensor element SE and the terminal resistors 6710.

The sensor element SE typically comprises a multiplicity of diamond nano crystals ND and/or crystals in the solidified substrate material TM. One or more or all of the diamond nano crystals ND of these diamond nano crystals ND typically comprise one or more NV centers and/or one or more other paramagnetic centers. One or more or all crystals of these crystals typically comprise one or more other paramagnetic centers. The NV centers of the sensor element SE and/or the other paramagnetic centers of the sensor element SE typically emit at least one fluorescence radiation FL. with a fluorescence radiation wavelength λ_{fl} upon exposure to pump radiation LB with a pump radiation wavelength λₚₘₚ.

The sensor element SE may, for example, be one or more of the sensor elements SE shown in FIGS. 54 to 68.

The total magnetic flux density B_{Σ} flows through the sensor element SE. Typically, the total flux density B_{Σ} influences the intensity of the fluorescence radiation LB emitted by the NV centers of the sensor element SE and/or the other paramagnetic centers of the sensor element SE.

A light source LED serves as a pump radiation source for the pump radiation LB with the pump radiation wavelength λₚₘₚ. The pump radiation source, in this case the light source LED, exposes the sensor element SE to the pump radiation LB with the pump radiation wavelength λₚₘₚ via an optical waveguide (LWL). The LED light source can be a light-emitting diode or a laser, for example. A transmission signal S5 for modulating the light source LED preferably controls the intensity of the pump radiation LB emitted by the light source LED.

Preferably, the transmission signal S5 is amplitude-modulated with an LED modulation signal S5w in its temporal course. Typically, the time-modulated LED modulation signal of the transmission signal S5 comprises an LED modulation spectrum in the frequency domain. For example, the LED modulation signal S5w can be a PWM modulation signal with a PWM period duration and a duty cycle. Also, the LED modulation signal S5w may be a spreading code signal based on a sequence of a first number of 1-bits and a second number of 0-s, wherein the bits of the spreading code comprise a spreading code bit period duration and wherein the spreading code comprises a spreading code period duration. Typically, when a spreading code is used, this spreading code is repeated in the LED modulation signal S5w. The first number of 1 spreading code bits in a spreading code is preferably, but not necessarily, equal to the second number of 0 spreading code bits in the spreading code. The spreading code may also be of infinite length and generated by a random number generator (abbreviation RNG), which may be part of the device. The random number generator (abbreviation RNG) can be a pseudo-random number generator (abbreviation PRNG) based, for example, on a linear feedback shift register (abbreviation LFSR) or a true random number generator (abbreviation TRNG) or a quantum random number generator (abbreviation QRNG).

Typically, the temporal intensity profile of the intensity of the pump radiation LB emitted by the light source LED comprises a pump radiation intensity spectrum, which is usually a more or less deformed LED modulation spectrum. The deformation usually results from the non-linear behavior of the LED light source. If the LED modulation signal is monofrequent, the temporal intensity curve of the intensity of the pump radiation LB emitted by the light source LED is usually also monofrequent with the same LED transmission frequency f_{LED}.

A first optical system (here F1, LWL) detects the pump radiation LB of the pump radiation source, here the light source LED, and transports the pump radiation LB to the one or more sensor elements SE of the sensor head and exposes the sensor elements SE of the sensor head to this pump radiation LB. Preferably, the first optical system comprises an optical functional element, for example a coupling structure, for detecting the largest possible proportion of the pump radiation LB from the pump radiation source, in this case the light source LED. Preferably, the first optical system comprises an optical functional element, for example an output coupling structure, for exposing the sensor element SE to the largest possible proportion of the pump radiation LB of the pump radiation source, in this case the light source LED, detected by the first optical functional element. In the example of FIG. 69, an optical waveguide LWL) transports the pump radiation LB to the one or more sensor elements SE of the sensor head. Such a first optical system may comprise one or more optical functional elements, such as but not limited to lenses, prisms, apertures, filters, mirrors, beam splitters, dichroitic mirrors, photonic crystals, optical waveguides, etc.

The electromagnetic pump radiation LB with the pump radiation wavelength λₚₘₚ excites the NV centers or the paramagnetic centers in the sensor element SE to emit fluorescence radiation FL of the fluorescence wavelength λ_{(fl)}. Typically, the temporal intensity profile of the intensity of the fluorescence radiation FL emitted by the sensor element SE comprises a fluorescence radiation intensity spectrum. The fluorescence radiation intensity spectrum is usually a more or less deformed pump radiation intensity spectrum and therefore also a more or less deformed LED modulation spectrum. If the LED modulation signal is monofrequent, the temporal intensity curve of the intensity of the pump radiation LB emitted by the light source LED is usually also monofrequent with the LED modulation frequency f_{LED} and the temporal intensity curve of the intensity Iᵢₛₜ(t) of the fluorescence radiation FL emitted by the sensor element SE is also monofrequent with the same LED transmission frequency f_{LED}.

A second optical system (here F1, LWL) detects the fluorescence radiation FL of the sensor element SE and transports the fluorescence radiation FL to the one or more photo detectors PD and exposes the one or more photo detectors PD to this fluorescence radiation FL. Preferably, the second optical system comprises an optical functional element, for example a coupling structure, for detecting the largest possible proportion of the fluorescence radiation FL of the sensor element SE. Preferably, the second optical system comprises an optical functional element, for example an output coupling structure, for exposing the one or more photo detectors PD to the largest possible proportion of the fluorescence radiation FL of the sensor element SE detected by the second optical system. In the example of FIG. 69, an optical waveguide LWL) detects the fluorescence radiation LB and transports the detected fluorescence radiation LB to the one or more photo detectors PD. Typically, the second optical system comprises an optical functional element, for example a filter F1 and/or a dichroitic mirror, which prevent pump radiation LB from reaching the one or more photo detectors PD. Such a second optical system may comprise one or more optical functional elements, such as but not limited to lenses, prisms, apertures, filters F1, mirrors, beam splitters, dichroitic mirrors, photonic crystals, optical waveguides LWL, etc.

Preferably, the first optical system and the second optical system are identical for a large proportion of their device parts.

In the example of FIG. 69, the pump radiation source in the form of the light source LED emits the pump radiation LB with the pump radiation wavelength λₚₘₚ. A dichroitic mirror F1 as the first exemplary part of the first optical system allows the pump radiation LB to pass through. An optical waveguide LWL as the second exemplary part of the first optical system receives the pump radiation LB at its first end and transports the pump radiation LB to the second end of the optical waveguide LWL. The pump radiation LB emerges from the optical waveguide LWL at the second end of the optical waveguide LWL and exposes one or more sensor elements SE of the sensor head.

The pump radiation LB with the pump radiation wavelength λₚₘₚ thus irradiates the paramagnetic centers and/or the NV centers in the diamond nano crystals ND or crystals of the one or more sensor elements SE. The NV centers and/or paramagnetic centers in the diamond nano crystals ND irradiated in this way emit fluorescence radiation FL with a fluorescence wavelength λ_{fl} due to the exposure to the pump radiation LB. The fluorescence wavelength λ_{fl} is typically different from the pump radiation wavelength λ₍ₚₘₚ₎. Typically, the fluorescence wavelength λ_{fl} is typically longer wavelength than the pump radiation wavelength λₚₘₚ. Typically, the intensity of the fluorescence radiation FL depends on the total magnetic flux density B_{Σ}, the microwave amplitude and microwave frequency of the microwave signal μW and the intensity of the pump radiation LB.

Preferably, the optical waveguide LWL) as the first exemplary part of the second optical system detects at its second end as large a proportion as possible of the emitted fluorescence radiation FL of the NV centers and/or the paramagnetic centers in the diamond nano crystals ND of the one or more sensor elements SE. This requires good alignment between the sensor element and the core of the optical waveguide LWL). Preferably, the sensor element SE is therefore manufactured by means of a self-aligning process at the second end of the optical waveguide LWL). The optical waveguide LWL transports the fluorescence radiation FL detected in this way from the second end of the optical waveguide LWL to the first end of the optical waveguide LWL. An exemplary dichroitic mirror F1 as the second exemplary optical functional element of the second optical system separates the fluorescence radiation FL from the pump radiation LB by the dichroitic mirror F1 essentially reflecting the fluorescence radiation FL out of the beam path onto a photo detector PD and essentially not reflecting the pump radiation LB out of the beam path.

Preferably, the second optical system thus comprises an optical functional element (F1) which allows the fluorescence radiation FL to pass in the direction of the photo detector PD or deflects it and which does not allow the pump radiation LB to pass in the direction of the photo detector PD and does not deflect it.

It is known from the prior art to modulate the amplitude of the microwave signal μW with a microwave modulation signal or alternatively to modulate the amplitude of the pump radiation LB with an LED modulation signal.

The proposal presented here envisages modulating or adjusting at least two, preferably three or more of the following parameters by means of a respective modulation signal:
the intensity of the pump radiation LB (amplitude modulation), e.g. by means of an LED modulation signal S5w;
the intensity of the microwave signal μW (amplitude modulation) by means of a microwave modulation signal S5m, for example;
the frequency of the microwave signal μW (frequency modulation) by means of a microwave frequency control signal, for example;
the amplitude of an additional magnetic flux density B_{ad} generated by a magnetic field generation means L_{c}. e.g. by means of a compensation field control signal.

Each of these modulations is assigned one of four basic modulation frequencies.

### To 1. The Modulation of the Intensity of the Pump Radiation LB (Amplitude Modulation)

Preferably, a control device CTR of the device controls the intensity of the pump radiation LB emitted by the pump radiation source, in this case the light source LED, by means of an LED modulation signal S5w. Preferably, the LED modulation signal S5w is modulated with an LED modulation spectrum. As a result, the temporal intensity curve of the pump radiation LB and the temporal intensity curve of the fluorescence radiation FL as well as the amplitude of the receiver output signal S0 of the photo detector PD are then also modulated with a more or less distorted LED modulation spectrum in each case. Preferably, the LED modulation signal S5w is amplitude-modulated mono-frequently with an LED modulation frequency f_{(LED)}. As a result, the temporal intensity curve of the pump radiation LB and the temporal intensity curve of the fluorescence radiation FL as well as the amplitude of the receiver output signal S0 of the photo detector PD are then also essentially amplitude-modulated with the LED modulation frequency f_{LED}.

One modulation can be that the LED modulation signal S5w PWM-modulates the pump radiation source. It may be useful for the LED modulation signal S5w to temporarily switch off the pump radiation source, in this case the light source LED, completely in a PWM period and switch it on for the remainder of the PWM period in question. Alternatively, it may be useful for the LED modulation signal S5w to temporarily reduce the emission intensity of the pump radiation source, in this case the light source LED, in a PWM period and increase its emission intensity for the remainder of the relevant PWM period. If a spreading code is used, it can be useful if the LED modulation signal S5w switches the pump radiation source, in this case the light source LED, completely off when a logical 0 spreading code bit is present and switches the pump radiation source, in this case the light source LED, completely on when a logical 1 spreading code bit is present. If a spreading code is used, it may also be useful if the LED modulation signal S5w reduces the emission intensity of the pump radiation source, in this case the light source LED, if a logical 0 spreading code bit is present and increases the emission intensity of the pump radiation source, in this case the light source LED, if a logical 1 spreading code bit is present.

### To 2. The Modulation of the Intensity of the Microwave Signal μW (Amplitude Modulation)

Preferably, the control device CTR of the device controls the amplitude of the microwave signal μW generated by the microwave signal source μWG by means of a microwave modulation signal S5m. Preferably, the microwave modulation signal S5m is modulated with a microwave modulation spectrum. As a result, the temporal intensity curve of the fluorescence radiation FL and the amplitude of the receiver output signal S0 of the photo detector PD are also modulated with a more or less distorted microwave modulation spectrum in addition to the LED modulation spectrum. Preferably, the microwave modulation signal S5m is mono-frequency amplitude modulated with a microwave modulation frequency fu (w). As a result, the temporal intensity curve of the intensity Iᵢₛₜ(t) of the fluorescence radiation FL and the amplitude of the receiver output signal S0 of the photo detector PD are then typically also essentially amplitude-modulated with the microwave modulation frequency fu w.

One modulation can be that the microwave modulation signal S5m PWM-modulates the amplitude of the microwave signal μW generated by the microwave signal source μWG. It may be useful for the microwave modulation signal S5m to temporarily switch the amplitude of the microwave signal μW generated by the microwave signal source μWG completely off to zero in a PWM period and to switch this amplitude on to a non-zero absolute value for the remainder of the PWM period in question. Alternatively, it may be useful for the microwave modulation signal S5m to temporarily reduce the amplitude of the microwave signal μW generated by the microwave signal source μWG in a PWM period and increase its amplitude for the remainder of the PWM period in question. If a spreading code is used, it may be useful for the microwave modulation signal S5m to switch the amplitude of the microwave signal μW generated by the microwave signal source μWG completely off to zero if a logical 0 spreading code bit is present and to switch the amplitude of the microwave signal μW generated by the microwave signal source μWG completely on to a non-zero amplitude if a logical 1 spreading code bit is present. If a spreading code is used, it may also make sense for the microwave modulation signal S5m to reduce the amplitude of the microwave signal μW generated by the microwave signal source μWG when a logical 0 spreading code bit is present and to increase the amplitude of the microwave signal μW generated by the microwave signal source μWG when a logical 1 spreading code bit is present.

### To 3. Modulation of the Frequency of the Microwave Signal μW (Frequency Modulation)

Preferably, the control device CTR of the device controls the frequency of the microwave signal μW, which is generated by the microwave signal source μWG, for example via a data bus DB by means of a microwave frequency control signal. Preferably, the frequency modulation by the microwave frequency control signal via the data bus DB leads to a further microwave modulation spectrum with which the microwave signal μW is then modulated. As a result, the temporal intensity curve of the intensity Iᵢₛₜ(t) of the fluorescence radiation FL and the amplitude of the receiver output signal S0 of the photo detector PD are then also modulated with a more or less distorted further microwave frequency modulation spectrum in addition to the LED modulation spectrum and the microwave modulation spectrum. For example, the microwave frequency of the microwave signal μW can be frequency-modulated monofrequently with a microwave frequency modulation frequency f_{fμ(W)}. Since the different microwave frequencies of the microwave signal μW result in different intensities Iᵢₛₜ(t) of the fluorescence radiation FL, the temporal intensity curve of the intensity Iᵢₛₜ(t) of the fluorescence radiation FL and the amplitude of the receiver output signal S0 of the photo detector PD are then essentially also modulated with the microwave frequency modulation frequency f_{fμW}.

To 4. The Modulation of the Amplitude of an Additional Magnetic Flux Density B_{ad} Generated by a Magnetic Field Generation Means L_{C}.

Preferably, the control device CTR of the device controls the amplitude of an additional magnetic flux density B_{ad} generated by a magnetic field generation means L_{C}, for example via a data bus DB by means of a compensation field control signal. The additional magnetic flux density B_{ad} contributes to the total magnetic flux density B_{Σ}. The total magnetic flux density B_{Σ} flows through the sensor element SE and therefore influences the intensity Iᵢₛₜ(t) of the fluorescence radiation FL. Preferably, for this purpose of controlling the magnetic field generation means L_{C}, the control device CTR controls a magnetic field controller LCTR via the data bus DB. The magnetic field controller LCTR typically controls a driver stage DRVL for supplying the magnetic field generation means L_{C} with electrical energy and/or for controlling the magnetic field generation means L_{C}. The control device CTR thus modulates the amplitude of the additional magnetic flux density B_{ad}, which the magnetic field generation means L_{c} generates as a function of the compensation field control signal, via the magnetic field controller LCTR and the driver stage DRLV by means of the compensation field control signal sent, for example, via the data bus DB.

For example, the compensation field control signal can be modulated with a magnetic field modulation spectrum. In this way, the additional magnetic flux density B_{ad}, which the magnetic field generation means L_{C} generates as a function of the compensation field control signal, can be amplitude-modulated with the magnetic field modulation spectrum. The additional magnetic flux density B_{ad} is superimposed with other magnetic flux densities from other sources to form the total magnetic flux density B_{Σ}. As a result, the total magnetic flux density B_{Σ}, which flows through the sensor element SE, is typically also essentially modulated with the magnetic field modulation spectrum.

The intensity Iᵢₛₜ(t) of the fluorescence radiation FL depends, among other things, on the amplitude of the total flux density B_{Σ}. As a result, the temporal intensity curve of the fluorescence radiation FL and ultimately also the amplitude of the receiver output signal S0 of the photo detector PD can essentially be modulated with a more or less distorted magnetic field modulation spectrum in addition to the LED modulation spectrum and the microwave modulation spectrum and the microwave frequency modulation spectrum.

Preferably, the compensation field control signal, if it is applied periodically, is modulated mono-frequently with a magnetic field modulation frequency f_{(mg)}. Since the different total magnetic flux densities B_{Σ} result in different intensities of the fluorescence radiation FL, the temporal intensity curve of the intensity Iᵢₛₜ(t) of the fluorescence radiation FL and the amplitude of the receiver output signal S0 of the photo detector PD are then also modulated with the magnetic field modulation frequency f_{(mg)}.

In this configuration, this results in 2⁴=16 mixed frequencies with which the receiver output signal S0 of the photo detector PD can be modulated.

Preferably, the magnetic field modulation frequency f_{mg}, the microwave frequency modulation frequency f_{μW}, the microwave modulation frequency fu w and the LED modulation frequency f_{LED} are selected so that preferably all mixed frequencies are different.

This can be achieved, for example, by a second fundamental modulation frequency comprising twice the frequency value of a first fundamental modulation frequency and a third fundamental modulation frequency comprising four times the frequency value of the first fundamental modulation frequency and a fourth fundamental modulation frequency comprising eight times the frequency value of the first fundamental modulation frequency.

For example, to give an arbitrary example, it is conceivable that the microwave frequency modulation frequency f_{μW} comprises eight times the frequency value of the magnetic field modulation frequency f_{mg} and that the LED modulation frequency f_{LED} four times the frequency value of the magnetic field modulation frequency f_{mg} and that the microwave frequency modulation frequency fμW Comprises twice the frequency value of the magnetic field modulation frequency f_{(mg)}.

Case with a Fundamental Modulation Frequency (Microwave Modulation Frequency)

It is known from the state of the art to operate the device with only one modulation fundamental frequency different from 0Hz and to set the other values of the other modulation fundamental frequencies to quasi-static values for the duration of a measurement. The following document presents an example.

If the control device CTR of the device, for example:
a modulation of the intensity of the pump radiation LB (amplitude modulation) is set quasi-statically via the data bus DB by means of control of the first signal generator G1, i.e. with an LED modulation frequency f_{LED}=0 Hz;
simultaneously modulates the intensity of the microwave signal μW (amplitude modulation) with a microwave modulation frequency f_{μW} via the data bus DB by means of control of the second signal generator G2;
the microwave frequency of the microwave signal μW adjusts the data bus DB in the microwave signal source μWG quasi-statically, i.e. with a microwave frequency modulation frequency f_{fμW}=0 Hz; and
adjusts the value of the compensation field control signal to a quasi-static value, i.e. to a magnetic field modulation frequency f_{mg}=0Hz, and thus to a quasi-static amplitude of an additional magnetic flux density B_{ad} set by the control device CTR, which generates the magnetic field generation means L_{C},

This results in exactly one mixed frequency with which the receiver output signal S0 of the photo detector PD can be modulated.

In this example, a first signal generator G1 generates the quasi-static LED modulation signal S5w, with an LED modulation frequency f_{LED}=0Hz typically corresponding to a default value that the control device CTR has set in the first signal generator G1 via the data bus DB. The control device CTR preferably controls the first signal generator G1 via the exemplary data bus DB.

A light source driver LDRV for the light source LED typically generates the quasi-static transmission signal S5 from the LED modulation signal S5w, with which the light source driver LDRV preferably also supplies the light source LED with electrical energy. Preferably, the light source LED is a semiconductor light source such as a laser or an LED. Particularly preferably, the light source LED comprises a silicon LED and/or a silicon avalanche LED, which means that this part of the device can possibly also be integrated into CMOS.

The light source LED then emits the pump radiation LB. with the pump radiation wavelength λₚₘₚ as a function of the transmission signal S5.

The receiver output signal S0 and the amplified receiver output signal S1 are then not modulated with an LED modulation spectrum due to the LED modulation frequency f_{LED}=0Hz.

In this example of FIG. 69, a second signal generator G2 generates the microwave modulation signal S5m in particular with a microwave modulation frequency f_{μW} typically corresponding to a preset value which the control device CTR has set in the second signal generator G2 via the data bus DB. Typically, the second signal generator G2 modulates the microwave modulation signal S5m with said microwave modulation spectrum and/or with said microwave modulation frequency f_{μW}. Very preferably, the microwave modulation of the microwave modulation signal S5m is a PWM modulation with a PWM frequency or a bit stream of a spreading code signal with a spreading code period duration and a spreading code bit frequency. The control device CTR preferably controls the second signal generator G2 via the exemplary data bus DB.

The microwave signal source μWG then generates the microwave signal μW modulated with the microwave modulation signal. The control device CTR controls the microwave signal source μWG preferably via the exemplary data bus DB.

Since the microwave modulation signal S5m is modulated with a microwave modulation spectrum, the microwave signal μW is also amplitude modulated with the microwave modulation spectrum. Therefore, the temporal intensity curve of the fluorescence radiation FL is typically also modulated with the microwave modulation spectrum. Therefore, the receiver output signal S0 and the amplified receiver output signal S1 are also modulated with the microwave modulation spectrum.

Typically, an optional first amplifier V1 amplifies the receiver output signal S0 of the photo detector PD to an amplified receiver output signal S1. Preferably, the transfer function of the first amplifier V1 for the amplification of the receiver output signal S0 to the amplified receiver output signal S1 comprises a filter property which is typically selected such that the first amplifier V1 essentially only amplifies modulated signal components of the receiver output signal S0 with a frequency f≠0Hz to the amplified receiver output signal S1 and essentially only amplifies signal components of the receiver output signal S0 with a frequency f<fₘₐₓ to the amplified receiver output signal S1. Preferably, fₘₐₓ is a maximum frequency whose frequency magnitude value is preferably greater than the frequency magnitude value of the mixed frequency with the largest frequency magnitude value.

Preferably, the first amplifier V1 or the device comprises an analog-to-digital conversion ADC, such that the amplified receiver output signal S1 may be a digitized receiver output signal S1.

The control device CTR can emulate the multiple correlator LIV of FIG. 69 in various embodiments of the device.

The multiple correlator LIV of FIG. 69 typically correlates the amplified receiver output signal S1 or the digitized receiver output signal S1 with the microwave signal μW in this operating mode.

If the multiple correlator LIV correlates the amplified receiver output signal S1 or the digitized receiver output signal S1 with a signal s1(t), the multiple correlator LIV essentially calculates the following correlation integral:

$$S 4 ( t ) = {\int }_{0}^{2 π} S 1 ( t ) \cdot s 1 ( t ) dt$$

Here, the angle 2π refers to the period of the periodic signal s1(t). In the example of FIG. 69, the multiple correlator LIV preferably correlates the amplified receiver output signal S1 or the digitized receiver output signal S1 with the microwave modulation signal S5m(t). Thus, the multiple correlator LIV essentially calculates the following correlation integral as the L2 product of the receiver output signal S1(t) or the digitized receiver output signal S1(t) and the microwave modulation signal S5m(t):

$$S {4}_{a} ( t ) = {\int }_{0}^{2 π} S 1 ( t ) \cdot S 5 m ( t ) dt$$

$$S {4}_{b} ( t ) = {\int }_{0}^{2 π} S 1 ( t ) \cdot S 5 mq ( t ) dt$$

Here, the angle 2π refers to the period of the periodic signal S5m(t). The signal S5mq is typically the inverted signal of the microwave modulation signal S5m.

Preferably, the microwave modulation signal S5m(t) is a digital signal that can assume the logic 1 level and the logic 0 level.

In the extreme case of the microwave modulation signal S5m(t), at a logical 1 level of the microwave modulation signal S5m(t), the microwave signal source μWG should switch on and generate a microwave signal μW with the amplitude preset via the data bus DB and the preset microwave frequency ω_{μW} and, at a logical 0 level of the microwave modulation signal S5m(t), the microwave signal source μWG should generate a microwave signal with the amplitude 0 and thus switch off the _{microwave} signal _{μW}.level of the microwave modulation signal S5m(t), the microwave signal source μWG generates a microwave signal with amplitude 0 and thus switches off the microwave signal μW.

At a logic 1 level of the microwave modulation signal S5m(t), the microwave signal source μWG is to switch on and generate a microwave signal μW with the increased amplitude preset via the data bus DB and the preset microwave frequency ω (μW), and at a logic 0 level of the microwave modulation signal S5m(t), the microwave signal source μWG is to switch on and generate a microwave signal with the lower amplitude preset via the data bus DB and the preset microwave frequency (μW).level microwave modulation signal S5m(t), the microwave signal source μWG generates (switches off) a microwave signal with the lower amplitude preset via the data bus DB and the preset microwave frequency ω(μW).

In the case where the microwave modulation signal S5m(t) is such a digital signal, an inverted microwave modulation signal S5mq(t) can be defined as an inverted signal of the microwave modulation signal S5m(t).

The filter output signal S4(t) then typically indicates the proportion in the amplified receiver output signal S1 or in the digitized receiver output signal S1 that is attributable to the microwave irradiation of the microwave signal μW into the sensor element SE.

Case with a Basic Modulation Frequency (LED Modulation Frequency)

It is known from the state of the art to operate the device with only one modulation fundamental frequency different from 0Hz and to set the other values of the other modulation fundamental frequencies to quasi-static values for the duration of a measurement. The following document presents an example.

If the control device CTR of the device, for example:
modulates the intensity of the pump radiation LB (amplitude modulation) via the data bus DB by means of control of the first signal generator G1, i.e. with an LED modulation frequency f_{LED};
simultaneously modulates the intensity of the microwave signal μW (amplitude modulation) quasi-statically, i.e. with a microwave modulation frequency f_{μW}=0 Hz, via the data bus DB by means of control of the second signal generator G2;
the microwave frequency of the microwave signal μW adjusts the data bus DB in the microwave signal source μWG quasi-statically, i.e. with a microwave frequency modulation frequency f_{fμW}=0 Hz; and
adjusts the value of the compensation field control signal to a quasi-static value, i.e. to a magnetic field modulation frequency f_{mg}=0Hz, and thus to a quasi-static amplitude of an additional magnetic flux density B_{ad} set by the control device CTR, which generates the magnetic field generation means L_{c},

This results in exactly one mixed frequency with which the receiver output signal S0 of the photo detector PD can be modulated.

In this example, a first signal generator G1 generates the quasi-static LED modulation signal S5w, with a LED modulation frequency f_{LED} typically corresponding to a preset value that the control device CTR has set in the first signal generator G1 via the data bus DB. The control device CTR preferably controls the first signal generator G1 via the exemplary data bus DB. Typically, the first signal generator G1 modulates the LEED modulation signal S5w with said LED modulation spectrum and/or with said LED modulation frequency f_{LED}. Very preferably, the LED modulation signal S5w is a PWM modulation with a PWM frequency or a bit stream of a spreading code signal with a spreading code period duration and a spreading code bit frequency. The control device CTR preferably controls the first signal generator G1 via the exemplary data bus DB.

A light source driver LDRV for the light source LED typically generates the transmission signal S5 from the LED modulation signal S5w, with which the light source driver LDRV preferably also supplies the light source LED with electrical energy. Preferably, the light source LED is a semiconductor light source such as a laser or an LED. Particularly preferably, the light source LED comprises a silicon LED and/or a silicon avalanche LED, which means that this part of the device can also be integrated into CMOS if necessary.

The light source LED then emits the pump radiation LB. with the pump radiation wavelength λₚₘₚ as a function of the transmission signal S5.

The receiver output signal S0 and the amplified receiver output signal S1 are then modulated with an LED modulation spectrum.

Since the LED modulation signal S5w is modulated with an LED modulation spectrum, the transmission signal S5 is also amplitude-modulated with the LED modulation spectrum. Therefore, the temporal intensity curve Iᵢₛₜ(t) of the fluorescence radiation FL is typically also modulated with the LED modulation spectrum. The receiver output signal S0 and the amplified receiver output signal S1 are therefore also modulated with the LED modulation spectrum.

In this example of FIG. 69, a second signal generator G2 generates the microwave modulation signal S5m with a microwave modulation frequency f_{μW}=0Hz in particular, typically according to a preset value set by the control device CTR via the data bus DB in the second signal generator G2. Typically, the second signal generator G2 modulates the microwave modulation signal S5m with said microwave modulation spectrum and/or with said microwave modulation frequency f_{μW}=0 Hz. The control device CTR preferably controls the second signal generator G2 via the exemplary data bus DB.

The microwave signal source μWG then generates the unmodulated microwave signal μW. The control device CTR controls the microwave signal source μWG preferably via the exemplary data bus DB.

Typically, an optional first amplifier V1 amplifies the receiver output signal S0 of the photo detector PD to an amplified receiver output signal S1. Preferably, the transfer function of the first amplifier V1 for the amplification of the receiver output signal S0 to the amplified receiver output signal S1 comprises a filter property which is typically selected such that the first amplifier V1 essentially only amplifies modulated signal components of the receiver output signal S0 with a frequency f≠0Hz to the amplified receiver output signal S1 and essentially only amplifies signal components of the receiver output signal S0 with a frequency f<fₘₐₓ to the amplified receiver output signal S1. Preferably, fₘₐₓ is a maximum frequency whose frequency magnitude value is preferably greater than the frequency magnitude value of the mixed frequency with the largest frequency magnitude value.

Preferably, the first amplifier V1 or the device comprises an analog-to-digital conversion ADC such that the amplified receiver output signal S1 may be a digitized receiver output signal S1.

The control device CTR can emulate the multiple correlator LIV of FIG. 69 in various embodiments of the device.

The multiple correlator LIV of FIG. 69 typically correlates the amplified receiver output signal S1 or the digitized receiver output signal S1 with the LED modulation signal S5w in this operating mode.

If the multiple correlator LIV correlates the amplified receiver output signal S1 or the digitized receiver output signal S1 with a signal s1(t), the multiple correlator LIV essentially calculates the following correlation integral:

$$S 4 ( t ) = {\int }_{0}^{2 π} S 1 ( t ) \cdot s 1 ( t ) dt$$

Here, the angle 2π refers to the period of the periodic signal s1(t). In the example of FIG. 69, the multiple correlator LIV preferably correlates the amplified receiver output signal S1 or the digitized receiver output signal S1 with the LED modulation signal S5w(t). Thus, the multiple correlator LIV essentially calculates the following correlation integral as the L2 product of the receiver output signal S1(t) or the digitized receiver output signal S1(t) and the LED modulation signal S5w(t):

$$S {4}_{a} ( t ) = {\int }_{0}^{2 π} S 1 ( t ) \cdot S 5 w ( t ) dt$$

$$S {4}_{b} ( t ) = {\int }_{0}^{2 π} S 1 ( t ) \cdot S 5 wq ( t ) dt$$

Here, the angle 2π refers to the period of the periodic signal S5m(t). The signal S5wq is typically the inverted signal of the LED modulation signal S5w.

Preferably, the LED modulation signal S5w(t) is a digital signal that can assume the logic 1 level and the logic 0 level.

In the extreme case of the LED modulation signal S5w(t), at a logic 1 level of the LED modulation signal S5w(t) according to the arbitrary definition of the script presented here, the light source LED should switch on and generate the pump radiation LB with the amplitude preset via the data bus DB and at a logic 0 level of the LED modulation signal S5w(t), the light source LED should generate the pump radiation LB with the amplitude 0 and thus switch off the pump radiation LB.

At a logic 1 level of the LED modulation signal S5w(t), the light source LED should switch on and generate the pump radiation LB with the increased amplitude preset via the data bus DB and at a logic 0 level of the LED modulation signal S5w(t), the light source LED should generate (switch off) the pump radiation LB with the lower amplitude preset via the data bus DB.

In the case that the LED modulation signal S5w(t) is such a digital signal, an inverted LED modulation signal S5wq(t) can be defined as an inverted signal of the LED modulation signal S5w(t).

The filter output signal S4(t) then typically indicates the proportion in the amplified receiver output signal S1 or in the digitized receiver output signal S1 that is attributable to the irradiation of the pump radiation LB into the sensor element SE.

Case with Two Fundamental Modulation Frequencies

It is conceivable and new compared to the prior art to operate the device with two modulation fundamental frequencies different from 0Hz instead of only one and to set the other values to quasi-static values for the duration of a measurement. In the following, the document presented here presents a preferred example without limiting the disclosure to it.

If the control device CTR of the device, for example:
sets a modulation of the intensity of the pump radiation LB (amplitude modulation) with an LED modulation frequency f_{LED} via the data bus DB by means of control of the first signal generator G1;
simultaneously modulates the intensity of the microwave signal μW (amplitude modulation) with a microwave modulation frequency f_{μW} via the data bus DB by means of control of the second signal generator G2;
the microwave frequency of the microwave signal μW adjusts the data bus DB in the microwave signal source μWG quasi-statically, i.e. with a microwave frequency modulation frequency f_{fμW}=0Hz; and
adjusts the value of the compensation field control signal to a quasi-static value, i.e. to a magnetic field modulation frequency f_{mg}=0Hz, and thus to a quasi-static amplitude of an additional magnetic flux density B_{ad} set by the control device CTR, which generates the magnetic field generation means L_{c},

This results in 2²=4 mixed frequencies with which the receiver output signal S0 of the photo detector PD can be modulated.

Preferably, in this configuration, the magnetic field modulation frequency f_{mg} is set so that the magnetic field modulation frequency f_{mg}=0 Hz.

Preferably, in this configuration, the microwave frequency modulation frequency f_{fμW} is set so that the microwave frequency modulation frequency f_{fμW}=0Hz.

Preferably, the microwave modulation frequency f_{μW} and the LED modulation frequency f_{LED} are now selected so that preferably these four mixed frequencies differ.

This can be achieved, for example, by a second fundamental modulation frequency comprising twice the frequency value of a first fundamental modulation frequency of these two fundamental modulation frequencies ω_{μW} and ω_{(LED)}.

For example, to give an arbitrary example, it is conceivable that the microwave modulation frequency fu w comprises twice the frequency value of the LED modulation frequency f (LED).

In this example of this configuration, the first signal generator G1 generates the LED modulation signal S5W, with a LED modulation frequency f_{LED} typically corresponding to a non-zero default value, which the control device CTR has set in the first signal generator G1 via the data bus DB. Typically, the first signal generator G1 modulates the LED modulation signal S5W with said LED modulation spectrum and/or with said LED modulation frequency f_{LED}. Very preferably, the LED modulation signal S5W is a PWM modulation with a PWM frequency or a bit stream of a spreading code signal with a spreading code period duration and a spreading code bit frequency. The control device CTR preferably controls the first signal generator G1 via the exemplary data bus DB.

A light source driver LDRV for the light source LED typically generates the transmission signal S5 from the LED modulation signal S5W, with which the light source driver LDRV preferably also supplies the light source LED with electrical energy. Preferably, the light source LED is a semiconductor light source such as a laser or an LED. Particularly preferably, the light source LED comprises a silicon LED and/or a silicon avalanche LED, which means that this part of the device can possibly also be integrated into CMOS.

The light source LED then emits the pump radiation LB. with the pump radiation wavelength λₚₘₚ as a function of the transmission signal S5.

Since the LED modulation signal S5w is modulated with an LED modulation spectrum, the transmission signal S5 is then also modulated with the LED modulation spectrum. Since the transmission signal S5 is modulated with the LED modulation spectrum, the temporal intensity curve of the pump radiation LB is typically modulated with the LED modulation spectrum. Therefore, the temporal intensity curve of the intensity Iᵢₛₜ(t) of the fluorescence radiation FL is typically also modulated with the LED modulation spectrum. Therefore, the receiver output signal S0 and the amplified receiver output signal S1 are typically also modulated with the LED modulation spectrum.

In this example of FIG. 69, in this configuration the second signal generator G2 generates the microwave modulation signal S5m in particular with a non-zero microwave modulation frequency f_{μW} typically corresponding to a preset value set by the control device CTR via the data bus DB in the second signal generator G2. Typically, the second signal generator G2 modulates the microwave modulation signal S5m with said microwave modulation spectrum and/or with said microwave modulation frequency f_{μW}. Very preferably, the microwave modulation of the microwave modulation signal S5m is a PWM modulation with a PWM frequency or a bit stream of a spreading code signal with a spreading code period duration and a spreading code bit frequency. The control device CTR preferably controls the second signal generator G2 via the exemplary data bus DB.

The microwave signal source μWG then generates the microwave signal μW modulated with the microwave modulation signal. The control device CTR controls the microwave signal source μWG preferably via the exemplary data bus DB.

Since the microwave modulation signal S5m is modulated with a microwave modulation spectrum, the microwave signal μW is then typically also amplitude modulated with the microwave modulation spectrum. Therefore, the temporal intensity curve of the fluorescence radiation FL is then typically also modulated with the microwave modulation spectrum. Therefore, the receiver output signal S0 and the amplified receiver output signal S1 are typically also modulated with the microwave modulation spectrum.

Typically, the optional first amplifier V1 amplifies the receiver output signal S0 of the photo detector PD to an amplified receiver output signal S1. Preferably, the transfer function of the first amplifier V1 for the amplification of the receiver output signal S0 to the amplified receiver output signal S1 comprises a filter property which is typically selected such that the first amplifier V1 essentially only amplifies modulated signal components of the receiver output signal S0 with a frequency f≠0Hz to the amplified receiver output signal S1 and essentially only amplifies signal components of the receiver output signal S0 with a frequency f<fₘₐₓ to the amplified receiver output signal S1. Preferably, fₘₐₓ is a maximum frequency whose frequency magnitude value is preferably greater than the frequency magnitude value of the mixed frequency with the largest frequency magnitude value.

Preferably, the first amplifier V1 or the device comprises an analog-to-digital conversion ADC such that the amplified receiver output signal S1 may be a digitized receiver output signal S1.

The control device CTR can emulate the multiple correlator LIV of FIG. 69 in various embodiments of the device.

The multiple correlator LIV of FIG. 69 preferably correlates the amplified receiver output signal S1 or the digitized receiver output signal S1 with the at least two following signals:
the LED modulation signal S5w; and
the microwave signal W.μ

If the multiple correlator LIV correlates the amplified receiver output signal S1 or the digitized receiver output signal S1 with two signals s1(t) and s2 (t), the multiple correlator LIV essentially calculates, for example, the following correlation integral:

$$S 4 ( t ) = {\int }_{0}^{2 π} S 1 ( t ) \cdot s 1 ( t ) \cdot s 2 ( t ) dt$$

DEFINITION: The document presented here now refers to this mathematical form as an L3 product (for three functions) based on the familiar L2 product.

Here, the angle 2π refers to the period of the periodic signal s1(t) or s2(t) with the longer period duration. The prerequisite is that the period duration of the signal with the longer period duration is an integer multiple of the period duration of the signal with the shorter period duration.

In the example of FIG. 69, the multiple correlator LIV preferably correlates the amplified receiver output signal S1 or the digitized receiver output signal S1 with the LED modulation signal S5w(t) and the microwave modulation signal S5m(t). Thus, the multiple correlator LIV essentially calculates the following correlation integral as the L3 product of the receiver output signal S1(t) or the digitized receiver output signal S1(t), the LED modulation signal S5w(t) and the microwave modulation signal S5m(t):

$$S 4 ( t ) = {\int }_{0}^{2 π} S 1 ( t ) \cdot S 5 w ( t ) \cdot S 5 m ( t ) dt$$

Here, the angle 2π refers to the period of the periodic signal S5m(t) or S5w(t) with the longer period duration. The preferred prerequisite is that the period duration of the signal with the longer period duration is an integer multiple of the period duration of the signal with the shorter period duration.

Preferably, the LED modulation signal S5w(t) is a digital signal that can assume the logic 1 level and the logic 0 level.

In the extreme case of the LED modulation signal S5w(t), at a logic 1 level of the LED modulation signal S5w(t), the light source driver LDRV for the light source LED should switch on the emission of a pump radiation source LB by the pump radiation source, in this case the light source LED, and switch off the pump radiation source, in this case the light source LED, at a logic 0 level of the LED modulation signal S5w(t).

At a logic 1 level of the LED modulation signal S5w(t), the light source driver LDRV for the light source LED should cause the pump radiation source, here the light source LED, to emit an increased intensity of the pump radiation LB and at a logic 0 level of the LED modulation signal S5w(t) cause the pump radiation source, here the light source LED, to emit a reduced intensity of the pump radiation LB, according to the arbitrary definition given here.

Preferably, the microwave modulation signal S5m(t) is a digital signal that can assume the logic 1 level and the logic 0 level.

In the extreme case of the microwave modulation signal S5m(t), at a logical 1 level of the microwave modulation signal S5m(t), the microwave signal source μWG should switch on and generate a microwave signal with the amplitude and the microwave frequency preset via the data bus DB and, at a logical 0 level of the microwave modulation signal S5m(t), the microwave signal source μWG should generate a microwave signal with the amplitude 0 and thus switch off the microwave signal μW.level of the microwave modulation signal S5m(t), the microwave signal source μWG generates a microwave signal with amplitude 0 and thus switches off the microwave signal μW.

At a logic 1 level of the microwave modulation signal S5m(t), the microwave signal source μWG is to switch on and generate a microwave signal with the increased amplitude preset via the data bus DB and the preset microwave frequency ω(μW), and at a logic 0 level of the microwave modulation signal S5m(t), the microwave signal source μWG is to switch on and generate a microwave signal with the lower amplitude preset via the data bus DB and the _{preset microwave frequency (μW)}.level microwave modulation signal S5m(t), the microwave signal source μWG generates (switches off) a microwave signal with the lower amplitude preset via the data bus DB and the preset microwave frequency ω(μW).

In the case where the microwave modulation signal S5m(t) is such a digital signal, an inverted microwave modulation signal S5mq(t) can be defined as an inverted signal of the microwave modulation signal S5m(t).

In the case that the LED modulation signal S5w(t) is such a digital signal, an inverted LED modulation signal S5wq(t) can be defined as an inverted signal of the LED modulation signal S5w(t).

The multiple correlator LIV can then form a total of four L3 products in the form of four filter output signals S4(t) from the amplified receiver output signal S1, microwave modulation signal S5m(t) and LED modulation signal S5w(t):

$$S {4}_{a} ( t ) = {\int }_{0}^{2 π} S 1 ( t ) \cdot S 5 w ( t ) \cdot S 5 m ( t ) dt$$

$$S {4}_{b} ( t ) = {\int }_{0}^{2 π} S 1 ( t ) \cdot S 5 wq ( t ) \cdot S 5 m ( t ) dt$$

$$S {4}_{c} ( t ) = {\int }_{0}^{2 π} S 1 ( t ) \cdot S 5 w ( t ) \cdot S 5 mq ( t ) dt$$

$$S {4}_{d} ( t ) = {\int }_{0}^{2 π} S 1 ( t ) \cdot S 5 wq ( t ) \cdot S 5 mq ( t ) dt$$

The first filter output signal S4ₐ(t) formed in this way indicates the intensity of the fluorescence radiation FL when the pump radiation LB is switched on and the microwave signal μW is switched on.

The second filter output signal S4_{b}(t) formed in this way indicates the intensity of the fluorescence radiation FL when the pump radiation LB is switched off and the microwave signal μW is switched on. Since no fluorescence radiation FL occurs due to the absence of pump radiation LB), this second filter output signal S4_{b}(t) formed in this way represents the radiation background that is present for whatever reason.

The third filter output signal S4_{c}(t) formed in this way indicates the intensity of the fluorescence radiation FL when the pump radiation LB is switched on and the microwave signal μW is switched off. The third filter output signal S4_{c}(t) formed in this way thus indicates the intensity of the microwave-free fluorescence radiation FL, as is known, for example, from EP 3 980 797A1.

The fourth filter output signal S4_{d}(t) formed in this way indicates the intensity of the fluorescence radiation FL when the pump radiation LB is switched off and the microwave signal μW is switched off. Since no fluorescence radiation FL occurs due to the absence of the pump radiation LB), this second filter output signal S4_{d}(t) thus formed represents the radiation background that is present for whatever reason.

The document presented here now proposes to understand the filter output signal S4(t) as a feature vector signal. The document presented here now proposes to form this vectorial filter output signal S4(t) by subtracting the respective radiation background, for example as follows:

$$S 4 ( t ) = ( \begin{matrix}S {4}_{1} ( t ) \\ S {4}_{2} ( t ) \\ S {4}_{3} ( t ) \\ S {4}_{4} ( t )\end{matrix} ) = ( \begin{matrix}S {4}_{a} ( t ) - S {4}_{b} ( t ) \\ S {4}_{c} ( t ) - S {4}_{d} ( t ) \\ S {4}_{a} ( t ) - S {4}_{c} ( t ) \\ S {4}_{a} ( t ) - S {4}_{b} ( t ) - S {4}_{c} ( t ) + S {4}_{d} ( t )\end{matrix} )$$

This corresponds to:

$$S 4 ( t ) = ( \begin{matrix}\begin{matrix}{\int }_{0}^{2 π} S 1 ( t ) \cdot S 5 w ( t ) \cdot S 5 m ( t ) dt - \\ {\int }_{0}^{2 π} S 1 ( t ) \cdot S 5 wq ( t ) \cdot S 5 m ( t ) dt\end{matrix} \\ \begin{matrix}{\int }_{0}^{2 π} S 1 ( t ) \cdot S 5 w ( t ) \cdot S 5 mq ( t ) dt - \\ {\int }_{0}^{2 π} S 1 ( t ) \cdot S 5 wq ( t ) \cdot S 5 mq ( t ) dt\end{matrix} \\ \begin{matrix}{\int }_{0}^{2 π} S 1 ( t ) \cdot S 5 w ( t ) \cdot S 5 m ( t ) dt - \\ {\int }_{0}^{2 π} S 1 ( t ) \cdot S 5 w ( t ) \cdot S 5 mq ( t ) dt\end{matrix} \\ \begin{matrix}\begin{matrix}\begin{matrix}{\int }_{0}^{2 π} S 1 ( t ) \cdot S 5 w ( t ) \cdot S 5 m ( t ) dt - \\ {\int }_{0}^{2 π} S 1 ( t ) \cdot S 5 wq ( t ) \cdot S 5 m ( t ) dt -\end{matrix} \\ {\int }_{0}^{2 π} S 1 ( t ) \cdot S 5 w ( t ) \cdot S 5 mq ( t ) dt +\end{matrix} \\ {\int }_{0}^{2 π} S 1 ( t ) \text{?}\end{matrix}\end{matrix}$$

$$S 4 ( t ) = ( \begin{matrix}{\int }_{0}^{2 π} S 1 ( t ) \cdot ( S 5 w ( t ) - S 5 wq ( t ) ) \cdot S 5 m ( t ) dt \\ {\int }_{0}^{2 π} S 1 ( t ) \cdot ( S 5 w ( t ) - S 5 wq ( t ) ) \cdot S 5 mq ( t ) dt \\ {\int }_{0}^{2 π} S 1 ( t ) \cdot S 5 w ( t ) \cdot ( S 5 m ( t ) - S 5 mq ( t ) ) dt \\ {\int }_{0}^{2 π} S 1 ( t ) \cdot ( S 5 w ( t ) - S 5 wq ( t ) ) \cdot ( S 5 m ( t ) - S 5 mq ( t ) ) dt\end{matrix} )$$

$$\text{?} \text{indicates text missing or illegible when filed}$$

The result is a four-dimensional filter output signal S4(t). Here, the possible further dimension of the filter output signal was determined according to the integral

$${\int }_{0}^{2 π} S 1 ( t ) \cdot S 5 wq ( t ) \cdot ( S 5 m ( t ) - S 5 mq ( t ) ) dt$$

is not taken into account, as this integral assumes an influence of the microwave radiation on the noise without fluorescence. However, this integral can theoretically also be part of the vectorial filter output signal S4(t).

Typically, the control device CTR sets different microwave frequencies ω_{μW} of the microwave signal μW via the data bus DB in the microwave signal source μWG and different values of the compensation field control signal. The control device CTR thus typically sets different amplitudes of the additional magnetic flux density B_{ad} generated by the magnetic field generation means L_{C}. The control device CTR then determines the value of the multidimensional filter output signal S4(t) by means of the multiple correlator LIV for preferably each of the set two-dimensional operating points from the value of the compensation field control signal (i.e. the set additional magnetic flux density B_{ad}) and the frequency value of the microwave frequency ω_{μW} of the microwave signal μW. That is, the device in FIG. 51a at least partially covers the area of FIG. 51a with a grid or a distribution of operating points of the device at each of which the device determines the values of the multidimensional filter output signals S4(t) respectively associated with these operating points.

The control device CTR preferably stores these values in a memory RAM, NVM.

The control device CTR preferably stores these values in a memory RAM, NVM preferably in the form of data records.

Preferably, each data set comprises firstly the vectorial value of the operating point, i.e. the value of the compensation field control signal (i.e. set additional magnetic flux density B_{ad}) and the frequency value of the microwave frequency ω_{μW} of the microwave signal μW, and secondly the current vector component values of the multidimensional filter output signal S4(t).

When the control device CTR has measured all operating points of a measurement cycle, the control device CTR and/or the pattern recognition device MEV can use these data sets as a preliminary feature vector for a computer- or logic-implemented pattern recognition method or one of the computer-implemented methods described above.

For this purpose, the device may have a separate pattern recognition device MEV, which evaluates the vectorial filter output signal S4(t) directly or accesses the data records in the memory RAM, NVM. Alternatively, and preferably, the control device CTR can emulate such a pattern recognition device MEV by a computer-implemented method. For example, the control device CTR may execute a computer-implemented artificial intelligence program as a pattern recognition program. For example, the control device CTR can execute a computer-implemented neural network model NN that estimates the total flux density B_{Σ} and the external total flux density B_{(ext)B}=_{Σ}−B_{ad} from the detected parameters. For example, the pattern recognition device MEV may also be a device that performs a computer-implemented or logic-implemented method for pattern recognition or for preparing a pattern recognition by the control device CTR by means of a computer-implemented method for pattern recognition. Typically, the pattern recognition device MEV generates a pattern data set MDS for this purpose. Preferably, this pattern data set MDS comprises the data set of a pattern recognized by the pattern recognition device MEV and/or a feature vector which the pattern recognition device MEV has extracted from the typically vectorial filter output signal S4(t) and possibly other data and signals present in the system. The pattern recognition device MEV provides this pattern data set MDS for pattern recognition and/or post-processing to the control device via the data bus DB and/or via a FiFo structure or a special interface with a special pattern data set data bus for further processing and/or use. In the case of transmitting feature vector data within the pattern data set, the control device CTR can perform pattern recognition in the transmitted current and temporally previous feature vector data using a computer-implemented program for pattern recognition or the like. An important value determined by the control device CTR and/or the pattern recognition device MEV is typically the value of the recognized total flux density B_{Σ}. Typically, this pattern data set MEV also comprises the measurement error value with which this value of the detected total flux density B_{Σ} is afflicted. The pattern recognition device MEV may comprise its own computer system with its own computer core. The pattern recognition device MEV may comprise its own program memory and its own data memory. The memories of the system may be volatile and non-volatile. Such a computer system of the pattern recognition device MEV may access the volatile memory RAM and non-volatile memory NVM together with the control device CTR, if necessary, and share them with the control device CTR in whole or partially. The pattern recognition device MEV can realize its functions wholly or partially by executing corresponding computer-implemented programs which are stored in the memories of the pattern recognition device MEV or the memories RAM, NVM of the system at least temporarily.

It is particularly advantageous if, during a measurement cycle that is still running, the control device CTR determines one or more future operating points of the sensor system (with regard to magnetic flux density B_{ad} and microwave frequency ω_{μW} of the microwave signal μW) as a function of the data sets already detected in the measurement cycle that is still running and in previous measurement cycles, which are to be measured subsequently. Preferably, the control device CTR applies, for example, a computer-implemented method of Bayesian optimization in order to determine these subsequent one or more operating points from the value of the compensation field control signal (i.e. set additional magnetic flux density B_{ad}) and the frequency value of the microwave frequency ω_{μW} of the microwave signal μW at this operating point for the next determination(s) of the vector component values of the multidimensional filter output signal S4(t).

In a further embodiment, the sensor system preferably comprises a display unit, in particular a screen 32, which is capable of graphically displaying the position of the boundary between the first measuring point and the second measuring point in the parameter space.

In a further embodiment of the sensor system, the display unit, in particular the screen 32, comprises, for example, a graphical user interface that allows a user to monitor and adjust the position of the boundary in the parameter space.

In a further embodiment of the sensor system, the control computer, for example the control device CTR, is configured to apply computer-implemented error detection and error correction algorithms based on the measured values in order to improve the accuracy of determining the position of the boundary in parameter space.

In a further embodiment of the sensor system, the control computer, for example the control device CTR, is configured to communicate with other sensors and/or systems (e.g. 33), in particular via a data interface (e.g. 29), in order to obtain additional information for determining the position of the boundary in the parameter space and/or to pass such information on to these other sensors and/or systems (e.g. 33) and/or to keep it available for them.

In a further embodiment of the sensor system, the control computer, for example the control device CTR, is configured to work in real time and to continuously monitor and update the position of the boundary in the parameter space.

In a further configuration of the sensor system, the control computer, for example the control device CTR, is configured to adaptively adjust the operating points in the parameter space in order to achieve optimum measurement accuracy for determining the position of the boundary.

In a further embodiment of the sensor system, the control computer, for example the control device CTR, is configured to store and analyze the measurement results in order to identify trends and patterns in the determination of the position of the boundary in the parameter space.

To ensure that the optimization is not counterproductive due to a measurement duration that is too long, a termination condition, for example the number of operating points, should be provided.

Once all predetermined operating points, which may be redetermined during a measuring cycle, have been measured and/or the specified maximum number of measuring points has been reached or exceeded, the sensor system typically ends the measuring cycle.

After completion of the last measurement cycle, the control device CTR typically starts the next measurement cycle. For this purpose, the control device CTR can, for example, again first measure the predetermined operating points from a respective value of the compensation field control signal (i.e. set additional magnetic flux density B_{ad}) at this operating point and the respective frequency value of the microwave frequency of the microwave signal μW at this operating point and detect the associated vector component values of the multidimensional filter output signal S4(t) at these operating points and then optimize the measured values in a second phase and/or further phases of the measurement cycle by measuring additional operating points.

The determination of the additional operating points within the further phases of the measurement cycle may also be performed by computer-implemented optimization methods other than a computer-implemented Bayesian optimization method. The shape and the course of the lower resonance edge 522, the lower middle resonance edge 23, the upper middle resonance edge 524, the upper resonance edge 25 and the middle resonance minimum 529 of FIG. 51a are known in advance or can be determined in a calibration measurement process. Only the position 530 of the peak of the V-formation (522, 525) can be changed by an additional magnetic flux density B_{ad} or a change in the external magnetic flux density Bₑₓₜ. Preferably, the computer-implemented method executing the control device CTR takes this data into account. Preferably, this calibration data, which takes into account the shape and position and the course of the lower resonance edge 522, the lower middle resonance edge 523, the upper middle resonance edge 24, the upper resonance edge 525 and the middle resonance minimum 529 of FIG. 51a are at least partially stored in a non-volatile memory NVM or another memory RAM of the device or a storage medium of the device, so that the control device CTR can access this data via the data bus DB and can determine the shape and position of the lower resonance edge 523, the upper middle resonance edge 24, the upper resonance edge 525 and the middle resonance minimum 529 of FIG. 51a by comparing the data records of the current measuring cycle and, if applicable, of previous measuring cycles, the current total flux density B_{Σ} and the external total flux density B_{(ext)B}=Σ−B_{ad} and/or can deduce additional operating points required for further measurements to improve the measurement result.

Preferably, the device determines a respective measurement uncertainty for the operating points and the regions in between by means of a computer-implemented method using the control device CTR.

Preferably, the control device CTR determines one or more of the following values as part of a measurement cycle:
the probable position of the lower resonance edge 522;
the probable position of the lower middle resonance edge 523;
the probable position of the upper middle resonance edge 524;
the probable position of the upper resonance edge 525;
the probable position of the middle resonance minimum 529;
the probable value of the effective offset flux density B_{off};
is the probable value of the zero-point flux density B₀;
the probable value of the zero-point microwave frequency ω_{μW0};
the probable value 564 of the magnetic flux density B associated with the upper reference line 561 at one or more operating points;
the probable value 565 of the magnetic flux density B associated with the lower reference line 562 at one or more operating points;
the probable difference 566 of the value of the magnetic flux density B associated with the middle reference line 563 minus the value 565 of the magnetic flux density B associated with the lower reference line 562;
the probable slope 567 of the curve at one or more operating points;
the polynomial coefficients of the polynominal approximation 627 of the curve at some operating points;
the probable value of a lower effective magnetic flux density B₂₂;
the probable value of a lower mean effective magnetic flux density B₂₃;
the probable value of an upper mean effective magnetic flux density B₂₄;
the probable value of an upper effective magnetic flux density B₂₅;
the probable value of an effective magnetic resonance minimum flux density B₂₉;
the probable value of a zero-point microwave frequency ω_{μW0};
the probable value of a lower microwave frequency ω_{μW22};
the probable value of a lower mean microwave frequency ω_{μW23};
the probable value of an upper mean microwave frequency ω_{μW24};
the probable value of an upper microwave frequency ω_{μW25};
the probable value of a resonance minimum microwave frequency ω_{μW29};
the probable value of an unknown microwave frequency ω_{μWnk}; and
the probable value of a microwave modulation frequency f_{MμW}.

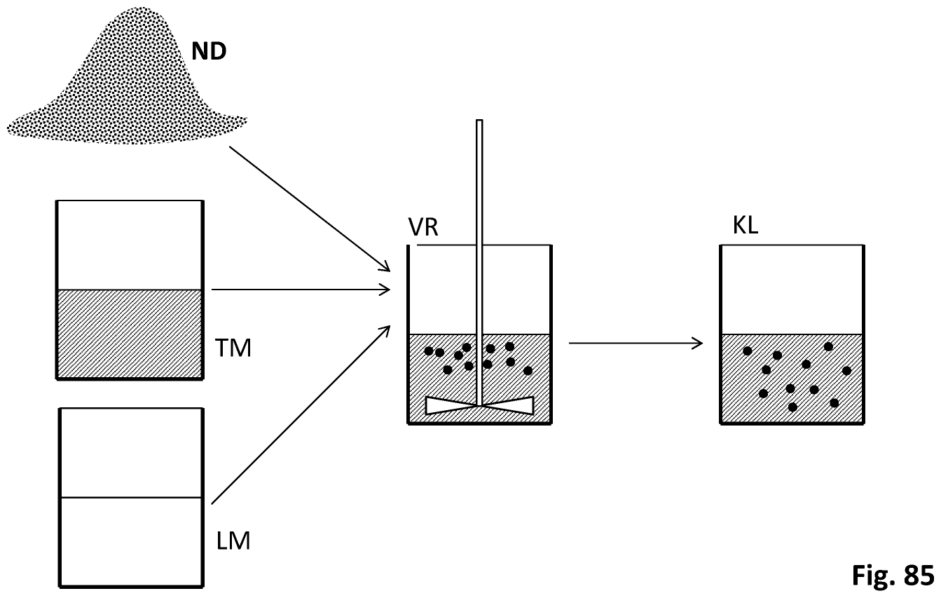

The device can determine the probable frequency value of an unknown microwave frequency ω_{μWnk} in that the microwave signal source μWG receives an internal microwave signal (μW_G_I, μW_G_II, μW_G_III, μW_G_IV) (see FIG. 85 for a vectorial embodiment, which can be applied here mutatis mutandis), comprising a known internal microwave frequency (ω_{μW_I}, ω_{μW_II}, ω_{μW_III}, ω_{μW_IV}), mixes with an external microwave signal S_{ω nk} to form the microwave signal μW and filters out one of the two sidebands by means of a filter (μWG_F_I, μWG_F_II, μWG_F_III, μWG_F_I, μWG_F_IV). The device is then typically calibrated with a known external microwave signal S_{ωμwk} with a reference microwave frequency ω_{pwk} and the zero-point microwave frequency ω_{μW0} and the value of the zero-point flux density B₀ are determined as the reference operating point. If an unknown microwave frequency ωₙₖ is now fed in from outside as an external microwave signal S_{ω nk}, the zero-point microwave frequency ω_{μW0} is shifted by a frequency difference value, between the zero-point microwave frequency ω_{μW0} during calibration and the zero-point microwave frequency ω_{μW0} during measurement of the unknown microwave frequency ω_{μWnk} corresponds to the difference between the reference microwave frequency and the unknown microwave frequency ω_{(μWnk)}. Therefore, the unknown microwave frequency ω_{μWnk} can be determined by determining the zero-point microwave frequency ω_{μW0}.

The device preferably adjusts the additional magnetic field B_{(ad)}. For this purpose, the device detects the total magnetic flux density B_{Σ} by means of a magnetic field sensor MS, compares the detected value of the total flux density B_{Σ} with a setpoint value and then adjusts the current supply of the magnetic field generation means L_{c} according to the difference between the total flux density Bs and the setpoint value. Preferably, this is a control with a PID-controller characteristic. For example, the device can form the signal S4_{c}(t) and use it as a controlled variable. In that case, the sensor element SE itself would be the magnetic field sensor MS. If the device does not use the sensor element SE as the magnetic field sensor MS for controlling the total magnetic flux density BE, the device can have a magnetic field sensor controller SIS, which controls, operates and reads out the magnetic field sensor MS and makes the measurement data read out in this way available to the magnetic field controller LCTR and/or the control device CTR for readjusting the total magnetic flux density B_{Σ}, for example by means of controlling the current supply to the magnetic field generation means L_{C} by the magnetic field controller LCTR. Preferably, the control device CTR can read out and/or control the magnetic field controller LCTR and the magnetic field sensor controller SIS via the data bus DB.

It is obvious that the formation of the above integrals can also be performed analogously without digitization of the receiver output signal in the multiple correlator LIV. For example, the vector component signals S4ₐ, S4_{b}, S4_{c} and S4ₐ or S4₁, S4₂, S4₃ and S4₄ can also be formed in the multiple correlator LIV by means of analog signal processing. In this case, digitization of the then analog vector component signals S4ₐ, S4_{b}, S4_{c} and S4ₐ or S4₁, S4₂, S4₃ and S4₄ of the filter output signal S4 is useful in order to make the values available to the control device CTR. In the case of analog formation of the above integrals, the use of a low pass filter TP or a filter with low pass properties as an integrator after the multiplications performed has proven itself.

### For Positioning the Sensor Elements SE

The document presented here indicates that a total of five positionings of sensor elements SE relative to the conduits and conduit surfaces of trip-plate waveguide 2380 are possible:
on the electrically conductive left signal ground plane 1310;
in the non-conductive left-hand insulation gap 2340;
on the signal conductor 1330;
in the non-conductive right-hand insulation gap 2350; and
on the electrically conductive left signal ground plane 1320.

Mixed forms of the sensor elements SE due to misplacement and enlargement of the relevant sensor elements SE are possible.

### FIG. 70

FIG. 70 shows an exemplary schematic realization of an analog multiple correlator LIV in a schematically sketched construction of FIG. 69.

For simplification, the analog multiple correlator LIV of FIG. 70 represents only one integral of the integrals listed in the description of FIG. 69. This is the integral

$$S {4}_{a} ( t ) = {\int }_{0}^{2 π} S 1 ( t ) \cdot S 5 w ( t ) \cdot S 5 m ( t ) dt$$

Since the multiple correlator LIV in FIG. 70 forms only this one integral, the multiple correlator LIV does not form any of the differences from the integrals as described in the description of FIG. 69.

In order to form the other integrals, additional parts of the device would have to be added, which can easily be done by a competent person.

Firstly, the missing inverted signals of the signals used here would have to be formed. For example, an inverter or similar would have to form the inverted microwave modulation signal S5mq or a functionally equivalent signal from the microwave modulation signal S5m. Furthermore, an inverter or the like would have to form the inverted LED modulation signal S5wd or a functionally equivalent signal from the LED modulation signal S5w. Additional multipliers and a further low pass TP would also be required for each signal to be formed. To form the differences of the filter output signals S4ₐ(t), S4_{B}(t), S4_{c}(t) and S4_{d}(t) formed by these low passes TP, a subtracter would then be required for each difference signal to be formed, which subtracts one of the filter output signals S4ₐ(t), S4_{b}(t), S4_{c}(t) and S4_{d}(t) from another of the filter output signals S4ₐ(t), S4_{b}(t), S4_{c}(t) and S4_{d}(t) and from this one of the vector component signals S4₁ (t), S4₂(t), S4₃(t) and S4₄(t) of the vector filter output signal S4(t) and, if appropriate, other vector component signals of the vector filter output signal S4(t) is subtracted. other vector component signals of the vectorial filter output signal S4(t).

FIG. 70 is therefore only one example of an analogous realization of the multiple correlator LIV from a larger set of possible realizations that are part of the technical teaching of the document presented here.

In FIG. 70, the first amplifier V1 does not digitize the receiver output signal S0 into a digital receiver output signal S1, but only forms the analog, amplified receiver output signal S1.

In the example of FIG. 70, the multiple correlator LIV comprises a first multiplier M1, which multiplies the first product S1(t)*s1(t)=S3a (t) of the L3 product

$$S 4 ( t ) = {\int }_{0}^{2 π} S 1 ( t ) \cdot s 1 ( t ) \cdot s 2 ( t ) dt$$

is formed. The result is the first intermediate signal S3a of the L3 product of the multiple correlator LIV.

In the example in FIG. 70, the first signal s1(t) of the L3 product is the LED modulation signal S5w.

In the example of FIG. 70, the multiple correlator LIV comprises a second multiplier M2, which multiplies the second product (S1(t)*s1(t))*s2(t)=S3a(t)*s2(t)=S3b(t) of the L3 product

$$S 4 ( t ) = {\int }_{0}^{2 π} S 1 ( t ) \cdot s 1 ( t ) \cdot s 2 ( t ) dt$$

is formed. The result is the second intermediate signal S3b(t) of the L3 product of the multiple correlator LIV.

In the example, in FIG. 70, low pass filtering of the intermediate signal S3b of the L3 product of the multiple correlator LIV in an analog low pass filter TP realizes the integration. Firstly, this low pass filter TP only forms an indefinite integral and not a definite integral. Secondly, this equivalence of a low pass filter TP with an integrator is only valid for sufficiently low frequencies.

Preferably, the cut-off frequency of the low pass filter TP is therefore selected so that the LED modulation frequency f_{LED}, the microwave modulation frequency f_{μW} and the difference frequency |f_{LED}−f_{μW}| are reliably suppressed, so that essentially only the components around 0Hz pass through the low pass filter TP.

The low pass TP can also realize and comprise more complex filter functions.

Not determining the integral in the low pass filter TP leads to errors. These can be avoided if a sample & hold circuit at the output of the low pass filter TP always freezes the analog level at the output of the low pass filter TP at the end of the longer period of the period of the microwave modulation signal S5m or the period of the LED modulation signal S5w until the next end of the period. This requires the two period durations to be in an integer ratio.

In practice, it has been shown that, depending on the application, such a sample & hold circuit as part of the low pass TP is often not absolutely necessary.

In the example shown in FIG. 70, the low pass TP forms the vector component signal S4ₐ(t) of the simplified one-dimensional vector filter output signal S4(t).

In the example of FIG. 70, the analog-to-digital converter ADC digitizes the vector component signal S4ₐ(t) of the simplified here exemplified one-dimensional vectorial filter output signal S4(t) and makes the sampled values available to the control device CTR via the data bus DB.

Typically, in the case of such an analog implementation, the device comprises more than one analog multiple correlator LIV for forming a plurality of vector component signals S4ₐ(t), S4_{B}(t), S4_{c}(t) and S4ₐ(t) of the vector filter output signal S4(t). The analog-to-digital converter ADC then samples each of these vector component signals S4ₐ(t), S4_{B}(t), S4_{c}(t) and S4ₐ(t) of the vector filter output signal S4(t) and makes their sampled values available to the control device CTR via the data bus DB.

In this respect, FIG. 70 is only a highly simplified illustration to explain the realization of a multiple correlator LIV. If the device comprises more than one multiple correlator LIV, these typically comprise different device parts such as multipliers and intermediate signals together for reasons of synergy in order to save resources.

### FIG. 71

FIG. 71 shows a device for controlling exemplary three sensor elements SE(1410, 1420, 1430), which are placed on the carrier substrate 1360, by means of an exemplary trip-plate waveguide 2380. Instead of the trip-plate waveguide 2380, other waveguides such as a slot line 1880 with the exemplary sensor elements 1410, 1420, 1430 or the microstrip line 1380 with the exemplary sensor elements 1410, 1420, 1430 can also be used. The technical teaching of FIG. 59 is thus intended here to stand in general for the control, measurement and evaluation of a plurality of sensor elements SE which are placed on a carrier substrate 1360 and whose NV centers and/or paramagnetic centers interact with the electromagnetic field and, in particular, with the magnetic flux density component of an electromagnetic field which is transported by a waveguide which is manufactured on the carrier substrate 1360.

In the example of FIG. 71, the device comprises as exemplary three sensor elements SE a left sensor element 1410 and a middle sensor element 1420 and a right sensor element 1430. The example of FIG. 71 is exemplary for devices with n sensor elements SE, where n is a positive integer greater than 1 and here in this example n=3 is exemplary.

In the example shown in FIG. 71, the device comprises several-here three-sensor element channels. Each sensor element channel is preferably assigned to a sensor element of the sensor elements SE(1410, 1420, 1430).

### General Sensor Element Channel

The device according to the proposal may typically comprise several sensor element channels. Preferably, the device according to the proposal comprises at least one sensor element channel or better at least two sensor element channels. In the example of FIG. 71, the device according to the proposal comprises as an example three sensor element channels.

Preferably, a sensor element channel comprises:
a first signal generator G1, which generates the LED modulation signal S5w;
a light source driver LDRV, which generates the transmission signal S5 for the pump radiation source, in this case the light source LED, as a function of the LED modulation signal S5w and preferably supplies the pump radiation source, in this case the light source LED, with electrical energy;
a transmission signal S5;
a pump radiation source, in this case a light source LED, which generates the pump radiation LB as a function of the transmission signal S5 and, for example, switches the pump radiation source, in this case a light source LED, on only temporarily and off only temporarily;
a first optical system;
which comprises one or more optical functional elements;
which detects the pump radiation LB of the pump radiation source, in this case the light source LED;
which transports the pump radiation LB to the assigned sensor element SE;
which decouples the pump radiation LB from the first optical system;
which exposes the assigned sensor element SE to pump radiation LB; and
which preferably comprises an optical waveguide LWL) for the sensor element SE as such an optical functional element;
a second optical system;
which comprises one or more optical functional elements;
which detects the fluorescence radiation FL of the NV centers and/or the paramagnetic centers of the associated sensor element SE;
which transports fluorescence radiation FL from the NV centers and/or the paramagnetic centers of the associated sensor element SE to the associated photo detector PD;
which couples fluorescence radiation FL from the NV centers and/or the paramagnetic centers of the associated sensor element SE from the second optical system;
which exposes the associated photo detector PD to fluorescence radiation FL of the NV centers and/or the paramagnetic centers of the associated sensor element SE;
which comprises functional elements, for example a dichroitic mirror F1 and/or an optical filter in the beam path, which ensure that essentially no pump radiation LB from this or other pump radiation sources, in particular that of the light source LED and/or other light sources (LED, LED_1, LED2, LED_3), reaches the photo detector PD;
which preferably comprises an optical waveguide LWL) for the sensor element SE as such an optical functional element; and
which may comprise device parts that are identical to device parts of the first optical system;
the photo detector PD, which converts the intensity of the received fluorescence radiation FL into a receiver output signal S0;
the receiver output signal S0;
a first amplifier V1 for the sensor element SE for amplification and/or digitization of the receiver signal S0 to the amplified receiver output signal S1 or to the digitized receiver output signal S1;
the amplified receiver output signal S1 or the digitized receiver output signal S1;
a multiple correlator LIV, which forms a vectorial filter output signal S4 as a function of the amplified receiver output signal S1 or the digitized receiver output signal S1 and the LED modulation signal S5w and makes data of the vectorial filter output signal S4 available to the control device CTR, in particular keeps it available for the control device CTR or transfers it to the control device CTR or another device (e.g. the pattern recognition device MEV), in particular for evaluation; and a vectorial filter output signal S4 for the associated sensor element SE, which is typically a part of a common vectorial filter output signal S4 of the vectorial filter output signals S4 of other sensor element channels and is typically evaluated by a pattern recognition device MEV and/or the control device CTR.

In a further development, the general sensor element channel comprises:
a second signal generator G2 configured to generate a microwave modulation signal S5m;
a waveguide (1380, 1880, 2380, 6830, 6980);
a microwave signal source μWG configured to generate the microwave signal μW for the waveguide (1380, 1880, 2380, 6830, 6980) as a function of the microwave modulation signal S5m and to feed it into the waveguide (1380, 1880, 2380, 6830, 6980); and
the multiple correlator LIV for the sensor element SE, which forms a vectorial filter output signal S4 for the sensor element SE as a function of the amplified receiver output signal S1 for the sensor element SE or from the digitized receiver output signal S1 for the sensor element SE and the LED modulation signal S5w for the sensor element SE and the microwave modulation signal S5m and makes data of the vectorial filter output signal S4 for the sensor element SE available to the control device CTR, in particular keeps it available for the control device CTR or transfers it to the control device CTR or another device (e.g. the pattern recognition device MEV), in particular for evaluation.

FIG. 71 comprises three such sensor element channels.

An exemplary first, left sensor element channel is associated with exemplary left sensor element 1410.

An exemplary second center sensor element channel is associated with exemplary center sensor element 1420.

An exemplary third, right-hand sensor element channel is associated with the exemplary right-hand sensor element 1430.

### First, Left Sensor Element Channel

Preferably, the first, left-hand sensor element channel comprises:
a first signal generator G1_1 for the left sensor element 1410, which generates the LED modulation signal S5w_1 for the left sensor element 1410;
a light source driver LDRV_1 for the left sensor element 1410, which generates the transmission signal S5_1 for the left sensor element 1410 for controlling the pump radiation source for the left sensor element 1410, in this case the light source LED_1 for the left sensor element 1410, as a function of the LED modulation signal S5w_1 for the left sensor element 1410 and preferably supplies the pump radiation source for the left sensor element 1410, in this case the light source LED_1 for the left sensor element 1410, with electrical energy;
a transmission signal S5_1 for the left sensor element 1410;
a pump radiation source the left sensor element 1410, in this case a light source LED_1 for the left sensor element 1410, which generates the pump radiation LB_1 for the left sensor element 1410 as a function of the transmission signal S5_1 for the left sensor element 1410 and, for example, switches the pump radiation source for the left sensor element 1410, in this case a light source LED_1 for the left sensor element 1410, on only temporarily and off only temporarily;
a first optical system for the left sensor element 1410;
which comprises one or more optical functional elements;
detecting the pump radiation LB_1 for the left sensor element 1410 of the pump radiation source for the left sensor element 1410, here the light source LED_1 for the left sensor element 1410;
which transports the pump radiation LB for the left sensor element 1410 to the associated sensor element SE, in this case the left sensor element 1410;
which decouples the pump radiation LB_1 for the left sensor element 1410 from the first optical system for the left sensor element 1410;
which exposes the associated sensor element SE, in this case the left sensor element 1410, to pump radiation LB_1 for the left sensor element 1410; and
which preferably comprises an optical waveguide LWL_1 for the left sensor element 1410 as such an optical functional element;
a second optical system:
which comprises one or more optical functional elements;
which detects the fluorescence radiation FL_1 of the NV centers and/or the paramagnetic centers of the associated sensor element SE, here the left sensor element 1410;
the fluorescence radiation FL_1 of the NV centers and/or the paramagnetic centers of the associated sensor element SE, in this case the left sensor element 1410, is transported to the associated photo detector PD_1 for the left sensor element 1410;
which couples fluorescence radiation FL_1 of the NV centers and/or the paramagnetic centers of the associated sensor element SE, here the left sensor element 1410, out of the second optical system;
which exposes the associated photo detector PD_1 for the left sensor element 1410 to fluorescence radiation FL_1 of the NV centers and/or the paramagnetic centers of the associated sensor element SE, in this case the left sensor element 1410;
which comprises functional elements, for example a dichroitic mirror F1_1 for the left-hand sensor element 1410 and/or an optical filter in the beam path, which ensure that essentially no pump radiation LB_1 from this or other pump radiation sources, in particular that from the light source LED_1 and/or other light sources (LED, LED_1, LED2, LED_3), reaches the photo detector PD_1 for the left-hand sensor element 1410;
which preferably comprises an optical waveguide LWL_1 for the left sensor element 1410 as such an optical functional element; and
which may comprise device parts that are identical to device parts of the first optical system;
the photo detector PD_1 for the left sensor element 1410, which converts the intensity of the received fluorescence radiation FL_1 of the left sensor element 1410 into a receiver output signal S0_1 for the left sensor element 1410;
the receiver output signal S0_1 for the left sensor element 1410;
a first amplifier V1_1 for the sensor element SE, here for the left sensor element 1410, for amplifying and/or digitizing the receiver signal S0_1 for the left sensor element 1410 to the amplified receiver output signal S1_1 for the left sensor element 1410 or to the digitized receiver output signal S1_1 for the left sensor element 1410;
the amplified receiver output signal S1_1 for the left sensor element 1410 or the digitized receiver output signal S1_1 for the left sensor element 1410;
a multiple correlator LIV_1 for the left sensor element 1410, which forms a vectorial filter output signal S4_1 for the left sensor element 1410 in dependence on the amplified receiver output signal S1_1 for the left sensor element 1410 or from the digitized receiver output signal S1_1 for the left sensor element 1410 and the LED modulation signal S5w_1 for the left sensor element 1410 and makes data of the vectorial filter output signal S4_1 for the left sensor element 1410 available to the control device CTR, in particular keeps it available for the control device CTR or transfers it to the control device CTR or another device (e.g. the pattern recognition device MEV), in particular for evaluation; and
a vectorial filter output signal S4_1 for the left sensor element 1410, which is typically a part of the vectorial filter output signal S4 and is typically evaluated by a pattern recognition device MEV and/or the control device CTR.

In a further development, the first sensor element channel comprises:
a first second signal generator G2_I, which is configured to generate a first microwave modulation signal S5m_I;
a first waveguide (1380, 1880, 2380, 6830, 6980);
a first microwave signal source μWG_I, which is configured to generate the first microwave signal μW_I for the first waveguide (1380, 1880, 2380, 6830, 6980) as a function of the first microwave modulation signal S5m_I and to feed it into the first waveguide 1380, 1880, 2380, 6830, 6980; and
the multiple correlator LIV_1 for the left sensor element 1410, which generates a vectorial filter output signal S4_1 for the left sensor element 1410 as a function of the amplified receiver output signal S1_1 for the left sensor element 1410 or from the digitized receiver output signal S1_1 for the left sensor element 1410 and the LED modulation signal S5w_1 for the left sensor element 1410 and the first microwave modulation signal S5m_I and makes data of the vectorial filter output signal S4_1 for the left sensor element 1410 available to the control device CTR, in particular keeps it available for the control device CTR or transfers it to the control device CTR or another device (e.g. the pattern recognition device MEV), in particular for evaluation.

With regard to the functions and the interaction of the sensor element channel specific device parts (SE(1410); S5w_1, LDRV_1, S5_1, LED_1, LB_1, LWL_1, F1_1, PD_1, S0_1, V1_1, S1_1, LIV_1, S4_1) of the first, left sensor element channel and the other non-sensor element channel specific device parts of the device, the document presented here refers to the description of FIG. 69 for the corresponding device parts (SE, S5w, LDRV, S5, LED, LB, LWL, F1, PD, S0, V1, S1, LIV, S4) of the one sensor channel of FIG. 69 and the other non-sensor element channel specific device parts of the device of FIG. 69.

### Second, Middle Sensor Element Channel

Preferably, the second, middle sensor element channel comprises:
a first signal generator G1_2 for the center sensor element 1420, which generates the LED modulation signal S5w_2 for the center sensor element 1420;
a light source driver LDRV_2 for the middle sensor element 1420, which generates the transmission signal S5_2 for the middle sensor element 1420 for controlling the pump radiation source for the middle sensor element 1420, in this case the light source LED_2 for the middle sensor element 1420, as a function of the LED modulation signal S5w_2 for the middle sensor element 1420 and preferably supplies the pump radiation source for the middle sensor element 1420, in this case the light source LED_2 for the middle sensor element 1420, with electrical energy;
a transmission signal S5_2 for the middle sensor element 1420;
a pump radiation source the middle sensor element 1420, in this case a light source LED_2 for the middle sensor element 1420, which generates the pump radiation LB_2 for the middle sensor element 1420 as a function of the transmission signal S5_2 for the middle sensor element 1420 and, for example, switches the pump radiation source for the middle sensor element 1420, in this case a light source LED_2 for the middle sensor element 1420, on only temporarily and off only temporarily;
a first optical system for the middle sensor element 1420;
which comprises one or more optical functional elements;
detecting the pump radiation LB_2 for the center sensor element 1420 of the pump radiation source for the center sensor element 1420, here the light source LED_2 for the center sensor element 1420;
which transports the pump radiation LB_2 for the middle sensor element 1420 to the associated sensor element SE, in this case the middle sensor element 1420;
which decouples the pump radiation LB_2 for the middle sensor element 1420 from the first optical system for the middle sensor element 1420;
which exposes the associated sensor element SE, in this case the middle sensor element 1420, to pump radiation LB_2 for the middle sensor element 1420; and
which preferably comprises an optical waveguide LWL_2 for the middle sensor element 1420 as such an optical functional element;
a second optical system;
which comprises one or more optical functional elements;
which detects the fluorescence radiation FL_2 of the NV centers and/or the paramagnetic centers of the associated sensor element SE, in this case the middle sensor element 1420;
the fluorescence radiation FL_2 of the NV centers and/or the paramagnetic centers of the associated sensor element SE, in this case the middle sensor element 1420, is transported to the associated photo detector PD_2 for the middle sensor element 1420;
which couples fluorescence radiation FL_2 of the NV centers and/or the paramagnetic centers of the associated sensor element SE, here the middle sensor element 1420, out of the second optical system;
which exposes the associated photo detector PD_2 for the middle sensor element 1420 to fluorescence radiation FL_2 of the NV centers and/or the paramagnetic centers of the associated sensor element SE, in this case the middle sensor element 1420;
which comprises functional elements, for example a dichroitic mirror F1_2 for the middle sensor element 1420 and/or an optical filter in the beam path, which ensure that essentially no pump radiation LB_2 from this or other pump radiation sources, in particular that from the light source LED_2 and/or other light sources (LED, LED_1, LED2, LED_3), reaches the photo detector PD_2 for the middle sensor element 1420;
which preferably comprises an optical waveguide LWL_2 for the central sensor element 1420 as such an optical functional element;
which may comprise device parts that are identical to device parts of the first optical system;
the photo detector PD_2 for the center sensor element 1420, which converts the intensity of the received fluorescence radiation FL_2 of the center sensor element 1420 into a receiver output signal S0_2 for the center sensor element 1420;
the receiver output signal S0_2 for the middle sensor element 1420;
a first amplifier V1_2 for the sensor element SE, here for the middle sensor element 1410, for amplifying and/or digitizing the receiver signal S0_2 for the middle sensor element 1420 to the amplified receiver output signal S1_2 for the middle sensor element 1420 or to the digitized receiver output signal S1_2 for the middle sensor element 1420;
the amplified receiver output signal S1_2 for the middle sensor element 1420 or the digitized receiver output signal S1_2 for the middle sensor element 1420;
a multiple correlator LIV_2 for the center sensor element 1420, which forms a vectorial filter output signal S4_2 for the center sensor element 1420 in dependence on the amplified receiver output signal S1_2 for the center sensor element 1420 or from the digitized receiver output signal S1_2 for the middle sensor element 1420 and the LED modulation signal S5w_2 for the middle sensor element 1420 and makes data of the vectorial filter output signal S4_2 for the middle sensor element 1420 available to the control device CTR, in particular keeps it available for the control device CTR or transfers it to the control device CTR or another device (e.g. the pattern recognition device MEV), in particular for evaluation; and
a vectorial filter output signal S4_2 for the middle sensor element 1420, which is typically a part of the vectorial filter output signal S4 and is typically evaluated by a pattern recognition device MEV and/or the control device CTR.

In a further development, the second sensor element channel comprises:
a second signal generator G2_II, which is configured to generate a second microwave modulation signal S5m_II;
a second waveguide (1380, 1880, 2380, 6830, 6980);
a second microwave signal source μWG_II, which is configured to generate the second microwave signal μW_II for the second waveguide (1380, 1880, 2380, 6830, 6980) as a function of the second microwave modulation signal S5m_II and to feed it into the second waveguide 1380, 1880, 2380, 6830, 6980; and
the multiple correlator LIV_2 for the middle sensor element 1420, which generates a vectorial filter output signal S4_2 for the middle sensor element 1420 as a function of the amplified receiver output signal S1_2 for the middle sensor element 1420 or from the digitized receiver output signal S1_2 for the middle sensor element 1420 and the LED modulation signal S5w_2 for the middle sensor element 1420 and the second microwave modulation signal S5m_II and makes data of the vectorial filter output signal S4_2 for the middle sensor element 1420 available to the control device CTR, in particular keeps it available for the control device CTR or transfers it to the control device CTR or another device (e.g. the pattern recognition device MEV), in particular for evaluation.

With regard to the functions and interaction of the sensor element channel-specific device parts (SE(1420); S5w_2, LDRV_2, S5_2, LED_2, LB_2, LWL_2, F1_2, PD_2, S0_2, V1_2, S1_2, LIV_2, S4_2) of the second, middle sensor element channel and the other non-sensor element channel specific device parts of the device, the document presented here refers to the description of FIG. 69 for the corresponding device parts (SE, S5w, LDRV, S5, LED, LB, LWL, F1, PD, S0, V1, S1, LIV, S4) of the one sensor channel of FIG. 69 and the other non-sensor element channel specific device parts of the device of FIG. 69.

### Third, Right-Hand Sensor Element Channel

Preferably, the third, right-hand sensor element channel comprises:
a first signal generator G1_3 for the right sensor element 1430, which generates the LED modulation signal S5w_3 for the right sensor element 1430:
a light source driver LDRV_3 for the right sensor element 1430, which generates the transmission signal S5_3 for the right sensor element 1430 for controlling the pump radiation source for the right sensor element 1430, in this case the light source LED_3 for the right sensor element 1430, as a function of the LED modulation signal S5w_3 for the right sensor element 1430 and preferably supplies the pump radiation source for the right sensor element 1430, in this case the light source LED_3 for the right sensor element 1430, with electrical energy:
a transmission signal S5_3 for the right sensor element 1430;
a pump radiation source the right sensor element 1430, in this case a light source LED_3 for the right sensor element 1430, which generates the pump radiation LB_3 for the right sensor element 1430 as a function of the transmission signal S5_3 for the right sensor element 1430 and, for example, switches the pump radiation source for the right sensor element 1430, in this case a light source LED_3 for the right sensor element 1430, on only temporarily and off only temporarily:
a first optical system for the right sensor element 1430:
which comprises one or more optical functional elements;
detecting the pump radiation LB_3 for the right sensor element 1430 of the pump radiation source for the right sensor element 1430, here the light source LED_3 for the right sensor element 1430;
which transports the pump radiation LB_3 for the right sensor element 1430 to the associated sensor element SE, in this case the right sensor element 1430, and
which decouples the pump radiation LB_3 for the right sensor element 1430 from the first optical system for the right sensor element 1430;
which exposes the associated sensor element SE, in this case the right-hand sensor element 1430, to pump radiation LB_3 for the right-hand sensor element 1430; and
which preferably comprises an optical waveguide LWL_3 for the right sensor element 1430 as such an optical functional element;
a second optical system,
which comprises one or more optical functional elements;
which detects the fluorescence radiation FL_3 of the NV centers and/or the paramagnetic centers of the associated sensor element SE, in this case the right-hand sensor element 1430;
the fluorescence radiation FL_3 of the NV centers and/or the paramagnetic centers of the associated sensor element SE, here the right-hand sensor element 1430, is transported to the associated photo detector PD_3 for the right-hand sensor element 1430;
which couples fluorescence radiation FL_3 from the NV centers and/or the paramagnetic centers of the associated sensor element SE, in this case the right-hand sensor element 1430, out of the second optical system;
which exposes the associated photo detector PD_3 for the right sensor element 1430 to fluorescence radiation FL_3 of the NV centers and/or the paramagnetic centers of the associated sensor element SE, in this case the right sensor element 1430;
which comprises functional elements, for example a dichroitic mirror F1_3 for the right-hand sensor element 1430 and/or an optical filter in the beam path, which ensure that essentially no pump radiation LB_3 from this or other pump radiation sources, in particular that from the light source LED_3 and/or other light sources (LED, LED_1, LED2, LED_3), reaches the photo detector PD_3 for the right-hand sensor element 1430;
which preferably comprises an optical waveguide LWL_3 for the right sensor element 1430 as such an optical functional element; and
which may comprise device parts that are identical to device parts of the first optical system;
the photo detector PD_3 for the right sensor element 1430, which converts the intensity of the received fluorescence radiation FL_3 of the right sensor element 1430 into a receiver output signal S0_3 for the right sensor element 1430;
the receiver output signal S0_3 for the right sensor element 1430;
a first amplifier V1_23 for the sensor element SE, here for the right sensor element 1430, for amplifying and/or digitizing the receiver signal S0_3 for the right sensor element 1430 to the amplified receiver output signal S1_3 for the right sensor element 1430 or to the digitized receiver output signal S1_3 for the right sensor element 1430;
the amplified receiver output signal S1_3 for the right sensor element 1430 or the digitized receiver output signal S1_3 for the right sensor element 1430;
a multiple correlator LIV_3 for the right sensor element 1430, which forms a vectorial filter output signal S4_3 for the right sensor element 1430 in dependence on the amplified receiver output signal S1_3 for the right sensor element 1430 or from the digitized receiver output signal S1_3 for the right sensor element 30e0 and the LED modulation signal S5w_3 for the right sensor element 1430 and makes data of the vectorial filter output signal S4_3 for the right sensor element 1430 available to the control device CTR, in particular keeps it available for the control device CTR or transfers it to the control device CTR or another device (e.g. the pattern recognition device MEV), in particular for evaluation; and
a vectorial filter output signal S4_3 for the right sensor element 1430, which is typically a part of the vectorial filter output signal S4 and is typically evaluated by a pattern recognition device MEV and/or the control device CTR.

In a further development, the third sensor element channel comprises:
a third second signal generator G2_III configured to generate a third microwave modulation signal S5m_III;
a third waveguide (1380, 1880, 2380, 6830, 6980);
a third microwave signal source μWG_III, which is configured to generate the third microwave signal μW_III for the third waveguide (1380, 1880, 2380, 6830, 6980) as a function of the third microwave modulation signal S5m_III and to feed it into the third waveguide 1380, 1880, 2380, 6830, 6980; and
the multiple correlator LIV_3 for the right sensor element 1430, which generates a vectorial filter output signal S4_3 for the right sensor element 1430 as a function of the amplified receiver output signal S1_3 for the right sensor element 1430 or from the digitized receiver output signal S1_3 for the right sensor element 1430 and the LED modulation signal S5w_3 for the right sensor element 1430 and the third microwave modulation signal S5m_III and makes data of the vectorial filter output signal S4_3 for the right sensor element 1430 available to the control device CTR, in particular keeps it available for the control device CTR or transfers it to the control device CTR or another device (e.g. the pattern recognition device MEV), in particular for evaluation.

With regard to the functions and the interaction of the sensor element channel specific device parts (SE(1430); S5w_3, LDRV_3, S5_3, LED_3, LB_3, LWL_3, F1_3, PD_3, S0_3, V1_3, S1_3, LIV_3, S4_3) of the third, right-hand sensor element channel and the other non-sensor element channel-specific device parts of the device, the document presented here refers to the description of FIG. 69 for the corresponding device parts (SE, S5w, LDRV, S5, LED, LB, LWL, F1, PD, S0, V1, S1, LIV, S4) of the one sensor channel of FIG. 69 and the other non-sensor element channel specific device parts of the device of FIG. 69.

The arrangement of the sensor elements 1410, 1420 1430 and the leads 1310, 1320, 1330 on the carrier substrate 1360 in the preferred presence of a magnetic field generation means L_{c}, for example a flat coil 2520, thus essentially corresponds to the arrangements of FIGS. 68 and 67.

### Alternative Use of a Slot Line 1880

Omitting the signal conductor 1330 transforms the triplate line 2380 into a slot line 1880. The left sensor element 1410 is then preferably placed on the electrically conductive left signal ground plane 1310 of the exemplary slot line 1880 to the left of the slot 1840 of the slot line 1880 in the vicinity of the edge of the slot 1840 of the slot line 1880. The right sensor element 1430 is then preferably placed on the electrically conductive right signal ground plane 1320 of the exemplary slot line 1880 to the right of the slot 1840 of the slot line 1880, near the edge of the slot 1840 of the slot line 1880. The center sensor element 1420 is then preferably placed as centrally as possible in the slot 1840 of the slot line 1880.

As the sensitivities of the sensor elements 1410, 1420, 1430 are different from those when using a trip-plate waveguide 2380, the parameters used by the device parts may have to be adjusted.

### Alternative Use of a Microstrip Cable 1380

Omitting the electrically conductive left signal ground plane 1310 and the electrically conductive right signal ground plane 1320 transforms the triplate line 2380 into a microstrip line 1380. The left sensor element 1410 is then preferably placed on the electrically essentially non-conductive left insulation area 1340 of the exemplary microstrip line 1380 to the left of the signal conductor 1330 of the microstrip line 1380 near the edge of the signal conductor 1330 of the microstrip line 1380. The right sensor element 1430 is then preferably placed on the electrically essentially non-conductive right insulation area 1350 of the exemplary microstrip line 1380 to the right of the signal conductor 1330 of the microstrip line 1380, near the edge of the signal conductor 1330 of the microstrip line 1380. The center sensor element 1420 is then preferably placed as centrally as possible on the signal conductor 1330 of the microstrip line 1380.

Since the sensitivities of the sensor elements 1410, 1420, 1430 are different from those when a slot line 1880 is used, the parameters that the device parts use may need to be adjusted. In the case of using a trip-plate waveguide 2380, the parameter differences between the parameters used by the device parts in the case of a trip-plate waveguide 2380 and the parameters used by the device parts in the case of a microstrip line 1380 are generally smaller.

Simplification without Left Sensor Element 1410

If the left sensor element 1410 is omitted, the sensor element channel-specific device parts (SE(1410); S5w_1, LDRV_1, S5_1, LED_1, LB_1, LWL_1, F1_1, PD_1, S0_1, V1_1, S1_1, LIV_1, S4_1) of the first left sensor element channel can also be omitted. The processing of the vectorial filter output signal S4, which is then reduced in dimensionality, by the pattern recognition device MEV and/or the control device CTR must then be adapted accordingly.

Simplification without Right Sensor Element 1430

If the right sensor element 1430 is omitted, the sensor element channel-specific device parts (SE(1430); S5w_3, LDRV_3, S5_3, LED_3, LB_3, LWL_3, F1_3, PD_3, S0_3, V1_3, S1_3, LIV_3, S4_3) of the third right sensor element channel can also be omitted. The processing of the vectorial filter output signal S4, which is then reduced in dimensionality, by the pattern recognition device MEV and/or the control device CTR must then be adapted accordingly.

Simplification without Middle Sensor Element 1420

If the middle sensor element 1420 is omitted, the sensor element channel-specific device parts (SE(1420); S5w_2, LDRV_2, S5_2, LED_2, LB_2, LWL_2, F1_2, PD_2, S0_2, V1_2, S1_2, LIV_2, S4_2) of the second middle sensor element channel can also be omitted. The processing of the vectorial filter output signal S4, which is then reduced in dimensionality, by the pattern recognition device MEV and/or the control device CTR must then still be adapted accordingly. However, such a device is-not or only slightly sensitive to components of the magnetic flux density that are perpendicular to the surface of the carrier substrate 1370 or whose components of the magnetic flux density are parallel to the signal line 1330.

Simplification Only with Left Sensor Element 1410

If the right sensor element 1430 and the middle sensor element 1420 are not used, the sensor element channel-specific device parts (SE(1420); S5w_2, LDRV_2, S5_2, LED_2, LB_2, LWL_2, F1_2, PD_2, S0_2, V1_2, S1_2, LIV_2, S4_2) of the second middle sensor element channel and (SE(1430); S5w_3, LDRV_3, S5_3, LED_3, LB_3, LWL_3, F1_3, PD_3, S0_3, V1_3, S1_3, LIV_3, S4_3) of the third right sensor element channel are also omitted. The processing of the vectorial filter output signal S4, which is then reduced in dimensionality, by the pattern recognition device MEV and/or the control device CTR must then still be adapted accordingly. However, such a device is-not or only slightly sensitive to components of the magnetic flux density that are perpendicular to the surface of the carrier substrate 1370 or whose flux density vector is parallel to the signal line 1330.

Simplification Only with Right-Hand Sensor Element 1430

If the left sensor element 1410 and the middle sensor element 1420 are dispensed with, the sensor element channel-specific device parts (SE(1420); S5w_2, LDRV_2, S5_2, LED_2, LB_2, LWL_2, F1_2, PD_2, S0_2, V1_2, S1_2, LIV_2, S4_2) of the second middle sensor element channel and (SE(1410); S5w_1, LDRV_1, S5_1, LED_1, LB_1, LWL_1, F1_1, PD_1, S0_1, V1_1, S1_1, LIV_1, S4_1) of the first left sensor element channel are also omitted. The processing of the vectorial filter output signal S4, which is then reduced in dimensionality, by the pattern recognition device MEV and/or the control device CTR must then still be adapted accordingly. However, such a device is-not or only slightly sensitive to components of the magnetic flux density that are perpendicular to the surface of the carrier substrate 1370 or whose flux density vector is parallel to the signal line 1330.

Simplification Only with Middle Sensor Element 1420

If the left sensor element 1430 and the right sensor element 1430 are dispensed with, the sensor element channel-specific device parts SE(1430); S5w_3, LDRV_3, S5_3, LED_3, LB_3, LWL_3, F1_3, PD_3, S0_3, V1_3, S1_3, LIV_3, S4_3) of the third right sensor element channel and (SE(1410); S5w_1, LDRV_1, S5_1, LED_1, LB_1, LWL_1, F1_1, PD_1, S0_1, V1_1, S1_1, LIV_1, S4_1) of the first left sensor element channel are also omitted. The processing of the vectorial filter output signal S4, which is then reduced in dimensionality, by the pattern recognition device MEV and/or the control device CTR must then still be adapted accordingly. However, such a device is-not or only slightly sensitive to components of the magnetic flux density that are aligned parallel to the surface of the carrier substrate 1370.

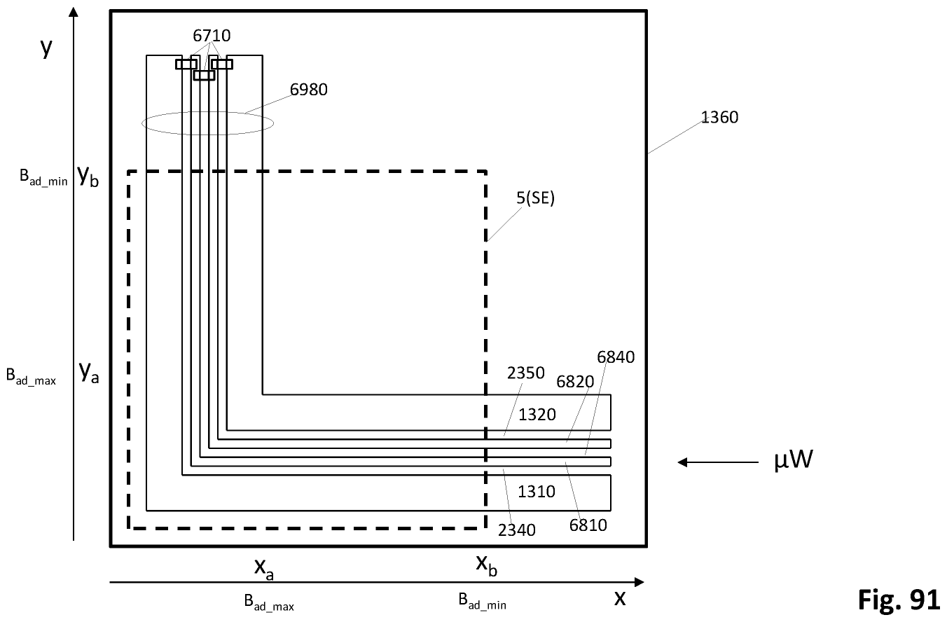

Of course, it is conceivable that the device could have further carrier substrates with waveguides (2380, 1880, 1380, 6830) and sensor elements (SE, 1410, 1420, 1430, 1710, 2210, 2410, 2420, 2430, 4410, 7115, 7125, 1735, 7145 and 7155) and preferably for each sensor element preferably comprises a sensor element channel with corresponding device parts corresponding to the device parts (SE, S5w, LDRV, S5, LED, LB, LWL, F1, PD, S0, V1, S1, LIV, S4) of the one sensor channel of FIG. 58. Particularly preferred are devices comprising two waveguides (2380, 1880, 1380, 6830) each having one or more sensor elements (SE, 1410, 1420, 1430, 1710, 2210, 2410, 2420, 2430, 4410, 7115, 7125, 1735, 7145 and 7155) and associated sensor element channels and device parts independent of the sensor element channel, in which the waveguides are arranged perpendicular to each other. Particularly preferred are devices comprising two waveguides (2380, 1880, 1380, 6830) each having one or more sensor elements (SE, 1410, 1420, 1430, 1710, 2210, 2410, 2420, 2430, 4410, 7115, 7125, 1735, 7145 and 7155) and associated sensor element channels and sensor element channel independent device parts, in which the waveguides are arranged perpendicular to each other in the plane of the surface of one of the carrier substrates 1370. (See FIG. 91) Particularly preferred are devices comprising two waveguides (2380, 1880, 1380, 6830) each having one or more sensor elements (SE, 1410, 1420, 1430, 1710, 2210, 2410, 2420, 2430, 4410, 7115, 7125, 1735, 7145 and 7155) and associated sensor element channels and the sensor element channel independent device parts in which the waveguides are arranged perpendicular to each other on the surface of the same carrier substrate 1370.

Typically, sensor elements (1410, 1420, 1430) of a waveguide (2380, 1880, 1380, 6830) have one or more common flat coils 2520 as common magnetic field generation means L_{C}. Preferably, the control device CTR and/or the magnetic field controller LCTR determine a value for the total flux density B_{Σ} and compares this determined value of the total flux density B_{Σ} with a setpoint value. Preferably, the control device CTR and/or the magnetic field controller LCTR determine the value for the total flux density B_{Σ} by means of the evaluation of the vectorial filter output signal S4 and/or by means of a magnetic field sensor MS and a magnetic field sensor controller SIS.

### Vector Sensor Element Channel

For the purposes of the present document, the plurality of sensor elements (SE, 1410, 1420, 1430, 1710, 2210, 2410, 2420, 2430, 4410, 7115, 7125, 1735, 7145 and 7155) can also be understood as a vectorial sensor element SE, that generates a plurality of separate fluorescence radiation signals (FL_1, FL_2, FL_3) as a vectorial fluorescence radiation signal FL upon exposure to pump radiation LB of the pump radiation wavelength λₚₘₚ.

The device according to the proposal may typically comprise a plurality of vectorial sensor element channels and vectorial sensor elements SE. The vectorial device according to the proposal preferably comprises at least one vectorial sensor element channel with preferably at least two sensor element channels. In the example shown in FIG. 60, the proposal-based device comprises, by way of example, a three-dimensional vectorial sensor element channel with three sensor element channels and a three-dimensional vectorial sensor element with three sensor elements (SE, 1410, 1420, 1430).

Preferably, a vectorial sensor element channel comprises:
a first signal generator G1, which generates an LED modulation signal S5w, or a first vectorial signal generator G1 comprising a plurality of signal generators (G1_1, G1_2, G1,_3), which generates a vectorial LED modulation signal S5w comprising a plurality of LED modulation signals (S5w_1, S5w_2, S5w_3):
a vectorial light source driver LDRV comprising a plurality of light source drivers (LDRV_1, LDRV_2, LDRV_3), which generates the vectorial transmission signal S5 for the vectorial pump radiation source, in this case the vectorial light source LED, as a function of the vectorial LED modulation signal S5w and/or the LED modulation signal S5w and preferably supplies the vectorial pump radiation source, in this case the light sources (LED_1, LED_2, LED_3) of the vectorial light source LED, with electrical energy:
a vectorial transmission signal S5, comprise several transmission signals (S5_1, S5_2, S5_3):
a vectorial pump radiation source, here a vectorial light source LED, which generates the vectorial pump radiation LB as a function of the vectorial transmission signal S5 and, for example, switches the pump radiation source, here a vectorial light source LED comprising a plurality of light sources (LED_1, LED_2, LED_3), only temporarily and/or partially on and only temporarily and/or partially off:
a first vector optical system;
which comprises one or more vectorial optical functional elements;
which detects the vectorial pump radiation LB of the vectorial pump radiation source, here the vectorial light source LED, in a vectorial manner, i.e. which detects the vectorial pump radiation components (LB_1, LB2, LB3) separately;
which transports the detected vectorial pump radiation LB vectorially, i.e. essentially without mixing the vectorial pump radiation components (LB_1, LB_2, LB_3) and without uneven attenuation or modification of the vectorial pump radiation components (LB_1, LB_2, LB_3), to the associated vectorial sensor element SE, i.e. to the associated sensor elements (B. 1410, 1420, 1430);
which vectorially decouples the vectorial pump radiation LB from the first vectorial optical system, i.e. essentially without mixing the vectorial pump radiation components (LB_1, LB_2, LB_3) and without non-uniform attenuation or modification of the vectorial pump radiation components (LB_1, LB_2, LB_3);
which exposes the associated vectorial sensor element SE, i.e. the associated sensor elements (e.g. 1410, 1420, 1430), with vectorial pump radiation LB, i.e. with the pump radiation components (LB_1, LB_2, LB_3), wherein a pump radiation component (LB_1, LB_2, LB_3) is preferably associated with one or more sensor elements (e.g. 1410, 1420, 1430) and wherein preferably exactly one pump radiation component (LB_1, LB_2, LB_3) is associated with each sensor element (e.g. 1410, 1420, 1430) used. B 1410, 1420, 1430) and wherein preferably exactly one pump radiation component (LB_1, LB_2, LB_3) is assigned to each sensor element (e.g. 1410, 1420, 1430) used; and
which preferably comprises a vectorial optical waveguide LWL, which preferably comprises a plurality of optical waveguides (LWL_1, LWL_2, LWL_3), for the vectorial sensor element SE as such a vectorial optical functional element;
a second vector optical system,
which comprises one or more vectorial optical functional elements;
which detects the vectorial fluorescence radiation FL vectorially;
wherein the vectorial fluorescence radiation FL comprises the fluorescence radiations (FL1, FL_2, FL_3) of the NV centers and/or the paramagnetic centers of the associated vectorial sensor element SE i.e. the sensor elements (e.g. 1410, 1420, 1430) as fluorescence radiation components (FL_1, FL_2, FL_3); and wherein this detecting by the second vectorial optical system typically takes place essentially without mixing of the vectorial fluorescence radiation components (FL_1, FL_2, FL_3) and without non-uniform attenuation or modification of the vectorial fluorescence radiation components (FL_1, FL_2, FL_3); and the vectorial fluorescence radiation FL of the NV centers and/or the paramagnetic centers of the associated vectorial sensor element SE to the associated photo detector PD, comprising the photo detectors (PD_1, PD_2, PD_3) vectorially, i.e. essentially without mixing of the vectorial fluorescence radiation components (FL_1, FL_2, FL_3) and without non-uniform attenuation or modification of the vectorial fluorescence radiation components (FL_1, FL_2, FL_3);
which decouples the vectorial fluorescence radiation FL of the NV centers and/or the paramagnetic centers of the associated vectorial sensor element SE from the second vectorial optical system vectorially, i.e. essentially without mixing the vectorial fluorescence radiation components (FL_1, FL_2, FL_3) and without non-uniform attenuation or modification of the vectorial fluorescence radiation components (FL_1, FL_2, FL_3);
which vectorially irradiates the associated vectorial photo detector PD comprising the photo detectors (PD_1, PD_2, PD_3) with vectorial fluorescence radiation FL comprising the fluorescence radiation (FL_1, FL_2, FL_3) of the NV centers and/or the paramagnetic centers of the associated vectorial sensor element SE;
where means vectorial exposure;
that preferably one photo detector (PD_1, PD_2, PD_3) of the vectorial photo detector PD is assigned to each of the fluorescence radiation components (FL_1, FL_2, FL_3);
that preferably photo detectors (PD_1, PD_2, PD_3) of the vectorial photo detector PD are preferably assigned one or more of the fluorescence radiation components (FL_1, FL_2, FL_3);
that particularly preferably exactly one photo detector (PD_1, PD_2, PD_3) of the vectorial photo detector PD is assigned to each fluorescence radiation component (FL_1, FL_2, FL_3); and
that particularly preferably each photo detector (PD_1, PD_2, PD_3) of the vectorial photo detector PD is assigned exactly one of the fluorescence radiation components (FL_1, FL_2, FL_3);
which comprises functional elements, for example one or more dichroitic mirrors F1 and/or one or more optical filters in the beam path, which ensure that essentially no pump radiation LB from this or other pump radiation sources, in particular that from the light source LED and/or other light sources (LED, LED_1, LED2, LED_3), reaches the vectorial photo detector PD; and
which preferably comprises one or more optical waveguides LWL or a vectorial optical waveguide LWL for the vectorial sensor element SE as such a vectorial optical functional element; and
wherein the vectorial optical waveguide LWL comprises one or more optical waveguides (LWL_1, LWL_2, LWL_3) each having a first end and a second end;
wherein optical waveguides (LWL_1, LWL_2, LWL_3) of the vectorial optical waveguide LWL are preferably assigned to a sensor element (SE_1, SE_2, SE_3) of the vectorial sensor element SE at their second end;
wherein preferably optical waveguides (LWL_1, LWL_2, LWL_3) of the vectorial optical waveguide LWL are preferably assigned to a photo detector (PD_1, PD_2, PD_3) of the vectorial photo detector SE at their second end;
wherein particularly preferably each optical waveguide (LWL_1, LWL_2, LWL_3) of the vectorial optical waveguide LWL is preferably assigned exactly one sensor element (SE_1, SE_2, SE_3) of the vectorial sensor element SE at its first end; and
each optical waveguide (LWL_1, LWL_2, LWL_3) of the vectorial optical waveguide LWL preferably being assigned exactly one photo detector (PD_1, PD_2, PD_3) of the vectorial photo detector SE at its first end;
which may comprise device parts that are identical to device parts of the first optical system;
the vectorial photo detector PD, which converts the intensity of the received vectorial fluorescence radiation FL into a vectorial receiver output signal S0;
the vectorial receiver output signal S0, which comprises the receiver output signals (S0_1, S0_2, S0_3);
a first vectorial amplifier V1 for the vectorial sensor element SE for vectorial amplification and/or vectorial digitization of the vectorial receiver output signal S0 to the amplified vectorial receiver output signal S1 or to the digitized vectorial receiver output signal S1;
wherein first vectorial amplifier V1 comprises one or more first amplifiers (V1_1, V1_2, V1_3); and
wherein first amplifiers (V1_1, V1_2, V1_3) of the first vectorial amplifier V1 amplify or digitize a receiver output signal (S0_1, S0_2, S0_3) of the vectorial receiver output signal S0 to an amplified receiver output signal (S1_1, S1_2, S1_3) of the amplified vectorial receiver output signal S1, and amplified or digitized to a digitized receiver output signal (S1_1, S1_2, S1_3) of the digitized vectorial receiver output signal S1; and
the amplified receiver output signal S1 or the digitized receiver output signal S1, which comprise one or more amplified receiver output signals (S1_1, S1_2, S1_3) of the amplified vectorial receiver output signal S1 or to a digitized receiver output signal (S1_1, S1_2, S1_3);
a vectorial multiple correlator LIV, which forms a common vectorial filter output signal S4 as a function of the vectorial amplified receiver output signal S1 or of the vectorial digitized receiver output signal S1 and the vectorial LED modulation signal S5w and makes data of the vectorial filter output signal S4 available to the control device CTR, in particular keeps it available for the control device CTR or transfers it to the control device CTR or another device (e.g. the pattern recognition device MEV), in particular for evaluation;
wherein the vectorial multiple correlator LIV typically comprises one or more multiple correlators (LIV_1, LIV_2, LIV_3); and
wherein multiple correlators (LIV_1, LIV_2, LIV_3) of the vectorial multiple correlator LIV, which generates a filter output signal (S4_1, S4_2, S4_3) of the common vectorial filter output signal S4 as a function of an amplified receiver output signal (S1_1, S1_2, S1_3) of the vectorial amplified receiver output signal S1 or from a digitized receiver output signal (S1_1, S1_2, S1_3) of the vectorial digitized receiver output signal S1 and as a function of a modulation signal (S5w_1, S5w_2, S5w_3) of the vectorial LED modulation signal S5w and forms data of the vectorial filter output signal (S4_1, S4_2, S4_3) of the common vectorial filter output signal S4 to the control device CTR, in particular keeps it available for the control device CTR or transmits it to the control device CTR or another device (e.g., the pattern recognition device).B. the pattern recognition device MEV), in particular for evaluation;
a common vectorial filter output signal S4 for the associated vectorial sensor element SE;
wherein the common vectorial filter output signal S4 comprises one or more vectorial filter output signals (S4_1, S4_2, S4_3); and
wherein typically a pattern recognition device MEV and/or the control device CTR evaluate and/or analyze one or more vectorial filter output signals (S4_1, S4_2, S4_3) and/or the common vectorial filter output signal S4 and/or process them by means of computer-implemented methods.

In a further development, the vectorial sensor element channel comprises:
a second signal generator (G2) configured to generate a microwave modulation signal (S5m), or a second vectorial signal generator (G2) comprising a plurality of second signal generators (G2_1, G2_2, G2_3, G2_4, G2_5) as second signal generator components and which is configured to generate a vectorial microwave modulation signal (S5m) with a plurality of microwave modulation signals (S5m_1, S5m_2, S5m_3, S5m_4, S5m_5) as microwave modulation signal components;
a waveguide (1380, 1880, 2380, 6830, 6980) or a vector waveguide with several waveguides as waveguide components (1380, 1880, 2380, 6830, 6980);
a microwave signal source (μWG) configured to generate the microwave signal (μW) for the waveguide (1380, 1880, 2380, 6830, 6980) as a function of the microwave modulation signal (S5m) and to feed it into the waveguide (1380, 1880, 2380, 6830, 6980); or
a vectorial microwave signal source (μWG) comprising a plurality of microwave signal sources (μWG_1, μWG_2, μWG_3, μWG_4, μWG_5) as microwave signal source components and configured to modulate the vectorial microwave signal (μW) with a plurality of microwave signals (μW_1, μW_2, μW_3, μW_4, μW_5) as microwave signal components in dependence on the vectorial microwave modulation signal (S5m) and/or on the microwave modulation signal (S5m) and to feed it into the vectorial waveguide;
a vectorial microwave signal source (μWG) comprising a plurality of microwave signal sources (μWG_1, μWG_2, μWG_3, μWG_4, μWG_5) as microwave signal source components and wherein respective microwave signal source components are configured to modulate a respective microwave signal component (μW_1, μW_2, μW_3, μW_4, μW_5) of the vectorial microwave signal (μW) in dependence on a respective microwave modulation signal component (S5m_1, S5m_2, S5m_3, S5m_4, S5m_5) of the vectorial microwave modulation signal (S5m) and/or on the microwave modulation signal (S5m) and to feed it into the respective waveguide component (1380, 1880, 2380, 6830, 6980) of the vectorial waveguide;
a multiple correlator (LIV) configured to form a filter output signal (S4) as a function of the amplified receiver output signal (S1) or from the digitized receiver output signal (S1) and from the LED modulation signal (S5w) and from a microwave modulation signal (S5m), or comprises multiple correlators (LIV_1, LIV_2, LIV_3, LIV_4, LIV_5) of a vectorial multiple correlator (LIV) as multiple correlator components, wherein each of the multiple correlator components (LIV_1, LIV_2, LIV_3, LIV_4, LIV_5) of the vectorial multiple correlator (LIV) is configured to receive a respective filter output signal (S4_1, S4_2, S4_3, S4_4, S4_5) as the respective filter output signal component of a common vectorial filter output signal (S4) in respective dependence on the respective amplified receiver output signal component (S1_1, S1_2, S1_3, S1_4, S1_5) of the vectorial amplified receiver output signal (S1) or in respective dependence on the respective digitized receiver output signal component (S1_1, S1_2, S1_3, S1_4, S1_5) of the vectorial digitized receiver output signal (S1) and in respective dependence on the respective LED modulation signal component (S5w_1, S5w_2, S5w_3, S5w_4, S5w_5) of the vectorial LED modulation signal (S5w) and, firstly, in respective dependence on the respective microwave modulation signal component (S5m_1, S5m_2, S5m_3, S5m_4, S5m_5) of the vectorial microwave modulation signal (S5m) or, secondly, in dependence on the microwave modulation signal (S5m).

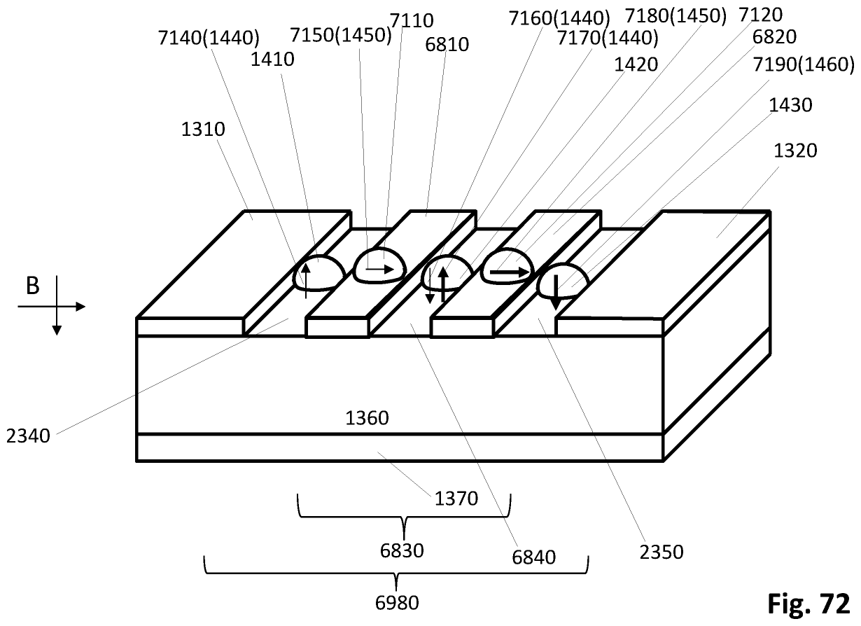

### FIG. 72

FIG. 72 shows a differential microstrip line 6880. The differential microstrip line 6880 of FIG. 68 again comprises a preferably non- or only slightly electrically conductive carrier substrate 1360. The differential microstrip line 6880 preferably again comprises an electrically conductive backside contact 1370 on the underside of the electrically non-conductive carrier substrate 1360. Preferably, the differential microstrip line 6880 comprises an electrically substantially non-conductive left insulation area 1340 on the top surface of the electrically non-conductive carrier substrate 1360 and an electrically substantially non-conductive right insulation area 1350 on the top surface of the electrically non-conductive carrier substrate 1360. Furthermore, preferably the differential microstrip line 6880 comprises a left electrically conductive signal line 6810 on the top side of the electrically non-conductive carrier substrate 1360 between the electrically essentially non-conductive left insulation area 1340 on the one hand and the electrically insulating gap 6840 between the left signal conductor 6810 and the right signal conductor 6820 of the differential signal conductor 6830 on the other hand. Further, preferably, the differential microstrip line 6880 comprises a right electrically conductive signal line 6820 on the top surface of the electrically non-conductive carrier substrate 1360 between the electrically insulating gap 6840 between the left signal conductor 6810 and the right signal conductor 6820 of the differential signal conductor 6830 on the one hand and the electrically essentially non-conductive right insulation area 1350 on the other hand. The electrically insulating gap 6840 between the left signal conductor 6810 and the right signal conductor 6820 of the differential signal conductor 6830 electrically insulates the left signal conductor 6810 from the right signal conductor 6820 of the differential signal conductor 6830. The left signal conductor 6810 and the right signal conductor 6820 together form the differential signal conductor 6830 of the differential microstrip line 6880. The differential microstrip line 6880 can be driven with a common-mode signal in which the same signal is fed into the left signal conductor 6810 and the right signal conductor 6820 of the differential signal conductor 6830 in a time-synchronized manner. This operating state is called common-mode drive with a common-mode signal. The differential microstrip line 6880 can be controlled with a push-pull clock signal, in which the same signal is fed into the left signal conductor 6810 and the right signal conductor 6820 of the differential signal conductor 6830 in a time-synchronized manner, but with a different sign. This operating state is called push-pull control with a push-pull signal. Preferably, the differential microstrip line 6880 comprises a common-mode wave resistor for a common-mode drive and a push-pull wave resistor for a push-pull drive in relation to the differential signal conductor 6830 as a “hot” inner conductor.

Such a differential microstrip line 6880 enables simplified control of the sensor elements SE through different use of common mode and differential mode control.

In common-mode drive, the differential signal conductor 6830 behaves essentially like the signal conductor 1330 of an exemplary microstrip line 1380. The differential microstrip line 6880 thus behaves essentially like a microstrip line 1380 in common-mode drive.

The differential signal conductor 6830 can also be regarded as a special slot line 1880 with push-pull control, in which the width of the electrically conductive left signal ground plane 1310 of the slot line 1880 on the upper side of the electrically non-conductive carrier substrate 1360 is shrunk to the width of the left signal conductor 6810 and in which the width of the electrically conductive right signal ground plane 1320 of the slot line 1880 on the upper side of the electrically non-conductive carrier substrate 1360 is shrunk to the width of the right signal conductor 6820. The electrically insulating gap 6840 between the left signal conductor 6810 and the right signal conductor 6820 of the differential signal conductor 6830 then corresponds to the slot 1840 of the slot line 1880. The distance of the left signal conductor 6810 from the right signal conductor 6810, i.e. the width of the electrically insulating gap 6840 between the left signal conductor 6810 and the right signal conductor 6820 of the differential signal conductor 6830, therefore corresponds in its function to the width d_{SL} of the slot 1840 of the slot line 1880. This is significant in that the following positioning of the sensor elements SE can then be better understood.

FIG. 72 also shows an exemplary differential trip-plate waveguide 6980. The exemplary differential trip-plate waveguide 6980 comprises a differential microstrip line 6880 with a differential signal conductor 6830. The differential microstrip line 6880 has already been explained. The differential trip-plate waveguide 6980 additionally comprises an electrically conductive left signal ground plane 1310 and an electrically conductive right signal ground plane 1320.

The electrically conductive left signal ground plane 1310 is spaced apart and insulated from the left signal conductor 6810 of the differential signal conductor 6830 of the differential microstrip line 6880 of the exemplary differential trip-plate waveguide 6980 by an electrically non-conductive left insulation gap 2340.

The electrically conductive right signal ground plane 1320 is spaced apart and insulated from the right signal conductor 6820 of the differential signal conductor 6830 of the differential microstrip line 6880 of the exemplary differential trip-plate waveguide 6980 by an electrically non-conductive right insulation gap 2350.

The electrically insulating gap 6840 separates the left signal conductor 6810 from the right signal conductor 6820 of the differential signal conductor 6830 of the differential microstrip line 6880 of the exemplary differential trip-plate waveguide 6980.

As with the differential microstrip line 6880, the differential trip-plate waveguide 6980 comprises at least two independent characteristic impedances. For simplicity, the technical teachings of the present document assume that the electrically conductive right signal ground plane 1320 and the electrically conductive right signal ground plane 1320 and the electrically conductive backside contact 1370 are electrically connected to each other or at least can be considered as a signal ground. However, this is not necessarily the case. If necessary, they can also be used simultaneously to supply and discharge electrical energy to device parts that need to be supplied with a direct current or a direct voltage or alternating voltage. However, such a power supply is likely to be problematic as a rule, as it generates magnetic fields that are undesirable. In the following, the paper presented here therefore assumes that, apart from the signals fed in by signal generators for controlling the sensor elements SE, no other signals are transported via the differential trip-plate waveguide 6980, which is preferred.

Preferably, the differential trip-plate waveguide 6980 is terminated with terminal resistors 6710 at the end opposite the other end of the differential trip-plate waveguide 6980 at which the signals are fed in.

Preferably, the width of the electrically non-conductive left insulation gap 2340 is essentially equal to the width of the electrically non-conductive left insulation gap 2340.

Preferably, the widths of the electrically non-conductive left insulation gap 2340 and the electrically non-conductive left insulation gap 2340 on the one hand and the width of the electrically insulating gap 6840 are adjusted relative to each other so that the common-mode wave impedance of the differential trip-plate waveguide 6980 when the differential signal conductor 6830 of the differential microstrip line 6880 of the exemplary differential trip-plate waveguide 6980 is common-mode driven is essentially equal to the differential mode wave impedance of the differential trip-plate waveguide 6980 when the differential signal conductor 6830 of the differential microstrip line 6880 of the exemplary differential trip-plate waveguide 6980 is differential-mode driven.

This simplifies the design of the control circuits (e.g. the microwave signal source μWG) and the terminal resistors 6710.

The exemplary trip-plate waveguide 6980 of FIG. 72 is supplemented by various sensor elements SE at various points of the trip-plate waveguide 6980.

As before, the sensor elements SE should each comprise a multiplicity of diamond nano crystals ND and/or crystals with different and preferably equally distributed spatial orientation. Preferably, diamond nano crystals ND and/or crystals of the sensor elements SE again comprise paramagnetic centers, in particular NV centers, which emit fluorescence radiation FL with a fluorescence wavelength λ_{fl} upon exposure to pump radiation LB of a pump radiation wavelength λₚₘₚ.

In the example of FIG. 72, it is assumed that the sensor elements SE are placed and sized in such a way that they behave ideally. Here, ideal behavior refers to a placement corresponding to the preceding figures for other waveguides, which can also be applied here for a differential trip-plate waveguide 6980. Mixed forms due to oversized sensor elements SE are of course possible. These mixed forms can also be applied here for the sensor elements SE of a differential trip-plate waveguide 6980.

The difference to the trip-plate waveguide 2380 is that by using a differential signal line 6830 of a differential microstrip line 6880 as part of the differential trip-plate waveguide 6980, two additional positions have been added for the sensor elements SE and that the properties of the sensor elements SE differ according to common mode properties and differential mode properties.

### Left Sensor Element SE(1410)

First of all, we again mention the left sensor element SE(1410). The left sensor element SE(1410) is more sensitive to common-mode signals of the signal fed from the signal generators (e.g. RWG,μWG) into the differential trip-plate waveguide 6980 and less sensitive to push-pull signals of the signal fed from the signal generators (e.g. RWG,μWG) into the differential trip-plate waveguide 6980. For common-mode signals, the arrangement of differential trip-plate waveguide 6980 and left sensor element SE(1410) behaves similarly to a trip-plate waveguide 2380 with left sensor element SE(1410) and central signal line 1330. In this context, the document presented here refers to the description of the corresponding FIG. 68, assuming that essentially for the common-mode drive, the differential signal line 6830 of the differential microstrip line 6880 of the differential trip-plate waveguide 6980 can be combined into a central signal line 1330 of a trip-plate waveguide 2380 with respect to the common-mode drive. The push-pull signal also influences the intensity of the fluorescence radiation LB of the left sensor element SE(1410). However, since the signals in the left signal line 6810 of the differential signal line 6830 of the differential microstrip line 6880 of the differential trip-plate waveguide 6980 and the right signal line 6820 of the differential signal line 6830 of the differential microstrip line 6880 of the differential trip-plate waveguide 6980 largely compensate each other due to the push-pull behavior, only the influence of the left signal line 6810 of the differential signal line 6830 of the differential microstrip line 6880 of the differential trip-plate waveguide 6980 remains, which, due to the greater proximity between the left sensor element SE(1410) and the left signal line 6810 of the differential signal line 6830 of the differential microstrip line 6880 of the differential trip-plate waveguide 6980, exceeds that of the right signal line 6820 of the differential signal line 6830 of the differential microstrip line 6880 of the differential trip-plate waveguide 6980. However, this is typically massively less than the influence of the common-mode signal. To simplify matters, the technical teaching of the present document assumes that the left sensor element SE(1410) is sensitive to common-mode signals of the signal generators (e.g. RWG, μWG) fed into the differential trip-plate waveguide. Typically, the intensity of the fluorescence radiation FL of the left sensor element SE(1410) depends on the component of the total flux density B_{Σ}, whose component vector is parallel to the surface of the carrier substrate 1360. In summary, the present document thus assumes that the intensity of the fluorescence radiation FL of the left sensor element SE(1410) depends on the fraction of the total magnetic flux density B_{Σ}, whose component vector is parallel to the surface of the carrier substrate 1360, and the common-mode signal of the signal generators (e.g., RWG,μWG). This new insight can be used for targeted sensor system design and control of the left sensor element SE(1410) by the signal generators (e.g. RWG,μWG).

### Right Sensor Element SE(1430)

Secondly, we again mention the right-hand sensor element SE(1430). The right sensor element SE(1430) is more sensitive to common-mode signals of the signal fed from the signal generators (e.g. RWG,μWG) into the differential trip-plate waveguide 6980 and less sensitive to push-pull signals of the signal fed from the signal generators (e.g. RWG,μWG) into the differential trip-plate waveguide 6980. For common-mode signals, the arrangement of differential trip-plate waveguide 6980 and right sensor element SE(1430) behaves similarly to a trip-plate waveguide 2380 with right sensor element SE(1430) and central signal line 1330. In this context, the document presented here refers to the description of the corresponding FIG. 68, assuming that essentially for the common-mode drive, the differential signal line 6830 of the differential microstrip line 6880 of the differential trip-plate waveguide 6980 can be combined into a central signal line 1330 of a trip-plate waveguide 2380 with respect to the common-mode drive. The push-pull signal also influences the intensity of the fluorescence radiation LB of the right sensor element SE(1430). However, since the signals in the right signal line 6820 of the differential signal line 6830 of the differential microstrip line 6880 of the differential trip-plate waveguide 6980 and the left signal line 6810 of the differential signal line 6830 of the differential microstrip line 6880 of the differential trip-plate waveguide 6980 largely compensate each other due to the push-pull behavior, only the influence of the right signal line 6820 of the differential signal line 6830 of the differential microstrip line 6880 of the differential trip-plate waveguide 6980 remains, which, due to the greater proximity between the right sensor element SE(1430) and the right signal line 6820 of the differential signal line 6830 of the differential microstrip line 6880 of the differential trip-plate waveguide 6980, exceeds that of the left signal line 6810 of the differential signal line 6830 of the differential microstrip line 6880 of the differential trip-plate waveguide 6980. However, this is typically massively less than the influence of the common-mode signal. To simplify matters, the technical teachings of the present document assume that the right-hand sensor element SE(1430) is sensitive to common-mode signals of the signal generators (e.g. RWG, μWG) fed into the differential trip-plate waveguide. Typically, the intensity Iᵢₛₜ of the fluorescence radiation FL of the right sensor element SE(1430) depends on the component of the total flux density B_{Σ}, whose component vector is parallel to the surface of the carrier substrate 1360. In summary, the present document thus assumes that the intensity Iᵢₛₜ of the fluorescence radiation FL of the right sensor element SE(1430) depends on the fraction of the total magnetic flux density B_{Σ}, whose component vector is parallel to the surface of the carrier substrate 1360, and the common-mode signal of the signal generators (e.g., RWG,μWG). This new insight can be used for targeted sensor system design and control of the right sensor element SE(1430) by the signal generators (e.g. RWG,μWG).

### Middle Sensor Element SE(1420)

Thirdly, we again mention the middle sensor element SE(1420). The middle sensor element SE(1420) is more sensitive to push-pull signals of the signal fed from the signal generators (e.g. RWG,μWG) into the differential trip-plate waveguide 6980 and less sensitive to common-mode signals of the signal fed from the signal generators (e.g. RWG,μWG) into the differential trip-plate waveguide 6980. For push-pull signals, the arrangement of differential trip-plate waveguide 6980 and center sensor element SE(1420) behaves similarly to a slot line 1880 with center sensor element SE(1430). In this context, the document presented here refers to the description of FIG. 55, whereby it is assumed that essentially for the push-pull control, the left signal line 6810 of the differential signal line 6830 of the differential microstrip line 6880 of the differential trip-plate waveguide 6980 can be approximately combined with the electrically conductive left signal ground plane 1310 of the differential trip-plate waveguide 6980 to form an electrically conductive left signal ground plane 1310 of a slot line 1880 with respect to the push-pull control. The common-mode clock signal also influences the intensity Iᵢₛₜ of the fluorescence radiation LB of the middle sensor element SE(1420), but now only due to manufacturing deviations. However, since the signals in the right signal line 6820 of the differential signal line 6830 of the differential microstrip line 6880 of the differential trip-plate waveguide 6980 and the left signal line 6810 of the differential signal line 6830 of the differential microstrip line 6880 of the differential trip-plate waveguide 6980 differ due to the common-mode behavior combined with the different by the common-mode signals in the lines 6810, 6820 of the differential signal line 6830, only the influence of alignment and manufacturing errors of the center sensor element 1430 remains, which lead to asymmetries with respect to the right signal line 6820 of the differential signal line 6830 of the differential microstrip line 6880 of the differential trip-plate waveguide 6980 and the left signal line 6810 of the differential signal line 6830 of the differential microstrip line 6880 of the differential trip-plate waveguide 6980. To simplify, the technical teaching of the present disclosure assumes that the center sensor element SE(1420) is sensitive to push-pull signals from the signal generators (e.g., RWG,μWG) fed into the differential trip-plate waveguide 6980. Typically, the intensity Iᵢₛₜ of the fluorescence radiation FL of the center sensor element SE(1420) depends on the portion of the total flux density B_{Σ}, whose component vector is parallel to the surface of the carrier substrate 1360. In summary, the present document thus assumes that the intensity Iᵢₛₜ of the fluorescence radiation FL of the center sensor element SE(1420) depends on the fraction of the total flux density B_{Σ}, whose component vector is parallel to the surface of the carrier substrate 1360, and the push-pull signal of the signal generators (e.g., RWG,μWG). This new insight can be used for targeted sensor system design and control of the middle sensor element SE(1420) by the signal generators (e.g. RWG,μWG).

### Left Line Sensor Element SE(7110)

The fourth is the new left-hand line sensor element SE(7110). The left line sensor element SE(7110) is sensitive to push-pull signals and common-mode signals of the signal fed into the differential trip-plate waveguide 6980 by the signal generators (e.g. RWG, μWG). In this respect, the left line sensor element SE(7110) differs from the left sensor element SE(1410) and the right sensor element SE(1430) and the center sensor element SE(1430). We therefore distinguish here between the behavior of common-mode signals and push-pull signals of the signal fed into the differential trip-plate waveguide 6980 by the signal generators (RWG, μWG).

### Push-Pull Signals

For push-pull signals, the arrangement of differential trip-plate waveguide 6980 and left line sensor element SE(7110) behaves similarly to a trip-plate waveguide 2380 with center sensor element SE(1430). In this context, the document presented here refers to the description of FIG. 56, wherein it is assumed that essentially for push-pull control, the right signal line 6820 of the differential signal line 6830 of the differential microstrip line 6880 of the differential trip-plate waveguide 6980 is connected to the electrically conductive right signal ground plane 1320 of the differential trip-plate waveguide 6980 to an electrically conductive right signal ground plane 1320 of the trip-plate waveguide 2380 with center sensor element SE(1430) with respect to the push-pull control, the push-pull control can be approximately summarized.

### Common-Mode Signals

For common-mode signals, the arrangement of differential trip-plate waveguide 6980 and left line sensor element SE(7110) also behaves similarly to a trip-plate waveguide 2380 with center sensor element SE(1430). In this context, the document presented here again refers to the description of FIG. 56, although it is now assumed that essentially for the common-mode drive, the right signal line 6820 of the differential signal line 6830 of the differential microstrip line 6880 of the differential trip-plate waveguide 6980 is connected to the left signal line 6810 of the differential signal line 6830 of the differential microstrip line 6880 of the differential trip-plate waveguide 6980 to an electrically conductive line 1330 of the trip-plate waveguide 2380 with central sensor element SE(1430) by means of the common-mode drive. common-mode drive can be approximately combined.

Typically, common-mode signals and push-pull signals should therefore influence the intensity of the fluorescence radiation FL of the left line sensor element SE(7110) essentially in the same way.

### Summary Left Line Sensor Element SE(7110)

Typically, the intensity Iᵢₛ of the fluorescence radiation FL of the left line sensor element SE(7110) depends on the portion of the total magnetic flux density B_{Σ} whose component vector is perpendicular to the surface of the carrier substrate 1360 or in the direction of the left signal line 6810 of the differential signal line 6830 of the differential microstrip line 6880 of the differential trip-plate waveguide 6980. In summary, the present document thus assumes that the intensity Iᵢₛₜ of the fluorescence radiation FL of the left line sensor element SE(7110) depends on the component of the magnetic total flux density B_{Σ}, whose component vector is perpendicular to the surface of the carrier substrate 1360 or in the direction of the left signal line 6810 of the differential signal line 6830 of the differential microstrip line 6880 of the differential trip-plate waveguide 6980, and the push-pull signal and common-mode signal of the signal generators (e.g., RWG,μWG).B. RWG,μWG). This new insight can be used for targeted sensor system design and control of the left line sensor element SE(7110) by the signal generators (B. RWG,μWG).

### Right Line Sensor Element SE(7120)

The fifth is the new right-hand line sensor element SE(7120). The right-hand line sensor element SE(7120) is also sensitive to push-pull signals and to common-mode signals of the signal fed into the differential trip-plate waveguide 6980 by the signal generators (e.g. RWG, μWG). However, the right-hand line sensor element SE(7120) is sensitive to push-pull signals with the opposite sign to the left-hand line sensor element SE(7110). In this respect, the right-hand line sensor element SE(7120) differs from the left-hand sensor element SE(1410) and the right-hand sensor element SE(1430) and the middle sensor element SE(1430) and the left-hand line sensor element SE(7110). We therefore again distinguish here the behavior common-mode signals and push-pull signals of the signal fed into the differential trip-plate waveguide 6980 by the signal generators (RWG, μWG).

### Push-Pull Signals

For push-pull signals, the arrangement of differential trip-plate waveguide 6980 and right line sensor element SE(7120) again behaves similarly to a trip-plate waveguide 2380 with center sensor element SE(1430), whereby the sign is inverted with respect to the behavior of the left line sensor element SE(7110). In this context, the document presented here refers to the description of FIG. 56, wherein it is assumed that essentially for the push-pull control, the left signal line 6810 of the differential signal line 6830 of the differential microstrip line 6880 of the differential trip-plate waveguide 6980 with the electrically conductive left signal ground plane 1310 of the differential trip-plate waveguide 6980 to an electrically conductive left signal ground plane 1310 of the trip-plate waveguide 2380 with center sensor element SE(1430) with respect to a differential signal ground plane 1310 of the differential trip-plate waveguide 2380 with center sensor element SE(1430). can be approximately summarized with respect to the push-pull control.

### Common-Mode Signals

For common-mode signals, the arrangement of differential trip-plate waveguide 6980 and right-hand line sensor element SE(7120) also behaves similarly to a trip-plate waveguide 2380 with center sensor element SE(1430). In this context, the document presented here again refers to the description of FIG. 56, although it is now assumed that essentially for the common-mode drive, the left signal line 6810 of the differential signal line 6830 of the differential microstrip line 6880 of the differential trip-plate waveguide 6980 is connected to the right signal line 6820 of the differential signal line 6830 of the differential microstrip line 6880 of the differential trip-plate waveguide 6980 to an electrically conductive line 1330 of the trip-plate waveguide 2380 with central sensor element SE(1430) by means of the common-mode drive. common-mode drive can be approximately combined.

Typically, common-mode signals and push-pull signals should therefore influence the intensity List of the fluorescence radiation FL of the right-hand line sensor element SE(7120) essentially in the same way, although the direction of action of the push-pull signals is now inverted with respect to the direction of action of the common-mode signals in the case of the left-hand line sensor element SE(7110).

### Summary Left Line Sensor Element SE(7110)

Typically, the intensity of the fluorescence radiation FL of the right line sensor element SE(7120) depends on the portion of the total magnetic flux density Bg whose component vector is perpendicular to the surface of the carrier substrate 1360 or in the direction of the right signal line 6820 of the differential signal line 6830 of the differential microstrip line 6880 of the differential trip-plate waveguide 6980. In summary, the present document thus assumes that the intensity Iᵢₛₜ of the fluorescence radiation FL of the right line sensor element SE(6820) depends on the portion of the total flux density B_{Σ}, the component vector of which is perpendicular to the surface of the carrier substrate 1360 or in the direction of the right signal line 6820 of the differential signal line 6830 of the differential microstrip line 6880 of the differential trip-plate waveguide 6980, and the push-pull signal and common-mode signal of the signal generators (e.g., RWG,μWG).B. RWG,μWG). This new insight can be used for targeted sensor system design and control of the right line sensor element SE(7120) by the signal generators (B. RWG, μWG).

The vectors of the respective magnetic flux density B_{μW} generated by the left signal line 6810 of the differential signal line 6830 of the differential microstrip line 6880 of the differential trip-plate waveguide 6980 are drawn with thin arrows for clarification.

The vectors of the respective magnetic flux density B_{μW} generated by the right signal line 6820 of the differential signal line 6830 of the differential microstrip line 6880 of the differential trip-plate waveguide 6980 are shown with bold arrows for clarification.

The vectors (7140, 7150, 7160, 7170, 7180, 7190) of the respective magnetic flux density B_{μW} of the current supply of the signal lines 6810, 6820 of the differential signal line 6830 of the differential microstrip line 6880 of the exemplary differential trip-plate waveguide 6980 are shown for clarification for push-pull control of the differential signal line 6830 of the differential microstrip line 6880 of the exemplary differential trip-plate waveguide 6980. To obtain the representation of the common-mode drive, it is sufficient, for example, to reverse the directions of the arrows 7170, 7180 and 7190.

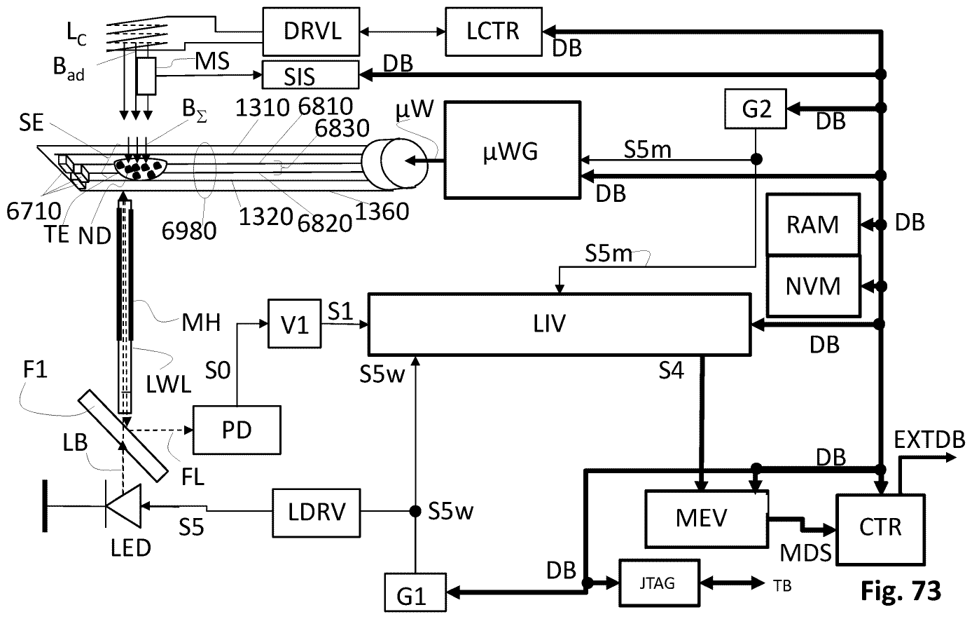

### FIG. 73

FIG. 73 corresponds to FIG. 69, with the trip-plate waveguide 2380 replaced by a differential trip-plate waveguide 6980.

The document presented here indicates that a total of seven positionings of sensor elements SE relative to the lines and line surfaces of the differential trip-plate waveguide 6980 are possible:
1. on the electrically conductive left signal ground plane 1310;
2. in the non-conductive left-hand insulation gap 2340;
3. on the left signal conductor 6810 of the differential signal conductor 6830;
4. in the electrically insulating gap 6840 between the left signal conductor 6810 and the right signal conductor 6820 of the differential signal conductor 6830;
5. on the right signal conductor 6820 of the differential signal conductor 6830;
6. in the non-conductive right-hand insulation gap 2350; and
7. on the electrically conductive right signal ground plane 1320.

Mixed forms due to incorrect placements and enlargements of the relevant sensor elements SE are possible. This results in 27=128 possible placement combinations at the various 3 sensor element positions, all of which are hereby disclosed to a person skilled in the art.

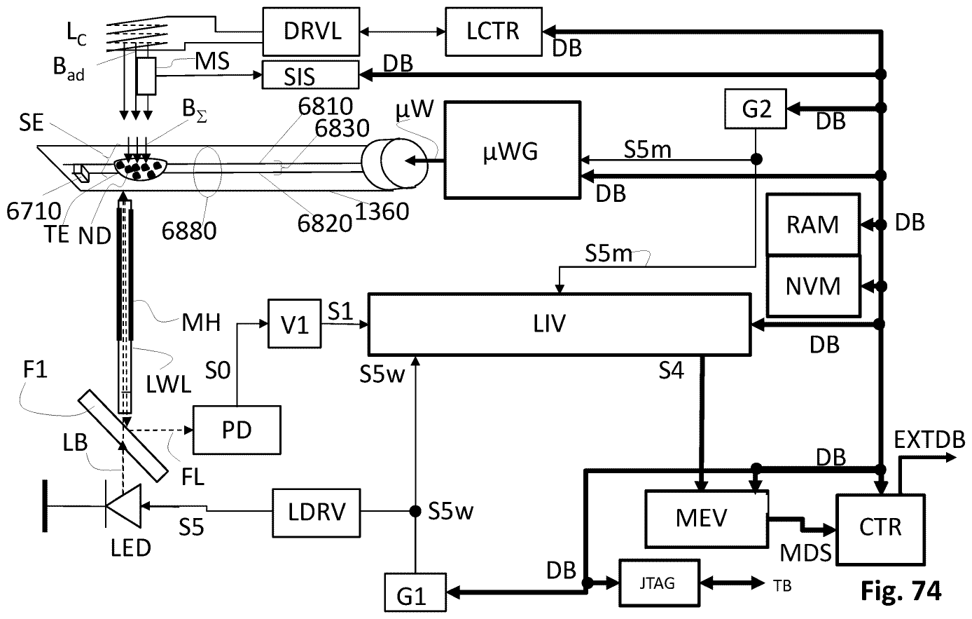

### FIG. 74

FIG. 74 corresponds to FIG. 69, with the trip-plate waveguide 2380 replaced by a differential microstrip line 6880.

The document presented here indicates that a total of five positionings of sensor elements SE relative to the leads and lead surfaces of differential microstrip line 6880 are possible:
1. on the essentially electrically non-conductive left-hand insulation area 1340;
2. on the left signal conductor 6810 of the differential signal conductor 6830;
3. in the electrically insulating gap 6840 between the left signal conductor 6810 and the right signal conductor 6820 of the differential signal conductor 6830;
4. on the right signal conductor 6820 of the differential signal conductor 6830 and
5. on the essentially electrically non-conductive right-hand insulation area 1350.

Mixed forms due to incorrect placements and enlargements of the relevant sensor elements SE are possible. This results in 25=32 possible placement combinations at the various 3 sensor element positions, all of which are hereby disclosed to a person skilled in the art.

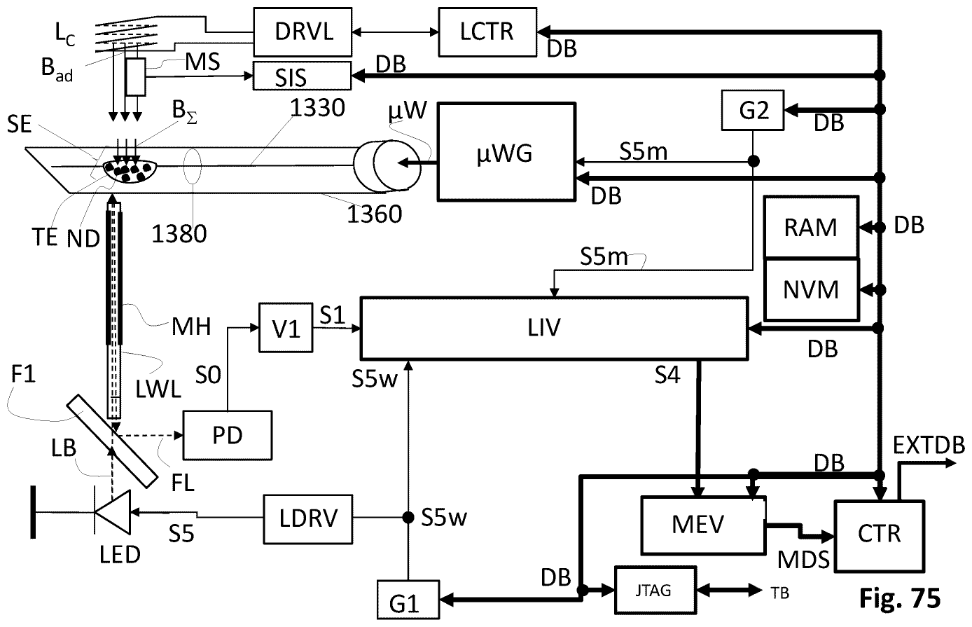

FIG. 75

FIG. 75 corresponds to FIG. 69, with the trip-plate waveguide 2380 replaced by a microstrip line 1380.

The document provided herein indicates that a total of three positionings of sensor elements SE relative to the wires and conductive surfaces of the microstrip line 1380 are possible:
1. on the essentially electrically non-conductive left-hand insulation area 1340;
2. on the left signal conductor 1330; and
3. on the essentially electrically non-conductive right-hand insulation area 1350.

Mixed forms due to incorrect placements and enlargements of the relevant sensor elements SE are possible. This results in 2³=8 possible placement combinations at the various 3 sensor element positions, all of which are hereby disclosed to a person skilled in the art.

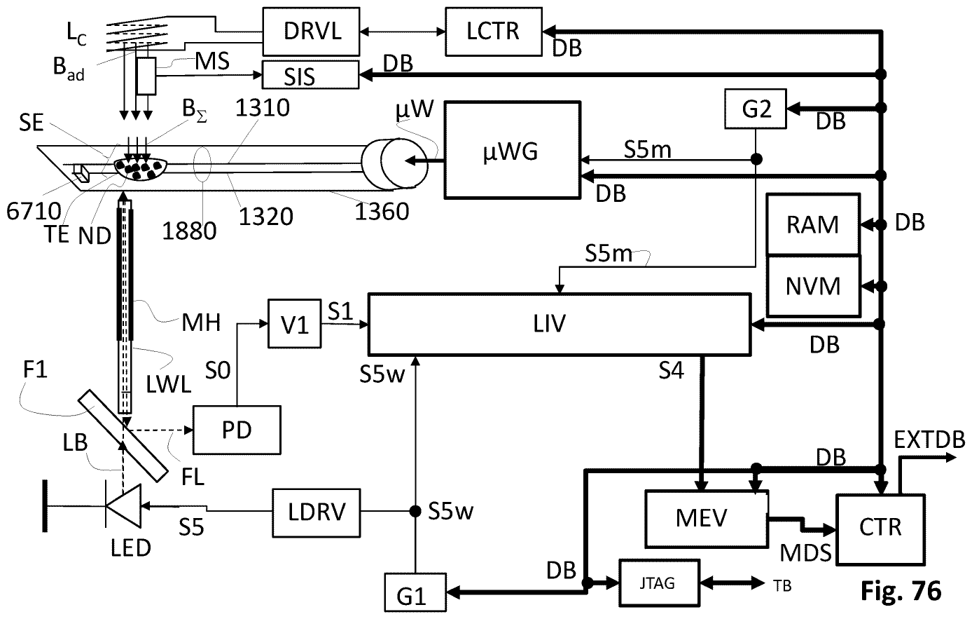

### FIG. 76

FIG. 76 corresponds to FIG. 69, with the trip-plate waveguide 2380 replaced by a slot line 1880.

The document presented here indicates that a total of three positionings of sensor elements SE relative to the conduits and conduit surfaces of the slot line 1880 are possible:
1. on the electrically conductive left signal ground plane 1310;
2. in slot 1840 of the slot line 1880; and
3. on the electrically conductive right signal ground plane 1320.

Mixed forms due to incorrect placements and enlargements of the relevant sensor elements SE are possible. This results in 23=8 possible placement combinations at the various 3 sensor element positions, all of which are hereby disclosed to a person skilled in the art.

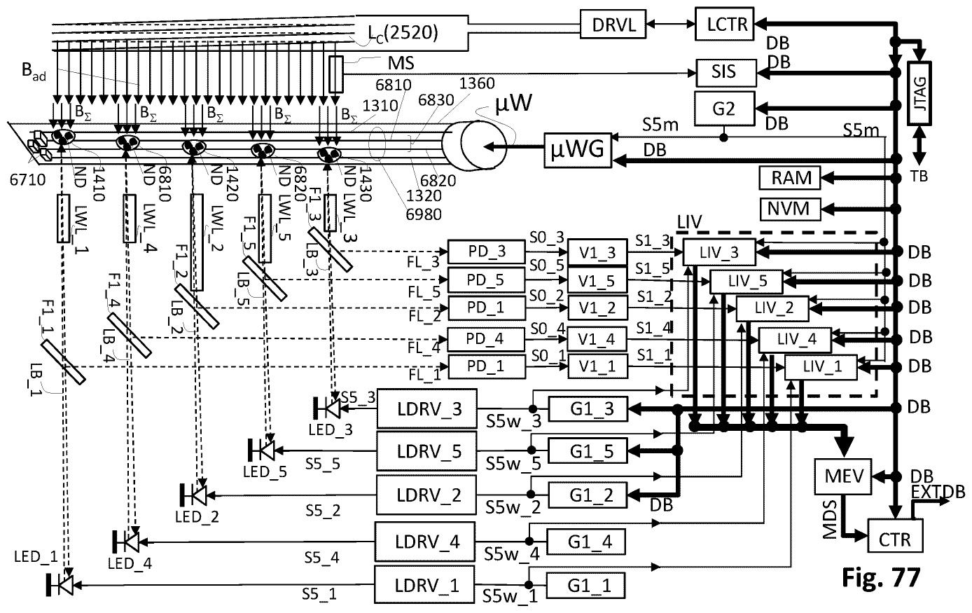

### FIG. 77

FIG. 77 corresponds to FIG. 71 with the difference that the waveguide is a differential trip-plate waveguide 6830 instead of a trip-plate waveguide 2380. Since the differential tri-plate line 2380 enables seven possible positionings of sensor elements SE, namely:
1. on the electrically conductive left signal ground plane 1310;
2. in the essentially electrically non-conductive left-hand insulation gap 2340;
3. on the left signal conductor 6810 of the differential signal conductor 6830;
4. in the electrically insulating gap 6840 between the left signal conductor 6810 and the right signal conductor 6820 of the differential signal conductor 6830;
5. on the right signal conductor 6820 of the differential signal conductor 6830;
6. in the essentially electrically non-conductive right-hand insulation gap 2350; and
7. on the electrically conductive right signal ground plane 1320.

Here, the device of FIG. 77 comprises only five of the seven possible sensor channels. The placements on the electrically conductive right signal ground plane 1320 and on the electrically conductive left signal ground plane 1310 are neglected in the document presented here, as the additional effort generally does not justify the gain in information. A person skilled in the art can imagine these two missing sensor elements SE and the associated sensor element channels, since their integration into the system of FIG. 77 is carried out in the same way as the integration of the other sensor elements SE(1410, 1420, 1430, 6810, 6820) and their associated sensor element channels, which is already shown in FIG. 77. All sensor elements SE(1410, 1420, 1430, 6810, 6820) are flooded with essentially the same additional magnetic flux density B_{ad} of the magnetic field generation means L_{C}. In the example of FIG. 77, the sensor elements are preferably positioned at different positions on the differential trip-plate waveguide 6980. As before, sensor elements SE and the associated sensor channels may be omitted.

The function of the sensor element channels is described in the description of FIG. 71.

The vectorial filter output signal S4 comprises the vectorial filter output signals (S4_1, S4_2, S4_3, S4_4, S4_5) of the multiple correlators (LIV_1, LIV_2, LIV_3, LIV_4, LIV_5).

The control device CTR and/or the pattern recognition device MEV preferably outputs the vectorial filter output signal S4. Typically, the control device CTR and/or the pattern recognition device MEV emulate some device parts of the sensor element channels.

It is often expedient if the control device CTR also emulates the pattern recognition device MEV in whole or in part, for example by means of a computer-implemented method.

This results in 2⁷=128 possible placement combinations at the various 3 sensor element positions, all of which are hereby disclosed to a person skilled in the art.

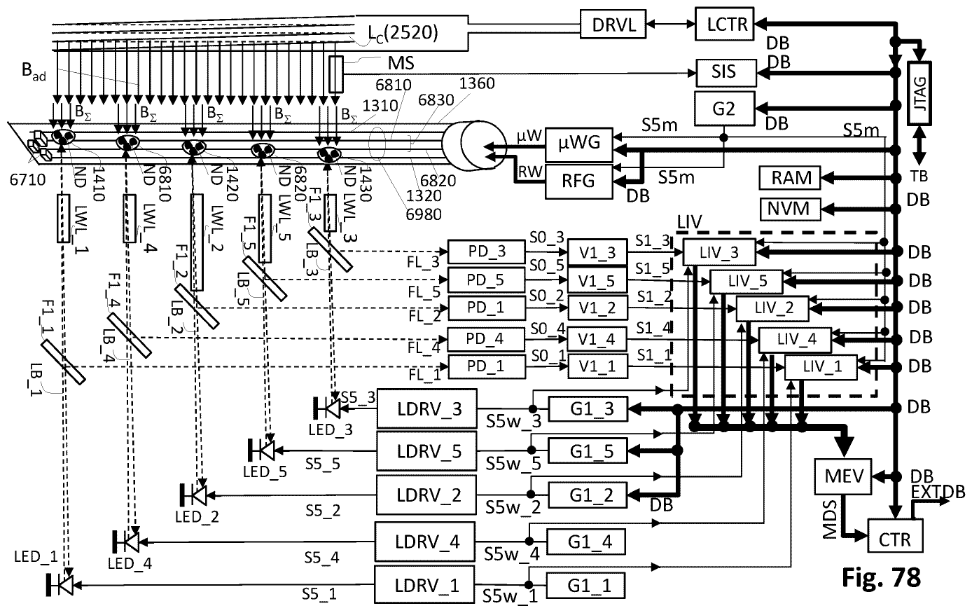

### FIG. 78

FIG. 78 corresponds to FIG. 71 with the difference that the waveguide is a differential trip-plate waveguide 6830 instead of a trip-plate waveguide 2380 and that the device of FIG. 78 uses a microwave signal source μWG and a radio wave signal source RFG for control. As before, the differential tri-plate line 6980 again enables seven possible positionings of sensor elements SE, namely:
1. on the electrically conductive left signal ground plane 1310;
2. in the essentially electrically non-conductive left-hand insulation gap 2340;
3. on the left signal conductor 6810 of the differential signal conductor 6830;
4. in the electrically insulating gap 6840 between the left signal conductor 6810 and the right signal conductor 6820 of the differential signal conductor 6830;
5. on the right signal conductor 6820 of the differential signal conductor 6830;
6. in the essentially electrically non-conductive right-hand insulation gap 2350; and
7. on the electrically conductive right signal ground plane 1320.

Again, the device of FIG. 78 now comprises five sensor channels. The placements on the electrically conductive right signal ground plane 1320 and on the electrically conductive left signal ground plane 1310 are neglected in the document presented here, as the additional effort generally does not justify the gain in information. A person skilled in the art can imagine these two missing sensor elements SE and the associated sensor element channels, since their integration into the system of FIG. 78 is analogous to the integration of the other sensor elements SE(1410, 1420, 1430, 6810, 6820) and their associated sensor element channels, which is already shown in FIG. 78. All sensor elements SE(1410, 1420, 1430, 6810, 6820) are flooded with essentially the same additional magnetic flux density B_{ad} of the magnetic field generation means L_{(C)}. In the example of FIG. 77, the sensor elements are preferably positioned at different positions on the differential trip-plate waveguide 6980. As before, sensor elements SE and the associated sensor channels may be omitted. The function of the sensor element channels is as described in the description of FIG. 71.

This results in 2⁷=128 possible placement combinations at the various 3 sensor element positions, all of which are hereby disclosed to a person skilled in the art.

The vectorial filter output signal S4 comprises the vectorial filter output signals (S4_1, S4_2, S4_3, S4_4, S4_5) of the multiple correlators (LIV_1, LIV_2, LIV_3, LIV_4, LIV_5).

The control device CTR and/or the pattern recognition device MEV preferably outputs the vectorial filter output signal S4. Typically, the control device CTR and/or the pattern recognition device MEV emulate some device parts of the sensor element channels.

It is often expedient if the control device CTR also emulates the pattern recognition device MEV in whole or in part, for example by means of a computer-implemented method.

The special feature is now that in the example shown here, the microwave signal source μWG does not feed the microwave signal μW generated by it into both signal lines 6810 and 6820 of the differential signal line 6830 of the microstrip line 6830 of the exemplary differential trip-plate waveguide 6980, but only into one of the two signal lines 6810 and 6820 of the differential signal line 6830 of the microstrip line 6830 of the exemplary differential trip-plate waveguide 6980. By way of explanation, the microwave signal source μWG preferably feeds the microwave signal μW generated by it into the left signal line 6810 of the differential signal line 6830 of the microstrip line 6830 of the exemplary differential trip-plate waveguide 6980 in the example of FIG. 78.

The microwave source μWG generates the microwave signal μW. Preferably, the control device CTR controls the generation of the microwave signal μW by the microwave source μWG by means of data messages via the data bus DB to the microwave source μWG. The control device CTR preferably checks the status of the microwave signal source μWG by means of data queries via the data bus DB. A second signal generator G2 typically generates a microwave modulation signal S5m. Preferably, the control device CTR controls the generation of the microwave modulation signal S5m by the second signal generator G2 by means of data messages via the data bus DB to the second signal generator G2. Typically, the control device CTR checks the status of the second signal generator G2 by means of data requests via the data bus DB. The microwave modulation signal S5m preferably modulates the amplitude of the radio wave signal μW of the microwave source μW. Typically, the radio wave modulation signal S5m is a digital signal with a first logic level and a second logic level that is different from the first logic level. For example, the second signal generator G2 controls the amplitude of the microwave signal μW generated by the microwave signal source μWG by means of the microwave modulation signal S5m.

For example, the device may be designed such that the microwave signal source μWG generates a microwave signal μW with a predetermined minimum amplitude when the microwave modulation signal S5m assumes the first logical value.

For example, the device may be designed such that the microwave signal source μWG generates a microwave signal RμW with a predetermined maximum amplitude when the microwave modulation signal S5m assumes the second logical value.

The microwave signal source μWG can also be controlled by the microwave modulation signal S5m in a switching manner:

For example, the device may be designed such that the microwave signal source μWG switches off the microwave signal μW when the microwave modulation signal S5m assumes the first logical value.

For example, the device may be designed such that the microwave signal source μWG generates a microwave signal μW with the predetermined maximum amplitude when the microwave modulation signal S5m assumes the second logical value.

The radio wave source RFG generates the radio wave signal RW. Preferably, the control device CTR controls the generation of the radio wave signal RW by the radio wave source RFG by means of data messages via the data bus DB to the radio wave source RFG. The control device CTR preferably checks the status of the radio wave signal source RFG by means of data requests via the data bus DB. A third signal generator G3 typically generates a radio wave modulation signal S5r. Preferably, the control device CTR controls the generation of the radio wave modulation signal S5r by the third signal generator G3 by means of data messages via the data bus DB to the third signal generator G3. Typically, the control device CTR checks the status of the third signal generator G3 by means of data requests via the data bus DB. The radio wave modulation signal S5r preferably modulates the amplitude of the radio wave signal RW of the radio wave source RW. Typically, the radio wave modulation signal S5r is a digital signal having a first logic level and a second logic level that is different from the first logic level. For example, the third signal generator G3 controls the amplitude of the radio wave signal RW generated by the radio wave signal source RFG by means of the radio wave modulation signal S5r.

For example, the device may be constructed such that the radio wave signal source RFG generates a radio wave signal RW with a predetermined minimum amplitude when the radio wave modulation signal S5r assumes the first logical value.

For example, the device may be constructed such that the radio wave signal source RFG generates a radio wave signal RW with a predetermined maximum amplitude when the radio wave modulation signal S5r assumes the second logical value.

The radio wave signal source RFG can also be controlled by the radio wave modulation signal S5r in a switching manner:

For example, the device may be constructed such that the radio wave signal source RFG switches off the radio wave signal RW when the radio wave modulation signal S5r assumes the first logical value.

For example, the device may be designed such that the radio wave signal source RFG generates a radio wave signal RW with the predetermined maximum amplitude when the radio wave modulation signal S5r assumes the second logical value.

Preferably, the radio wave modulation signal RW is modulated at a radio wave modulation frequency f_{(RWm)}. Preferably, the radio wave modulation frequency f_{RWm} is different from the other modulation frequencies of the device as previously explained. Preferably, the radio wave modulation frequency f_{RWm} fits into the 2ⁿ scheme of modulation frequencies of the device that ensures that none of the mixed frequencies of the modulation frequencies are the same or similar.

The exemplary device of FIG. 78 uses the microwave modulation signal S5m as the radio wave modulation signal S5r and the second signal generator G2 as the third signal generator G3 to simplify the representation.

The special feature is that in the example shown here, the radio wave signal source RFG does not feed the radio wave signal RW generated by it into both signal lines 6810 and 6820 of the differential signal line 6830 of the microstrip line 6830 of the exemplary differential trip-plate waveguide 6980, but only into one of the two signal lines 6810 and 6820 of the differential signal line 6830 of the microstrip line 6830 of the exemplary differential trip-plate waveguide 6980, and preferably now into the other of the two signal lines 6810 and 6820 of the differential signal line 6830 of the microstrip line 6830 of the exemplary differential trip-plate waveguide 6980. By way of explanation, the radio wave signal source RFG should preferably now feed the radio wave signal RW generated by it into the right signal line 6820 of the differential signal line 6830 of the microstrip line 6830 of the exemplary differential trip-plate waveguide 6980 in the example of FIG. 78.

This has the advantage that a mixer MIX is no longer required for mixing the radio wave signal RW with the microwave signal μW to form a radio wave/microwave mixed signal RWμW.

The use of radio waves has the advantage that resonances caused by the interaction of the paramagnetic centers with nuclear atomic nuclei of isotopes, which comprise a magnetic moment and are located in the material of the diamond nano crystals ND or the crystals used with the same function in the sensor element SE, can also be excited and possibly observed.

Thus, the basic idea of FIG. 78 is to use the two signal lines 6810 and 6820 of the differential signal line 6830 of the differential microstrip line 6880 of the differential trip-plate waveguide 6980 for different functions. A signal line of the differential signal line 6830 of the differential microstrip line 6880 of the differential trip-plate waveguide 6980 for the excitation of the resonances between the nuclear atomic nucleus of isotopes with magnetic moments in the material of the diamond nano crystals ND or in the material of the function-equivalent crystals, which are respectively located in the sensor elements SE, on the one hand and the paramagnetic centers, for example NV centers, in these diamond nano crystals ND or these function-equivalent crystals on the other hand.

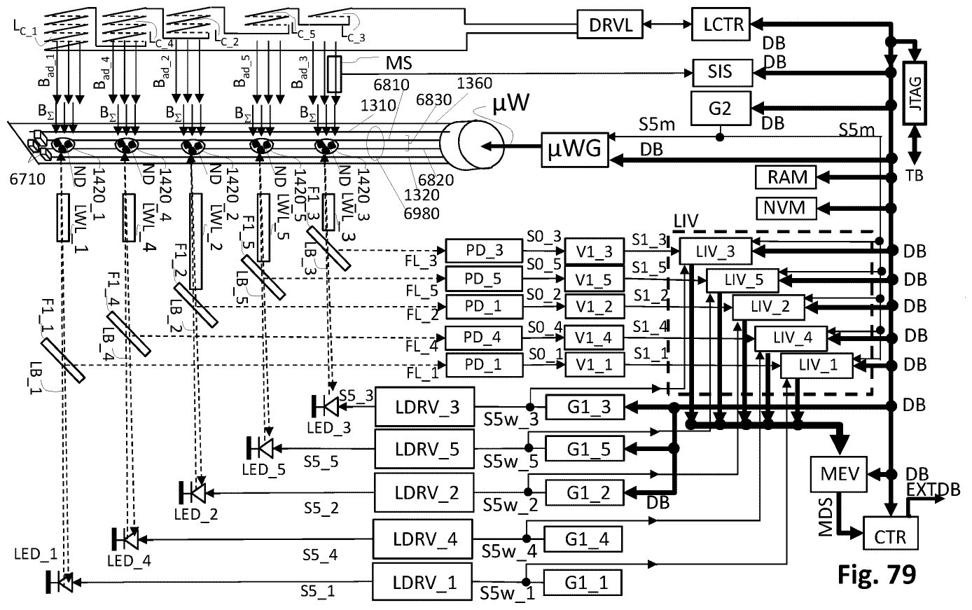

### FIG. 79

FIG. 79 corresponds to FIG. 77, whereby now, firstly, five central sensor elements 1420 are arranged along the differential trip-plate waveguide, each of which is assigned a sensor element channel. Secondly, the device of FIG. 79 now comprises a plurality of magnetic field generation means (L_{c}_1, L_{c}_2, L_{c}_3, L_{c}_4, L_{c}_5). These magnetic field generation means each generate a respective additional magnetic flux density (B_{ad}_1, B_{ad}_2, B_{ad}_3, B_{ad}_4, B_{ad}_5), which is preferably assigned in each case to a sensor element (1420_1, 1420_2, 1420_3, 1420_4, 1420_5) associated with the respective magnetic field generation means (L_{c}_1, L_{c}_2, L_{c}_3, L_{c}_4, L_{c}_5).

In FIG. 51b, these additional magnetic flux densities (B_{ad}_1, B_{ad}_2, B_{ad}_3, B_{ad}_4, B_{ad}_5) each define a horizontal line on which the operating point of the associated sensor element (1420_1, 1420_2, 1420_3, 1420_4, 1420_5) must lie. In the example in FIG. 79, the coils of the magnetic field generating means (L_{c}_1, L_{c}_2, L_{c}_3, L_{c}_4, L_{c}_5) comprise different numbers of turns and are connected in series. In FIG. 51b, they therefore define five of these horizontal lines, for example, on which the respective operating points of the five sensor elements (1420_1, 1420_2, 1420_3, 1420_4, 1420_5), for example, must lie, with exactly one sensor element (1420_1, 1420_2, 1420_3, 1420_4, 1420_5) being assigned to each of these lines.

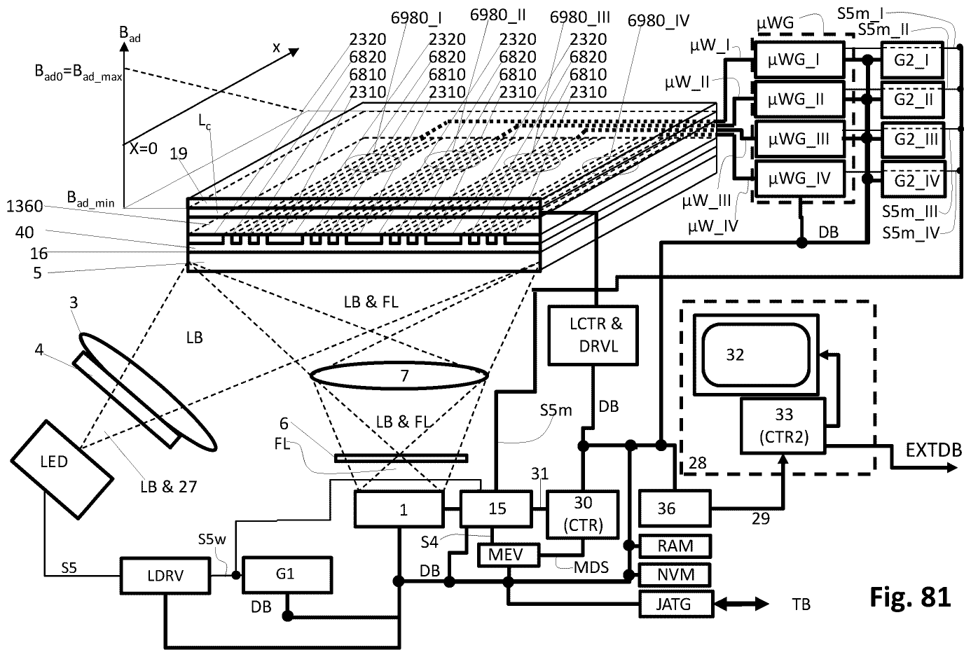

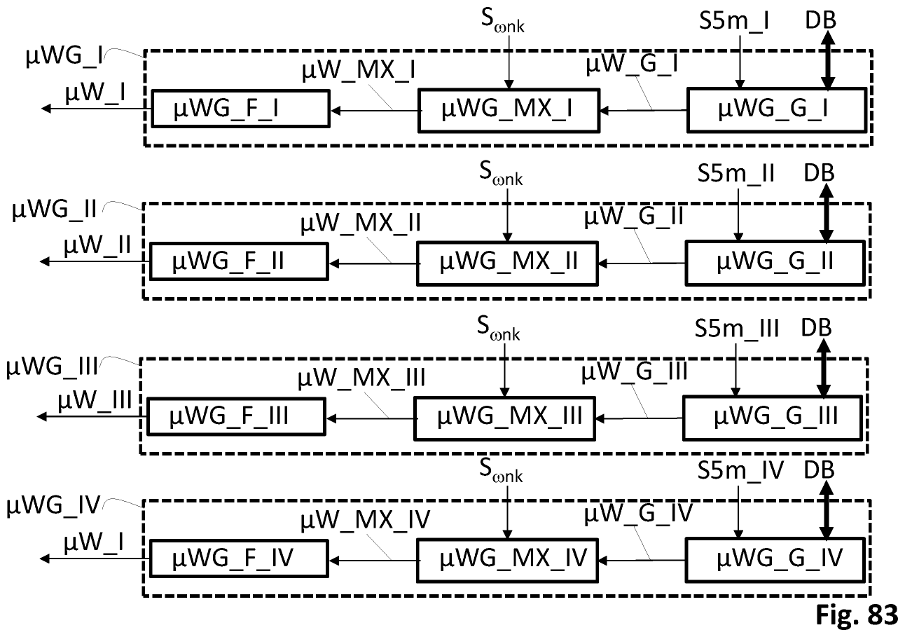

The specifications of a respective microwave frequency (ω_{μW_I}, ω_{μW_I}, ω_{μW_I}, ω_{μW_IV}) of the respective microwave signals (μW_I, μW_II, μW_III, μW_IV) of FIGS. 81 and 83 each define a vertical line in FIG. 51b. The five crossing points of the horizontal lines and the vertical line defined in this way result in their operating points for the respective assigned sensor elements (1420_1, 1420_2, 1420_3, 1420_4, 1420_5). It is intuitively obvious that in this way the control device CTR can roughly determine one or more of the following values during the first measurement:
1. the probable position of the lower resonance edge 522;
2. the probable position of the lower middle resonance edge 523;
3. the probable position of the upper middle resonance edge 524;
4. the probable position of the upper resonance edge 525;
5. the probable position of the middle resonance minimum 529;
6. the probable value of the effective offset flux density B_{off};
7. is the probable value of the zero-point flux density B₀; and
8. the probable value of the zero-point microwave frequency ω_{μW0};

After further measurements, the control device CTR can also conclude one or more of the following values here:
9. the probable value 564 of the magnetic flux density B associated with the upper reference line 561 at one or more operating points;
10. the probable value 565 of the magnetic flux density B associated with the lower reference line 562 at one or more operating points;
11. the probable difference 566 of the value of the magnetic flux density B associated with the middle reference line 563 minus the value 565 of the magnetic flux density B associated with the lower reference line 562;
12. the probable slope 567 of the curve at one or more operating points;
13. the polynomial coefficients of the polynominal approximation 627 of the curve at some operating points;
14. the probable value of a lower effective magnetic flux density B₂₂;
15. the probable value of a lower mean effective magnetic flux density B₂₃;
16. the probable value of an upper mean effective magnetic flux density B₂₄;
17. the probable value of an upper effective magnetic flux density B₂₅;
18. the probable value of an effective magnetic resonance minimum flux density B₂₉;
19. the probable value of a zero-point microwave frequency ω_{μW0};
20. the probable value of a lower microwave frequency ω_{μW22};
21. the probable value of a lower mean microwave frequency ω_{μW23};
22. the probable value of an upper mean microwave frequency ω_{μW24};
23. the probable value of an upper microwave frequency ω_{μW25};
24. the probable value of a resonance minimum microwave frequency ω_{μW29};
25. the probable value of an unknown microwave frequency ω_{μWnk}; and
26. the probable value of a microwave modulation frequency f pw.

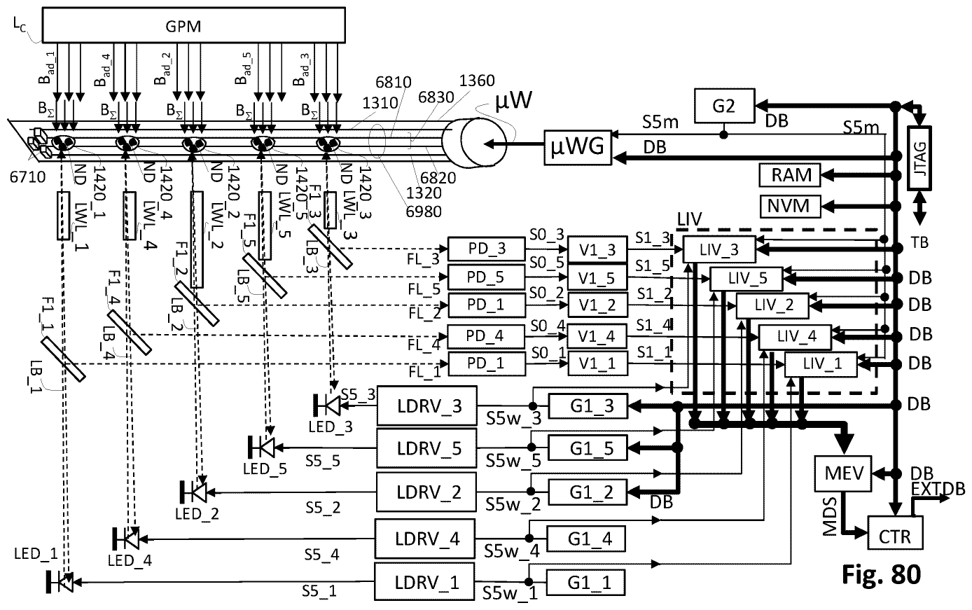

### FIG. 80

FIG. 80 corresponds to FIG. 79 with the difference that a gradient afflicted permanent magnet GPM as magnetic field generating means L_{c} generates the different additional magnetic flux densities (B_{ad}_1, B_{ad}_2, B_{ad}_3, B_{ad}_4, B_{ad}_5). Again, the generation of the additional magnetic flux densities can be such that, for example, the following applies:

B_{ad}_1|>|_{B(ad)}_2|>|_{B(ad)}_3|>|_{B(ad)}_4|>|_{B(ad)}_5.|

The disadvantage is that it is then no longer possible to adjust the total magnetic flux density B_{Σ} with the gradient afflicted permanent magnet GPM alone. It therefore makes sense to provide an additional magnetic field generating means L. in addition to the gradient afflicted permanent magnet GPM in this case.

It is obvious here that a resolution with only 5 sensor element channels is insufficient.

### FIG. 81

FIG. 81 shows, as a consistent further development of the use of several more or less point-shaped sensor elements SE, the use of linear and/or planar sensor element layers 5 as a finely granular extended sensor element SE. To make this possible, the sensor element layer 5 is preferably manufactured thinner than the smallest structure size of the waveguide to be measured (1380, 2380, 6830, 6980). The widths of the signal lines (1330, 6830, 6810, 6820) of the relevant waveguides (1380, 2380, 6830, 6980) and their distances from each other and from ground planes (2310, 2320) of the relevant waveguides (2380, 1880, 6980) are regarded as the structure size. The principle shown in FIG. 81 can be applied to various waveguides (1380, 2380, 6830, 6980). Preferably, the waveguides (1380, 2380, 6830, 6980) are planar waveguides. By way of example, the document presented here deals with microstrip lines 1380, slot lines 1880, trip-plate waveguides 2380, differential microstrip lines 6830 and differential trip-plate waveguides 6980. However, the technical teaching of the document presented here is expressly not limited to these types of waveguides. Preferably, the linear and/or planar sensor element layer 5 comprises all the features of a sensor element SE that have already been described several times in this document. The idea is thus to use a continuous and linear and/or planar, typically essentially homogeneously manufactured sensor element layer 5 as the sensor element SE to measure the total flux density B_{Σ} and/or the unknown microwave frequency ωₙₖ of an external microwave signal S_{ω nk} acting on the sensor element layer 5 instead of using discrete sensor elements SE.

A use of a line-like sensor element layer 5 as a sensor element SE can be obtained by connecting the sensor elements of, for example, FIGS. 72, 54 to 57. In principle, firstly, a linear sensor element SE(5) can be arranged transversely in the direction of a waveguide (1380, 1880, 2380, 6830, 6980). In principle, secondly, a linear sensor element SE(5) can be arranged parallel to the direction of a waveguide (1380, 1880, 2380, 6830, 6980) and, if it is narrower than the distance between the signal lines (1330, 6810, 6820) and smaller than the width of any non-conductive left-hand insulation gaps (1380, 1880, 2380, 6830, 6980), can be arranged parallel to the direction of the waveguide (1380, 1880, 2380, 6830, 6980). If it is narrower than the distance between the signal lines (1330, 6810, 6820) and smaller than the width of the non-conductive left insulation gap (2340), if present, and the non-conductive right insulation gap (2350), if present, it can occupy several positions relative to these structures of the respective waveguide (1380, 1880, 2380, 6830, 6980). In this case, the linear sensor element SE(5) arranged parallel to the respective waveguide (1380, 1880, 2380, 6830, 6980) can thus assume different positions relative to the waveguide (1380, 1880, 2380, 6830, 6980). However, if the linear sensor element SE(5) is wider in these cases, this is equivalent to having different ideal linear sensor elements SE(5) directly adjacent and parallel to each other. A camera can observe the intensity Iᵢₛ of the fluorescence radiation FL of these widened line-like sensor elements SE(5) and a subsequent processing device 30 or a control device CTR, CTR2 can separate these signals of the intensity of the fluorescence radiation FL of these line-like sensor elements SE(5) in the widened line-like sensor element SE(5) by means of computer-implemented image processing methods and determine associated measured values

In the case of the connection of the sensor elements of, for example, FIGS. 72, 54 to 57, the linear sensor element layer 5 would be arranged transversely to the direction of the waveguide as an example. Such a linear sensor element layer 5 arranged transversely to the waveguide (1380, 2380, 1880, 6830, 6980) is therefore referred to in the present document as a transversely arranged linear sensor element layer 5.

If the magnetic field generation means L_{c} is to comprise several magnetic field generation means (L_{c}_1, L_{c}_2, L_{c}_3, L_{c}_4, L_{c}_5) as subdevices of the magnetic field generation means L_{c}, which are arranged along the waveguide (1380, 2380, 1880, 6830, 6980), a linear sensor element layer 5 can preferably also be formed along this waveguide (1380, 2380, 1880, 6830, 6980). Such a linear sensor element layer 5 arranged along the waveguide (1380, 2380, 1880, 6830, 6980) is therefore referred to in the present document as a longitudinally arranged linear sensor element layer 5, which here typically comprises a multiplicity of sensor elements SE merging into one another.

First of all, we assume that the longitudinally arranged linear sensor element layer 5. is so narrow that it can occupy one of the positions possible below for the various exemplary waveguides (1380, 2380, 1880, 6830, 6980) already mentioned above. For alternative, in particular planar, waveguides not listed here, the analogous positions apply.

To this end, the document presented here discusses the waveguides already mentioned as examples in the document presented here (1380, 2380, 1880, 6830, 6980).

The document presented here indicates that a total of three positionings of longitudinally arranged linear sensor element layers 5 relative to the wires and conductive surfaces of the microstrip line 1380 are possible:
1. on the essentially electrically non-conductive left-hand insulation area 1340;
2. on the left signal conductor 1330; and
3. on the essentially electrically non-conductive right-hand insulation area 1350.

The document presented here indicates that a total of three positionings of longitudinally arranged linear sensor element layers 5 relative to the conduits and conduit surfaces of the slot line 1880 are possible:
1. on the electrically conductive left signal ground plane 1310, in slot 1840 of slot line 1880; and
2. on the electrically conductive right signal ground plane 1320.

The document presented here indicates that a total of five positionings of longitudinally arranged linear sensor element layers 5 relative to the conduits and conduit surfaces of the triplate conduit 2380 are possible:
1. on the electrically conductive left signal ground plane 1310;
2. in the essentially electrically non-conductive left-hand insulation gap 2340;
3. on the signal conductor 1330;
4. in the essentially electrically non-conductive right-hand insulation gap 2350; and
5. on the electrically conductive right signal ground plane 1320.

The document presented here indicates that a total of five positionings of longitudinally arranged linear sensor element layers 5 relative to the lines and line surfaces of the differential microstrip line 6880 are possible:
1. on the essentially electrically non-conductive left-hand insulation area 1340;
2. on the left signal conductor 6810 of the differential signal conductor 6830;
3. in the electrically insulating gap 6840 between the left signal conductor 6810 and the right signal conductor 6820 of the differential signal conductor 6830;
4. on the right signal conductor 6820 of the differential signal conductor 6830; and
5. on the essentially electrically non-conductive right-hand insulation area 1350.

The document presented here indicates that a total of seven positionings of longitudinally arranged line-like sensor element layers 5 relative to the lines and line surfaces differential triplate line 2380 are possible:
1. on the electrically conductive left signal ground plane 1310;
2. in the essentially electrically non-conductive left-hand insulation gap 2340;
3. on the left signal conductor 6810 of the differential signal conductor 6830;
4. in the electrically insulating gap 6840 between the left signal conductor 6810 and the right signal conductor 6820 of the differential signal conductor 6830;
5. on the right signal conductor 6820 of the differential signal conductor 6830;
6. in the essentially electrically non-conductive right-hand insulation gap 2350; and
7. on the electrically conductive right signal ground plane 1320.

Mixed forms due to misplacements and enlargements (widenings) of the relevant longitudinally arranged linear sensor element layers 5 are possible and are expressly comprised by the claim. The waveguides (1380, 2380, 1880, 6830, 6980) may be formed straight or not straight on the carrier substrate 1360. The width of the waveguides (1380, 2380, 1880, 6830, 6980) may vary along the sensor element layer 5, wherein the variation points of the width of the waveguides (1380, 2380, 1880, 6830, 6980) are preferably formed such that no butt joints are formed due to varying wave resistances of the respective waveguides as a result of the variation of the width of the waveguides (1380, 2380, 1880, 6830, 6980). Preferably, the widths of the signal lines (1330, 6810, 6820) and the distances of the signal lines (1380, 2380, 1880, 6830, 6980) from each other and the widths of the non-conductive left insulation gaps 2340 and the non-conductive right insulation gaps 2340, if present, deviate from each other, the widths of the signal lines (1330, 6810, 6820) and the distances of the signal lines (1380, 2380, 1880, 6830, 6980) from one another and the widths of the non-conductive right-hand insulation gaps 2350, if present, in a first region of a waveguide (1380, 2380, 1880, 6830, 6980) which comprises sensor elements SE and/or is wholly or partially covered by a sensor element layer 5 or interacts with a sensor element layer 5 and/or a sensor element SE, depend on the widths of the signal lines (1330, 6810, 6820) and the distances of the signal lines (1380, 2380, 1880, 6830, 6980) from one another and the widths of the non-conductive right-hand insulation gaps 2350, if present, in a second region of a waveguide (1380, 2380, 1880, 6830, 6980) which comprises sensor elements SE and/or is wholly or partially covered by a sensor element layer 5 and/or interacts with a sensor element SE. insulation gaps 2340 and the non-conductive right insulation gaps 2350, if present, in a second region of a waveguide (1380, 2380, 1880, 6830, 6980) which comprises no sensor elements SE and which is not completely or partially covered by a sensor element layer 5 and does not interact with a sensor element layer 5 and/or a sensor element SE. Preferably, these deviations are such that the characteristic impedance of the waveguide (1380, 2380, 1880, 6830, 6980) in question in the first region deviates from the characteristic impedance of the second region by no more than 25%, better by no more than 10%, better by no more than 5%, better by no more than 2%, better by no more than 1%, better by no more than 0.5%.

The document presented here indicates that it is also possible to use other, in particular planar, waveguides in a functionally equivalent manner.

Waveguides can also comprise functional elements of stripline technology, such as capacitances, inductances, branches, bends, curves, circulators, wave couplers, phase shifters, thick-film resistors, thin-film transistors, MEMS switches, etc.

If two longitudinally arranged linear sensor element layers 5 are now used directly next to each other, these can comprise two or more of the above-mentioned positionings relative to the respective waveguide at the same time.

The document presented here then designates such a sensor element layer 5 as a longitudinally arranged planar sensor element layer 5. If several longitudinally arranged linear sensor element layers 5 are now used which are located directly next to one another and comprise all of the above-mentioned positioning relative to the respective waveguide at the same time, the document presented here then designates such a sensor element layer 5 as a planar sensor element layer 5.

Preferably, the absolute value of the additional magnetic flux density B_{ad}, which flows through the planar sensor element layer 5, depends on the position along the respective waveguide.

Most preferably, the proposed device uses a static magnetic field generation means 19 (L_{C}), for example in the form of a permanent magnet PM. Preferably, the device comprises a gradient afflicted permanent magnet GPM as static magnetic field generating means 19 (L_{C}) which generates an additional magnetic flux density B_{ad} which preferably depends on the coordinate x along the waveguides used (1380, 2380, 1880, 6830, 6980, 6830_I, 6830_II, 6830_III, 6830_IV). Particularly preferably, this dependence of the additional magnetic flux density B_{ad} on the coordinate x along the waveguide in question (1380, 2380, 1880, 6830, 6980, 6830_I, 6830_II, 6830_III, 6830_IV) in the region of the planar sensor element layer 5 is linearly dependent on the coordinate x along the waveguide used (1380, 2380, 1880, 6830, 6980, 6830_I, 6830_II, 6830_III, 6830_IV):

B_{ad}(x)≈B_{ad0}+k×x

Here, B_{ad0} is an offset constant specific to the gradient afflicted permanent magnet GPM (19) used. x is the coordinate along the relevant waveguide (1380, 2380, 1880, 6830, 6980, 6830_I, 6830_II, 6830_III, 6830_IV). k is a proportionality constant for the gradient afflicted permanent magnet GPM (19) used in the region of the planar sensor element layer 5. In the example in FIG. 81, k is arbitrarily chosen to be negative. Of course, instead of this linear relationship, polynomials of a higher degree than 1 with more complex dependencies of the additional magnetic flux density B_{ad} on the coordinate x along the relevant waveguide (1380, 2380, 1880, 6830, 6980, 6830_I, 6830_II, 6830_III, 6830_IV) in the region of the planar sensor element layer 5 can also be used.

Due to the quasi-continuous distribution of the absolute value of the additional magnetic flux density B_{ad} from the coordinate x along the relevant waveguide (1380, 2380, 1880, 6830, 6980, 6830_I, 6830_II, 6830_III, 6830_IV) corresponding to B_{ad}(x), the dimensionality of the sensor element SE increases virtually to infinity. It is ultimately only limited by the granularity of the diamond nano crystals ND in the sensor element SE, in this case the granularity of the crystals/diamond nano crystals ND in the planar sensor element layer 5. It is therefore still a vectorial sensor element SE with extremely high dimensionality. The transition is similar to the transition from a Fourier series to a Fourier integral.

Accordingly, the evaluation devices and methods presented so far can generally no longer adequately solve this problem.

The document presented here therefore proposes using a magnetic field camera for evaluation instead of discrete sensor element channels. To this end, the document presented here refers to the as yet unpublished German patent applications DE 10 2023 100 856.0, DE 10 2023 100 857.9, DE 10 2023 111 858.7 and DE 10 2023 111 859.5.

An essential idea of the document presented here is to combine such a magnetic field camera as described in these documents with a waveguide, in particular a planar waveguide and/or in particular with one of the waveguides discussed here (1380, 2380, 1880, 6830, 6980, 6830_I, 6830_II, 6830_III, 6830_IV), and one of the systems presented here and to detect the distribution of the intensity of the fluorescence radiation FL in the area of the planar sensor element layer 5 within the resulting overall system as two-dimensional vectorial fluorescence radiation and to detect it by means of a camera, in particular a CMOS camera, and to recognize it by the control device CTR or a pattern recognition device MEV and/or an evaluation device 30 using computer-implemented image processing algorithms in order to infer measured values, in particular the position of the tip 30 of the V-formation (522, 525) and/or values derived therefrom. Preferably, the evaluation device 30 and/or the control device CTR comprise a storage medium (RAM, NVM) that applies these computer-implemented image processing algorithms to the output data of the output signals 31 of the photo detectors PD of the light sensor array 1 in order to determine measured values and/or measured value groups and to display them on a screen 32 and/or to deploy them for processing by a higher-level computer system (CTR2, 29) or to transfer them to such a higher-level computer system (CTR2, 29).

Preferably, the control device CTR and/or the pattern recognition device MEV determine one or more of the following measured values or groups of measured values using computer-implemented image processing and/or pattern recognition algorithms:
1. Information on the probable position of the lower resonance edge 522;
2. Information on the probable position of the lower middle resonance edge 523;
3. Information on the probable position of the upper middle resonance edge 524;
4. Information on the probable position of the upper resonance edge 525;
5. Information on the probable position of the middle resonance minimum 529;
6. Information about the probable value of the effective offset flux density B_{off};
7. Information about the probable value of the zero-point flux density B₀; and
8. Information on the probable value of the zero-point microwave frequency ω_{μW0}.

After further measurements, the control device CTR and/or the pattern recognition device MEV or an evaluation device 530 can also conclude one or more of the following values here:
9. Information about the probable value 564 of the magnetic flux density B₆₁ associated with the upper reference line 561 at one or more operating points;
10. Information about the probable value 565 of the magnetic flux density B₆₂ associated with the lower reference line 562 at one or more operating points;
11. Information on the probable difference 566 of the value of the magnetic flux density Bos associated with the middle reference line 563 minus the value 565 of the magnetic flux density B₆₂ associated with the lower reference line 562;
12. Information about the probable slope 567 of the curve at one or more operating points;
13. Information on the polynomial coefficients of the polynominal approximation 627 of the curve at some operating points;
14. Information on the probable value of a lower effective magnetic flux density B₂₂;
15. Information on the probable value of a lower mean effective magnetic flux density B₂₃;
16. Information on the probable value of an upper mean effective magnetic flux density B₂₄;
17. Information on the probable value of an upper effective magnetic flux density B₂₅;
18. Information on the probable value of an effective magnetic resonance minimum flux density B₂₉;
19. Information on the probable value of a zero-point microwave frequency ω_{μW0};
20. the probable value of a lower microwave frequency ω_{μW22};
21. Information on the probable value of a lower mean microwave frequency ω_{μW23};
22. Information on the probable value of an upper mean microwave frequency ω_{μW24};
23. Information on the probable value of an upper microwave frequency ω_{μW25};
24. Information on the probable value of a resonance minimum microwave frequency ω_{μW29};
25. Information on the probable value of an unknown microwave frequency ω_{μWnk}; and
26. Information about the probable value of a microwave modulation frequency f pw.

As an example, the determination of an unknown microwave frequency ωₙₖ is explained here:

It is particularly preferred that the relation B_{ad}(x) is a bijective function. To determine an additional magnetic flux density B_{ad}, the evaluation device 30 and/or the pattern recognition device MEV can then, in a first step, generate an intensity curve I_{fl}(x) of the intensity of the fluorescence radiation FL along a waveguide (1380, 2380, 1880, 6830, 6980, 6830_I, 6830_II, 6830_III, 6830_IV), for example the first waveguide (6830_I), with the photo detectors PD of the light sensor array 1 for a first microwave frequency ω_{μW_1}. Since the relation B_{ad}(x) of the gradient afflicted permanent magnet GPM (19) is known and reversible and a function of x, the evaluation device 30 and/or the pattern recognition device MEV can determine the inverse function x (B_{ad}) and insert it into a calibration curve I_{fl}(x) determined at ωₙₖ=0 Hz and thus obtain a curve I_{fl}(B_{ad}) for this one microwave frequency ω_{μW_1}. Preferably, the entire intensity field In (ω_{μW}, B_{ad}) was previously determined in a calibration process, so that the evaluation device 30 and/or the pattern recognition device MEV preferably have the corresponding data in a memory (RAM, NVM) of the device. If, for example, a signal S_{ωnk} with an unknown microwave frequency ωₙₖ is now mixed with a known first microwave signal μW_G_I with the first microwave frequency ω_{μW_1} of the first internal microwave source μW_G_I within the first microwave source μWG_I (see FIG. 83) in a first mixer μW_MX_I of the first microwave source μWG_I, a first microwave mixing signal μW_MX_I is produced. A first microwave filter μW_F_I (see FIG. 83) preferably eliminates one of the two transients arising at ω_{μW_1}-ωₙₖ and ω_{μW_1}+ωₙₖ in the first microwave mixing signal μW_MX_I. Preferably, the cut-off frequency of the first microwave filter μW_F_I (see FIG. 83) is lower than the zero-point microwave frequency ω_{μW0} when a low pass is used as the first microwave filter μW_F_I. Preferably, the cut-off frequency of the first microwave filter μW_F_I (see FIG. 83) is greater than the zero-point microwave frequency ω_{μW0} in the case of a high-pass first microwave filter μW_F_I. This converts the diagram of FIG. 2 regarding the position of the lower resonance edge 522 into an invertible function ω_{μW} (B_{ad}). (See FIG. 83).

Hereby, in a third step, the evaluation device 30 and/or the pattern recognition device MEV can determine the position of the lower resonance edge 522 in the detected curve I_{fl}(B_{ad}) as the value of the additional magnetic flux density B_{ad,22} for this lower resonance edge 522. This can be done, for example, by forming a cross-correlation integral between the detected curve I_{fl}(B_{ad}) and a reference curve I_{fl_ref}(B_{ad}) for S_{ω nk} constant.

$$K ( {B}_{a d} ) = {\int }_{{B}_{a {d}_{min}}}^{{B}_{a {d}_{max}}} {I}_{f l} ( {B}_{a d} ) ∘ {I}_{f {l}_{ref}} ( {B}_{a {d}_{max}} - {B}_{a d} ) d {B}_{a d}$$

If only a lower reference edge is sought, this is typically at the additional magnetic flux density B_{ad,22} with the maximum correlation K (B_{ad}).

In a fourth step, the evaluation device 30 and/or the pattern recognition device MEV can then determine a microwave frequency ω_{μW22}=ω_{μW} (B_{ad,22}) for the position of the lower resonance edge 522.

Depending on the type of the first microwave filter μW_F_I (high pass or low pass), the evaluation device 30 and/or the pattern recognition device MEV can then determine the unknown microwave frequency ωₙₖ by means of −ωₙₖ=ω_{μW22}−ω_{μW_I} Of ωₙₖ=ω_{μW_I}−ω_{μW(22)}.

In FIG. 81, an XY diagram is shown to the left of the carrier substrate 1360 to illustrate the exemplary, possible relationship B_{ad}(x). Of course, k=0 can also apply if no gradient of the magnetic flux density is desired in the respective application.

The linear waveguide (1380, 2380, 1880, 6830, 6980) may not only be straight in the region of the planar sensor element layer 5, but may also be curved and/or ring-shaped and/or ring-segment-shaped and/or kinked. If, for example, the linear waveguide (1380, 2380, 1880, 6830, 6980) comprises two sections of the linear waveguide (1380, 2380, 1880, 6830, 6980) connected in series in the region of the planar sensor element layer 5, which are preferably straight in these sections and which are arranged, for example, at an angle of 90° to one another (see FIG. 91), the control device CTR and/or the pattern recognition device MEV can use a computer-implemented image processing method to infer the polarization direction and frequency of externally incident microwave radiation or other electromagnetic radiation, respectively. other electromagnetic radiation whose mixing frequency with the microwave frequency of the microwave signal μW lies within the measuring range of the paramagnetic centers or the NV centers of the diamond nano crystals ND or the corresponding functionally equivalent crystals.

For the sake of completeness, the document presented here explains the operation of the device proposed here in more detail:

As an exemplary pump radiation source, the light source LED emits pump radiation LB with the pump radiation wavelength λₚₘₚ and possibly unwanted electromagnetic radiation 27 of other wavelength ranges. Optionally, a first signal generator G1 can again generate an LED modulation signal S5w with an LED modulation frequency f_{LED}. Preferably, the control device CTR controls the first signal generator G1 via the data bus DB. A light source driver LDRV preferably supplies the light source LED with electrical energy at least temporarily as a function of the optional LED modulation signal S5w and/or as a function of control data from the control device CTR, which the control device CTR transmits to the light source driver LDRV via the data bus DB. Typically, the LED modulation signal S5w and/or the control data of the control device LED can thus modulate the intensity of the pump radiation LB emitted by the light source LED. In extreme cases, the LED modulation signal S5w and/or the control data of the control device LED can thus switch the emission of the pump radiation LB emitted by the light source LED on and off, in particular as a function of a computer-implemented light generation program in a memory RAM, NVM of the device that the control device CTR executes at least temporarily. An optional optical short pass filter 4 preferably allows only the pump radiation LB with pump radiation wavelength λₚₘₚ of the light source LED to pass and preferably retains the electromagnetic radiation 27 of other wavelength ranges. Provided that the light source LED does not emit any unwanted electromagnetic radiation 27 of other wavelength ranges, this optical short pass filter 4 is not necessary. An optional, preferably existing illumination optics 3 ensures that the pump radiation LB illuminates the sensor element layer 5 as homogeneously as possible. The illumination optics 3 may comprise one or more optical functional elements such as lenses, apertures, optical waveguides, prisms, etc., as found in any textbook on technical optics. The shape of the lenses and/or mirrors and other optical functional elements of the illumination optics 3 is preferably calculated and shaped such that, with a known radiation characteristic of the light source LED, the illumination of the sensor element layer 5 with pump radiation LB is homogeneous. These optical functional elements may also comprise functional elements of diffractive optics such as photonic crystals, dielectric mirrors, holograms, etc. The document presented here refers to the documents Baha E. A. Saleh, Malvin Carl Teich, “Grundlagen der Photonik “Wiley-VCH, 2007 and Bernhard C. Kress, Patrick Meyreueis “Applied Digital Optics” Wiley, 2009, as examples.

The sensor element layer 5 is preferably applied to the mechanical carrier substrate 1360, for example a flat surface 16. The flat surface can be achieved in particular by a dielectric 40 that compensates for unevenness of the waveguides (1360, 1880, 2380, 6830, 6980, 6980_1, 6980_II, 6980_III, 6980_IV). Preferably, the device is installed in a housing 8. The material housing wall of the housing 8 is preferably non-magnetic in the region and preferably does not essentially influence the magnetic field. Typically, the carrier substrate 1360 comprises materials such as FR-4 (flameresistant-4) or PTFE (polytetrafluoroethylene) or made of semiconducting materials, such as pieces of board materials or pieces of plastic sheet or film and/or pieces of glass wafers or a pieces of ceramic wafers and/or pieces of semiconductor wafers, for example pieces of CMOS wafers or for example pieces of BiCMOS wafers for example pieces of wafers from a bipolar technology or pieces of a wafer from a III/V material or the like and/or for example pieces of MEMS wafers and/or pieces of microelectronic circuits and/or for example pieces of MEOS wafers (MEOS=micro electro optical system) and/or for example pieces of MOEMS wafers etc. and/or pieces of MOEMS wafers microelectronic circuits and functional elements and/or micro-optical functional elements and/or micro-mechanical functional elements and/or micro-fluidic functional elements. Preferably, the sensor element layer 5 comprises a multiplicity of randomly and preferably uniformly oriented crystals with paramagnetic centers or diamond nano crystals ND with paramagnetic centers and/or NV centers. Preferably, the sensor element layer 5 comprises a substrate material TM in which the crystals with paramagnetic centers or diamond nano crystals ND with paramagnetic centers and/or NV centers are embedded. Preferably, the substrate material TM of the sensor element layer 5 is a cured substrate material TM. Preferably, the substrate material TM of the sensor element layer 5 is a substrate material TM cured by means of electromagnetic curing radiation 4910 of a curing wavelength λ_{H}. The sensor element layer 5 very preferably comprises a multiplicity of randomly and preferably uniformly oriented diamond nano crystals ND with NV centers. The paramagnetic centers can be, for example, NV centers and/or SiV centers and/or TiV centers and/or GeV centers and/or SnV centers and/or NiN4 centers and/or PbV centers and/or ST1 centers when diamond is used as the crystal material of the diamond nano crystals ND. Other paramagnetic centers and/or crystal materials appear to be functionally equivalent. The pump radiation LB preferably comprises a pump radiation wavelength λₚₘₚ in a wavelength range from 400 nm to 700 nm and/or better 450 nm to 650 nm and/or better 500 nm to 550 nm and/or better 515 nm to 540 nm when using NV centers in dimant as crystals of the sensor element layer 5. A wavelength of 532 nm is clearly preferred as the pump radiation wavelength λₚₘₚ. In the case of the use of NV centers in diamond or in diamonds of the sensor element layer 5, a laser diode of the type PLT5 520B from Osram, for example, is suitable as a light source LED with 520 nm pump radiation wavelength λ₍ₚₘₚ₎. When using NV centers in diamond crystals as diamond nano crystals ND in the sensor element layer 5 as paramagnetic centers of the sensor element layer 5, the NV centers of the sensor element layer 5 typically emit fluorescence radiation FL with a typical fluorescence wavelength λ_{fl} of approx. 637 nm when exposed to pump radiation LB of the pump radiation wavelength λₚₘₚ described above.

Preferably, the substrate material TM of the sensor element layer 5 is transparent to electromagnetic radiation with the fluorescence radiation wavelength λ_{fl} of the paramagnetic centers of the crystals and/or the diamond nano crystals ND and/or the NV centers of the diamond nano crystals ND of the sensor element layer 5 after the substrate material TM has hardened.

Preferably, after curing of the substrate material TM of the sensor element layer 5, the substrate material TM is transparent for electromagnetic radiation with the pump radiation wavelength λₚₘₚ of the light source LED for excitation of the emission of the fluorescence radiation FL of the paramagnetic centers of the crystals and/or the diamond nano crystals ND and/or the NV centers of the diamond nano crystals ND of the sensor element layer 5.

An imaging optics 7 preferably detects the image of the location-dependent intensity Iᵢₛₜ of the fluorescence radiation FL with the fluorescence wavelength λ_{fl}, which the sensor element layer 5 generates by means of the paramagnetic centers, for example by means of the NV centers, in the sensor element layer 5 when excited by the pump radiation LB with the pump radiation wavelength λ₍ₚₘₚ₎.

The imaging optics 7 may comprise one or more optical functional elements such as lenses, apertures, optical waveguides, prisms, mirrors, plane mirrors, convex and concave mirrors, etc., as found in any textbook of technical optics. In particular, these optical functional elements may also comprise functional elements of diffractive optics such as phononic crystals, dielectric mirrors, holograms, etc. The document presented here refers to the documents Baha E. A. Saleh, Malvin Carl Teich, “Grundlagen der Photonik” Wiley-VCH, 2007 and Bernhard C. Kress, Patrick Meyreueis “Applied Digital Optics” Wiley, 2009 as examples.

An optical long pass filter F1(6) preferentially allows electromagnetic radiation with the fluorescence wavelength λ_{fl} and thus the fluorescence radiation FL to pass. The optical long pass filter F1(13406) preferentially blocks the passage of other electromagnetic radiation, for example radiation with the pump radiation wavelength λₚₘₚ, and thus the passage of the pump radiation LB. As a result, the imaging optics 7 can detect the image of the intensity distribution of the emission of the fluorescence radiation FL via the sensor element layer 5 in the wavelength range of the fluorescence wavelength λ_{fl} separately from other radiation images of other wavelengths and image it onto the n×m photo detectors PD of the n×m light sensor array 1 of the fluorescence camera. For example, the imaging optics may comprise lenses and/or optical waveguide bundles as vector optical waveguides LWL) with optical waveguides as optical waveguide bundle components. n and m are positive integers here. The light sensor array 1 is preferably a CMOS chip, even more preferably a micro integrated CCD photodetector circuit, which preferably comprises evaluation electronics. Since the intensity Iᵢₛₜ(x) of the fluorescence radiation FL of the sensor element layer 5 depends locally in the sensor element layer 5 on the total magnetic flux density B_{Σ} and the microwave frequency ω_{μW} (x) at the respective location x of the respective paramagnetic center in the sensor element layer 5, the image of the intensity distribution of the intensity Iᵢₛₜ(x) of the emission of the fluorescence radiation FL over the sensor element layer 5 corresponds to a magnetic flux density magnitude image of the field of the total magnetic flux density B_{Σ}, which flows through the sensor element layer 5, or a microwave frequency magnitude image that depends non-linearly on the distribution of the microwave frequencies of the microwave radiation in the region of the sensor element layer b5. Since the density distribution of the paramagnetic centers in the sensor element layer 5 and/or the illumination of the sensor element layer 5 with pump radiation LB and/or detecting the intensity of the fluorescence radiation FL over the area of the sensor element layer 5 cannot be produced completely homogeneously despite all efforts, it has proven useful to calibrate the system before first use by means of calibration measurements. To process the measured values of the photo detectors PD of the light sensor array 1, evaluation electronics 15 of the light sensor array 1 detect the measured values of the signals of the photo detectors PD of the light sensor array 1 and form the output signals 31 of the photo detectors PD of the light sensor array 1 therefrom, in particular by amplification and/or filtering. These evaluation electronics 15 of the light sensor array 1 correspond to the function of the first amplifier V1 in the sensor element channels discussed above. The output signals 31 of the photo detectors PD of the light sensor array 1 correspond analogously to the received signals S0 of the previously discussed photo detectors PD. However, due to the high dimensionality, the evaluation can now typically no longer be carried out by means of a simple multiple correlator LIV, which may also be provided on a channel-by-channel basis. Instead, the document presented here proposes to perform the analysis by means of a computer-implemented image and/or pattern recognition program, which is stored in a memory (RAM, NVM) of the device and is executed by a processing device 30 as a control device CTR.

The processing device 30 for the output signals 31 (S0) of the photo detectors PD of the light sensor array 1 can optionally control further magnetic field generation means L_{C} by means of a control device LCTR, if these do not comprise only the gradient afflicted permanent magnet GPM. The further magnetic field generation means L_{C} can, for example, again be flat coils 2520 (L_{C}), which are energized with an electric current by the control device LCTR for the further magnetic field generation means L_{C}.

The processing device 30 for the output signals 31 of the photo detectors PD of the light sensor array 1 preferably generates an image of the intensity distribution of the fluorescence radiation FL of the sensor element layer 5 from the output signals 31 of the photo detectors PD of the light sensor array 1. Based on the relationships shown above, the image of the intensity distribution of the intensity Iᵢₛ of the fluorescence radiation FL of the sensor element layer 5 represents a magnetic flux density magnitude image of the field of the total magnetic flux density B_{Σ} in the sensor element layer 5. The processing device 30 for the output signals 31 of the photo detectors PD of the light sensor array 1 can transfer this image of the intensity distribution of the intensity Iᵢₛ of the fluorescence radiation FL of the sensor element layer 15, for example, directly by means of the interface circuit 136 via a data bus 29 to a further and/or higher-level computer system 28 (CTR2). The further and/or higher-level computer system 28 (CTR2) can be to operate the sensor system 21. The further and/or higher-level computer system 28 may be a further control device CTR2 of the sensor system 21. For example, the further and/or higher-level computer system 28 for operating the sensor system 21 can generate a one- or two- or three-dimensional representation of the distribution of the total magnetic flux density B_{Σ} in the sensor element layer 5 from the image of the intensity distribution of the intensity Iᵢₛₜ of the fluorescence radiation FL of the sensor element layer 5 transferred by the evaluation device 30 via a data interface 36 and a data bus 29 to the further and/or higher-level computer system 28. In the example of FIG. 81, four exemplary waveguides, here exemplary four exemplary differential trip-plate waveguides (6980_I, 6980_II, 6980_III, 6980_IV), are applied to a first surface of the carrier substrate 1360. In the example of FIG. 81, the dielectric 40 covers the signal lines (6810, 6820) of the trip-plate waveguide 6980 of these trip-plate waveguides (6980_I, 6980_II, 6980_III, 6980_IV) and the respective electrically conductive left signal ground plane 1310 and the respective electrically conductive right signal ground plane 1320 and, by way of example, fills the respective non-conductive left insulation gap 2340 and the respective non-conductive right insulation gap 2350 and the electrically insulating gap 6840 between the respective left signal conductor 6810 and the respective right signal conductor 6820 of the respective differential signal conductor 6830 for planarization, so that an essentially smooth intermediate surface 16 is obtained, on which the sensor element layer 5 is applied by way of example. In the example of FIG. 81, the dielectric 40 thus also serves the purpose of ensuring a planar surface 16 for applying the sensor element layer 5 to the carrier substrate 1360 in order to reduce the artifacts in the computer-implemented image and pattern recognition. The further and/or higher-level computer system 28 can, for example, as a further control device CTR2 of the sensor system 21, display the received images and/or the extracted measured values on the screen 32.

The data bus 29 is used for the fabrication of the data connection between the processing device 30(CTR) for the output signals 31 of the photo detectors PD of the light sensor array 1 (receiver output signals S0 or digitized receiver output signals S1 or analog receiver output signals S1) and the further and/or higher-level computer system 28 (CTR2) for operating the sensor system 21. The external magnetic flux densities Bₑₓₜ acting on the sensor element layer 5 from the outside, which contributes to the total flux density B_{Σ} influencing the sensor element layer 5, and the external microwave radiation S_{ω nk} influences the intensity distribution of the intensity Iᵢₛₜ of the fluorescence radiation FL of the sensor element layer 5 by superposition, and thus the images which the processing device 30 transfers for the output signals 31 of the photo detectors PD of the light sensor array 1 as images of the intensity distribution of the intensity Iᵢₛ of the fluorescence radiation FL of the sensor element layer 5, for example directly by means of the interface circuit 36 via a data bus 29 to the further and/or higher-level computer system 28 (CTR2).

In order to detect as much data as possible with one image, the exemplary device has four exemplary microwave signal sources (μWG_I, μWG_II, μWG_III, μWG_IV). Preferably, the exemplary four microwave signal sources (μWG_I, μWG_II, μWG_III, μWG_IV) are part of a vectorial microwave signal source μW. Each of these exemplary four microwave signal sources (μWG_I, μWG_II, μWG_III, μWG_IV) generates one of four microwave signals (μW_I, μW_II, μW_III, μW_IV) in the example. In other words, the vectorial microwave signal source μW generates a vectorial microwave signal μW, which comprises these exemplary four microwave signal sources (μWG_I, μWG_II, μWG_III, μWG_IV), for example. On the carrier substrate 1360 there are, for example, four waveguides, in this case four triplate waveguides (6980_I, 6980_II, 6980_III, 6980_IV).

In the example of FIG. 81, the first microwave source μWG_I feeds the first microwave signal μW_I into the first waveguide, here a first trip-plate waveguide 6980_I.

In the example shown in FIG. 81, the second microwave source μWG_I feeds the second microwave signal μW_II into the second waveguide, in this case a second trip-plate waveguide 6980_II.

In the example of FIG. 81, the third microwave source μWG_III feeds the third microwave signal μW_III into the third waveguide, in this case a third trip-plate waveguide 6980_III.

In the example of FIG. 81, the fourth microwave source μWG_IV feeds the fourth microwave signal μW_IV into the fourth waveguide, in this case a fourth trip-plate waveguide 6980_IV.

The four waveguides, here in the example of FIG. 81 the exemplary four trip-plate waveguides (6980_I, 6980_II, 6980_III, 6980_IV), together form a vectorial waveguide, here a vectorial trip-plate waveguide 6980, which comprises the exemplary four trip-plate waveguides (6980_I, 6980_II, 6980_III, 6980_IV) in the example of FIG. 81.

In the example of FIG. 81, the vector microwave source μWG feeds the vector microwave signal u W into the vector waveguide, here a vector trip-plate waveguide 6980.

In the example of FIG. 81, the first microwave source μWG_I generates the first microwave signal μW_I with a first microwave frequency ω_{μW_I}.

In the example of FIG. 81, the second microwave source μWG_II generates the second microwave signal μW_II with a second microwave frequency ω_{μW_II}.

In the example of FIG. 81, the third microwave source μWG_III generates the third microwave signal μW_III with a third microwave frequency ω_{μW_III}.

In the example of FIG. 81, the fourth microwave source μWG_IV generates the fourth microwave signal μW_IV with a fourth microwave frequency ω_{μW_IV}.

The first microwave frequency ω_{μW_I} and the second microwave frequency ω_{μW_II} and the third microwave frequency ω_{μW_III} and the fourth microwave frequency ω_{μW_IV} can be understood together as the vector microwave frequency ω(μW).

In the example shown in FIG. 81, the vector microwave source μWG thus generates the vector microwave signal μW with a vector microwave frequency ω_{μW}.

In order to detect a maximum amount of information, the first microwave frequency ω_{μW_I} and the second microwave frequency ω_{μW_II} and the third microwave frequency ω_{μW_III} and the fourth microwave frequency ω_{μW_IV} are preferably different from each other.

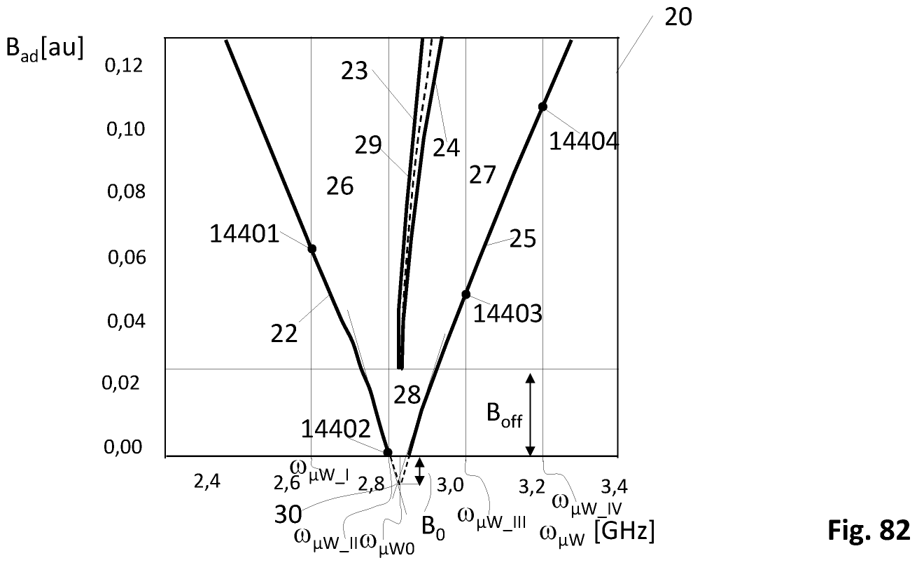

These four microwave frequencies (ω_{μW_I}, ω_{μW_II}, ω_{μW_III}, ω_{μW_IV}) then define four vertical virtual lines in FIG. 51b on which the operating points must lie. (See FIG. 82 below.)

By using a gradient afflicted permanent magnet GPM, these vertical lines actually become visible as measured values and can be extracted directly from the images of the light sensor array 1 by a computer-implemented pattern recognition and/or image processing method. Preferably, the processing device 30 for the output signals 31 of the photo detectors PD of the light sensor array 1 and/or the pattern recognition device MEV and/or the further and/or higher-level computer system CTR2(28) perform the computer-implemented pattern recognition and/or image processing method. Preferably, the program data with the program code for the computer-implemented pattern recognition and/or image processing method is located in a storage medium, for example in a memory (RAM, NVM) of the system. Preferably, the processing device 30 for the output signals 31 of the photo detectors PD of the light sensor array 1 and/or the pattern recognition device MEV and/or the further and/or higher-level computer system CTR2(28) execute the program code for the computer-implemented pattern recognition and/or image processing method in a storage medium, for example in a memory (RAM, NVM) of the system when executing these methods.

An optional first second signal generator G2_I generates a first microwave modulation signal S5m_I with a first microwave modulation frequency f_{μW_I}.

An optional second second signal generator G2_II generates a second microwave modulation signal S5m_II with a second microwave modulation frequency f_{μW_(I)(I)}.

An optional third second signal generator G2_III generates a third microwave modulation signal S5m_III with a third microwave modulation frequency f_{μW_III}.

An optional fourth second signal generator G2_IV generates a fourth microwave modulation signal S5m_IV with a fourth microwave modulation frequency f_{μW_IV}.

Preferably, the reciprocal of the first microwave modulation frequency f_{μW_I} is an integer multiple of the frame rate of the light sensor array 1.

Preferably, the reciprocal of the second microwave modulation frequency f_{μW_II} is an integer multiple of the frame rate of the light sensor array 1.

Preferably, the reciprocal of the third microwave modulation frequency f_{μW_III} is an integer multiple of the frame rate of the light sensor array 1.

Preferably, the reciprocal of the fourth microwave modulation frequency f_{μW_IV} is an integer multiple of the frame rate of the light sensor array 1.

This avoids alizing effects.

The processing device 30 for the output signals 31 of the photo detectors PD of the light sensor array 1 and/or the pattern recognition device MEV and/or the further and/or higher-level computer system CTR2(28) can typically set the first microwave modulation frequency f_{μW_I} of the first microwave modulation signal S5m_I of the first second signal generator G2_I via the data bus DB.

The processing device 30 for the output signals 31 of the photo detectors PD of the light sensor array 1 and/or the pattern recognition device MEV and/or the further and/or higher-level computer system CTR2(28) can typically set the second microwave modulation frequency f_{μW_II} of the second microwave modulation signal S5m_II of the second second signal generator G2_II via the data bus DB.

The processing device 30 for the output signals 31 of the photo detectors PD of the light sensor array 1 and/or the pattern recognition device MEV and/or the further and/or higher-level computer system CTR2(28) can typically set the third microwave modulation frequency f_{μW_III} of the third microwave modulation signal S5m_III of the third second signal generator G2_III via the data bus DB.

The processing device 30 for the output signals 31 of the photo detectors PD of the light sensor array 1 and/or the pattern recognition device MEV and/or the further and/or higher-level computer system CTR2(28) can typically set the fourth microwave modulation frequency f_{μW_IV} of the fourth microwave modulation signal S5m_IV of the fourth second signal generator G2_IV via the data bus DB.

The optional first microwave modulation signal S5m_I can typically, if present, modulate the amplitude of the first microwave signal μW_I.

The optional second microwave modulation signal S5m_II can typically, if present, modulate the amplitude of the second microwave signal μW_II.

The optional third microwave modulation signal S5m_III can typically, if present, modulate the amplitude of the third microwave signal μW_III.

The optional fourth microwave modulation signal S5m_IV can typically, if present, modulate the amplitude of the fourth microwave signal μW_IV.

Preferably, the first second signal generator G2_I also transmits the first microwave modulation signal S5m_I to the processing device 30 for the output signals 31 of the photo detectors PD of the light sensor array 1 and/or the pattern recognition device MEV and, if necessary, indirectly via these to the further and/or higher-level computer system CTR2(28).

Preferably, the second second signal generator G2_II also transmits the second microwave modulation signal S5m_II to the processing device 30 for the output signals 31 of the photo detectors PD of the light sensor array 1 and/or the pattern recognition device MEV and, if necessary, indirectly via these to the further and/or higher-level computer system CTR2(28).

Preferably, the third second signal generator G2_III also transmits the third microwave modulation signal S5m_III to the processing device 30 for the output signals 31 of the photo detectors PD of the light sensor array 1 and/or the pattern recognition device MEV and, if necessary, indirectly via these to the further and/or higher-level computer system CTR2(28).

Preferably, the first fourth signal generator G2_IV also transmits the fourth microwave modulation signal S5m_IV to the processing device 30 for the output signals 31 of the photo detectors PD of the light sensor array 1 and/or the pattern recognition device MEV and, if necessary, indirectly via these to the further and/or higher-level computer system CTR2(28).

If such modulation takes place in accordance with the vectorial microwave modulation signal S5m, the processing device 30 for the output signals 31 of the photo detectors PD of the light sensor array 1 and/or the pattern recognition device MEV and, if applicable, indirectly via these to the further and/or higher-level computer system CTR2(28), take into account the respective vectorial value of the vectorial microwave modulation signal S5m when executing the computer-implemented image recognition methods and/or pattern recognition methods.

After evaluating one or more images of the light sensor array 1, the processing device 30 for the output signals 31 of the photo detectors PD of the light sensor array 1 and/or the pattern recognition device MEV and/or the further and/or higher-level computer system CTR2(28) preferably determine a need for refinement in order to improve the precision of the measurement results. For this purpose, the processing device 30 for the output signals 31 of the photo detectors PD of the light sensor array 1 and/or the pattern recognition device MEV and/or the further and/or higher-level computer system CTR2(28) preferably carry out a computer-implemented Bayesian optimization procedure, for example. Preferably, the program code for the exemplary Bayesian optimization method is stored in a storage medium of the device, in particular a memory (RAM, NVM). Preferably, the processing device 30 for the output signals 31 of the photo detectors PD of the light sensor array 1 and/or the pattern recognition device MEV and/or the further and/or higher-level computer system CTR2(28) carry out this program code when executing the computer-implemented Bayesian optimization method.

During the exemplary Bayesian optimization procedure, the processing device 30 for the output signals 31 of the photo detectors PD of the light sensor array 1 and/or the pattern recognition device MEV and/or the further and/or higher-level computer system CTR2(28) can, for example, set new vector microwave frequencies (ω_{μW_I}, ω_{(μW_)(I)(I)}, ω_{μW_III}, ω_{μW_IV}) in the vectorial microwave source μW and thus the diagram detected FIG. 51b at points of interest other microwave frequencies (ω_{μW_I}, ω_{(μW_)(I)(I)}, ω_{μW_III}, ω_{μW_IV}) at points of interest.

During the exemplary Bayesian optimization process, the processing device 30 for the output signals 31 of the photo detectors PD of the light sensor array 1 and/or the pattern recognition device MEV and/or the further and/or higher-level computer system CTR2(28) can set other additional magnetic flux densities B_{ad}, which the magnetic field generation device L_{C} generates and which contributes to the total flux density B_{Σ} in each case, for example via the data bus DB.

This allows the processing device 30 for the output signals 31 of the photo detectors PD of the light sensor array 1 and/or the pattern recognition device MEV and/or the further and/or higher-level computer system CTR2(28) to shift the detection area in the FIG. 51b upwards or downwards and thus bring more significant positions, such as the point of the zero-point microwave frequency ω_{μW0} and the zero-point flux density B₀, into the detection area. Such positions are particularly easy to detect. In this way, the sensor device can very quickly improve the precision of the measured values and, by determining the position of the curve of FIG. 51b in a flux density-microwave frequency diagram, determine the parameters of an external magnetic flux density Bₑₓₜ and an unknown microwave frequency ω_{μWnk} of a microwave field acting from outside, in particular by mixing with a mixed frequency.

Preferably, the control device CTR (processing device 30) and/or the pattern recognition device MEV and/or the further and/or higher-level computer system CTR2(28) determine one or more of the following measured values or groups of measured values using said computer-implemented image processing and/or pattern recognition devices:
1. Information on the probable position of the lower resonance edge 522;
2. Information on the probable position of the lower middle resonance edge 523;
3. Information on the probable position of the upper middle resonance edge 524;
4. Information on the probable position of the upper resonance edge 525;
5. Information on the probable position of the middle resonance minimum 529;
6. Information about the probable value of the effective offset flux density B_{off};
7. Information on the probable value of the zero-point flux density B₀; and
8. Information on the probable value of the zero-point microwave frequency ω_{μW0},

After further measurements, the control device CTR and/or the pattern recognition device MEV and/or an evaluation device 30 and/or the further and/or higher-level computer system CTR2(28) can also conclude one or more of the following values here:
9. Information about the probable value 564 of the magnetic flux density B₆₁ associated with the upper reference line 561 at one or more operating points;
10. Information about the probable value 565 of the magnetic flux density B₆₂ associated with the lower reference line 562 at one or more operating points;
11. Information about the probable difference 566 of the value of the magnetic flux density B₆₃ associated with the middle reference line 563 minus the value 565 of the magnetic flux density B₆₂ associated with the lower reference line 562;
12. Information about the probable slope 567 of the curve at one or more operating points;
13. Information on the polynomial coefficients of the polynominal approximation 627 of the curve at some operating points;
14. Information on the probable value of a lower effective magnetic flux density B₂₂;
15. Information on the probable value of a lower mean effective magnetic flux density B₂₃;
16. Information on the probable value of an upper mean effective magnetic flux density B₂₄;
17. Information on the probable value of an upper effective magnetic flux density B₂₅;
18. Information on the probable value of an effective magnetic resonance minimum flux density B₂₉;
19. Information on the probable value of a zero-point microwave frequency ω_{μW0};
20. the probable value of a lower microwave frequency ω_{μW22};
21. Information on the probable value of a lower mean microwave frequency ω_{μW23};
22. Information on the probable value of an upper mean microwave frequency ω_{μW24};
23. Information on the probable value of an upper microwave frequency ω_{μW25};
24. Information on the probable value of a resonance minimum microwave frequency ω_{μW29};
25. Information on the probable value of an unknown microwave frequency ω_{μWnk}; and
26. Information about the probable value of a microwave modulation frequency f_{μW};

### FIG. 82

FIG. 82 shows the diagram of FIG. 51b, wherein four exemplary microwave frequencies (ω_{μW_I}, ω_{μW_II}, ω_{μW_III}, ω_{μW_IV}) are now drawn as examples, with which, for example, a device corresponding to FIG. 81 determines the measured values of the intensity of the I_{fl}(B_{ad}) fluorescence radiation FL along the four drawn vertical lines for various additional absolute values of the magnetic flux density B_{ad}. This enables the control device CTR and/or the pattern recognition device MEV or an evaluation device 30 to determine the first operating point 14401 with the values B₂₂, ω_{μW,22}=ω_{μW_I} and the second operating point 14402 with the values B₂₂, ω_{μW,22}=ω_{μW_II} on the lower resonance edge 522.

In addition, this enables the control device CTR and/or the pattern recognition device MEV or an evaluation device 30 to determine the third operating point 14403 with the values B₂₅, ω_{μW,25}=ω_{μW_III} and the fourth operating point 14404 with the values B₂₂, ω_{μW,25}=ω_{μW_IV} on the upper resonance edge 25. It is easy to see that for microwave frequencies ω_{μW} that are greater than the zero-point microwave frequency ω_{μW0}, there may also be intersections of the vertical lines with the lower middle resonance edge 523, with the upper middle resonance edge 524 and with the middle resonance minimum 529. Depending on the application, it may therefore be better to use the left-hand region of the diagram of FIG. 51b with ω_{μW}<ω_{μW0} (more precise and unambiguous) or the right-hand region of the diagram of FIG. 51b with ω_{μW}>ω_{μW0} (more information). By means of computer-implemented methods, the pattern recognition device MEV and/or the control device CTR can determine the position of the tip 30 of the F-formation (522, 525) and derive measured values for physical parameters sought.

### FIG. 83

FIG. 83 shows an example of the internal structure of a vector microwave source μWG with the microwave sources (μWG_I, μWG_II, μWG_III, μWG_IV) of FIG. 81 in the case of the addition of an external signal S_{ω nk} with unknown microwave frequency ωₙₖ using the microwave sources (μWG_I, μWG_II, μWG_III, μWG_IV) of FIG. 81 as an example.

In the example, the first internal microwave source μW_G_I generates the first internal microwave signal μW_G_I as a function of the first microwave modulation signal S5m_I and the parameters set via the data bus DB by the control device CTR or the evaluation device 30 or the pattern recognition device MEV. Preferably, the amplitude of the first internal microwave signal μW_G_I depends on the first microwave modulation signal S5m_I. The first internal microwave signal μW_G_I comprises a first microwave frequency ω_{μW}_I.

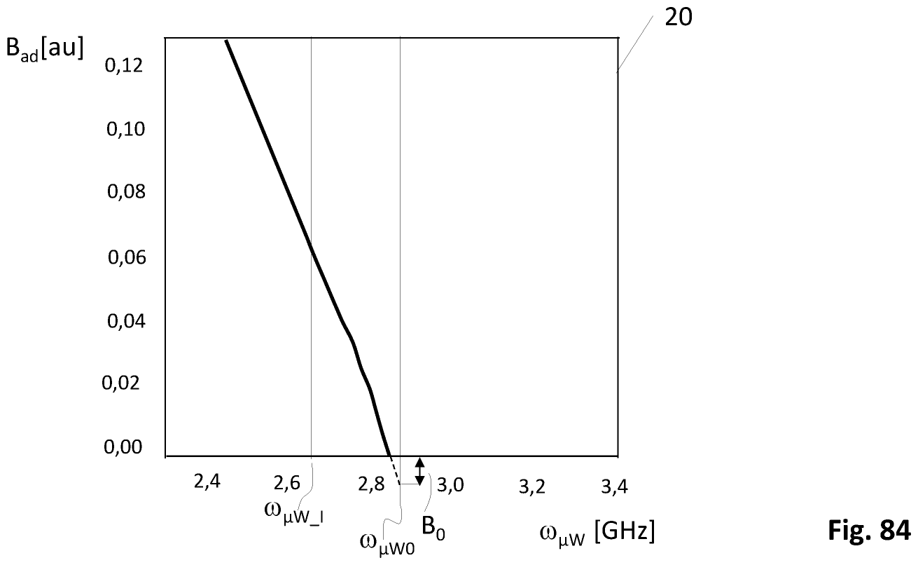

A first internal mixer μW_MX_I within the first microwave source μWG_I now mixes the first internal microwave signal μW_G_I with the signal S_{ω nk} with the unknown microwave frequency ωₙₖ. The first internal mixer μW_MX_I thus forms the first microwave mixing signal μW_MX_I mixed in this way. A first microwave filter μW_F_I (see FIG. 83) preferably eliminates one of the two transients arising at ω_{μW_I}−ωₙₖ and ω_{μW_I}+ωₙₖ in the first microwave mixing signal μW_MX_I and forms the first microwave signal μW_I. Preferably, the cut-off frequency of the first microwave filter μW_F_I is lower than the zero-point microwave frequency ω_{μW0} in the case of a low pass as the first microwave filter μW_F_I. Preferably, the cut-off frequency of the first microwave filter μW_F_I is greater than the zero-point microwave frequency ω_{μW0} in the case of a high-pass first microwave filter μW_F_I. This converts the diagram of FIG. 51b relating to the position of the lower resonance edge 522 into an invertible function ω_{μW} (B_{ad}). (see FIG. 84)

In the example, the second internal microwave source μW_G_II generates the second internal microwave signal μW_G_II as a function of the second microwave modulation signal S5m_II and the parameters set via the data bus DB by the control device CTR or the evaluation device 30 or the pattern recognition device MEV. Preferably, the amplitude of the second internal microwave signal μW_G_II depends on the second microwave modulation signal S5m_II. The second internal microwave signal μW_G_II comprises a second microwave frequency ω_{μW_II}.

A second internal mixer μW_MX_II within the second microwave source μWG_II now mixes the second internal microwave signal μW_G_II with the signal S_{ωnk} with the unknown microwave frequency ωₙₖ. The second internal mixer μW_MX_II thus forms the mixed second microwave mixing signal μW_MX_II. A second microwave filter μW_F_II (see FIG. 83) preferably eliminates one of the two transients occurring at ω_{μW_II}−ωₙₖ and ω_{μW_(I)(I)}+ωₙₖ in the second microwave mixing signal μW_MX_II and forms the second microwave signal μW_II. Preferably, the cut-off frequency of the second microwave filter μW_F_II is lower than the zero-point microwave frequency ω_{μW0} in the case of a low pass second microwave filter μW_F_II. Preferably, the cut-off frequency of the second microwave filter μW_F_II is greater than the zero-point microwave frequency ω_{μW0} in the case of a high-pass second microwave filter μW_F_II. This converts the diagram of FIG. 51b relating to the position of the lower resonance edge 522 into an invertible function ω_{μW} (B_{ad}). (see FIG. 84)

In the example, the third internal microwave source μW_G_III generates the third internal microwave signal μW_G_III as a function of the third microwave modulation signal S5m_III and the parameters set via the data bus DB by the control device CTR or the evaluation device 30 or the pattern recognition device MEV. Preferably, the amplitude of the third internal microwave signal μW_G_III depends on the third microwave modulation signal S5m_III. The third internal microwave signal μW_G_III comprises a third microwave frequency ω_{μW_III}.

A third internal mixer μW_MX_III within the third microwave source μWG_III now mixes the third internal microwave signal μW_G_III with the signal S_{ω nk} with the unknown microwave frequency ωₙₖ. The third internal mixer μW_MX_III thus forms the mixed third microwave mixing signal μW_MX_III. A third microwave filter μW_F_III (see FIG. 83) preferably eliminates one of the two transients arising at ω_{μW_III}−ωₙₖ and ω_{μW_III}+ωₙₖ in the third microwave mixing signal μW_MX_III and forms the third microwave signal μW_III. Preferably, the cut-off frequency of the third microwave filter μW_F_III is lower than the zero-point microwave frequency ω_{μW0} in the case of a low pass third microwave filter μW_F_III. Preferably, the cut-off frequency of the third microwave filter μW_F_III is greater than the zero-point microwave frequency ω_{μW0} in the case of a high-pass third microwave filter μW_F_III. This converts the diagram of FIG. 2 relating to the position of the lower resonance edge 522 into an invertible function ω_{μW} (B_{ad}). (see FIG. 84)

In the example, the fourth internal microwave source μW_G_IV generates the fourth internal microwave signal μW_G_IV as a function of the fourth microwave modulation signal S5m_IV and the parameters set via the data bus DB by the control device CTR or the evaluation device 30 or the pattern recognition device MEV. Preferably, the amplitude of the fourth internal microwave signal μW_G_IV depends on the fourth microwave modulation signal S5m_IV. The fourth internal microwave signal μW_G_IV comprises a fourth microwave frequency ω_{μW_IV}.

A fourth internal mixer μW_MX_IV within the fourth microwave source μWG_IV now mixes the fourth internal microwave signal μW_G_IV with the signal S_{ω nk} with the unknown microwave frequency ωₙₖ. The fourth internal mixer μW_MX_IV thus forms the mixed fourth microwave mixing signal μW_MX_IVI. A fourth microwave filter μW_F_IV (see FIG. 83) preferably eliminates one of the two transients arising at ω_{μW_IV}−ωₙₖ and ω_{μW_IV}+ωₙₖ in the fourth microwave mixing signal μW_MX_IV and forms the fourth microwave signal μW_IV. Preferably, the cut-off frequency of the fourth microwave filter μW_F_IV is lower than the zero-point microwave frequency ω_{μW0} in the case of a low pass fourth microwave filter μW_F_IV. Preferably, the cut-off frequency of the fourth microwave filter μW_F_IV is greater than the zero-point microwave frequency ω_{μW0} in the case of a high-pass fourth microwave filter μW_F_IV. This converts the diagram of FIG. 51b relating to the position of the lower resonance edge 522 into an invertible function ω_{μW}(B_{ad}). (see FIG. 84)

### FIG. 84

FIG. 84 illustrates the function formation of the curve of the lower resonance edge 522 by low-pass filtering in the microwave filters (μW_F_I, μW_F_II, μW_F_III, μW_F_IV) (see FIGS. 81, 82 and 83).

### FIG. 85

The basic idea of the fabrication of a colloidal varnish KL for coating and/or printing the carrier substrate 1360 is illustrated in FIG. 85:

First of all, we assume here that the crystals or diamond nano crystals ND are present in sufficiently large quantities in preferably essentially the same form. By way of example, we assume here that the crystals or diamond nano crystals ND are nano-diamonds with one or more paramagnetic centers, preferably with one or more NV centers. Other crystal materials and/or paramagnetic centers are conceivable if they also emit a fluorescence radiation FL upon exposure to a pump radiation LB of a typically center-specific pump radiation wavelength λₚₘₚ. The diamond nano crystals ND are thus exemplary here for other possible crystals with possibly other properties and/or other paramagnetic centers. Reference is made to the rest of this document. In the case of diamond nano crystals ND comprising diamond, NV centers are preferred paramagnetic centers.

The crystals with paramagnetic centers and/or diamond nano crystals ND with paramagnetic centers and/or NV centers are mixed with the previously selected substrate material TM, which is provided in a suitable form, and optionally a solvent LM for adjusting the viscosity. a solvent LM for adjusting the viscosity, for example, are placed in a container for mixing and mixed by means of stirring VR until a colloidal mixture (colloidal varnish KL) is formed which is suitable for the intended further processing, for example in a subsequent spin-on coating or a printing process, for example a screen printing process and/or a stencil printing process and/or pad printing.

The document presented herein proposes as substrate material TM, for example, a clear, colorless, liquid photopolymer, such as Norland optical adhesive 61. Further information is available at the point in time of filing the document presented here at https://www.norlandprod.com/adhesives/noa%2061.html.

Norland Optical Adhesive 61 (“NOA 61”) is a clear, colorless, liquid photopolymer that cures under exposure to a curing radiation 4910 with the curing wavelength λ_{H} in the ultraviolet wavelength range. As it is a one-component system with 100% solids content, it offers many advantages for bonding where the adhesive can be exposed to UV light. The use of NOA 61 eliminates the need for premixing, drying or curing by heat as is common with other adhesive systems. The curing time is typically short and depends on the applied thickness D_{SE} of the sensor element layer 5 or the sensor element SE and the available UV light energy. It is particularly useful if the carrier medium TM fulfills the Federal Specification MIL-A-3920 for optical adhesives. NOA 61 as carrier medium TM complies with the Federal Specification MIL-A-3920 of Feb. 21, 1977, for optical adhesives. The substrate material TM should be able to create the best possible optical bond to the surface of the carrier substrate 1360. Accordingly, the substrate material TM should provide the best possible optical and/or mechanical bond to FR-4 surfaces (Flameresistant-4) or PTFE surfaces (polytetrafluoroethylene) or surfaces of semiconducting materials, such as surfaces of pieces of printed circuit board materials or pieces of plastic sheets or films and/or pieces of glass wafers or pieces of ceramic wafers and/or pieces of semiconductor wafers, for example surfaces of pieces of CMOS wafers or for example pieces of BICMOS wafers for example pieces of wafers from a bipolar technology or pieces of a wafer from a III/V material or the like and/or for example pieces of MEMS wafers and/or pieces of microelectronic circuits and/or for example pieces of MEOS wafers (MEOS=micro electro optical system) and/or for example pieces of MOEMS wafers etc. and/or pieces of MOEMS wafers of microelectronic circuits and microelectronic functional elements and/or micro-optical functional elements and/or micro-mechanical functional elements and/or micro-fluidic functional elements, depending on the field of application. NOA61 generally fulfills these requirements, in particular over the required temperature range and typically over the expected lifetime. However, this does not make product qualification superfluous. The use of a substrate material TM, which is recommended for the bonding of lenses, prisms and mirrors for military, aerospace and commercial optics as well as for the termination and splicing of optical fibers, is particularly advantageous. NOA61 fulfills these requirements.

According to the manufacturer, the substrate material TM is also typically characterized by excellent clarity, low shrinkage and light flexibility. These properties are important to enable the user to produce high quality sensor elements SE and/or sensor element layers SE(5) and achieve long-term performance under varying aggressive environmental conditions.

NOA 61 cures, as desired for the substrate material TM, with ultraviolet light as curing radiation 4910, whereby the maximum absorption is in the region of 320-380 nanometers for the curing wavelength λ_{H} and the highest sensitivity for the curing of NOA61 is achieved at a curing wavelength λ_{H} of 365 nm. The recommended energy for complete curing is 3 joules/cm² at these curing wavelengths& H. The curing of NOA 61 is not inhibited by oxygen, so all regions in contact with air will cure to a non-tacky state when exposed to ultraviolet light as curing radiation 4910.

In most optical applications, curing takes place in two steps by means of curing radiation 4910. First, a short, uniform exposure, known as pre-bake, is carried out using curing radiation 4910 with a curing wavelength λ_{H}. The curing time is long enough to solidify the joint and allow it to be moved/transported without disturbing the alignment. This is followed by a longer curing under UV light as curing radiation 4910 to achieve complete cross-linking and solvent resistance of the adhesive, for example NOA 61. In the example NOA 61 as substrate material TM, curing with curing radiation 4910 can be accomplished in 10 seconds using a 100 watt mercury lamp at 6″. If a longer time is required for alignment, it can be extended to several minutes in the case of the exemplary substrate material TM NOA 61 using a very low intensity light source for curing radiation 4910. Final curing can be achieved in 5 to 10 minutes with the 100 watt mercury lamp in the case of the exemplary substrate material TM.

Pre-baking allows the user to still quickly align and fix the carrier substrate 1360 and/or optical waveguide LWL) against each other if required in the case of separate deployment, and minimizes the number of holding devices required. After pre-fixing, excess adhesive can be wiped off and/or rinsed off with a cloth moistened with alcohol or acetone as an exemplary solvent LM. The optical waveguide LWL) should be inspected at this point in time and rejects separated in methylene chloride. The coated region of the sensor elements SE and/or sensor element layers 5 typically needs to be soaked in the solvent LM for rework and typically dissolves overnight. The time required to dissolve the substrate material TM for reworking depends on the extent of curing and the size of the coating.

After curing, NOA 61 as substrate material TM comprises very good adhesion and solvent resistance, but it has not yet reached its optimum adhesion to glass and/or SiO₂ semiconductor wafer surfaces. This is achieved by ageing over a period of about 1 week, during which a chemical bond forms between the glass or SiO₂ surface on the one hand and the substrate material TM on the other. This optimum adhesion can also be achieved by aging the carrier substrate 1360 with the sensor element layer 5 and/or the sensor elements SE at 50° C. for 12 hours in a temperature oven.

NOA 61 can withstand temperatures from −15° C. to 60° C. before ageing when used to coat the optical waveguide (LWL) and/or the carrier substrate 1360. After ageing, it can withstand temperatures from −150° C. to 125° C. This substrate material TM NOA 61 is therefore suitable for automotive applications. As a coating on the surface of the optical waveguide (LWL) and/or the carrier substrate 1360, NOA 61 can withstand 260° C. for three hours and during reflow soldering. This is of particular interest if the carrier substrate is a circuit board material, for example with electronic components. In this context, the document presented here refers to the as yet unpublished document DE 10 2023 111 858.7, which allows the sensor element SE and/or the sensor element layer 5 and/or the proposed optical waveguides LWL) to be used up to these temperatures for measuring the total flux density B_{Σ} and/or for measuring unknown microwave frequencies ωₙₖ. The document presented here therefore proposes the use of a proposed optical waveguide LWL and/or the sensor element SE and/or the sensor element layer 5 at temperatures above 100° C. and/or even above 110° C. and/or even above 120° C. and/or even above 130° C. and/or even above 140° C. and/or even above 150 and/or even above 160° C. and/or even above 170° C. and/or even above 180° C. and/or even above 190° C. and/or even above 200° C. and/or even above 210° C. and/or even above 220° C. and/or even above 230° C. and/or even above 240° C. and/or even above 250° C. and/or even above 260° C. It should be noted here that the properties of the material of a proposed optical waveguide LWL) and/or the sensor element SE and/or the sensor element layer 5 were not taken into account here, which may no longer permit these temperature ranges, which would have to be checked in the event of reworking.

Typical properties of a substrate material TM are a solids content of more than 80%, a viscosity at 25° C. of more than 250 cps, a refractive index of the cured substrate material TM of more than 1.2, an elongation at break of less than 50% or more than 25% depending on the application, a modulus of elasticity of less than (psi) 200,000, a tensile strength of more than (psi) 3,000 and a hardness of more than Shore D

60.

Typical properties of NOA 61 as an exemplary substrate material TM are a solids content of 100%, a viscosity at 25° C. of 300 cps, a refractive index of the cured polymer of the substrate material TM of 1.56, an elongation at break of 38%, a modulus of elasticity of (psi) 150,000, a tensile strength of (psi) 3,000 and a hardness of Shore D 85.

As already described, these methods are in principle not limited to the use of substrate material TM (NAO 61 in alcoholic solution, for example) and these crystals or diamond nano crystals ND with paramagnetic centers, in particular NV centers. For example, diamond nano crystals ND with SiV centers and/or with TiV centers and/or with GeV centers and/or with SnV centers and/or with NiN4 centers and/or with PbV centers and/or with ST1 centers can also be used as paramagnetic centers instead of diamonds with NV centers as diamond nano crystals ND, whereby their suitability would have to be checked beforehand by a person skilled in the art, if necessary during reworking. Such alternative paramagnetic centers and/or materials for crystals and/or diamond nano crystals ND must be suitable for fulfilling the technical purpose of the system to be manufactured, which would have to be checked in each case at the beginning of reworking. To simplify the description, we do not present all reasonable variants here. However, the claim also comprises such combinations. Other combinations of crystals of other materials and other substrate materials TM and other solvents LM can also be used if the technical task to be solved by the system to be fabricated and the intended fabrication method (coating and/or printing and/or local wetting) require this. In the following, only the term coating is usually used. Where applicable, this term should also comprise the terms coating, coating and/or local wetting. The reference sign ND thus stands here not only for diamond nano crystals ND, which comprise diamond as a material, but also for more general crystals.

The crystals can also be poly-crystalline and then comprise different materials and layers. For example, they may be silicon nanocrystals and/or crystals and mixed crystals comprising, for example, III/V materials, which are encased in an SiO₂ layer or another insulation layer that is optical in the relevant wavelength ranges (λₚₘₚ,λ_{FL}) and preferably comprise suitable paramagnetic centers. Numerous different transparent lacquers are also known from the prior art, for example, which can be tested for their respective suitability as substrate material TM when used instead of NOA61. What is written here applies to the diamond nano crystals ND throughout the document.

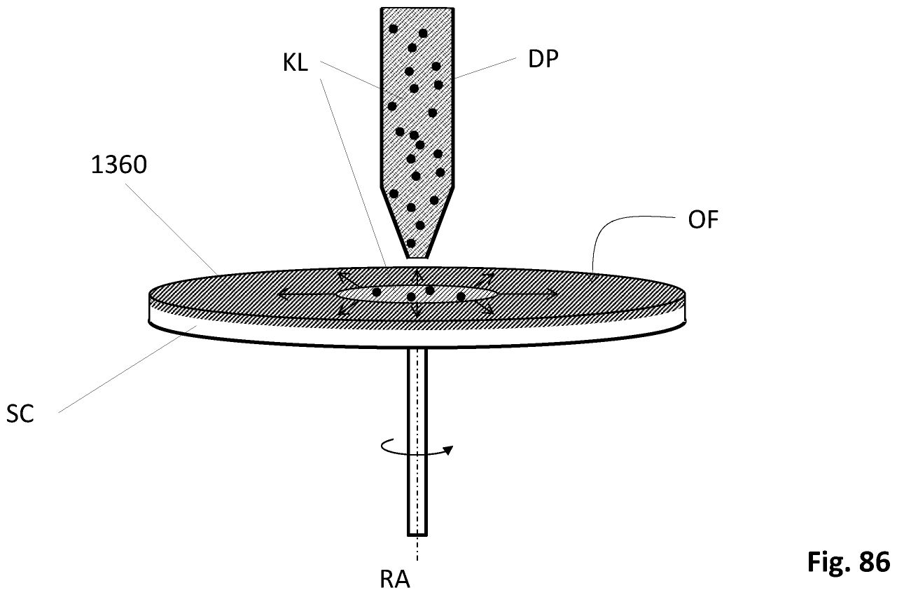

### FIG. 86

In its basic version, the method presented here provides for applying a colloidal varnish KL comprising a substrate material TM and crystals and/or diamond nano crystals ND to the carrier substrate 1360.

Typically, the carrier substrate 1360 comprises materials such as FR-4 (Flameresistant-4) or PTFE (polytetrafluoroethylene) or semiconducting materials, such as pieces of board materials or pieces of plastic sheet or film and/or pieces of glass wafers or pieces of ceramic wafers and/or pieces of semiconductor wafers, for example pieces of CMOS wafers or for example pieces of BiCMOS wafers and/or for example pieces of wafers from a bipolar technology and/or pieces of a wafer from a III/V material or the like and/or for example pieces of MEMS wafers and/or pieces of microelectronic circuits and/or for example pieces of MEOS wafers (MEOS=micro electro optical system) and/or for example pieces of MOEMS wafers etc. and/or pieces of MOEMS wafers microelectronic circuits and microelectronic functional elements and/or micro-optical functional elements and/or micro-mechanical functional elements and/or micro-fluidic functional elements.

The colloidal varnish KL can be applied to the carrier substrate 1360, for example by spinning or spraying or printing or similar methods. (See FIG. 147.) With regard to the coating processes possible in the state of the art of microtechnology, reference is made here to Marc J. Madou “Fundamentals of Microfabrication: the science of miniaturization” CRC Press 2002.

FIG. 86 shows an example of a possible coating process corresponding to this. The colloidal varnish KL is applied to the exemplary carrier substrate 1360, here an exemplary wafer, by means of a dispenser DP, a special dosing device, preferably in the center of symmetry of the exemplary carrier substrate 1360, here an exemplary wafer, in a preferably predetermined temporal quantity progression per unit of time. The exemplary carrier substrate 1360 in the form of the exemplary wafer, which here represents the exemplary carrier substrate 1360, lies in this example on the turntable of a lacquer spinner SC. This turntable of the lacquer spinner SC rotates at a process-typical speed, typically corresponding to a process-typical temporal speed profile. The application and the rotation speed may depend on the point in time since the start of coating, for example by the dispenser DP, to ensure an optimal result for the coating with the colloidal varnish KL and the placement of the nanoparticles NP. They therefore preferably follow a rotation speed profile or a temporal profile of the application quantity of the colloidal varnish KL.

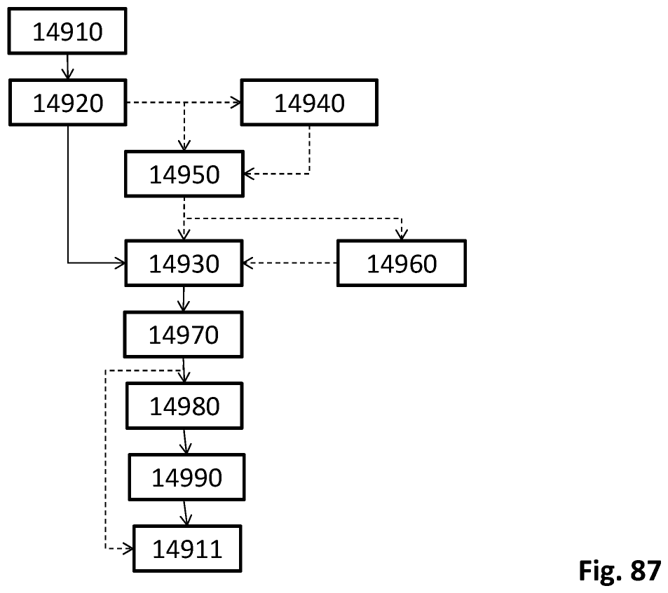

### FIG. 87

The exemplary steps of a wafer-based coating process are shown schematically and in simplified form in FIG. 87.

The relevant exemplary coating process of FIG. 87 begins at the start of process 14910.

This is followed by the deployment 14920 of a carrier substrate 1360, preferably a semiconductor substrate—for example a wafer.

This is preferably followed by the deployment 14930 of a colloidal varnish KL in the form of a colloidal solution of crystals or diamond nano crystals ND in a still liquid substrate material TM and possibly an additional solvent. The deployment 14920 of the carrier substrate 1360 and the deployment 14930 of a colloidal varnish KL can be carried out in any order one after the other or simultaneously. The crystals or diamond nano crystals ND preferably comprise paramagnetic centers and/or NV centers in diamond.

The colloidal varnish KL is later structured and cured to form a structured colloidal film in the form of the sensor elements SE on the carrier substrate 1360 preferably by means of a curing radiation 4910 with the curing wavelength λ_{H}. The colloidal varnish KL is preferably structured to form a structured colloidal film in the form of the sensor elements SE on the carrier substrate 1360, most preferably by means of a locally selectively projected or supplied curing radiation 4910 with the curing wavelength λ_{H} locally and selectively cured. Preferably, optical functional elements of the device, for example optical waveguides LWL) and/or carrier substrates 1360 used as optical waveguides, which must later be aligned with respect to the sensor elements SE and/or the sensor element layers 5 then formed, are used for the supply of curing radiation 4910 with the curing wavelength λ_{H}, so that this supply automatically produces a self-adjusting curing effect of the UV-curable colloidal varnish KL during the formation of the sensor elements SE and/or the sensor element layers 5 with respect to these optical functional elements of the device, for example optical waveguides LWL and/or carrier substrates 1360 used as optical waveguides. So that this later hardened colloidal film in the form of the sensor elements SE can adhere to the surface of the carrier substrate 1360, the colloidal varnish KL of the crystals or diamond nano crystals ND should be able to wet at least parts of the carrier substrate 1360. This can be controlled, for example, by one or more optional preceding plasma treatments 14950 with hydrogen or oxygen or the like, as is known. Here, the wetting properties of the surface can also be modulated (wetting vs. non-wetting) by means of a photolithography 14940 preceding the plasma treatment. For this purpose, prior to the plasma treatment 14950, some surface regions are selectively covered, for example, with photoresist in said photolithography step 14940 and other regions to be treated are not covered with photoresist so that they are exposed to the plasma. Such modulation of the wetting properties would thus be another optional additional step in the form of photolithography 14940 that is conceivable.

After the optional plasma treatment 14950, the masking lacquer is typically removed again 14960 if said photolithography step 14940 has been performed beforehand.

The coating 14970 of the carrier substrate 1360 with the colloidal varnish KL of the crystals or diamond nano crystals ND then follows, in order to obtain a colloidal film of colloidal varnish KL on a surface of the carrier substrate 1360. This is done, for example, by spinning and/or spraying and/or printing a previously prepared colloidal varnish of the crystals or diamond nano crystals ND.

As a rule, the colloidal varnish KL of the crystals or diamond nano crystals ND with the crystals or diamond nano crystals ND contained therein is then cured 14980 to such an extent to form a colloidal film in the form of sensor elements SE that it is mechanically sufficiently stable for further processing, but can still be structured by means of other subsequent process steps if necessary. The processing instructions for the preferred substrate material TM NOA 61 in this document are referred to in this context.

This structuring 14990 of the colloidal film to produce the sensor elements SE is usually preferably carried out using photolithographic methods.

The preferred method proposed by the present document is the structured curing of the colloidal film of colloidal varnish KL on the surface of the support substrate 1360 by selective exposure to curing radiation 4910 having a curing wavelength λ_{H}, removal of the excess colloidal varnish KL with a solvent LM and, if necessary, subsequent final curing by a temperature step in a thermal chamber or a curing step by storage.

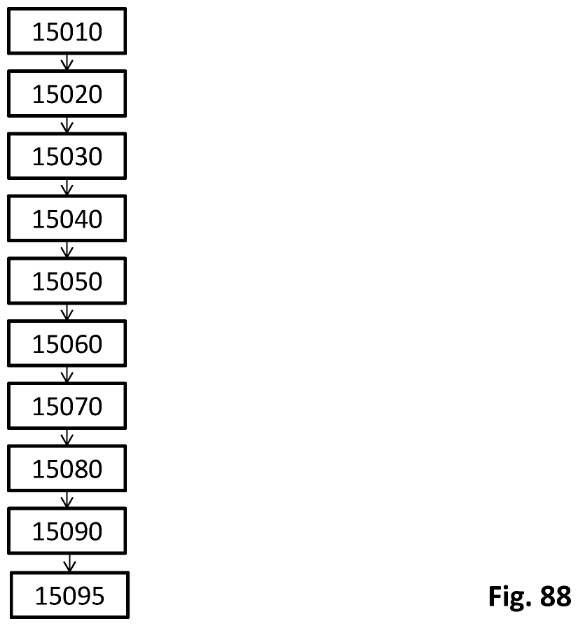

### FIG. 88

FIG. 88 shows a second method of patterning. This second method of patterning may be performed by pre-baking the colloidal film of colloidal varnish KL on the surface of the support substrate 1360. Subsequently, the not fully cured colloidal film of colloidal varnish KL on the surface of the support substrate 1360 may be photolithographically patterned using photolithographic methods. For example, such a photolithographic method may be as follows:
1. Applying 15010 the colloidal film of colloidal varnish KL to the surface of the carrier substrate 1360;
2. Curing 15020 of the colloidal film of colloidal varnish KL on the surface of the carrier substrate 1360;
3. Application 15030 photoresist on the surface of the colloidal film of colloidal varnish KL on the surface of the carrier substrate 1360;
4. Curing 15040 of the photoresist;
5. selectively exposing 15050 the photoresist with a mask aligned with respect to other structures on the support substrate 1360, or otherwise;
6. Developing 15060 of the photoresist develop with opening of the etching openings in the photoresist;
7. if necessary, curing 15070 of the photoresist, the challenge here being to cure the photoresist sufficiently and not to cure the substrate material TM of the colloidal film in the colloidal varnish KL on the surface of the carrier substrate 1360 too far;
8. selectively etching or dissolving 15080 the exposed colloidal film of colloidal varnish KL on the surface of the carrier substrate 1360 in the etching openings, whereby the photoresist should be attacked as little as possible (if necessary, other intermediate layers such as metal layers can be applied to the colloidal film of colloidal varnish KL on the carrier substrate 1360 and structured);
9. selective removal 15090 of the photoresist; and
10. curing 15095 of the remaining colloidal film of colloidal varnish KL on the surface of the carrier substrate 1360 to obtain the sensor elements SE and/or sensor element layers 5).

Such a structuring process is not self-adjusting and is therefore subject to greater manufacturing fluctuations than the self-adjusting manufacturing process.

Such structuring 14990 is not necessarily required. In some applications, it may be sufficient to apply the colloidal varnish KL of the crystals or diamond nano crystals ND using one of said coating methods, i.e. to carry out the coating 14970 and then directly cure the colloidal varnish KL of the crystals or diamond nano crystals ND completely 14910. However, structuring 14990 is also conceivable by means of micro-mechanical methods (scribing, milling) in addition to said photolithographic methods. Excimer lasers and particle beams such as electrons and/or ion beams can also be used for structuring. Either the substrate material TM of the colloidal varnish KL or the resulting colloidal film is itself a photoresist material and thus the colloidal varnish is a photoresist, or the photoresist is applied to the colloidal varnish KL as an overlying layer. In the latter case, the photoresist should be selected such that it can be selectively patterned by the colloidal varnish KL or colloidal film and the colloidal varnish KL or colloidal film can be selectively patterned by the photoresist.

Preferred, however, is a variant of the colloidal varnish KL with a photosensitive substrate material TM, for example a suitable photosensitive polyimide and/or NOA 61.

The preferably photolithographic or micro-mechanical structuring 14990 of the colloidal varnish KL to form the colloidal film with the sensor elements SE and/or the sensor element layer 5 then takes place.

After structuring 14990, the final curing 14911 of the colloidal film and thus of the sensor elements SE and/or the sensor element layers 5 typically takes place.

By means of the proposed method, it is thus possible to place any crystals and/or diamond nano crystals ND in a targeted manner on a carrier substrate 1360, in particular a circuit board and/or a wafer, in particular on a CMOS wafer or BICMOS wafer or bipolar wafer or a planar glass or plastic wafer, and, if desired, to place them in a self-aligning manner.

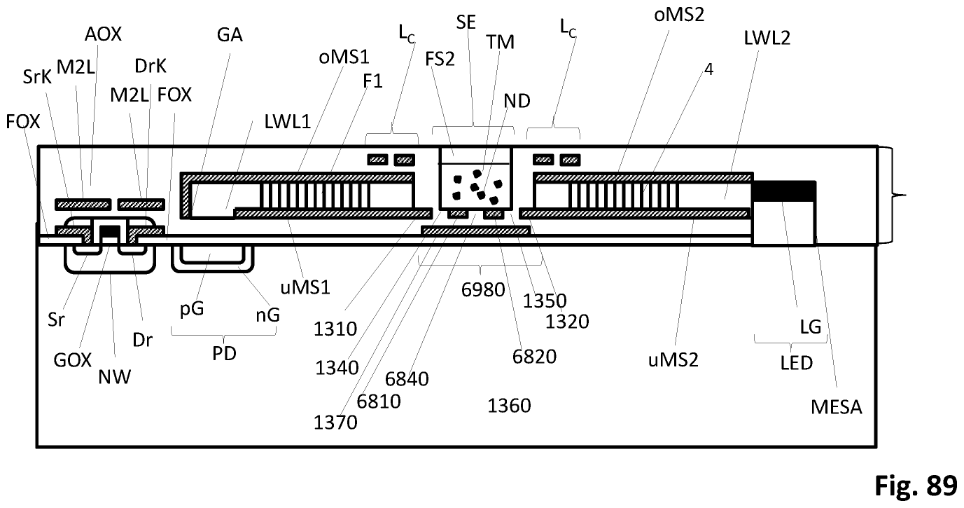

### FIG. 89

FIG. 89 shows a schematic and roughly simplified sectional view of an exemplary system to illustrate the content of the preceding proposal when applied to a CMOS microelectronic circuit. The basis of the exemplary device is the carrier substrate 1360, which in the example of FIG. 89 is a silicon wafer (generally referred to as a chip or die) with a p-type conductivity, as is common today in MOS, CMOS, BICMOS and bipolar technology. The explanations here can of course also be transferred to bipolar technology.

### Integrated Formwork as Carrier Substrate 1360

Before the crystals and/or diamond nano crystals ND with paramagnetic centers and/or NV centers were introduced, an exemplary MOS or CMOS or BICMOS or a bipolar process and/or another semiconductor process was carried out with the exemplary carrier substrate 1360, in this case the exemplary silicon wafer. In this process, an exemplary microelectronic circuit with at least one microelectronic component was fabricated on the exemplary silicon wafer and thus on the exemplary carrier substrate 1360. As a result of this manufacturing step, this became a MOS wafer or a CMOS wafer or a BICMOS wafer or a bipolar wafer. A single exemplary MOS transistor is shown schematically in simplified form to symbolize such a microelectronic circuit. FIG. 89 does not show a more complex circuit diagram in order to maintain clarity. A knowledgeable person can directly read a large number of possible components and circuits here. For example, a bipolar transistor or similar components such as thyristors and the like can also be imagined there. This simplified representation is intended to ensure that the basic principle is clear without confusing details. The simplified representation is intended to express the co-integration of a microelectronic circuit with the crystal and/or diamond nano crystals ND with the paramagnetic centers and/or in particular NV centers. Unfortunately, it is not possible to illustrate functionality here due to the complexity of the representation then required, but this does not reduce the content of the disclosure.

### Example MOS Transistor

In this example, the exemplary MOS transistor comprises an N-well NW in the carrier substrate 1360. The exemplary MOS transistor shown comprises a source region Sr, a drain region Dr, a source contact SrK for contacting the source region Sr, a drain contact DrK for contacting the drain region Dr, a gate oxide GOX, a field oxide FOX, a covering oxide AOX and a gate GA. The metallization stack of the micro integrated circuit is located above these microelectronic components. The metallization stack of the micro integrated circuit preferably comprises a plurality of structured insulation layers and a plurality of structured electrically conductive layers, in particular metallization layers, which fabricate the electrical connections. For example, a metallization layer is indicated by a second electrically upwardly and downwardly insulated and structured second metal layer M2L. In reality, MOS, CMOS, BICMOS and bipolar structures are much more complicated. They typically comprise, for example, several layers of electrically conductive metal and/or polycrystalline silicon and typically several insulation layers, e.g. of SiO₂ and contacts and through hole contacts.

The second optical waveguide LWL2 couples the light-emitting region LG of the mesa structure MESA, which forms the light source LED of the sensor system, to the sensor element Se, which is located here in the micro-mechanical recess of the second trap structure FS2 and which here again comprises crystals and/or diamond nano crystals ND with paramagnetic centers and/or NV centers. The second lower metal shield uMS2 of the second optical waveguide LWL2 shields the second optical waveguide LWL2 downwards to the carrier substrate 1360 as optical shield ME. The second upper metal shield oMS2 of the second optical waveguide LWL2 shields the second optical waveguide LWL2 upwards to the surface of the carrier substrate 1360 as optical shield ME. The second optical waveguide LWL2 detects the pump radiation LB of the light-generating area LG in its function as light source LED and transports the pump radiation LB to the sensor element SE. Preferably, this optical transport path comprises an optical filter (short pass) 4, which is inserted into the second optical waveguide LWL2 and which does not transmit electromagnetic waves that do not comprise the pump radiation wavelength λₚₘₚ and only transmits electromagnetic radiation with the pump radiation wavelength λ₍ₚₘₚ₎.

The first optical waveguide LWL1 detects the fluorescence radiation FL of the paramagnetic centers and/or NV centers of the sensor element SE and transports the fluorescence radiation FL to the photo detector PD. In the example of FIG. 89, the photo detector PD is exemplarily designed as a PN junction between a p-doped region pG and an n-doped region nG. The photo detector PD can also be other photo detectors such as CCD detectors, for example, a filter F1 is inserted into the first optical waveguide LWL1 which essentially only transmits electromagnetic radiation of the fluorescence wavelength λ_{fl} of the fluorescence radiation FL and which preferably essentially absorbs or reflects electromagnetic radiation of a wavelength different from the fluorescence wavelength λ_{fl} of the fluorescence radiation FL. This ensures that, for example, the pump radiation LB with the pump radiation wavelength λₚₘₚ cannot reach the photo detector PD. The first lower metal shield uMS1 of the first optical waveguide LWL1 shields the first optical waveguide LWL1 downwards to the carrier substrate 1360 as an optical shield ME. The first upper metal shield oMS1 of the first optical waveguide LWL1 shields the first optical waveguide LWL1 upwards to the surface of the carrier substrate 1360 as optical shield ME.

Preferably, the microelectronic circuit on and/or in the carrier substrate 1360 comprises device parts of systems disclosed herein, such as those of FIGS. 69 to 71 and/or those of FIGS. 73 to 81. Such device parts that the microelectronic circuit on and/or in the carrier substrate 1360 may comprise, for example:

the evaluation device (AWV, 30), control devices (CTR, CTR2, 33), data buses (DB, 29), driver stages DRVL, signal generators (G1, G1_1, G1_2, G1_3, G2, G2_I, G2_II, G2_III, G2_IV), magnetic field generation means (L_{C}, L_{C}_3, L_{C}_2, L_{C}_3, L_{C}_4, L_{C}_5), magnetic field controllers LCTR, light source drivers (LDRV, LDRV_1, LDRV_2, LDRV_3, LDRV_4, LDRV_5), light sources (LED, LED_1, LED_2, LED_3, LED_4, LED_5, 2), multiple correlators (LIV, LIV_1, LIV_2, LIV_3, LIV_4, LIV_5), multipliers (M1, M2), pattern recognition device MEV, magnetic field sensors MS, microwave signal sources (μWG, μWG_I, μWG_II, μWG_III, μWG_IV), memory (RAM, NVM), photo detectors (PD, PD_1, PD_2, PD_3, PD_4, PD_5), radio wave sources RFG, amplifiers (V1, V1_1, V1_2, V1_3, V1_4, V1_5), light sensor arrays 1, evaluation electronics 15, processing devices 30, interface circuits 36, etc.

Preferably, the microelectronic circuit also comprises, for example, a voltage regulator for supplying the microelectronic circuit and possibly its subcomponents and/or for supplying a pump radiation source, the light source LED, for exciting the emission of the fluorescence radiation FL of the paramagnetic centers of the crystals and/or the diamond nano crystals ND of the sensor elements SE and/or the sensor element layers 5 by means of pump radiation LB. However, a suitable micro-optical system must, on the one hand, be able to stimulate the paramagnetic centers of the crystals and/or the diamond nano crystals ND of the sensor elements SE and/or the sensor element layers 5 by means of pump radiation LB and, on the other hand, be able to detect the fluorescence radiation FL of the paramagnetic centers of the crystals and/or the diamond nano crystals ND of the sensor elements SE and/or the sensor element layers 5 and reliably separate it from the pump radiation LB of the pump radiation source, in this case the light source LED. For this purpose, it is useful if the micro-electro-optical system comprises micro-optical components that are micro-technically fabricated in a corresponding process step. Optical filters (F1, 3) and optical waveguides (LWL1, LWL2) are particularly important here.

At this point, the document presented here refers to the books Baha E.A. Saleh, Malvin Carl Teich, “Grundlagen der Photonik “Wiley-VCH, 2007 and Bernhard C. Kress, Patrick Meyreueis “Applied Digital Optics” Wiley, 2009 as examples.

In addition, the document presented here comprises references to other descriptive parts of this document which also deal with microelectronic systems and/or circuits and which, in this context, therefore also provide important information on this section which, in combination with the technical teacher of this section, is also disclosed here.

The document presented here therefore refers to the relevant state of the art for microelectronic circuits.

### First Micro-Optical Optical Waveguide LWL1 and Sensor Element SE

The illustrative structure of the device of FIG. 89 comprises exemplary micro-optical components in the form of exemplary optical waveguides (LWL1, LWL2). These exemplary optical waveguides (LWL1, LWL2) are intended to interact with the multiplicity of paramagnetic centers in the multiplicity of crystals and/or diamond nano crystals ND with NV centers and/or paramagnetic centers in the illustrative example of FIG. 89. Preferably, the diamond nano crystals ND may be nano-diamonds having NV centers as paramagnetic centers. The colloidal varnish KL with substrate material TM and crystals and/or diamond nano crystals ND has been placed in the recess of the second trap structure FS2. The colloidal varnish KL covers the surface of the device in the region of the trap structure FS2 in order to fix the position of the crystals and/or diamond nano crystals ND in the recess of the second trap structure FS2. After curing, the substrate material TM of the colloidal varnish KL must be sufficiently transparent for the pump radiation LB to be used and the fluorescence radiation FL of the paramagnetic centers of the crystals and/or diamond nano crystals ND to be used. The second trap structure FS2 is preferably filled with the substrate material TM of the colloidal varnish KL. In the example of FIG. 89, the layer of the colloidal varnish KL comprising substrate material TM and crystals and/or diamond nano crystals ND has been limited to the region of the trap structure FS2 by photolithography and/or by a self-adjusting curing process. This has the advantage that B electrical contacts of the integrated circuit can preferably be exposed again more easily.

The exemplary device described herein by way of illustration comprises a first optical waveguide structure LWL1, the material of which may comprise, for example, a sputtered SiO₂ material or the material of another transparent oxide and/or an optical transparent insulation layer of the metallization stack applied to the surface of the carrier substrate 1360. Preferably, light emission to other regions of the circuit has been previously prevented by a first portion of a first metal shield uMS1 downwardly toward the carrier substrate 1360. Preferably, the first optical fiber structure LWL1 was photolithographically structured and exemplarily covered with a first section of a second metal shield oMS1 towards the top to reduce optical crosstalk and to improve the signal-to-noise ratio. It is recommended to precisely simulate the workability of such a design with an FDTD simulation before fabrication for the process parameters used, as light propagation, for example, is no longer possible if the dimensions are too small. In the same way, a second optical fiber structure LWL2 was manufactured, which is preferably comprised of a second section of the first metal shield uMS2 and a second section of the second metal shield oMS2.

### MESA Structure as a Light Source

In the example of FIG. 89, an exemplary light source is provided. This comprises here, by way of example, an exemplary MESA structure (LED), which is preferably and exemplarily insulated from the planar substrate. Instead of a MESA structure MESA, other silicon LEDs or other light sources can also be used as the light source LED of the device. In this light-generating MESA structure MESA, a light-emitting region is typically manufactured as a light source LED. In this context, reference is made to the following document with regard to the manufacture of a light source LED in indirect semiconductors such as silicon:

Röcke H., Meijer J., Stephan A., Weidenmüller U., Bukow H. H., Rolfs C. “White electroluminescent nanostructure in silicon fabricated using focused ion implantation” Nuclear Instruments and Methods in Physics Research B 181 (1001) page 274-279.

The special feature of using a MESA structure MESA is that it emits a wavelength range in the necessary wavelength range of the pump radiation wavelength λₚₘₚ of the pump radiation LB. Unfortunately, the MESA structure MESA also emits other wavelengths, so that the use of an optical bandpass filter 4 appears necessary.

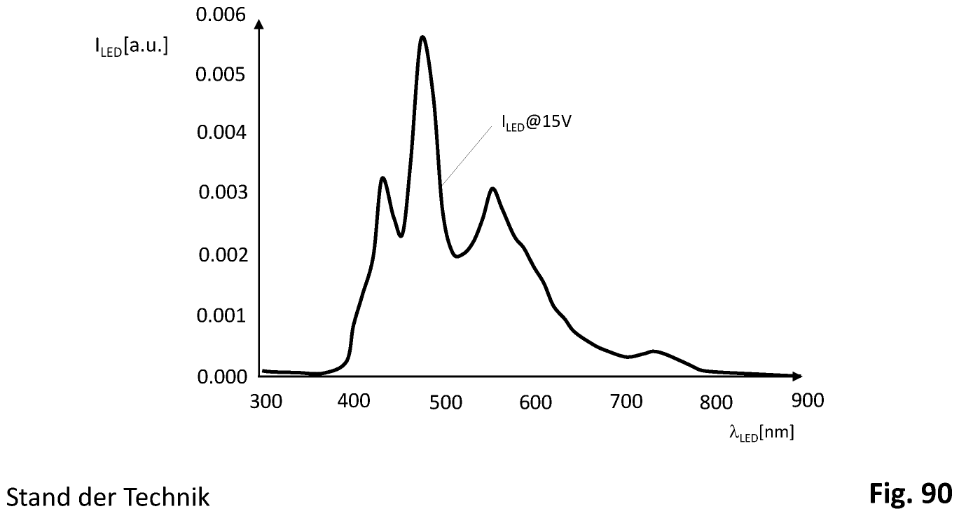

FIG. 90 shows the exemplary emission spectrum of such a MESA structure MESA as light source LED. Experiments have shown that the optical bandpass filter 4 should be inserted into the second optical waveguide LWL2 in order to limit the optical transmission in the direction of the crystals and/or the diamond nano crystals ND with the paramagnetic centers or NV centers to the pump radiation LB of the pump radiation wavelength pmp and not to transmit electromagnetic radiation from the light source LED with shorter and longer wavelengths.

If a light source LED is used that essentially only emits electromagnetic radiation of the pump radiation wavelength λₚₘₚ, the optical bandpass filter 4 can be dispensed with.

In the example of FIG. 89, such a light source LED with the light-emitting region LG is used to pump the paramagnetic centers or NV centers of the crystals and/or diamond nano crystals ND via the first optical waveguide LWL1 after bandpass filtering in the optical bandpass filter 4 and to excite them to emit fluorescence radiation FL.

For example, an optical bandpass filter 4 is inserted into the first optical waveguide LWL1, which essentially allows electromagnetic radiation with a pump radiation wavelength λₚₘₚ to pass through and essentially attenuates electromagnetic radiation of other wavelengths, in particular the fluorescence radiation wavelength λ_{(fl)}, to such an extent that they no longer play a role for the respective application.

### Second Optical Waveguide LWL2 and Photo Detector PD

In the example shown in FIG. 89, the second optical waveguide LWL2 detects the fluorescence radiation FL and directs it to a photo detector PD of the microelectronic circuit.

As an example, an optical filter F1 is inserted into the second optical waveguide LWL2, which essentially allows electromagnetic radiation with fluorescence radiation wavelength λ_{fl} to pass through and essentially attenuates electromagnetic radiation of other wavelengths, in particular the pump radiation wavelength λ₍ₚₘₚ₎, to such an extent that they no longer play a role for the respective application.

Preferably, the optical filter F1 and the optical bandpass filter 4 are designed as micro-optical functional elements, for example as a dielectric layer sequence and/or as a photonic crystal. The document presented here recommends FDTD simulations to check the selected designs, whereby the manufacturing tolerances should definitely also be simulated.

In this illustrative example of FIG. 89, the exemplary photo detector PD comprises an exemplary PN diode comprising an N-well nG and a P cathode pG.

### Microtechnical Functional Elements

Numerous light-sensitive microelectronic components are known from the prior art, which can be manufactured using the aforementioned MOS, CMOS, BICMOS and bipolar processes in particular. In order to keep the complexity of the embodiment low and transparent, FIG. 89 has been simplified to such an extent that a person skilled in the art can recognize which exemplary elements can be combined and how and can interact in an exemplary manner. The numerous micro-fluidic, micro-mechanical, micro-optical and micro-electronic functional elements known in the prior art can also be combined in similar devices using the method proposed herein. For example, Bragg filters and mirror structures can be provided in the optical waveguides (LWL1, LWL2).

### Microtechnical Device and Waveguide

In contrast to the prior art, the proposal presented here provides for a waveguide (1380, 1880, 2380, 6830, 6980), here an exemplary differential trip-plate waveguide 6980, to be placed above or, as here, below the sensor element SE. The differential trip-plate waveguide 6980 again comprises the electrically conductive backside contact 1370, the electrically conductive left signal ground plane 1310, the electrically conductive right signal ground plane 1320 and the differential signal line 6830 with the electrically conductive left signal line 6810 and the electrically conductive right signal line 6820. The differential trip-plate waveguide 6980 is only one example of a waveguide. The exemplary micro integrated circuit of FIG. 89 may instead also comprise a micro strip line 1380 and/or a slot line 1880 and/or a trip-plate waveguide 2380 and/or a differential micro strip line 6830 and/or another waveguide, in particular a planar waveguide, interacting with a sensor element SE and/or a sensor element layer 5. In the preceding figures, various positioning of different sensor elements SE with respect to device portions of waveguides have been discussed. Such a micro integrated circuit may comprise one or more sensor elements SE, which may be positioned differently with respect to the device parts of said wave guides, and which may have different sizes relative to the device parts of the waveguides. These different sizes of the sensor elements SE have also been discussed in the preceding figure descriptions and are therefore not repeated here. However, they are hereby deemed disclosed in the context of use in micro integrated circuits as defined herein.

### Microelectronic System

Preferably, the system thus comprises a microelectronic circuit or at least one microelectronic component, in particular a photo detector PD and/or a light-emitting component as light source LED. More specifically, the system preferably comprises a microelectronic MOS, CMOS, BICMOS or bipolar circuit or at least one microelectronic MOS or CMOS or BICMOS or bipolar component, in particular a photo detector and/or a light-emitting component. In the case of a CMOS technology, this is preferably a CMOS photo detector, e.g. a CCD pixel or a CCD pixel array and/or a light-emitting CMOS component, whereby a CMOS component is characterized in that it has been manufactured using a CMOS technology. The microelectronic circuit is preferably manufactured at least in part in MOS or CMOS or BICMOS or bipolar technology.

The microelectronic circuit may have a multiplicity of circuit elements, some of which may interact with the sensor element. The document presented here only lists a few by way of example:
Analog-to-digital converter (ADC): Converts analog input signals into digital signals;
Digital-to-analog converter (DAC): Converts digital input signals into analog signals;
Operational amplifier (OPV): Amplifies and amplifies analog signals;
Voltage references: Generate stable reference voltages for circuit operation;
Amplifier: Amplifies analog signals with different amplification factors;
Filter: Filters unwanted frequencies from a signal (e.g. low pass, high pass or band pass filter);
Oscillators: Generates periodic waveforms or clock signals;
Multiplexer (MUX) and demultiplexer (DEMUX): Switch between different input signals or distribute an input signal to several outputs;
Phase-locked loops (PLL): Generates stabilized clock signals based on a reference clock;
Delay elements: Enable the timing of signals;
Comparators: Compares two input signals and provides an output according to the result of the comparison;
Buffer amplifier: Amplifies the signal without changing its characteristics;
Voltage regulator: Stabilizes the output voltage, regardless of fluctuations in the input voltage or load changes;
Clock generators: Generates clock signals with defined frequencies and phase shifts;
Data buffer: Stores data and enables time-delayed transfer;
Circuit monitoring: Monitors the operating conditions of the circuit and protects it from damage;
Serial communication interfaces: Enable communication between different components or devices via serial data transmission;
Power drivers: Amplify the signal for driving high-performance components such as motors or actuators;
Circuit logic: Contains logical elements such as AND, OR, NAND, and XOR gates for performing digital calculations and logic operations;
Memory: Comprises various types of memory modules such as flip-flops, latches or registers for storing data
Clock and phase-locked loops (PLL): Generates precise and stable clock signals based on a reference clock and enables the synchronization of signals;
Analog switch: Switches analog signals between different paths or channels;
Pulse width modulation (PWM): Modulates the width of pulses to control the power or the ratio of switch-on time to switch-off time of a signal;
Signal processing units (DSP): Specialized digital signal processors for the processing and analysis of analog and digital signals;
Voltage divider: Divides an input voltage into two or more output voltages;
Temperature sensors: Detecting and measuring the temperature in the environment or in a component;
Current sources and current sinks: Generate constant current or absorb current in a circuit;
Protective circuits: Monitor and protect the circuit against overvoltage, undervoltage, overtemperature or short circuit;
Level converter: Translates signals between different voltage levels or logic levels;
Impedance converter: Adjusts the impedance between different parts of a circuit to enable optimum signal transmission;
Voltage regulators: Stabilize the output voltage to a predefined value, regardless of fluctuations in the input voltage or load changes;
Current measurement: Enables the current in a circuit section or component to be measured;
Digital Signaling Interface (DSI): A high-speed serial bus for transferring data between integrated circuits;
Analog loop filter: Filters unwanted interference signals from an analog input signal;
Energy detection: Detecting and measuring the energy consumption in a circuit or system;
Error correction: Uses error correction codes and algorithms to detect and correct transmission errors in digital signals;
Data converter: Converts data from one format to another, e.g. serial to parallel or vice versa;
Amplifier with variable gain: Offers the possibility to dynamically adjust the gain factor of an amplifier;
Band gap references: Generates a stable reference voltage independent of temperature changes;
Pulse width modulation (PWM): Modulates the pulse width of a signal to transfer analog information or to control the power of circuits;
Clock distribution: Distributes clock signals to different parts of a circuit or system.
Clock cleaner: Filters interference and noise from a clock signal;
Sensor interfaces: Integrated interfaces for various sensors such as temperature sensors, pressure sensors, acceleration sensors, etc.;
Circuit models: Describes mathematical models for analyzing and simulating mixed-signal circuits;
Digital signal processing (DSP): Processes digital signals using mathematical algorithms such as filtering, spectral analysis, signal modulation, etc.;
Phase detectors: Compares the phase relationship between two signals and generates an output voltage corresponding to the phase difference;
Digital control logic: Controls the functions and operation of the circuit on the basis of digital input signals;
Voltage multipliers: Generates a higher output voltage than the input voltage by repeatedly charging and discharging capacitors;
Error detection and correction (ECC): Identifies and corrects errors in digital data by adding redundancy information;
Programmable logic: Contains programmable logic devices such as FPGAs (Field-Programmable Gate Arrays) or CPLDs (Complex Programmable Logic Devices) to enable flexible circuit functionalities;
Data buffer: Temporarily stores data to enable a temporal separation between input and output;
Clock generator: Generates clock signals with specific frequencies and phase shifts;
Battery management: Monitors and controls the charge status and performance of batteries;
Digital filter: Filters unwanted frequencies or noise from digital signals;
Phase shift networks: Introduces phase shifts in a signal to achieve specific temporal relationships;
Signal isolators: Galvanically isolates signals to minimize electrical interference;
Pulse generators: Generates pulses or short signals for specific applications;
Spectrum analyzers: Analyzes and visualizes the frequency spectrum of a signal;
Real-time clock (RTC): Enables accurate time measurement and maintenance of a real-time clock during power failure;
Multipoint modulation: Combines several digital signals in one modulation scheme;
Display driver: Controls the control of display elements such as LCDs or LED displays;
Hysteresis comparators: Compares input signals with a threshold and generates an output voltage that is dependent on the hysteresis;
Analog loop compensators: Compensates for errors in feedback loops of analog circuits to improve stability and accuracy;
Programmable amplifiers: Allows the amplifier factor or amplification function to be adjusted via a digital interface;
Clock multiplexer: Selects between different clock signals and forwards them for further processing;
High-voltage driver: Amplifies and drives high-voltage signals, for example for the control of power transistors;
I/O interfaces: Establishes communication and data exchange with external devices or interfaces;
Logic monitoring: Monitors and controls the logic levels in a circuit to ensure reliable signal processing;
Data Encoding/Decoding: Encodes and decodes data for efficient transfer or storage; and
Load driver: Controls the output of power to external components or loads.

Preferably, the microelectronic circuit on and/or in the carrier substrate 1360 comprises device parts of systems disclosed herein, such as those of FIGS. 69 to 71 and/or those of FIGS. 73 to 81. Such device parts that the microelectronic circuit on and/or in the carrier substrate 1360 may comprise may include, for example:

the evaluation device (AWV, 30), control devices (CTR, CTR2, 33), data buses (DB, 29), driver stages DRVL, signal generators (G1, G1_1, G1_2, G1_3, G2, G2_I, G2_II, G2_III, G2_IV), magnetic field generation means (L_{C}, L_{C}_3, L_{C}_2, L_{C}_3, L_{C}_4, L_{C}_5), magnetic field controllers LCTR, light source drivers (LDRV, LDRV_1, LDRV_2, LDRV_3, LDRV_4, LDRV_5), light sources (LED, LED_1, LED_2, LED_3, LED_4, LED_5, 2), multiple correlators (LIV, LIV_1, LIV_2, LIV_3, LIV_4, LIV_5), multipliers (M1, M2), pattern recognition device MEV, mixer MIX, magnetic field sensors MS, microwave signal sources (μWG, μWG_I, μWG_II, μWG_III, μWG_IV), memory (RAM, NVM), photo detectors (PD, PD_1, PD_2, PD_3, PD_4, PD_5), radio wave sources RFG, amplifiers (V1, V1_1, V1_2, V1_3, V1_4, V1_5), light sensor arrays 1, evaluation electronics 15, processing devices 30, interface circuits 36, etc.

Preferably, the microelectronic circuit also comprises, for example, a voltage regulator for supplying the microelectronic circuit and possibly its subcomponents and/or for supplying a pump radiation source, the light source LED, for exciting the emission of the fluorescence radiation FL of the paramagnetic centers of the crystals and/or the diamond nano crystals ND of the sensor elements SE and/or the sensor element layers 5 by means of pump radiation LB. However, a suitable micro-optical system must, on the one hand, be able to stimulate the paramagnetic centers of the crystals and/or the diamond nano crystals ND of the sensor elements SE and/or the sensor element layers 5 by means of pump radiation LB and, on the other hand, be able to detect the fluorescence radiation FL of the paramagnetic centers of the crystals and/or the diamond nano crystals ND of the sensor elements SE and/or the sensor element layers 5 and reliably separate it from the pump radiation LB of the pump radiation source, in this case the light source LED. For this purpose, it is useful if the micro-electro-optical system comprises micro-optical components that are micro-technically fabricated in a corresponding process step. Optical filters (F1, 3) and optical waveguides (LWL1, LWL2) are particularly important here.

At this point, the document presented here refers to the books Baha E.A. Saleh, Malvin Carl Teich, “Grundlagen der Photonik “Wiley-VCH, 2007 and Bernhard C. Kress, Patrick Meyreueis “Applied Digital Optics” Wiley, 2009 as examples.

The proposed method thus preferably comprises a step of performing a method for the fabrication of micro-optical devices on the semiconductor substrate.

### For the Co-Integration of Suitable Light-Emitting Components

As already indicated, light-emitting components in standard silicon technologies for the fabrication of microelectronic circuits pose a particular problem. Either a material made from a semiconductor with a direct junction, such as GaAs or another suitable III/V material, is used as the semiconductor substrate, whereby the light-emitting components (light sources LED) for the generation of the pump radiation LB for the excitation of the fluorescence radiation FL of the paramagnetic centers of the crystals and/or the diamond nano crystals ND of the sensor elements SE and/or the sensor element layers 5 can be manufactured directly on the wafer, or a material made of a semiconductor with an indirect transition, such as silicon or diamond, is used as the semiconductor substrate. With regard to the production of light sources LED in diamond, the document presented here refers by way of example to the following document:

Burchard B., “Elektronische und optoelektronische Bauelemente und Bauelementstrukturen auf Diamantbasis” Dissertation, Hagen 1994.

With regard to the generation of light sources LED in silicon, the document presented here refers again to the following journal article already mentioned as an example:

Röcken H., Meijer J., Stephan A., Weidenmüller U., Bukow H.H., Rolfs C., “White electroluminescent nanostructure in silicon fabricated using focused ion implantation” Nuclear Instruments and Methods in Physics Research B 181 (1001) page 274-279.

This document deals with a PNP or NPN MESA structure MESA, in which the center doping is extremely high and very narrow. The authors of the document are of the opinion that this is a component in avalanche breakdown. The light energy is emitted in the form of a thermal spectrum by the hot electrons. In an NPN structure, the microelectronic circuit applies a relatively high voltage between the contact of the first N region and the contact of the second N region. A breakdown occurs. A current is injected into the base through the breakdown of the base-collector path. The extremely highly doped and very narrow base switches through so that the transistor suddenly switches through extremely quickly. The parts of the base-collector capacitance in the vicinity of the PN junction are suddenly discharged. This results in an electromagnetic wave in the base, which is focused by the high doping and the resulting refractive index jump. If a “+” is to symbolize high doping, the use of a PN+P structure or an NP+N structure is therefore suggested here. So-called silicon avalanche-based light-emitting diodes are known from the literature in particular, which perform similarly but typically emit in the infrared wavelength range. (K. Kurokawa, “Avalanche Breakdown Electroluminescence in Silicon Carbide Light Emitting Diodes”, January 2000Materials Science Forum 338-342:691-694, DOI: 10.4028/www.scientific.net/MSF.338-342.691) These are therefore not suitable as pump radiation sources.

On the basis of such a PN+P structure or an NP+N structure or such a silicon avalanche-based light-emitting diode, a quantum technological, micro-electro-optical or photonic or microelectronic system in MOS, CMOS, BICMOS or bipolar technology, or another suitable wafer manufacturing technology, is then obtained. Said system then comprises a carrier substrate 1360, which may in particular be made of an indirect semiconductor such as silicon and comprises a surface OF. Preferably, the carrier substrate 1360 a silicon avalanche-based light-emitting diode or a PN+P structure or an NP+N structure or a semiconducting MESA structure (MESA) MESA for light generation. This silicon avalanche-based light-emitting diode, PN+P structure, NP+N structure or semiconducting MESA structure (MESA) MESA serves here as a light-emitting microelectronic component that can be used, for example, as a pump light source, in this case the light source LED, for the excitation of a paramagnetic center. The MESA structure MESA is preferably insulated from the substrate and comprises a first region (E) of the MESA structure (MESA), a second region (B) of the MESA structure (MESA) and a third region (C) of the MESA structure (MESA). The quantum technological, micro-electro-optical or photonic or microelectronic system further comprises at least a plurality of crystals and/or diamond nano crystals ND with at least a multiplicity of preferably identical paramagnetic centers, in particular NV centers. At least one micro-optical functional element, in particular an optical waveguide LWL2, which is fabricated in the carrier substrate 1360 or on the surface OF of the carrier substrate 1360, preferably couples said light-emitting components in or on the carrier substrate 1360 to one or more paramagnetic centers so that they can be pumped or otherwise optically manipulated. Preferably, an optical bandpass filter 4 is integrated into the micro-optical functional element, in particular the second optical waveguide LWL2, which preferably essentially transmits the pump radiation LB with pump radiation wavelength λₚₘₚ. For the purposes of the present document, the carrier substrate 1360 then comprises the micro-optical functional element, in this case the second optical waveguide LWL2. Here, the second optical waveguide LWL2 is preferably fixedly connected to the substrate 1360 in its longitudinal extension in whole or in large parts. The first region (E) and the third region (C) of the MESA structure MESA, if used, preferably comprise a first conductivity type. The second region (B) of the MESA structure MESA, if used, preferably comprises a second conductivity type which is different from the first conductivity type and the second region (B) is arranged between the first region (E) and the second region (C). The MESA structure (MESA) MESA is preferably a PNP or NPN MESA structure MESA, wherein the width of the second region (B) is preferably less than 3 μm and/or less than 1 μm and/or less than 500 nm and/or less than 200 nm and/or less than 100 nm and/or less than 50 nm and/or less than 25 nm and/or less than 10 nm. If the doping is sufficiently high, the second region (B) is then suitable for emitting light when a sufficiently high electrical voltage is applied. An exemplary spectrum is shown in FIG. 90. Coupling with an optical functional element then documents that the MESA structure MESA is intended to emit light. The light emitted by the second region (SE) then interacts with paramagnetic centers of the crystals and/or the diamond nano crystals ND of the sensor element SE and/or the sensor element layer 5 by means of said micro-optical functional element, in this case the second optical waveguide LWL2.

The carrier substrate 1360 is preferably a semiconductor substrate or a silicon wafer or a GaAs wafer or a wafer of a III/V material or a wafer of a II/VI material or a wafer treated by means of band-gap engineering or a diamond wafer or a Ge wafer or another wafer of a mixed semiconductor or a part of such a wafer.

There is thus proposed in the present disclosure a quantum technological, micro-electro-optical or photonic system comprising a carrier substrate 1360, in particular a semiconductor substrate. The particular feature of the proposal here is that the entire system, with the exception of the crystals and/or diamond nano crystals ND, may be made of an indirect semiconductor material. A microelectronic circuit is typically fabricated in and/or on the semiconductor material, preferably in a MOS, CMOS, BICMOS, or bipolar technology. The microelectronic circuit preferably comprises a plurality of components such as transistors, diodes, resistors, capacitors, light-sensitive and possibly light-emitting electronic components. Such a light-sensitive component, for example a photo detector PD, of said microelectronic circuit, for example for detecting the intensity Iᵢₛₜ of the fluorescence radiation FL of the paramagnetic centers of the crystals and/or the diamond nano crystals ND, which preferably comprise a diamond and NV center, can for example be a PN diode as light-sensitive electrical component, as photo detector PD, which is part of the microelectronic circuit. A light-emitting device can be, for example, a MESA structure MESA as described herein. The quantum technological, micro-electro-optical or photonic system preferably comprises a partial area of a colloidal film or colloidal varnish KL as sensor element SE and/or sensor element layer 5, which comprises several crystals and/or diamond nano crystals ND with paramagnetic centers. A variant in which the carrier substrate 1360 is a microelectronic circuit, in particular a microelectronic circuit in MOS, CMOS, BICMOS or bipolar technology, is particularly preferred. Typically, the carrier substrate 1360 then comprises materials such as pieces of board materials or pieces of plastic sheet or film and/or pieces of glass wafers or pieces of ceramic wafers and/or pieces of semiconductor wafers, for example pieces of CMOS wafers or for example pieces of BiCMOS wafers and/or for example pieces of wafers from a bipolar technology and/or pieces of a wafer from a III/V material or the like and/or for example pieces of MEMS wafers and/or pieces of microelectronic circuits and/or for example pieces of MEOS wafers (MEOS=micro electro optical system) and/or for example pieces of MOEMS wafers, etc. and/or pieces of MOEMS wafers microelectronic circuits and microelectronic functional elements and/or micro-optical functional elements and/or micro-mechanical functional elements and/or micro-fluidic functional elements.

Such a microelectronic circuit, which is typically manufactured in the carrier substrate 1360, comprises as preferred a plurality of microelectronic components, such as MOS transistors, bipolar transistors, diodes, resistors, capacitors, coils and possibly further semiconductor components, which are manufactured in the carrier substrate 1360 and in particular in the metallization stack, and are interconnected to the microelectronic circuit by lines, which are optically coupled to the paramagnetic centers of the crystals and/or the diamond nano crystals ND, which preferably comprise diamond and/or NV centers, to form an overall system. In this context, the carrier substrate 1360 preferably comprises at least one micro-optical functional element, for example a first optical waveguide LWL1 and the microelectronic circuit in MOS, CMOS, BICMOS, or bipolar technology. Typically, the carrier substrate 1360 also comprises the light-sensitive electrical component (nG, pG), the photo detector PD, in order to detect, preferably by means of this light-sensitive electrical component (pG, nG), the photo detector PD, an emission of fluorescence radiation FL of the paramagnetic centers, in particular of NV centers, of the crystals and/or diamond nano crystals ND. Typically, at least one operating parameter of the microelectronic circuit then depends on a value of the intensity I (ist) of the fluorescence radiation FL of the paramagnetic centers of the crystals and/or diamond nano crystals ND of the sensor elements SE and/or the sensor element layer 5 detected by the light-sensitive component (pG, nG), the photo detector PD. The paramagnetic centers of the crystals and/or diamond nano crystals ND of the sensor elements SE and/or the sensor element layer 5 are preferably coupled to the light-sensitive electrical component (pG, nG), the photo detector PD, via the first micro-optical functional element LWL1. Preferably, the first optical functional element and/or the second optical functional element are partially or completely identical. However, FIG. 89 shows different optical functional elements by way of example. However, such a quantum technological, micro-electro-optical or photonic or microelectronic system can also be manufactured on a carrier substrate 1360 made of a direct semiconductor material. This has the advantage that the luminous efficacy of the light-emitting components of the system is higher when used as light sources LED and thus a better pump radiation LB can be achieved, which increases the contrast between the intensity Iᵢₛₜ of the fluorescence radiation FL of the paramagnetic centers of the crystals and/or diamond nano crystals ND of the sensor elements SE and/or the sensor element layer 5 at the magnetic flux density with maximum intensity Iᵢₛₜ of the fluorescence radiation FL of the paramagnetic centers of the crystals and/or diamond nano crystals ND of the sensor elements crystals ND of the sensor elements SE and/or the sensor element layer 5 and the intensity Iᵢₛ of the fluorescence radiation FL of the paramagnetic centers of the crystals and/or diamond nano crystals ND of the sensor elements SE and/or the sensor element layer 5 at the magnetic flux density with minimum intensity Iᵢₛ of the fluorescence radiation FL of the paramagnetic centers of the crystals and/or diamond nano crystals ND of the sensor elements SE and/or the sensor element layer 5. Preferably, substrate materials of the carrier substrate 1360 are then used, in which a semiconductor material of the substrate may be a III/V semiconductor material and/or a II/VI semiconductor material or a semiconductor material fabricated by bandgap engineering. The substrate material of the carrier substrate 1360 therefore expressly does not have to be homogeneous, but can consist of different materials. The system then comprises a micro-electronic circuit, which can preferably be part of the carrier substrate 1360, and an electrical component, which is preferably part of the micro-electronic circuit, and a micro-optical sub-device (LWL1, LWL2), which is preferably part of the carrier substrate 1360, and a plurality of crystals and/or diamond nano crystals ND, which may be diamonds, with paramagnetic centers of the crystals and/or diamond nano crystals ND of the sensor elements SE and/or the sensor element layer 5. In the case presented here, the carrier substrate 1360 thus comprises the microelectronic circuit and the electrical component and the micro-optical device (LWL1, LWL2). The special feature of the system is then that it comprises at least one light-emitting electro-optical component MESA, preferably as a light source LED, which is part of the carrier substrate 1360 or is manufactured on the surface of the carrier substrate 1360, wherein the carrier substrate 1360 comprises the light-emitting component MS as light source LED and wherein the light-emitting electro-optical component MESA as light source LED interacts optically with the micro-optical subdevice (LWL1, LWL2). The light-emitting electro-optical component MESA interacts as a light source LED with the electrical component electrically and/or optically in a direct or indirect manner by means of the micro-optical sub-device (LWL1, LWL2). This interaction between the light-emitting electro-optical component MESA as light source LED with the electrical component preferably takes place with the interaction of the paramagnetic centers of the crystals and/or diamond nano crystals ND of the sensor elements SE and/or the sensor element layer 5.

In the case presented here, the carrier substrate 1360 is thus preferably a semiconductor substrate, a silicon wafer or a GaAs wafer or a wafer made of a III/V material or a wafer made of II/VI material or a wafer treated by means of band-gap engineering or a diamond wafer or a Ge wafer or another wafer made of a mixed semiconductor.

In the case of III/V materials, the substrate can also comprise another LED or a laser as the light source LED.

Preferably, the quantum technological, micro-electro-optical or photonic system comprises at least one micro-optical element. Preferably, the micro-optical element is suitable or intended to fulfill at least the function of one of the following micro-optical elements:
the function of an optical lens;
the function of a photonic crystal;
the function of an optical filter;
the function of an optical fully or partially reflecting mirror;
the function of an optical waveguide (LWL1, LWL2);
the function of a directional coupler;
the function of a shaft sump;
the function of a circulator; and/or
the function of a coupling and/or decoupling element.

The paramagnetic centers of the crystals and/or diamond nano crystals ND of the sensor elements SE and/or the sensor element layer 5 generally interact with magnetic fields. Therefore, it is conceivable that the device comprises at least one functional element of a magnetic circuit and/or a ferromagnetic sub-device or a ferromagnetic sub-structure. This may be a micro- or nanoscopic permanent magnet PM, which may be integrated, for example, in the metallization stack of said MOS, CMOS, BICMOS or bipolar circuit, in particular above the paramagnetic centers of the crystals and/or diamond nano crystals ND of the sensor elements SE and/or the sensor element layer 5. Preferably, it may be a gradient afflicted permanent magnet GPM. Preferably, said ferromagnetic sub-device or sub-structure is part of a magnetic circuit. In this case, the quantum technology micro-electro-optical system preferably has an excitation device, for example a magnetic field generation means L_{c}, for example in the form of one or more flat coils manufactured in the metallization stack, which is suitable for causing a magnetic excitation in the magnetic circuit. Preferably, the magnetic sub-device is manufactured by depositing a ferromagnetic layer and subsequent photolithographic structuring.

in the example of FIG. 89, the exemplary device comprises an exemplary magnetic field generation means L_{c} in the form of an exemplary flat coil in the metallization stack above the sensor element SE or the sensor element layer 5. With regard to the function and operation, the document presented here refers to the preceding descriptions.

If the paramagnetic centers of the crystals and/or diamond nano crystals ND of the sensor elements SE and/or the sensor element layer 5 are to be used as subdevices of a sensor system, the absolute value and/or the direction of the magnetic excitation H generated by the excitation device in the magnetic circuit or in the magnetic field generation means Le preferably depends on an operating state parameter of the electronic circuit, i.e. preferably of the MOS, CMOS, BICMOS or bipolar circuit. In this context, the document presented here refers to the document DE 10 2018 127 394 A1. The use of the method presented here for the fabrication of a device according to DE 10 2018 127 394 A1 is expressly part of this disclosure. In its core, the document presented here deals with the large-scale series production of such systems as described, for example, in DE 10 2018 127 394 A1. However, the methods presented here will also be suitable for the fabrication of quantum computers and other quantum optical systems that require interfacing to micro-electronic and/or micro-mechanical and/or micro-optical systems.

Typically, such a quantum technological, micro-electro-optical system comprises a light-sensitive component (pG, nG). The light-sensitive component (pG, nG), in particular the photo detector PD, is then preferably suitable and/or intended for detecting the intensity Iᵢₛ of a fluorescence radiation FL from paramagnetic centers of the crystals and/or diamond nano crystals ND of the sensor elements SE and/or the sensor element layer 5. Preferably, the paramagnetic centers of the crystals and/or diamond nano crystals ND of the sensor elements SE and/or of the sensor element layer 5 are detected for this purpose by various optical elements, on the one hand with a pump light source MS as light source LED via an optical wave connection consisting of several optical components (paramagnetic centers, SE, LWL2) and on the other hand with the light-sensitive component (pG, nG) in the form of the light source LED via a further optical wave connection consisting of several other optical components (paramagnetic centers, SE, LWL1).

The MOS integrated circuit or CMOS integrated circuit or BICMOS integrated circuit or bipolar integrated circuit or other circuit technology disclosed herein is thus characterized in that it comprises a plurality of crystalline subdevices which are preferably mechanically fixedly connected thereto. circuit in bipolar technology or another circuit technology is thus characterized in that it comprises a plurality of crystalline subdevices which are preferably mechanically firmly connected to it and the paramagnetic centers of the crystals and/or diamond nano crystals ND of the sensor elements SE and/or of the sensor element layer 5, the paramagnetic centers of the crystals and/or diamond nano crystals ND of the sensor elements SE and/or of the sensor element layer 5 being functional elements for the intended use of the integrated circuit. A colloidal film and/or a colloidal varnish KL preferably provides the mechanical connection between the crystalline sub-devices and the carrier substrate 1360 as sensor element SE and/or sensor element layer 5. Preferably, one or more optical couplings, B. by one or more micro-optical functional elements cause one or more active connections between the paramagnetic centers of the crystals and/or diamond nano crystals ND of the sensor elements SE and/or the sensor element layer 5 and at least one or more parts of the MOS, CMOS, BICMOS or bipolar circuit, in particular light-emitting regions LG of the light source LED and/or light-sensitive components (PD, pG, nG), in particular the photo detector PD. The CMOS integrated circuit, or MOS circuit, or BICMOS circuit, or circuit in bipolar technology or another circuit technology typically comprises one or more transistors. In the case of a BICMOS circuit, these can be bipolar transistors and/or MOS transistors. In the case of an MOS or CMOS circuit, these can be MOS transistors. In the case of a bipolar circuit, these can be bipolar transistors.

Preferably, the micro integrated circuit is made in one piece. Preferably, the micro integrated circuit comprises several of the following sub-devices such as the control device CTR and the memories RAM, NVM, parts of the data bus DB, one or more light source drivers LDRV, one or more first signal generators G1, one or more multiple correlators LIV, one or more photo detectors PD, one or more first amplifiers V1, one or more pattern recognition devices MEV, one or more microwave sources μWG, one or more second signal generators G2, one or more magnetic field sensor controllers SIS, one or more magnetic field sensors MS, one or more magnetic field controllers LCTR, one or more micro-optical functional elements 6, 4, F1, one or more sensor elements SE and/or sensor element layers 5, one or more light sensor arrays 1, one or more evaluation electronics 15 of the light sensor array 1, one or more conditioning devices 30, one or more interface circuits 36, one or more permanent magnets 19, one or more magnetic field generating devices L_{c}.

The microelectronic circuit may comprise one or more sensor elements SE and/or one or more sensor layers 5 according to the technical teaching of the document presented herein. The one or more sensor elements SE and/or the one or more sensor layers 5 preferably comprise a multiplicity of crystals of different orientation with paramagnetic centers and/or a multiplicity of diamond nano crystals ND of different orientation and NV centers and/or other paramagnetic centers.

Preferably, the microelectronic circuit comprises one or more light sources LED for generating the pump radiation LB for the one or more sensor elements SE and/or the one or more sensor layers 5.

Preferably, the microelectronic circuit comprises micro-optical functional elements for exposure of the one or more sensor elements SE and/or the one or more sensor layers 5 to the pump radiation LB from the one or more light sources LED.

Preferably, the microelectronic circuit comprises micro-optical functional elements for detecting the fluorescence radiation FL of the one or more sensor elements SE and/or the one or more sensor layers 5 and for separating the fluorescence radiation FL of the one or more sensor elements SE and/or the one or more sensor layers 5 from the pump radiation LB of the one or more light sources LED and for exposing the photo detectors PD to the fluorescence radiation FL of the one or more sensor elements SE and/or the one or more sensor layers 5.

For use in various applications, the microelectronic circuit can comprise micro-fluidic and/or micro-mechanical and other micro-optical functional elements.

### FIG. 90

FIG. 90 shows a spectrum of a MESA structure MESA of FIG. 89 from the prior art for an operating voltage of 15V.

The curve data are taken from Röcken H., Meijer J., Stephan A., Weidenmüller U., Bukow H. H., Rolfs C., “White electroluminescent nanostructure in silicon fabricated using focused ion implantation” Nuclear Instruments and Methods in Physics Research B 181 (1001) page 274-279.

It can be clearly seen that such a structure not only emits light in the region of the desired pump radiation wavelengths λₚₘₚ around 520 nm, but also in the region of the expected fluorescence radiation FL above 600 nm. Use without an optical bandpass filter 4 is therefore not advisable.

### FIG. 91

FIG. 91 shows an exemplary carrier substrate 1360 with an angularly applied waveguide 6980. The exemplary waveguide in the example of FIG. 91 is a differential trip-plate waveguide 6980. The exemplary waveguide 6980 is covered by a sensor element layer 5 as sensor element SE. The exemplary sensor element layer 5 is again to comprise a multiplicity of crystals and/or diamond nano crystals ND with paramagnetic centers which, upon exposure to pump radiation LB of a pump radiation wavelength λ pmp, emit fluorescence radiation FL of a fluorescence wavelength λ_{fl} as a function of the microwave frequency ω_{μW} of the microwave signal μW and the additional magnetic flux density B_{ad}. The terminal resistors 6710 again preferably terminate the exemplary tri-plate waveguide 6980 as exemplary waveguide without reflections.

Preferably, a gradient afflicted permanent magnet GPM from the other side of the carrier substrate 1360 floods the sensor element layer 5 with an additional magnetic flux density which decreases, for example, in the x-direction from a maximum additional magnetic flux density B_{ad_max} a minimum additional magnetic flux density B_{ad_min} and which decreases, for example, in the y-direction from a maximum additional magnetic flux density B_{ad_max} a minimum additional magnetic flux density B_{ad_min}. Of course, other curves are conceivable.

As a result, the position of the V-formation (522, 525, 530) of FIG. 51b shifts in the vertical of FIG. 51b for each point of the sensor element layer 5 above the waveguide, here the trip-plate waveguide 6980. Thus, the intensity curve of the intensity Iᵢₛ(x, y) of the fluorescence radiation FL along the two branches of the waveguide, here the trip-plate waveguide 6980, allows conclusions to be drawn about the microwave spectrum of the microwave signal μW.

Preferably, the sensor system comprises in a memory RAM, NVM of the sensor system via a database of a multiplicity of measured value courses for the intensity course Iᵢₛ(x, y) of the fluorescence radiation FL along the waveguide coordinates x, y for the respective courses of the two branches of the waveguide, here the trip-plate waveguide 6980, for various microwave frequencies ω_{μW} of the microwave signal μW and/or computer-implemented models and/or computer-implemented approximation functions known at the time of detecting these measured values, which can provide these measured values. Preferably, the control device CTR and/or the pattern recognition device MEV determine a correlation value K(ω_{μW}) between the measured value curves for the intensity curve I_{LIB}(x) and I_{LIB}(y) for different microwave frequencies ω_{μW}. I_{LIB}(y) of the fluorescence radiation FL along the two branches of the waveguide from the database or the computer-implemented models or the computer-implemented approximation functions on the one hand and the currently measured value curves for the intensity curve Iᵢₛₜ(x) or Iᵢₛₜ(y) of the fluorescence radiation FL along the two branches of the waveguide on the other hand.

For the horizontal part of the waveguide (see FIG. 90), we form the correlation value K_{w}(ω_{μW}), for example, by forming an L2 product integral:

$${K}_{w} ( {ω}_{μ W} ) = {\int }_{{x}_{a}}^{{x}_{b}} {I}_{LIB} ( x ) * {I}_{i s t} ( {x}_{0} + x ) d x$$

For the vertical part of the waveguide (see FIG. 90), we form the correlation value Kₛ(ω_{μW}), for example, by forming an L2 product integral:

$${K}_{s} ( {ω}_{μ W} ) = {\int }_{{y}_{a}}^{{y}_{b}} {I}_{LIB} ( y ) * {I}_{i s t} ( {y}_{0} + y ) d y$$

Since each position x and y is assigned exactly one additional magnetic flux density B_{ad}(x) and B_{ad}(y) respectively, this L2 product can also be written as:

$${K}_{w} ( {ω}_{μ W} ) = {\int }_{{B}_{a d} ( {x}_{a} )}^{{B}_{a d} ( {x}_{b} )} {I}_{LIB} ( x ( {B}_{a d} ) ) * {I}_{i s t} ( x ( {B}_{a d} ) + x ( {B}_{a d} ( {x}_{0} ) ) ) d {B}_{a d}$$

$${K}_{s} ( {ω}_{μ W} ) = {\int }_{{B}_{a d} ( {y}_{a} )}^{{B}_{a d} ( {y}_{b} )} {I}_{LIB} ( y ( {B}_{a d} ) ) * {I}_{i s t} ( y ( {B}_{a d} ) + y ( {B}_{a d} ( {y}_{0} ) ) ) d {B}_{a d}$$

The V-formation (see FIGS. 51b and 84) can be limited to the left branch (522) or the right branch (25). Therefore, before feeding the microwave signal μW into the waveguide 6980, a low pass filter (e.g. μWG_F_I) should ensure that the microwave signal μW no longer comprises any signal components with a microwave frequency ω_{μW} greater than the zero point microwave frequency ω_{μW0} if the left branch (522) is used. Therefore, before feeding the microwave signal μW into the waveguide 6980 when using the right branch (525), a high-pass filter (e.g. μWG_F_I) should ensure that the microwave signal μW no longer comprises any signal components with a microwave frequency ω_{μW} less than the zero point microwave frequency ω_{μW0}. In practice, the realization of the low pass filter and thus the use of the left branch (522) of the V-formation (see FIG. 2) is simpler.

In this case, each additional magnetic flux density B_{ad}(x) or B_{ad}(y) is assigned exactly one microwave frequency ω_{μW} (B_{ad}(x)) or ω_{μW} (B_{ad}(y)).

The L2 product can then be written as:

$${K}_{w} ( {ω}_{μ W} ( {B}_{a d} ( {x}_{0} ) ) ) = {\int }_{{ω}_{μ W} ( {B}_{a d} ( {x}_{a} ) )}^{{ω}_{μ W} ( {B}_{a d} ( {x}_{b} ) )} {I}_{LIB} ( x ( {B}_{a d} ( {ω}_{μ W} ) ) ) * {I}_{i s t} ( x ( {B}_{a d} ( {ω}_{μ W} ) ) + x ( {B}_{a d} ( {ω}_{μ W} ( {B}_{a d} ( {x}_{0} ) ) ) ) ) d {ω}_{μ W}$$

$${K}_{s} ( {ω}_{μ W} ( {B}_{a d} ( {y}_{0} ) ) ) = {\int }_{{ω}_{μ W} ( {B}_{a d} ( {y}_{a} ) )}^{{ω}_{μ W} ( {B}_{a d} ( {y}_{b} ) )} {I}_{LIB} ( y ( {B}_{a d} ( {ω}_{μ W} ) ) ) * {I}_{i s t} ( y ( {B}_{a d} ( {ω}_{μ W} ) ) + y ( {B}_{a d} ( {ω}_{μ W} ( {B}_{a d} ( {y}_{0} ) ) ) ) ) d {ω}_{μ W}$$

Such a correlation value Kₛ(ω_{μW}), K_{w}(ω_{μW}), which depends on the microwave frequencies ω_{μW}, is referred to in this document as the high-frequency spectrum of the microwave signal μW.

It is obvious that magnetic field cameras such as those shown as examples in FIGS. 79 to 81 are particularly favorable for measuring the intensity curves Iᵢₛₜ(x) and Iᵢₛₜ(y) of the fluorescence radiation FL along the two branches of the waveguide.

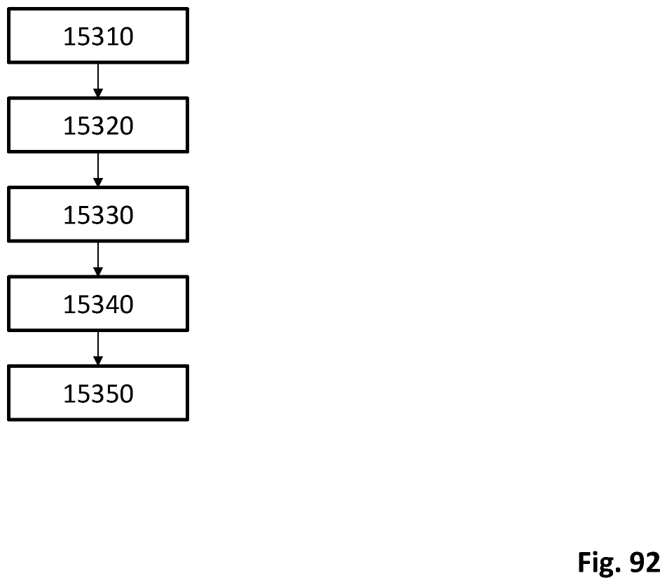

### FIG. 92

FIG. 92 illustrates in a schematically simplified manner the aforementioned method for the fabrication of a self-aligned sensor element SE optical waveguide LWL (4630), as previously described and used. The proposed method comprises the steps of:
deploying 15310 an optical waveguide LWL (4630), wherein the optical waveguide LWL (4630) comprises a first end and a second end;
deployment 15320 of a liquid substrate material TM which is curable by means of electromagnetic radiation of a curing wavelength λ_{H}, wherein a multiplicity of crystals and/or diamond nano crystals ND, preferably nanodiamonds, are embedded in the substrate material TM, are embedded in the substrate material TM and wherein one or more or all of the crystals and/or diamond nano crystals ND comprise NV centers and/or other paramagnetic centers and wherein the NV centers of the crystals and/or diamond nano crystals ND of the substrate material TM and/or the other paramagnetic centers of the crystals and/or diamond nano crystals ND of the substrate material TM emit at least one fluorescence radiation FL upon exposure to pump radiation LB;
wetting 15330 of the second end of the optical waveguide LWL (4630) at least to a wetting length LTM with the substrate material TM comprising the multiplicity of embedded crystals and/or diamond nano crystals ND with NV centers and/or paramagnetic centers;
injecting 15340 electromagnetic radiation into the first end of the optical waveguide LWL (4630), the wavelength of this electromagnetic radiation, the curing wavelength ÅH, being selected such that the substrate material TM at the second end of the optical waveguide LWL (4630) cures and transforms into a solid; and
removal 15350 of the uncured substrate material TM, in particular by means of a solvent LM, the remaining film of the substrate material TM at the second end of the optical waveguide LWL (4630) forming the sensor element SE.

Typically, the substrate material TM only partially hardens, which enables the formation of the optical functional elements and the sensor element SE.

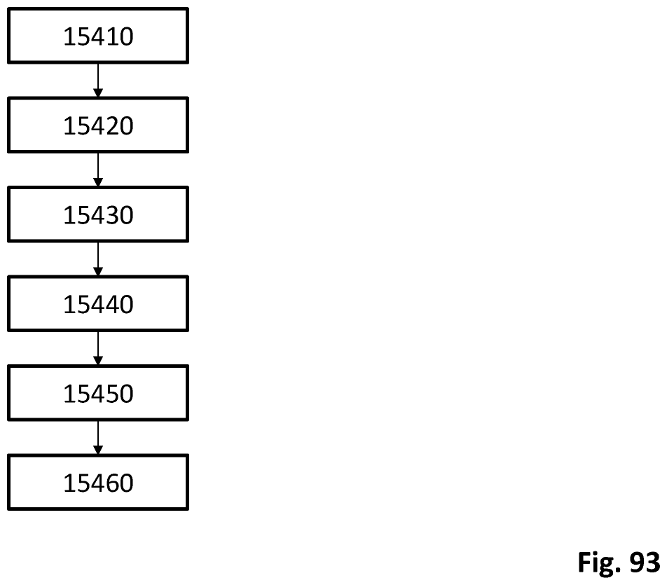

### FIG. 93

FIG. 93 illustrates in a schematically simplified manner the aforementioned method for the fabrication of a mask-adjusted sensor element SE on the optical waveguide LWL (4630), as previously described and used. The proposed method comprises the steps:
deploying 15410 an optical waveguide LWL (4630), wherein the optical waveguide LWL (4630) comprises a first end and a second end;
deployment 15420 of a liquid substrate material TM which is curable by means of electromagnetic radiation of a curing wavelength λ_{H}, wherein a multiplicity of crystals and/or diamond nano crystals ND, preferably nanodiamonds, are embedded in the substrate material TM, are embedded in the substrate material TM and wherein one or more or all of the crystals and/or diamond nano crystals ND comprise NV centers and/or other paramagnetic centers and wherein the NV centers of the crystals and/or diamond nano crystals ND of the substrate material TM and/or the other paramagnetic centers of the crystals and/or diamond nano crystals ND of the substrate material TM emit at least one fluorescence radiation FL upon exposure to pump radiation LB;
coating 15430 the second end of the optical waveguide LWL (4630) at least to a wetting length LTM with the substrate material TM comprising the multiplicity of embedded crystals and/or diamond nano crystals ND with NV centers and/or paramagnetic centers;
adjustment 15440 of an exposure mask 5410 in relation to the carrier substrate 1360;
exposure 15450 of the second end of the optical waveguide LWL (4630) through the exposure mask 5410 to electromagnetic radiation, the wavelength of this electromagnetic radiation, the curing wavelength λ_{H}, being selected such that the substrate material TM at the second end of the optical waveguide LWL (4630) cures and transforms into a solid; and
removal 15460 of the uncured substrate material TM, in particular by means of a solvent LM, the remaining film of the substrate material TM at the second end of the optical waveguide LWL (4630) forming the sensor element SE.

Typically, the substrate material TM only partially hardens, which enables the formation of the optical functional elements and the sensor element SE.

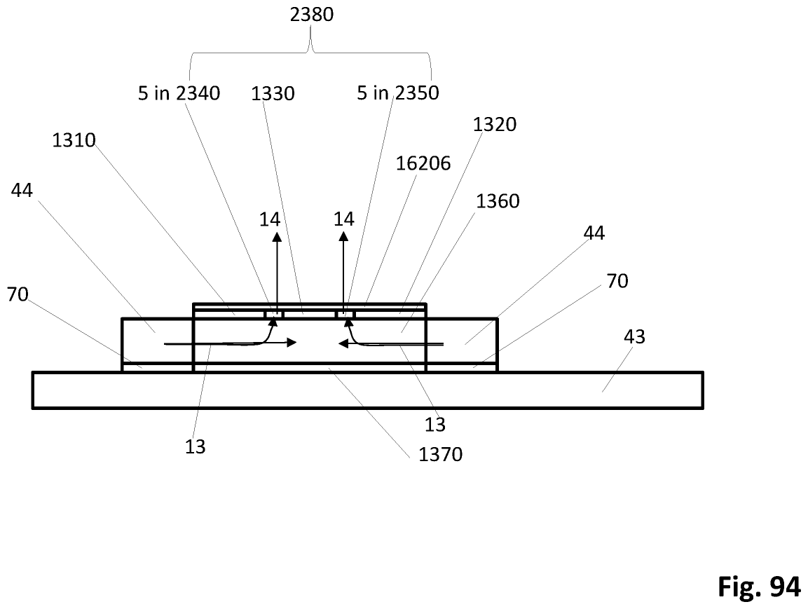

### FIG. 94

FIG. 94 shows an exemplary optically transparent carrier substrate 1360 with an exemplary waveguide in the form of a trip-plate waveguide 2380. When selecting the waveguide type of the waveguide on the surface of the optically transparent carrier substrate 1360, it is advantageous if the lines and electrically conductive surfaces of the waveguide in question completely cover the surface of the optically transparent carrier substrate 1360 except for the clearances (2340, 2350), so that light from the optically transparent carrier substrate 1360 can essentially only leave the optically transparent carrier substrate 1360 via the edges of the optically transparent carrier substrate 1360 and/or the clearances (2340, 2350) of the waveguide. Preferably, the electrically conductive backside contact 1370 is designed to be reflective for this purpose, so that it reflects the light within the optically transparent carrier substrate 1360 back into the optically transparent carrier substrate 1360. This increases the intensity of the pump radiation in the clearances (2340, 2350) of the waveguide. Suitable waveguides include, for example, slot lines 1880, trip-plate waveguides 2380, and differential trip-plate waveguides 6980, as these typically an electrically conductive left signal ground plane 1310 and an electrically conductive right signal ground plane 1320, which prevent the light, in particular the pump radiation 13 (13), from escaping from the optically transparent carrier substrate 1360.

In the case of a slot line 1880, the slot 1840 of the slot line 1880 forms the clearances through which the pump radiation 13 (13) can exit the carrier substrate 1360, which is optically transparent to the pump radiation 13 (13), and enter the sensor layer 5 as sensor element SE. Typically, the paramagnetic centers, here typically NV centers in diamonds within the irradiated segments of the sensor layer 5 in the slot 1840 of the slot line 1880, emit fluorescence radiation 14 as a result of the exposure to the pump radiation 13 (13).

In the case of a trip-plate waveguide 2380, the electrically essentially non-conductive left insulation gap 2340 and the electrically essentially non-conductive right insulation gap 2350 of the trip-plate waveguide 2380 form the two clearances through which the pump radiation 13 (13) can emerge from the carrier substrate 1360, which is optically transparent for the pump radiation 13 (13), and can enter the two partial segments of the sensor layer 5 as sensor elements SE. Typically, the paramagnetic centers, here typically NV centers in diamonds within the exposed segments of the sensor layer 5 in the electrically essentially non-conductive left insulation gap 2340 and in the electrically essentially non-conductive right insulation gap 2350 of the trip-plate waveguide 2380, emit fluorescence radiation 14 as a result of the exposure to the pump radiation 13 (13).

In the case of a differential trip-plate waveguide 6980, the electrically essentially non-conductive left insulation gap 2340 and the electrically essentially non-conductive right insulation gap 2350 of the trip-plate waveguide 2380 as well as the electrically insulating gap 6840 between the left signal conductor 6810 and the right signal conductor 6820 of the differential signal conductor 6830 of the trip-plate waveguide 2380 form the three clearances, through which the pump radiation 13 (13) can emerge from the carrier substrate 1360, which is optically transparent for the pump radiation 13 (13), and can enter the three subsegments of the sensor layer 5 as sensor elements SE in these three clearances. Typically, the paramagnetic centers, here typically NV centers in diamonds within the exposed segments of the sensor layer 5 emit in the electrically essentially non-conductive left insulation gap 2340 and in the electrically essentially non-conductive right insulation gap 2350 of the trip-plate waveguide 2380 as well as in the electrically insulating gap 6840 between the left signal conductor 6810 and the right signal conductor 6820 of the differential signal conductor 6830 of the trip-plate waveguide 2380, fluorescence radiation 14 as a result of exposure to the pump radiation 13.

Preferably, in normal operation, LEDs as pump radiation sources 44 emit the pump radiation 13 and radiate it into the optically transparent carrier substrate 1360 via edges of the optically transparent carrier substrate 1360. The optically transparent carrier substrate 1360 distributes the pump radiation 13 within the optically transparent carrier substrate 1360.

The pump radiation 13 exits the optically transparent carrier substrate 1360 through the clearances (2349, 2350) of the waveguide (2380) and irradiates the sensor elements SE of the sensor layer 5.

The printed circuit board (PCB) 43 for the LEDs 44 is preferably installed in a magnetic field camera, such as that described in this document. Express reference is made here to the other sections of this document.

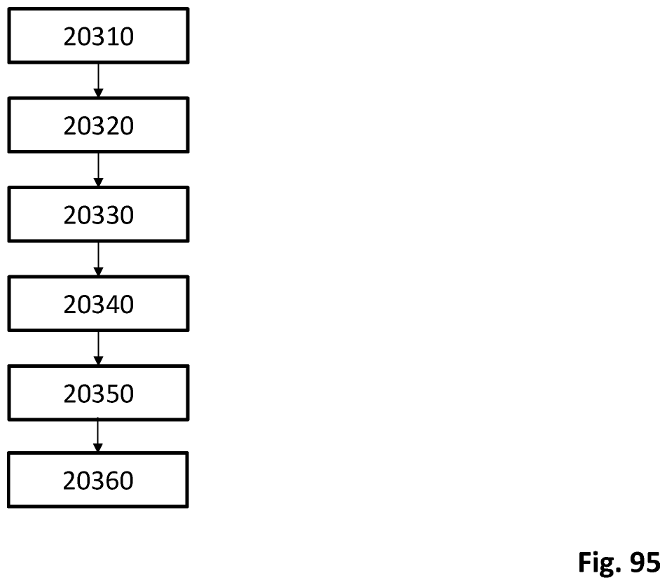

### FIG. 95

FIG. 95 shows an example of the fabrication of a device according to FIG. 94.

The proposed method preferably comprises the following steps:
1. deployment 20310 of an optically transparent carrier substrate 1360, wherein the optically transparent carrier substrate 1360 comprises at least one optically transparent edge, and wherein the optically transparent carrier substrate 1360 is covered with a waveguide having at least one clearances, such as a slot line and/or a tri-plate line or a differential tri-plate line, so that light is substantially only transmitted through the clearance of the waveguide on the surface of the optically transparent carrier substrate 1360, for example a slot line and/or a trip-plate waveguide or a differential trip-plate waveguide, so that light can essentially only emerge from the optically transparent carrier substrate 1360 through the clearances of the waveguide on the surface of the optically transparent carrier substrate 1360;
2. deployment 20320 of a liquid colloidal mixture KL with a liquid substrate material TM which is curable by means of electromagnetic radiation, the curing radiation 4910, of a curing wavelength λ_{H}, wherein a multiplicity of crystals and/or diamond nano crystals ND, preferably nano-diamonds, are embedded in the substrate material TM of the colloidal mixture KL and wherein one or more or all of the crystals and/or diamond nano crystals ND have NV centers and/or other paramagnetic centers and wherein the NV centers of the crystals and/or diamond nano crystals ND have NV centers and/or other paramagnetic centers and wherein the crystals and/or diamond nano crystals ND have NV centers and/or other paramagnetic centers and wherein the crystals and/or diamond nano crystals ND have NV centers and/or other paramagnetic centers and wherein the crystals and/or diamond nano crystals ND have NV centers and/or other paramagnetic centers and wherein the crystals and/or diamond nano crystals ND have NV centers and/or other paramagnetic centers and wherein the crystals and/or diamond nano crystals ND have NV centers and/or other paramagnetic centers and wherein the crystals and/or diamond nano crystals ND have NV centers and/or other paramagnetic centers, and wherein one or more or all of the crystals and/or diamond nano crystals ND comprise NV centers and/or other paramagnetic centers and wherein the NV centers of the crystals and/or diamond nano crystals ND of the colloidal mixture KL and/or the other paramagnetic centers of the crystals and/or diamond nano crystals ND of the colloidal mixture KL emit at least one fluorescence radiation FL upon exposure to pump radiation LB;
3. coating 20330 the surface of the optically transparent substrate 1360 and the waveguide on the surface of the optically transparent substrate 1360 to at least a wetting length LTM with the colloidal mixture KL of the substrate material TM and the crystals and/or diamond nano crystals ND with NV centers and/or paramagnetic centers, the colloidal mixture KL thus comprising a multiplicity of embedded crystals and/or diamond nano crystals ND with NV centers and/or paramagnetic centers;
4. if necessary (not shown), hardening the coating of the optically transparent carrier substrate 1360 from the colloidal mixture KL, in particular by means of a temperature treatment;
5. feeding 20340 electromagnetic curing radiation 4910 with the curing wavelength λ_{H} into the optically transparent carrier substrate 1360 via the at least one edge of the optically transparent carrier substrate 1360;
6. emission 20350 of the curing radiation 4910 in the region of at least one clearances (1840, 2340, 2350, 6840) of the waveguide (1880, 2380, 6980) on the surface of the optically transparent carrier substrate 1360 from the optically transparent carrier substrate 1360 and irradiation of the curing radiation 4910 into the substrate material TM of the colloidal mixture KL, wherein the curing wavelength λ_{H} of the curing radiation 4910 is selected such that the substrate material TM of the colloidal mixture KL cures in the region of this clearances (1840, 2340, 2350, 6840) of the waveguide (1880, 2380, 6980) on the surface of the optically transparent carrier substrate 1360 and the colloidal mixture KL transforms into a solid in the irradiated area;
7. removal 20360 of the uncured substrate material TM of the colloidal mixture KL, in particular by means of a solvent LM, wherein the remaining film of the substrate material TM of the colloidal mixture KL and the colloidal mixture KL in the region of these clearances (1840, 2340, 2350, 6840) of the waveguide (1880, 2380, 6980) forms a sensor element SE and/or a sensor layer 16205 on the surface of the optically transparent carrier substrate 1360; and
8. if necessary (not shown) final curing of the substrate material TM of the colloidal mixture KL of the remaining sensor element SE and/or a sensor layer 16205 in the clearances (1840, 2340, 2350, 6840) of the waveguide (1880, 2380, 6980) in the region of a clearance of the waveguide (1880, 2380, 6980) on the surface of the optically transparent carrier substrate 1360, in particular by means of a temperature treatment. The necessity of this post-bake step is determined by the type of substrate material TM of the colloidal mixture KL used and the solvent LM in the colloidal mixture KL.

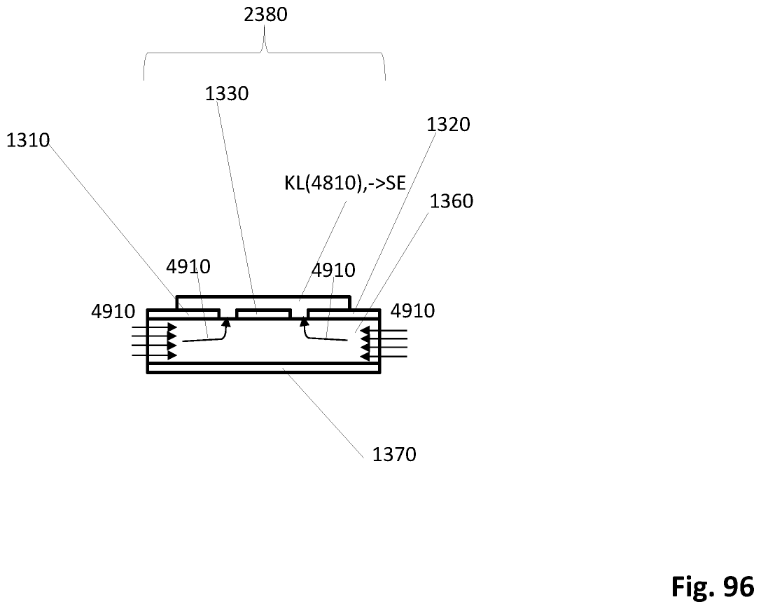

### FIG. 96

FIG. 96 schematically shows the implementation of the curing of the substrate material TM of the colloidal mixture KL according to the method according to FIG. 96 in step 20350. At this point in time, the pump radiation sources 44 and the printed circuit board (PCB) 43 for the LEDs 44 and their power supply 45 are preferably not yet connected to the optically transparent carrier substrate 1360. Curing radiation sources (not shown) emit curing radiation 4910 with a curing wavelength λ_{H}. An optical curing system (not shown) transports the curing radiation 4910 to the optically transparent edges of the optically transparent carrier substrate 1360. This optical curing system preferably comprises one or more optical functional elements such as mirrors, lenses, apertures, prisms, etc. to guide the curing radiation 4910 and to adjust its intensity and spectrum appropriately. Preferably, the system comprising curing radiation sources and optical curing system has a curing control (not shown) with a timer and/or a computer system with a memory, so that the computer system of the curing control and/or the curing control can determine the duration of the exposure by:
1. control of the curing radiation sources, e.g. by switching the curing radiation sources on/off and/or
2. by means of shutters within the optical curing system, e.g. by interrupting/opening the optical path between curing radiation sources and the optically transparent carrier substrate 1360 can control the curing process.

The computer system within the curing control device can typically control the curing process by means of a computer-implemented curing control program within the memory of the curing control computer system. The program code of the computer-implemented curing control program is preferably located in the memory of the computer system of the curing control device. The computer system within the cure control device typically executes this program code during exposure of the optically transparent carrier substrate 1360. The memory may comprise a storage medium, which may be removable, comprising this program code and/or parameters for performing the exposure. Preferably, a temperature control device 8 not shown maintains the temperature of the optically transparent carrier substrate 1360 during the exposure to curing radiation 4910. The temperature control device may also be a heatable and/or air-conditionable room in which the exposure to curing radiation 4910 takes place. The curing control device may control this temperature control device as a function of the measured temperature value of a temperature sensor.

The optical curing system irradiates the curing radiation 4910 into the optically transparent carrier substrate 1360 via the edges of the optically transparent carrier substrate 1360.

The optically transparent carrier substrate 1360 is preferably sufficiently transparent for electromagnetic radiation with the curing wavelength λ_{H} of the curing radiation 4910 for the intended purpose, so that the curing radiation 4910 can penetrate the colloidal material KL in the clearances (1840, 2340, 2350, 6840) of the waveguide (1880, 2380, 6980) on the surface of the optically transparent carrier substrate 1360 with sufficient intensity to cure the substrate material TM of the colloidal mixture KL. This means that the optically transparent carrier substrate 1360 is preferably essentially transparent to electromagnetic radiation having the curing wavelength λ_{H} of the curing radiation 4910.

The optically transparent carrier substrate 1360 is preferably essentially transparent to electromagnetic radiation with the pump radiation wavelength λ₍ₚₘₚ₎. This means that the intensity of the pump radiation 13 (see FIG. 94) reaching the paramagnetic centers of the crystals and/or diamond nano crystals ND and/or the NV centers of the diamond nano crystals ND after passing through the material of the optically transparent carrier substrate 1360 is sufficient to cause this to emit fluorescence radiation 14 (see FIG. 94).

The exposure of the colloidal material KL in the clearances (1840, 2340, 2350, 6840) of the waveguide (1880, 2380, 6980) on the surface of the optically transparent carrier substrate 1360 leads to the hardening of the substrate material TM of the colloidal mixture KL in the clearances (1840, 2340, 2350, 6840) of the waveguide (1880, 2380, 6980) on the surface of the optically transparent carrier substrate 1360. This forms solidified sensor elements SE within the colloidal material KL in the clearances (1840, 2340, 2350, 6840) of the waveguide (1880, 2380, 6980) on the surface of the optically transparent carrier substrate 1360. After removing 20360 the excess colloidal material KL, the optically transparent carrier substrate 1360 comprises the necessary sensor elements SE in the clearances (1840, 2340, 2350, 6840) of the waveguide (1880, 2380, 6980) on the surface of the optically transparent carrier substrate 1360 in order to be deployed as schematically sketched in FIG. 202. This use can preferably take place in one of the magnetic field cameras described above.

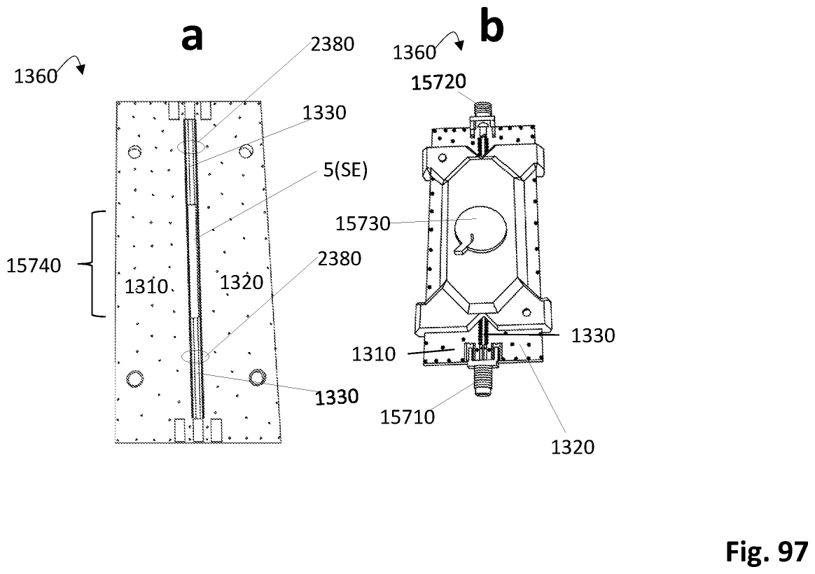

### FIG. 97a

FIG. 97a schematically shows an exemplary carrier substrate 1360 with an exemplary tri-plate waveguide 2389 as an example of a waveguide (1380, 1880, 2380, 6880, 6990). The exemplary tri-plate waveguide 2380 is covered with the sensor element SE on a section 15740 of the waveguide (1380, 1880, 2380, 6880, 6990). The sensor element SE, which is preferably produced according to one of the methods described herein and cured by means of curing radiation 4910, again comprises, by way of example, a preferably radiation cured and optically transparent substrate material TM, which preferably again comprises crystals and/or diamonds DM with paramagnetic centers and/or NV centers NVZ. In the region of the section 15740 of the waveguide (1380, 1880, 2380, 6880, 6990), which is covered with the sensor element SE, the paramagnetic centers and/or NV centers NVZ of the crystals and/or diamonds DM, which are embedded in the substrate material TM of the sensor element SE, can interact with a microwave signal μW and/or an RF signal RW, which are fed, for example, via a first microwave and/or RF connector 15710 for connecting the waveguide (1380, 1880, 2380, 6880, 6990), for example, into the signal conductor 1330 of the exemplary triplate line 2380. This interaction causes a frequency-dependent characteristic impedance that deviates from the characteristic impedance of the remaining waveguide (1380, 1880, 2380, 6880, 6990), in this case the trip-plate waveguide 2380.

A first part of the microwave signal μW radiated into the path 15740 of the waveguide (1380, 1880, 2380, 6880, 6990), which is covered by the sensor element (SE), is reflected as a reflected microwave signal μWR due to the characteristic impedance jumps at the transitions from the undisturbed waveguide (1380, 1880, 2380, 6880, 6990), to the path 15740 and back again as a reflected microwave signal μWR in the direction of the first microwave and/or RF connector 15710 and can be decoupled there from the transmission line by means of a wave coupler μWC and fed to a reflection microwave analyzer μWAR, which can, for example, determine relevant parameters such as amplitude, phase, spectrum, etc.

A second part of the microwave signal μW radiated into the path 15740 of the waveguide (1380, 1880, 2380, 6880, 6990), which is covered by the sensor element (SE), is transmitted as a transmitted microwave signal μWT as a result of the characteristic impedance jumps at the transitions from the undisturbed waveguide (1380, 1880, 2380, 6880, 6990), to the path 15740 and back again as a transmitted microwave signal μWT in the direction of the second microwave and/or RF connector 15720, where it can be fed to a transmission microwave analyzer μWAT, which can, for example, determine relevant parameters such as amplitude, phase, spectrum, etc., in the direction of the second microwave and/or RF connector 15720, etc.

If the relevant parameters of the irradiated microwave signal μW and the reflected microwave signal μWR and the transmitted microwave signal μWT are known, a control device CTR, for example, which receives this data from the microwave source μWG and the reflection microwave analyzer μWAR and the transmission microwave analyzer μWAT via the data bus DB, can be set to a third absorbed component of an absorbed microwave signal μWA of the microwave signal μW. The substrate material TM of the sensor element SE and/or the paramagnetic centers and/or the NV centers NVZ of the crystals and/or diamonds DM embedded in the substrate material TM of the sensor element SE have then typically influenced this absorbed microwave signal μWA. Therefore, the absorbed microwave signal μWA typically depends on the quantum states of the paramagnetic centers and/or the NV centers NVZ of the crystals and/or diamonds DM embedded in the substrate material TM of the sensor element SE. It is therefore possible that the absorbed microwave signal μWA depends on the intensity of a pump radiation LB, which exposes the paramagnetic centers and/or the NV centers NVZ of the crystals and/or diamonds DM to electromagnetic radiation of a pump radiation wavelength λₚₘₚ, and then additionally on physical parameters of physical quantities, such as magnetic flux densities, which influence the paramagnetic centers and/or the NV centers NVZ of the crystals and/or diamonds DM.

If the relevant parameters of the radiated RF signal RW and the reflected RF signal RWR and the transmitted RF signal RWT are known, a control device CTR, for example, which receives this data from the RF source RFG and the reflection RF signal analyzer RWAR and the transmission RF signal analyzer RWAT via the data bus DB, can infer a third absorbed component of an absorbed RF signal RWA of the RF signal RW. The substrate material TM of the sensor element SE and/or the paramagnetic centers and/or the NV centers NVZ of the crystals and/or diamonds DM embedded in the substrate material TM of the sensor element SE have then typically influenced this absorbed RF signal RWA. Therefore, the absorbed RF signal RWA typically depends on the quantum states of the paramagnetic centers and/or the NV centers NVZ of the crystals and/or diamonds DM embedded in the substrate material TM of the sensor element SE. It is therefore possible that the absorbed RF signal RWA depends on the intensity of a pump radiation LB, which exposes the paramagnetic centers and/or the NV centers NVZ of the crystals and/or diamonds DM to electromagnetic radiation of a pump radiation wavelength λₚₘₚ, and then additionally on physical parameters of physical quantities, such as magnetic flux densities, which influence the paramagnetic centers and/or the NV centers NVZ of the crystals and/or diamonds DM.

### FIG. 97b

FIG. 97b schematically shows an exemplary carrier substrate 1360 with an exemplary tri-plate waveguide 2389 as an example of a waveguide (1380, 1880, 2380, 6880, 6990), wherein XXXX covers the section 15740 of the waveguide (1380, 1880, 2380, 6880, 6990) covered with the sensor element SE and thus protects it from damage. The covering 15730 of the carrier substrate 1360 with the waveguide (1380, 1880, 2380, 6880, 6990) and the sensor element SE for mechanical and chemical protection of the sensor element SE and possibly for EMC protection preferably does not influence the value and/or absolute value of the physical quantity to be measured. The physical quantity to be measured can be, for example, a magnetic flux density B at the location of the sensor element SE.

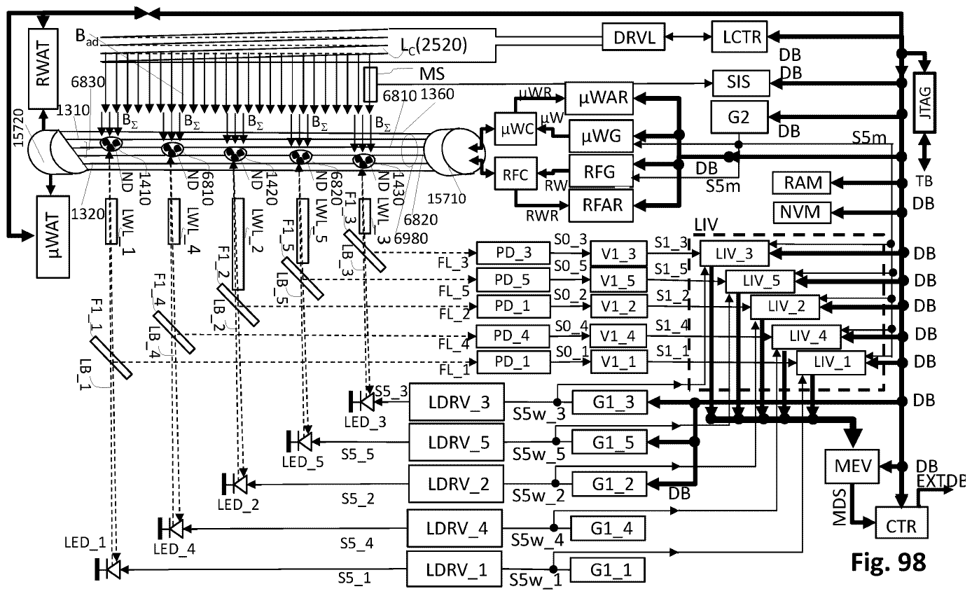

### FIG. 98

FIG. 98 corresponds as far as possible to FIG. 78, with the additional reference sign of the first microwave and/or RF connector 15710 for the connection of the waveguide (1380, 1880, 2380, 6880, 6990) to the microwave signal source μWG and the RF signal source RFG and to a reflection microwave signal analyzer (μWAR) and to a reflection RF signal analyzer (RWAR) being drawn with the reference sign 15710. In the example of FIG. 98, a differential trip-plate waveguide 6980 is drawn as an exemplary waveguide (1380, 1880, 2380, 6880, 6990) as an example and representative of other waveguides (1380, 1880, 2380, 6880, 6990). In this case, the first microwave and/or RF connector 15710 is preferably a triax connector which enables the simultaneous but separate connection of a microwave signal μW and an RF signal RW to different signal conductors 6910, 6920 of the exemplary differential trip-plate waveguide 6980.

Furthermore, the second microwave and/or RF connector 15720 for connecting the waveguide (1380, 1880, 2380, 6880, 6990) to a reflection microwave signal analyzer (μWAR) and to a transmission RF-signal analyzer (RWAT) is also shown. In the example of FIG. 98, a differential trip-plate waveguide 6980 is drawn as an exemplary waveguide (1380, 1880, 2380, 6880, 6990) as an example and representative of other waveguides (1380, 1880, 2380, 6880, 6990). Preferably in this case, the second microwave and/or RF connector 15720 is also a triax connector, which enables the simultaneous but separate extraction of the transmitted microwave signal μWT and the transmitted RF signal RWT to the respective different signal conductors 6910, 6920 of the exemplary differential trip-plate waveguide 6980.

A first part of the microwave signal μW radiated into the path 15740 of the exemplary differential trip-plate waveguide 6980, which is covered with the sensor element SE, is reflected as a reflected microwave signal μWR as a result of the characteristic impedance jumps at the transitions from the undisturbed exemplary differential trip-plate waveguide 6980 to section 15740 and back again as a reflected microwave signal μWR in the direction of the first microwave and/or RF connector 15710 and is decoupled there from the transmission line by means of a wave coupler μWC and fed to the reflection microwave analyzer μWAR, which can, for example, determine relevant parameters such as amplitude, phase, spectrum, etc, etc. Preferably, the reflection microwave analyzer μWAR transmits the detected parameters to the control device CTR via the data bus DB.

A second part of the microwave signal μW radiated into the path 15740 of the exemplary differential trip-plate waveguide 6980, which is covered with the sensor element SE, is transmitted as a transmitted microwave signal μWT as a result of the characteristic impedance jumps at the transitions from the undisturbed section of the exemplary differential trip-plate waveguide 6980 to the section 15740 and back again as a transmitted microwave signal μWT in the direction of the second microwave and/or RF connector 15720, where it is fed to a transmission microwave analyzer μWAT, which can, for example, determine relevant parameters such as amplitude, phase, spectrum, etc., and can then be used to determine the transmission of the microwave signal μWT, etc. Preferably, the transmission microwave analyzer μWAT transmits the detected parameters to the control device CTR via the data bus DB.

A first part of the RF signal RW radiated into the path 15740 of the exemplary differential trip-plate waveguide 6980, which is covered by the sensor element SE, is reflected as reflected RF signal RWR as a result of the characteristic impedance jumps at the transitions from the undisturbed exemplary differential trip-plate waveguide 6980 to section 15740 and back again as reflected RF signal RWR in the direction of the first microwave and/or RF connector 15710, where it is decoupled from the transmission line by means of an RF wave coupler RWC and fed to the reflection RF signal analyzer RWAR, which can, for example, determine relevant parameters such as amplitude, phase, spectrum, etc, etc. Preferably, the reflection RF signal analyzer RWAR transmits the detected parameters to the control device CTR via the data bus DB.

A second part of the RF signal RW radiated into the path 15740 of the exemplary differential trip-plate waveguide 6980, which is covered by the sensor element SE, is transmitted as a transmitted RF signal RWT as a result of the characteristic impedance jumps at the transitions from the undisturbed section of the exemplary differential trip-plate waveguide 6980 to the section 15740 and back again as a transmitted RF signal RWT in the direction of the second microwave and/or RF connector 15720, where it is fed to a transmission RF signal analyzer RWAT, which can, for example, determine relevant parameters such as amplitude, phase, spectrum, etc., in the direction of the second microwave and/or RF connector 15720, etc. Preferably, the transmission RF signal analyzer RWAT transmits the detected parameters to the control device CTR via the data bus DB.

If the relevant parameters of the irradiated microwave signal μW and the reflected microwave signal μWR and the transmitted microwave signal μWT are known, the control device CTR, for example, which receives this data from the microwave source μWG and the reflection microwave analyzer μWAR and the transmission microwave analyzer μWAT via the data bus DB, can be set to the third absorbed component of an absorbed microwave signal μWA of the microwave signal μW. The substrate material TM of the sensor element SE and/or the paramagnetic centers and/or the NV centers NVZ of the crystals and/or diamonds DM embedded in the substrate material TM of the sensor element SE have then typically influenced this absorbed microwave signal μWA. Therefore, the absorbed microwave signal μWA typically depends on the quantum states of the paramagnetic centers and/or the NV centers NVZ of the crystals and/or diamonds DM embedded in the substrate material TM of the sensor element SE. It is therefore possible that the absorbed microwave signal μWA depends on the intensity of a pump radiation LB, which exposes the paramagnetic centers and/or the NV centers NVZ of the crystals and/or diamonds DM to electromagnetic radiation of a pump radiation wavelength pmp, and then additionally on physical parameters of physical quantities, such as magnetic flux densities, which influence the paramagnetic centers and/or the NV centers NVZ of the crystals and/or diamonds DM.

If the relevant parameters of the radiated RF signal RW and the reflected RF signal RWR and the transmitted RF signal RWT are known, a control device CTR, for example, which receives this data from the RF source RFG and the reflection RF signal analyzer RWAR and the transmission RF signal analyzer RWAT via the data bus DB, can infer a third absorbed component of an absorbed RF signal RWA of the RF signal RW. The substrate material TM of the sensor element SE and/or the paramagnetic centers and/or the NV centers NVZ of the crystals and/or diamonds DM embedded in the substrate material TM of the sensor element SE have then typically influenced this absorbed RF signal RWA. Therefore, the absorbed RF signal RWA typically depends on the quantum states of the paramagnetic centers and/or the NV centers NVZ of the crystals and/or diamonds DM embedded in the substrate material TM of the sensor element SE. Therefore, it is possible that the absorbed RF signal RWA depends on the intensity of a pump radiation LB, which exposes the paramagnetic centers and/or the NV centers NVZ of the crystals and/or diamonds DM with electromagnetic radiation of a pump radiation wavelength 2pmp, and then additionally on physical parameters of physical quantities, such as magnetic flux densities, which influence the paramagnetic centers and/or the NV centers NVZ of the crystals and/or diamonds DM. means of computer-implemented methods, the pattern recognition device MEV and/or the control device CTR can estimate and/or determine values of physical parameters using these data, based on these and other data determined in this system. Preferably, the program code for such computer-implemented methods, which may comprise in particular methods for pattern recognition, is stored in memories (RAM, NVM) of the device. The present document refers here to the methods of pattern recognition and artificial intelligence mentioned elsewhere in this document. In particular, the emulation of a computer-implemented neural network model and/or the application of computer-implemented deep learning methods and computer-implemented machine learning methods by the pattern recognition device MEV and/or the control device CTR may comprise such computer-implemented methods. Preferably, the control device CTR uses at least a portion of the data detected in the device to generate a feature vector, to which the control device then applies a computer-implemented pattern recognition method.

The application of the technical teachings of FIGS. 97 and 98 to those of the other figures, and in particular FIGS. 1, 6, 8, 11 to 14, 16 to 20, 27, 29 to 35, 38 to 44,47 to 84, 89, 91, 96, 97 and the description is an express part of the disclosure of the document presented here. It is easy for a person skilled in the art to insert the additional components of FIG. 98 in comparison with FIG. 78 in the same way additionally into the corresponding aforementioned figures, in particular the particularly relevant FIGS. 1, 6, 17, 49, 69, 70, 71, 73 to 81 and 98, in an analogous manner as required and thus arrive at the technical teaching disclosed herein. The same applies to components that are missing in the corresponding figure but are present in FIG. 98. In this respect, the figures shown here are only examples by way of explanation, the technical teachings of which can be combined with one another if appropriate. A technically skilled person can check the usefulness of these combinations.

### LIST OF REFERENCE SYMBOLS

1 Light sensor array 1 with electronics (control, etc.). Preferably, the light sensor array 1 comprises a CCD camera sensor or the like, wherein each CCD pixel of the CCD camera sensor represents a light sensor of the light sensor array within the meaning of the present document;
2 The light source 2 can be a laser or an LED, for example. Preferably, the light source 2 emits pump radiation 13 (LB) of the pump radiation wavelength λₚₘₚ when supplied with electrical energy. The document presented here also refers to the light source 2 as pump radiation source PL with the reference sign PL;
3 illumination optics;
4 optical filter (short pass);
5 FIG. 25 shows an exemplary structure of the sensor layer 5 for exposure by an external pump radiation source 2 as pump radiation source PL;
6 Optical filter (long pass) 6 The optical filter 6 has the function of a dichroitic mirror/optical filter F1 for separating the fluorescence radiation FL from the pump radiation LB;
7 imaging optics 7;
8 For example, the housing 8 of the magnetic field camera may be a 3D printed housing. The housing 8 of the magnetic field camera may comprise, for example, an upper housing part 40 of the housing 8 and a lower housing part 41 of the housing 8;
9 Substrate material I 9. Typically, the substrate material I 9 comprises a partial device of the lower housing part 41 of the housing 8 of the magnetic field camera and/or the material of a printed circuit board (PCB) and/or a semiconductor wafer part (die) and/or a micro-integrated semiconductor circuit and/or a micro-mechanical device and/or a micro-electromechanical device and/or a micro-optical device and/or a micro-fluidic device etc. and/or combinations thereof;
10 Reflective coating 10;
11 Layer 11 comprising crystals and/or nano crystals 66 with paramagnetic centers. Preferably, this layer comprises a multiplicity of crystals and/or nano crystals 66 which are preferably completely random, uniformly oriented and whose density is preferably not essentially dependent on the position in the layer. Preferably, the crystals and/or nano crystals 66 are diamonds. Preferably, the paramagnetic centers are NV centers. Preferably, the diamond material is NV-rich diamond dust in an optically transparent composite material that is essentially transparent to electromagnetic radiation, for example pump radiation 13, with pump radiation wavelength λₚₘₚ and to electromagnetic radiation with fluorescence radiation wavelength λ_{fl}. Typically, the sensor layer 5 comprises this layer 11. The layer 11 preferably comprises a solidified colloidal mixture KL of a substrate material TM cured by means of electromagnetic radiation of a curing wavelength λ H. Preferably, a multiplicity of diamonds DM or nano-diamonds and/or crystals are embedded in the substrate material TM. One or more or all diamonds DM or nano-diamonds of these diamonds DM and/or crystals preferably comprise NV centers NVZ and/or other paramagnetic centers. The NV centers NVZ of the substrate material TM and/or the other paramagnetic centers of the substrate material TM preferably emit at least one fluorescence radiation FL upon exposure to pump radiation LB;
12 The substrate material II 12 can be, for example, a glass plate 46 which, as an exemplary optical functional element, simultaneously exposes the layer 11 with crystals and/or nano crystals 66 with paramagnetic centers to pump radiation 13 with the pump radiation wavelength λₚₘₚ. For the purposes of the present document, the substrate material II 12 is an optical waveguide LWL);
13 Pump radiation 13 with the pump radiation wavelength λₚₘₚ. The document presented here also designates the pump radiation 13 with the reference sign LB (like laser beam);
14 Fluorescence radiation 14 having the fluorescence radiation wavelength λ_{fl}. The document presented here also designates the fluorescence radiation 14 with the reference sign FL (as in fluorescence);
15 Evaluation electronics 15 of the light sensor array 1;
16 Preferably flat surface 16;
17 ferromagnetic material 17;
18 Defects in the exemplary ferromagnetic material 17 of FIG. 26;
19 Auxiliary magnet 19;
20 exemplary direction of movement 20;
21 Magnetic field camera head 21;
22 underside of the sensor layer 5 in the direction away from the light sensor array 1;
23 upper side of the sensor layer 5 in the direction of the light sensor array 1;
24 underside 24 of the housing 8 of the magnetic field camera;
25 Sensor layer thickness 25 of the sensor layer 5;
26 the distance 26 between the sensor layer 5 and the outer surface of the housing 8 of the magnetic field camera in the region of the sensor layer 5. In the examples presented here, the distance between the sensor layer 5 and the surface 34 of the measurement object 17 was less than 1 mm;
27 electromagnetic radiation 27 of other wavelength ranges 27;
28 Computer system 28 for operating the magnetic field camera head 21;
29 Data bus 29 for fabrication of the data connection between the processing circuit 30 for the output signals 31 of the light sensors of the light sensor array 1 of the magnetic field camera head 21 and the computer system 28 for operating the magnetic field camera head 21;
30 Processing circuit 30 for the output signals 31 of the light sensors of the light sensor array 1 of the magnetic field camera head 21. The processing circuit 30 is preferably part of the evaluation electronics 15 of the magnetic field camera head 21;
31 Output signals 31 of the light sensors of the light sensor array 1 of the magnetic field camera head 21;
32 Screen 32 of the magnetic field camera;
33 Computer core 33 of the computer system 28 for operating the magnetic field camera head 21 of the magnetic field camera with at least one CPU;
34 Surface 34 of the measurement object. In FIG. 16, the surface of the ferromagnetic material 17;
35 Control device 35 for the electromagnets of the auxiliary magnets 19 of the magnetic field camera head 21;
36 Interface circuit 36;
37 Permanent magnets 37 for testing purposes of the magnetic field camera and/or the magnetic field camera head 21;
38 Glass plate 38. In some embodiments, the technical teaching of the document presented here uses the glass plate 38 as an optical waveguide LWL);
39 two-dimensional false-color magnetic flux density magnitude image of the distribution of the magnetic flux density of four permanent magnets 37 on a glass plate 38, which was determined using a magnetic field camera with a magnetic field camera head 21 according to the technical teaching presented here.
40 upper housing part 40 of the housing 8 of an exemplary magnetic field camera head 21 of an exemplary magnetic field camera. For example, it may be an upper 3D printed housing part of the exemplary 3D printed housing 8;
41 lower housing portion 41 of the housing 8 of an exemplary magnetic field camera head 21 of an exemplary magnetic field camera. For example, it may be a lower 3D printed housing part of the exemplary 3D printed housing 8;
42 Power supply cable 42 for the PCB 43 with the LEDs 44 of an exemplary magnetic field camera head 21 of an exemplary magnetic field camera;
43 Printed circuit board (PCB) 43 for the LEDs 44 of an exemplary magnetic field camera head 21 of an exemplary magnetic field camera and its power supply 45;
44 LED 44 for exposure of the sensor layer 5 via illumination optics 3, for example in the form of a glass plate 46 as an exemplary optical functional element with pump radiation 13 (LB) with the pump radiation wavelength λₚₘₚ. In the example, the glass plate 46 serves as an optical functional element of an optical waveguide LWL). The edge of the glass plate 46 represents the second end ELWL2 of the optical waveguide LWL, in this case the second end ELWL2 of the glass plate 46, via which the LEDs 44 as pump radiation sources (2, PL) emit the pump radiation 13 (LB) with the pump radiation wavelength λₚₘₚ into the optical waveguide LWL, in this case the glass plate 46. The pump radiation 13 (LB) with the pump radiation wavelength λₚₘₚ then emerges via the surface of the glass plate 46 as the first end ELWL1 of the optical waveguide LWL, in this case the first end ELWL1 of the glass plate 46, from the optical waveguide LWL, in this case the glass plate 46, and into the substrate material TM of the solidified colloidal mixture KL (layer 11) with the diamonds DM and/or nano-diamonds bz. the diamonds and/or crystals ND with the paramagnetic centers and/or NV centers NVZ. The surface of the glass plate 46 represents the first end surface EF1 of the optical waveguide LWL, via which the LEDs 44 as pump radiation sources (2, PL) enter the sensor element SE on the surface of the glass plate 46 (optical waveguide LWL). In the example of the magnetic field camera with the magnetic field sensor head 21, the optical path to the light sensor array 1 represents the second optical waveguide LWL2 as defined in the document presented here;
45 Power supply 45 of the LEDs 44 of the exemplary printed circuit board (PCB) 43 of the magnetic field sensor head 21 of the magnetic field camera;
46 Glass plate 46 as exemplary optical functional elements and exemplary optical waveguide (LWL), which expose the paramagnetic centers of the layer 11 to pump radiation 13 with the pump radiation wavelength λₚₘₚ. Preferably, the layer 11 comprises crystals and/or nano crystals 66 with these paramagnetic centers, which are preferably NV centers. Preferably, the layer 11 comprises a cured colloidal mixture KL of a substrate material TM and diamonds DM and/or diamond nano crystals ND having one or more paramagnetic centers and/or one or more NV centers NVZ. Preferably, the glass plate 46 forms the flat surface 16 of the lower housing part 41 of the housing 8 of the magnetic field sensor head 21 of the exemplary magnetic field camera. The glass plate 46 here also has the function of the substrate material II 12. For the purposes of the document presented here, the glass plate 46 of the magnetic field sensor head 21 of the exemplary magnetic field camera is thus an optical waveguide LWL in which the first end surface ELWL1 is perpendicular to the second end surface ELWL2. The pump radiation LB passes from the first end surface ELWL1 of the optical waveguide LWL, in this case the glass plate 46, into the substrate material TM of the colloidal mixture KL of the layer 11. From the first end surface ELWL1 of the optical waveguide LWL, in this case the glass plate 46, the curing radiation with the curing wavelength λ_{H} passes from the optical waveguide LWL into the substrate material TM of the colloidal mixture KL of layer 11. The pump radiation LB and/or the curing radiation with the curing wavelength λ_{H} is fed in via the second end surface ELWL2 of the optical waveguide LWL, in this case the glass plate 46;
47 dichroitically mirrored optional layer 47. This layer has the function of the optical filter 6 and the dichroitic mirror/optical filter F1 for separating the fluorescence radiation FL (14) from the pump radiation LB (13);
48 Adhesive 48;
49 second heat sink 49 for cooling the printed circuit board (PCB) 43 of the magnetic field sensor head 21 of the exemplary magnetic field camera for the LEDs 44 and their power supply 45 and the LEDs 44. The second heat sink 49 preferably comprises copper as the heat sink material of the second heat sink 49;
50 first heat sink 50 for cooling the evaluation electronics 15 of the light sensor array 1 of the magnetic field sensor head 21 of the exemplary magnetic field camera and/or the light sensor array 1. The first heat sink 50 preferably comprises copper as the heat sink material of the first heat sink 50;
51 cooling fins 51, which are thermally coupled to the first heat sink 50 of the magnetic field sensor head 21 of the exemplary magnetic field camera, for example by means of a heat-conducting paste 53 or the like;
52 Cover 52 of the housing 8 of the magnetic field sensor head 21 of the exemplary magnetic field camera;
53 Heat-conducting paste 53 of the magnetic field sensor head 21 of the exemplary magnetic field camera;
54 Camera housing 54 of the fluorescence camera with the light sensor array 1 with its evaluation electronics 15 and the imaging optics 7. This is an exemplary housing 8 of the magnetic field sensor head 21 of the exemplary magnetic field camera;
55 Power supply line 55 for supplying power to the printed circuit board (PCB) 43 of the magnetic field sensor head 21 of the exemplary magnetic field camera for the LEDs 44 and its power supply 45 and the LEDs 44 56 Connector 56 for the power supply line 55 for the power supply of the printed circuit board (PCB) 43 of the magnetic field sensor head 21 of the exemplary magnetic field camera for the LEDs 44 and their power supply 45 and the LEDs 44;
57 elastic and thermally conductive material 57 of the magnetic field sensor head 21 of the exemplary magnetic field camera;
58 Thermally conductive insulation film 58 of the magnetic field sensor head 21 of the exemplary magnetic field camera;
59 LED series resistors 59 of the LEDs 44 on the printed circuit board (PCB) 43 of the magnetic field sensor head 21 of the exemplary magnetic field camera for the LEDs 44; 60 electronic components 60 of the power supply of the LEDs 44 on the printed circuit board (PCB) 43 of the magnetic field sensor head 21 of the exemplary magnetic field camera;
61 The voltage regulator and/or control transistor 61 is typically an electronic component 60 of the power supply of the LEDs 44 on the printed circuit board (PCB) 43 of the magnetic field sensor head 21 of the exemplary magnetic field camera. The voltage regulator and/or control transistor 61 is typically the actuator of the voltage regulation of the power supply of the LEDs 44 on the printed circuit board (PCB) 43 of the magnetic field sensor head 21 of the exemplary magnetic field camera;
62 Coding plug 62 for changing analog operating parameters of the electronic circuit on the printed circuit board (PCB) 43 of the magnetic field sensor head 21 of the exemplary magnetic field camera
63 Fastening means for the exemplary fastening of the auxiliary magnet 19 to the cover 52 of the housing of the magnetic field sensor head 21 of the exemplary magnetic field camera;
64 Access opening 64 in the lower housing part 41 of the housing 8 on the underside of the housing 8 of the magnetic field sensor head 21 of the exemplary magnetic field camera, which the coding position of the jumper of the coding plug 62 to be changed and thus analog operating parameters of the electronic circuit on the printed circuit board (PCB) 43 to be changed after the housing 8 of the magnetic field sensor head 21 of the exemplary magnetic field camera has been closed. For this purpose, however, the coding plug 64 must be mounted on the other side of the printed circuit board (PCB) 43 of the magnetic field sensor head 21 of the exemplary magnetic field camera as shown in FIGS. 30, 31, 35, 38, 39. In developing the technical teaching of this document, it was realized that coding on this side of the printed circuit board (PCB) 43 using solder bridges instead of jumpers and coding plugs 62 is more efficient and durable;
65 Opening 65 in the printed circuit board (PCB) 43 of the magnetic field sensor head 21 of the exemplary magnetic field camera for the LEDs 44. The opening 65 serves to allow the fluorescence radiation 14 of the paramagnetic centers, for example the NV centers, in the layer 11 of the sensor layer 5 on the underside of the glass plate 46 of the magnetic field sensor head 21 of the exemplary magnetic field camera to pass through the glass plate 46 and the opening in the printed circuit board (PCB) 43 to the light sensor array 1 of the magnetic field sensor head 21 of the exemplary magnetic field camera
66 Crystal, preferably diamond nano crystals 66 and/or diamond with preferably several paramagnetic centers and/or one or more NV centers NVZ;
67 first surface 67 of the first optical functional element (glass plate 46 of the magnetic field sensor head 21 of the exemplary magnetic field camera);
68 second surface 68 of the first optical functional element (glass plate 46 of the magnetic field sensor head 21 of the exemplary magnetic field camera);
69 In the sense of the technical teaching of the document presented here, the diffuser layer 69 can also a diffuser structure on the first surface 67 or on the second surface 68 of the first optical functional element, in particular the glass plate 46 of the magnetic field sensor head 21 of the exemplary magnetic field camera. Preferably, the diffuser layer 69 is located on the first surface 67 of the first optical functional element of the sensor layer 5—in this case the glass plate 46 of the magnetic field sensor head 21 of the exemplary magnetic field camera;
70 Connecting line of the LEDs 44;
71 Connector and/or socket 71 of the microwave signal μW and/or the RF signal RW to a waveguide (1380, 1880, 2380, 6830, 6980) on the surface of the carrier substrate 1360. In the case of the connection of a differential microstrip waveguide 6830 or a differential trip-plate waveguide 6980, the connector and/or socket 71 is preferably designed as a triax-connector or triax-socket. Information on this can be found on the Internet at the URL https://de.wikipedia.org/wiki/Triaxialkabel. The technical teaching disclosed here thus describes a connection of a waveguide on the carrier substrate 1360 by means of a triax-cable and, if applicable, the associated triax-connections.
72 Memory 72 and/or storage medium of the computer core 33 in the computer system 38; The memory 72 and/or storage medium may comprise volatile memory RAM and non-volatile memory ROM.
λ_{FL} Fluorescence radiation wavelength λ_{fl} of the fluorescence radiation 14 (FL);
λₚₘₚ Pump radiation wavelength λₚₘₚ of the pump radiation 13 (LB);
140 Deployment 140 of an optical waveguide LWL, wherein the optical waveguide LWL comprises a first end ELWL1 and a second end ELWL2;
145 Deployment 145 of a liquid substrate material TM which is curable by means of electromagnetic radiation of a curing wavelength λ_{H}, wherein a multiplicity of diamonds DM or nano-diamonds are embedded in the substrate material (TM) and wherein one or more or all of the diamonds DM or nano-diamonds DM have NV centers NVZ and/or other paramagnetic centers and wherein the NV centers NVZ of the substrate material TM and/or the other paramagnetic centers of the substrate material T have NV centers NVZ and/or other paramagnetic centers of the substrate material TM. nanodiamonds of these diamonds DM comprise NV centers NVZ and/or other paramagnetic centers and wherein the NV centers NVZ of the substrate material TM and/or the other paramagnetic centers of the substrate material TM emit at least one fluorescence radiation FL upon exposure to pump radiation LB;
147 if necessary, pre-baking 147 (pre-bake) of the sensor element SE by a preceding temperature treatment;
150 Wetting 150 of the first end of the optical waveguide TM to a wetting length LTM with the substrate material TM comprising the multiplicity of embedded diamonds DM or nano-diamonds and/or crystals with one or more NV centers and/or one or more paramagnetic centers;
155 Injection 155 of electromagnetic radiation into the second end ELWL2 of the optical waveguide LWL, the wavelength of this electromagnetic radiation, the curing wavelength λ_{H}, being selected such that the substrate material TM at the second end ELWL2 of the optical waveguide LWL hardens and transforms into a solid, the hardened substrate material TM forming the sensor element SE;
160 Removal 160 of the uncured substrate material TM, in particular by means of a solvent, the remaining film of the substrate material TM at the first end of the optical waveguide LWL) forming the sensor element;
165 if necessary, post-baking 165 (post-bake) of the sensor element SE by subsequent temperature treatment;
167 Deployment 167 of a sensor head housing GH of the sensor head SK and an excitation source for a magnetic excitation H, in particular a permanent magnet PM (in application example I);
170 Installation 170 of the optical waveguide LWL with the newly formed sensor element SE in the channel KN of the sensor head housing GH of the sensor head SK and installation of an excitation source for a magnetic excitation H in the sensor head housing GH of the sensor head SK (in application example I);
180 Use 180 of the sensor head SK for spatially resolved measurement of the magnetic properties of the material of a workpiece in the vicinity of the surface OF of the workpiece (in application example I), wherein the spatial resolution is better than 500 μm and/or better than 200 μm and/or better than 100 μm and/or better than 50 μm and/or better than 20 μm and/or better than 10 μm. Resolution is the possibility of being able to detect two adjacent disturbances of the magnetic properties of a surface OF a workpiece by an extremum of 5% of the signal amplitude if they are spaced apart according to the resolution. Such disturbances can be, for example, cracks, blowholes, material inhomogeneities, etc.
182 Deployment 182 of a housing GH of the motor;
185 Installation 185 of the optical waveguide LWL) with the newly formed sensor element SE in the opening OF of the housing GH of the motor;
187 Use 187 of the optical waveguide LWL) with the newly formed sensor element SE for measuring the magnetic flux density B within the air gap LS of the motor or in the stray field BSTR of the magnetic field in the air gap LS.
190 if necessary, determination 190 of the points in time of the zero crossing of the absolute value of the magnetic flux density B of the magnetic flux density B within the air gap LS of the motor or in the stray field BSTR of the magnetic field in the air gap LS and/or, if necessary, determination 190 of the absolute value of the magnetic flux density B of the magnetic flux density B within the air gap LS of the motor or in the stray field BSTR of the magnetic field in the air gap LS.
193 If necessary, determine 193 or estimate the position of the magnetic field within the air gap of the motor.
195 If necessary, commutation 195 of the current supply to one or more stator coils of the motor and/or one or more rotor coils of the motor as a function of
   a) from the determined zero crossing times of the absolute value of the magnetic flux density B of the magnetic flux density B within the air gap LS of the motor or in the stray field BSTR of the magnetic field in the air gap LS and/or
   b) from the determined absolute value of the magnetic flux density B of the magnetic flux density B within the air gap LS of the motor or in the stray field BSTR of the magnetic field in the air gap LS and/or from the determined or estimated position of the magnetic field within the air gap of the motor
511 Diagram of the resonance lines of the proportion with microwave modulation frequency f_{μW} of the intensity Iᵢₛₜ of the fluorescence radiation FL of a diamond single crystal provided with NV centers as a function of the microwave frequency ω_{μW} and of the magnetic flux density B. The microwave frequency ω_{(μW) is} plotted on the x-axis of the diagram 511. The magnetic flux density B is plotted on the Y-axis of diagram 511 in arbitrary units (abbreviated to “au”). In the example, a single diamond crystal in [111] is oriented with respect to the direction of the magnetic flux density B of a magnetic field. The behavior shown in diagram 511 is known from the prior art;
512 Resonance line of NV centers of a diamond single crystal for the spin quantum number mₛ=−1, which is aligned in the [111] direction with respect to the magnetic flux density B of the magnetic field and wherein the NV centers of the diamond single crystal interacting at this resonance line are aligned in the [111] direction of the diamond single crystal. The B component of the microwave field is oriented perpendicular to the magnetic flux density B of the magnetic field. The resonance line corresponds to the spin quantum number mₛ=−1;
513 Resonance of a single crystal aligned with respect to the magnetic field in the [111] direction and wherein the NV centers of the diamond single crystal interacting at this resonance line are aligned in one of the three other crystal directions of the diamond single crystal with respect to the [111] direction of the diamond single crystal. The B component of the microwave field is oriented perpendicular to the magnetic flux density B of the magnetic field. The resonance line corresponds to the spin quantum number mₛ=−1
514 Resonance line of NV centers of a diamond single crystal for the spin quantum number mₛ=+1, which is aligned with respect to the magnetic flux density B of the magnetic field in the [111] direction and wherein the NV centers of the diamond single crystal interacting at this resonance line are aligned in one of the three other crystal directions of the diamond single crystal with respect to the [111] direction of the diamond single crystal. The B component of the microwave field is oriented perpendicular to the magnetic flux density B of the magnetic field. The resonance line corresponds to the spin quantum number mₛ=+1;
515 Resonance line of NV centers of a diamond single crystal for the spin quantum number mₛ=+1, which is aligned in the [111] direction with respect to the magnetic flux density B of the magnetic field and wherein the NV centers of the diamond single crystal interacting at this resonance line are aligned in the [111] direction of the diamond single crystal. The B component of the microwave field is oriented perpendicular to the magnetic flux density B of the magnetic field. The resonance line corresponds to the spin quantum number mₛ=+1;
520 Diagram of the resonance of the intensity Iᵢₛₜ of the fluorescence radiation FL or the change in the intensity Iᵢₛₜ of the fluorescence radiation FL of a collective of diamond crystals, which are oriented differently in space, randomly and essentially equally distributed in relation to one another, as a function of the microwave frequency ω_{μW} and of the magnetic flux density B. The microwave frequency ω(μW) is plotted on the x-axis of the diagram. The magnetic flux density B is plotted on the Y-axis in arbitrary units. (In the example, the diamonds of the multiplicity of diamond crystals are aligned in different directions with respect to the magnetic field. This behavior is known from the state of the art.
522 lower resonance edge 522. This is the lower resonance edge of the intensity Iᵢₛ of the fluorescence radiation FL or of the change in the intensity Iᵢₛ of the fluorescence radiation FL of the resonance field of the intensity Iᵢₛ of the fluorescence radiation FL of a collective of diamond crystals which are oriented differently in space, randomly and essentially uniformly distributed with respect to one another, as a function of the microwave frequency ω_{μW} and of the magnetic flux density B. The microwave frequency ω(MW) is plotted on the x-axis of the diagram. The magnetic flux density B is plotted on the Y-axis in arbitrary units. (In the example, the diamonds of the multiplicity of diamond crystals are aligned in different directions with respect to the magnetic flux density B of the magnetic field.
523 lower mean resonance edge 523. This is the lower mean resonance edge of the intensity Iᵢₛ of the fluorescence radiation FL or the change in the intensity Iᵢₛ of the fluorescence radiation FL of the resonance field of the intensity Iᵢₛ of the fluorescence radiation FL of a collective of diamond crystals, which are oriented differently in space, randomly and essentially equally distributed in relation to one another, as a function of the microwave frequency ω_{μW} and of the magnetic flux density B. The microwave frequency ω(MW) is plotted on the x-axis of the diagram. The magnetic flux density B is plotted on the Y-axis in arbitrary units. (In the example, the diamonds of the multiplicity of diamond crystals are aligned in different directions with respect to the magnetic flux density of the magnetic field.
524 upper mean resonance edge 524. This is the upper mean resonance edge of the intensity Lis of the fluorescence radiation FL or the change in the intensity Iᵢₛ of the fluorescence radiation FL of the resonance field of the intensity Iᵢₛ of the fluorescence radiation FL of a collective of diamond crystals which are oriented differently in space, randomly and essentially uniformly distributed relative to one another, as a function of the microwave frequency ω_{μW} and of the magnetic flux density B. The microwave frequency ω_{(μW) is} plotted on the x-axis of the diagram. The magnetic flux density B is plotted on the Y-axis in arbitrary units. (In the example, the diamonds of the multiplicity of diamond crystals are aligned in different directions with respect to the magnetic flux density of the magnetic field.
525 Upper resonance edge 525. This is the upper resonance edge of the intensity Iᵢₛ of the fluorescence radiation FL or the change in the intensity Iᵢₛ of the fluorescence radiation FL of the resonance field of the intensity Iᵢₛ of the fluorescence radiation FL of a collective of diamond crystals, which are oriented differently in space, randomly and essentially uniformly distributed in relation to each other, as a function of the microwave frequency ω_{μW} and of the magnetic flux density B. The microwave frequency ω(MW) is plotted on the x-axis of the diagram. The magnetic flux density B is plotted on the Y-axis in arbitrary units. (In the example, the diamonds of the multiplicity of diamond crystals are aligned in different directions with respect to the magnetic flux density of the magnetic field.
526 lower resonance sub-field. This is the lower resonance sub-field of the intensity Iᵢₛ of the fluorescence radiation FL or the change in the intensity Iᵢₛ of the fluorescence radiation FL of the resonance field of the intensity Iᵢₛ of the fluorescence radiation FL of a collective of diamond crystals, which are oriented differently in space, randomly and essentially equally distributed in relation to one another, as a function of the microwave frequency ω_{μW} and of the magnetic flux density B. The microwave frequency ω(W) is plotted on the x-axis of the diagram. The magnetic flux density B is plotted on the Y-axis in arbitrary units. (In the example, the diamonds of the multiplicity of diamond crystals are aligned in different directions with respect to the magnetic flux density of the magnetic field. The lower resonance edge 522 limits the lower resonance sub-field 26 towards lower microwave frequencies ω_{μW} and towards lower magnetic flux densities B. The lower middle resonance edge 523 limits the lower resonance sub-field 526 to higher microwave frequencies ω_{μW} and to lower magnetic flux densities B. An offset flux density B_{off} further limits the lower resonance sub-field 526 towards lower magnetic flux densities B.
527 upper resonance sub-field. This is the upper resonance sub-field of the intensity Iᵢₛₜ of the fluorescence radiation FL or the change in the intensity Iᵢₛₜ of the fluorescence radiation FL of the resonance field of the intensity Iᵢₛₜ of the fluorescence radiation FL of a collective of diamond crystals, which are oriented differently in space, randomly and essentially equally distributed in relation to one another, as a function of the microwave frequency ω_{μW} and of the magnetic flux density B. The microwave frequency ω(W) is plotted on the x-axis of the diagram. The magnetic flux density B is plotted on the Y-axis in arbitrary units. (In the example, the diamonds of the multiplicity of diamond crystals are aligned in different directions with respect to the magnetic flux density of the magnetic field. The upper resonance edge 525 limits the upper resonance sub-field 527 towards lower microwave frequencies ω_{μW} and towards higher magnetic flux densities B. The upper middle resonance edge 24 limits the upper resonance sub-field 527 towards higher microwave frequencies ω_{μW} and towards higher magnetic flux densities B. An offset flux density B_{off} further limits the upper resonance sub-field 527 towards lower magnetic flux densities B.
528 Lower resonance field. This is the lower resonance sub-field of the intensity Iᵢₛ of the fluorescence radiation FL or the change in the intensity Lis of the fluorescence radiation FL of the resonance field of the intensity Iᵢₛ of the fluorescence radiation FL of a collective of diamond crystals, which are oriented differently in space, randomly and essentially equally distributed in relation to one another, as a function of the microwave frequency ω_{μW} and of the magnetic flux density B. The microwave frequency ω_{(μW) is} plotted on the x-axis of the diagram. The magnetic flux density B is plotted on the Y-axis in arbitrary units. (In the example, the diamonds of the multiplicity of diamond crystals are aligned in different directions with respect to the magnetic flux density of the magnetic field. The lower resonance edge 522 limits the lower resonance field 528 to lower microwave frequencies ω_{μW} and to lower magnetic flux densities B. The upper resonance edge 525 limits the lower resonance sub-field 528 towards higher microwave frequencies ω_{μW} and towards lower magnetic flux densities B. An offset flux density B_{off} further limits the lower resonant field 528 towards higher magnetic flux densities B.
529 middle resonance minimum 529. This is the middle resonance minimum of the intensity Iᵢₛ of the fluorescence radiation FL or of the change in the intensity Iᵢₛ of the fluorescence radiation FL of the resonance field of the intensity Iᵢₛ of the fluorescence radiation FL of a collective of diamond crystals which are oriented differently in space, randomly and essentially uniformly distributed with respect to one another, as a function of the microwave frequency ω_{μW} and of the magnetic flux density B. The microwave frequency ω(μW) is plotted on the x-axis of the diagram. The magnetic flux density B is plotted on the Y-axis in arbitrary units. (In the example, the diamonds of the multiplicity of diamond crystals are aligned in different directions with respect to the magnetic flux density of the magnetic field. The resonance minimum runs between the lower middle resonance edge 523 and the upper middle resonance edge 524, and an offset flux density B_{off} further limits the resonance minimum 529 towards smaller magnetic flux densities B.
530 Top of the V-formation 530 consisting of a lower resonance edge 522 and an upper resonance edge 525;
541 Line 541 along which the operating point of the sensor element (SE) moves when, for example, the device changes the effective magnetic reference flux density B_{ref} by means of changing the additional effective magnetic flux density B_{adw} in order to determine an unknown microwave frequency ω_{(μWnk)};
542 Intersection 542 of line 543 with the lower resonance edge 522; line 543 along which the operating point of the sensor element SE moves, if, for the determination of an unknown microwave frequency ω_{μWnk}, the device, for example, mixes a microwave signal μW with the varied microwave frequency ω_{μW} and microwave signal portions with a mixed microwave frequency of ω_{μWmix+}=ω_{μWnk}+ω_{μW} and ω_{μWmix-}=ω_{μWnk}−ω_{μW} result within the sensor element SE). result;
545 Intersection 545 of line 543 with the upper resonance edge 525;
561 Upper reference line 561;
562 Lower reference line 562;
563 middle reference line 563;
564 Value 564 of the magnetic flux density B₆₁ assigned to the upper reference line 561;
565 Value 565 of the magnetic flux density B₆₂ assigned to the lower reference line 562;
566 Difference 566 of the value of the magnetic flux density B₆₃ assigned to the middle reference line 563 minus the value 565 of the magnetic flux density B₆₂ assigned to the lower reference line 562;
567 Gradient 567 of the curve;
627 Polynominal approximation 627 of the curve;
1310 electrically conductive left signal ground plane 1310 of the exemplary slot line 1880 or the exemplary trip-plate waveguide 2380 or exemplary differential trip-plate waveguide 6980;
1320 electrically conductive right signal ground plane 1320 exemplary slot line 1880 or exemplary trip-plate waveguide 2380 or exemplary differential trip-plate waveguide 6980;
1330 Signal conductor 1330 of the exemplary microstrip line 1380 or exemplary differential microstrip line 6880 or exemplary trip-plate waveguide 2380 or exemplary differential trip-plate waveguide 6980;
1340 electrically essentially non-conductive left-hand insulation area 1340. For the purposes of the document presented here, this is a clearances through which, in the case of an optical for curing radiation 4910 of a curing wavelength λ_{H}, curing radiation can escape from the carrier substrate 1360 into a possibly applied substrate material TM and/or through which pump radiation LB can pass from the carrier substrate 1360 into an applied sensor element SE;
1350 electrically essentially non-conductive right-hand insulation area 1350. For the purposes of the document presented here, this is a clearances through which, in the case of an optical for curing radiation 4910 of a curing wavelength λ_{H}, curing radiation can escape from the carrier substrate 1360 into a substrate material TM that may have been applied and/or through which pump radiation LB can pass from the carrier substrate 1360 into a sensor element SE that has been applied;
1360 Carrier substrate 1360. In particular, the carrier substrate 1360 can be the carrier substrate of the exemplary trip-plate waveguide 2380 or the exemplary microstrip line 1380 or exemplary differential microstrip line 6880 or exemplary slot line 1880 or exemplary trip-plate waveguide 2380 or exemplary differential trip-plate waveguide 6980. Preferably, the carrier substrate 1360 is a dielectric substrate such as a ceramic with a high dielectric constant εᵣ. The carrier substrate 1360 may also be a semiconductor wafer, such as a silicon wafer or a CMOS wafer or a BICMOS wafer or a wafer from a bipolar semiconductor process or a wafer from a III/V material or a wafer from a II/VI material or a wafer from a mixed crystal semiconductor material or a diamond wafer or a diamond-coated wafer. Also, the carrier substrate 1360 may be an insulation layer of a micro integrated circuit and/or a MEMS device or a micro-optical system or a micro-electro-optical system or a micro-fluidic system or the like.
1370 Electrically conductive backside contact 1370 of the exemplary microstrip line 1380 or exemplary differential microstrip line 6880 or exemplary slot line 1880 or exemplary trip-plate waveguide 2380 or exemplary differential trip-plate waveguide 6980;
1380 The exemplary single microstrip line 1380 comprises a preferably non- or only slightly electrically conductive carrier substrate 1360, an electrically conductive backside contact 1370 on the underside of the electrically non-conductive carrier substrate 1360, an electrically conductive signal line 1330 on the top side of the electrically non-conductive carrier substrate 1360. An electrically essentially non-conductive left insulation area 1340 separates the electrically conductive signal line 1330 from other circuit parts. In addition, an electrically essentially non-conductive right insulation area 1350 separates the electrically conductive signal line 1330 from other circuit parts. Preferably, individual microstrip line 1380 comprises a characteristic impedance with respect to the electrically conductive signal line 1330 as “hot” inner conductor and the electrically conductive backside contact 1370 as ground electrode;
1410 Left-hand sensor element SE(1410)
   to the left of the electrically conductive signal line 1330 on the essentially electrically non-conductive left-hand insulation area 1340 of the exemplary microstrip line 1380 or
      to the left of the electrically conductive left signal line 6810 on the essentially non-conductive left insulation area 1340 of the exemplary differential microstrip line 6880 or
      to the left of the electrically conductive signal line 1330 in the non-conductive left insulation gap 2340 between the electrically conductive left signal ground plane 1310 of the exemplary triplate line 2380 and the electrically conductive signal line 1330 or
   to the left of the electrically conductive left signal line 6810 in the non-conductive left insulation gap 2340 between the electrically conductive left signal ground plane 1310 of the exemplary differential triplate line 6980 and the electrically conductive left signal line 6810 of the exemplary differential triplate line 6980 or
   left of the slot 1840 of the slot line 1880 on the electrically conductive left signal ground plane 1310 of the exemplary slot line 1880;
1420 middle sensor element SE(1420) on the electrically conductive signal line 1330 of the exemplary triplate line 2380 or in the gap 6840 between the electrically conductive left signal line 6810 of the differential signal line 6830 of the exemplary differential triplate line 6980 and that of the electrically conductive right signal line 6820 of the differential signal line 6830 of the exemplary differential triplate line 6980 or on the electrically conductive signal line 1330 of the exemplary microstrip line 1380 or in the gap 6840 between the electrically conductive left signal line 6810 of the differential signal line 6830 of the exemplary differential microstrip line 6880 and that of the electrically conductive right signal line 6820 of the differential signal line 6830 of the exemplary differential microstrip line 6880 or in slot 1840 of slot line 1880;
1430 Right-hand sensor element SE(1430)
   to the right of the electrically conductive signal line 1330 on the electrically essentially non-conductive right-hand insulation area 1350 of the exemplary microstrip line 1380 or
   to the right of the electrically conductive right signal line 6820 on the electrically essentially non-conductive right insulation area 1350 of the exemplary differential microstrip line 6880 or
      to the right of the electrically conductive signal line 1330 in the non-conductive right-hand insulation gap 2350 between the electrically conductive right-hand signal ground plane 1320 of the exemplary triplate line 2380 and the electrically conductive signal line 1330 or
      to the right of the electrically conductive right signal line 6820 in the non-conductive right insulation gap 2350 between the electrically conductive right signal ground plane 1320 of the exemplary differential triplate line 6980 and the electrically conductive right signal line 6820 of the exemplary differential triplate line 6980, respectively
      to the right of the slot 1840 of the slot line 1880 on the electrically conductive right signal ground plane 1320 of the exemplary slot line 1880;
1440 Direction of the vector 1440 of the magnetic flux density B_{μW} of the microwave field of the microwave signal μW,
a) which the microwave signal source μWG feeds into the signal line 1330, in the region of the sensor element SE, if the sensor element SE is placed to the left of the signal line 1330 and it is microstrip line 1380, or
b) which feeds the microwave signal source μWG into the signal line 1330, in the region of the sensor element SE, if the sensor element SE is placed to the left of the signal line 1330 and is a triplate line 2380, or
c) which the microwave signal source μWG into the slot 1840 of the slot line 1880, in the region of the sensor element SE, if the sensor element SE is placed in the slot 1840 of the slot line 1880 and it is a slot line 1880;
1450 Direction of the vector 1450 of the magnetic flux density B_{μW} of the microwave field of the microwave signal μW,
a) which the microwave signal source μWG feeds into the signal line 1330, in the region of the sensor element SE, if the sensor element SE is placed on the signal line 1330 and it is microstrip line 1380, or
b) which feeds the microwave signal source μWG into the signal line 1330, in the region of the sensor element SE, if the sensor element SE is placed on the signal line 1330 and it is a triplate line 2380, or
c) which the microwave signal source μWG into the slot line 1880, in the region of the sensor element SE, if the sensor element SE is placed on electrically conductive left signal ground plane 1310 and it is a slot line 1880, or
d) which the microwave signal source μWG into the slot line 1880, in the region of the sensor element SE, if the sensor element SE is placed on electrically conductive right signal ground plane 1320 and it is a slot line 1880;
1460 Direction of the vector 1460 of the magnetic flux density B_{μW} of the microwave field of the microwave signal μW,
a) which the microwave signal source μWG feeds into the signal line 1330, in the region of the sensor element SE, if the sensor element SE is placed to the right of the signal line 1330 and it is microstrip line 1380, or
b) which feeds the microwave signal source μWG into the signal line 1330, in the region of the sensor element SE, if the sensor element SE is placed to the right of the signal line 1330 and is a triplate line 2380, or
c) which the microwave signal source μWG into the slot 1840 of the slot line 1880, in the region of the sensor element SE, if the sensor element SE is placed in the slot 1840 of the slot line 1880 and it is a slot line 1880;
1710 Sensor element SE(1710) surrounding the electrically conductive signal line 1330. In the broadest sense, the sensor element SE(1710) is a combination of the sensor elements 1410, 1420 and 1430;
1840 Slot 1840 of slot line 1880. For the purposes of the present document, slot 1840 of slot line 1880 is also referred to as a clearances of slot line 1880. Slot 1840 of slot line 1880 is a non-conductive insulation gap for the purposes of the present document. For the purposes of the present document, it is a clearance through which, in the case of an optical for curing radiation 4910 of a curing wavelength λ_{H}, curing radiation can escape from the carrier substrate 1360 into a possibly applied substrate material TM and/or through which pump radiation LB can pass from the carrier substrate 1360 into an applied sensor element SE;
1880 Slot line 1880. The exemplary slot line 1880 comprises a preferably non- or only slightly electrically conductive carrier substrate 1360, an electrically conductive backside contact 1370 on the underside of the electrically non-conductive carrier substrate 1360, an electrically conductive left signal ground plane 1310 of the exemplary slot line 1880 on the upper side of the electrically non-conductive carrier substrate 1360 and an electrically conductive right signal ground plane 1320 of the exemplary slot line 1880 on the upper side of the electrically non-conductive carrier substrate 1360. Here, an electrically essentially non-conductive left insulation area 1340 separates the electrically conductive signal line 1330 from other circuit parts. In addition, an electrically essentially non-conductive slot 1840 of slot line 1880 separates the electrically conductive left signal ground plane 1310 of exemplary slot line 1880 from the electrically conductive right signal ground plane 1320 of exemplary slot line 1880. Preferably, slot line 1880 comprises a characteristic impedance with respect to the electrically conductive left signal ground plane 1310 of exemplary slot line 1880 and the electrically conductive right signal ground plane 1320 of exemplary slot line 1880 as “hot” outer conductor and the electrically conductive backside contact 1370 as ground electrode;
Sensor element SE(2210) covering the slot 1840 of the slot line 1880;
2340 essentially non-conductive left-hand insulation gap 23402. For the purposes of the document presented here, this is a clearances through which, in the case of an optical curing radiation 4910 of a curing wavelength (H), curing radiation can escape from the carrier substrate 1360 into a substrate material TM that may have been applied and/or through which pump radiation LB can pass from the carrier substrate 1360 into a sensor element SE that has been applied;
2350 An essentially electrically non-conductive right-hand insulation gap 2350. For the purposes of the document presented here, this is a clearances through which, in the case of an optical for curing radiation 4910 of a curing wavelength λ_{H}, curing radiation can escape from the carrier substrate 1360 into a substrate material TM that may have been applied and/or through which pump radiation LB can pass from the carrier substrate 1360 into a sensor element SE that has been applied;
2380 Trip-plate waveguide 2380. The exemplary trip-plate waveguide 2380 comprises a preferably non- or only slightly electrically conductive carrier substrate 1360, an electrically conductive backside contact 1370 on the underside of the electrically non-conductive carrier substrate 1360, an electrically conductive left signal ground plane 1310 on the upper side of the electrically non-conductive carrier substrate 1360, an electrically conductive right signal ground plane 1320 on the upper side of the electrically non-conductive carrier substrate 1360, an electrically conductive signal line 1330 on the upper side of the electrically non-conductive carrier substrate 1360 between the electrically conductive left signal ground plane 1310 and the electrically conductive right signal ground plane 1320. Here, an electrically essentially non-conductive left insulation gap 2340 separates the electrically conductive signal line 1330 from the electrically conductive left signal ground plane 1310. In addition, an electrically essentially non-conductive right insulation gap 2350 separates the electrically conductive signal line 1330 from the electrically conductive right signal ground plane 1320. Preferably, the trip-plate waveguide 2380 comprises a characteristic impedance with respect to the electrically conductive signal line 1330 as “hot” inner conductor and the community of electrically conductive left signal ground plane 1310, electrically conductive right signal ground plane 1320 and electrically conductive backside contact 1370 as ground electrodes;
   left sensor element SE(2410) covering the non-conductive left insulation gap 2340 of the trip-plate waveguide 2380;
   center sensor element SE(2420) covering the electrically conductive signal line 1330 of the trip-plate waveguide 2380;
   right sensor element SE(2430) covering the non-conductive right insulation gap 2350 of the trip-plate waveguide 2380;
2510 Insulation layer 2510;
2520 Flat coil 2520 as magnetic field generation means L_{C};
4410 Large sensor element SE(4410) to which the middle sensor element SE(1420) and the right sensor element SE(1430) and the left sensor element SE(1410) are fused;
4510 left through hole contact 4510 electrically connecting the electrically conductive left signal ground plane 1310 of the exemplary slot line 1880 or the exemplary triplate line 2380 or the exemplary differential triplate line 6980 to the electrically conductive backside contact 1370 of the exemplary triplate line 2380 or the exemplary differential triplate line 6980 or the exemplary slot line 1880;
4520 right through hole contact 4520, which electrically connects the electrically conductive right signal ground plane 1320 of the exemplary slot line 1880 or the exemplary triplate line 2380 or the exemplary differential triplate line 6980 to the electrically conductive backside contact 1370 of the exemplary triplate line 2380 or the exemplary differential triplate line 6980 or the exemplary slot line 1880;
4610 Left optical waveguide (LWL) (4610);
4620 right optical waveguide (LWL) (4620);
4630 medium optical waveguide LWL (4630);
4810 Sensor element layer 4810;
4910 Curing radiation 4910 with the curing wavelength λ H;
5210 Left adjustment mark 5210;
5220 right adjustment mark 5220;
6710 The terminal resistors 6710 can, for example, be connected between the leads of the respective waveguide and/or the leads and the electrically conductive backside contact 1370;
6810 left signal conductor 6810 of the differential signal conductor 6830;
6820 right signal conductor 6820 of the differential signal conductor 6830;
6830 differential signal conductor 6830 of the exemplary differential microstrip line 6830 or of the exemplary differential triplate line 7080. The differential signal conductor 6830 can also transfer signals simultaneously in common mode operation and in push-pull operation if necessary. In common mode operation, the differential signal conductor 6830 behaves like the signal conductor 1330 of the exemplary microstrip line 1380 or the exemplary triplate line 2380; 6840 electrically insulating gap 6840 between the left signal conductor 6810 and the right signal conductor 6820 of the differential signal conductor 6830. For the purposes of the present document, the electrically insulating gap 6840 between the left signal conductor 6810 and the right signal conductor 6820 of the differential signal conductor 6830 is also referred to as the clearances of the differential signal conductor 6830. The electrically insulating gap 6840 is a non-conductive insulation gap for the purposes of the present document. For the purposes of the present document, it is a clearance through which, in the case of an optical for curing radiation 4910 of a curing wavelength λ_{H}, curing radiation can escape from the carrier substrate 1360 into a possibly applied substrate material TM and/or through which pump radiation LB can pass from the carrier substrate 1360 into an applied sensor element SE;
6880 differential microstrip line 6880. The exemplary differential microstrip line 6880 comprises a preferably non-conductive or low electrically conductive carrier substrate 1360, an electrically conductive backside contact 1370 on the underside of the electrically non-conductive carrier substrate 1360, an electrically substantially non-conductive left insulation area 1340 on the top of the electrically non-conductive carrier substrate 1360, electrically substantially non-conductive right insulation area 1350 on the top of the electrically non-conductive carrier substrate 1360, a left electrically conductive signal line 6810 on the upper side of the electrically non-conductive carrier substrate 1360 between the electrically essentially non-conductive left insulation area 1340 on the one hand and the electrically insulating gap 6840 between the left signal conductor 6810 and the right signal conductor 6820 of the differential signal conductor 6830 on the other hand, a right electrically conductive signal line 6820 on the upper side of the electrically non-conductive carrier substrate 1360 between the electrically insulating gap 6840 between the left signal conductor 6810 and the right signal conductor 6820 of the differential signal conductor 6830 on the one hand and the electrically essentially non-conductive right insulation area 1350 on the other hand. The electrically insulating gap 6840 between the left signal conductor 6810 and the right signal conductor 6820 of the differential signal conductor 6830 electrically insulates the left signal conductor 6810 from the right signal conductor 6820 of the differential signal conductor 6830. The left signal conductor 6810 and the right signal conductor 6820 together form the differential signal conductor 6830 of the differential microstrip line 6880. The document presented herein also refers to the electrically insulating gap 6840 between the left signal conductor 6810 and the right signal conductor 6820 of the differential signal conductor 6830 as the clearances of the differential signal conductor 6830. The document provided herein also refers to the electrically insulating gap 6840 between the left signal conductor 6810 and the right signal conductor 6820 of the differential signal conductor 6830 of the differential microstrip line 6880 as the clearances of the differential signal conductor 6830 of the differential microstrip line 6880. The document presented here also refers to the electrically insulating gap 6840 between the left signal conductor 6810 and the right signal conductor 6820 of the differential signal conductor 6830 of the differential microstrip line 6880 as the clearances of the differential microstrip line 6880. The differential microstrip line 6880 can be driven with a common-mode signal, in which the same signal is fed into the left signal conductor 6810 and the right signal conductor 6820 of the differential signal conductor 6830 in a time-synchronized manner. This operating state is called common-mode drive with a common-mode signal. The differential microstrip line 6880 can be controlled with a push-pull clock signal, in which the same signal is fed into the left signal conductor 6810 and the right signal conductor 6820 of the differential signal conductor 6830 in a time-synchronized manner, but with a different sign. This operating state is called push-pull control with a push-pull signal. Preferably, the differential microstrip line 6880 comprises a common-mode wave resistor for a common-mode drive and a differential-mode wave resistor for a push-pull drive in relation to the differential signal conductor 6830 as a “hot” inner conductor;
6980 differential trip-plate waveguide 6980;
7110 left line sensor element SE(7110) on the electrically conductive left signal line 6810 of the differential signal line 6830 of the differential microstrip line 6880 of the exemplary differential triplate line 6980 or on the electrically conductive left signal line 6810 of the differential signal line 6830 of the differential microstrip line 6880;
7120 right line sensor element SE(7120) on the electrically conductive right signal line 6820 of the differential signal line 6830 of the differential microstrip line 6880 of the exemplary differential triplate line 6980 or on the electrically conductive right signal line 6820 of the differential signal line 6830 of the differential microstrip line 6880;
7140 direction of the vector 7340 of the magnetic flux density B_{μW} of the microwave field of the microwave signal μW, a) which feeds the microwave signal source μWG and/or another signal source (RWG) into the left signal line 6810 of the differential signal line 6830 of the differential microwave line 6880, in the region of the left sensor element SE(1410), if it is a differential microstrip line 6880, or a) which feeds the microwave signal source μWG and/or another signal source (RWG) into the left signal line 6810 of the differential signal line 6830 of the differential microwave line 6880 of the differential trip-plate waveguide 6980, in the region of the left sensor element SE(1410), if it is a differential trip-plate waveguide 6980;
7150 direction of the vector 7350 of the magnetic flux density B_{μW} of the microwave field of the microwave signal μW, a) which feeds the microwave signal source μWG and/or another signal source (RWG) into the left signal line 6810 of the differential signal line 6830 of the differential microwave line 6880, in the region of the left line sensor element SE(7110), if it is a differential microstrip line 6880, or a) which feeds the microwave signal source μWG and/or another signal source (RWG) into the left signal line 6810 of the differential signal line 6830 of the differential microwave line 6880 of the differential trip-plate waveguide 6980, in the region of the left line sensor element SE(7110), if it is a differential trip-plate waveguide 6980;
7160 direction of the vector 7360 of the magnetic flux density B_{μW} of the microwave field of the microwave signal μW, a) which feeds the microwave signal source μWG and/or another signal source (RWG) into the left signal line 6810 of the differential signal line 6830 of the differential microwave line 6880, in the region of the central sensor element SE(1420) if it is a differential microstrip line 6880, or a) which feeds the microwave signal source μWG and/or another signal source (RWG) into the left signal line 6810 of the differential signal line 6830 of the differential microwave line 6880 of the differential trip-plate waveguide 6980, in the region of the middle line sensor element SE(1420), if it is a differential trip-plate waveguide 6980;
7170 Direction of the vector 7370 of the magnetic flux density B_{μW} of the microwave field of the microwave signal μW, a) which feeds the microwave signal source μWG and/or another signal source (RWG) into the right signal line 6820 of the differential signal line 6830 of the differential microwave line 6880, in the region of the center sensor element SE(1420), if it is a differential microstrip line 6880, or a) which feeds the microwave signal source μWG and/or another signal source (RWG) into the right signal line 6820 of the differential signal line 6830 of the differential microwave line 6880 of the differential trip-plate waveguide 6980, in the region of the middle line sensor element SE(1420), if it is a differential trip-plate waveguide 6980;
7180 direction of the vector 7380 of the magnetic flux density B_{μW} of the microwave field of the microwave signal μW, a) which feeds the microwave signal source μWG and/or another signal source (RWG) into the right signal line 6820 of the differential signal line 6830 of the differential microwave line 6880, in the region of the right line sensor element SE(7120), if it is a differential microstrip line 6880, or a) which feeds the microwave signal source μWG and/or another signal source (RWG) into the right signal line 6820 of the differential signal line 6830 of the differential microwave line 6880 of the differential trip-plate waveguide 6980, in the region of the right line sensor element SE(7120), if it is a differential trip-plate waveguide 6980;
7190 direction of the vector 7390 of the magnetic flux density B_{μW} of the microwave field of the microwave signal μW, a) which feeds the microwave signal source μWG and/or another signal source (RWG) into the right signal line 6820 of the differential signal line 6830 of the differential microwave line 6880, in the region of the right sensor element SE(1430), if it is a differential microstrip line 6880, or a) which feeds the microwave signal source μWG and/or another signal source (RWG) into the right signal line 6820 of the differential signal line 6830 of the differential microwave line 6880 of the differential trip-plate waveguide 6980, in the region of the right sensor element SE(1430), if it is a differential trip-plate waveguide 6980;
13320 Enlarged middle sensor element SE(13320). The enlarged middle sensor element SE(13320) corresponds to a middle sensor element SE(1420), which has properties of the neighboring sensor elements, for example the left line sensor element SE(7110) and the right line sensor element SE(7120). The enlarged center sensor element SE(13320) is essentially located on the electrically conductive signal line 1330 of the exemplary triplate line 2380, respectively in the gap 6840 between the electrically conductive left signal line 6810 of the differential signal line 6830 of the exemplary differential triplate line 6980 and that of the electrically conductive right signal line 6820 of the differential signal line 6830 of the exemplary differential triplate line 6980 or on the electrically conductive signal line 1330 of the exemplary microstrip line 1380 or in the gap 6840 between the electrically conductive left signal line 6810 of the differential signal line 6830 of the exemplary differential microstrip line 6880 and that of the electrically conductive right signal line 6820 of the differential signal line 6830 of the exemplary differential microstrip line 6880 or in slot 1840 of slot line 1880;
15710 First microwave and/or RF connector for connecting the waveguide (1380, 1880, 2380, 6880, 6990) to a microwave signal source μWG or an RF signal source RFG or to a microwave signal analyzer (μWAT, μWAR) or to an RF signal analyzer (RFAR, RFAT).
15720 Second microwave and/or RF connector for connecting the waveguide (1380, 1880, 2380, 6880, 6990) to a microwave signal source μWG or an RF signal source RFG or to a microwave signal analyzer (μWAT, μWAR) or to an RF signal analyzer (RFAR, RFAT).
15730 Cover 15730 of the carrier substrate 1360 with the waveguide (1380, 1880, 2380, 6880, 6990) and the sensor element SE for mechanical and chemical protection and, if necessary, for EMC protection.
15740 Distance 15740 of the waveguide (1380, 1880, 2380, 6880, 6990) covered by the sensor element SE.
20310 Deployment 20310 of an optically transparent carrier substrate 1360, wherein the optically transparent carrier substrate 1360 comprises at least one optically transparent edge, and wherein the optically transparent carrier substrate 1360 is covered with a waveguide having at least one clearances, such as a slot line and/or a tri-plate line or a differential tri-plate line, so that light is substantially only transmitted through the clearance of the waveguide on the surface of the optically transparent carrier substrate 1360, for example a slot line and/or a trip-plate waveguide or a differential trip-plate waveguide, so that light can essentially only emerge from the optically transparent carrier substrate 1360 through the clearances of the waveguide on the surface of the optically transparent carrier substrate 1360.
20320 Deployment 20320 of a liquid colloidal mixture KL with a liquid substrate material TM which can be cured by means of electromagnetic radiation, the curing radiation 4910, of a curing wavelength λ_{H}, wherein a multiplicity of crystals and/or diamond nano crystals ND, preferably nano-diamonds, are embedded in the substrate material TM of the colloidal mixture KL and wherein one or more or all of the crystals and/or diamond nano crystals ND have NV centers and/or other paramagnetic centers and wherein NV centers of the crystals and/or diamond nano crystals ND have NV centers and/or other paramagnetic centers and wherein one or more or all of the crystals and/or diamond nano crystals ND have NV centers and/or other paramagnetic centers and wherein one or more or all of the crystals and/or diamond nano crystals ND have NV centers and/or other paramagnetic centers and wherein one or more or more or all of the crystals and/or diamond nano crystals ND have NV centers and/or other paramagnetic centers and wherein one or more or more of the crystals and/or diamond nano crystals ND have NV centers and/or other paramagnetic centers and wherein one or more or more of the crystals and/or diamond nano crystals ND have NV centers and/or other paramagnetic centers embedded in the substrate material TM of the colloidal mixture KL, and wherein one or more or all of the crystals and/or diamond nano crystals ND comprise NV centers and/or other paramagnetic centers and wherein the NV centers of the crystals and/or diamond nano crystals ND of the colloidal mixture KL and/or the other paramagnetic centers of the crystals and/or diamond nano crystals ND of the colloidal mixture KL emit at least one fluorescence radiation FL upon exposure to pump radiation LB;
20330 Coating 20330 the surface of the optically transparent carrier substrate 1360 and the waveguide on the surface of the optically transparent carrier substrate 1360 at least to a wetting length LB with the colloidal mixture KL comprising the multiplicity of embedded crystals and/or diamond nano crystals ND with NV centers and/or paramagnetic centers;
20340 Feeding 20340 electromagnetic curing radiation 4910 with the curing wavelength λ_{H} via the at least one edge of the optically transparent carrier substrate 1360 into the optically transparent carrier substrate 1360,
20350 Emergence 20350 of the curing radiation 4910 in the region of a clearances of the waveguide on the surface of the optically transparent carrier substrate 1360 from the optically transparent carrier substrate 1360 and irradiation of the curing radiation 4910 into the substrate material TM of the colloidal mixture KL, wherein the curing wavelength λ_{H} of the curing radiation 4910 is selected such that the substrate material TM of the colloidal mixture KL cures in the region of this clearances of the waveguide on the surface of the optically transparent carrier substrate 1360 and transforms into a solid;
20360 Removal 20360 of the uncured substrate material TM of the colloidal mixture KL, in particular by means of a solvent LM, the remaining film of the colloidal mixture KL forming a sensor element SE and/or a sensor layer 16205 in the region of this clearances of the waveguide on the surface of the optically transparent substrate 1360;
α Angle formed by the optical waveguide LWL) with the contact surface AF in the immediate vicinity of the sensor element SE;
β Angle between the virtual perpendicular AFS to the contact surface AF of the sensor head SK on the one hand and the optical waveguide LWL) as it emerges from the sensor head housing GH of the sensor head SK. Preferably, the angle β is 90°. This has the advantage that such an angle β minimizes the torque that the optical waveguide LWL together with its mechanical sheath MH exerts on the sensor head SK, since the optical waveguide LWL then comes to rest at a relatively short distance from the sensor head SK on the surface of the workpiece or a surface on which the workpiece rests. Preferably, the value of β is between 45° and 135°, better between 70° and 110°, better between 80° and 100°, better between 85° and 95°, better between 87° and 93°;
AOX Covering insulator AOX;
AWV Permanent magnet axis of symmetry AWV;
AX (first application example) or permanent magnet symmetry axis (second application example);
AF Contact surface of the sensor head SK;
AFS Virtual perpendicular to the contact surface AF of the sensor head SK;
B magnetic flux density B;
B₀ Zero-point flux density B₀;
B₂₂ lower effective magnetic flux density B₂₂;
B_{Σ} lower mean effective magnetic flux density B₂₃;
B₂₄ upper mean effective magnetic flux density B₂₄;
B₂₅ upper effective magnetic flux density B₂₅;
B₂₉ effective magnetic resonance minimum flux density B₂₉;
B₆₁ magnetic flux density B₆₁, which is assigned to the upper reference line 61;
B₆₂ magnetic flux density B₆₂, which is assigned to the lower reference line 62;
B₆₃ magnetic flux density B₆₃, which is assigned to the mean reference line 63;
dₗ Thickness of the substrate material TM at the center MP of the end face EF at the first end ELWL1) of the first common optical waveguide LWL;
Bₑₓₜ external flux density Bₑₓₜ. The external flux density Bₑₓₜ comprises the portion of the external flux density Bₑₓₜ whose flux density vector is perpendicular to the magnetic flux density component B_{μW} of the microwave radiation of the microwave signal μW, and the portion of the external flux density Bₑₓₜ whose flux density vector is parallel to the magnetic flux density component B_{μW} of the microwave radiation of the microwave signal μW. Provided that the proportion of the external flux density Bₑₓₜ whose flux density vector is perpendicular to the magnetic flux density component B_{μW} of the microwave radiation of the microwave signal μW is unknown, the proportion of the external flux density Bₑₓₜ whose flux density vector is perpendicular to the magnetic flux density component B_{μW} of the microwave radiation of the microwave signal μW is equal to the unknown external effective magnetic flux density Bₙₖ;
B_{g} averaged mean effective flux density B_{g};
B_{μW} Flux density component B_{μW} of the microwave radiation of the microwave signal μW;
Bₙₖ unknown external effective magnetic flux density Bₙₖ. The unknown external effective magnetic flux density Bₙₖ is the portion of the unknown external flux density Bₑₓₜ whose flux density vector is perpendicular to the magnetic flux density component B_{μW} of the microwave radiation of the microwave signal μW.
B_{off} effective offset flux density B_{off};
BSTR magnetic stray field of the air gap LS (first application example) or the magnetic flux density of the permanent magnet PM (second application example);
B_{ref} effective magnetic reference flux density B_{ref};
B_{Σ} Total flux density B_{Σ} that flows through the sensor element SE and the nano-diamonds ND. It is made up of the external magnetic flux density Bₑₜₓ and the additional magnetic flux density B_{ad} generated by the magnetic field generation means L_{(C)}.
CTR Control device CTR;
CTR2 further control device CTR2. The further control device CTR2 may serve as the control device CTR of the device. (See FIG. 81.) Preferably, the evaluation device 30 comprises the control device CTR;
CTRH Half-bridge control CTRH. The half-bridge control CTRH preferably comprises a control device CTR and/or a further control device CTR2 as defined herein;
DB Data bus DB;
D_{LWL} Diameter D_{LWL} of the optical waveguide LWL;
dₗ Thickness of the substrate material TM at the center point MP of the end face EF at the first end ELWL1 of the first and/or the second or the common optical waveguide LWL;
d_{(IS1} Width d_{IS1} of the non-conductive left-hand insulation gap 2340 of the trip-plate waveguide 2380;
d_{(IS2} Width d_{IS2} of the non-conductive right-hand insulation gap 2350 of the trip-plate waveguide 2380;
Dr Drain region Dr;
DrK Drain contact DrK;
DRVL Driver stage DRVL for supplying the magnetic field generation means L_{C} with electrical energy and/or for controlling the magnetic field generation means L_{C}. If the magnetic field generation means L_{C} is one or more coils, in particular flat coils, the driver stage DRVL preferably energizes the magnetic field generation means L_{C} with an electrical coil current IL. A magnetic field controller LCTR compares values of the magnetic flux density B with a reference value and adjusts the supply of electrical energy to the magnetic field generation means L_{C} and/or the current supply to the magnetic field generation means L_{C} with an electrical coil current IL in such a way that this change counteracts a difference between the values of the magnetic flux density B and the reference value. The magnetic field controller LCTR receives the information about the values of the magnetic flux density B either from separate magnetic field sensors and/or from a control device CTR of the device according to the proposal;
dₛ Width dₛ of the electrically conductive signal cable 1330;
d_{SE} Diameter d_{SE} of the sensor element SE;
D_{SE} Thickness D_{SE} of the sensor element SE and/or the sensor element layer 14305;
d_{SL} Width d_{SL} of the slot 1840 of the slot line 1880 or the gap 6840 of a differential microstrip line 6880 or the gap 6840 of a differential trip-plate waveguide 6980;
dₚₘ Distance dₚₘ of the lower end of the permanent magnet PM to the contact surface AF;
dᵣ thickness at other points of the end face EF of the first end ELWL1 of the first and/or the second or the common optical waveguide LWL);
d_{SK1} Height of the sensor head SK;
d_{SK2} Length of the sensor head SK;
d_{SK3} Width of the sensor head SK;
d_{SK4} Depth of the recess VT of the sensor head SK;
D_{LWL} Diameter of the optical waveguide LWL;
D_{LWLL} Diameter of the fiber optic lens LWLL;
D_{LWLMH} Diameter of the sheathed optical waveguide LWL comprising the diameter of the optical waveguide LWL with the mechanical sheath MH;
DM Diamonds DM. The diamonds preferably have a size smaller than 5 mm, better smaller than 2 mm, better smaller than 1 mm, better smaller than 0.5 mm, better smaller than 0.2 mm, better smaller than 0.1 mm, better smaller than 50 μm, better smaller than 20 μm, better smaller than 10 μm, better smaller than 5 μm, better smaller than 2 mm, better smaller than 1 μm, better smaller than 0.5 μm, better smaller than 0.2 μm, better smaller than 0.1 μm, better smaller than 50 nm, better smaller than 20 nm, better smaller than 10 nm. The diamonds here also stand for the other possible crystals with paramagnetic centers, which can comprise the substrate material TM and which emit fluorescence radiation FL upon exposure to pump radiation LB;
EF End face of the first end ELWL1 of the first and/or the second or the common optical waveguide LWL;
ELWL1) first end of the optical waveguide LWL;
ELWL2) second end of the optical waveguide LWL;
EU one revolution of the motor;
EXTDB External data bus EXTDB, in particular for communication between a control device (CTR, CTRH, CTR2) and a higher-level computer system;
F1 Dichroitic mirror F1 or optical filter F1 for separating the fluorescence radiation FL from the pump radiation LB for the sensor element SE. The dichroitic mirror/optical filter F1 is thus functionally identical to the optical filter (long pass) 6. For the purposes of the document presented here, the dichroitic mirror F1 or the optical filter F1 can also a vectorial dichroitic mirror F1 or a vectorial optical filter F1, which can comprise a plurality of dichroitic mirror components or a plurality of optical filter components (F1_1, F1_2, F1_3, F1_4, F1_5);
F1_1 dichroitic mirror F1_1 for the left sensor element SE(1410) or optical filter F1 for the left sensor element SE(1410) for separating the fluorescence radiation FL_1 of the left sensor element SE(1410) from the pump radiation LB_1 for the left sensor element SE(1410);
F1_2 dichroitic mirror F1_2 for the middle sensor element SE(1420) or optical filter F1 for the middle sensor element SE(1420) for separating the fluorescence radiation FL_2 of the middle sensor element SE(1420) from the pump radiation LB_2 for the middle sensor element SE(1420);
F1_3 dichroitic mirror F1_3 for the right sensor element SE(1430) or optical filter F1 for the right sensor element SE(1430) for separating the fluorescence radiation FL_3 of the right sensor element SE(1430) from the pump radiation LB_3 for the right sensor element SE(1430);
F1_4 Dichroitic mirror F1_4 for the left line sensor element SE(7110) or optical filter F1 for the left line sensor element SE(7110) for separating the fluorescence radiation FL_4 of the left line sensor element SE(7110) from the pump radiation LB_4 for the left line sensor element SE(7110);
F1_5 dichroitic mirror F1_5 for the right line sensor element SE(7120) or optical filter F1 for the right line sensor element SE(7120) for separating the fluorescence radiation FL_5 of the right line sensor element SE(7120) from the pump radiation LB_5 for the right line sensor element SE(7120)
f_{μW} Microwave frequency modulation frequency f_{fμW};
FL Fluorescence radiation FL of the NV centers and/or paramagnetic centers within the sensor element SE. The document presented here also designates the fluorescence radiation FL with the reference sign 14. In the sense of the document presented here, the fluorescence radiation FL can also be a vectorial fluorescence radiation FL, which can comprise a plurality of fluorescence radiation components (FL_1, FL_2, FL_3, FL_4, FL_5);
FL_1 Fluorescence radiation FL_1 of the NV centers and/or paramagnetic centers within the left sensor element SE(1410);
FL_2 Fluorescence radiation FL_2 of the NV centers and/or paramagnetic centers within the middle sensor element SE(1420);
FL_3 Fluorescence radiation FL_3 of the NV centers and/or paramagnetic centers within the right sensor element SE(1430);
FL_4 Fluorescence radiation FL_4 of the NV centers and/or paramagnetic centers within the left line sensor element SE(7110);
FL_5 Fluorescence radiation FL_5 of the NV centers and/or paramagnetic centers within the right line sensor element SE(7120);
f_{LED} LED modulation frequency f_{LED} of the LED modulation signal S5w of the transmission signal S5 for the sensor element SE for modulating the light source LED for the sensor element SE;
f_{LED_1} LED modulation frequency f_{LED_1} of the LED modulation signal S5w_1 of the transmission signal S5_1 for the left sensor element SE(1410) for modulating the light source LED_1 for the left sensor element SE(1410);
f_{LED_2} LED modulation frequency f_{LED_2} of the LED modulation signal S5w_2 of the transmission signal S5_2 for the middle sensor element SE(1420) for modulating the light source LED_2 for the middle sensor element SE(1420);
f_{LED_3} LED modulation frequency f_{LED_3} of the LED modulation signal S5w_3 of the transmission signal S5_3 for the right sensor element SE(1430) for modulating the light source LED_3 for the right sensor element SE(1430);
f_{LED_4} LED modulation frequency f_{LED_4} of the LED modulation signal S5w_4 of the transmission signal S5_4 for the left line sensor element SE(7110) for modulation of the light source LED_5 for the left line sensor element SE(71100);
f_{LED_5} LED modulation frequency f_{LED_5} of the LED modulation signal S5w_5 of the transmission signal S5_5 for the right line sensor element SE(7120) for modulating the light source LED_5 for the right line sensor element SE(7120);

FM optical non-transparent filling compound
f_{mg} Magnetic field modulation frequency f_{mg};
f_{μW} Microwave modulation frequency f_{μ(W)};
FMM ferromagnetic material;
FOX Field oxide FOX;
f_{RWm} Radio wave modulation frequency f_{RWm};
FS2 second trap structure FS2;
G Signal generator G;
G1 first signal generator G1. For the purposes of the present document, the first signal generator G1 may also be a vectorial first signal generator G1, which may comprise a plurality of first signal generator components (G1_1, G1_2, G1_3, G1_4, G1_5);
G1_1 First signal generator G1 for the left sensor element SE(1410);
G1_2 first signal generator G1 for the middle sensor element SE(1420);
G1_3 first signal generator G1 for the right sensor element SE(1430);
G1_4 First signal generator G1 for the right-hand line sensor element SE(7110);
G1_5 First signal generator G1 for the right-hand line sensor element SE(7120);
G2 second signal generator G2;
G2_I first second signal generator G2_I for generating the first microwave modulation signal S5m_I;
G2_II second second signal generator G2_II for generating the second microwave modulation signal S5m_II;
G2_III third second signal generator G2_III for generating the third microwave modulation signal S5m_III;
G2_IV fourth second signal generator G2_IV for generating the fourth microwave modulation signal S5m_IV;
GA Gate GA;
GH Housing, in particular the stator of the motor in the second embodiment of a motor;
GHR rotor housing;
GH Sensor head housing GH. The sensor head housing GH of the sensor head SK can be fabricated, for example, by means of 3D printing, such as FDM or SLS printing. Preferably, the material of the sensor head housing is non-ferromagnetic (μ₍ₜ)<1) at least in the vicinity of the sensor element SE. Preferably, the material of the sensor head housing is diamagnetic;
GND Reference potential;
GOX Gate oxide GOX;
H magnetic excitation;
HB Half-bridges HB;
HSL Half-bridge control lines HSL;
I_{MPHU} Motor phase current of the U-motor-phase MPH_{U};
I_{MPHV} Motor phase current of the V-motor-phase MPH_{V};
I_{MPHW} Motor phase current of the W-motor-phase MPH_{W};
JTAG IEEE 1149 JATG test controller JTAG;
KI Kink in channel KN of the sensor head housing GH;
KL colloidal varnish KL. The colloidal varnish KL preferably comprises the substrate material TM, for example the UV-curable NOA 61 Adhesive and the crystals and/or diamond nano crystals ND. If necessary, the colloidal varnish KL may comprise a solvent LM at the point in time of processing to adjust the viscosity for the coating and/or printing and/or dispensing process;
KN Channel KN through which the optical waveguide LWL) is inserted into the sensor head housing GH;
L_{B} Wetting length;
LB Pump radiation LB. The document presented here also designates the pump radiation LB with the reference sign 13. In the sense of the document presented here, the pump radiation LB (13) can also be a vectorial pump radiation LB, which can comprise a plurality of pump radiation components (LB_1, LB_2, LB_3, LB_4, LB_5);
   Pump radiation LB_1 of the light source LED_1 (pump radiation source) for the left sensor element SE(1410);
   Pump radiation LB_2 of the light source LED_2 (pump radiation source) for the middle sensor element SE(1420);
   Pump radiation LB_3 of the light source LED_3 (pump radiation source) for the right sensor element SE(1430);
   Pump radiation LB_4 of the light source LED_4 (pump radiation source) for the left line sensor element SE(7110);
   Pump radiation LB_5 of the light source LED_5 for the right-hand line sensor element SE(7120);
Line sensor element SE(7120);
L_{C} Magnetic field generation means L_{(C)}. The magnetic field generation means L_{C}. can be, for example, an electrical coil, in particular an electrical flat coil on the rear side of the printed circuit board 1360 (PCB). Preferably, a driver stage DRVL for supplying the magnetic field generation means L_{C} supplies the magnetic field generation means L_{C} with electrical energy. In the case of a coil as magnetic field generation means L_{C}, driver stage DRVL supplies the magnetic field generation means L_{C} with an electric current to supply the magnetic field generation means L_{(C)}. For the purposes of the document presented here, the magnetic field generation means L_{C} can also comprise a permanent magnet PM with a positioning device PV, in which case the driver stage DRVL preferably controls the positioning device PV of the permanent magnet PM. Depending on the positioning of the permanent magnet PM relative to the sensor element SE, a different effective magnetic flux density B_{w} flows through the sensor element SE. Preferably, the magnetic field controller LCTR controls the driver stage DRVL. For the purposes of the present document, the magnetic field generation means L_{C} may also a vector magnetic field generation means L_{C}, which may comprise a plurality of magnetic field generation means components (L_{C}_1, L_{C}_2, L_{C}_3, L_{C}_4, L_{C}_5);
L_{c}_1 first magnetic field generation means L_{C}_1 for the first sensor element SE of the first sensor element channel. In the example of FIG. 141, the first magnetic field generation means L_{C}_1 is part of the magnetic field generation means L_{C}. At this point, the document presented here refers to the description of the magnetic field generation means L_{C}.
L_{c}_2 second magnetic field generation means L_{C}_2 for the second sensor element SE of the second sensor element channel. In the example of FIG. 141, the second magnetic field generation means L_{C}_2 is part of the magnetic field generation means L_{C}. At this point, the document presented here refers to the description of the magnetic field generation means L_{C}.
L_{c}_3 third magnetic field generation means L_{C}_3 for the third sensor element SE of the third sensor element channel. In the example of FIG. 141, the third magnetic field generation means L_{C}_3 is part of the magnetic field generation means L_{C}. At this point, the document presented here refers to the description of the magnetic field generation means L_{C}.

L_{c}_4 fourth magnetic field generation means L_{C}_4 for the fourth sensor element SE of the fourth sensor element channel. In the example of FIG. 141, the fourth magnetic field generation means L_{C}_4 is part of the magnetic field generation means L_{C}. At this point, the document presented here refers to the description of the magnetic field generation means L_{C}.

L_{c}_5 fifth magnetic field generation means L_{C}_5 for the fifth sensor element SE of the fifth sensor element channel. In the example of FIG. 141, the fifth magnetic field generation means L_{C}_5 is part of the magnetic field generation means L_{C}. At this point, the document presented here refers to the description of the magnetic field generation means L_{C}.
LCTR Magnetic field controller LCTR. The magnetic field controller LCTR preferably compares values of the magnetic flux density B with a reference value and adjusts the supply of electrical energy to the magnetic field generation means L_{C} and/or the current supply to the magnetic field generation means L_{C} with an electrical coil current IL in such a way that this change counteracts a difference between the values of the magnetic flux density B and the reference value. The magnetic field controller LCTR receives the information about the values of the magnetic flux density B either from separate magnetic field sensors and/or from a control device CTR of the device according to the proposal. The magnetic field controller LCTR can be, for example, a P-controller and/or a PI-controller and/or a PID-controller or the like, the controller preferably comprising at least one integrating property in its control characteristics. The magnetic field controller LCTR preferably receives the reference value from a control device CTR of the device according to the proposal or by constructive measures or the like. If necessary, the control device CTR can emulate the magnetic field controller LCTR;
LDRV Light source driver LDRV for the LED light source (pump radiation source). For the purposes of the document presented here, the light source driver LDRV for the light source LED (pump radiation source) can also be a vectorial light source driver LDRV for a vectorial light source LED (pump radiation source), which can comprise a plurality of light source driver components (LDRV_1, LDRV_2, LDRV_3, LDRV_4, LDRV_5);
LDRV_1 Light source driver LDRV_1 for the light source LED_1 (pump radiation source) for the pump radiation LB_1 for the left sensor element SE(1410);
LDRV_2 Light source driver LDRV_2 for the light source LED_2 (pump radiation source) for the pump radiation LB_2 for the middle sensor element SE(1420);
LDRV_3 Light source driver LDRV_3 for the light source LED_3 (pump radiation source) for the pump radiation LB_3 for the right sensor element SE(1430);
LDRV_4 Light source driver LDRV_4 for the light source LED_4 (pump radiation source) for the pump radiation LB_4 for the left line sensor element SE(7110);
LDRV_5 Light source driver LDRV_5 for the light source LED_5 (pump radiation source) for the pump radiation LB_5 for the right-hand line sensor element SE(7120);
LED Light source LED (pump radiation source). For the purposes of the document presented here, the light source LED (pump radiation source) can also be a vector light source LED (pump radiation source), which can comprise a plurality of light source components (LED_1, LED_2, LED_3, LED_4, LED_5);
   Light source LED_1 (pump radiation source) for the left sensor element SE(1410);
   Light source LED_2 (pump radiation source) for the middle sensor element SE(1420);
   Light source LED_3 (pump radiation source) for the right-hand sensor element SE(1430);
   Light source LED_4 (pump radiation source) for the left line sensor element SE(7110);
   Light source LED_5 (pump radiation source) for the right-hand line sensor element SE(7120);
λ_{B} Exposure wavelength λ_{B};
λ_{fl} Fluorescence radiation wavelength λ_{fl};
λ_{H} Curing wavelength λ_{H};
λₚₘₚ Pump radiation wavelength λₚₘₚ;
LIV Multiple correlator LIV. The multiple correlator LIV is preferably a lock-in amplifier or a functionally equivalent device, for example for estimating the proportion of a predetermined transmission signal in a received signal. For the purposes of the present document, the multiple correlator LIV may also be a vectorial multiple correlator LIV, which may comprise a plurality of multiple correlator components (LIV_1, LIV_2, LIV_3, LIV_4, LIV_5);
LIV_1 Multiple correlator LIV_1 for the left sensor element SE(1410);
LIV_2 Multiple correlator LIV_2 for the middle sensor element SE(1420);
LIV_3 Multiple correlator LIV_3 for the right-hand sensor element SE(1430);
LIV_4 Multiple correlator LIV_4 for the left line sensor element SE(7110);
LIV_5 Multiple correlator LIV_5 for the right-hand line sensor element SE(7120);
LS Air gap;
LST Value of the fluorescence intensity-based filter output signal S4 (in arbitrary units);
FIBER OPTIC CABLE Optical waveguide LWL. For example, it may be an optical fiber or a glass plate 46 or an optical transmission link. For the purposes of the present document, the optical waveguide LWL may also be a vectorial optical waveguide LWL (e.g. an optical waveguide bundle or an assembly of optical waveguides LWL), which may comprise a plurality of optical waveguide components (LWL_1, LWL_2, LWL_3, LWL_4, LWL_5);
LWL1 first optical waveguide LWL1;
LWL2 second optical waveguide LWL2;
LWLC Core of the optical waveguide (LWL);
LWLL) Fiber optic lens;
λ_{fl} Fluorescence wavelength λ_{fl};
λ_{H} Curing wavelength λ_{H};
λₚₘₚ Pump radiation wavelength λₚₘₚ;
M1 first multiplier M1 or simply multiplier;
M2 second multiplier M2;
M2L second metal layer M2L;
MDS Pattern data set MDS. Preferably, this pattern data set MDS comprises the data set of a recognized pattern and or a feature vector for a pattern recognition performed by the control device CTR using a computer-implemented program for pattern recognition or the like. Typically, this is the value of the recognized total flux density B_{Σ}. Typically, this data set also comprises the measurement error value with which this value of the recognized total flux density B_{Σ} is afflicted;
optional mechanical sheath ME and/or optical shield ME; ME
ME_1 Optional mechanical sheath ME_1 and/or optical shield ME_1 for the left sensor element SE(1410);
ME_2 Optional mechanical sheath ME_2 and/or optical shield ME_2 for the middle sensor element SE(1420);
ME_3 Optional mechanical sheath ME_3 and/or optical shield ME_3 for the right-hand sensor element SE(1430);
MESA MESA structure MESA;
MEV MEV pattern recognition device;
MH mechanical sheath;
MIX Mixer MIX;
ML Center line of the optical waveguide (LWL) (This is a virtual line);
MP Center of the end face EF of the first end ELWL1) of the optical waveguide LWL;
MPH Motor phases;
MPH (u U-motor-phase;
MPH (v V-motor-phase;
MPH (W W-motor-phase;
MRK Marking on the rotor housing GHR;
MS MS magnetic field sensor;
μW Microwave signal μW;
μW_I first microwave signal μW_I;
μW_II second microwave signal μW_II;
μW_III third microwave signal μW_III;
μW_IV fourth microwave signal μW_IV;
μWG_F_I first microwave filter μWG_F_I;
μWG_F_II first microwave filter μWG_F_II;
μWG_F_III first microwave filter μWG_F_III;
μWG_F_IV first microwave filter μWG_F_IV;
μW_G_If irst internal microwave signal μW_G_I;
μW_G_II second internal microwave signal μW_G_II;
μW_G_III third internal microwave signal μW_G_III;
μW_G_IV fourth internal microwave signal μW_G_IV;
μW_MX_I first microwave mixing signal μW_MX_I;
μW_MX_II second microwave mixing signal μW_MX_II;
μW_MX_III third microwave mixing signal μW_MX_III;
μW_MX_IV fourth microwave mixing signal μW_MX_IV;
μWAR Transmission microwave signal analyzer μWAR for detecting the microwave signal μWR of the microwave signal μW deformed and reflected by the path 15740 of the waveguide (1380, 1880, 2380, 6880, 6990) covered by the sensor element SE by interaction with the substrate material TM of the sensor element SE and by interaction with the NV centers NVZ and/or paramagnetic centers of the crystals and/or diamonds DM within the substrate material TM of the sensor element SE.
μWAT Reflection microwave signal analyzer μWAT for detecting the waveguide (1380, 1880, 2380, 6880, 6990) by interaction with the substrate material TM of the sensor element SE and by the interaction with the NV centers NVZ and/or paramagnetic centers of the crystals and/or diamonds DM within the substrate material TM of the sensor element SE deformed and transmitted microwave signal μWT of the microwave signal μW.
μWC Microwave directional coupler for feeding the microwave signal μW into the waveguide (1380, 1880, 2380, 6880, 6990) and for coupling out the reflected microwave signal μWR for analysis by the reflection microwave analyzer μWAR.
μWG Microwave signal source μWG;
   first microwave signal source μWG_I;
   second microwave signal source μWG_II;
   third microwave signal source μWG_III;
   fourth microwave signal source μWG_IV;
μWG_MX_I first internal mixer μW_G_I;
μWG_MX_II second internal mixer μW_G_II;
μWG_MX_III third internal mixer μW_G_III;
μWG_MX_IV fourth internal mixer μW_G_IV;
μWR reflected microwave signal μWR of the microwave signal μW which is deformed and reflected by interaction with the substrate material TM of the sensor element SE and by the interaction with the NV centers NVZ and/or paramagnetic centers of the crystals and/or diamonds DM within the substrate material TM of the sensor element SE in the section 15740 of the waveguide (1380, 1880, 2380, 6880, 6990) covered by the sensor element SE;
μWT transmitted microwave signal μWT of the microwave signal μW which is deformed by interaction with the substrate material TM of the sensor element SE and by interaction with the NV centers NVZ and/or paramagnetic centers of the crystals and/or diamonds DM within the substrate material TM of the sensor element SE in the section 15740 of the waveguide (1380, 1880, 2380, 6880, 6990) covered by the sensor element SE and transmitted through it;
ND Diamond nano crystals ND. The document presented here uses the reference sign ND to designate not only diamonds DM, but also crystals in general which may comprise paramagnetic centers. Nevertheless, diamond crystals DM are preferred as diamond nano crystals ND. NV centers in diamond are preferred as paramagnetic centers. The small stochastically uniformly distributed diamond nano crystals ND in the material of the substrate material TM of the colloidal mixture KL are indicated in some figures for clarification. Preferably, the diamond nano crystals ND are crystals, preferably diamond crystals, with a size smaller than 10 μm, better smaller than 5 μm, better smaller than 2 μm, better smaller than lum, better smaller than 0.5 μm, better smaller than 0.2 μm, better smaller than 0.1 μm, smaller than 50 nm, smaller than 20 nm, smaller than 10 nm. Sizes above 100 nm are particularly preferred, since sizes smaller than 100 nm can cause special surface effects between the paramagnetic centers, in particular NV centers, and the respective crystal surface of the diamond nano crystals ND or crystal in question. Preferably, a multiplicity of these diamond nano crystals ND or crystals comprise one or more NV centers in diamond, which then the fluorescence radiation FL upon exposure to pump radiation LB;
NVM non-volatile memory NVM;
NVZ) NV centers;
NW N-well NW;
OF Opening
KE Core;
KN Channel in the housing GH or sensor head housing GH for feeding the optical waveguide (LWL) and/or optical window in the housing or sensor head housing GH;
OE Opening for the optical waveguide (LWL) in the ferromagnetic support ST of the second application example;
OF Surface of the workpiece, for example the surface of a ferromagnetic material FMM, of the first application example;
OFF1 Offset addition;
oMS1 first upper metal shield oMS1 of the first optical waveguide LWL1 upwards to the surface of the carrier substrate 1360. It is an optical shield ME;
oMS2 second upper metal shield oMS2 of the second optical waveguide LWL2 upwards to the surface of the carrier substrate 1360. It is an optical shield ME;
ω_{(μW} Microwave frequency ω_{μW};
ω_{μW0} Zero-point microwave frequency ω_{μW0};
ω_{μW22} lower microwave frequency ω_{μW22};
ω_{μW23} lower average microwave frequency ω_{μW23};
ω_{μW24} upper average microwave frequency ω_{μW24};
ω_{μW25} upper microwave frequency ω_{μW25};
ω_{(μW29} Resonance minimum microwave frequency ω_{μW29};
ω_{(μWnk} unknown microwave frequency ω_{μWnk};
φ_{MPHU} Current angle of the complex current vector of the motor phase current I_{MPHU} of the motor phase MPH_{U};
φ_{MPHV} Current angle of the complex current vector of the motor phase current I_{MPHV} of the motor phase MPH_{V};
φ_{MPHW} Current angle of the complex current vector of the motor phase current I_{MPHW} of the motor phase MPH_{W};
PD Photo detector PD. For the purposes of the present document, the photo detector PD may also be a vectorial photo detector PD, which may comprise a plurality of photo detector components (PD_1, PD_2, PD_3, PD_4, PD_5);
PD_1 Photo detector PD_1 for the left sensor element SE(1410);
PD_2 Photo detector PD_2 for the middle sensor element SE(1420);
PD_3 PD_3 photo detector for the right-hand sensor element SE(1430);
PD_4 Photo detector PD_4 for the left line sensor element SE(7110);
PD_5 PD_5 photo detector for the right-hand line sensor element SE(7120);
PL Pump radiation source PL, also referred to as light source 2 with the reference sign 2;
PM Permanent magnet PM. Preferably, in the first application example of the sensor head SK, the permanent magnet PM is tubular with a permanent magnet axis of symmetry AX. If, in this first application example, the sensor element SE is located on this axis of symmetry AX, the horizontal component of the magnetic flux density B is approximately 0 T. In the first application example presented here, the permanent magnet PM serves to deploy the magnetic excitation H of the magnetic circuit of the sensor head SK in interaction with the material of the workpiece in the vicinity of the surface OF of the workpiece and in the vicinity of the sensor element SE. Instead of a permanent magnet PM, a current-carrying coil or the like can also be used here in the first application example. More complicated magnetic circuits with more than one source of magnetic excitation are also conceivable in the first application example for the same purpose. For example, the sensor head SK in the first application example may also comprise a combination of one of the plurality of permanent magnets with one or more coils as the source of magnetic excitation H. For example, the sensor head SK in the first application example may also comprise one or more coils as the source of the magnetic excitation H. For the purposes of the document presented here, the term permanent magnet stands for any structured source of magnetic excitation H. However, a single permanent magnet is expressly particularly preferred in the first application example. In the second application example, it can be a permanent magnet of the motor, for example the rotor or the stator. In the third application example of a magnetic camera, the permanent magnet PM can act as an auxiliary magnet 19 for the magnetic excitation H of the measurement object to be tested. In the case of the fourth application example of a microwave spectrometer, the permanent magnet as a gradient afflicted permanent magnet GPM can provide for a different splitting of the lower resonance edge 522 and the upper resonance edge 525. For example, a permanent magnet PM can be used as magnetic field generation means L_{(C)};
POS Position detector;
POSS Position signal;
POSSW Value of the position signal POSS in arbitrary units;
RAM Memory RAM, in particular volatile memory;
RFG Radio wave source (RF-source) RFG;
RFAR Transmission RF-signal analyzer RFAR for detecting the signal transmitted through the section 15740 of the waveguide (1380, 1880, 2380, 6880, 6990) by interaction with the substrate material TM of the sensor element SE and by the interaction with the NV centers NVZ and/or paramagnetic centers of the crystals and/or diamonds DM within the substrate material TM of the sensor element SE in the section 15740 of the waveguide (1380, 1880, 2380, 6880, 6990) covered with the sensor element SE and reflected RF signal RWR of the RF signal RW.
RFAT Reflection RF signal analyzer RFAT for detecting the RF signal transmitted through the section 15740 of the waveguide (1380, 1880, 2380, 6880, 6990) by interaction with the substrate material TM of the sensor element SE and by the interaction with the NV centers NVZ and/or paramagnetic centers of the crystals and/or diamonds DM within the substrate material TM of the sensor element SE in the section 15740 of the waveguide (1380, 1880, 2380, 6880, 6990) covered by the sensor element SE and transmitted RF signal RWT of the RF signal RW.
RMK RMK magnetic rotor circuit;
RI Disturbance in the ferromagnetic material FMM. Such a disturbance may be a change in composition that locally changes the magnetic properties of the ferromagnetic material FM. For example, it may be a crack or a blowhole or a hole or a recess or a thickness variation or a modulation of a shape factor such as thickness, width or the like;
RW Radio wave signal RW;
RWC Microwave directional coupler for feeding the RF signal RW into the waveguide (1380, 1880, 2380, 6880, 6990) and for decoupling the reflected RF signal RWR for analysis by the reflection RF signal analyzer μWAR.
RWR reflected RF signal RWR of the RF signal RW which is deformed and reflected by interaction with the substrate material TM of the sensor element SE and by interaction with the NV centers NVZ and/or paramagnetic centers of the crystals and/or diamonds DM within the substrate material TM of the sensor element SE in the section 15740 of the waveguide (1380, 1880, 2380, 6880, 6990) covered by the sensor element SE;
RWT Transmitted RF signal RWT of the RF signal RW which is deformed by interaction with the substrate material TM of the sensor element SE and by interaction with the NV centers NVZ and/or paramagnetic centers of the crystals and/or diamonds DM within the substrate material TM of the sensor element SE in the section 15740 of the waveguide (1380, 1880, 2380, 6880, 6990) covered by the sensor element SE and is transmitted through it;
S0 Receiver output signal S0. For the purposes of the present document, the receiver output signal S0 may also be a vectorial receiver output signal S0, which may comprise a plurality of receiver output signal components (S0_1, S0_2, S0_3, S0_4, S0_5);
S0_1 Receiver output signal S0_1 for the left sensor element SE(1410). The receiver output signal S0_1 for the left sensor element SE(1410) preferably represents a receiver output signal component of the vectorial receiver output signal S0;
S0_2 Receiver output signal S0_2 for the middle sensor element SE(1420);
S0_3 Receiver output signal S0_3 for the right sensor element SE(1430);
S0_4 Receiver output signal S0_4 for the left line sensor element SE(7110);
S0_5 Receiver output signal S0_5 for the right-hand line sensor element SE(7120);
S1 amplified receiver output signal S1 or digitized receiver output signal S1. For the purposes of the present document, the amplified receiver output signal S1 or digitized receiver output signal S1 may also a vector amplified receiver output signal S1 or a vector digitized receiver output signal S1, which may comprise a plurality of amplified receiver output signal components (S1_1, S1_2, S1_3, S1_4, S1_5);
S1_1 amplified receiver output signal S1_1 for the left sensor element SE(1410) or digitized receiver output signal S1_1 for the left sensor element SE(1410);
S1_2 amplified receiver output signal S1_2 for the left sensor element SE(1420) or digitized receiver output signal S1_2 for the left sensor element SE(1410);
S1_3 amplified receiver output signal S1_3 for the left sensor element SE(1430) or digitized receiver output signal S1_3 for the left sensor element SE(1430);
S1_4 amplified receiver output signal S1_4 for the left line sensor element SE(7110) or digitized receiver output signal S1_3 for the left line sensor element SE(7110);
S1_5 amplified receiver output signal S1_5 for the right line sensor element SE(7120) or digitized receiver output signal S1_3 for the right line sensor element SE(7120); S3 Filter input signal;
S3a first intermediate signal S3a of the L3 product of the multiple correlator LIV;
S3b second intermediate signal S3b of the L3 product of the multiple correlator LIV;
S4 Filter output signal S4 is also referred to as a flux density measurement signal in the case of use as a magnetometer. For the purposes of the present document, the filter output signal S4 may also be a vectorial filter output signal S4, which may comprise a plurality of filter output signal components (S4_1, S4_2, S4_3, S4_4, S4_5);
S4_1 Filter output signal S4_1 for the left sensor element SE(1410);
S4_2 Filter output signal S4_2 for the middle sensor element SE(1420);
S4_3 Filter output signal S4_3 for the right sensor element SE(1430);
S4_4 Filter output signal S4_4 for the left line sensor element SE(7110);
S4_5 Filter output signal S4_5 for the right line sensor element SE(7120);
S5 Transmission signal S5. For the purposes of the present document, the transmission signal S5 may also be a vectorial transmission signal S5, which may comprise a plurality of transmission signal components (S5_1, S5_2, S5_3, S5_4, S5_5);
S5 Transmission signal S5 for modulating the light source LED (pump radiation source of the pump radiation LB);
S5_1 Transmission signal S5_1 for the left sensor element SE(1410) for modulating the light source LED_1 for the left sensor element SE(1410) (pump radiation source of the pump radiation LB_1 for the left sensor element SE(1410));
S5_2 Transmission signal S5_2 for the middle sensor element SE(1420) for modulating the light source LED_2 for the middle sensor element SE(1420) (pump radiation source of the pump radiation LB_2 for the middle sensor element SE(1420));
S5_3 Transmission signal S5_3 for the right sensor element SE(1430) for modulating the light source LED_3 for the right sensor element SE(1430) (pump radiation source of the pump radiation LB_3 for the right sensor element SE(1430));
S5_4 Transmission signal S5_4 for the left line sensor element SE(7110) for modulating the light source LED_4 for the left line sensor element SE(7110) (pump radiation source of the pump radiation LB_4 for the left line sensor element SE(7110));
S5_5 Transmission signal S5_5 for the right line sensor element SE(7120) for modulating the light source LED_5 for the right left line sensor element SE(7120) (pump radiation source of the pump radiation LB_5 for the right left line sensor element SE(7120));
S5m Microwave modulation signal S5m;
S5mq inverted microwave modulation signal S5mq;
S5w LED modulation signal S5w, also referred to as a transmit pre-signal. For the purposes of the document presented here, the LED modulation signal S5w can also be a vectorial LED modulation signal S5w, which can comprise a plurality of LED modulation signal components (S5w_1, S5w_2, S5w_3, S5w_4, S5w_5);
S5w 1 LED modulation signal S5w1 for the left sensor element SE(1410) for modulating the light source LED_1 for the left sensor element SE(1410) (pump radiation source of the pump radiation LB_1 for the left sensor element SE(1410));
S5w 2 LED modulation signal S5w2 for the middle sensor element SE(1420) for modulating the light source LED_2 for the middle sensor element SE(1420) (pump radiation source of the pump radiation LB_2 for the middle sensor element SE(1420));
S5w_3 LED modulation signal S5w3 for the right sensor element SE(1430) for modulating the light source LED_3 for the right sensor element SE(1430) (pump radiation source of the pump radiation LB_3 for the right sensor element SE(1430));
S5w_4 LED modulation signal S5w4 for the left line sensor element SE(7110) for modulating the light source LED_4 for the left line sensor element SE(7110) (pump radiation source of the pump radiation LB_4 for the left line sensor element SE(7110));
S5w_5 LED modulation signal S5w5 for the right line sensor element SE(7120) for modulating the light source LED_5 for the right line sensor element SE(7120) (pump radiation source of the pump radiation LB_5 for the right line sensor element SE(7120));
S5wq inverted LED modulation signal S5wq;
SCHR screw. In the first application example, the sensor head housing GH preferably comprises a thread for a grub screw to hold the screw for fixing the optical waveguide LWL);
SE Sensor element SE. Preferably, the sensor element SE comprises a multiplicity of nano-diamonds or diamonds DM, which are oriented differently and preferably comprise a multiplicity of NV centers NVZ. Preferably, the sensor element SE comprises a multiplicity of crystals which are oriented differently and preferably comprise a multiplicity of NV centers NVZ and/or paramagnetic centers. Preferably, in the case of the first application example of a sensor head SK, the sensor element SE with the diamonds DM or nano-diamonds and/or the crystals with paramagnetic centers is placed centrally under the permanent magnet PM and as close as possible to the test object, here in the first application example of a sensor head SK the exemplary workpiece with the ferromagnetic material FMM. In the case of the second application example of a motor, the sensor element is preferably positioned within the air gap LS of the motor or in its stray field. In the case of the third application example of a magnetic field camera, the sensor element SE preferably comprises a sensor layer 5. In the case of the fourth application example of a waveguide (1380, 1880, 2380 6830, 6980), the sensor element is preferably located in the vicinity of a line (1310, 1320, 1330, 6810, 6820) of the respective waveguide and/or in a clearances (1340, 1350, 1840, 2340, 2350, 6840) of a respective waveguide. The sensor element SE typically comprises the nano diamond crystals ND and a typically solidified carrier medium TE. The paper presented here describes various sensor elements SE, in particular the sensor elements 1410, 1420, 1430, 1710, 2210, 2410, 2420, 2430, 4410, 7115, 7125, 1735, 7110 and 7120, 13310 which differ in terms of expansion and position relative to the lines;
SIS Magnetic field sensor controller SIS;
SK Sensor head;
SL Stator coil windings;
SMK magnetic stator circuit;
Sr Source region Sr;
SrK Source contact SrK;
ST ferromagnetic support;
TB Data interface of the IEEE JATG test controller JTAG and JTAG test data bus;
TM Substrate material TM. The substrate material TM of the colloidal mixture KL is preferably liquid at the beginning of processing and is solidified during processing, for example by exposure to a curing radiation 4910 of a curing wavelength λ_{H}. Preferably, after solidification, the substrate material TM is optically transparent to electromagnetic radiation with the pump radiation wavelength λₚₘₚ and the fluorescence wavelength λ_{fl} of the paramagnetic centers of the embedded crystals and/or diamond nano crystals ND, here preferably the NV centers;
t time;
T Motor current period duration (I_{MPHU}, I_{MPHV}, I_{MPHW});
TM substrate material;
TP Low pass;
TP Low pass filter or filter with low pass properties;
uMS1 first lower metal shield uMS1
uMS2 second lower metal shield uMS2
V Feed speed;
V1 first amplifier V1 or just amplifier in this document. For the purposes of the present document, the amplifier V1 may also be a vectorial amplifier V1, which may comprise a plurality of amplifier components (V1_1, V1_2, V1_3, V1_4, V1w_5);
V1_1 first amplifier V1_1 for the left sensor element SE(1410) for amplification and/or digitization of the receiver signal S0_1 for the left sensor element SE(1410) to the amplified receiver output signal S1_1 for the left sensor element SE(1410) or to the digitized receiver output signal S1_1 for the left sensor element SE(1410);
V1_2 first amplifier V1_2 for the middle sensor element SE(1420) for amplification and/or digitization of the receiver signal S0_2 for the middle sensor element SE(1420) to the amplified receiver output signal S1_2 for the middle sensor element SE(1420) or to the digitized receiver output signal S1_2 for the left sensor element SE(1420);
V1_3 first amplifier V1_3 for the right sensor element SE(1430) for amplification and/or digitization of the receiver signal S0_3 for the right sensor element SE(1430) to the amplified receiver output signal S1_3 for the right sensor element SE(1430) or to the digitized receiver output signal S1_3 for the right sensor element SE(1430);
V1_4 First amplifier V1_4 for the left line sensor element SE(7110) Amplification and/or digitization of the receiver signal S0_4 for the left line sensor element SE(7110) to the amplified receiver output signal S1_4 for the left line sensor element SE(7110) or to the digitized receiver output signal S1_4 for the left line sensor element SE(7110)
V1_5 first amplifier V1_5 for the right line sensor element SE(7120) for amplifying and/or digitizing the receiver signal S0_5 for the right line sensor element SE(7120) to the amplified receiver output signal S1_5 for the right line sensor element SE(7120) or to the digitized receiver output signal S1_5 for the right line sensor element SE(7120);
VDD Supply voltage;
V_{MPHU} Motor phase voltage of the U-motor-phase MPH_{U} in relation to the reference potential GND;
V_{MPHV} Motor phase voltage of the V-motor-phase MPH_{V} in relation to the reference potential GND;
V_{MPHW} Motor phase voltage of the W-motor-phase MPH_{W} in relation to the reference potential GND;
VT Recess VT of the sensor head SK e.g. for a guide finger of a hand.

### Glossary

### Diamond Nano Crystals ND

Preferably, the technical teaching presented here uses HD-NV diamonds as diamond nano crystals ND or crystals of the sensor elements SE or the sensor element layers 5. In this context, the document presented here refers to DE 10 2020 109 477 A1.
A HD-NV diamond, as defined herein, is a crystal with a particularly high density of paramagnetic centers. Due to this high density of paramagnetic centers, the fluorescence intensity curve and/or the fluorescence delay curve show fluorescence characteristics that cause couplings of these paramagnetic centers with other crystal structure elements. Such other crystal structure elements can be, for example:
i. Other paramagnetic centers of the same type that are aligned in the same direction as the coupling paramagnetic center, for example the coupling of an NV center to an aligned NV center in diamond;
ii. Other paramagnetic centers of the same type that are not aligned in the same way as the coupling paramagnetic center, for example the coupling of an NV center to a non-aligned NV center in diamond;
iii. Other paramagnetic centers of a different type that are aligned in the same way as the coupling paramagnetic center, for example the coupling of a SiV center and/or TiV center and/or GeV center and/or SnV center and/or NiN4 center and/or PbV center and/or ST1 center to an NV center in diamond that is aligned in the same way;
iv. Other paramagnetic centers of a different type that are not aligned in the same direction as the coupling paramagnetic center, for example the coupling of a SiV center and/or TiV center and/or GeV center and/or SnV center and/or NiN4 center and/or PbV center and/or ST1 center to a non-aligned NV center in diamond;
v. Nuclear spins with magnetic moment of isotopes with such a spin which couple to the coupling paramagnetic center and which are part of the paramagnetic center, e.g. the coupling of an NV center to a nitrogen nucleus in the NV center;
vi. Nuclear spins with magnetic moment of isotopes with such a spin which couple to the coupling paramagnetic center and which are not part of the paramagnetic center, e.g. the coupling of an NV center to a nucleus of a ¹³C isotope in the vicinity of an NV center.
   The high density of paramagnetic centers of one type, for example of NV centers in diamond as a crystal, increases the probability that the distance of a paramagnetic center to such another crystal structure element is so small that one of the couplings indicated above becomes possible. As a result, the fluorescence characteristics indicating such a coupling between a paramagnetic center and another crystal structure element are more pronounced in the fluorescence intensity curve or the fluorescence delay curve of the crystal. On a diamond with a high density of NV centers, this means that the fluorescence characteristics indicating such a coupling between a NV center and another crystal structure element are more pronounced in the fluorescence intensity curve and the fluorescence delay curve of the diamond, respectively. One feature that is characteristic of an HD NV diamond, for example, is the coupling of one NV center to another NV center. Such a diamond thus comprises a NV center pair of two coupled and equivalent NV centers. According to the subject matter herein, this diamond (HDNV) is then preferably for use in a quantum technological device and/or in a quantum technological method. The HD-NV diamond can then be characterized, for example, by the fact that the intensity value curve of the intensity Iᵢₛₜ of the fluorescence radiation FL of the NV center pair when exposed to a pump radiation LB with a pump radiation wavelength (λ pmp) shows a typical intensity dip (English: dip) of the fluorescence radiation FL depending on the value of the magnetic flux density (B) of a magnetic field external to the diamond (HDNV): dip) in the fluorescence intensity value of the intensity Iᵢₛₜ of the fluorescence radiation FL and/or a typical delay increase in the fluorescence delay value of more than 0.01% and/or more than 0.02% and/or more than 0.05% and/or more than 0.1% and/or more than 0.2% and/or more than 0.5% and/or 1% and/or more than 2% and/or more than 5% at an external magnetic flux density (B) of about 34.0 mT (E_{34.0.0}) acting on the diamond, indicating an NV-NV interaction of equivalent pairs of NV centers and thus a small average distance between the equivalent NV centers.
At this point, the paper presented here points out that, as a rule, diamonds comprise an extremely high density of P1 centers. Therefore, increasing the NV center density does not usually lead to a change in the fluorescence characteristic indicating NV/P1 coupling.
The size of the diamond nano crystals ND is preferably less than 1 mm, better less than 500 μm, better less than 200 μm, better less than 100 μm, better less than 50 μm, better less than 20 μm, better less than 10 μm, better less than 5 μm, better less than 2 μm, better less than 1 μm, better less than 500 nm, better less than 200 nm, better less than 100 nm, better less than 50 nm. The size of the diamond nano crystals can be smaller than 20 nm and/or smaller than 10 nm and/or smaller than 5 nm and/or smaller than 2 nm and/or smaller than 1 nm. The authors are of the opinion that a size of 50 nm is optimal, without the corresponding experiments having been carried out. The same applies when using crystals comprising other materials and replacing the diamond nano crystals ND functionally equivalent in the sensor elements SE or supplementing them in the sensor elements SE. The technical teaching of this document is thus expressly not limited to diamond nano crystals ND with diamond crystals and NV centers. When the text and/or claims refer to diamond nano crystals ND and/or NV centers, a person skilled in the art may read into the use of other crystals and/or other paramagnetic centers. However, these must be expressly tested for suitability for the respective application.

### Fluorescence Characteristics

Fluorescence characteristics in the sense of the paper presented here are characteristic points in the fluorescence intensity curve or the fluorescence delay curve. The fluorescence intensity curve is the graph of the fluorescence intensity values of the intensity Iᵢₛₜ of the fluorescence radiation FL of a diamond nano crystals ND made of diamond plotted against the absolute value of the magnetic flux density B. The fluorescence delay curve is the graph of the time delay values of the time delay of the modulation of the intensity Iᵢₛ of the fluorescence radiation FL with respect to the modulation of the intensity of the pump radiation LB or with respect to the modulation signal S5 or a signal derived therefrom plotted against the absolute value of the magnetic flux density B. Fluorescence characteristics in the fluorescence intensity curve are local minima and maxima in the curve. Fluorescence characteristics in the fluorescence delay curve are local maxima and minima in the curve. The following list enumerates the fluorescence characteristics of an HD-NV diamond (HDNV) with a high density of NV centers determined in the preliminary work on the cited papers. These can be considered as fluorescence characteristics within the meaning of this document when a diamond is used as the crystal of a device or method according to the proposal. When fluorescence characteristics are mentioned in this document, at least the following fluorescence characteristics are meant when a diamond is used as the crystal of a device or method according to the proposal. If other materials are used (see also the contents of the ZPL table), other fluorescence characteristics result, but these are generally attributable to analogous mechanisms. The use of these other materials and the corresponding paramagnetic centers and their fluorescence characteristics is comprised in the disclosure of the present document. In particular, the use of crystals of elements of the II. main group and the VI. main group and the IV. Main Group is comprised in the disclosure herein. Isotopes of the IV main group of the periodic table of the elements and from solid solutions The fluorescence characteristics are not limited to this, however. If necessary, fewer and more fluorescence characteristics may be used:

| | | | | Type of | | |
|---|---|---|---|---|---|---|
| | | | approx. | intensity | Type of delay | |
| | | Pair no. of | position in mT | extremum | extremum | Fluorescence |
| Fluorescence | | fluorescence | (approx. | min = minimum | min = minimum | feature |
| trait group | No. | markers | specification) *) | max = maximum | max = maximum | category |
| 0 mT | E_{0.0,0} | 0 | 0.00 mT | min | max | Main |
| | | | | | | fluorescence |
| | | | | | | feature |
| | E_{0.0,1b} | 1 | 2.10 mT | max | min | Secondary |
| | | | | | | fluorescence |
| | | | | | | feature |
| | E_{0.0,2B} | 2 | 3.80 mT | max | min | Secondary |
| | | | | | | fluorescence |
| | | | | | | feature |
| | E_{0.0,3B} | 3 | 5.30 mT | max | min | Secondary |
| | | | | | | fluorescence |
| | | | | | | feature |
| 9.5 mT | E_{9.5,8a} | 8 | 5.91 mT | max | min | Secondary |
| | | | | | | fluorescence |
| | | | | | | feature |
| | E_{9.5,7a} | 7 | 6.70 mT | max | min | Secondary |
| | | | | | | fluorescence |
| | | | | | | feature |
| | E_{9.5,6a} | 6 | 6.95 mT | min | max | Secondary |
| | | | | | | fluorescence |
| | | | | | | feature |
| | E_{9.5,5a} | 5 | 7.21 mT | max | min | Secondary |
| | | | | | | fluorescence |
| | | | | | | feature |
| | E_{9.5,4a} | 4 | 7.85 mT | min | max | Secondary |
| | | | | | | fluorescence |
| | | | | | | feature |
| | E_{9.5.3a} | 3 | 8.12 mT | max | min | Secondary |
| | | | | | | fluorescence |
| | | | | | | feature |
| | E_{9.5,2a} | 2 | 8.43 mT | min | max | Secondary |
| | | | | | | fluorescence |
| | | | | | | feature |
| | E_{9.5,1a} | 1 | 8.82 mT | max | min | Secondary |
| | | | | | | fluorescence |
| | | | | | | feature |
| | E_{9.5,0} | 0 | 9.38 mT | min | max | Main |
| | | | | | | fluorescence |
| | | | | | | feature |
| | E_{9.5,1b} | 1 | 10.05 mT | max | min | Secondary |
| | | | | | | fluorescence |
| | | | | | | feature |
| | E_{9.5,2b} | 2 | 10.55 mT | min | max | Secondary |
| | | | | | | fluorescence |
| | | | | | | feature |
| | E_{9.5,3b} | 3 | 11.10 mT | max | min | Secondary |
| | | | | | | fluorescence |
| | | | | | | feature |
| | E_{9.5,4b} | 4 | 11.60 mT | min | max | Secondary |
| | | | | | | fluorescence |
| | | | | | | feature |
| | E_{9.5,5b} | 5 | 11.89 mT | max | min | Secondary |
| | | | | | | fluorescence |
| | | | | | | feature |
| | E_{9.5,6b} | 6 | 12.12 mT | min | max | Secondary |
| | | | | | | fluorescence |
| | | | | | | feature |
| 34 mT | E_{34,11a} | 11 | 31.22 mT | max | min | Secondary |
| | | | | | | fluorescence |
| | | | | | | feature |
| | E_{34,10a} | 10 | 31.67 mT | min | max | Secondary |
| | | | | | | fluorescence |
| | | | | | | feature |
| | E_{34,9a} | 9 | 31.78 mT | max | min | Secondary |
| | | | | | | fluorescence |
| | | | | | | feature |
| | E_{34,8a} | 8 | 32.00 mT | min | max | Secondary |
| | | | | | | fluorescence |
| | | | | | | feature |
| | E_{34,7a} | 7 | 32.25 mT | max | min | Secondary |
| | | | | | | fluorescence |
| | | | | | | feature |
| | E_{34,6a} | 6 | 32.63 mT | min | max | Secondary |
| | | | | | | fluorescence |
| | | | | | | feature |
| | E_{34,5a} | 5 | 32.72 mT | max | min | Secondary |
| | | | | | | fluorescence |
| | | | | | | feature |
| | E_{34,4a} | 4 | 32.96 mT | min | max | Secondary |
| | | | | | | fluorescence |
| | | | | | | feature |
| | E_{34,3a} | 3 | 33.24 mT | max | min | Secondary |
| | | | | | | fluorescence |
| | | | | | | feature |
| | E_{34,2a} | 2 | 33.53 mT | min | max | Secondary |
| | | | | | | fluorescence |
| | | | | | | feature |
| | E_{34,1a} | 1 | 33.65 mT | max | min | Secondary |
| | | | | | | fluorescence |
| | | | | | | feature |
| | E_{34,0} | 0 | 33.98 mT | min | max | Main |
| | | | | | | fluorescence |
| | | | | | | feature |
| | E_{34,1b} | 1 | 34.28 mT | max | min | Secondary |
| | | | | | | fluorescence |
| | | | | | | feature |
| | E_{34,2b} | 2 | 34.38 mT | min | max | Secondary |
| | | | | | | fluorescence |
| | | | | | | feature |
| | E_{34,3b} | 3 | 34.72 mT | max | min | Secondary |
| | | | | | | fluorescence |
| | | | | | | feature |
| | E_{34,4b} | 4 | 34.97 mT | min | max | Secondary |
| | | | | | | fluorescence |
| | | | | | | feature |
| | E_{34,5b} | 5 | 35.24 mT | max | min | Secondary |
| | | | | | | fluorescence |
| | | | | | | feature |
| | E_{34,6b} | 6 | 35.35 mT | min | max | Secondary |
| | | | | | | fluorescence |
| | | | | | | feature |
| | E_{34,7b} | 7 | 35.74 mT | max | min | Secondary |
| | | | | | | fluorescence |
| | | | | | | feature |
| | E_{34,8b} | 8 | 36.03 mT | min | max | Secondary |
| | | | | | | fluorescence |
| | | | | | | feature |
| | E_{34,9b} | 9 | 36.30 mT | max | min | Secondary |
| | | | | | | fluorescence |
| | | | | | | feature |
| | E_{34,10a} | 10 | 36.44 mT | min | max | Secondary |
| | | | | | | fluorescence |
| | | | | | | feature |
| | E_{34,11b} | 11 | 36.67 mT | max | mir | Secondary |
| | | | | | | fluorescence |
| | | | | | | feature |
| | E_{34,12b} | 12 | 36.80 mT | min | max | Secondary |
| | | | | | | fluorescence |
| | | | | | | feature |
| | E_{34,13b} | 13 | 36.97 mT | min | min | Secondary |
| | | | | | | fluorescence |
| | | | | | | feature |
| 51.0 mT | E_{51.0,0} | 0 | 51.00 mT | min | max | Main |
| | | | | | | fluorescence |
| | | | | | | feature |
| 59.5 mT | E_{59.5,0} | 0 | 59.50 mT | min | max | Main |
| | | | | | | fluorescence |
| | | | | | | feature |
| 102.4 mT | E_{102.4,9a} | 9 | 97.10 mT | max | min | Secondary |
| | | | | | | fluorescence |
| | | | | | | feature |
| | E_{102.4,8a} | 8 | 97.60 mT | min | max | Secondary |
| | | | | | | fluorescence |
| | | | | | | feature |
| | E_{102.4,7a} | 7 | 98.00 mT | max | min | Secondary |
| | | | | | | fluorescence |
| | | | | | | feature |
| | E_{102.4,6a} | 6 | 98.40 mT | min | max | Secondary |
| | | | | | | fluorescence |
| | | | | | | feature |
| | E_{102.4,5a} | 5 | 98.90 mT | max | min | Secondary |
| | | | | | | fluorescence |
| | | | | | | feature |
| | E_{102.4,4a} | 4 | 99.50 mT | min | max | Secondary |
| | | | | | | fluorescence |
| | | | | | | feature |
| | E_{102.4,3a} | 3 | 100.10 mT | max | min | Secondary |
| | | | | | | fluorescence |
| | | | | | | feature |
| | E_{102.4,2a} | 2 | 101.10 mT | min | max | Secondary |
| | | | | | | fluorescence |
| | | | | | | feature |
| | E_{102.4,1a} | 1 | 101.80 mT | max | min | Secondary |
| | | | | | | fluorescence |
| | | | | | | feature |
| | E_{102.4,0} | 0 | 102.40 mT | min | max | Main |
| | | | | | | fluorescence |
| | | | | | | feature |
| | E_{102.4,1b} | 1 | 103.10 mT | max | min | Secondary |
| | | | | | | fluorescence |
| | | | | | | feature |
| | E_{102.4,2b} | 2 | 103.80 mT | min | max | Secondary |
| | | | | | | fluorescence |
| | | | | | | feature |
| | E_{102.4,3b} | 3 | 104.80 mT | max | min | Secondary |
| | | | | | | fluorescence |
| | | | | | | feature |
| | E_{102.4,4b} | 4 | 105.50 mT | min | max | Secondary |
| | | | | | | fluorescence |
| | | | | | | feature |
| | E_{102.4,5b} | 5 | 106.10 mT | max | min | Secondary |
| | | | | | | fluorescence |
| | | | | | | feature |
| | E_{102.4,6b} | 6 | 106.60 mT | min | max | Secondary |
| | | | | | | fluorescence |
| | | | | | | feature |
| | E_{102.4,7b} | 7 | 107.00 mT | max | min | Secondary |
| | | | | | | fluorescence |
| | | | | | | feature |
| | E_{102.4,8b} | 8 | 107.30 mT | min | max | Secondary |
| | | | | | | fluorescence |
| | | | | | | feature |
| | E_{102.4,9b} | 9 | 107.70 mT | max | min | Secondary |
| | | | | | | fluorescence |
| | | | | | | feature |

*) Also referred to in this document as the characteristic magnetic flux density B of the fluorescence characteristic. The respective characteristic magnetic flux density B of the respective fluorescence characteristic is taken from the drawings. When reworking the technical teaching disclosed here , the document presented here therefore explicitly recommends a prior remeasurement of the precise values of the characteristic magnetic flux densities B. The values could possibly be provided with an offset of max. +/−1 mT and a proportional error of 1%.

### Essentially

The term “essentially means, for the purposes of this document, that deviations from an ideal value are permitted, but that the resulting technical effects only impair the intended purpose of the method or device to such an extent that the usability of the technical device or method for a user is not impaired or only impaired to such an extent that the user assesses the real technical effect as sufficient in comparison to the ideal technical effect.

### Crystal (HDNV)

Preferably, the object referred to herein as a crystal (HDNV) comprises a single crystalline material. If it is not a monocrystalline material, the partial crystals should preferably be monocrystalline and should preferably be aligned in such a way that the fluorescence characteristics are essentially the same. Preferably, the material of the crystal (HDNV) is diamond.
In this regard, the document presented here refers to DE 10 2021 132 783 A1.
However, the principles disclosed in the paper presented here can also be applied with other crystalline materials. Diamond is particularly suitable, however, since cooling of the electron spin configuration to a few mK is easily achieved by exposure to pump radiation (LB) and the T₂ times, in particular those of NV centers, are relatively long. In some places in this text, only dimant is mentioned. Other crystals can also be used here. In the case of using other crystals of materials other than diamond, the devices and methods disclosed in this paper use other paramagnetic centers with other pump radiation wavelengths (λₚₘₚ) and with other fluorescence wavelengths (λ_{FL}). Of particular interest here are silicon crystals, germanium crystals and mixed crystals of elements from the IV main group of the periodic table. In some applications, the crystals are isotopically pure. A material is isotope-pure in the sense of the paper presented here if the concentration of isotopes other than the basic isotopes that dominate the material of the crystal (HDNV) is so low that the technical purpose is achieved to a sufficient extent for the production and sale of products with an economically sufficient production yield. This means that disturbances caused by such isotopic impurities do not interfere with the functionality of the paramagnetic centers, or at most to a sufficiently low degree. In relation to diamond as the material of the crystal (HDNV), this means that the diamond preferably consists essentially of ¹²C isotopes as base isotopes, which have no magnetic moment. This is shown in such a way that, for example, in the fluorescence intensity curve and/or the fluorescence delay curve, the secondary fluorescence features (E_{102.4,9a}, E_{102.4,8a}, E_{102.4,7a}, E_{102.4,6a}, E_{102.4,5a}, E_{102.4,4a}, E_{102.4,3a}, E_{102.4,2a}, E_{102.4,1a}, E_{102.4,1b}, E_{102.4,2b}, E_{102.4,3b}, E_{102.4,4b}, E_{(102.4,)5b}, E_{102.4,6b}, E_{102.4,7b}, E_{102.4,8b}, E_{102.4,9b}) of the 102.4mT main fluorescence feature (E_{102.4,0}) are not or less pronounced. Conversely, it may be desirable that the minor fluorescence features (E_{(102.4,9a)}, E_{102.4,8a}, E_{102.4,7a}, E_{102.4,6a}, E_{102.4,5a}, E_{102.4,4a}, E_{102.4,3a}, E_{102.4,2a}, E_{102.4,1a}, E_{102.4,1b}, E_{102.4,2b}, E_{102.4,3b}, E_{102.4,4b}, E_{102.4,5b}, E_{102.4,6b}, E_{102.4,7b}, E_{102.4,8b}, E_{102.4,9}b) of the 102.4mT main fluorescence feature (E_{102.4,0}) are particularly pronounced, as this enables improved interpolation and calibration. In relation to diamond as the material of the crystal (HDNV), this means that in order to increase the intensity of the secondary fluorescence features, the diamond then preferably consists essentially of 13C isotopes as base isotopes, which have a magnetic moment. A less preferred possibility is that to increase the intensity of the secondary fluorescence features, the diamond preferably comprises an increased proportion of 13C isotopes as base isotopes which have a magnetic moment. The normal isotope distribution assumed in this paper is as follows:

| | Proportion K₀ of isotopes without |
|---|---|
| isotope | magnetic moment at 100% C |
| isotope ¹²C | 98.94 % |
| isotope ¹⁴C | Tracks |
| Total proportion K_{0 G} of isotopes without | 98.94% |
| magnetic moment at 100% C | |
| Total proportion K_{1 G} of isotopes with | 1.06% |
| magnetic moment at 100% C | |

A reduction of the factor K_{IG} by more than 10% and/or better by more than 25% comprises an isotopically pure diamond crystal (HDNV). An increase in the factor K_{IG} by more than 10% and/or better by more than 25% and/or better by more than 50% and/or by more than 100% and/or better by more than 250% and/or better by more than 500% and/or better by more than 1000% and/or better by more than 2500% and/or better by more than 5000% (to K_{(IG})>50%) is comprised in the present document as an isotopically pure diamond crystal (HDNV) with amplified secondary fluorescence features. The use of such diamonds for quantum technological systems in the sense of the document presented here and/or in the sense of the quantum technological devices and methods, in particular in the sense of the quantum technological sensor devices and measurement methods of the documents DE 10 2020 101 784 B3, DE 20 2020 106 110 U, PCT/DE 2020/100 953, PCT/EP 2019/079 992, PCT/EP 2020/068 110, PCT/EP 2020/070 485, PCT/DE 2021/100 069, PCT/DE 2020/100 827, WO 2020 239 172 A1 (PCT/DE 2020/100 430) WO 2001 073 935 A1 and WO 2021 013 308 A1 (PCT/DE 2020/100 648) and the documents cited in these documents are part of the disclosure provided here to the extent permitted by the respective law of the country of filing. What is written here applies to the entire text presented here.

### Pump Radiation λₚₘₚ

### Definition of

The preceding parts of the description use the term pump radiation LB for pumping the paramagnetic centers of the crystals or the diamond nano crystals ND, which preferably comprise diamond. The pump radiation LB comprises a pump radiation wavelength λₚₘₚ. If impurity centers other than NV centers in diamond are used, a proposed device or method may use light or electromagnetic radiation of other pump radiation wavelengths λₚₘₚ as pump radiation LB. In order for this pump radiation LB with the pump radiation wavelength λₚₘₚ to reach the paramagnetic centers in the crystals, the structure of any electrical lines present on the surface of the crystals and other structures on the surface of the crystals should allow the pump radiation LB to pass in the direction of the respective paramagnetic centers. Preferably, the surfaces of the crystals or diamond nano crystals ND are free of such lines and structures.
The sensor systems proposed here now preferably use the HD-NV diamonds (HDNV) with a respective high density of paramagnetic centers in the form of NV centers as sensor elements (SE, 14305), which detect the intensity Iᵢₛₜ of the fluorescence radiation FL of the paramagnetic centers upon exposure to pump radiation LB. The pump radiation LB with the pump radiation wavelength λₚₘₚ causes the respective paramagnetic center or the paramagnetic centers or the group or groups of paramagnetic centers in the crystals or diamond nano crystals ND to emit fluorescence radiation FL with a fluorescence wavelength λ_{fl} upon exposure to the pump radiation LB of the pump radiation wavelength λₚₘₚ. Typically, when NV centers in diamond are used as paramagnetic centers of the crystals or diamond nano crystals ND, the fluorescence wavelength λ_{fl} of the fluorescence radiation FL of the NV centers is such that they appear red. It has been shown that in connection with NV centers in diamond as paramagnetic centers of the crystals or diamond nanocrystals ND, light with a pump radiation wavelength λₚₘₚ of the pump radiation LB of at most 700 nm and at least 500 nm is particularly suitable as pump radiation LB. In connection with the use of crystals of other materials in place of the diamond nano crystals ND or as a supplement for the sensor element SE and correspondingly other paramagnetic centers, completely different wavelength ranges of the pump radiation wavelength λₚₘₚ of the pump radiation LB can fulfill the same functions in the sensor system modified in this way. Therefore, the NV centers here represent only one example of an embodiment of such a paramagnetic center. In particular, when using an NV center in diamond as a paramagnetic center in the crystals or diamond nano crystals ND, the pump radiation LB should comprise a pump radiation wavelength λₚₘₚ in a wavelength range of 400 nm to 700 nm wavelength and/or preferably 450 nm to 650 nm and/or preferably 500 nm to 550 nm and/or preferably 515 nm to 540 nm. A wavelength of 532 nm is clearly preferred as the pump radiation wavelength λₚₘₚ. Light or electromagnetic pump radiation LB, which is used to perform the same functions when other paramagnetic centers are used, in particular in materials other than NV centers in diamond, are also possible. The proposed sensor systems are thus also applicable to other suitable paramagnetic centers, such as SiV center and/or TiV center and/or GeV center and/or SnV center and/or NiN4 center and/or PbV center and/or ST1 center, etc. However, the NV center in diamond is particularly suitable and particularly good, for example as described above, and can be fabricated in high density with high fabrication yield. Expediently, the pump radiation LB of the respective pump radiation source here the light source LED, which is preferably a laser or an LED, is pulsed as a function of a pulsed alternating component of the LED modulation signal S5w by means of the transmission signal S5. The LED modulation signal S5w is used as a measurement signal, i.e. as a reference signal for a look-in amplifier, here the multiple correlator LIV, in order to amplify the modulation of the intensity Iᵢₛₜ of the fluorescence radiation FL converted into modulated electrical currents, in particular photoelectron currents or voltages, for example of a receiver output signal S0, with low noise. It has been recognized that the pulsed pulse modulation of the pump radiation LB and thus the pulsed pulse modulation of the alternating component of the transmission signal S5 should preferably not comprise a 50% duty cycle. The alternating component of the transmission signal S5 has an amplitude of the alternating component of the transmission signal S5. At the beginning of a modulation signal period Tₚ, the value of the transmission signal S5 is the value of the DC component of the transmission signal S5 minus the value of the amplitude of the AC component of the transmission signal S5. The value of the transmission signal S5 then increases to the value of the sum of the value of the amplitude of the alternating component of the transmission signal S5 plus the value of the DC component of the transmission signal S5. For a modulation signal plateau time, the value of the transmission signal S5 then essentially remains at this value level, only to fall with a modulation signal decay time to the value of the difference between the value of the DC component of the transmission signal S5 minus the value of the amplitude of the AC component of the transmission signal S5. The value of the transmission signal S5 then essentially remains at this value until the end of the modulation signal period Tₚ, when the value of the transmission signal S5 rises again with a modulation signal rise time to the value of the sum of the amplitude of the alternating component of the transmission signal S5 plus the value of the constant component of the transmission signal S5. Preferably, the maximum value of the pulses of the alternating component of the transmission signal S5 is maximized in the form of the sum of the amplitude of the alternating component of the transmission signal S5 plus the value of the DC component of the transmission signal S5 in order to achieve a maximum intensity of the pump radiation LB at the times when the pump radiation source, in this case the light source LED, emits pump radiation LB. The purpose of this is to maximize the contrast, since the contrast does not depend linearly on the intensity of the pump radiation LB reaching the paramagnetic centers and adds pump radiation LB to large intensities. This is for single NV centers in diamond, i.e. not for HD NV diamonds as described here, for example from the paper Staacke, R., John, R., Wunderlich, R., Horsthemke, L, Knolle, W., Laube, C, Glosekötter, P., Burchard, B., Abel, B., Meijer, J. (2020), “Isotropic Scalar Quantum Sensing of Magnetic Fields for Industrial Application”, Adv. Quantum Technol., doi: 10.1002/qute.202000037. We refer in particular to FIGS. 3b and 3d of that publication. Due to a high density of paramagnetic centers in the diamond nano crystals ND, such as a high density of NV centers as in a HD-NV diamond as disclosed in the publications EN 10 2021 132 780 A1, EN 10 2021 132 781 A1, EN 10 2021 132 782 A1, EN 10 2021 132 783 A1, EN 10 2021 132 784 A1, EN 10 2021 132 785 A1, EN 10 2021 132 786 A1, EN 10 2021 132 787 A1, EN 10 2021 132 788 A1, EN 10 2021 132 790 A1, EN 10 2021 132 791 A1, EN 10 2021 132 793 A1, EN 10 2021 132 794 A1 the contrast can be increased beyond the level shown in those documents.
The duty cycle of the transmission signal S5 is defined here as the modulation signal pulse duration divided by the modulation signal period T₍ₚ₎. Modulation signal pulse duration plus modulation signal complementary time are equal here to the modulation signal period. Preferably, the alternating component of the transmission signal S5 is pulse modulated with a duty cycle of the alternating component of the transmission signal S5 of less than 50% and/or preferably less than 40% and/or preferably less than 30% and/or preferably less than 20% and/or preferably less than 10%. It is therefore preferably an ultrashort pulse with the highest possible amplitude. Accordingly, the LED modulation signal S5w is preferably pulse-modulated with a duty cycle of less than 50% and/or better than less than 40% and/or better than less than 30% and/or better than less than 20% and/or better than less than 10%. It is therefore preferably an ultrashort pulse. This ultrashort pulse is preferably converted with as large an amplifier as possible into a corresponding short, preferably intense intensity pulse of the intensity of the pump radiation LB. Since the pump radiation source, in this case the light source LED, is driven by the transmission signal S5, it typically reproduces the transmission signal S5 essentially delayed by a transmission delay. For the calculation of many applications, this send delay can be assumed to be 0 s for simplification. Here, the pump radiation pulse duration is defined such that the intensity pulse of the intensity of the pump radiation LB comprises a pump radiation intensity maximum and that the pump radiation pulse duration of an intensity pulse of the pump radiation LB with the first point in time of exceeding 50% of the intensity value of the pump radiation intensity maximum minus the bias value of the intensity of the pump radiation LB, if any, is divided by the instantaneous intensity of the intensity pulse of the pump radiation LB minus the bias value of the intensity of the pump radiation LB, if any, and that the pump radiation pulse duration of an intensity pulse of the pump radiation LB begins at the second point in time of falling below 50% of the intensity value of the pump radiation intensity maximum minus the bias value, if any, of the intensity of the pump radiation LB, by the instantaneous intensity of the intensity pulse of the pump radiation LB minus the bias value, if any, of the intensity of the pump radiation LB.

### ZPL Table

The table is only an exemplary compilation of some possible paramagnetic centers that can be used in crystals that perform the function of diamond nano crystals ND in this document. The functionally equivalent use of other paramagnetic centers in other materials of the crystals is explicitly possible. Testing is required for crystals and/or paramagnetic centers other than NV centers. The pump radiation wavelengths λₚₘₚ of the pump radiation LB are also exemplary. Other pump radiation wavelengths λₚₘₚ are generally possible if they are shorter than the wavelength of the ZPL to be excited.

| Material | | | | |
|---|---|---|---|---|
| of the | | | exemplary | reference |
| crystal | | | pump | radiation |
| ND | Malfunction center | ZPL | wavelength | (λₚₘₚ) |
| diamond | NV center | | 520 nm, 532 nm | |
| Diamond | SiV center | 738 nm | 685 nm | /2/, /3/, /4/ |
| Diamond | GeV center | 602 nm | 532 nm | /4/, /5/ |
| Diamond | SnV center | 620 nm | 532 nm | /4/, /6/ |
| diamond | PbV center | 520 nm, | 450 nm | /4/, /7/ |
| | | 552 nm | | /4/, /7/ |
| | | 715 nm | 532 nm | /7/ |
| Diamond | ST1 center | 555 nm | 532 nm | /15/ |
| diamond | TR12 center | 471 nm | 410 nm | /16/ |
| Silicon | G center | 1278.38 nm | 637 nm | /8/ |
| Silicon carbide | V_{SI} center | 862 nm(V1) 4H, | 1330 nm | /1/, /9/, /10/ |
| | | 858.2 nm(V1′) 4H | 1330 nm | /1/, /9/, /10/ |
| | | 917 nm(V2) 4H | 1330 nm | /1/, /9/, /10/ |
| | | 865 nm(V1) 6H, | 1330 nm | /1/, /9/, /10/ |
| | | 887 nm(V2) 6H | 1330 nm | /1/, /9/, /10/ |
| | | 907 nm(V3) 6H | 1330 nm | /1/, /9/, /10/ |
| Silicon carbide | DV center | 1078-1132 nm 6H | 1330 nm | /9/ |
| Silicon carbide | N_{C}V_{SI} center | 1093-1140 nm 6H | 1330 nm | /9/ |
| Silicon carbide | CAV center | 648.7 nm 4H, 6H, 3C | 1330 nm | /9/ |
| | | 651.8 nm 4H, 6H, 3C | 1330 nm | /9/ |
| | | 665.1 nm 4H, 6H, 3C | 1330 nm | /9/ |
| | | 668.5 nm 4H, 6H, 3C | 1330 nm | /9/ |
| | | 671.7 nm 4H, 6H, 3C | 1330 nm | /9/ |
| | | 673 nm 4H, 6H, 3C | 1330 nm | /9/ |
| | | 675.2 nm 4H, 6H, 3C | 1330 nm | /9/ |
| | | 676.5 nm 4H, 6H, 3C | 1330 nm | /9/ |
| Silicon carbide | N_{C}V_{SI} center | 1180 nm-1242 nm 6H | 1330 nm | /9/, /13/, /14/ |

List of reference literature for the above table
/1/ Marina Radulaski, Matthias Widmann, Matthias Niethammer, Jingyuan Linda Zhang, Sang-Yun Lee, Torsten Rendler, Konstantinos G. Lagoudakis, Nguyen Tien Son, Erik Janzén, Takeshi Ohshima, Jörg Wrachtrup, Jelena Vučković, “Scalable Quantum Photonics with Single Color Centers in Silicon Carbide”, Nano Letters 17 (3), 1782-1786 (2017), DOI: 10.1021/acs.nanolett.6b05102, arXiv: 1612.02874
/2/ C. Wang, C. Kurtsiefer, H. Weinfurter, and B. Burchard, “Single photon emission from SiV centers in diamond produced by ion implantation” J. Phys. B: At. Mol. Opt. Phys., 39(37), 2006
/3/ Björn Tegetmeyer, “Luminescence properties of SiV-centers in diamond diodes” PhD thesis, University of Freiburg, 30.01.2018
/4/ Carlo Bradac, Weibo Gao, Jacopo Forneris, Matt Trusheim, Igor Aharonovich, “Quantum Nanophotonics with Group IV defects in Diamond”, DOI: 10.1038/s41467-020-14316-x, arXiv: 1906.10992
/5/ Rasmus Høy Jensen, Erika Janitz, Yannik Fontana, Yi He, Olivier Gobron, Ilya P. Radko, Mihir Bhaskar, Ruffin Evans, Cesar Daniel Rodriguez Rosenblueth, Lilian Childress, Alexander Huck, Ulrik Lund Andersen, “Cavity-Enhanced Photon Emission from a Single Germanium-Vacancy Center in a Diamond Membrane”, arXiv: 1912.05247v3 [quant-ph] 25 May 2020
/6/ Takayuki Iwasaki, Yoshiyuki Miyamoto, Takashi Taniguchi, Petr Siyushev, Mathias H. Metsch, Fedor Jelezko, Mutsuko Hatano, “Tin-Vacancy Quantum Emitters in Diamond”, Phys. Rev. Lett. 119, 253601 (2017), DOI: 10.1103/PhysRevLett.119.253601, arXiv: 1708.03576 [quant-ph]
/7/ Matthew E. Trusheim, Noel H. Wan, Kevin C. Chen, Christopher J. Ciccarino, Ravishankar Sundararaman, Girish Malladi, Eric Bersin, Michael Walsh, Benjamin Lienhard, Hassaram Bakhru, Prineha Narang, Dirk Englund, “Lead-Related Quantum Emitters in Diamond” Phys. Rev. B 99, 075430 (2019), DOI: 10.1103/PhysRevB.99.075430, arXiv: 1805.12202 [quant-ph]
/8/ M. Hollenbach, Y. Berencén, U. Kentsch, M. Helm, G. V. Astakhov “Engineering telecom single-photon emitters in silicon for scalable quantum photonics” Opt. Express 28, 26111 (2020), DOI: 10.1364/OE.397377, arXiv: 2008.09425 [physics.app-ph]
/9/ Castelletto and Alberto Boretti, “Silicon carbide color centers for quantum applications” 2020 J. Phys. Photonics2 022001
/10/ V. Ivády, J. Davidsson, N. T. Son, T. Ohshima, I. A. Abrikosov, A. Gali, “Identification of Si-vacancy related room-temperature qubits in 4H silicon carbide”, Phys. Rev. B, 2017, 96, 161114
/11/ J. Davidsson, V. Ivády, R. Armiento, N. T. Son, A. Gali, I. A. Abrikosov, ″First principles predictions of magneto-optical data for semiconductor point defect identification: the case of divacancy defects in 4H—SiC”, New J. Phys., 2018, 20, 023035
/12/ J. Davidsson, V. Ivády, R. Armiento, T. Ohshima, N. T. Son, A. Gali, I. A. Abrikosov “Identification of divacancy and silicon vacancy qubits in 6H-SiC”, Appl. Phys. Lett. 2019, 114, 112107
/13/ S. A. Zargaleh, S. Hameau, B. Eble, F. Margaillan, H. J. von Bardeleben, J. L. Cantin, W. Gao, “Nitrogen vacancy center in cubic silicon carbide: a promising qubit in the 1.5 μm spectral range for photonic quantum networks” Phys. Rev. B, 2018, 98, 165203
/14/ S. A. Zargaleh et al “Evidence for near-infrared photoluminescence of nitrogen vacancy centers in 4H—SiC” Phys. Rev. B, 2016, 94, 060102
/15/ P. Balasubramanian, M. H. Metsch, Reddy, R. Prithvi, J. Lachlan, N. B. Manson, M. W. Doherty, F. Jelezko, “Discovery of ST1 centers in natural diamond” Nanophotonics, Vol. 8, No. 11, 2019, pages 1993-2002. https://doi.org/10.1515/nanoph-2019-0148
/16/ J. Foglszinger, A. Denisenko, T. Kornher, M. Schreck, W. Knolle, B. Yavkin, R. Kolesov, J. Wrachtrup ″ODMR on Single TR12 Centers in Diamond” arXiv: 2104.04746v1 [physics.optics]

Radio Waves vs. Microwaves
For the purposes of this document, radio waves in the low frequency range are electromagnetic radiation waves in a frequency range from 3 Hz to 30 kHz, the low frequency range.
For the purposes of this document, radio waves in the radio wave frequency range are electromagnetic radiation waves in a frequency range from 30 kHz to 300 MHz, the radio wave frequency range.
For the purposes of this document, microwaves in the microwave frequency range are electromagnetic radiation waves in a frequency range from 300 MHz to 300 GHz, the microwave frequency range.

### Stripline Technology for Waveguides

Stripline technology for use in connection with waveguides, in particular the exemplary waveguides mentioned herein (1380, 1880, 2380, 6880, 6980), is a method for transferring electrical signals preferably in high frequency applications. Here, the conductive paths (signal lines 1310, 1320, 1330, 6810, 6820) are arranged on an insulating substrate layer (carrier substrate 1360) in order to enable efficient and controlled signal transmission. Here are some of the most important functional elements of stripline technology:
1. Conductor tracks: In stripline technology, the conductor tracks (signal lines 1310, 1320, 1330, 6810, 6820) comprise metal strips that are attached to the substrate (carrier substrate 1360). These metal strips (signal lines 1310, 1320, 1330, 6810, 6820) are used to transfer the electrical signal.
2. Substrate (carrier substrate 1360): The substrate (carrier substrate 1360) is an electrically insulating layer on which the conductor tracks (signal lines 1310, 1320, 1330, 6810, 6820) are placed. Typically, the substrate (carrier substrate 1360) consists of materials such as FR-4 (Flameresistant-4) or PTFE (polytetrafluoroethylene) or of semiconducting materials, such as pieces of semiconductor wafers, for example pieces of CMOS wafers or for example pieces of BiCMOS wafers for example pieces of wafers from a bipolar technology and/or for example pieces of MEMS wafers and/or for example pieces of MEOS wafers (MEOS=micro electro optical system) and/or for example pieces of MOEMS wafers, etc. For example, these pieces of CMOS wafers or pieces of BiCMOS wafers or pieces of wafers from a bipolar technology or pieces of a wafer from a III/V material or the like and/or pieces of MEMS wafers and/or pieces of MEOS wafers (MEOS=micro electro optical system) and/or pieces of MOEMS wafers may comprise microelectronic circuits and functional elements and/or micro-optical functional elements and/or micro-mechanical functional elements and/or micro-fluidic functional elements. The se in turn may comprise sub-functional elements that interact with the paramagnetic centers and/or NV centers of the sensor element layer 14305 and or sensor elements SE.
3. Dielectric: The dielectric is the insulating material that surrounds the conductors (signal lines 1310, 1320, 1330, 6810, 6820) and separates them from each other. It is used to maintain the signal integrity of the signals on the conductor tracks (signal lines 1310, 1320, 1330, 6810, 6820) and to minimize unwanted signal losses. Air or a special low-loss dielectric such as PTFE is often used for strip conductors (B waveguides 1380, 1880, 2380, 6880, 6980).
4. Impedance control (control of characteristic impedance): In stripline technology, impedance control of the characteristic impedance of the waveguides (B waveguides 1380, 1880, 2380, 6880, 6980) is an important aspect. The width and geometry of the conductors (signal lines 1310, 1320, 1330, 6810, 6820) as well as the properties of the dielectric are designed to achieve the desired impedance (characteristic impedance) of the transmission system. This ensures efficient signal transmission and minimizes reflections.
5. Terminal resistors (6710): Terminal resistors (6710) are placed at the end of a stripline (signal lines 1310, 1320, 1330, 6810, 6820) to minimize reflections and improve signal integrity. They are used to terminate the impedance (characteristic impedance) of the stripline waveguides (e.g. waveguide 1380, 1880, 2380, 6880, 6980) and ensure efficient signal transmission.
6. Connection structures: In stripline technology, various connection structures such as T-connectors, cross-connectors and S-connectors are used to connect traces (signal lines 1310, 1320, 1330, 6810, 6820) and/or various striplines (B waveguides 1380, 1880, 2380, 6880, 6980) to each other, to branch or combine signals.
   These functional elements are fundamental to the design and operation of striplines in high-frequency applications. They enable precise signal transmission and high performance in regions such as high-frequency communication, microwave and radar technology, power electronics and much more. Wikipedia (https://de.wikipedia.org/wiki/Streifenleitung) contains the following functional elements (citation):
   “Simple components such as capacitors and inductors can be created directly using specially dimensioned strips. Long, thin conductors have an inductive effect, while wide, short ones have a capacitive effect. In addition to these classic components, other components typical of high-frequency technology can be realized directly with strips.
   These include:
Swamp (non-reflective finish)
Impedance matching, inductive or capacitive coupling
Reflector, series resonant circuit, parallel resonant circuit
   More complex functional units can be fabricated from these basic elements:
Directional coupler
Power divider
Filter (bandpass, bandstop, high pass, low pass)
Crossovers
Transformer for decoupling and coupling, potential separation, impedance or symmetry matching
   Discrete components, such as those used on normal circuit boards, can also be soldered onto a microstrip conductor circuit if their dimensions and mutual interference are taken into account. SMD components are particularly suitable. Partially, SMD designs are also specially designed for this case. This is particularly the case with active elements such as transistors or diodes.”
   Various microwave components can be realized in microstrip line technology. Here are some of the most important ones:
1. Microstrip line: A microstrip line is an embossed conductor track on a dielectric layer that lies on a conductive substrate. It serves as a transmission medium for microwave signals.
2. Microstrip junction: A microstrip junction enables the connection of two microstrip lines with different impedances.
3. Microstrip filter: A microstrip filter is an electronic component that is used to filter certain frequency ranges in a microwave signal. For example, it can be designed as a low pass filter, high pass filter or band pass filter.
4. Microstrip coupler: A microstrip coupler is used to transfer a microwave signal from one microstrip line to another. There are different types of couplers, such as directional couplers, hybrid couplers and ring couplers.
5. Microstrip phase shifter: A microstrip phase shifter is a component used to change the phase of a microwave signal. It can be used for phase modulation, phase control or phase adjustment.
6. Microstrip delay line: A microstrip delay line is a special form of microstrip line that is used to delay the propagation time of microwave signals. It can be used for phase correction, signal processing or the generation of delay elements.
7. Microstrip circuit elements: Various circuit elements can also be realized in microstrip line technology, such as microstrip diodes, microstrip transistors, microstrip inductors and microstrip capacitors. These are generally used for active circuits and passive components.
   There are many other microwave components that can be used in microstrip line technology. However, the examples given should provide an overview of the basic components.
   The use of these functional elements together with the sensor elements SE and/or sensor element layers 14305 as defined herein are part of the disclosure of the document provided herein.

### General Information on Different Types of Waveguide

This section is intended to apply to any waveguide and thus to the entire document. The document presented here mentions only for the sake of completeness that in principle the presence of one or more sensor elements SE(1410, 1420, 1430, 7110, 7120, 2210, 2410, 2420, 2430, 4410) on a waveguide, here the exemplary differential trip-plate waveguide 6980 and/or the exemplary differential microstrip waveguide 6880 and/or the exemplary microstrip waveguide 1330 and/or the exemplary slot line 1880 and/or the exemplary trip-plate waveguide 2380 and/or other preferably planar waveguides is always possible. In this case, several different of these types of sensor elements SE can always be “fused” into one sensor element SE.
Preferably, at least one sensor element channel is assigned to each of these sensor elements SE.
If more than one sensor element channel is assigned to a sensor element SE, the sensor element should preferably comprise different paramagnetic centers with at least two different pump radiation wavelengths λₚₘₚ and preferably each sensor element channel of the at least two assigned sensor element channels should use a pump radiation wavelength λₚₘₚ of these pump radiation wavelengths λₚₘₚ which is different from the pump radiation wavelengths λₚₘₚ used by the other sensor element channels of this sensor element SE. In principle, more than one sensor element SE can be assigned to a sensor element channel within the meaning of this document.
The document presented here mentions only for the sake of completeness that in principle the presence of one or more sensor elements SE(1410, 1420, 1430, 7110, 7120, 2210, 2410, 2420, 2430, 4410) on a waveguide, here the differential trip-plate waveguide 6980 as an example, is always possible. Here, one or more of the sensor elements SE may comprise nano crystals ND with paramagnetic centers in place of the diamond nano crystals ND and their paramagnetic centers. These nano crystals ND with paramagnetic centers in place of the diamond nano crystals ND and their paramagnetic centers may comprise, in particular, crystals other than diamond crystals and therefore paramagnetic centers other than the paramagnetic centers in diamond nano crystals ND mentioned herein.
If such other nano crystals ND and/or other paramagnetic centers are used in sensor elements SE, the pump radiation wavelength λₚₘₚ of the pump radiation source, in particular the light source LED, of the sensor element channel assigned to such a sensor element SE should in particular be adapted to these other paramagnetic centers of these possibly other nano crystals ND. Preferably, the LED modulation frequency f_{LED} should be different at least between sensor element channels with different pump radiation wavelengths λ₍ₚₘₚ₎.
If such other nanocrystals ND and/or other paramagnetic centers are used in sensor elements SE, the other device parts of the sensor element channels and/or the parameters for their operation of the sensor element channel assigned to such a sensor element SE should also be adapted to these other paramagnetic centers of these possibly other nanocrystals ND.
The positioning of the structure of FIG. 2 in the two-dimensional parameter surface consisting of total magnetic flux density B_{Σ} or additional magnetic flux density B_{ad} on the one hand and its shape depends on the nano crystals or diamond nano crystals ND used and the paramagnetic centers used. Typically, the presence of a structure similar to that of FIG. 2 for a crystal used as a diamond nano crystals ND and its crystal material as well as the paramagnetic centers used and employed in this crystal is a prerequisite for the application of the technical teaching described here. If other crystals made of a material other than diamond and/or other paramagnetic centers than NV centers are to be used in diamond, the structure of FIG. 2 or a functionally equivalent structure should be demonstrated in corresponding measured values during reworking.
Thus, the microwave frequency f_{μW} can be used to select different paramagnetic centers. It is therefore conceivable that one or more sensor elements SE comprise different nano crystals ND with paramagnetic centers instead of diamond nano crystals ND and their paramagnetic centers and/or diamond nano crystals ND with different paramagnetic centers, for example SiV centers and NV centers. Thus, by using different microwave frequencies f_{μW}, the proposed device can address different paramagnetic centers and thus possibly also different sensor elements SE.
As shown in the descriptions of FIGS. 13 to 64 and 68 to 134, the sensitivity and selectivity of the respective sensor element SE with respect to the total magnetic flux density B and/or the external magnetic flux density B(ext) and/or the additional magnetic flux density B (ad) and/or the magnetic flux density component B(μW) of the microwave signal can be increased by different positioning and/or shaping of the sensor elements relative to the device elements of the respective waveguide (1380, 1880, 2380, 6880, 6980). the total magnetic flux density B_{Σ} and/or the external magnetic flux density Bₑₓₜ and/or the additional magnetic flux density B_{ad} and/or the magnetic flux density component B_{μW} of the microwave signal μW can be controlled.
Furthermore, the respective LED modulation frequency f_{LED} can be used to differentiate between the sensor elements SE with different paramagnetic centers of different associated pump radiation wavelengths λ₍ₚₘₚ₎.

### Sensor Element Channel

A sensor element channel within the meaning of the document presented here comprises a light radiation source driver LDRV, a pump radiation source (LED), first optical means (LWL) for transporting the pump radiation LB to the sensor element SE, second optical means (LWL) for transporting the fluorescence radiation FL of the sensor element SE to the photo detector PD, a photo detector PD, means (F1) for separating the fluorescence radiation FL from the total radiation spectrum before reaching the photo detector PD, optionally means (1380, 1880, 2380, 6880, 6980, μWG) for irradiating the sensor element SE with electromagnetic radiation of a microwave signal μW. means (1380, 1880, 2380, 6880, 6980, μWG) for exposure of the sensor element SE to electromagnetic radiation of a microwave signal μW, optionally means (μWG) for generating the microwave signal μW, means (G1, S5, S5w) for modulating the intensity of the pump radiation LB of the pump radiation source (LED) with an LED modulation signal S5w, means (G1) for generating the LED modulation signal S5w, means (S5m, G2) for modulating the amplitude of the microwave signal μW by means of a microwave modulation signal S5m, means (G2) for generating the microwave modulation signal S5m, means (V1) for conditioning the receiver output signal S0 of the photo detector PD to form a conditioned (amplified, filtered and/or digitized) receiver output signal S1, means (LIV) for performing a multiple correlation at least between the conditioned (amplified, filtered and/or digitized) receiver output signal S1, the LED modulation signal S5w and, if applicable, the microwave modulation signal S5m, means (G2) for generating the microwave modulation signal S5m, means (V1) for conditioning the receiver output signal S0 of the photo detector PD to form a conditioned (amplified, filtered and/or digitized) receiver output signal S1, means (LIV) for performing a multiple correlation at least between the conditioned (amplified, filtered and/or digitized) receiver output signal S1, the LED modulation signal S5w and, if applicable, the microwave modulation signal S5m. the microwave modulation signal S5m to generate a correlation result, for example for transfer to the control device CTR. For the purposes of the present document, the sensor element SE itself is not part of the sensor element channel. A sensor system thus preferably comprises at least one sensor element SE, one or more sensor element channels and a control device CTR with memories RAM, NVM for controlling the sensor channel and for controlling the device parts of the sensor system and for communicating with higher-level computer systems. Preferably, such a sensor system can comprise, for example, further components such as means (LCTR, LDRV, L_{c}) for generating an additional magnetic flux density B_{ad} and/or means (MS, SIS) for measuring the total flux density B_{Σ} and/or means (MEV) for pattern recognition.
Potential Interaction with Plasmonic Nanoparticles in the Sensor Element SE
The fluorescence radiation of the NV centers and/or the other paramagnetic centers in the crystals and/or diamond nano crystals ND in the substrate materials TM of the sensor elements SE and, in particular, the fluorescence wavelength λ_{fl} of the fluorescence radiation FL of the NV centers and/or the other paramagnetic centers in the crystals and/or diamond nano crystals ND in the substrate materials TM of the sensor elements SE can be modified, for example, by means of plasmonic coupling by optional metallic nanoparticles, which are also added to the substrate materials TM of sensor elements SE during the fabrication of the colloidal mixtures KL. In this case, for example, a substrate material TM of the colloidal mixture KL may comprise metallic nanoparticles with a diameter smaller than 200 nm and/or smaller than 100 nm and/or smaller than 50 nm and/or smaller than 20 nm and/or smaller than 10 nm and/or smaller than 5 nm, which are later embedded in the solidified substrate material TM of the colloidal mixture KL. This improves the applicability in special applications.

The metallic nanoparticles then typically interact plasmonically with the NV centers and/or the other paramagnetic centers in the crystals and/or diamond nano crystals ND in the substrate materials TM of the sensor elements SE and thus influence the fluorescence radiation FL of these NV centers and/or the other paramagnetic centers in the crystals and/or diamond nano crystals ND in the substrate materials TM of the sensor elements SE.

These metallic nanoparticles typically have gold and/or platinum and/or palladium and/or graphite and/or graphene and/or chromium and/or silicon and/or germanium and/or tin and/or sulphu and/or selenium and/or tellurium and/or magnesium and/or calcium and/or strontium and/or barium and/or titanium and/or zirconium and/or hafnium and/or chromium and/or molybdenum and/or tungsten and/or iron and/or ruthenium and/or osmium and/or nickel and/or tin and/or cadmium and/or mercury and/or cerium and/or neodymium and/or samarium and/or gadolinium and/or dysprosium and/or erbium and/or ytterbium and/or thorium and/or proactinium and/or uranium and/or plutonium. Whereby the former are particularly preferred.

The atoms of the metal of these optional nanoparticles comprise one or more elements of the periodic table. Each of these elements occurs in different isotopes in nature with a respective natural isotope mixing ratio. Each isotope of an element comprises a natural proportion corresponding to the natural isotope mixing ratio of that element. With regard to these proportions and the values, the document presented here refers to the applicant's German patent application DE 10 2020 125 178 A1. These isotopes each comprise a magnetic nuclear moment u or not, depending on the isotope. Preferably, the metallic nanoparticles have an increased proportion in the isotope mixing ratio for at least one element comprised by the metallic nanoparticles compared to the natural proportion of the isotope mixing ratio for at least one of the following isotopes: ¹²C, ¹⁴C, ²⁸Si, ³⁰Si, ⁷⁰Ge, ⁷²Ge, ⁷⁴Ge, ⁷⁶Ge, ¹¹²Zn, ¹¹⁴Zn, ¹¹⁶Zn, ¹¹⁸Zn, ¹²⁰Zn, ¹²²Zn, ¹²⁴Zn, ¹⁶O, ¹⁸O, ³²S, ³⁴S, ³⁶S, ⁷⁴Se, ⁷⁶Se, ⁷⁸Se, ⁸⁰Se, ⁸²Se, ¹²⁰Te, ¹²²Te, ¹²⁴Te, ¹²⁶Te, ¹²⁸Te, ¹³⁰Te, ²⁴ Mg, ²⁶ Mg, ⁴⁰Ca, ⁴²Ca, ⁴⁴Ca, ⁴⁶Ca, ⁴⁸Ca, ⁸⁴Sr, ⁸⁶Sr, ⁸⁸Sr, ¹³⁰Ba, ¹³²Ba, ¹³⁴Ba, ¹³⁶Ba, ¹³⁸Ba, ⁴⁶Ti, ⁴⁸Ti, ⁵⁰Ti, ⁹⁰Zr, ⁹⁰Zr, ⁹²Zr, ⁹⁴Zr, ⁹⁶Zr, ¹⁷⁴Hf, ¹⁷⁶Hf, ¹⁷⁸Hf, ⁵⁰Cr, ⁵²Cr, ⁵³Cr, ⁹²Mo, ⁹⁴Mo, ⁹⁶Mo, ⁹⁸Mo, ¹⁰⁰Mo, ¹⁸⁰W, ¹⁸²W, ¹⁸⁴W, ¹⁸⁶W, ⁵⁴Fe, ⁵⁶Fe, ⁵⁸Fe, ⁹⁶Ru, ⁹⁸Ru, ¹⁰⁰Ru, ¹⁰²Ru, ¹⁰⁴Ru, ¹⁸⁴Os, ¹⁸⁶Os, ¹⁸⁸Os, ¹⁹⁰Os, ¹⁹²Os, ⁵⁸Ni, ⁶⁰Ni, ⁶²Ni, ⁶⁴Ni, ¹⁰²Pd, ¹⁰²Pd, ¹⁰⁴Pd, ¹⁰⁶Pd, ¹⁰⁸Pd, ¹¹⁰Pd, ¹⁹⁰ Pt, ¹⁹²Pt, ¹⁹⁴Pt, ¹⁹⁶Pt, ¹⁹⁸Pt, ⁶⁴Zn, ⁶⁶Zn, ⁶⁸Zn, ⁷⁰Zn, ¹⁰⁶Cd, ¹⁰⁸Cd, ¹¹⁰Cd, ¹¹²Cd, ¹¹⁴Cd, ¹¹⁶Cd, ¹⁹⁶Hg, ¹⁹⁸Hg, ²⁰⁰Hg, ²⁰²Hg, ²⁰⁴Hg, ¹³⁶Ce, ¹³⁸Ce, ¹⁴⁰Ce, ¹⁴²Ce, ¹⁴²Nd, ¹⁴⁴Nd, ¹⁴⁶Nd, ¹⁴⁸Nd, ¹⁵⁰Nd, ¹⁴⁴Sm, ¹⁴⁶Sm, ¹⁴⁸Sm, ¹⁵⁰Sm, ¹⁵²Sm, ¹⁵⁴Sm, ¹⁵²Gd, ¹⁵⁴Gd, ¹⁵⁶Gd, ¹⁵⁸Gd, ¹⁶⁰Gd, ¹⁵⁶Dy, ¹⁵⁸Dy, ¹⁶⁰Dy, ¹⁶²Dy, ¹⁶⁴Dy, ¹⁶²Er, ¹⁶⁴Er, ¹⁶⁶Er, ¹⁶⁸Er, ¹⁷⁰Er, ¹⁶⁸Yb, ¹⁷⁰Yb, ¹⁷²Yb, ¹⁷⁴Yb, ¹⁷⁶Yb, ²³²Th, ²³⁴Pa, ²³⁴U, ²³⁸U, ²⁴⁴Pu.

### LIST OF CITED WRITINGS

To the extent that disclosure by reference is permitted in the context of the nationalization of a subsequent international application under the law of the particular jurisdiction in which the nationalization of the international application of the document submitted herein takes place, the contents of the following documents form an integral part of the disclosure submitted herein.

### Patent Literature

DE 10 2018 127 394 A1, DE 10 2019 120 076 A1, DE 10 2019 121 028 A1, DE 10 2020 101 784 B3,
DE 10 2020 109 477 A1, DE 10 2020 125 178 A1, DE 10 2020 129 319 A1, DE 10 2020 129 367 A1,
DE 10 2021 101 565 A1, DE 10 2021 114 589.9, DE 10 2021 132 148 A1, DE 10 2021 132 780 A1,
DE 10 2021 132 781 A1, DE 10 2021 132 782 A1, DE 10 2021 132 783 A1, DE 10 2021 132 784 A1,
DE 10 2021 132 785 A1, DE 10 2021 132 786 A1, DE 10 2021 132 787 A1, DE 10 2021 132 788 A1,
DE 10 2021 132 790 A1, DE 10 2021 132 791 A1, DE 10 2021 132 793 A1, DE 10 2021 132 794 A1,
EN 10 2022 121 444.3, EN 10 2022 122 505.7, EN 10 2022 122 507.0, EN 10 2023 100 856.0,
DE 10 2023 100 857.9, DE 10 2023 111 858.7, DE 10 2023 111 859.5, DE 11 2020 003 569 A5,
DE 11 2020 004 650 A5, DE 20 2020 106 110 U
EP 3 213 093 B1, EP 3 874 343 A2
US 2017/0 322 244 A1, US 2022/0 307 997 A1,
WO 2001 073 935 A1, WO 2020 089 465 A1, WO 2020 239 172 A1, WO 2020 260 640 A1,
WO 2021 013 308 A1, WO 2021 083 448 A1, WO 2021 089 091 A1, WO 2021 018 654 A1,
WHERE 2021 151 429 A1

### Non-Patent Literature

Keunhong Jeong, Anna J. Parker, Ralph H. Page, Alexander Pines, Christophoros C. Vassiliou, Jonathan P. King “Understanding the Magnetic Resonance Spectrum of Nitrogen Vacancy Centers in an Ensemble of Randomly Oriented Nanodiamonds”, The Journal of Physical Chemistry C, 2017, 121 (38), p. 21057-21061, DOI: 10.1021/acs.jpcc.7607247
R. K. Hoffmann “Integrated Microwave Circuits: Electrical Principles, Dimensioning, Technical Design, Technologies” Springer; 1st Edition (Jun. 1, 1983), ISBN-10:3540123520, ISBN-13:978-3540123521 Marc J. Madou “Fundamentals of Microfabrication: the science of miniaturization” CRC Press 2002
Röcke H., Meijer J., Stephan A., Weidenmüller U., Bukow H. H., Rolfs C. “White electroluminescent nanostructure in silicon fabricated using focused ion implantation” Nuclear Instruments and Methods in Physics Research B 181 (1001) page 274-279.
Baha E. A. Saleh, Malvin Carl Teich, “Fundamentals of Photonics “Wiley-VCH, 2007
Bernhard C. Kress, Patrick Meyreueis “Applied Digital Optics” Wiley, 2009
Burchard B., “Elektronische und optoelektronische Bauelemente und Bauelementstrukturen auf Diamantbasis” Dissertation, Hagen 1994.
K. Kurokawa, “Avalanche Breakdown Electroluminescence in Silicon Carbide Light Emitting Diodes”, January 2000Materials Science Forum 338-342:691-694, DOI: 10.4028/www.scientific.net/MSF.338-342.691
Staacke, R., John, R., Wunderlich, R., Horsthemke, L, Knolle, W., Laube, C, Glösekötter, P., Burchard, B., Abel, B., Meijer, J. (2020), “Isotropic Scalar Quantum Sensing of Magnetic Fields for Industrial Application”, Adv. Quantum Technol., doi: 10.1002/qute.202000037,
Marina Radulaski, Matthias Widmann, Matthias Niethammer, Jingyuan Linda Zhang, Sang-Yun Lee, Torsten Rendler, Konstantinos G. Lagoudakis, Nguyen Tien Son, Erik Janzén, Takeshi Ohshima, Jörg Wrachtrup, Jelena Vučković, “Scalable Quantum Photonics with Single Color Centers in Silicon Carbide”, Nano Letters 17 (3), 1782-1786 (2017), DOI: 10.1021/acs.nanolett.6b05102, arXiv: 1612.02874
C. Wang, C. Kurtsiefer, H. Weinfurter, and B. Burchard, “Single photon emission from SiV centers in diamond produced by ion implantation” J. Phys. B: At. Mol. Opt. Phys., 39 (37), 2006
Björn Tegetmeyer, “Luminescence properties of SiV-centers in diamond diodes” PhD thesis, University of Freiburg, 30 Jan. 2018
Carlo Bradac, Weibo Gao, Jacopo Forneris, Matt Trusheim, Igor Aharonovich, “Quantum Nanophotonics with Group IV defects in Diamond”, DOI: 10.1038/s41467-020-14316-x, arXiv: 1906.10992
Rasmus Høy Jensen, Erika Janitz, Yannik Fontana, Yi He, Olivier Gobron, Ilya P. Radko, Mihir Bhaskar, Ruffin Evans, Cesar Daniel Rodriguez Rosenblueth, Lilian Childress, Alexander Huck, Ulrik Lund Andersen, “Cavity-Enhanced Photon Emission from a Single Germanium-Vacancy Center in a Diamond Membrane”, arXiv: 1912.05247v3 [quant-ph] 25 May 2020
Takayuki Iwasaki, Yoshiyuki Miyamoto, Takashi Taniguchi, Petr Siyushev, Mathias H. Metsch, Fedor Jelezko, Mutsuko Hatano, “Tin-Vacancy Quantum Emitters in Diamond”, Phys. Rev. Lett. 119, 253601 (2017), DOI: 10.1103/PhysRevLett.119.253601, arXiv: 1708.03576 [quant-ph]
Matthew E. Trusheim, Noel H. Wan, Kevin C. Chen, Christopher J. Ciccarino, Ravishankar Sundararaman, Girish Malladi, Eric Bersin, Michael Walsh, Benjamin Lienhard, Hassaram Bakhru, Prineha Narang, Dirk Englund, “Lead-Related Quantum Emitters in Diamond” Phys. Rev. B 99, 075430 (2019), DOI: 10.1103/PhysRevB.99.075430, arXiv: 1805.12202 [quant-ph]
M. Hollenbach, Y. Berencén, U. Kentsch, M. Helm, G. V. Astakhov “Engineering telecom single-photon emitters in silicon for scalable quantum photonics” Opt. Express 28, 26111 (2020), DOI: 10.1364/OE.397377, arXiv: 2008.09425 [physics.app-ph]
Castelletto and Alberto Boretti, “Silicon carbide color centers for quantum applications” 2020 J. Phys. Photonics2 022001
V. Ivády, J. Davidsson, N. T. Son, T. Ohshima, I. A. Abrikosov, A. Gali, “Identification of Si-vacancy related room-temperature qubits in 4H silicon carbide”, Phys. Rev.B, 2017, 96, 161114
J. Davidsson, V. Ivády, R. Armiento, N. T. Son, A. Gali, I. A. Abrikosov, “First principles predictions of magneto-optical data for semiconductor point defect identification: the case of divacancy defects in 4H—SiC”, New J. Phys., 2018, 20, 023035
J. Davidsson, V. Ivády, R. Armiento, T. Ohshima, N. T. Son, A. Gali, I. A. Abrikosov “Identification of divacancy and silicon vacancy qubits in 6H—SiC”, Appl. Phys. Lett. 2019, 114, 112107
S. A. Zargaleh, S. Hameau, B. Eble, F. Margaillan, H. J. von Bardeleben, J. L. Cantin, W. Gao, “Nitrogen vacancy center in cubic silicon carbide: a promising qubit in the 1.5 μm spectral range for photonic quantum networks” Phys. Rev.B, 2018, 98, 165203
S. A. Zargaleh et al “Evidence for near-infrared photoluminescence of nitrogen vacancy centers in 4H—SiC” Phys. Rev.B, 2016, 94, 060102
P. Balasubramanian, M. H. Metsch, Reddy, R. Prithvi, J. Lachlan, N. B. Manson, M. W. Doherty, F. Jelezko, “Discovery of ST1 centers in natural diamond” Nanophotonics, Vol. 8, No. 11, 2019, pages 1993-2002. https://doi.org/10.1515/nanoph-2019-0148
J. Foglszinger, A. Denisenko, T. Kornher, M. Schreck, W. Knolle, B. Yavkin, R. Kolesov, J. Wrachtrup “ODMR on Single TR12 Centers in Diamond” arXiv: 2104.04746v1 [physics.optics]
IEEE Standard for Test Access Port and Boundary-Scan Architecture, IEEE Std 1149.1-2013 (Revision of IEEE Std 1149.1-2001).
IEEE Standard for Reduced-Pin and Enhanced-Functionality Test Access Port and Boundary-Scan Architecture IEEE Std 1149.7-2009
IEEE Supplement to Standard Test Access Port and Boundary-Scan Architecture (1149.1) IEEE Std 1149.1b-1994
IEEE Standard for Reduced-Pin and Enhanced-Functionality Test Access Port and Boundary-Scan Architecture, IEEE Std 1149.7-2022 (Revision of IEEE Std 1149.7-2009)
IEEE Standard for Access and Control of Instrumentation Embedded within a Semiconductor Device, IEEE Std 1687-2014 Ilja Fescenko, Andrey Jarmola, Igor Savukov, Pauli Kehayias, Janis Smits, Joshua Damron, Nathaniel Ristoff, Nazanin Mosavian and Victor M. Acosta “Diamond magnetometer enhanced by ferrite flux concentrators”, Phys. Rev. Research 2, 023394, 24 Jun. 2020, DOI: https://doi.org/10.1103/PhysRevResearch.2.023394
Georgios Chatzidrosos, Joseph Shaji Rebeirro, Huijie Zheng, Muhib Omar, Andreas Brenneis, Felix M. Stürner, Tino Fuchs, Thomas Buck, Robert Rölver, Tim Schneemann, Peter B1ümler, Dmitry Budker, Arne Wickenbrock, “Fiberized Diamond-Based Vector Magnetometers”, Front. Photon., Aug. 20, 2021, Sec. Quantum Optics, Volume 2-2021| https://doi.org/10.3389/fphot.2021.732748
Yuji Hatano, Jaewon Shin, Daisuke Nishitani, Haruki Iwatsuka, Yuta Masuyama, Hiroki Sugiyama, Makoto Ishii, Shinobu Onoda, Takeshi Ohshima, Keigo Arai, Takayuki Iwasaki, Mutsuko Hatano, “Simultaneous thermometry and magnetometry using a fiber-coupled quantum diamond sensor” Appl. Phys. Lett. 118, 034001 (2021) https://doi.org/10.1063/5.0031502,
https://de.wikipedia.org/wiki/Lichtwellenleiter
“https://de.wikipedia.org/wiki/Streifenleitung”
“https://de.wikipedia.org/wiki/Joint_Test_Action_Group”
“https://www.corelis.com/education/tutorials/boundary-scan/”
“https://de.wikipedia.org/wiki/Statistische_Versuchsplanung”
“https://www.norlandprod.com/adhesives/noa%2061.html”

What is claimed is:

1. An optical waveguide system comprising:
a sensor element; and
an optical waveguide, wherein:
the sensor element further includes a substrate material and;
a multiplicity of diamonds embedded in the substrate material, wherein;
one or more diamonds of the multiplicity of diamonds include NV centers and/or other paramagnetic centers;
the NV centers of the sensor element and/or the other paramagnetic centers of the sensor element emit at least one fluorescence radiation upon exposure to pump radiation;
that:
the substrate material is radiation cured;
the substrate material is essentially transparent to radiation with a pump radiation wavelength (λₚₘₚ) of the pump radiation with which the NV centers and/or the other paramagnetic centers are pumped; and
the substrate material is essentially transparent to radiation with a fluorescence wavelength (λ_{FL}) of the at least one fluorescence radiation of the NV centers and/or of the other paramagnetic centers.

2. A method for fabricating an optical waveguide system,
comprising:
deploying an optical waveguide, wherein the optical waveguide comprises a first end and a second end;
deploying a liquid substrate material curable by means of electromagnetic radiation of a curing wavelength (λ_{H}); wherein:
a multiplicity of diamonds) and/or crystals are embedded in the substrate material;
one or more diamonds of the multiplicity of diamonds and/or crystals comprise NV centers and/or other paramagnetic centers; and
the NV centers of the substrate material and/or the other paramagnetic centers of the substrate material emit at least one fluorescence radiation upon exposure to pump radiation of a pump radiation wavelength (λₚₘₚ);
wetting the first end of the optical waveguide, with the substrate material comprising the multiplicity of embedded diamonds and/or crystals;
exposing the substrate material in a region of the first end of the optical waveguide to electromagnetic curing radiation;
wherein the curing wavelength (H) of the electromagnetic radiation is selected such that the substrate material at the first end of the optical waveguide cures at least partially in an irradiated area and transforms at least partially into a solid; and
removing uncured substrate material,
wherein a remaining film of the substrate material at the first end of the optical waveguide forms one or more sensor elements.

3. The method for fabricating fabrication of the an optical waveguide system (LWL) according to claim 2, wherein the exposing of the substrate material in the region of the first end of the optical waveguide further comprises injecting electromagnetic curing radiation into the second end of the optical waveguide, wherein the curing wavelength (H) of this electromagnetic curing radiation is selected such that the substrate material at the first end of the optical waveguide cures and transforms into a solid.

4. The method for fabrication of fabricating an the optical waveguide system (LWL) according to claim 2, wherein the substrate material only partially hardens during exposure to the electromagnetic curing radiation of the curing wavelength (λ_{H}).

5. The method for fabrication of fabricating an the optical waveguide system (LWL) according to claim 2, wherein the electromagnetic curing radiation fed in at the second end of the optical waveguide for curing is UV radiation having the curing wavelength (λ_{H}) in a wavelength range from 1 nm to 400 nm.

6. The method for fabrication of an fabricating the optical waveguide system (LWL) according to claim 2, wherein the optical waveguide further includes:
an optical waveguide core at least at the first end of the optical waveguide, and/or
is coated, at least at the first end of the optical waveguide, with a light-impermeable layer comprising one or more light-permeable openings or clearances;
wherein the optical waveguide core and/or the clearances, limit light emission of the electromagnetic curing radiation with the curing wavelength (λ_{H}) at the first end of the optical waveguide to one or more emission areas;
wherein whereby the method being carried out in the substrate material during curing by injecting the electromagnetic curing radiation with the curing wavelength (λ_{H}) at the second end of the optical waveguide;
one or more optical functional elements; and/or
one or more sensor elements;
is formed at the first end of the optical waveguide in the region of one or more emission areas; and
wherein the one or more optical functional elements thus formed by the method and/or the one or more sensor elements thus formed by the method are configured by the method such that the one or more optical functional elements thus formed by the method and/or the one or more sensor elements thus formed by the method:
with the optical waveguide core at the first end of the optical waveguide; and/or
with the one or more clearances at the first end of the optical waveguide;
interact optically;
if optical radiation, in particular pump radiation with the pump radiation wavelength (λₚₘₚ) is fed in at the second end of the optical waveguide; and/or
if NV centers within the substrate material and/or other paramagnetic centers within the substrate material emit the at least one fluorescence radiation at the first end of the optical waveguide.

7. The method for fabrication of an fabricating the optical waveguide system (LWL) according to claim 2, wherein the optical waveguide is coated with one or more waveguides comprising clearances.

8. The method for fabrication of an fabricating the optical waveguide system (LWL) according to claim 2 further comprising determining a physical quantity, the determining of the physical quantity including:
deploying the optical waveguide,
wherein the deployed optical waveguide is coated with one or more waveguides comprising clearances;
wherein one or more sensor elements are located in the clearances of the one or more waveguides or on the one or more optical waveguides and/or in a vicinity of the one or more optical waveguides; and
injecting a microwave signal into the one or more waveguides and injecting a pump radiation with the pump radiation wavelength (λₚₘₚ) into the optical waveguide at the second end of the optical waveguide, or exposing the one or more sensor elements of the optical waveguide to a pump radiation with the pump radiation wavelength (λₚₘₚ);
detecting an intensity value of the at least one fluorescence radiation of the NV centers of the one or more sensor elements and/or the other paramagnetic centers of the one or more sensor elements; and
determining at least one measured value for a physical quantity from this intensity value and possibly other values.

9. The A method for fabrication of an optical waveguide (LWL) for determining a physical quantity including comprising:
deploying the optical waveguide system according to claim 1;
feeding pump radiation with the pump radiation wavelength (λₚₘₚ) into the optical waveguide, or exposing the sensor element of the optical waveguide to pump radiation with the pump radiation wavelength (λₚₘₚ);
detecting an intensity value of the at least one fluorescence radiation of the NV centers of the sensor element and/or the other paramagnetic centers of the sensor element; and
determining at least one measured value for the physical quantity from this intensity value and possibly other values.

10. A magnetic field camera comprising:
a sensor element layer as a sensor element, the sensor element further comprising; wherein:
a substrate material; and
a multiplicity of diamonds embedded in the substrate material, wherein (i); and
one or more diamonds of said multiplicity of diamonds further include NV centers and/or other paramagnetic centers; (ii)
the NV centers of the sensor element and/or the other paramagnetic centers of the sensor element emit at least one fluorescence radiation upon exposure to pump radiation; (iii)
that:
the substrate material is a radiation cured substrate material; (iv)
the substrate material is essentially transparent to radiation with a pump radiation wavelength (λₚₘₚ) of the pump radiation with which the NV centers and/or the other paramagnetic centers are pumped; and (v)
the substrate material is essentially transparent to radiation with a fluorescence wavelength (λ_{fl}) of the at least one fluorescence radiation of the NV centers;
a light sensor array; and
an optical system, for spatially resolved recording of a fluorescence picture of the at least one fluorescence radiation of the NV centers and/or the other paramagnetic centers with at least 2×2 pixels.

11. The magnetic field camera according to claim 10, wherein the magnetic field camera is configured to:
generate the fluorescence picture;
output the fluorescence picture; and
store or at least temporarily store the fluorescence picture in a memory of the magnetic field camera and/or to keep the fluorescence picture available and/or to output the fluorescence picture from the memory and/or to transfer the fluorescence picture from the memory to a higher-level computer system.

12. The magnetic field camera according to claim 10, wherein:
the magnetic field camera is configured to execute a computer-implemented artificial intelligence program to:
generate and/or output digitized and/or binary measured values and/or classifications from the recorded fluorescence pictures of the magnetic field camera, and/or
store digitized and/or binary measured values in a memory of the magnetic field camera,
keep digitized and/or binary measured values available in the memory of the magnetic field camera, and/or
output digitized and/or binary measured values and/or to transmit digitized and/or binary measured values to a higher-level computer system.

13. The magnetic field camera according to claim 11 wherein:
further comprising a memory storing at least temporarily a computer program code of a computer-implemented artificial intelligence program, wherein;
a computer system of the magnetic field camera retrieves and executes the program code from the memory upon execution of the computer-implemented artificial intelligence program.

14. A computer program product, wherein:
comprising at least one storage medium, wherein;
information of a program code of a computer-implemented artificial intelligence program is at least temporarily stored in the at least one storage medium in compressed and/or non-compressed and/or encrypted or non-encrypted form; and
the at least one storage medium of the computer program product is configured to:
become part of a memory of a magnetic field camera in which the program code of the computer-implemented artificial intelligence program is at least temporarily stored, or
transfer at least part of its contents to the memory of the magnetic field camera in which the program code of the computer-implemented artificial intelligence program is at least temporarily stored.

15. A motor control for a motor, wherein:
the motor and/or the motor control comprises an optical waveguide system according to claim 1;
the motor control comprises a sensor element layer as a sensor element, the sensor element comprising:
a substrate material;
a multiplicity of diamonds embedded in the substrate material, wherein (i) one or more diamonds of said multiplicity of diamonds further include NV centers and/or other paramagnetic centers, (ii) the NV centers of the sensor element and/or the other paramagnetic centers of the sensor element emit at least one fluorescence radiation upon exposure to pump radiation, (iii) the substrate material is a radiation cured substrate material, (iv) the substrate material is essentially transparent to radiation with a pump radiation wavelength (pmp) of the pump radiation with which the NV centers and/or the other paramagnetic centers are pumped, and (v) the substrate material is essentially transparent to radiation with a fluorescence wavelength (fl) of the at least one fluorescence radiation of the NV centers;
a light sensor array; and
an optical system, for spatially resolved recording of a fluorescence picture of the at least one fluorescence radiation of the NV centers and/or the other paramagnetic centers with at least 2×2 pixels; the; and/or
the motor control is configured to include the a memory storing at least temporarily a computer program code of a computer-implemented artificial intelligence program, wherein a computer system of a magnetic field camera retrieves and executes the program code from the memory upon execution of the computer-implemented artificial intelligence program.

16. A method for commutation of a motor, by comprising:
detecting points in time of zero crossings of a phase current of a motor phase of the motor by means of the method according to claim 9;
detecting points in time of zero crossings of the an absolute value of a magnetic flux density within an air gap of the motor by means of the method according to claim 9, wherein the sensor element is arranged in the air gap of the motor and/or in a stray field of the magnetic field in the air gap of the motor; and
controlling of commutation of phase voltages of phase connections of motor phase windings depending on the points in time of the zero crossings.

17. A light waveguide production quantity
comprising a plurality of optical waveguides systems;
wherein each optical waveguide system of the plurality of optical waveguide systems is provided with an optical waveguide and a sensor element and
wherein the sensor element comprises a substrate material and
wherein a multiplicity of diamonds and/or crystals are embedded in the substrate material and
wherein one or more of the multiplicity of diamonds and/or one or more crystals of the crystals comprise NV centers and/or other paramagnetic centers and
wherein the NV centers of the sensor element and/or the other paramagnetic centers of the sensor element emit at least one fluorescence radiation upon exposure to pump radiation of a pump radiation wavelength (λₚₘₚ) of a predetermined pump radiation intensity via the optical waveguide in the optical waveguide system,
wherein:
the light waveguide production quantity of the light waveguide systems comprises 10 or more light waveguides systems, and
a relevant tolerance window of the intensity of the fluorescence radiation of the pump radiation wavelength (λₚₘₚ) of a predetermined pump radiation intensity via the optical waveguide of a respective optical waveguide system during exposure to pump radiation is 10% of a mean value of measured intensities of the fluorescence radiation of the respective optical waveguides of the respective waveguide systems of the optical waveguide production quantity during the exposure of the sensor element to pump radiation of the pump radiation wavelength (λₚₘₚ) of the predetermined pump radiation intensity, wherein the exposure is irradiation for measuring the respective optical waveguide system via the respective optical waveguide system, and
a Cₚₖ value of these measured intensities of the fluorescence radiation of the respective optical waveguides systems of the light waveguide production quantity during the exposure of the sensor element to pump radiation of the pump radiation wavelength (λₚₘₚ) of the predetermined pump radiation intensity with respect to said relevant tolerance window is a Cₚₖ value higher than Cₚₖ=0,8 and/or higher than Cₚₖ=1.0 and/or higher than Cₚₖ=1.2 and/or higher than Cₚₖ=1.4 and/or higher than Cₚₖ=1.66.

18. A waveguide production quantity wherein the waveguide production quantity comprises a plurality waveguides and
wherein each waveguide of the plurality of waveguides is provided with a sensor element and
wherein the sensor element comprises a substrate material and
wherein a multiplicity of diamonds and/or crystals are embedded in the substrate material and
wherein one or more diamonds of the multiplicity of diamonds and/or one or more crystals of the crystal comprise NV centers and/or other paramagnetic centers, and
wherein the NV centers of the sensor element and/or the other paramagnetic centers of the sensor element emit at least one fluorescence radiation upon exposure to pump radiation of a pump radiation wavelength (λₚₘₚ) of a predetermined pump radiation intensity,
wherein:
the waveguide production quantity of the plurality of waveguides comprises 10 or more waveguides; and
a tolerance window of the intensity of the fluorescence radiation of the sensor element upon exposure to pump radiation of a pump radiation wavelength (λₚₘₚ) of a predetermined pump radiation intensity via an optical waveguide or via a light transmission path which is same for each waveguide is 10% of a mean value of measured intensities of the fluorescence radiation of the respective waveguides of the waveguide production quantity during the exposure of the sensor element to pump radiation of the pump radiation wavelength (λₚₘₚ) of the predetermined pump radiation intensity, the exposure for the measurement of the respective waveguide being carried out via the optical waveguide for each waveguide or via the same light transmission path for each waveguide, and
a Cₚₖ value of these measured intensities of the fluorescence radiation of the respective waveguides of the waveguide production quantity during said exposure of the sensor element to pump radiation of the pump radiation wavelength (λₚₘₚ) of the predetermined pump radiation intensity with respect to a relevant tolerance window is a Cₚₖ value higher than Cₚₖ=0,8 and/or higher than Cₚₖ=1.0 and/or higher than Cₚₖ=1.2 and/or higher than Cₚₖ=1.4 and/or higher than Cₚₖ=1.66.

19. A micro integrated circuit, wherein:
the circuit is a MOS circuit or a CMOS circuit or a BICMOS circuit or a bipolar circuit on a, in particular semiconducting, carrier substrate; and
the micro integrated circuit comprises at least one optical waveguide system according to claim 1.
